(19) United States
(12) Patent Application Publication
(10) Pub. No.: US 2026/0354022 A1
(43) Pub. Date: Nov. 5, 2026

(54) HETEROCYCLIC COMPOUND, ORGANIC LIGHT-EMITTING DEVICE INCLUDING THE HETEROCYCLIC COMPOUND, AND ELECTRONIC APPARATUS INCLUDING THE ORGANIC LIGHT-EMITTING DEVICE

(71) Applicant: Samsung Electronics Co., Ltd., Suwon-si (KR)

(72) Inventors: Eunkyung Lee, Suwon-si (KR); Keisuke KORAI, Yokohama-city (JP); Sangmo Kim, Suwon-si (KR); Halim Lee, Suwon-si (KR); Raesung Kim, Suwon-si (KR); Joonghyuk Kim, Suwon-si (KR); Jiwhan Kim, Suwon-si (KR); Sungho Nam, Suwon-si (KR); Daun Jeong, Suwon-si (KR); Hwayoung Cho, Suwon-si (KR); Jun Chwae, Suwon-si (KR)

(21) Appl. No.: 19/400,948

(22) Filed: Nov. 25, 2025

(30) Foreign Application Priority Data
Dec. 24, 2024 (KR) 10-2024-0196203

(51) Int. Cl. H10K 85/60; C07F 5/02; C09K 11/06; H10K 50/12

(52) U.S. Cl. CPC H10K 85/658; C07F 5/027; C09K 11/06; C09K 2211/1007; C09K 2211/1018; H10K 50/121

(57) ABSTRACT

A heterocyclic compound represented by Formula 1, an organic light-emitting device including the heterocyclic compound, and an electronic apparatus including the organic light-emitting device:

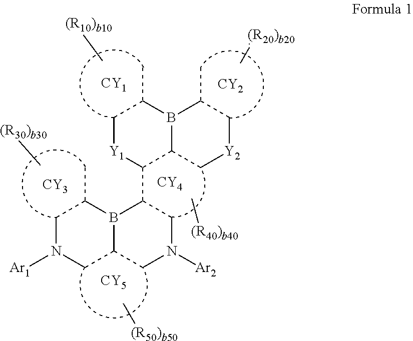

wherein, in Formula 1, Ar₁ and Ar₂ are each independently a group represented by Formula 2:

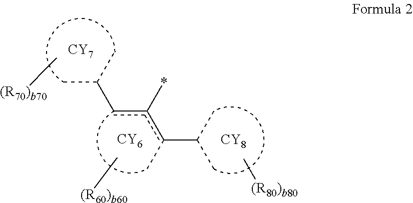

and wherein the remaining descriptions of the substituents in Formulae 1 and 2 are as provided herein.

### CROSS-REFERENCE TO RELATED APPLICATION

This application claims to and the benefit of Korean Patent Application No. 10-2024-0196203, filed on Dec. 24, 2024, in the Korean Intellectual Property Office, and all the benefits accruing therefrom under 35 U.S.C. § 119, the content of which is incorporated by reference herein in its entirety.

### BACKGROUND

### 1. Field

The subject matter relates to a heterocyclic compound, an organic light-emitting device including the heterocyclic compound, and an electronic apparatus including the organic light-emitting device.

### 2. Description of the Related Art

Organic light-emitting devices (OLEDs) are self-emissive devices that have excellent characteristics in terms of viewing angles, response time, brightness, driving voltage, response speed, and the like. In addition, OLEDs can produce full-color images.

An example of an organic light-emitting device includes an anode, a cathode, and an organic layer arranged between the anode and the cathode and including an emission layer. A hole transport region may be arranged between the anode and the emission layer, and an electron transport region may be arranged between the emission layer and the cathode. Holes provided from the anode may move toward the emission layer through the hole transport region, and electrons provided from the cathode may move toward the emission layer through the electron transport region. The holes and the electrons recombine in the emission layer to produce excitons. When the excitons transition from an excited state to a ground state, light is emitted.

### SUMMARY

Provided are a heterocyclic compound, an organic light-emitting device including the heterocyclic compound, and an electronic apparatus including the organic light-emitting device.

Additional aspects will be set forth in part in the detailed description that follows and, in part, will be apparent from the detailed description, or may be learned by practice of the presented exemplary embodiments herein.

According to an aspect, provided is a heterocyclic compound represented by Formula 1:

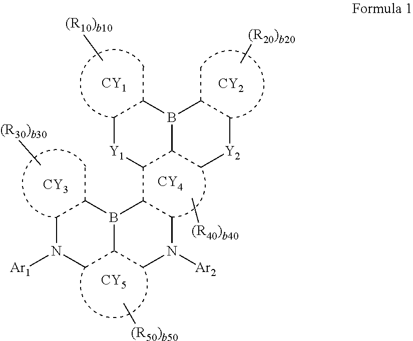

wherein, in Formula 1,
Y₁ is a single bond, O, S, Se, N(R₁), C(R₁)(R₂), Si(R₁)(R₂), Ge(R₁)(R₂), B(R₁), P(R₁), P(═O)(R₁), S(═O)₂, or C(═O),
Y₂ is a single bond, O, S, Se, N(R₃), C(R₃)(R₄), Si(R₃)(R₄), Ge(R₃)(R₄), B(R₃), P(R₃), P(═O)(R₃), S(═O)₂, or C(═O),
ring CY₁ to ring CY₅ are each independently a C₅-C₃₀ carbocyclic group or a C₁-C₃₀ heterocyclic group, and
Ar₁ and Ar₂ are each independently a group represented by Formula 2,

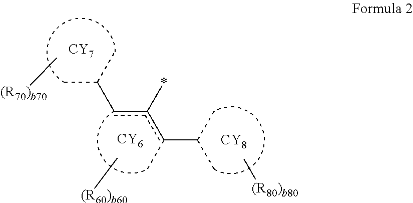

wherein, in Formula 2,
ring CY₆ to ring CY₈ are each independently a C₅-C₃₀ carbocyclic group or a C₁-C₃₀ heterocyclic group,
[symbol] indicates a single bond or a double bond,
* indicates a binding site to a neighboring atom,
   wherein, in Formulae 1 and 2,
R₁ to R₄, R₁₀, R₂₀, R₃₀, R₄₀, R₅₀, R₆₀, R₇₀, and R₈₀ are each independently hydrogen, deuterium, —F, —Cl, —Br, —I, —SF₅, a hydroxyl group, a cyano group, a nitro group, an amino group, an amidino group, a hydrazino group, a hydrazono group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, a substituted or unsubstituted monovalent non-aromatic condensed heteropolycyclic group, —N(Q₁)(Q₂), —Si(Q₁)(Q₂)(Q₃), —Ge(Q₁)(Q₂)(Q₃), —C(═O)(Q₁), —S(═O)(Q₁), —S(═O)₂(Q₁), —B(Q₁)(Q₂), —P(Q₁)(Q₂), —P(═O)(Q₁)(Q₂), or —P(═S)(Q₁)(Q₂),
b10, b20, b30, b40, b50, b60, b70, and b80 are each independently 1, 2, 3, 4, 5, 6, 7, 8, 9, 10, 11, 12, 13, or 14,
at least two of a plurality of R₁₀ are optionally bonded together to form a substituted or unsubstituted C₅-C₃₀ carbocyclic group or a substituted or unsubstituted C₁-C₃₀ heterocyclic group,
at least two of a plurality of R₂₀ are optionally bonded together to form a substituted or unsubstituted C₅-C₃₀ carbocyclic group or a substituted or unsubstituted C₁-C₃₀ heterocyclic group,
at least two of a plurality of R₃₀ are optionally bonded together to form a substituted or unsubstituted C₅-C₃₀ carbocyclic group or a substituted or unsubstituted C₁-C₃₀ heterocyclic group,
at least two of a plurality of R₄₀ are optionally bonded together to form a substituted or unsubstituted C₅-C₃₀ carbocyclic group or a substituted or unsubstituted C₁-C₃₀ heterocyclic group,
at least two of a plurality of R₅₀ are optionally bonded together to form a substituted or unsubstituted C₅-C₃₀ carbocyclic group or a substituted or unsubstituted C₁-C₃₀ heterocyclic group,
at least two of a plurality of R₆₀ are optionally bonded together to form a substituted or unsubstituted C₅-C₃₀ carbocyclic group or a substituted or unsubstituted C₁-C₃₀ heterocyclic group,
at least two of a plurality of R₇₀ are optionally bonded together to form a substituted or unsubstituted C₅-C₃₀ carbocyclic group or a substituted or unsubstituted C₁-C₃₀ heterocyclic group,
at least two of a plurality of R₈₀ are optionally bonded together to form a substituted or unsubstituted C₅-C₃₀ carbocyclic group or a substituted or unsubstituted C₁-C₃₀ heterocyclic group,
two or more of adjacent R₁ to R₄, R₁₀, R₂₀, R₃₀, R₄₀, R₅₀, R₆₀, R₇₀, and R₈₀ are optionally bonded together to form a substituted or unsubstituted C₅-C₃₀ carbocyclic group or a substituted or unsubstituted C₁-C₃₀ heterocyclic group,
at least one substituent of the substituted C₅-C₃₀ carbocyclic group, the substituted C₁-C₃₀ heterocyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₁-C₆₀ alkylthio group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₇-C₆₀ alkyl aryl group, the substituted C₇-C₆₀ aryl alkyl group, the substituted C₆-C₆₀ aryloxy group, the substituted C₆-C₆₀ arylthio group, the substituted C₁-C₆₀ heteroaryl group, the substituted C₂-C₆₀ alkyl heteroaryl group, the substituted C₂-C₆₀ heteroaryl alkyl group, the substituted C₁-C₆₀ heteroaryloxy group, the substituted C₁-C₆₀ heteroarylthio group, the substituted monovalent non-aromatic condensed polycyclic group, the substituted monovalent non-aromatic condensed heteropolycyclic group, the substituted C₃-C₁₀ cycloalkylene group, the substituted C₁-C₁₀ heterocycloalkylene group, the substituted C₃-C₁₀ cycloalkenylene group, the substituted C₁-C₁₀ heterocycloalkenylene group, the substituted C₆-C₆₀ arylene group, the substituted C₁-C₆₀ heteroarylene group, the substituted divalent non-aromatic condensed polycyclic group, and the substituted divalent non-aromatic condensed heteropolycyclic group is:
deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, or a C₁-C₆₀ alkylthio group,
a C₁-C₆₀ alkyl group, a C₂-C₆₀ alkenyl group, a C₂-C₆₀ alkynyl group, a C₁-C₆₀ alkoxy group, or a C₁-C₆₀ alkylthio group, each substituted with deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₁₁)(Q₁₂), —Si(Q₁₁)(Q₁₂)(Q₁₃), —Ge(Q₁₁)(Q₁₂)(Q₁₃), —C(═O)(Q₁₁), —S(═O)(Q₁₁), —S(═O)₂(Q₁₁), —B(Q₁₁)(Q₁₂), —P(Q₁₁)(Q₁₂), —P(═O)(Q₁₁)(Q₁₂), —P(═S)(Q₁₁)(Q₁₂), or a combination thereof,
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, or a monovalent non-aromatic condensed heteropolycyclic group, each unsubstituted or substituted with deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₇-C₆₀ aryl alkyl group, a C₆-C₆₀ aryloxy group, a C₆-C₆₀ arylthio group, a C₁-C₆₀ heteroaryl group, a C₂-C₆₀ alkyl heteroaryl group, a C₂-C₆₀ heteroaryl alkyl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₂₁)(Q₂₂), —Si(Q₂₁)(Q₂₂)(Q₂₃), —Ge(Q₂₁)(Q₂₂)(Q₂₃), —C(═O)(Q₂₁), —S(═O)(Q₂₁), —S(═O)₂(Q₂₁), —B(Q₂₁)(Q₂₂), —P(Q₂₁)(Q₂₂), —P(═O)(Q₂₁)(Q₂₂), —P(═S)(Q₂₁)(Q₂₂), or a combination thereof,
—N(Q₃₁)(Q₃₂), —Si(Q₃₁)(Q₃₂)(Q₃₃), —Ge(Q₃₁)(Q₃₂)(Q₃₃), —C(═O)(Q₃₁), —S(═O)(Q₃₁), —S(═O)₂(Q₃₁), —B(Q₃₁)(Q₃₂), —P(Q₃₁)(Q₃₂), —P(═O)(Q₃₁)(Q₃₂), or —P(═S)(Q₃₁)(Q₃₂), or
a combination thereof,
Q₁ to Q₃, Q₁₁ to Q₁₃, Q₂₁ to Q₂₃, and Q₃₁ to Q₃₃ are each independently hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, or a substituted or unsubstituted monovalent non-aromatic condensed heteropolycyclic group, and
* indicates a binding site to a neighboring atom.

According to another aspect, an organic light-emitting device includes at least one of the heterocyclic compounds represented by Formula 1.

According to another aspect, provided is an organic light-emitting device including a first electrode; a second electrode; and an organic layer arranged between the first electrode and the second electrode, wherein the organic layer includes an emission layer, and wherein the organic layer further includes at least one heterocyclic compound represented by Formula 1.

According to another aspect, an electronic apparatus includes the organic light-emitting device.

### BRIEF DESCRIPTION OF THE DRAWINGS

These and other aspects, features, and advantages of certain exemplary embodiments will be more apparent from the following detailed description taken in conjunction with the accompanying drawings, in which:

FIG. 1 is a schematic cross-sectional view of an organic light-emitting device according to one or more embodiments; and

FIGS. 2 to 6 are schematic diagrams showing energy transfer of an organic light-emitting device according to one or more embodiments, wherein the y-axis is energy.

### DETAILED DESCRIPTION

Reference will now be made in further detail to exemplary embodiments, examples of which are illustrated in the accompanying drawings, wherein like reference numerals refer to like elements throughout the specification. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

The terminology used herein is for the purpose of describing one or more exemplary embodiments only and is not intended to be limiting. As used herein, the singular forms “a,” “an,” and “the” are intended to include the plural forms as well, unless the context clearly indicates otherwise. The term “or” means “and/or.” It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms first, second, third etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present embodiments.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

It will be understood that when an element is referred to as being “on” another element, it can be directly in contact with the other element or intervening elements may be present therebetween. In contrast, when an element is referred to as being “directly on” another element, there are no intervening elements present.

Unless otherwise defined, all terms (including technical and scientific terms) used herein have the same meaning as commonly understood by one of ordinary skill in the art to which this general inventive concept belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

A heterocyclic compound according to an aspect is represented by Formula 1:

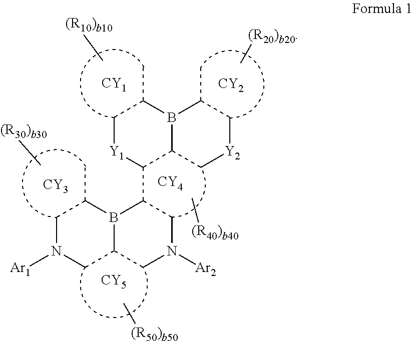

In Formula 1, Y₁ is a single bond, O, S, Se, N(R₁), C(R₁)(R₂), Si(R₁)(R₂), Ge(R₁)(R₂), B(R₁), P(R₁), P(═O)(R₁), S(═O)₂, or C(═O).

In Formula 1, Y₂ is a single bond, O, S, Se, N(R₃), C(R₃)(R₄), Si(R₃)(R₄), Ge(R₃)(R₄), B(R₃), P(R₃), P(═O)(R₃), S(═O)₂, or C(═O).

According to one or more embodiments, Y₁ may be O, S, Se, or N(R₁).

According to one or more embodiments, Y₂ may be O, S, Se, or N(R₃).

In Formula 1, ring CY₁ to ring CY₅ are each independently a C₅-C₃₀ carbocyclic group or a C₁-C₃₀ heterocyclic group.

In Formula 1, Ar₁ to Ar₄ are each independently a group represented by Formula 2:

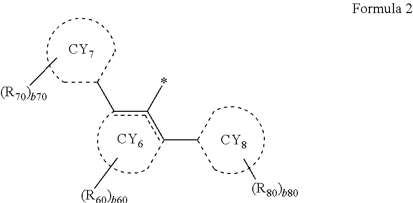

wherein, in Formula 2,
ring CY₆ to ring CY₈ are each independently a C₅-C₃₀ carbocyclic group or a C₁-C₃₀ heterocyclic group,
[symbol] indicates a single bond or a double bond, and
* indicates a binding site to a neighboring atom.

According to one or more embodiments, ring CY₁ to ring CY₈ may each independently be i) a first ring, ii) a second ring, iii) a condensed ring group in which at least two first rings are condensed, iv) a condensed ring group in which at least two second rings are condensed, or v) a condensed ring group in which at least one first ring is condensed with at least one second ring,
the first ring may be a cyclopentane group, a cyclopentadiene group, a furan group, a thiophene group, a pyrrole group, a silole group, an indene group, a benzofuran group, a benzothiophene group, an indole group, a benzosilole group, an oxazole group, an isoxazole group, an oxadiazole group, an isoxadiazole group, an oxatriazole group, an isoxatriazole group, a thiazole group, an isothiazole group, a thiadiazole group, an isothiadiazole group, a thiatriazole group, an isothiatriazole group, a pyrazole group, an imidazole group, a triazole group, a tetrazole group, an azasilole group, a diazasilole group, or a triazasilole group, and
the second ring may be an adamantane group, a norbornene group, a bicyclo[1.1.1]pentane group, a bicyclo[2.1.1]hexane group, a bicyclo[2.2.1]heptane(norbornane) group, a bicyclo[2.2.2]octane group, a cyclohexane group, a cyclohexene group, a benzene group, a pyridine group, a pyrimidine group, a pyrazine group, a pyridazine group, or a triazine group.

According to one or more embodiments, ring CY₁ to ring CY₈ may each independently be a C₆-C₃₀ aromatic carbocyclic group or a C₁-C₃₀ aromatic heterocyclic group.

According to one or more embodiments, ring CY₁ to ring CY₈ may each independently be a benzene group, a naphthalene group, an anthracene group, a phenanthrene group, a triphenylene group, a pyrene group, a chrysene group, a 1,2,3,4-tetrahydronaphthalene group, a benzothiophene group, a benzofuran group, an indole group, an indene group, a benzosilole group, a benzoborole group, a benzophosphole group, a benzoselenophene group, a benzogermole group, a dibenzothiophene group, a dibenzofuran group, a carbazole group, a fluorene group, a dibenzosilole group, a dibenzoborole group, a dibenzophosphole group, a dibenzoselenophene group, a dibenzogermole group, a dibenzothiophene 5-oxide group, a 9H-fluoren-9-one group, a dibenzothiophene 5,5-dioxide group, an azabenzothiophene group, an azabenzofuran group, an azaindole group, an azaindene group, an azabenzosilole group, an azabenzoborole group, an azabenzophosphole group, an azabenzoselenophene group, an azabenzogermole group, an azadibenzothiophene group, an azadibenzofuran group, an azacarbazole group, an azafluorene group, an azadibenzosilole group, an azadibenzoborole group, an azadibenzophosphole group, an azadibenzoselenophene group, an azadibenzogermole group, an azadibenzothiophene 5-oxide group, an aza-9H-fluoren-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a 5,6,7,8-tetrahydroisoquinoline group, a 5,6,7,8-tetrahydroquinoline group, an adamantane group, a norbornane group, or a norbornene group.

According to one or more embodiments, ring CY₁ to ring CY₈ may each independently be a benzene group, a naphthalene group, a phenanthrene group, a fluorene group, a pyridine group, a pyrimidine group, a quinoline group, an isoquinoline group, a phthalazine group, a naphthyridine group, a quinoxaline group, a quinazoline group, a carbazole group, a dibenzofuran group, a dibenzothiophene group, a dibenzosilole group, a dibenzoborole group, a dibenzophosphole group, a dibenzoselenophene group, a dibenzogermole group, a dibenzothiophene 5-oxide group, a 9H-fluoren-9-one group, or a dibenzothiophene 5,5-dioxide group.

According to one or more embodiments, ring CY₁ to ring CY₅ may each independently be a benzene group, a naphthalene group, a phenanthrene group, a fluorene group, a pyridine group, a pyrimidine group, a quinoline group, an isoquinoline group, a phthalazine group, a naphthyridine group, a quinoxaline group, a quinazoline group, a carbazole group, a dibenzofuran group, a dibenzothiophene group, or a dibenzosilole group.

According to one or more embodiments, ring CY₆ to ring CY₈ may each independently be a benzene group, a naphthalene group, a phenanthrene group, a pyridine group, a pyrimidine group, a quinoline group, an isoquinoline group, a phthalazine group, a naphthyridine group, a quinoxaline group, or a quinazoline group.

According to one or more embodiments, a group represented by Formula 2 may be a group represented by Formula 2A:

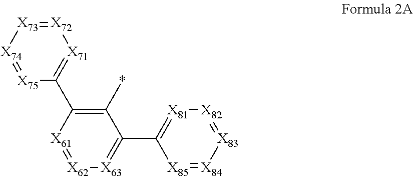

wherein, in Formula 2A,
X₆₁ may be C(R₆₁) or N, X₆₂ may be C(R₆₂) or N, X₆₃ may be C(R₆₃) or N,
X₇₁ may be C(R₇₁) or N, X₇₂ may be C(R₇₂) or N, X₇₃ may be C(R₇₃) or N, X₇₄ may be C(R₇₄) or N, X₇₅ may be C(R₇₅) or N,
X₈₁ may be C(R₈₁) or N, X₈₂ may be C(R₈₂) or N, X₈₃ may be C(R₈₃) or N, X₈₄ may be C(R₈₄) or N, X₈₅ may be C(R₈₅) or N,
R₆₁ to R₆₃ are each independently as described in connection with R₆₀,
R₇₁ to R₇₅ are each independently as described in connection with R₇₀,
R₈₁ to R₈₅ are each independently as described in connection with R₈₀, and
* indicates a binding site to a neighboring atom.

According to one or more embodiments, a group represented by Formula 2 may be a group represented by Formula 2A-1.

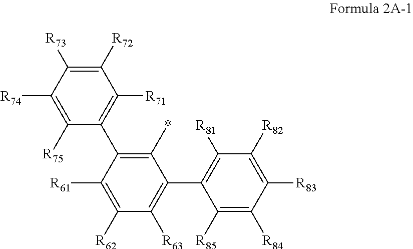

In Formula 2A-1,
R₆₁ to R₆₃ are each independently as described in connection with R₆₀,
R₇₁ to R₇₅ are each independently as described in connection with R₇₀,
R₈₁ to R₈₅ are each independently as described in connection with R₈₀, and
* indicates a binding site to a neighboring atom.

In Formulae 1 and 2, R₁ to R₄, R₁₀, R₂₀, R₃₀, R₄₀, R₅₀, R₆₀, R₇₀, and Rao are each independently hydrogen, deuterium, —F, —Cl, —Br, —I, —SF₅, a hydroxyl group, a cyano group, a nitro group, an amino group, an amidino group, a hydrazino group, a carboxylic acid group or a salt thereof, a sulfonic acid group or a salt thereof, a phosphoric acid group or a salt thereof, a hydrazono group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, a substituted or unsubstituted monovalent non-aromatic condensed heteropolycyclic group, —N(Q₁)(Q₂), —Si(Q₁)(Q₂)(Q₃), —Ge(Q₁)(Q₂)(Q₃), —C(═O)(Q₁), —S(═O)(Q₁), —S(═O)₂(Q₁), —B(Q₁)(Q₂), —P(Q₁)(Q₂), —P(═O)(Q₁)(Q₂), or —P(═S)(Q₁)(Q₂).

According to one or more embodiments, R₁ to R₄, R₁₀, R₂₀, R₃₀, R₄₀, R₅₀, R₆₀, R₇₀, and Rao may each independently be:
hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, or a C₁-C₂₀ alkylthio group;
a C₁-C₂₀ alkyl group, a C₁-C₂₀ alkoxy group, or a C₁-C₂₀ alkylthio group, each substituted with deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a deuterium-containing C₁-C₂₀ alkyl group, a fluorine-containing C₁-C₂₀ alkyl group, a cyclopentyl group, a cyclohexyl group, a cycloheptyl group, a cyclooctyl group, an adamantanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group (norbornanyl group), a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.1]heptyl group, a (C₁-C₂₀ alkyl)bicyclo[2.2.2]octyl group, a silolanyl group, a phenyl group, a (C₁-C₂₀ alkyl)phenyl group, a biphenyl group, a terphenyl group, a naphthyl group, a 1,2,3,4-tetrahydronaphthyl group, a pyridinyl group, a pyrimidinyl group, or a combination thereof;
a cyclopentyl group, a cyclohexyl group, a cycloheptyl group, a cyclooctyl group, an adamantanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a silolanyl group, a phenyl group, a (C₁-C₂₀ alkyl)phenyl group, a biphenyl group, a terphenyl group, a naphthyl group, a 1,2,3,4-tetrahydronaphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, or an azadibenzothiophenyl group, each unsubstituted or substituted with deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a deuterium-containing C₁-C₂₀ alkyl group, a fluorine-containing C₁-C₂₀ alkyl group, a C₁-C₂₀ alkoxy group, a C₁-C₂₀ alkylthio group, a cyclopentyl group, a cyclohexyl group, a cycloheptyl group, a cyclooctyl group, an adamantanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.1]heptyl group, a (C₁-C₂₀ alkyl)bicyclo[2.2.2]octyl group, a silolanyl group, a phenyl group, a (C₁-C₂₀ alkyl)phenyl group, a biphenyl group, a terphenyl group, a naphthyl group, a 1,2,3,4-tetrahydronaphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, or a combination thereof; or
—N(Q₁)(Q₂), —Si(Q₁)(Q₂)(Q₃), —Ge(Q₁)(Q₂)(Q₃), —C(═O)(Q₁), —S(═O)(Q₁), —S(═O)₂(Q₁), —B(Q₁)(Q₂), —P(Q₁)(Q₂), —P(═O)(Q₁)(Q₂), or —P(═S)(Q₁)(Q₂).

According to one or more embodiments, R₁ to R₄, R₁₀, R₂₀, R₃₀, R₄₀, R₅₀, R₆₀, R₇₀, and R₈₀ are each independently:
hydrogen, deuterium, —F, —Cl, —Br, —I, —SF₅, —CD₃, —CD₂H, —CDH₂, —CF₃, —CF₂H, —CFH₂, a C₁-C₆₀ alkyl group, a C₂-C₆₀ alkenyl group, a C₂-C₆₀ alkynyl group, a C₁-C₆₀ alkoxy group, or a C₁-C₆₀ alkylthio group; or
a group represented by one of Formulae 9-1 to 9-61, 9-201 to 9-244, 10-1 to 10-154, or 10-201 to 10-350:

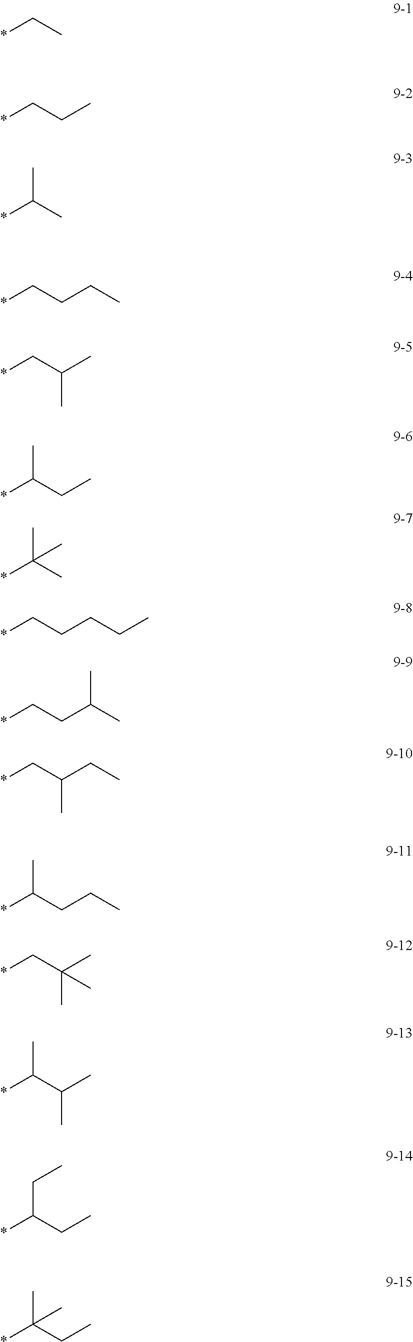

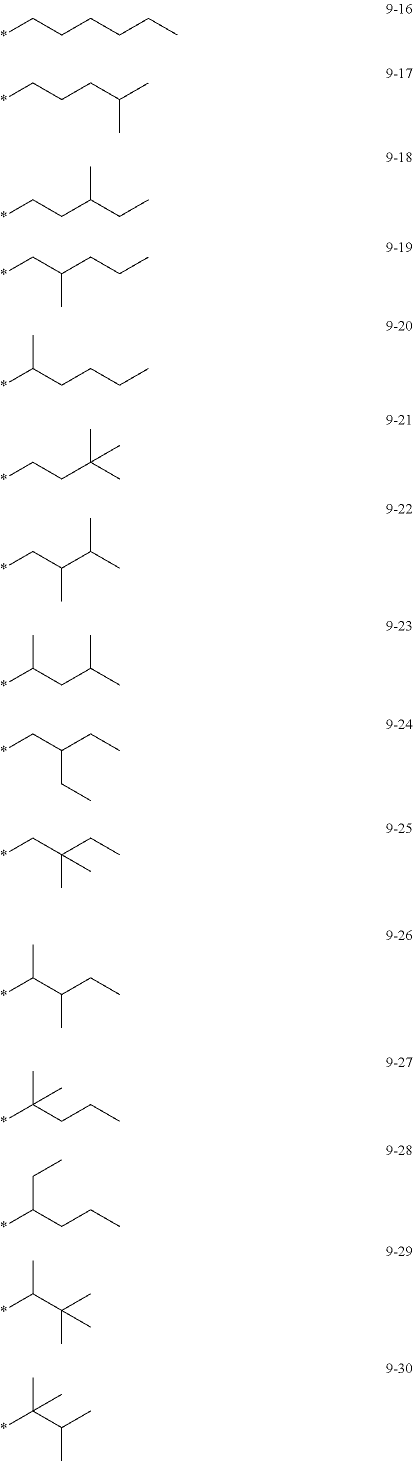

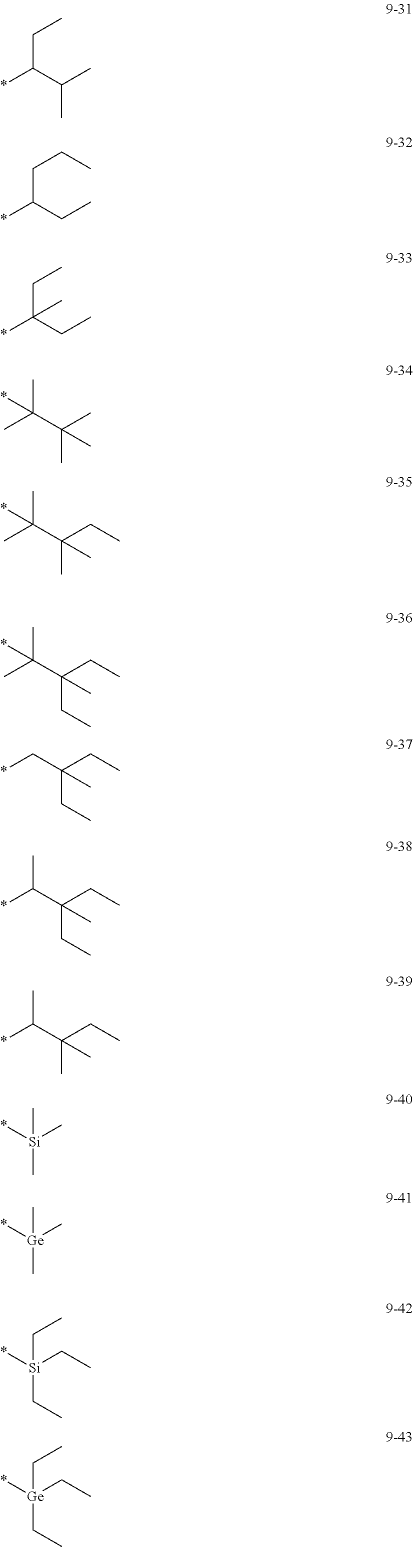

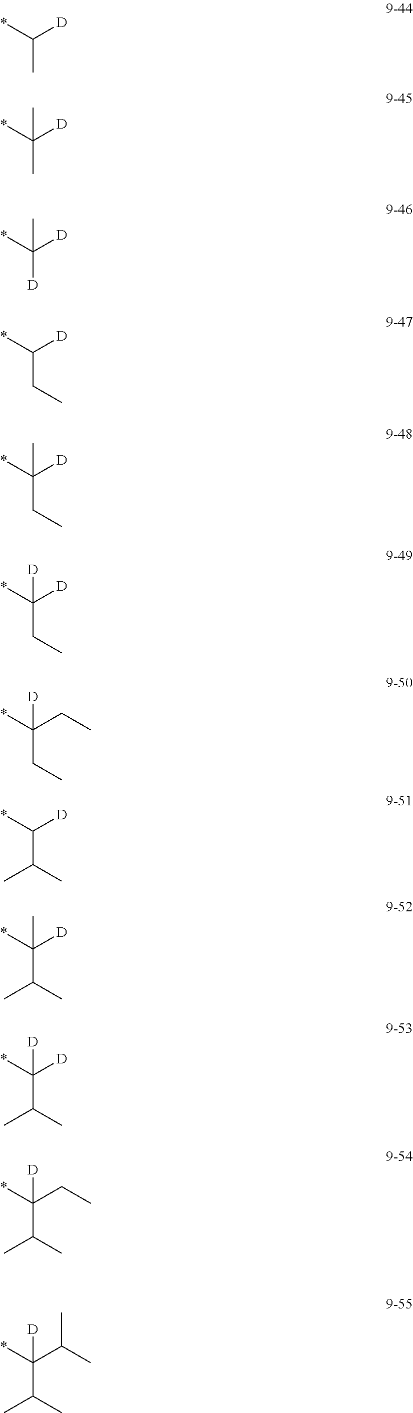

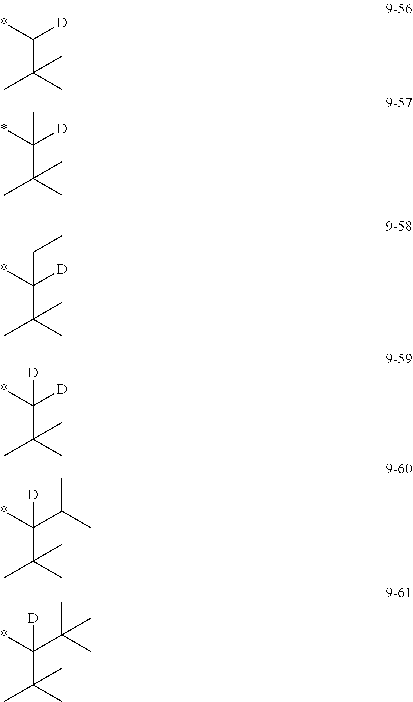

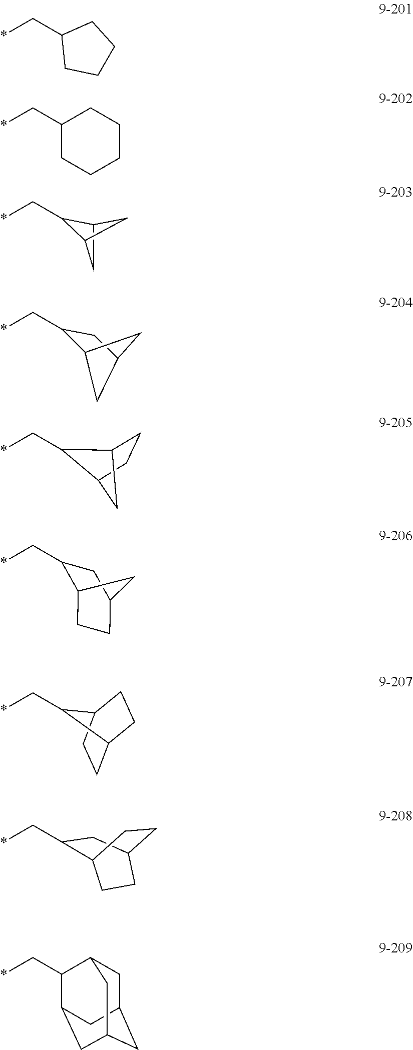

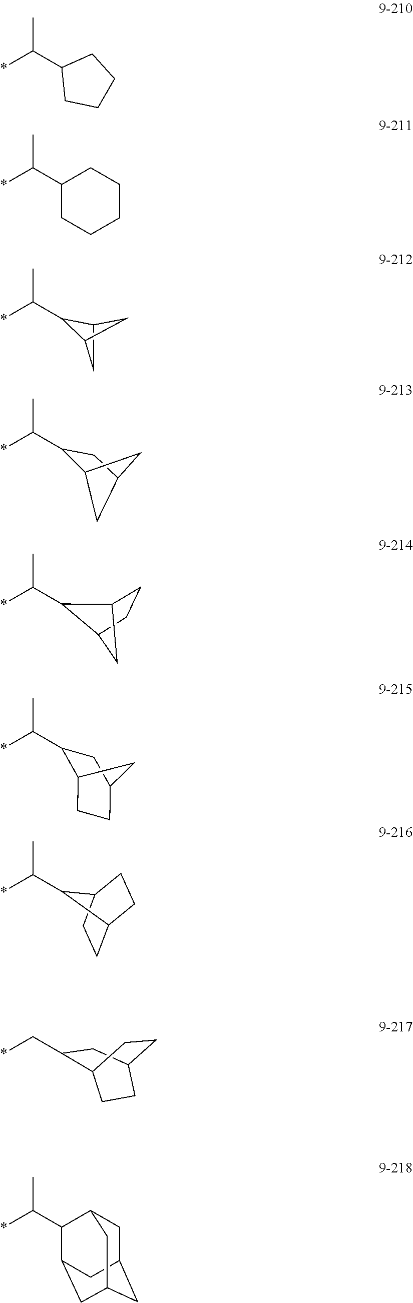

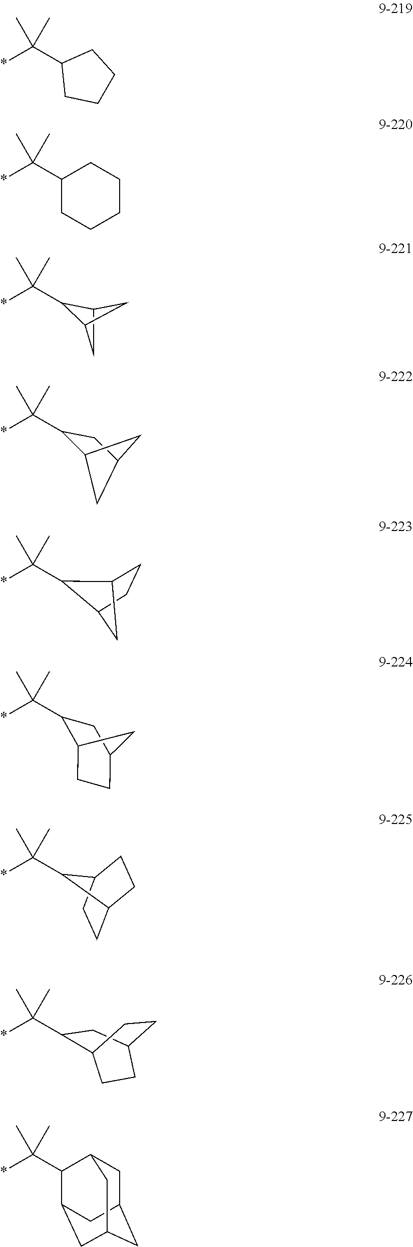

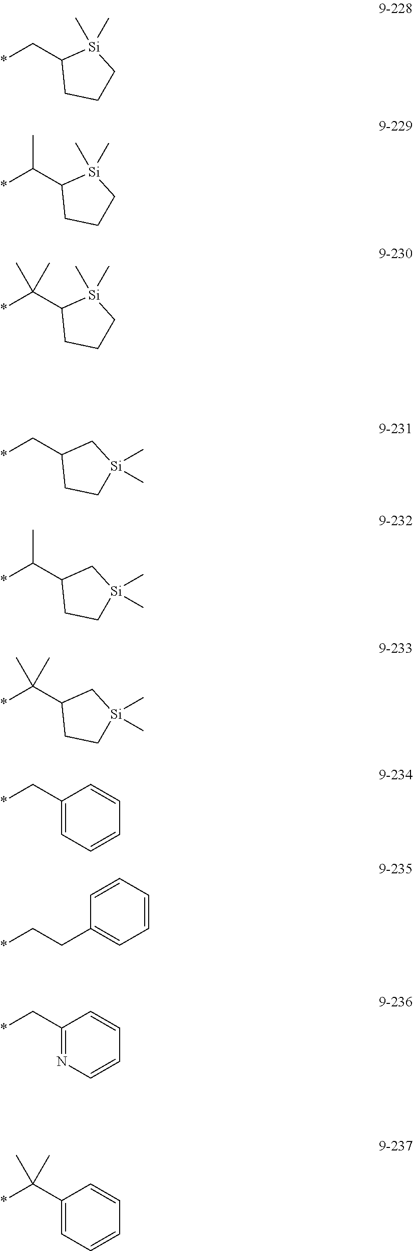

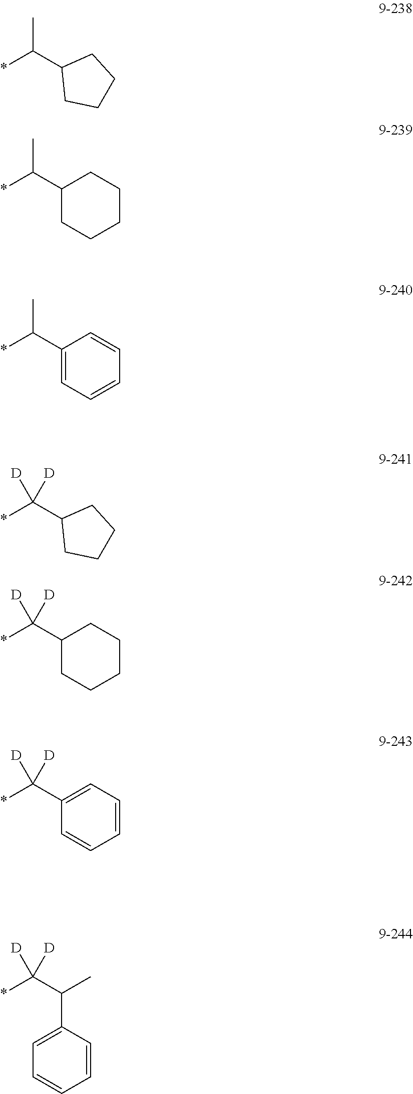

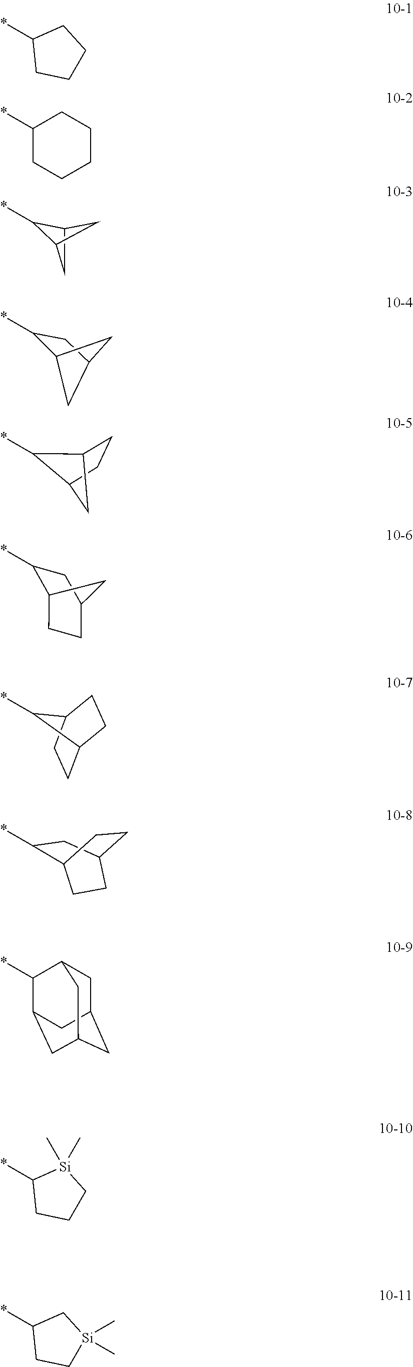

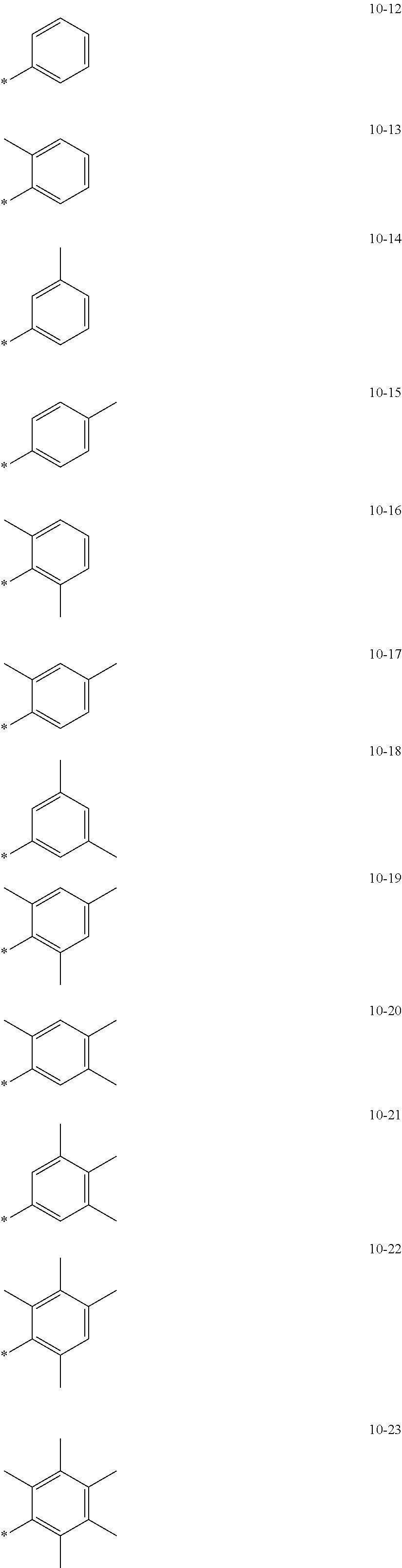

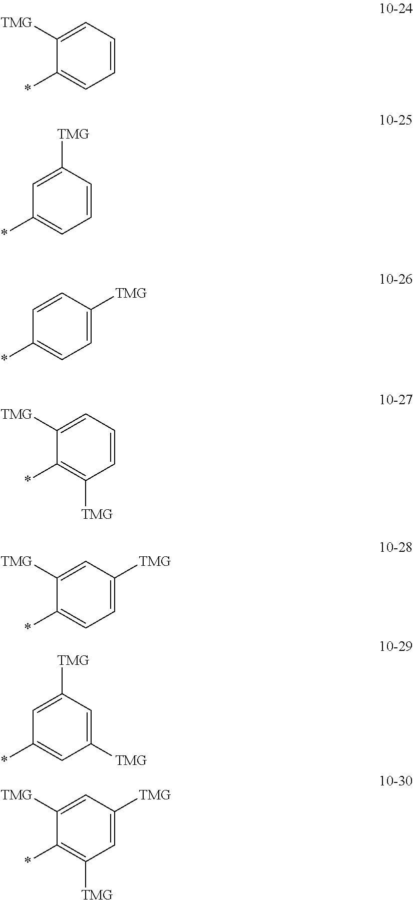

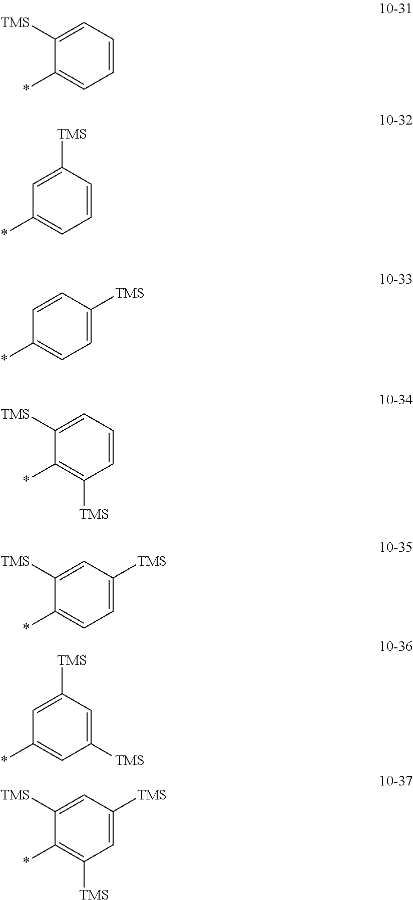

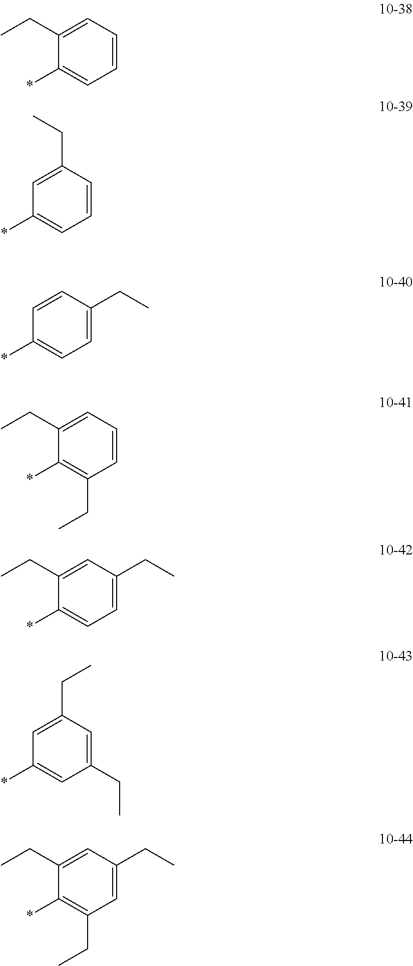

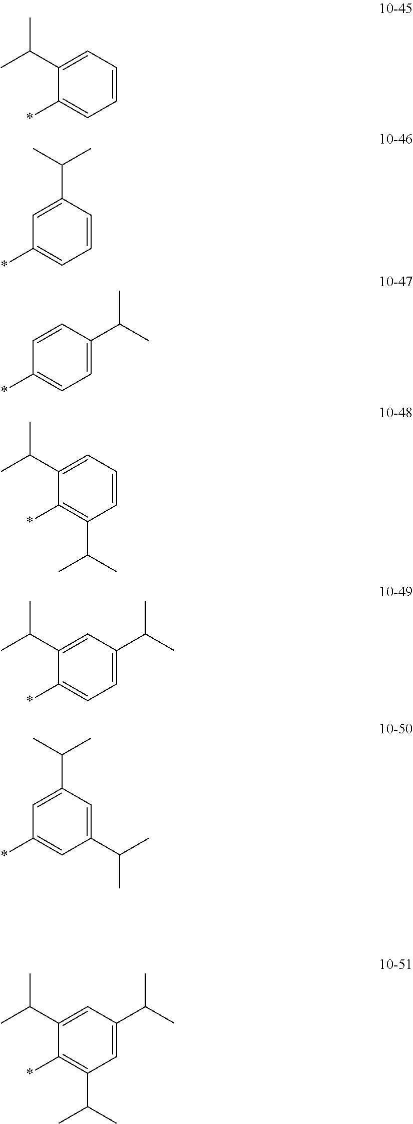

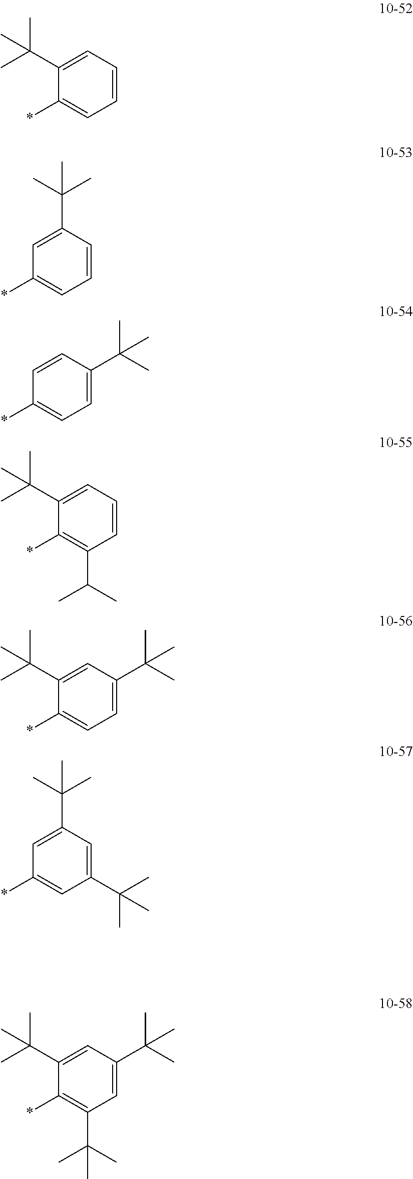

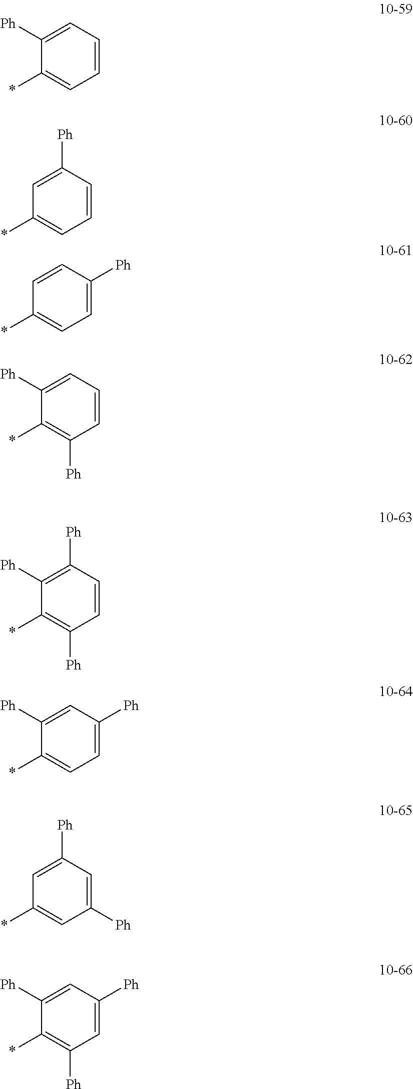

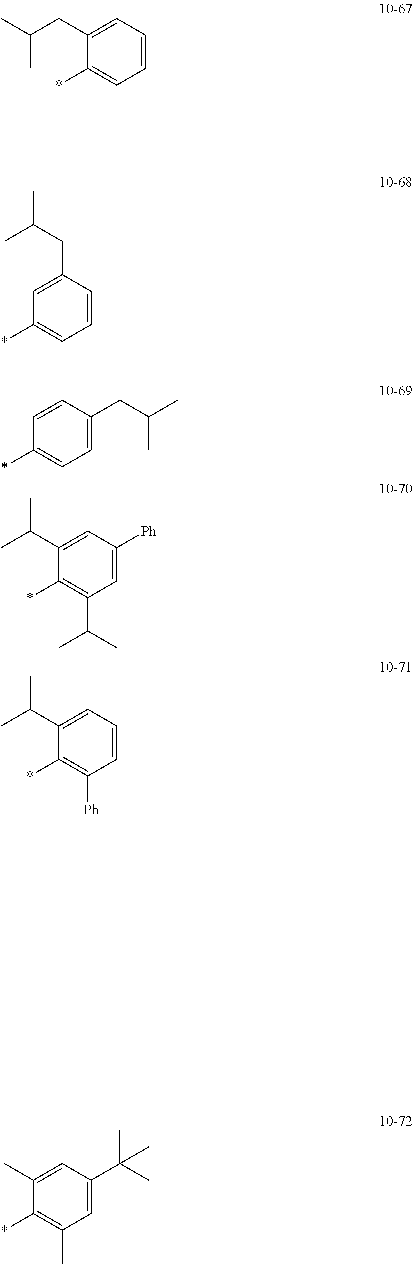

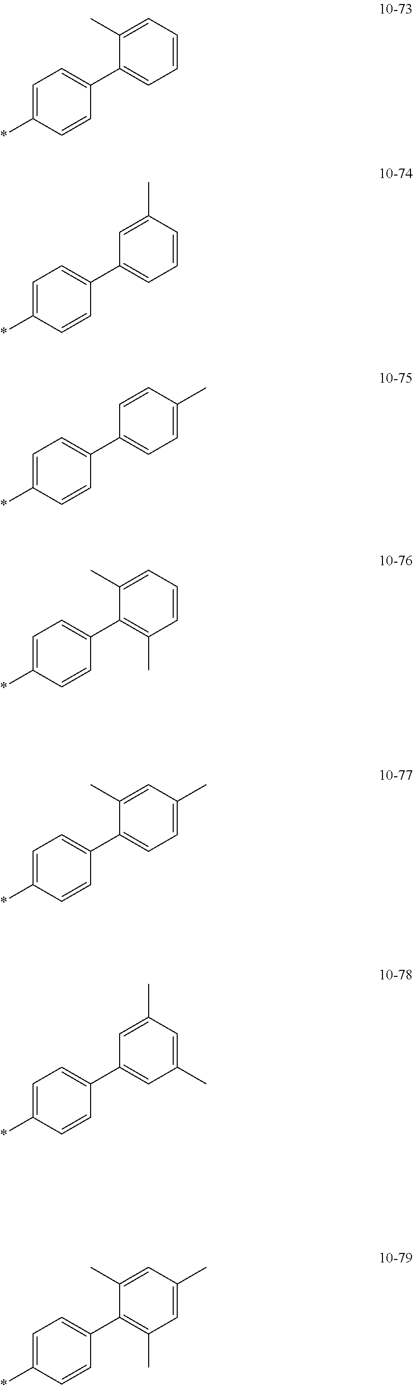

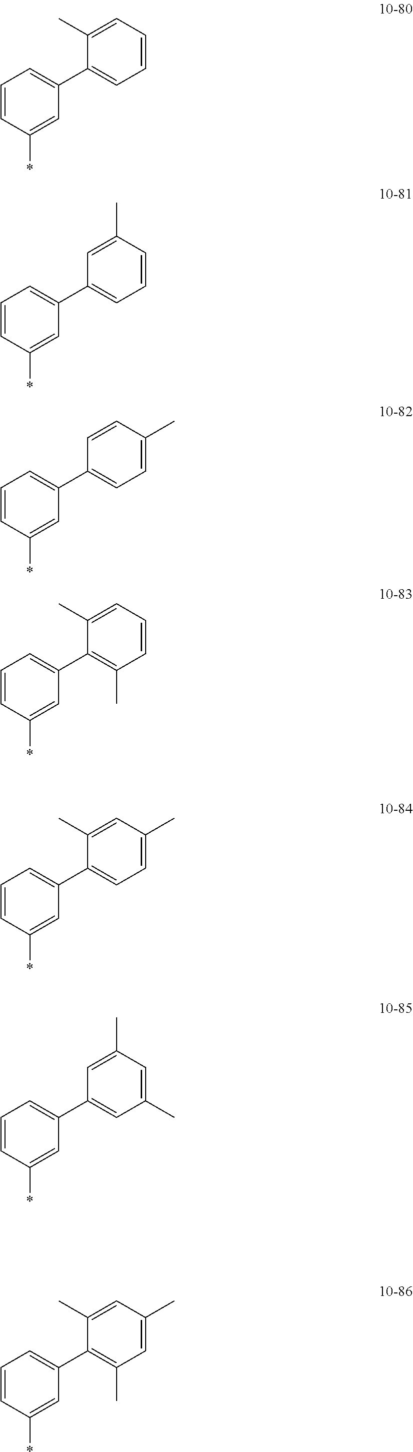

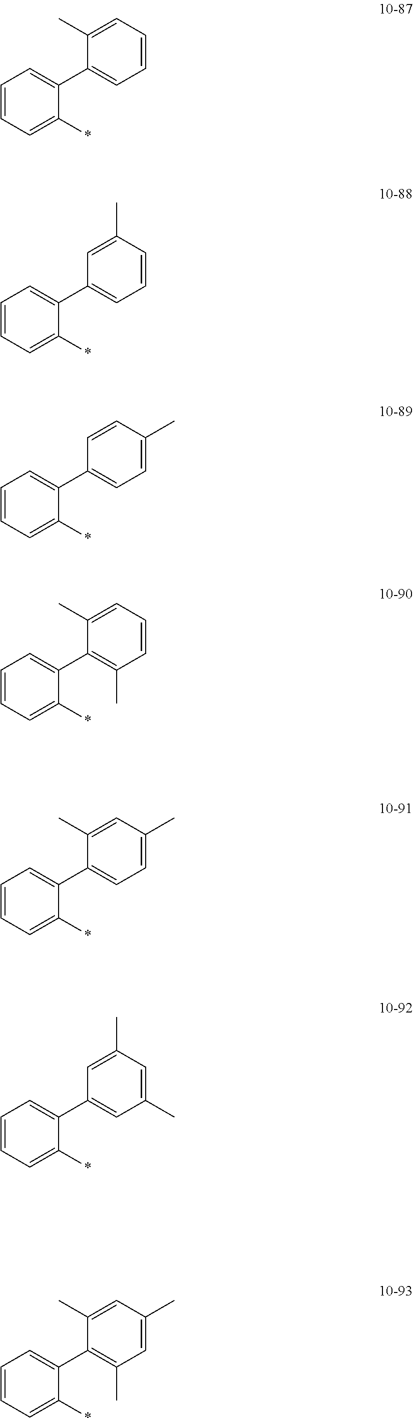

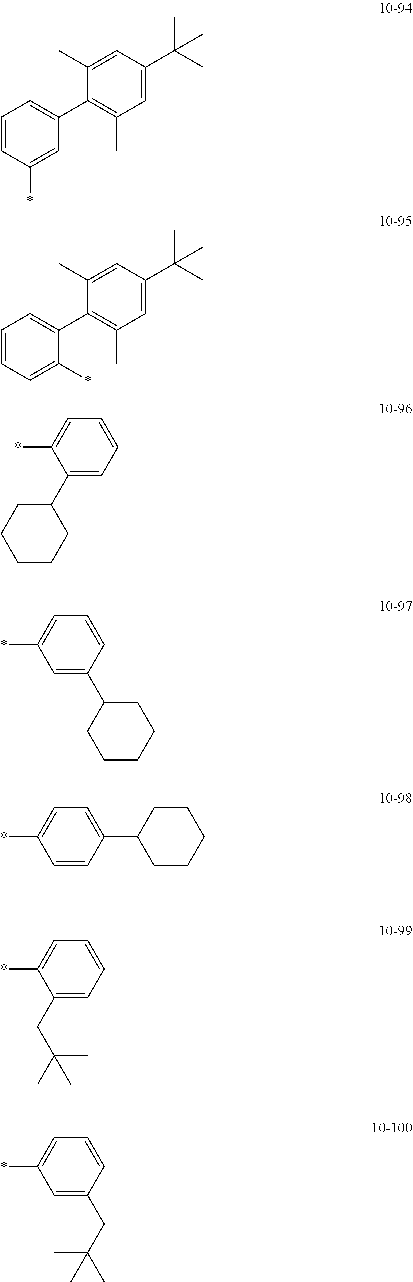

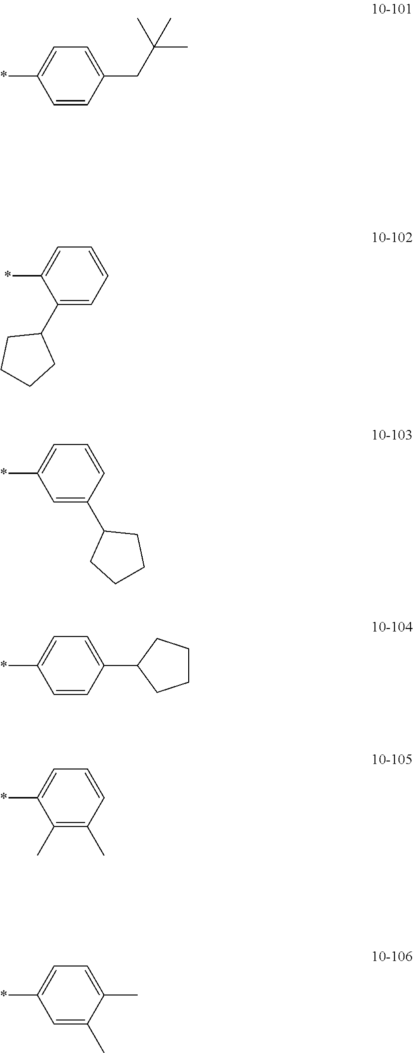

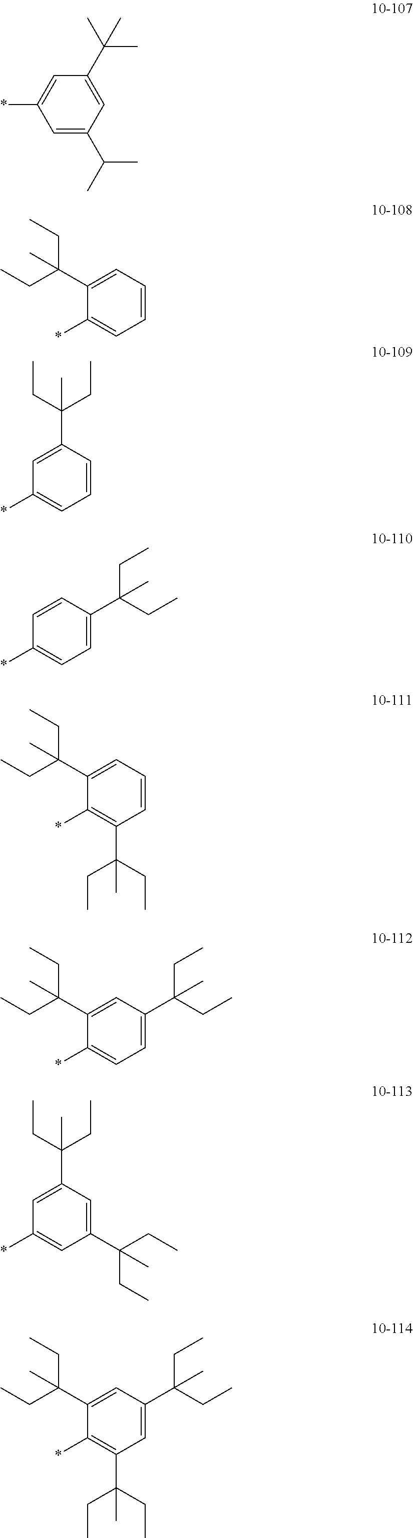

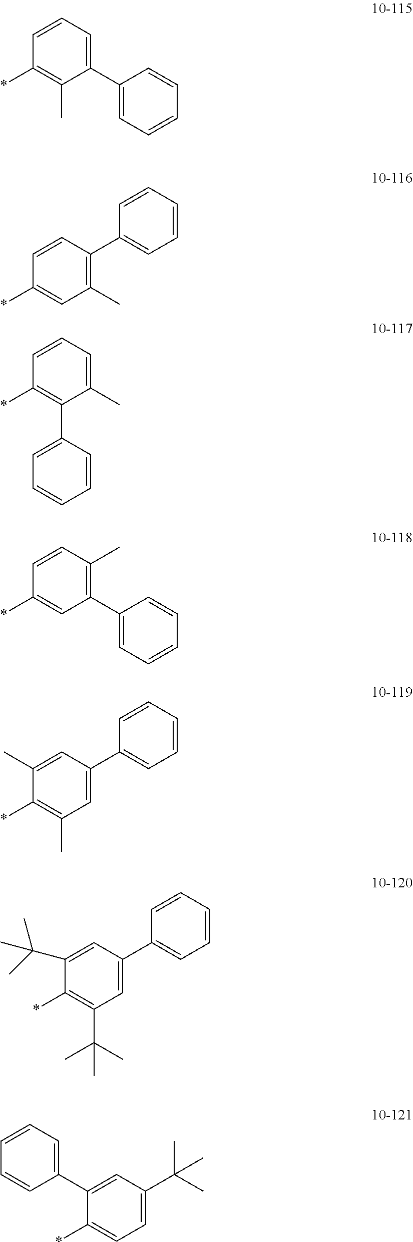

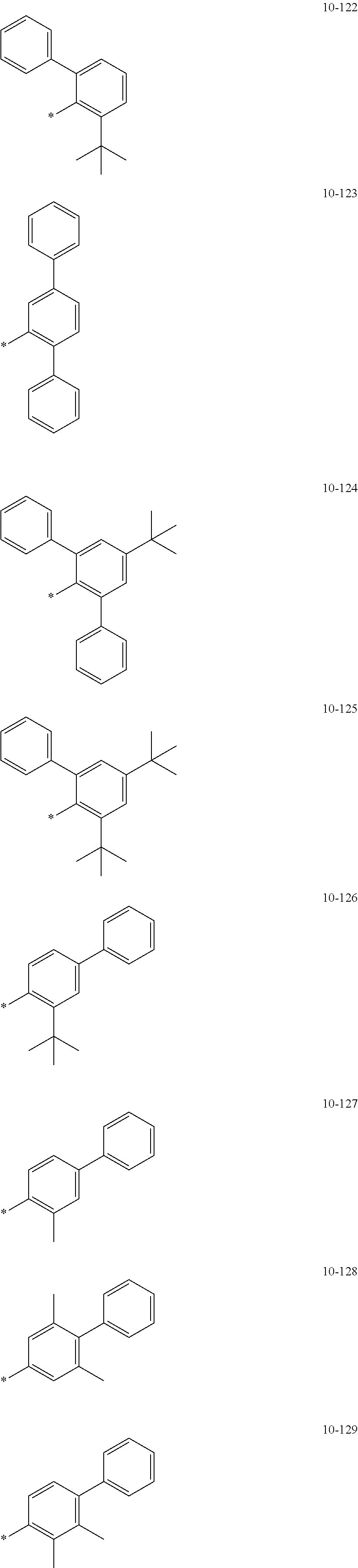

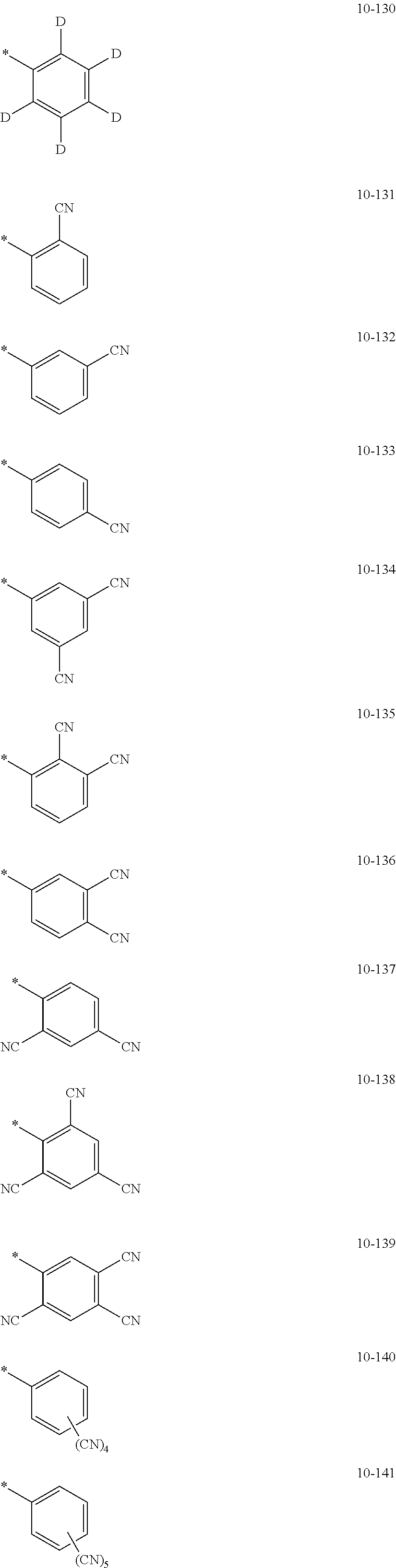

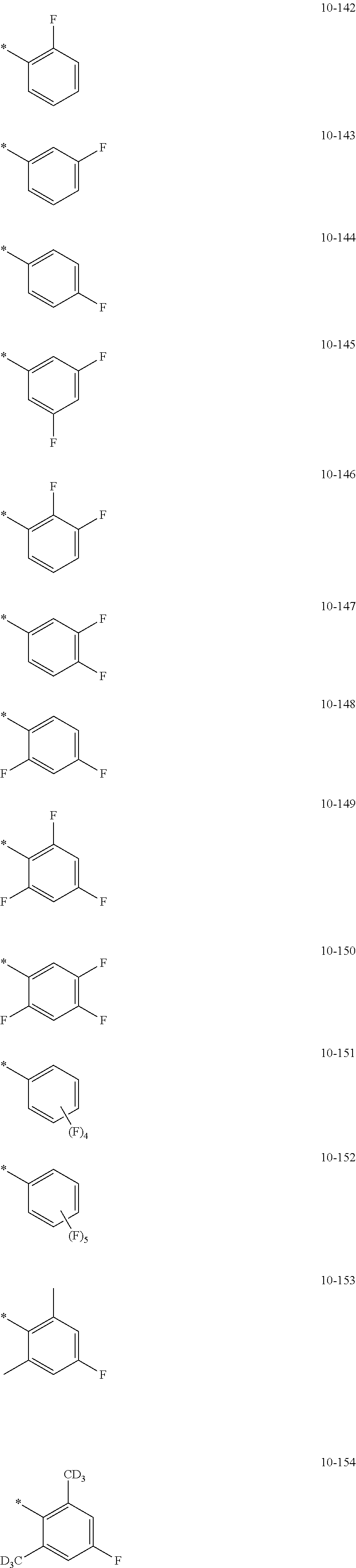

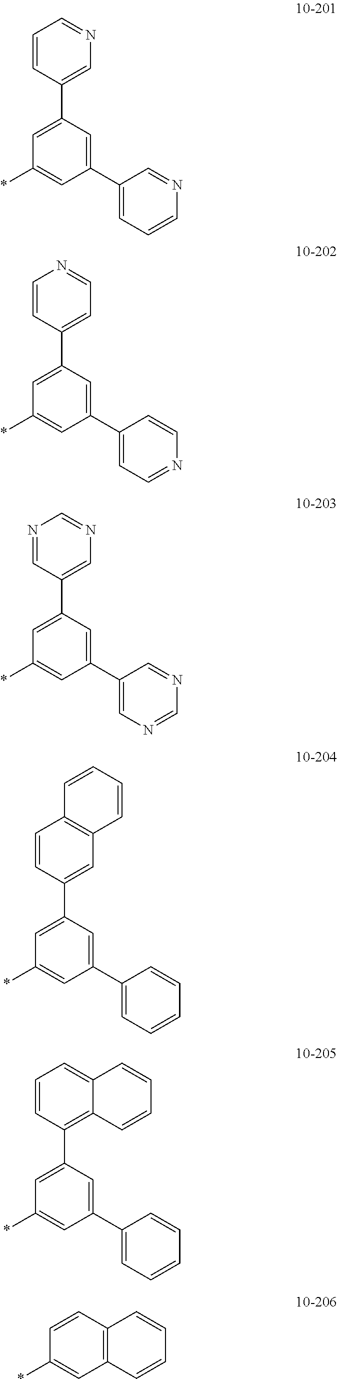

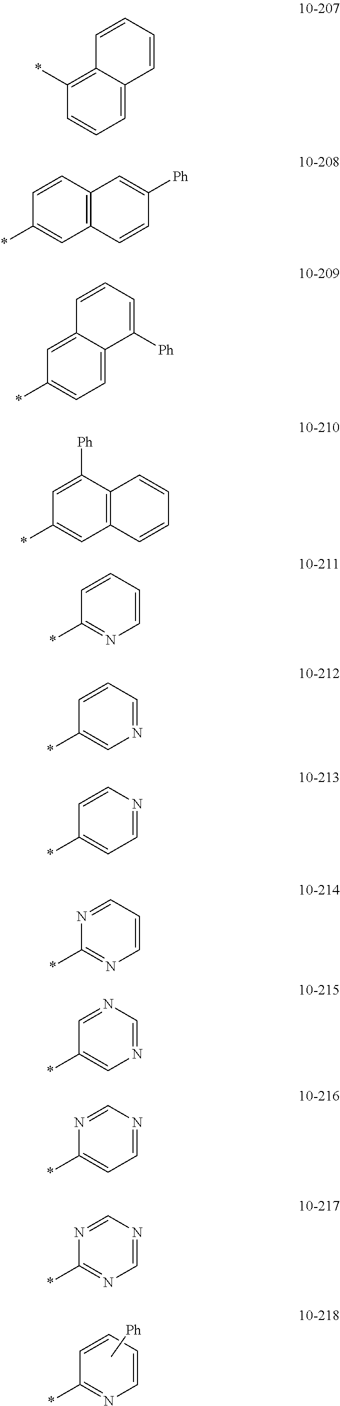

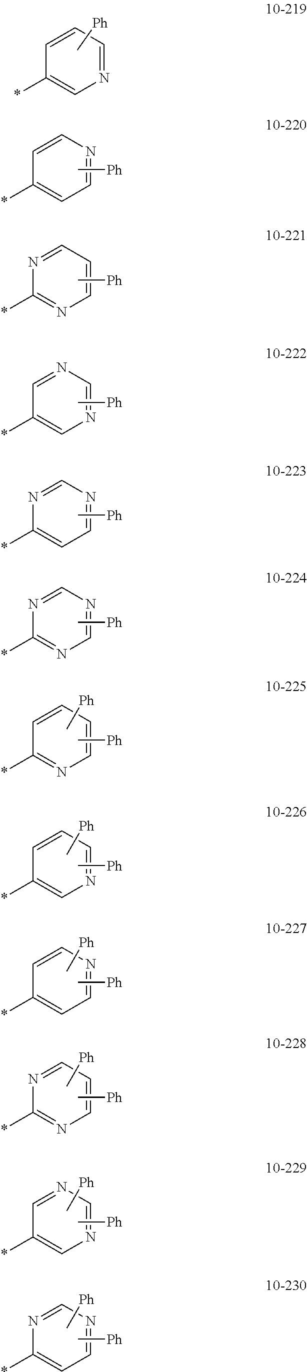

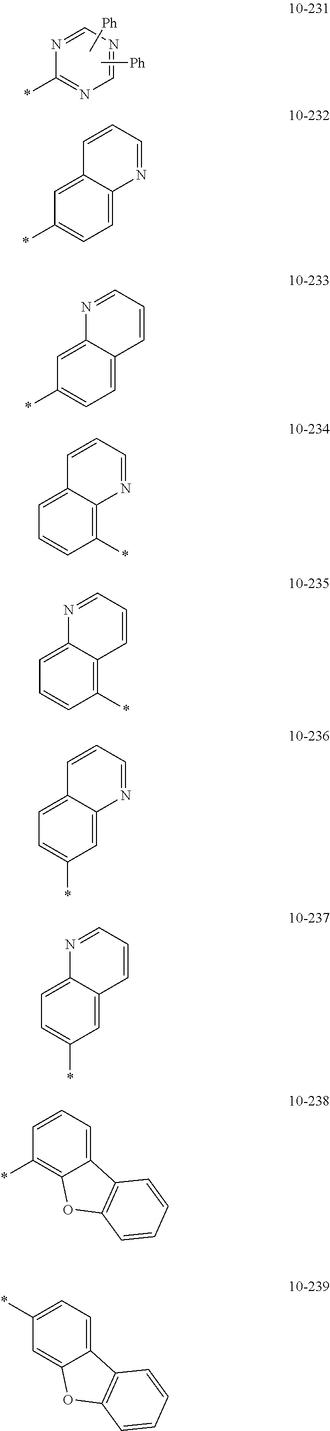

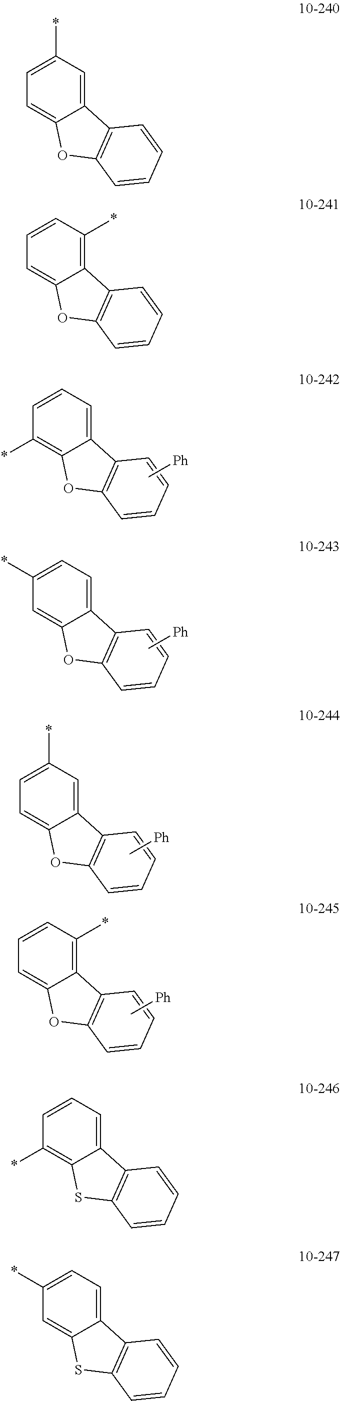

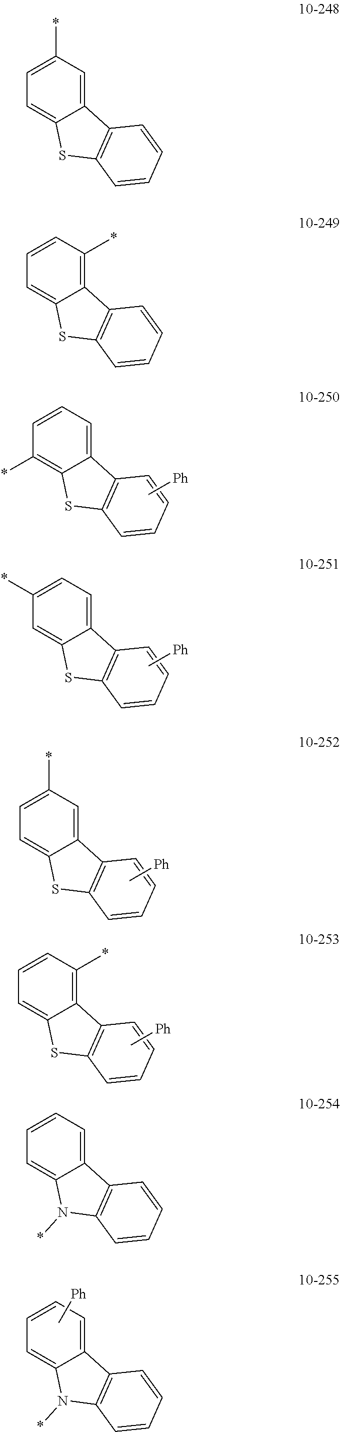

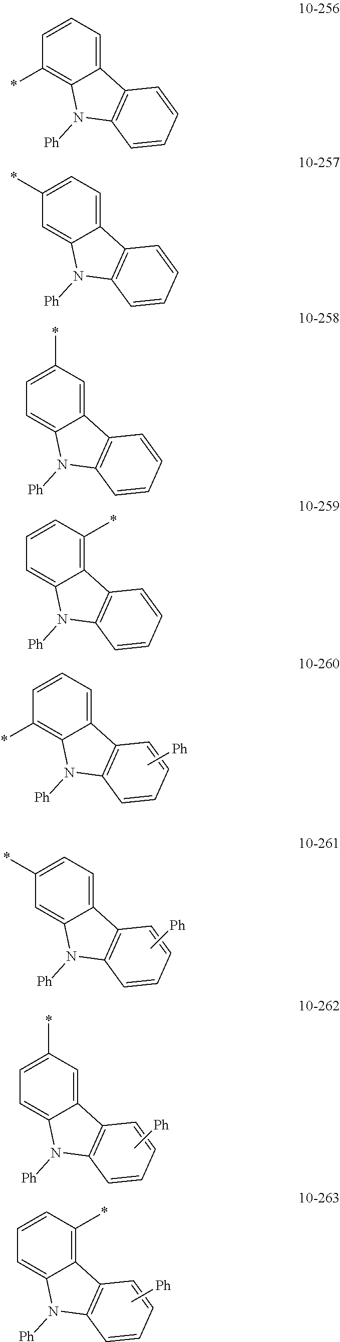

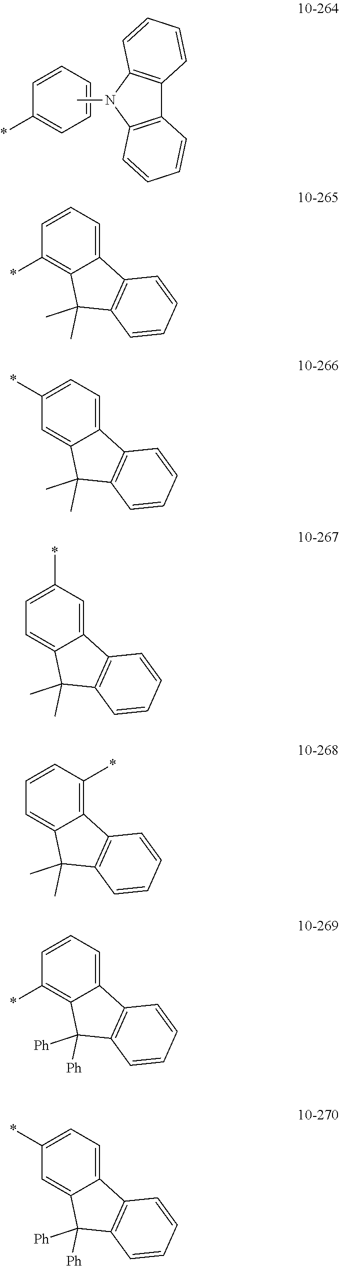

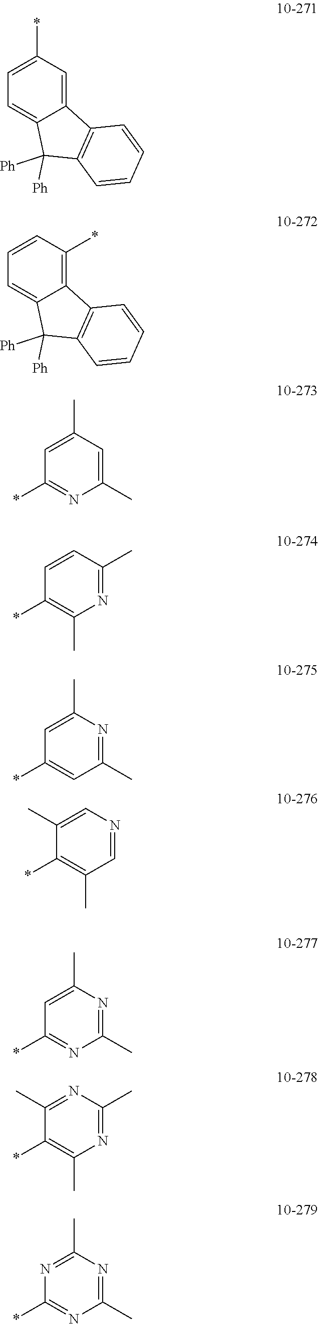

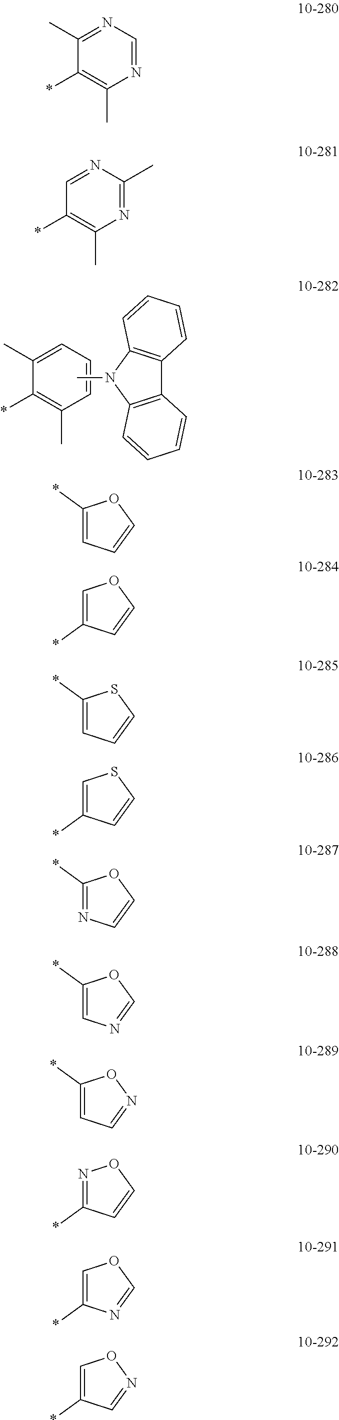

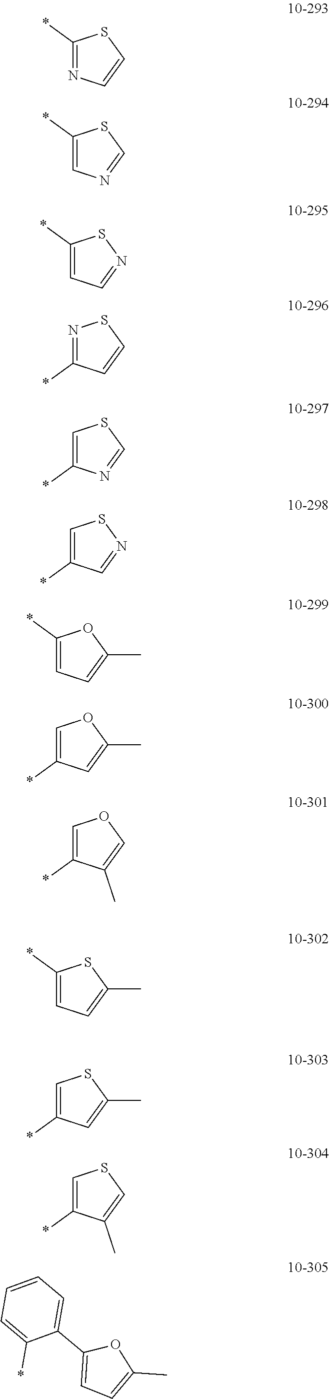

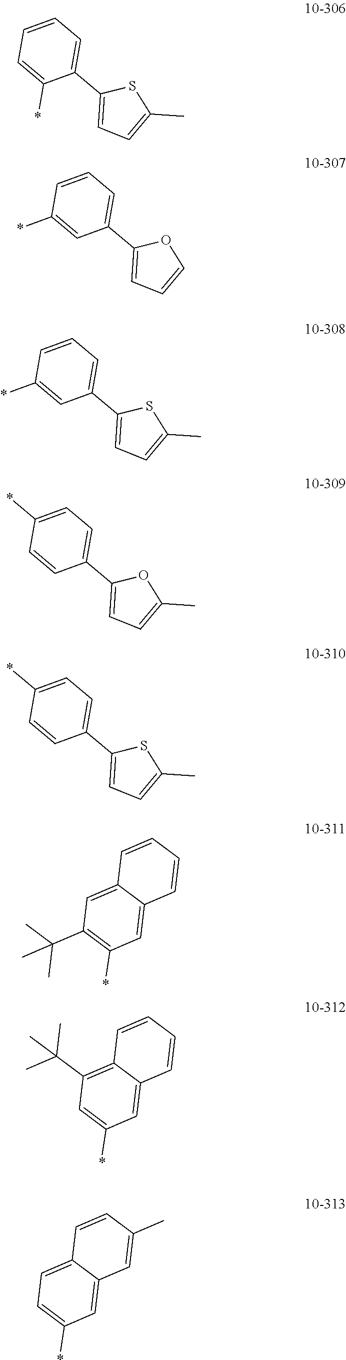

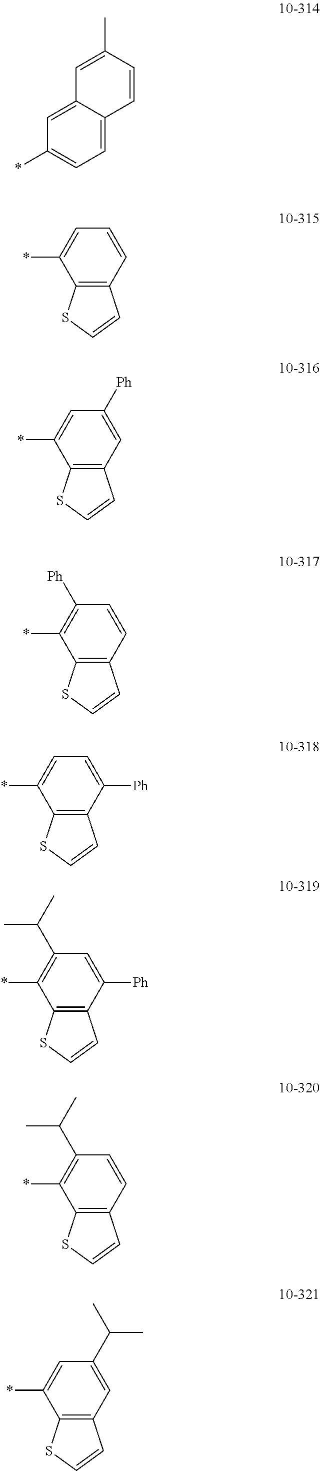

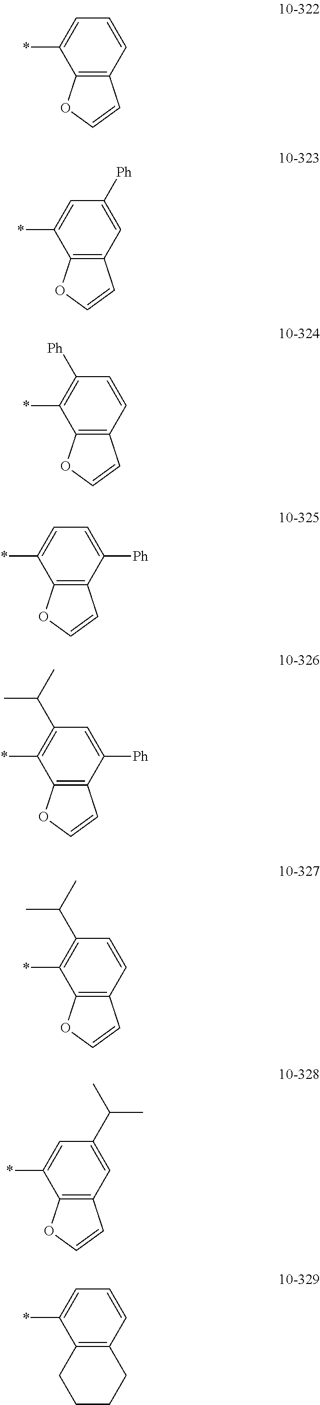

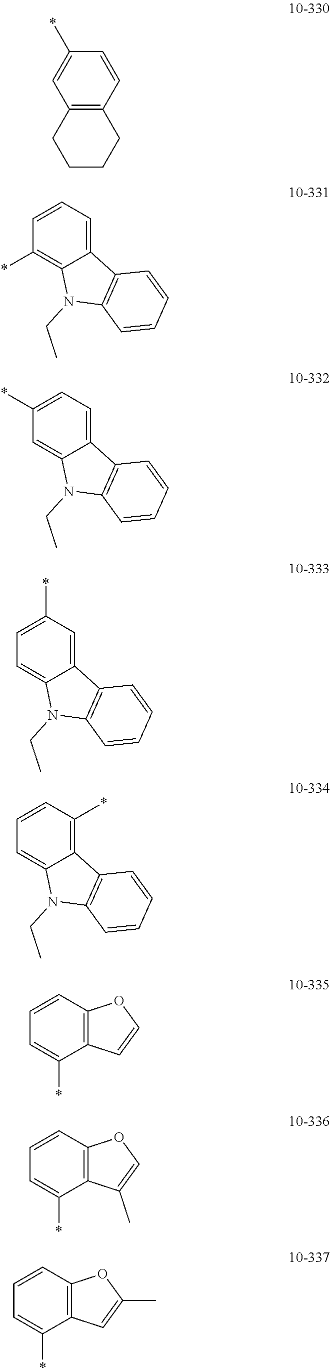

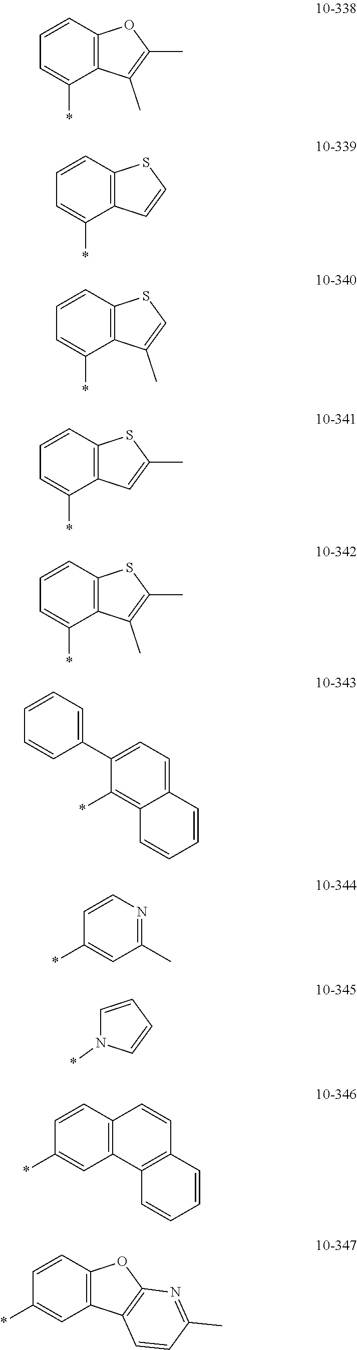

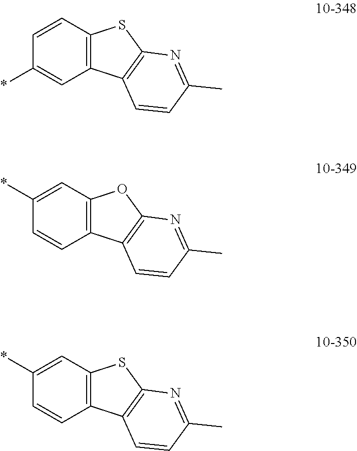 [SMILES: *c1ccc2sc3nc(C)ccc3c2c1 ; *c1ccc2c(c1)oc1nc(C)ccc12 ; *c1ccc2c(c1)sc1nc(C)ccc12]

wherein in Formulae 9-1 to 9-61, 9-201 to 9-244, 10-1 to 10-154, and 10-201 to 10-350, * represents a trimethylsilyl group, and “TMG” represents a trimethylgermyl group.

According to one or more embodiments, R₁ to R₄, R₁₀, R₂₀, R₃₀, R₄₀, R₅₀, R₆₀, R₇₀, and R₈₀ may each independently be:
hydrogen, deuterium, —F, —Cl, —Br, —I, —SF₅, —CD₃, —CD₂H, —CDH₂, —CF₃, —CF₂H, —CFH₂, a C₁-C₆₀ alkyl group, a C₂-C₆₀ alkenyl group, a C₂-C₆₀ alkynyl group, a C₁-C₆₀ alkoxy group, or a C₁-C₆₀ alkylthio group, or
a group represented by one of Formulae 9-1 to 9-61, 9-201 to 9-244, 10-1 to 10-154, or 10-201 to 10-350.

According to one or more embodiments, at least one of R₁ to R₄, R₁₀, R₂₀, R₃₀, R₄₀, R₅₀, R₆₀, R₇₀, or R₈₀ may be deuterium, —F, —Cl, —Br, —I, —SF₅, a cyano group, a substituted or unsubstituted C₁-C₆₀ alkyl group, a substituted or unsubstituted C₃-C₁₀ cycloalkyl group, a substituted or unsubstituted C₆-C₆₀ aryl group, a substituted or unsubstituted C₁-C₆₀ heteroaryl group, a substituted or unsubstituted monovalent non-aromatic condensed polycyclic group, or a substituted or unsubstituted monovalent non-aromatic condensed heteropolycyclic group.

According to one or more embodiments, at least one of R₁ to R₄, R₁₀, R₂₀, R₃₀, R₄₀, R₅₀, R₆₀, R₇₀, or R₈₀ may be a substituted or unsubstituted C₁-C₆₀ alkyl group, a substituted or unsubstituted C₃-C₁₀ cycloalkyl group, a substituted or unsubstituted C₆-C₆₀ aryl group, a substituted or unsubstituted C₁-C₆₀ heteroaryl group, a substituted or unsubstituted monovalent non-aromatic condensed polycyclic group, or a substituted or unsubstituted monovalent non-aromatic condensed heteropolycyclic group.

According to one or more embodiments, at least one of R₁ to R₄, R₁₀, R₂₀, R₃₀, R₄₀, R₅₀, R₆₀, R₇₀, or R₈₀ may be deuterium, —F, —Cl, —Br, —I, —SF₅, a cyano group, a methyl group, an ethyl group, a n-propyl group, an isopropyl group, a n-butyl group, an isobutyl group, a sec-butyl group, a tert-butyl group, a n-pentyl group, an isopentyl group, a 2-methylbutyl group, a sec-pentyl group, a tert-pentyl group, a neo-pentyl group, a 3-pentyl group, a 3-methyl-2-butyl group, a phenyl group, a biphenyl group, a (C₁-C₂₀ alkyl)phenyl group, or a naphthyl group.

In Formulae 1 and 2, b10, b20, b30, b40, b50, b60, b70, and b80 are each independently 1, 2, 3, 4, 5, 6, 7, 8, 9, 10, 11, 12, 13, or 14.

According to one or more embodiments, b10, b20, b30, b40, b50, b60, b70, and b80 may each independently be 1, 2, 3, 4, 5, 6, 7, or 8.

According to one or more embodiments, b10, b20, and b30 may each independently be 1, 2, 3, or 4.

According to one or more embodiments, b40 may be 1.

According to one or more embodiments, b50 may be 1, 2, or 3.

In Formulae 1 and 2,
at least two of a plurality of R₁₀ are optionally bonded together to form a substituted or unsubstituted C₅-C₃₀ carbocyclic group or a substituted or unsubstituted C₁-C₃₀ heterocyclic group,
at least two of a plurality of R₂₀ are optionally bonded together to form a substituted or unsubstituted C₅-C₃₀ carbocyclic group or a substituted or unsubstituted C₁-C₃₀ heterocyclic group,
at least two of a plurality of R₃₀ are optionally bonded together to form a substituted or unsubstituted C₅-C₃₀ carbocyclic group or a substituted or unsubstituted C₁-C₃₀ heterocyclic group,
at least two of a plurality of R₄₀ are optionally bonded to form a substituted or unsubstituted C₅-C₃₀ carbocyclic group or a substituted or unsubstituted C₁-C₃₀ heterocyclic group,
at least two of a plurality of R₅₀ are optionally bonded together to form a substituted or unsubstituted C₅-C₃₀ carbocyclic group or a substituted or unsubstituted C₁-C₃₀ heterocyclic group,
at least two of a plurality of R₆₀ are optionally bonded together to form a substituted or unsubstituted C₅-C₃₀ carbocyclic group or a substituted or unsubstituted C₁-C₃₀ heterocyclic group,
at least two of a plurality of R₇₀ are optionally bonded together to form a substituted or unsubstituted C₅-C₃₀ carbocyclic group or a substituted or unsubstituted C₁-C₃₀ heterocyclic group,
at least two of a plurality of R₈₀ are optionally bonded together to form a substituted or unsubstituted C₅-C₃₀ carbocyclic group or a substituted or unsubstituted C₁-C₃₀ heterocyclic group, and
two or more of adjacent R₁ to R₄, R₁₀, R₂₀, R₃₀, R₄₀, R₅₀, R₆₀, R₇₀, and R₈₀ are optionally bonded together to form a substituted or unsubstituted C₅-C₃₀ carbocyclic group or a substituted or unsubstituted C₁-C₃₀ heterocyclic group.

According to one or more embodiments, at least two of a plurality of R₁₀; at least two of a plurality of R₂₀; at least two of a plurality of R₃₀; at least two of a plurality of R₄₀; at least two of a plurality of R₅₀; at least two of a plurality of R₆₀; at least two of a plurality of R₇₀; at least two of a plurality of R₈₀; and/or two or more of adjacent R₁ to R₄, R₁₀, R₂₀, R₃₀, R₄₀, R₅₀, R₆₀, R₇₀, and R₈₀ may optionally be bonded to each other via a single bond, a double bond, or a first linking group to form a C₅-C₃₀ carbocyclic group unsubstituted or substituted with at least one R₁₀ₐ or a C₁-C₃₀ heterocyclic group unsubstituted or substituted with at least one R₁₀ₐ (e.g., a fluorene group, a xanthene group, an acridine group, or the like, each unsubstituted or substituted with at least one R₁₀ₐ). R₁₀ₐ is the same as described herein in connection with R₁₀.

In one or more embodiments, non-limiting examples of the “C₅-C₃₀ carbocyclic group that is unsubstituted or substituted with at least one R₁₀ₐ or a C₁-C₃₀ heterocyclic group that is unsubstituted or substituted with at least one R₁₀ₐ” include a benzene group, a naphthalene group, a cyclopentane group, a cyclopentadiene group, a cyclohexane group, a cycloheptane group, a bicyclo[2.2.1]heptane group, a furan group, a thiophene group, a pyrrole group, a silole group, an indene group, a benzofuran group, a benzothiophene group, an indole group, or a benzosilole group, each unsubstituted or substituted with at least one R₁₀ₐ. R₁₀ₐ is the same as described herein in connection with R₁₀. The C₅-C₃₀ carbocyclic group and the C₁-C₃₀ heterocyclic group are each as described herein.

The first linking group may be *—N(R₈)—*′, *—B(R₈)—*′, *—P(R₈)—*′, *—C(R₈)(R₉)—*′, *—Si(R₈)(R₉)—*′, *—Ge(R₈)(R₉)—*′, *—S—*′, *—Se—*′, *—O—*′, *—C(═O)—*′, *—S(═O)—*′, *—S(═O)₂—*′, *—C(R₈)═*′, *═C(R₈)—*′, *—C(R₈)═C(R)—*′, *—C(═S)—*′, or *—C≡C—*′, wherein R₈ and R₉ are the same as described herein in connection with R₁₀, and each of * and *′ indicates a binding site to a neighboring atom.

In Formulae 1 and 2, Q₁ to Q₃, Q₁₁ to Q₁₃, Q₂₁ to Q₂₃, and Q₃₁ to Q₃₃ are each independently hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, or a substituted or unsubstituted monovalent non-aromatic condensed heteropolycyclic group

According to one or more embodiments, Q₁ to Q₃, Q₁₁ to Q₁₃, Q₂₁ to Q₂₃, and Q₃₁ to Q₃₃ may each independently be:
deuterium, —CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂;
an n-propyl group, an isopropyl group, an n-butyl group, an isobutyl group, a sec-butyl group, a tert-butyl group, an n-pentyl group, an isopentyl group, a sec-pentyl group, a tert-pentyl group, a phenyl group, or a naphthyl group; or
an n-propyl group, an isopropyl group, an n-butyl group, an isobutyl group, a sec-butyl group, a tert-butyl group, an n-pentyl group, an isopentyl group, a sec-pentyl group, a tert-pentyl group, a phenyl group, or a naphthyl group, each substituted with deuterium, a C₁-C₁₀ alkyl group, a phenyl group, or a combination thereof.

According to one or more embodiments, the heterocyclic compound represented by Formula 1 may be represented by Formula 11:

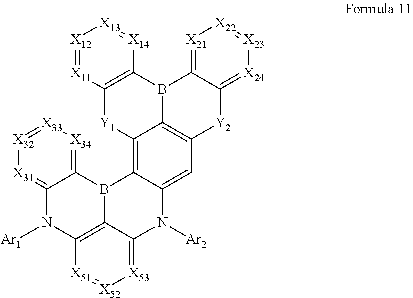

wherein, in Formula 11,
Y₁, Y₂, Ar₁, and Ar₂ are as described herein for Formula 1,
X₁₁ may be C(R₁₁) or N, X₁₂ may be C(R₁₂) or N, X₁₃ may be C(R₁₃) or N, and X₁₄ may be C(R₁₄) or N,
X₂₁ may be C(R₂₁) or N, X₂₂ may be C(R₂₂) or N, X₂₃ may be C(R₂₃) or N, and X₂₄ may be C(R₂₄) or N,
X₃₁ may be C(R₃₁) or N, X₃₂ may be C(R₃₂) or N, X₃₃ may be C(R₃₃) or N, and X₃₄ may be C(R₃₄) or N,
X₄₁ may be C(R₄₁) or N,
X₅₁ may be C(R₅₁) or N, X₅₂ may be C(R₅₂) or N, and X₅₃ may be C(R₅₃) or N,
R₁₁ to R₁₄ are each independently as described in connection with R₁₀,
R₂₁ to R₂₄ are each independently as described in connection with R₂₀,
R₃₁ to R₃₄ are each independently as described in connection with R₃₀,
R₄₁ is as described in connection with R₄₀, and
R₅₁ to R₅₃ are each independently as described in connection with R₅₀.

According to one or more embodiments, the heterocyclic compound represented by Formula 1 may be represented by Formula 21:

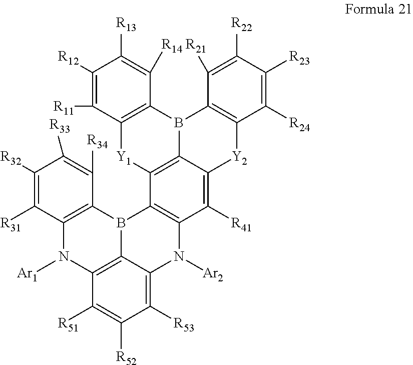

wherein, in Formula 21,
Y₁, Y₂, Ar₁, and Ar₂ are as described herein for Formula 1,
R₁₁ to R₁₄ are each independently as described in connection with R₁₀,
R₂₁ to R₂₄ are each independently as described in connection with R₂₀,
R₃₁ to R₃₄ are each independently as described in connection with R₃₀,
R₄₁ is as described in connection with R₄₀, and
R₅₁ to R₅₃ are each independently as described in connection with R₅₀.

According to one or more embodiments, the heterocyclic compound represented by Formula 1 may be represented by Formula 31:

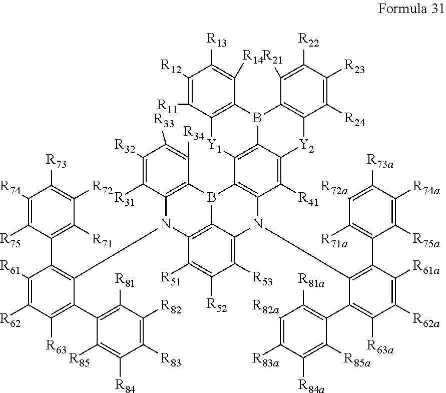

wherein, in Formula 31,
Y₁ and Y₂ are as described herein for Formula 1,
R₁₁ to R₁₄ are each independently as described in connection with R₁₀,
R₂₁ to R₂₄ are each independently as described in connection with R₂₀,
R₃₁ to R₃₄ are each independently as described in connection with R₃₀,
R₄₁ is as described in connection with R₄₀,
R₅₁ to R₅₃ are each independently as described in connection with R₅₀,
R₆₁ to R₆₃ and R₆₁ₐ to R₆₃ₐ are each independently as described in connection with R₆₀,
R₇₁ to R₇₅ and R₇₁ₐ to R₇₅ₐ are each independently as described in connection with R₇₀, and
R₈₁ to R₈₅ and R₈₁ₐ to R₈₅ₐ are each independently as described in connection with R₈₀.

According to one or more embodiments, in Formulae 11, 21, and 31, at least one of R₁₁ to R₁₄, R₂₁ to R₂₄, R₃₁ to R₃₄, R₄₁, or R₅₁ to R₅₃ may be —F, —Cl, —Br, —I, —SF₅, a cyano group, a substituted or unsubstituted C₁-C₆₀ alkyl group, a substituted or unsubstituted C₃-C₁₀ cycloalkyl group, a substituted or unsubstituted C₆-C₆₀ aryl group, a substituted or unsubstituted C₁-C₆₀ heteroaryl group, a substituted or unsubstituted monovalent non-aromatic condensed polycyclic group, or a substituted or unsubstituted monovalent non-aromatic condensed heteropolycyclic group.

According to one or more embodiments, in Formulae 11, 21, and 31, at least one of R₁₁ to R₁₄, R₂₁ to R₂₄, R₃₁ to R₃₄, R₄₁, or R₅₁ to R₅₃ may be a substituted or unsubstituted C₁-C₆₀ alkyl group, a substituted or unsubstituted C₃-C₁₀ cycloalkyl group, a substituted or unsubstituted C₆-C₆₀ aryl group, a substituted or unsubstituted C₁-C₆₀ heteroaryl group, a substituted or unsubstituted monovalent non-aromatic condensed polycyclic group, or a substituted or unsubstituted monovalent non-aromatic condensed heteropolycyclic group.

According to one or more embodiments, in Formulae 11, 21, and 31, at least one of R₁₁ to R₁₄ (e.g., R₁₃), at least one of R₂₁ to R₂₄ (e.g., R₂₂), at least one of R₃₁ to R₃₄ (e.g., R₃₃), R₄₁, and/or at least one of R₅₁ to R₅₃ (e.g., R₅₂) may be a substituted or unsubstituted C₁-C₆₀ alkyl group, substituted or unsubstituted C₃-C₁₀ cycloalkyl group, a substituted or unsubstituted C₆-C₆₀ aryl group, a substituted or unsubstituted C₁-C₆₀ heteroaryl group, a substituted or unsubstituted monovalent non-aromatic condensed polycyclic group, or a substituted or unsubstituted monovalent non-aromatic condensed heteropolycyclic group. Specific examples of these substituted or unsubstituted groups may be as specifically defined herein for R₁ to R₄, R₁₀, R₂₀, R₃₀, R₄₀, R₅₀, R₆₀, R₇₀, and R₈₀ in Formula 1, for example, may refer to the corresponding groups in claim 6, or may be a group represented by one of Formulae 9-1 to 9-61, 9-201 to 9-244, 10-1 to 10-154, or 10-201 to 10-350.

According to one or more embodiments, in Formulae 11, 21, and 31, at least one of R₁₁ to R₁₄ (e.g., R₁₃), at least one of R₂₁ to R₂₄ (e.g., R₂₂), and/or at least one of R₅₁ to R₅₃ (e.g., R₅₂) may be a substituted or unsubstituted C₁-C₆₀ alkyl group. In Formulae 11, 21, and 31, at least one of R₃₁ to R₃₄ (e.g., R₃₃) may be a substituted or unsubstituted C₁-C₆₀ alkyl group, or a substituted or unsubstituted C₆-C₆₀ aryl group. Specific examples of the substituted or unsubstituted C₁-C₆₀ alkyl group and the substituted or unsubstituted C₆-C₆₀ aryl group may be as specifically defined herein for R₁ to R₄, R₁₀, R₂₀, R₃₀, R₄₀, R₅₀, R₆₀, R₇₀, and R₈₀ in Formula 1, for example, may refer to the corresponding groups in claim 6, or may be the corresponding groups among the groups represented by Formulae 9-1 to 9-61, 9-201 to 9-244, 10-1 to 10-154, and 10-201 to 10-350.

According to one or more embodiments, in Formulae 11, 21, and 31, at least one of R₁₁ to R₁₄, R₂₁ to R₂₄, R₃₁ to R₃₄, R₄₁, or R₅₁ to R₅₃ may be —F, —Cl, —Br, —I, —SF₅, a cyano group, a methyl group, an ethyl group, a n-propyl group, an isopropyl group, an n-butyl group, an isobutyl group, a sec-butyl group, a tert-butyl group, an n-pentyl group, an isopentyl group, a 2-methylbutyl group, a sec-pentyl group, a tert-pentyl group, a neo-pentyl group, a 3-pentyl group, a 3-methyl-2-butyl group, a phenyl group, a biphenyl group, a C₁-C₂₀ alkylphenyl group, or a naphthyl group.

According to one or more embodiments, in Formula 31, at least one of R₆₁ to R₆₃, R₇₁ to R₇₅, and R₈₁ to R₈₅, and/or at least one of R₆₁ₐ to R₆₃ₐ, and R₇₁ₐ to R₇₅ₐ, and R₈₁ₐ to Rasa, may be a substituted or unsubstituted C₁-C₆₀ alkyl group. For example, at least one of R₆₁ to R₆₃ (e.g., R₆₂), and/or at least one of R₆₁ₐ to R₆₃ₐ (e.g., R₆₂ₐ) may be a substituted or unsubstituted C₁-C₆₀ alkyl group. Specific examples of the substituted or unsubstituted C₁-C₆₀ alkyl group may be as specifically defined herein for R₁ to R₄, R₁₀, R₂₀, R₃₀, R₄₀, R₅₀, R₆₀, R₇₀, and R₈₀ in Formula 1, for example, may refer to the corresponding groups in claim 6, or may be a group represented by one of Formulae 9-1 to 9-39 and 9-44 to 9-61.

At least one substituent of the substituted C₅-C₃₀ carbocyclic group, the substituted C₁-C₃₀ heterocyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₁-C₆₀ alkylthio group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₇-C₆₀ alkyl aryl group, the substituted C₇-C₆₀ aryl alkyl group, the substituted C₆-C₆₀ aryloxy group, the substituted C₆-C₆₀ arylthio group, the substituted C₁-C₆₀ heteroaryl group, the substituted C₂-C₆₀ alkyl heteroaryl group, the substituted C₂-C₆₀ heteroaryl alkyl group, the substituted C₁-C₆₀ heteroaryloxy group, the substituted C₁-C₆₀ heteroarylthio group, the substituted monovalent non-aromatic condensed polycyclic group, and the substituted monovalent non-aromatic condensed heteropolycyclic group is:
deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, or a C₁-C₆₀ alkylthio group;
a C₁-C₆₀ alkyl group, a C₂-C₆₀ alkenyl group, a C₂-C₆₀ alkynyl group, a C₁-C₆₀ alkoxy group, or a C₁-C₆₀ alkylthio group, each substituted with deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₁₁)(Q₁₂), —Si(Q₁₁)(Q₁₂)(Q₁₃), —Ge(Q₁₁)(Q₁₂)(Q₁₃), —C(═O)(Q₁₁), —S(═O)(Q₁₁), —S(═O)₂(Q₁₁), —B(Q₁₁)(Q₁₂), —P(Q₁₁)(Q₁₂), —P(═O)(Q₁₁)(Q₁₂), —P(═S)(Q₁₁)(Q₁₂), or a combination thereof;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, or a monovalent non-aromatic condensed heteropolycyclic group, each unsubstituted or substituted with deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₇-C₆₀ aryl alkyl group, a C₆-C₆₀ aryloxy group, a C₆-C₆₀ arylthio group, a C₁-C₆₀ heteroaryl group, a C₂-C₆₀ alkyl heteroaryl group, a C₂-C₆₀ heteroaryl alkyl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₂₁)(Q₂₂), —Si(Q₂₁)(Q₂₂)(Q₂₃), —Ge(Q₂₁)(Q₂₂)(Q₂₃), —C(═O)(Q₂₁), —S(═O)(Q₂₁), —S(═O)₂(Q₂₁), —B(Q₂₁)(Q₂₂), —P(Q₂₁)(Q₂₂), —P(═O)(Q₂₁)(Q₂₂), —P(═S)(Q₂₁)(Q₂₂), or a combination thereof;
—N(Q₃₁)(Q₃₂), —Si(Q₃₁)(Q₃₂)(Q₃₃), —Ge(Q₃₁)(Q₃₂)(Q₃₃), —C(═O)(Q₃₁), —S(═O)(Q₃₁), —S(═O)₂(Q₃₁), —B(Q₃₁)(Q₃₂), —P(Q₃₁)(Q₃₂), —P(═O)(Q₃₁)(Q₃₂), or —P(═S)(Q₃₁)(Q₃₂); or
a combination thereof.

In some embodiments, Q₁ to Q₃, Q₁₁ to Q₁₃, Q₂₁ to Q₂₃ and Q₃₁ to Q₃₃ may each independently be hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₇-C₆₀ aryl alkyl group, a C₆-C₆₀ aryloxy group, a C₆-C₆₀ arylthio group, a C₁-C₆₀ heteroaryl group, a C₂-C₆₀ alkyl heteroaryl group, a C₂-C₆₀ heteroaryl alkyl group, a C₁-C₆₀ heteroaryloxy group, a C₁-C₆₀ heteroarylthio group, a monovalent non-aromatic condensed polycyclic group, or a monovalent non-aromatic condensed heteropolycyclic group; or
a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, or a monovalent non-aromatic condensed heteropolycyclic group, each substituted with deuterium, —F, —Cl, —Br, —I, —SF₅, a hydroxyl group, a cyano group, a C₁-C₆₀ alkyl group, a C₆-C₆₀ aryl group, a C₁-C₆₀ heteroaryl group, a monovalent non-aromatic condensed heteropolycyclic group, a monovalent non-aromatic condensed heteropolycyclic group, or a combination thereof.

For example, Q₁ to Q₃, Q₁₁ to Q₁₃, Q₂₁ to Q₂₃ and Q₃₁ to Q₃₃ may each independently be:
—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; or
an n-propyl group, an isopropyl group, an n-butyl group, a sec-butyl group, an isobutyl group, a tert-butyl group, an n-pentyl group, a tert-pentyl group, an neopentyl group, an isopentyl group, a sec-pentyl group, a 3-pentyl group, a sec-isopentyl group, a phenyl group, a biphenyl group, or a naphthyl group, each unsubstituted or substituted with deuterium, a C₁-C₁₀ alkyl group, a phenyl group, or a combination thereof.

According to one or more embodiments, the heterocyclic compound represented by Formula 1 may be at least one of compounds 1 to 1705:

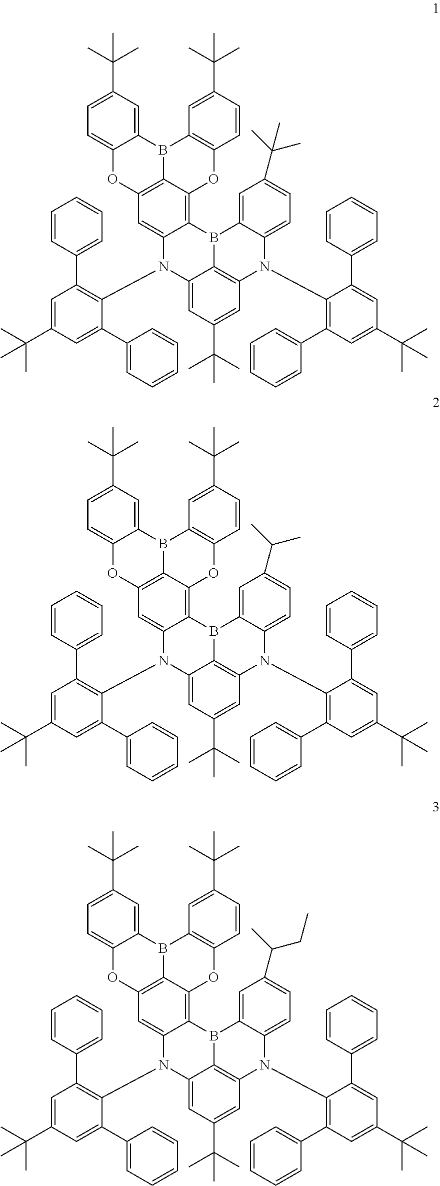

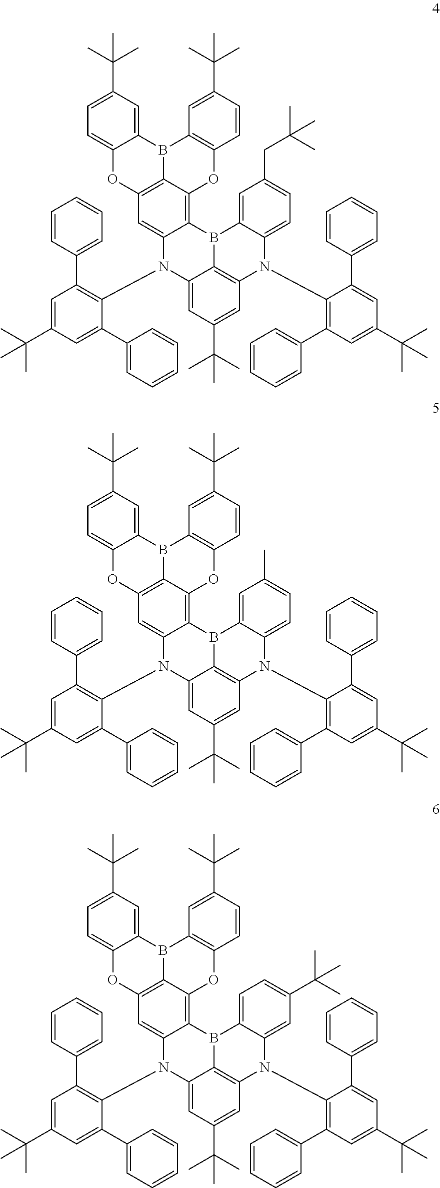

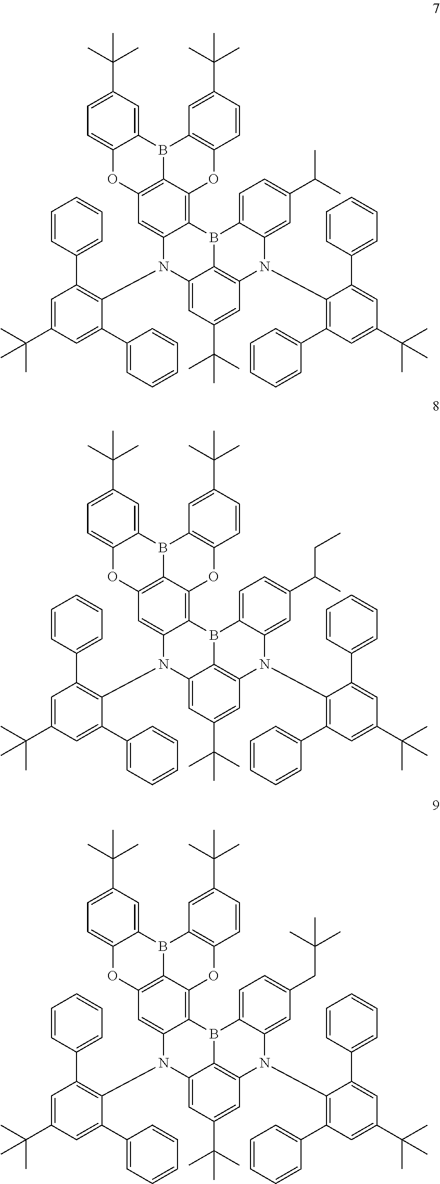

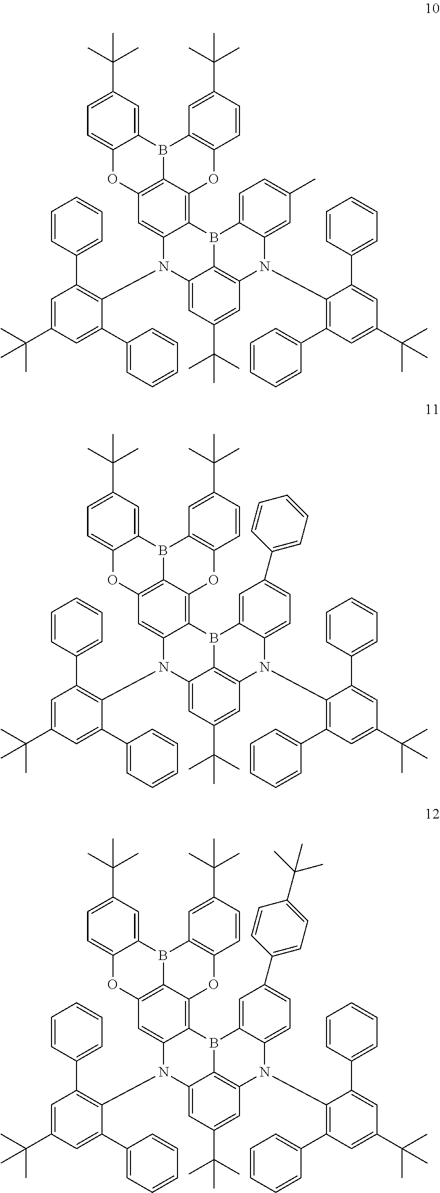

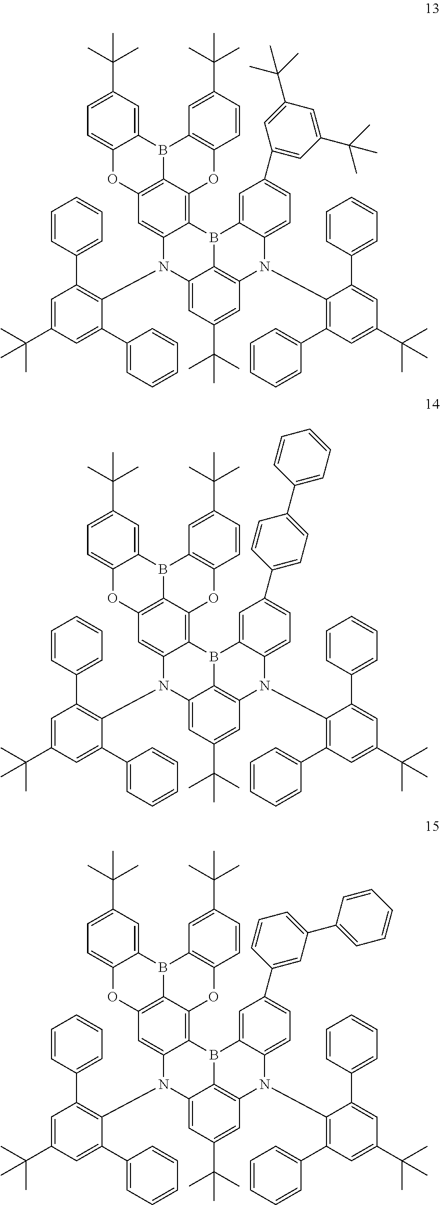

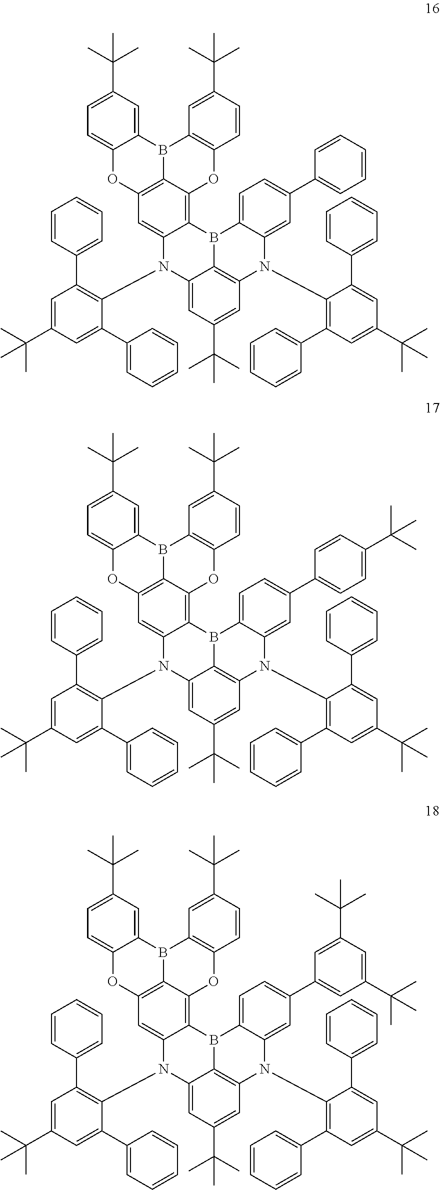

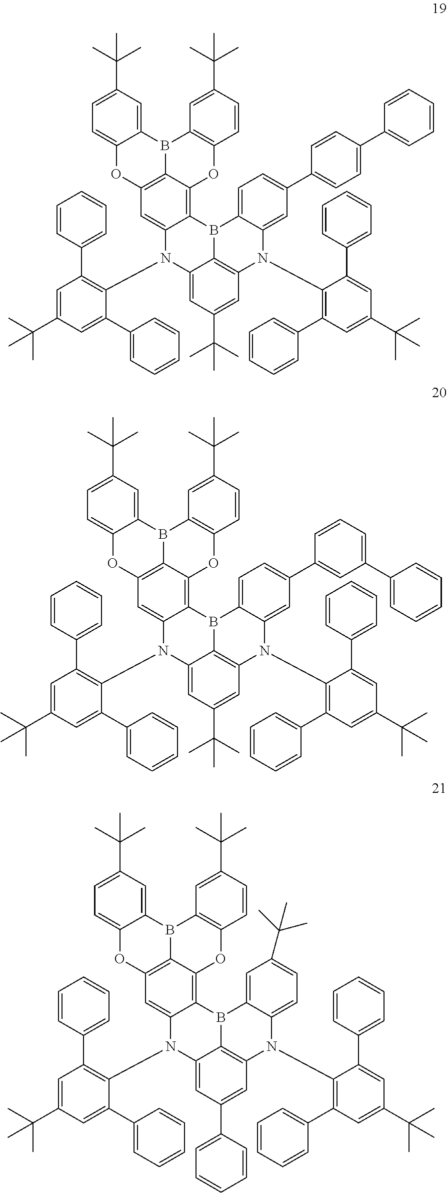

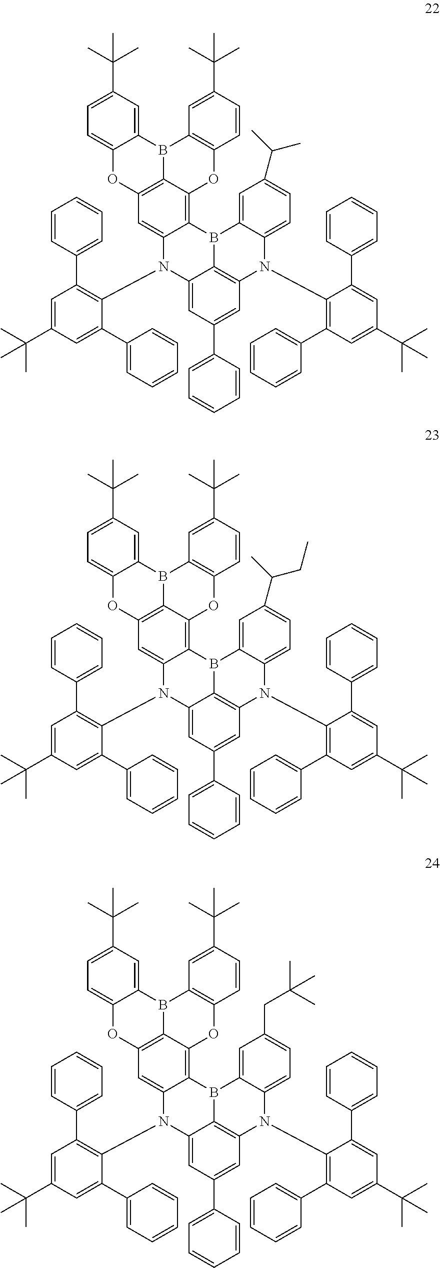

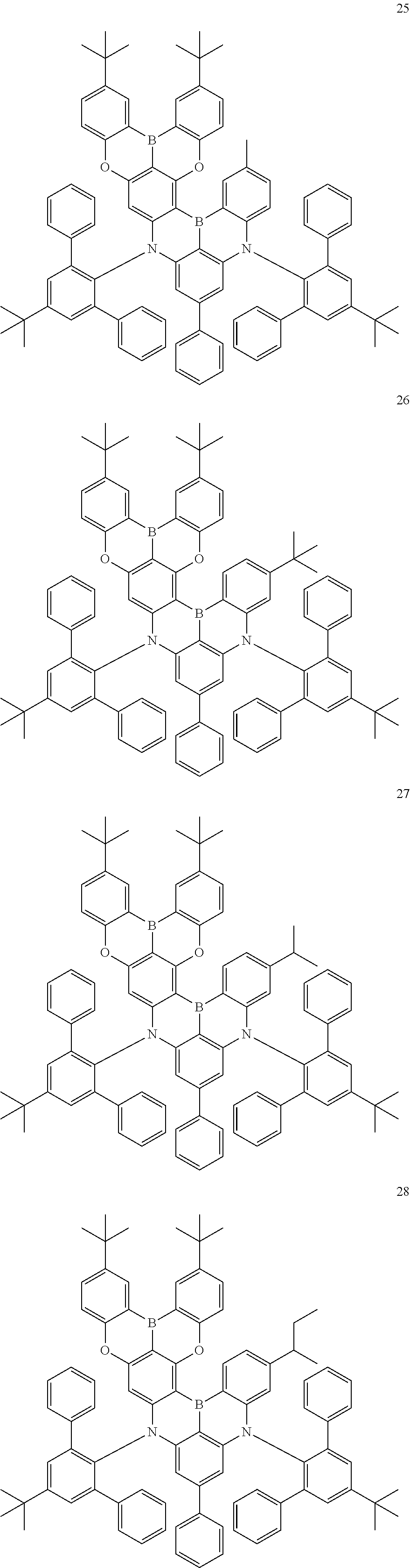

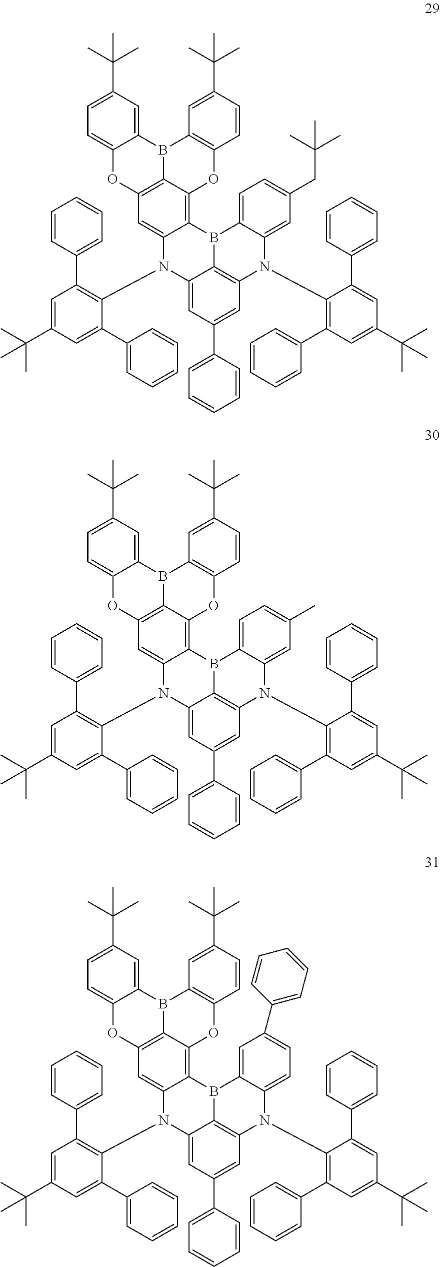

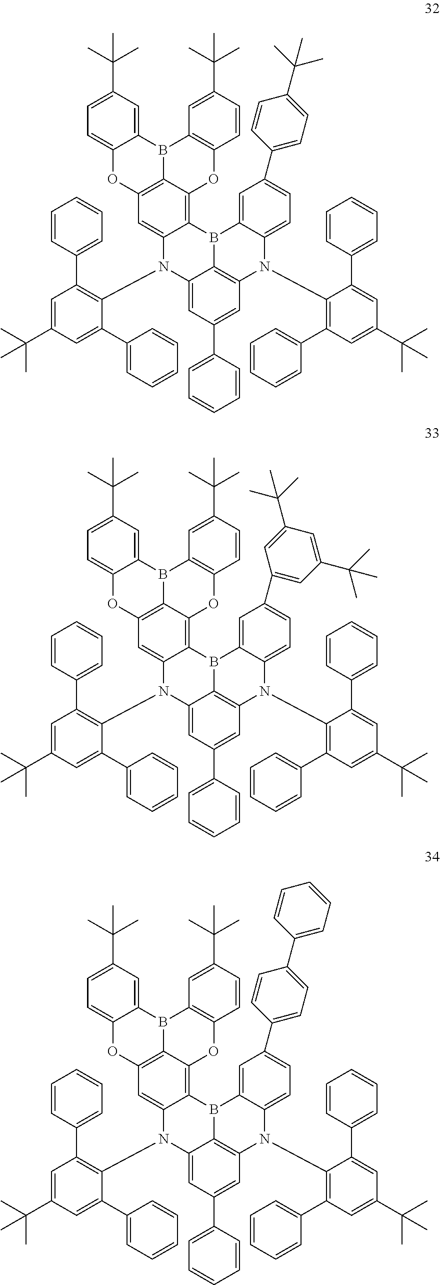

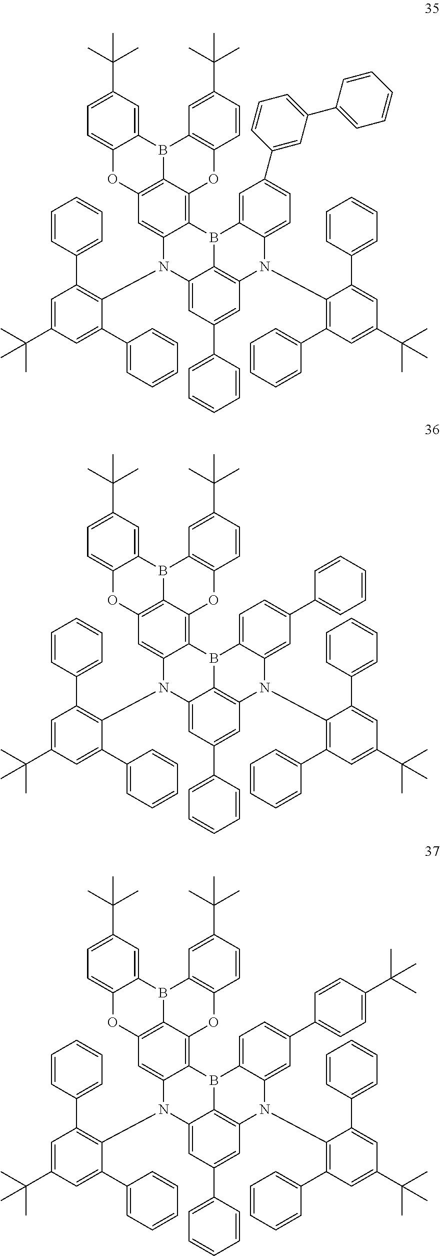

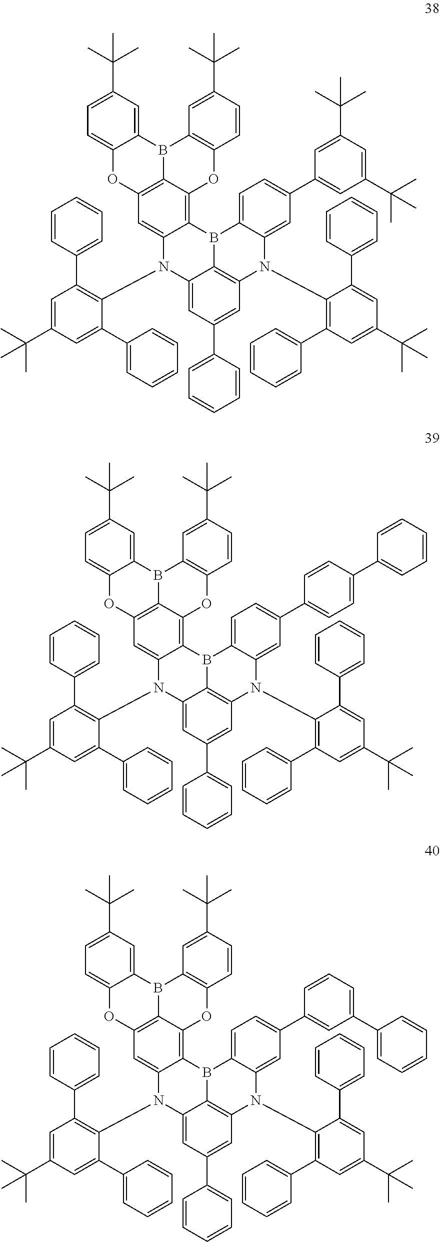

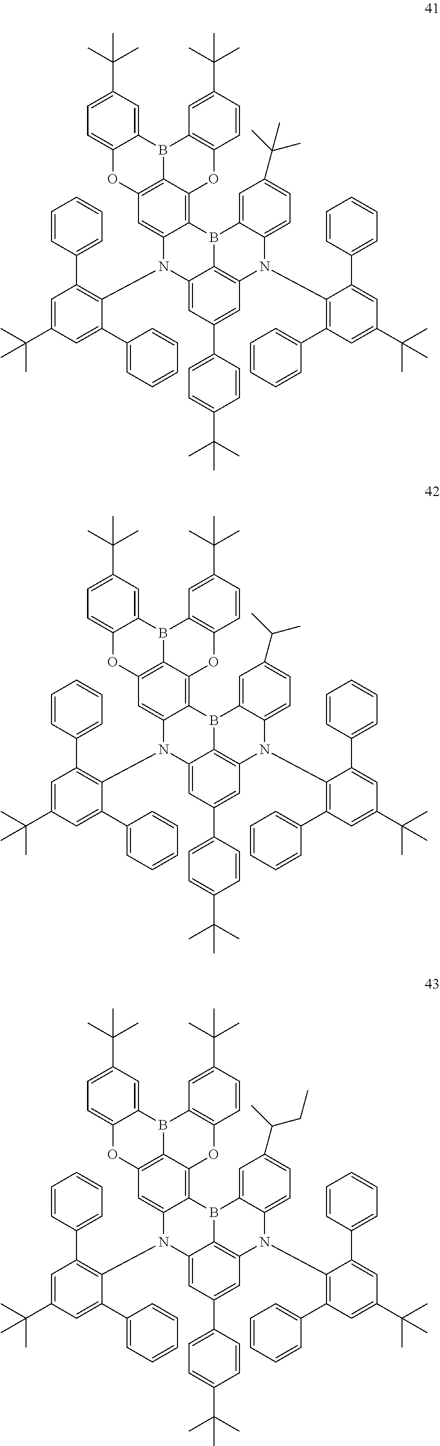

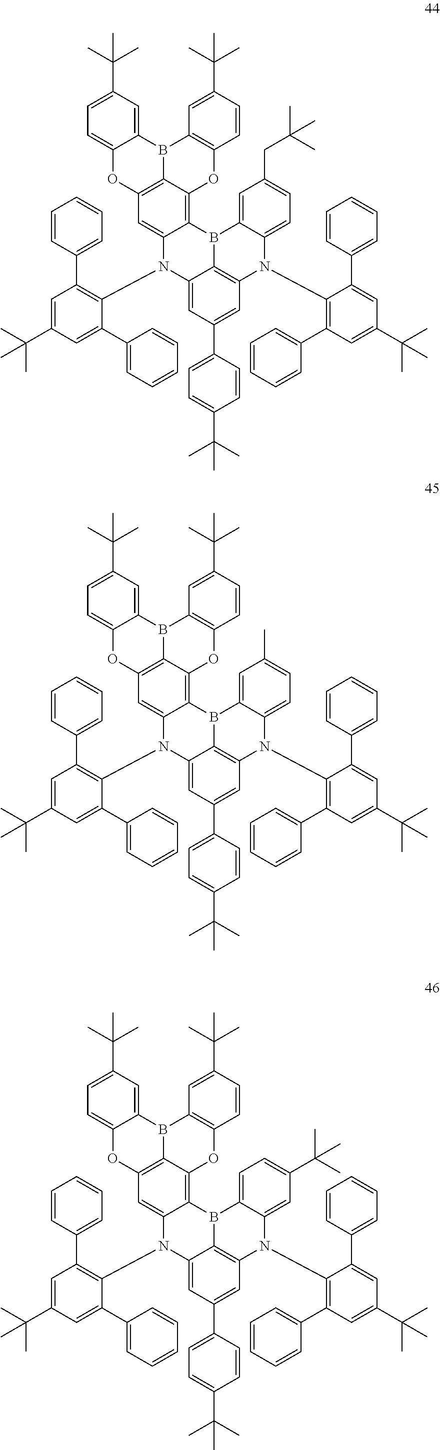

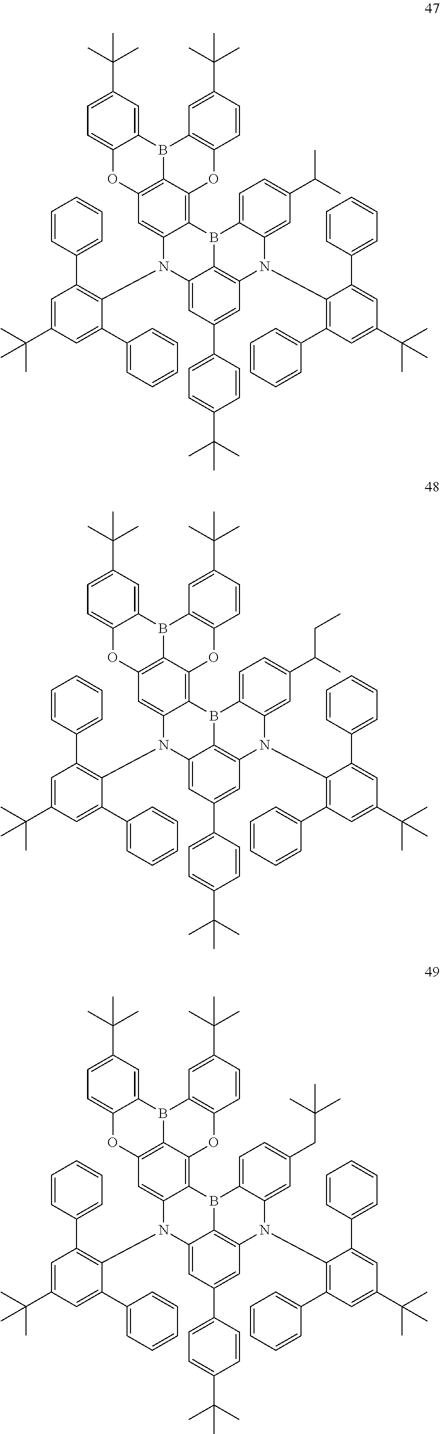

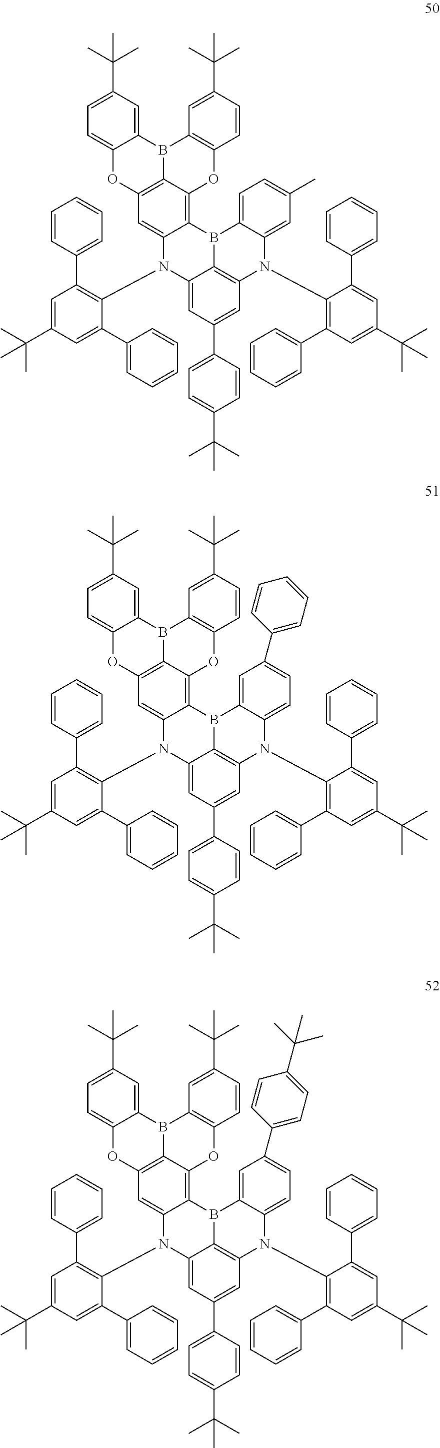

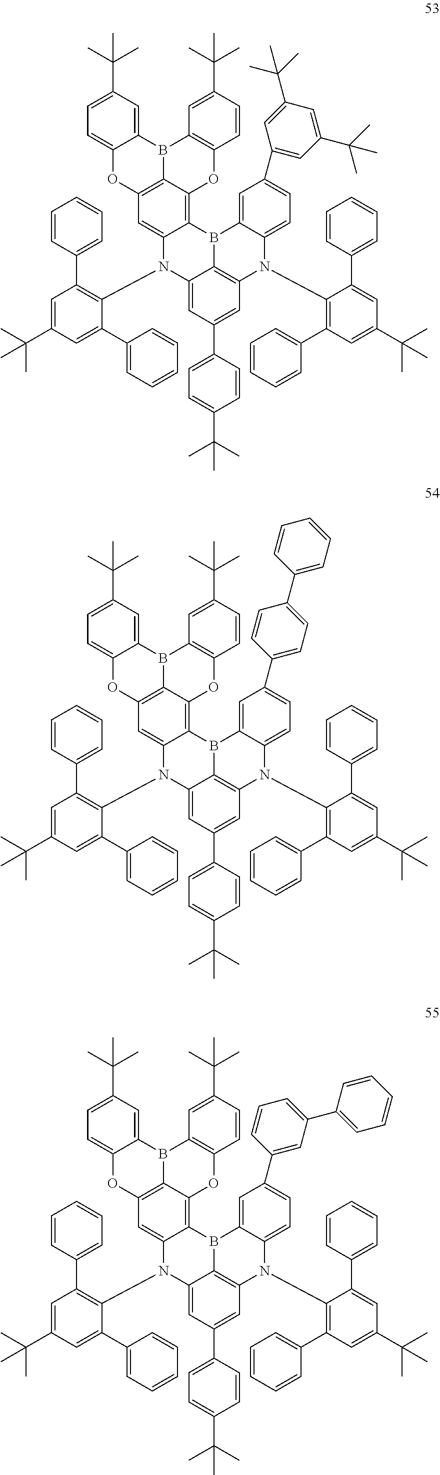

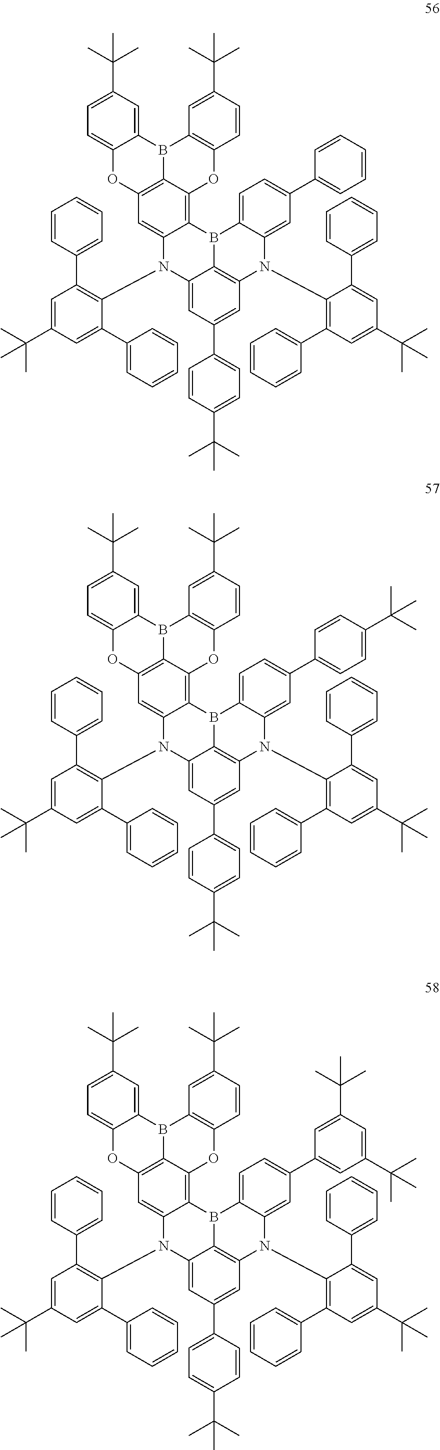

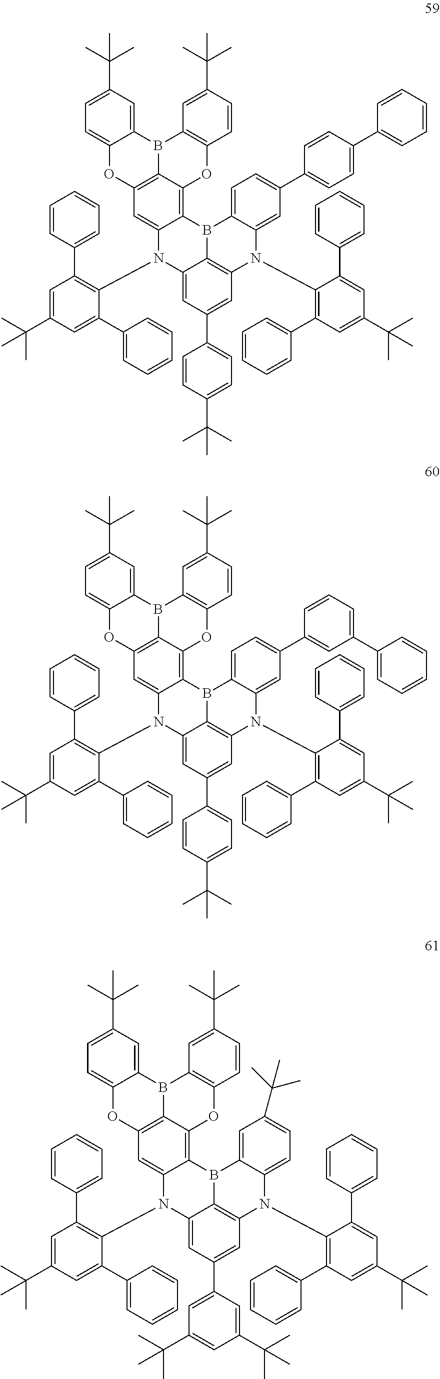

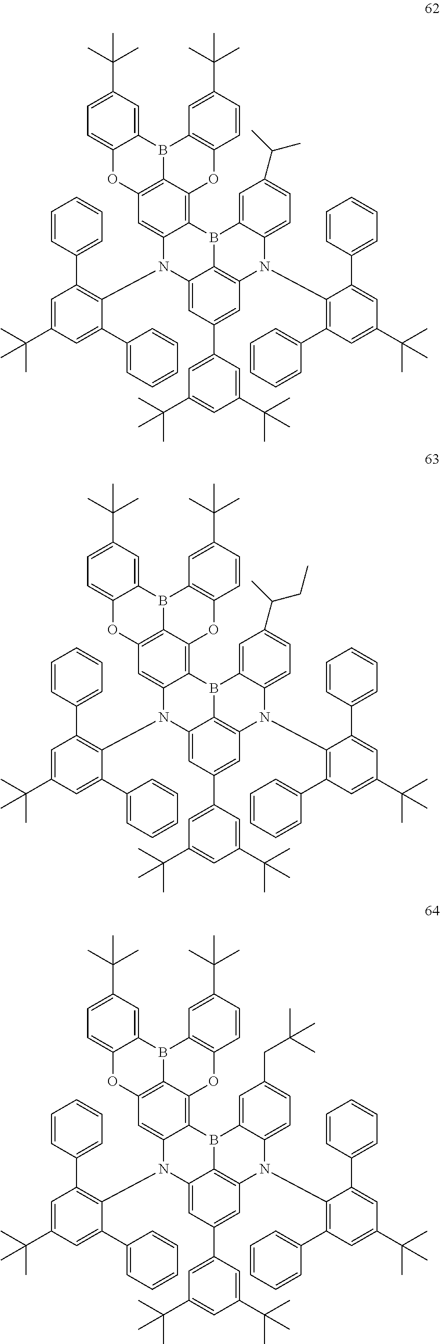

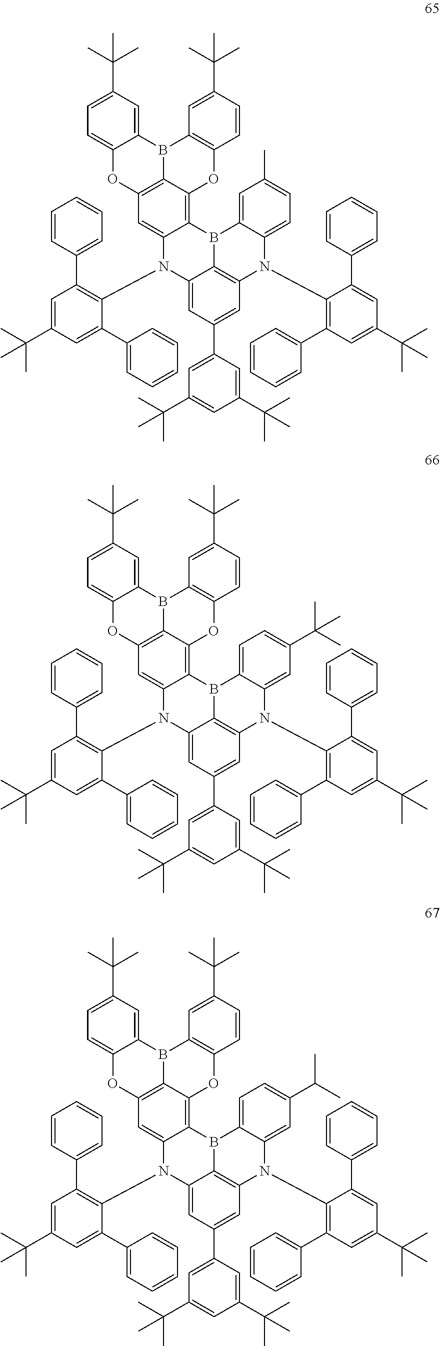

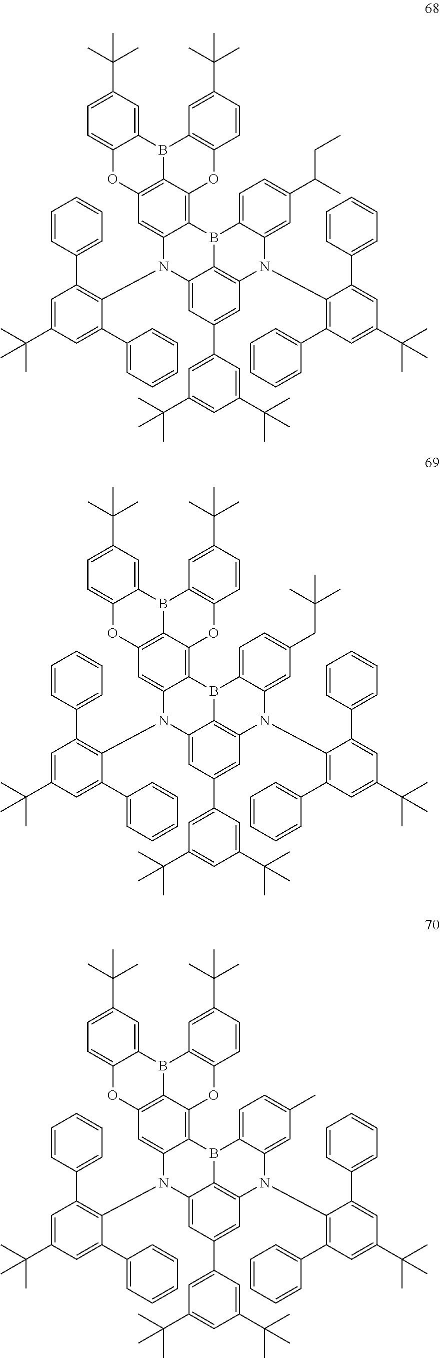

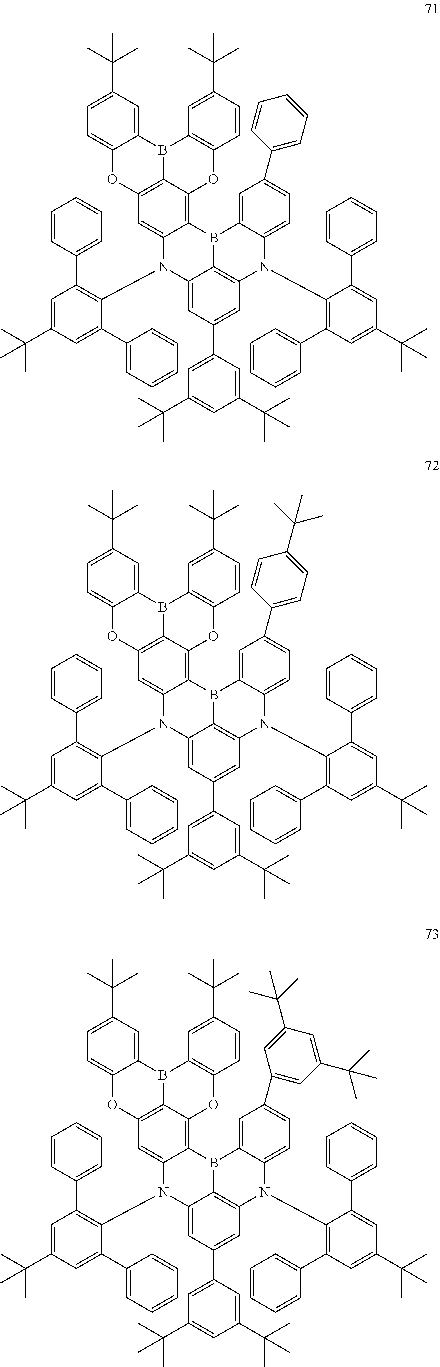

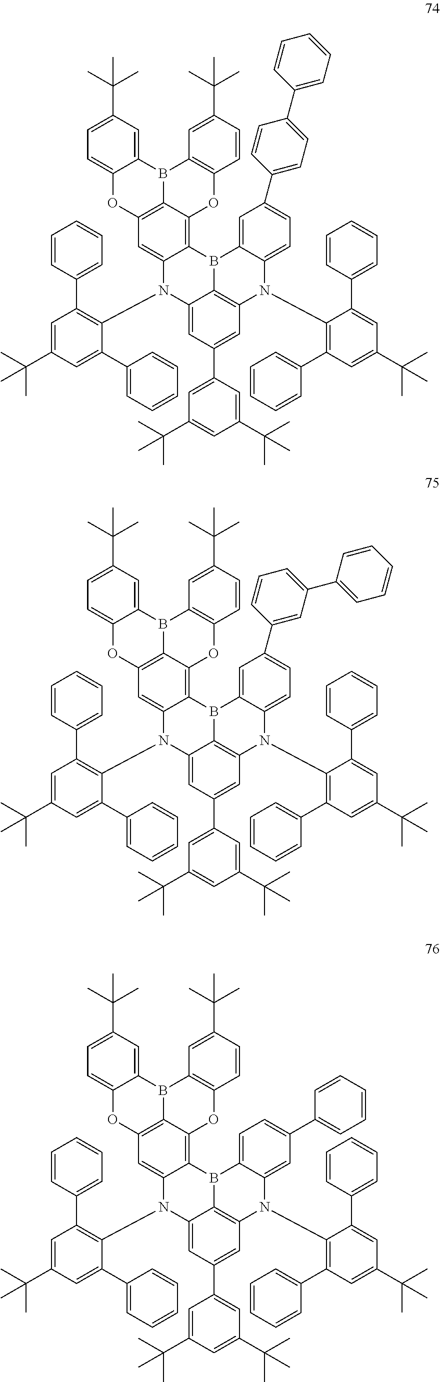

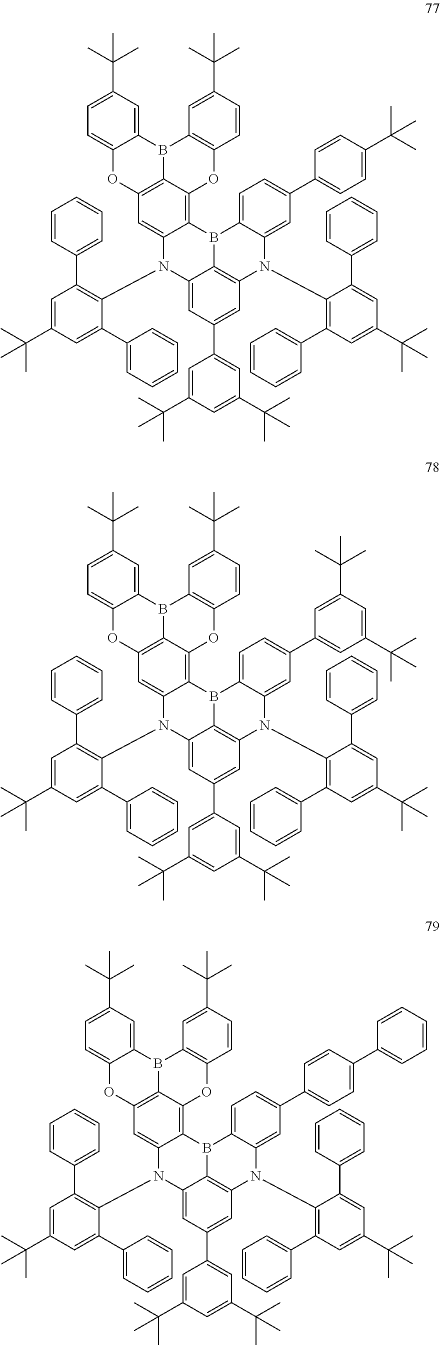

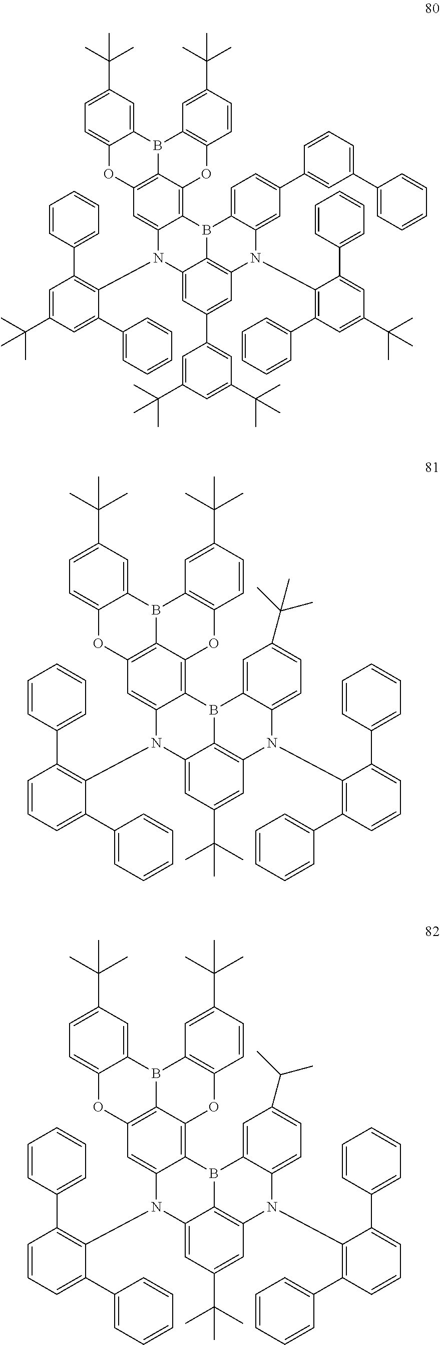

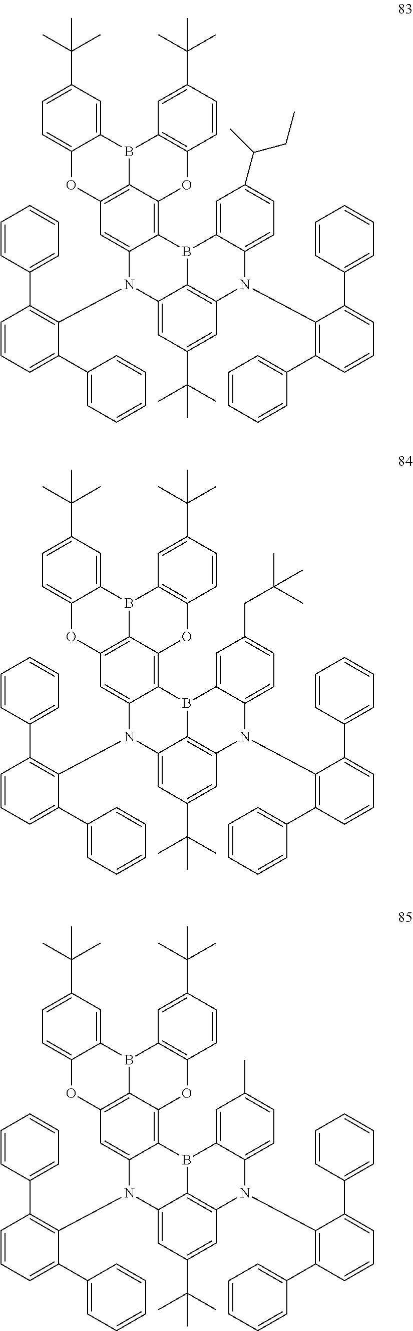 [SMILES: CCC(C)c1ccc2c(c1)B1c3c(cc(C(C)(C)C)cc3N(c3c(-c4ccccc4)cccc3-c3ccccc3)c3cc4c5c(c31)Oc1ccc(C(C)(C)C)cc1B5c1cc(C(C)(C)C)ccc1O4)N2c1c(-c2ccccc2)cccc1-c1ccccc1 ; CC(C)(C)Cc1ccc2c(c1)B1c3c(cc(C(C)(C)C)cc3N(c3c(-c4ccccc4)cccc3-c3ccccc3)c3cc4c5c(c31)Oc1ccc(C(C)(C)C)cc1B5c1cc(C(C)(C)C)ccc1O4)N2c1c(-c2ccccc2)cccc1-c1ccccc1 ; Cc1ccc2c(c1)B1c3c(cc(C(C)(C)C)cc3N(c3c(-c4ccccc4)cccc3-c3ccccc3)c3cc4c5c(c31)Oc1ccc(C(C)(C)C)cc1B5c1cc(C(C)(C)C)ccc1O4)N2c1c(-c2ccccc2)cccc1-c1ccccc1]

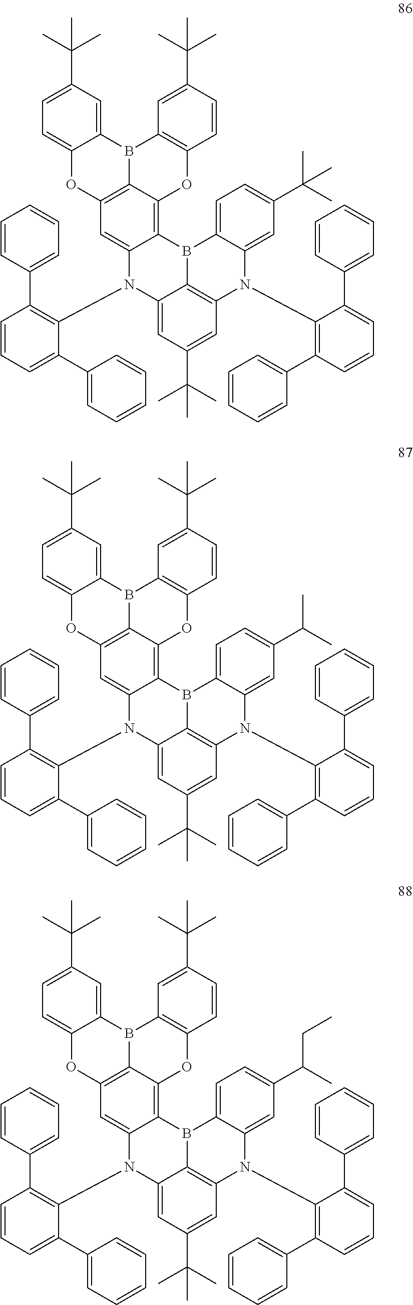

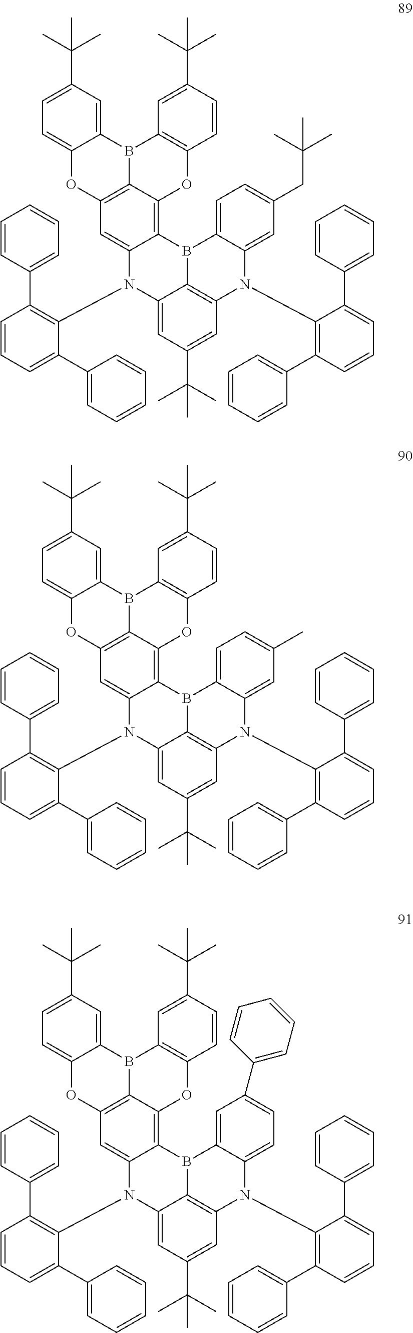 [SMILES: CC(C)(C)Cc1ccc2c(c1)N(c1c(-c3ccccc3)cccc1-c1ccccc1)c1cc(C(C)(C)C)cc3c1B2c1c(cc2c4c1Oc1ccc(C(C)(C)C)cc1B4c1cc(C(C)(C)C)ccc1O2)N3c1c(-c2ccccc2)cccc1-c1ccccc1 ; Cc1ccc2c(c1)N(c1c(-c3ccccc3)cccc1-c1ccccc1)c1cc(C(C)(C)C)cc3c1B2c1c(cc2c4c1Oc1ccc(C(C)(C)C)cc1B4c1cc(C(C)(C)C)ccc1O2)N3c1c(-c2ccccc2)cccc1-c1ccccc1 ; CC(C)(C)c1ccc2c(c1)B1c3cc(C(C)(C)C)ccc3Oc3c1c(cc1c3B3c4cc(-c5ccccc5)ccc4N(c4c(-c5ccccc5)cccc4-c4ccccc4)c4cc(C(C)(C)C)cc(c43)N1c1c(-c3ccccc3)cccc1-c1ccccc1)O2]

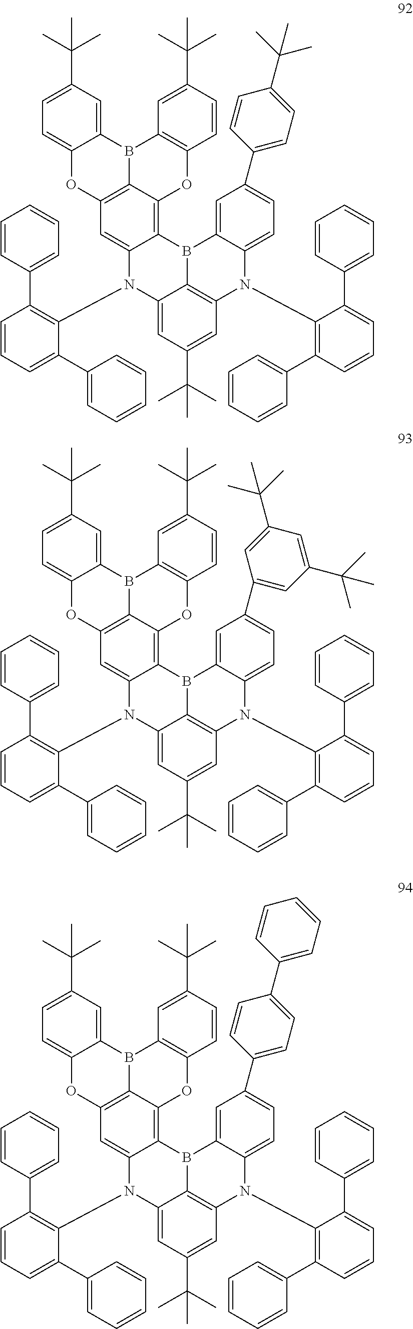

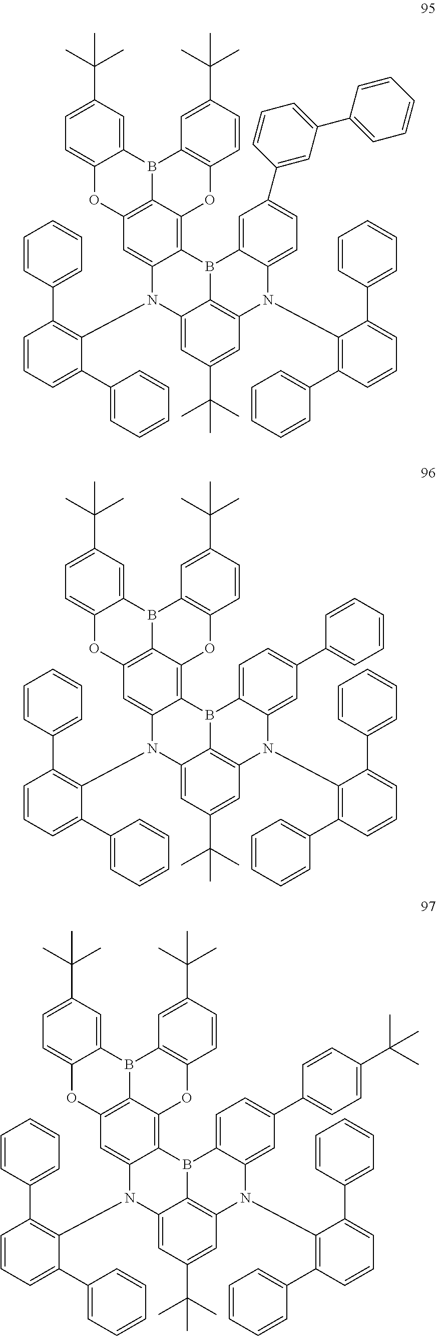 [SMILES: CC(C)(C)c1ccc2c(c1)B1c3cc(C(C)(C)C)ccc3Oc3c1c(cc1c3B3c4cc(-c5cccc(-c6ccccc6)c5)ccc4N(c4c(-c5ccccc5)cccc4-c4ccccc4)c4cc(C(C)(C)C)cc(c43)N1c1c(-c3ccccc3)cccc1-c1ccccc1)O2 ; CC(C)(C)c1ccc2c(c1)B1c3cc(C(C)(C)C)ccc3Oc3c1c(cc1c3B3c4ccc(-c5ccccc5)cc4N(c4c(-c5ccccc5)cccc4-c4ccccc4)c4cc(C(C)(C)C)cc(c43)N1c1c(-c3ccccc3)cccc1-c1ccccc1)O2 ; CC(C)(C)c1ccc(-c2ccc3c(c2)N(c2c(-c4ccccc4)cccc2-c2ccccc2)c2cc(C(C)(C)C)cc4c2B3c2c(cc3c5c2Oc2ccc(C(C)(C)C)cc2B5c2cc(C(C)(C)C)ccc2O3)N4c2c(-c3ccccc3)cccc2-c2ccccc2)cc1]

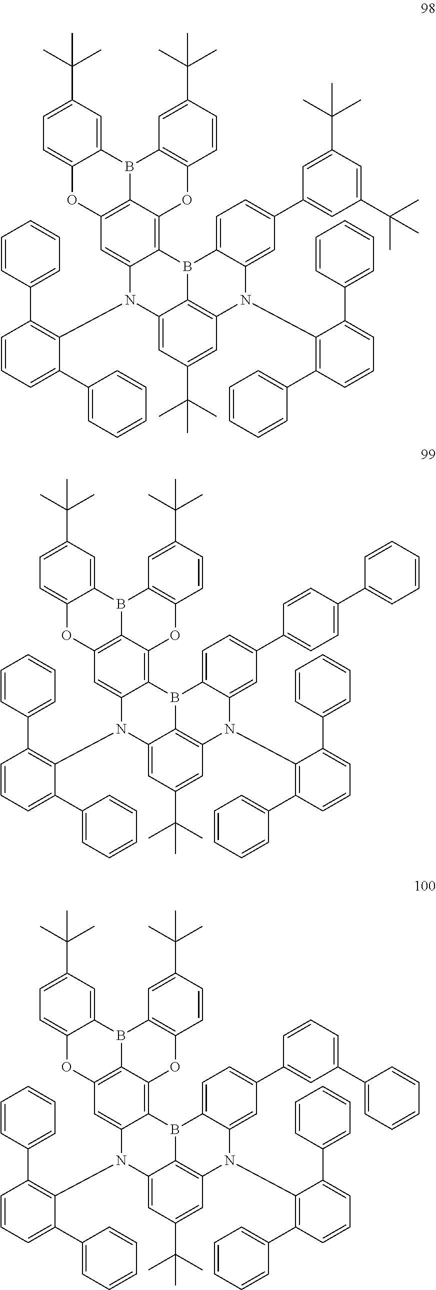

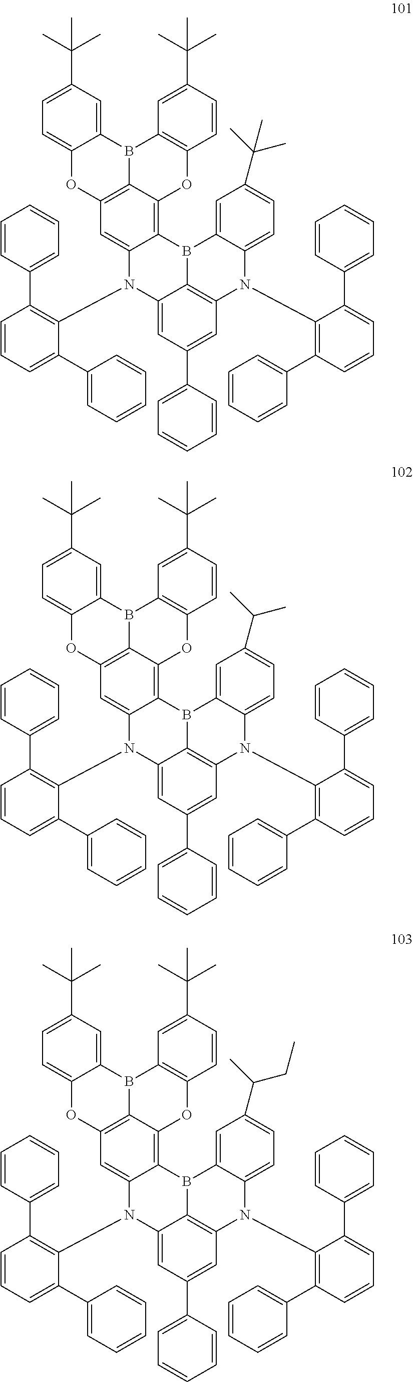

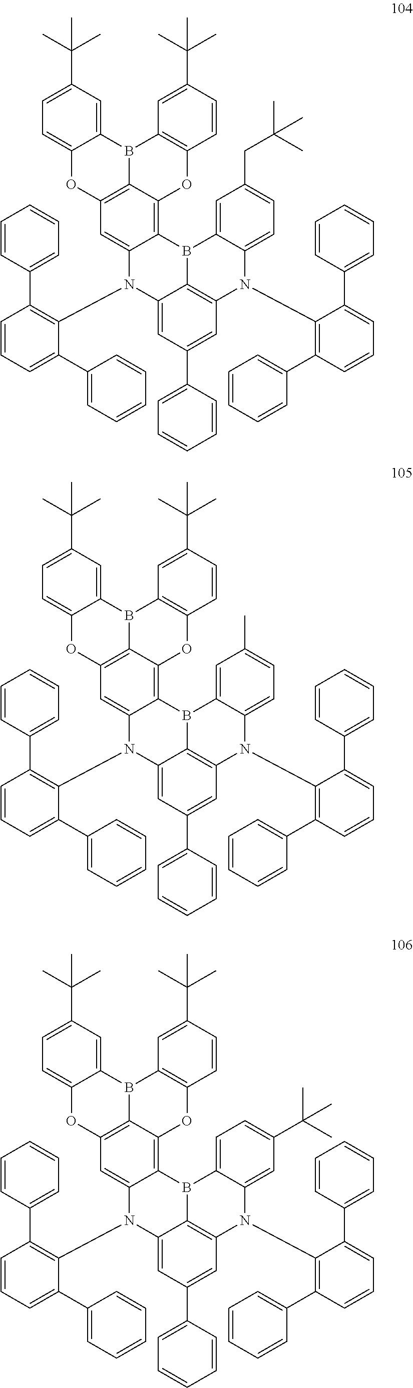

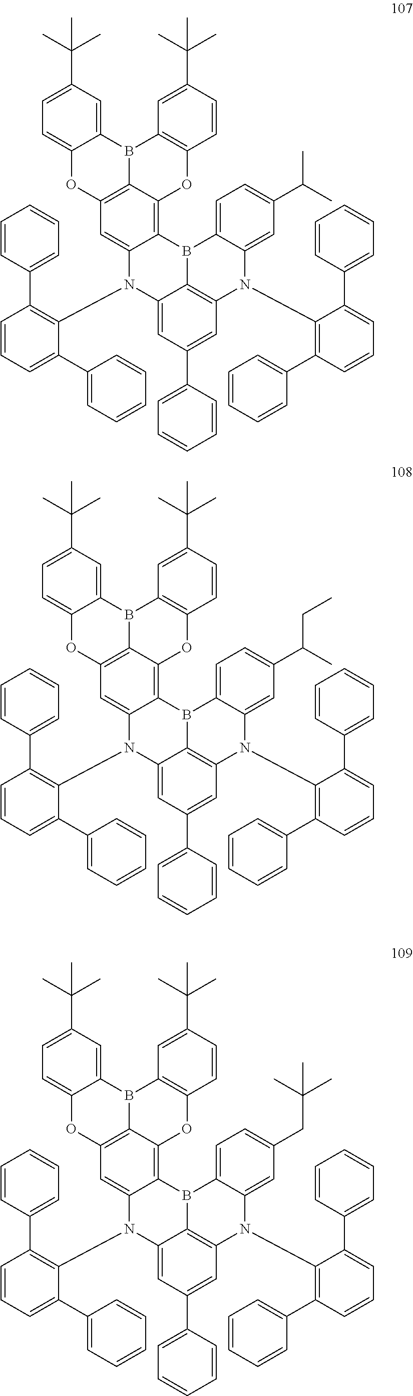

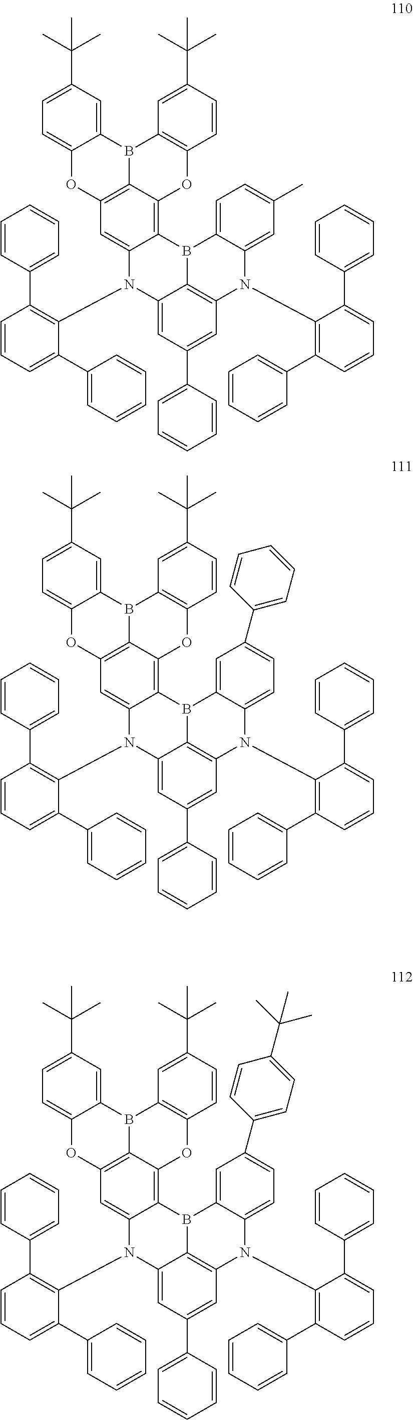

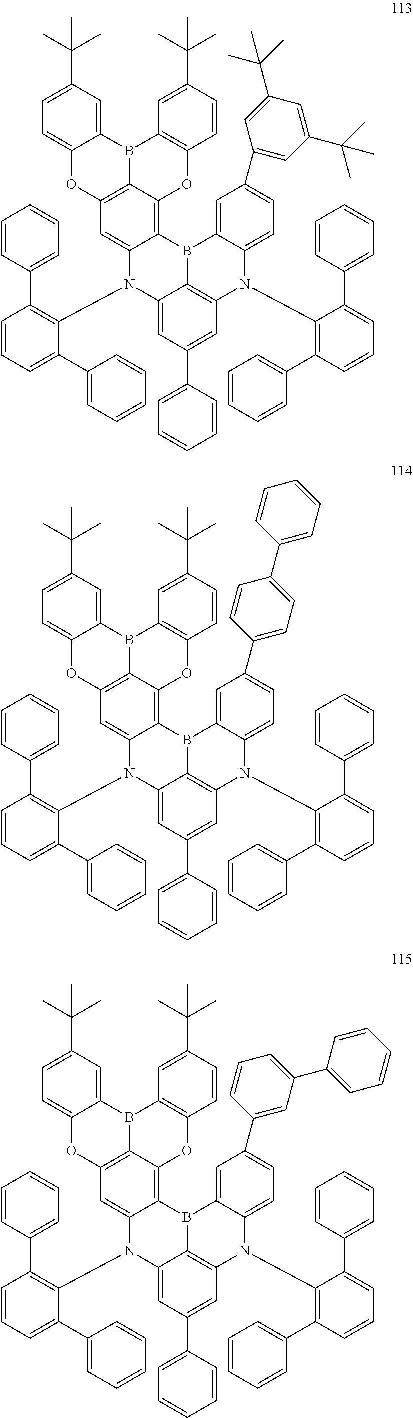

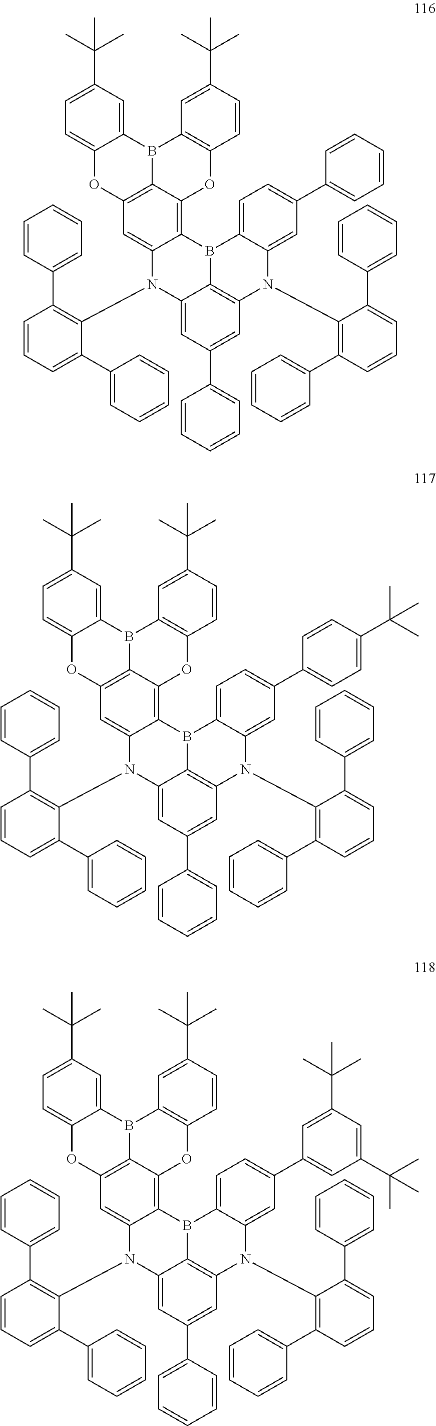

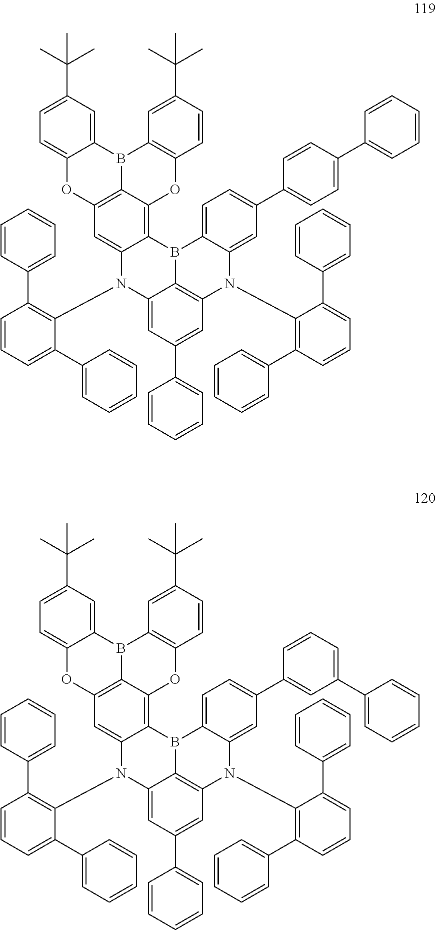 [SMILES: CC(C)(C)c1ccc2c(c1)B1c3cc(C(C)(C)C)ccc3Oc3c1c(cc1c3B3c4ccc(-c5ccc(-c6ccccc6)cc5)cc4N(c4c(-c5ccccc5)cccc4-c4ccccc4)c4cc(-c5ccccc5)cc(c43)N1c1c(-c3ccccc3)cccc1-c1ccccc1)O2 ; CC(C)(C)c1ccc2c(c1)B1c3cc(C(C)(C)C)ccc3Oc3c1c(cc1c3B3c4ccc(-c5cccc(-c6ccccc6)c5)cc4N(c4c(-c5ccccc5)cccc4-c4ccccc4)c4cc(-c5ccccc5)cc(c43)N1c1c(-c3ccccc3)cccc1-c1ccccc1)O2]

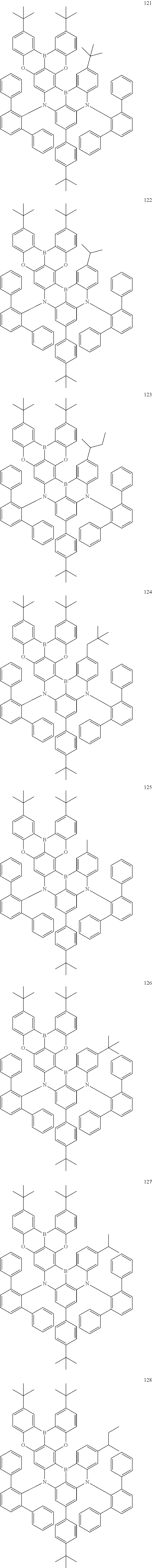

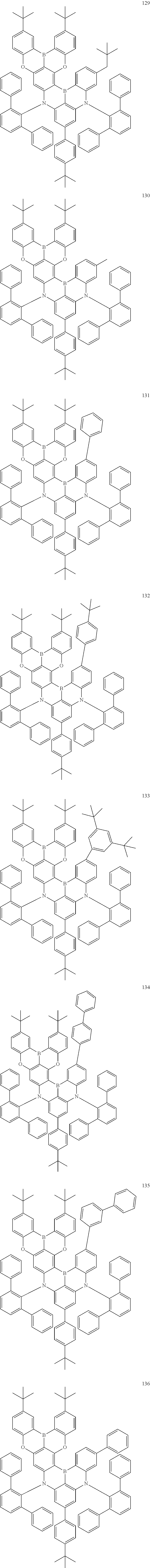

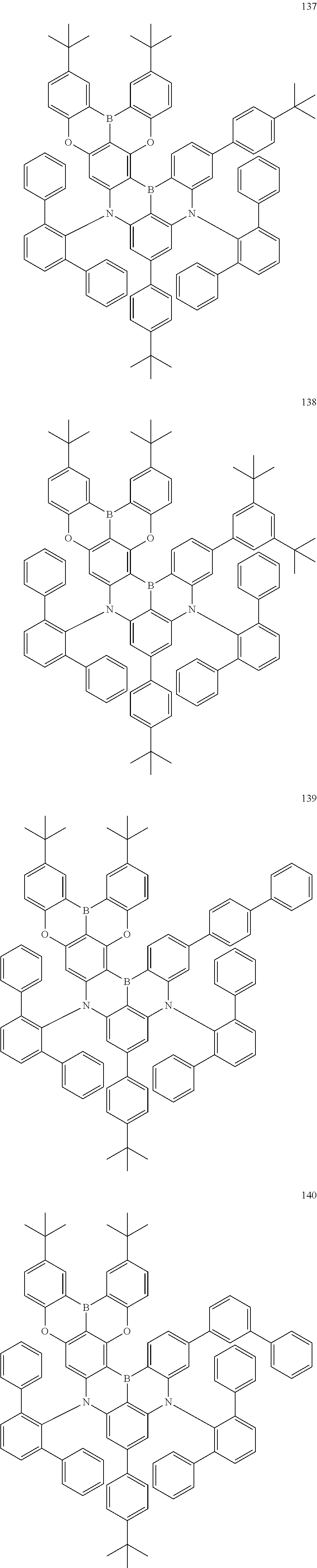

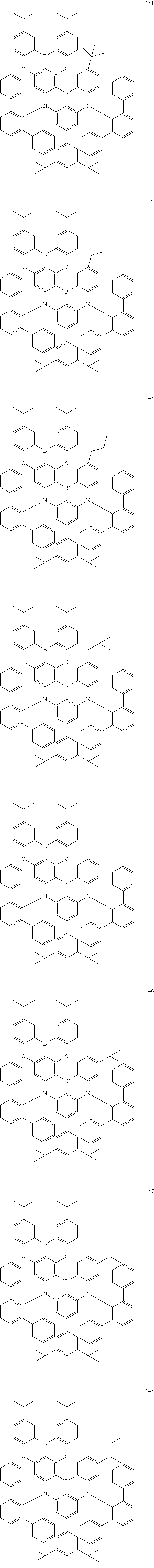

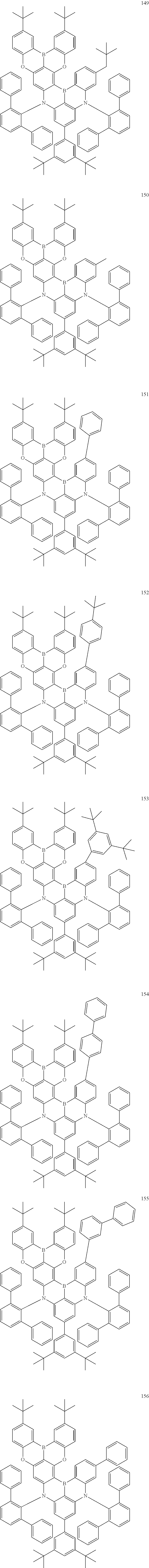

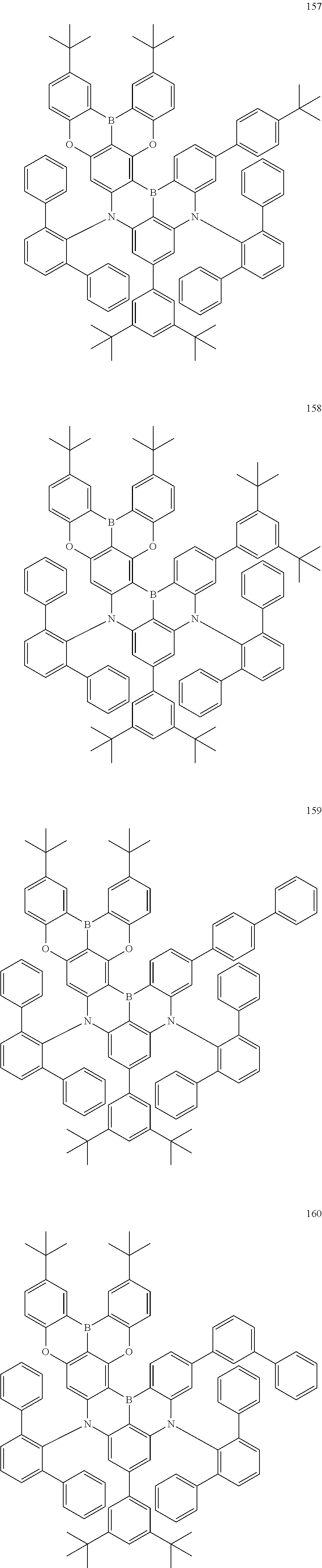

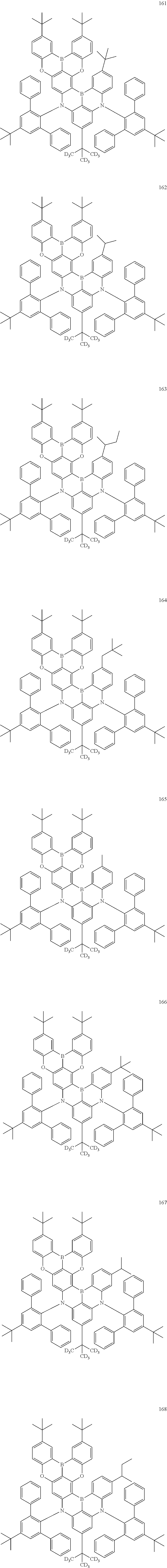

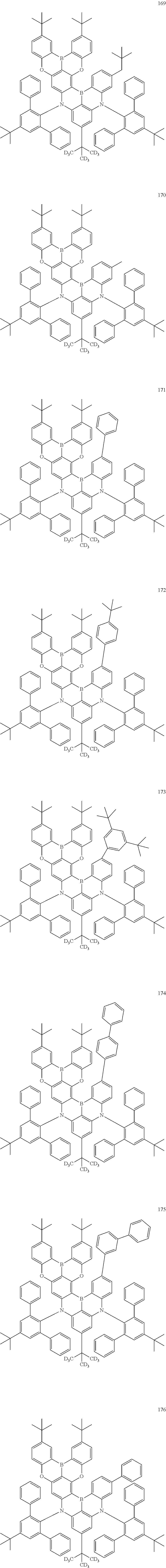

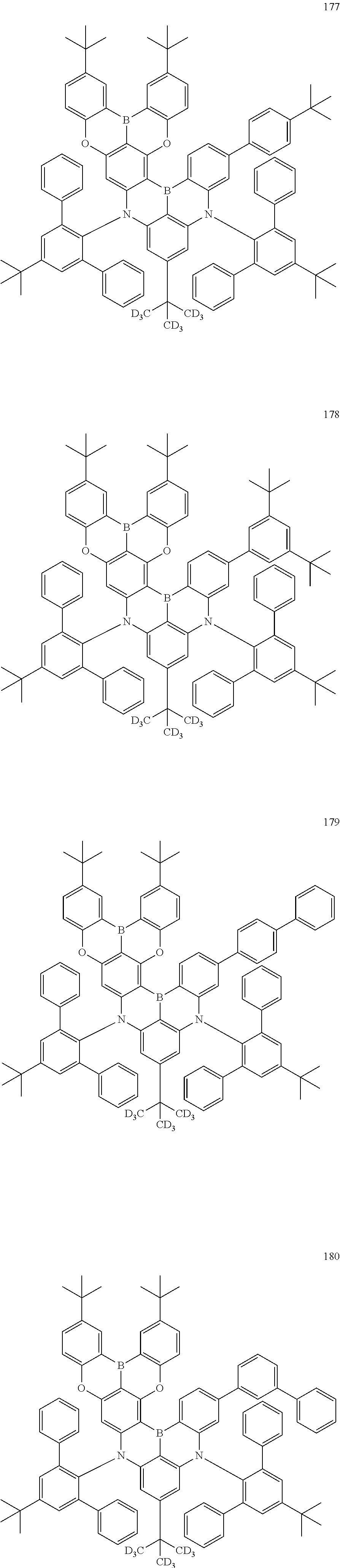

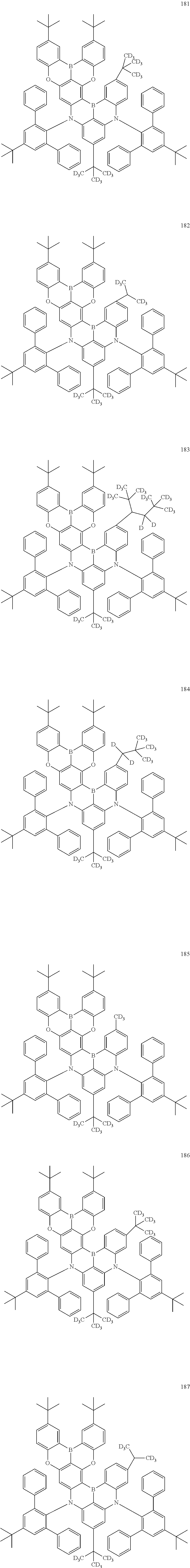

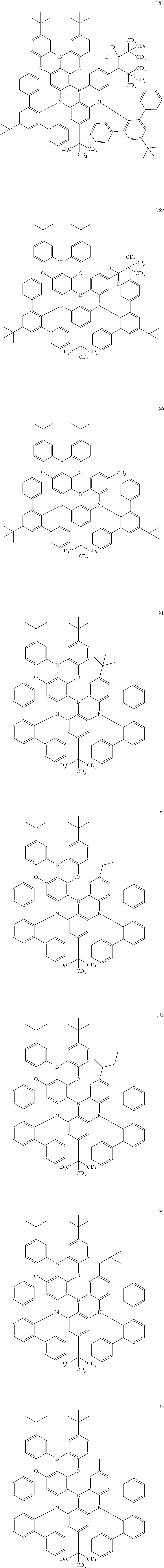

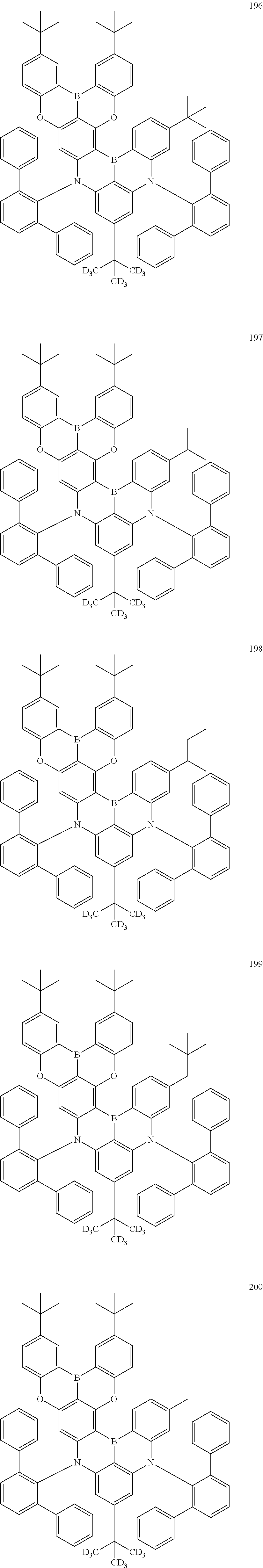

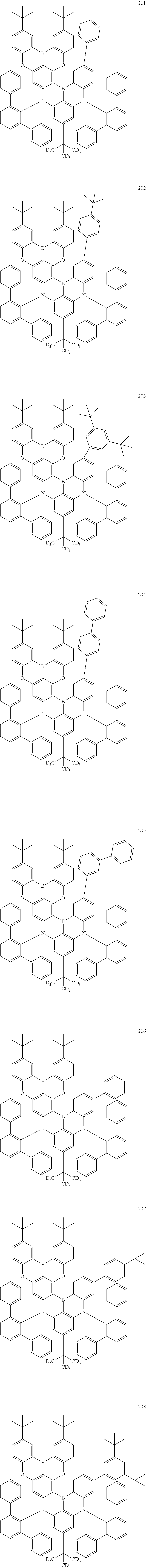

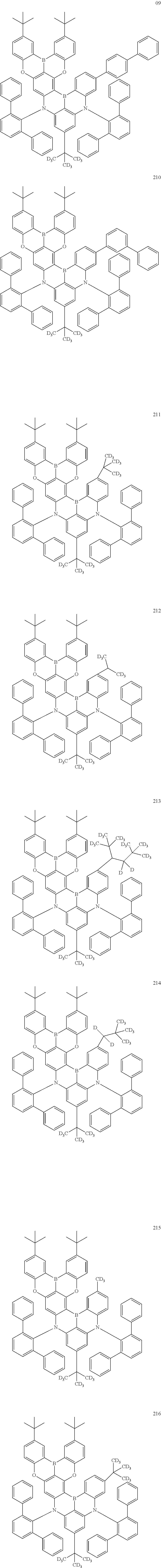

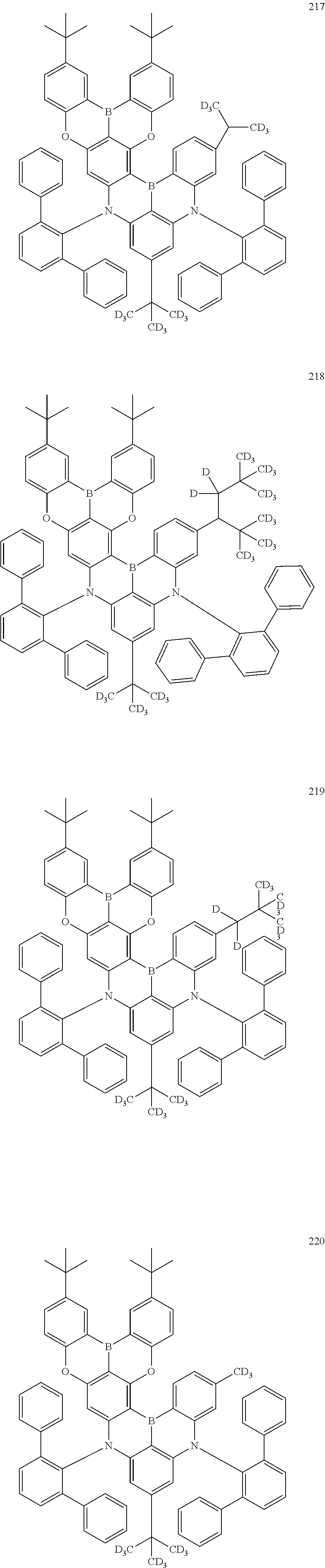

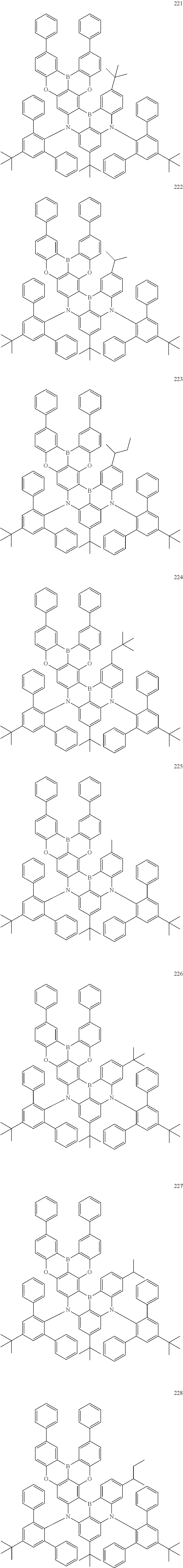

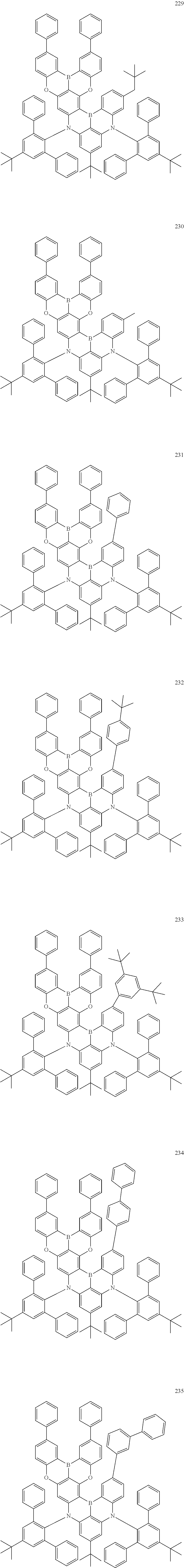

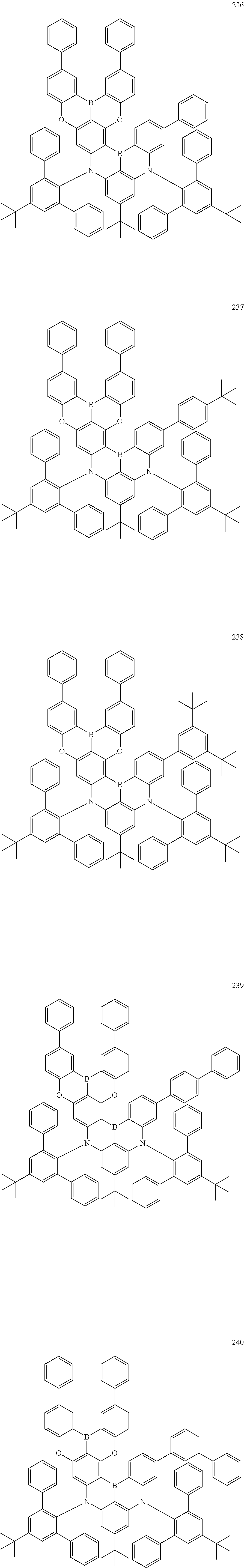

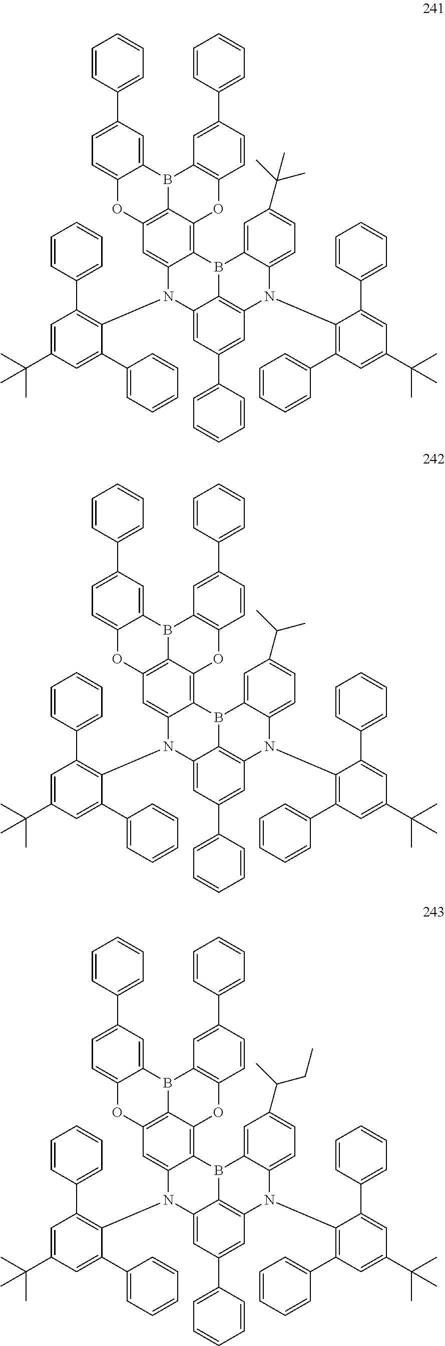

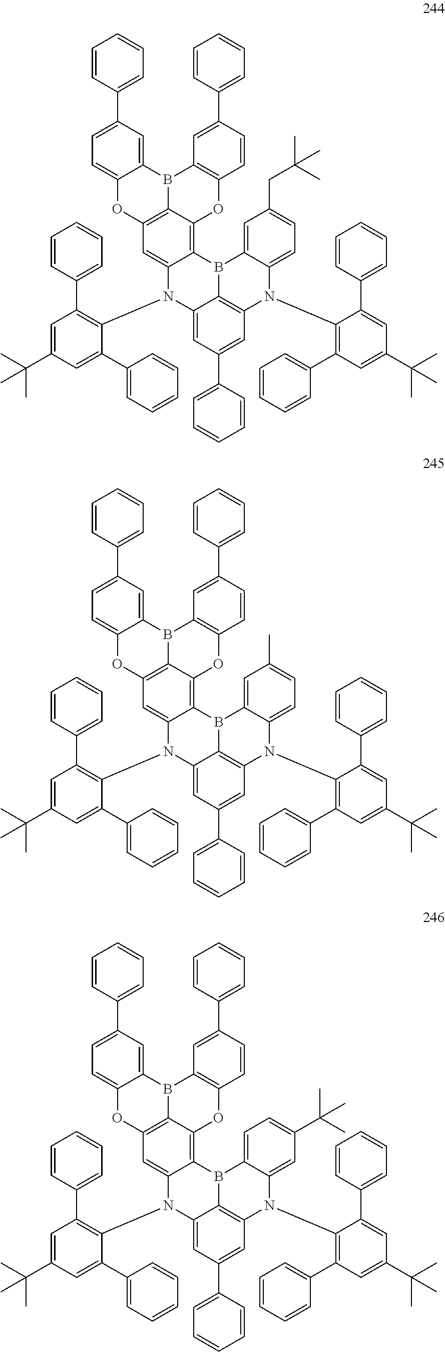

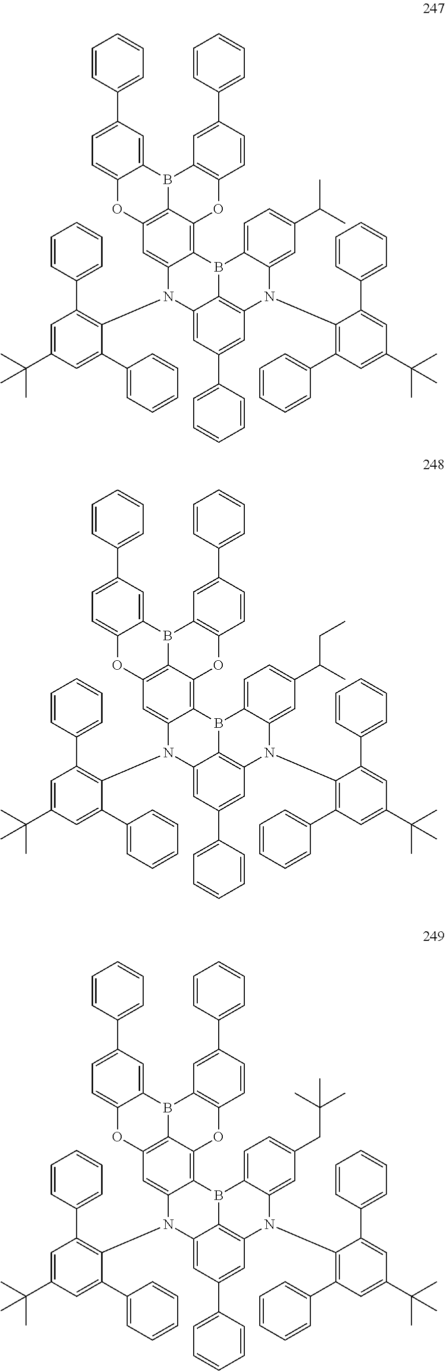

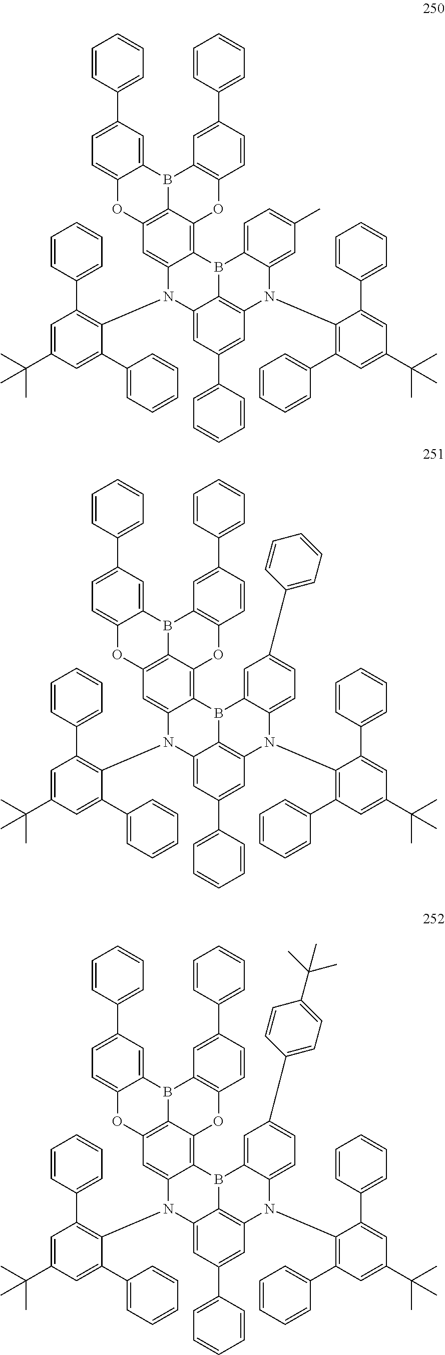

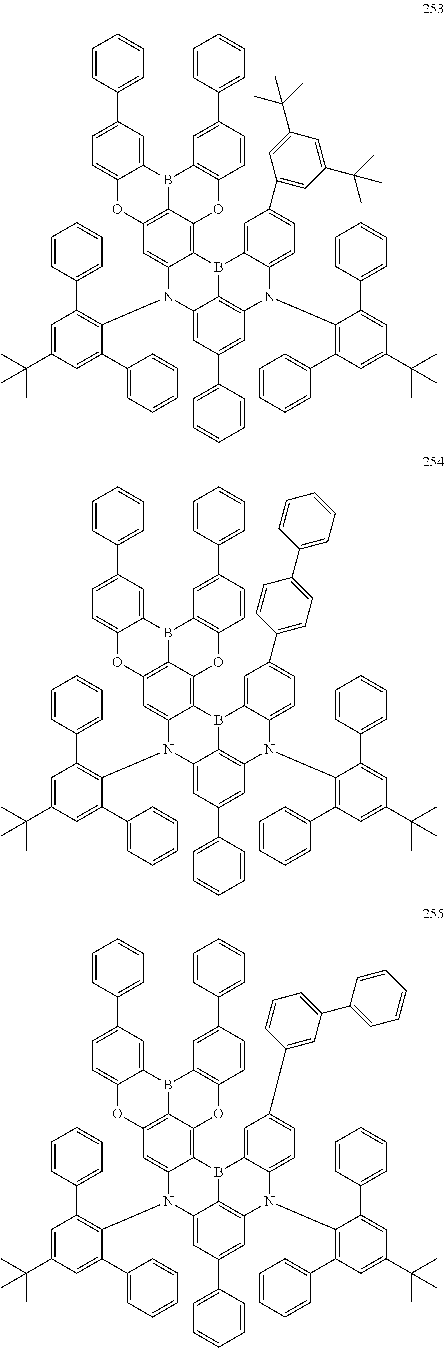

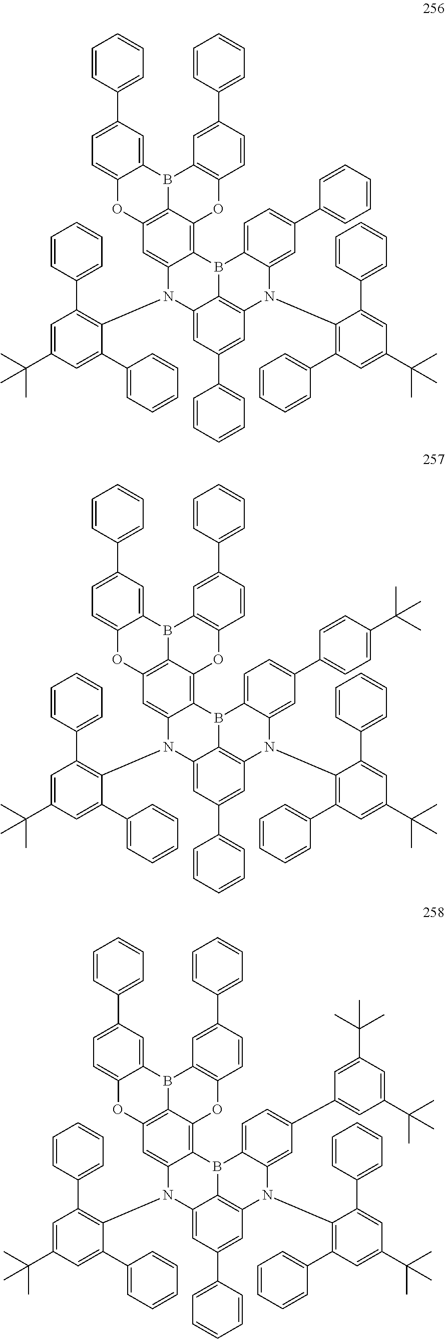

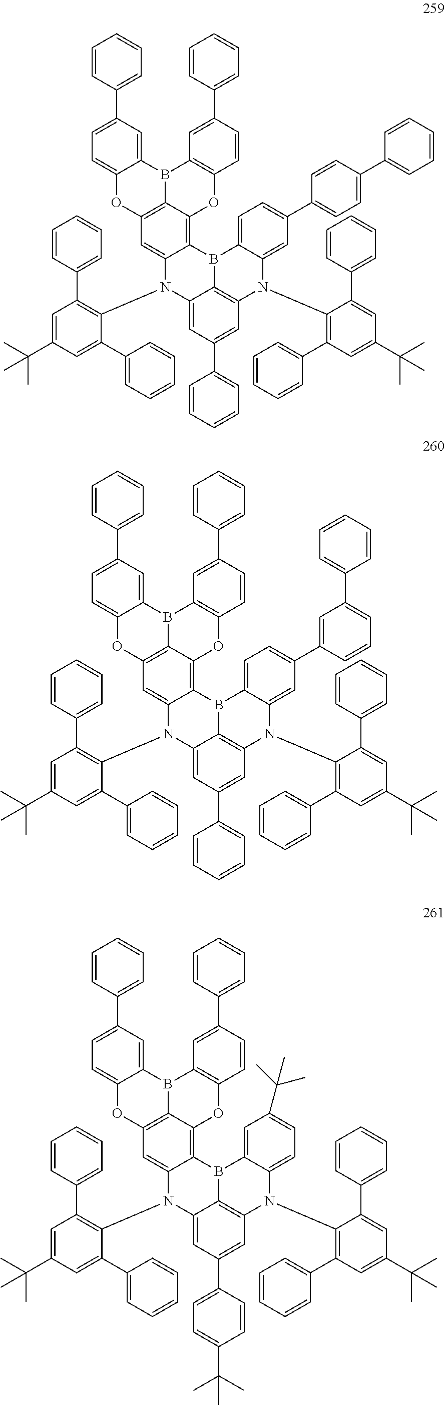

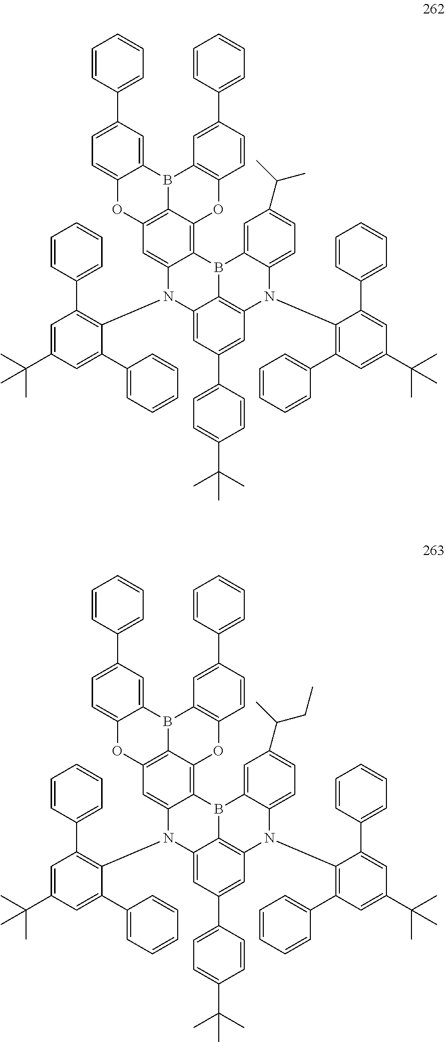

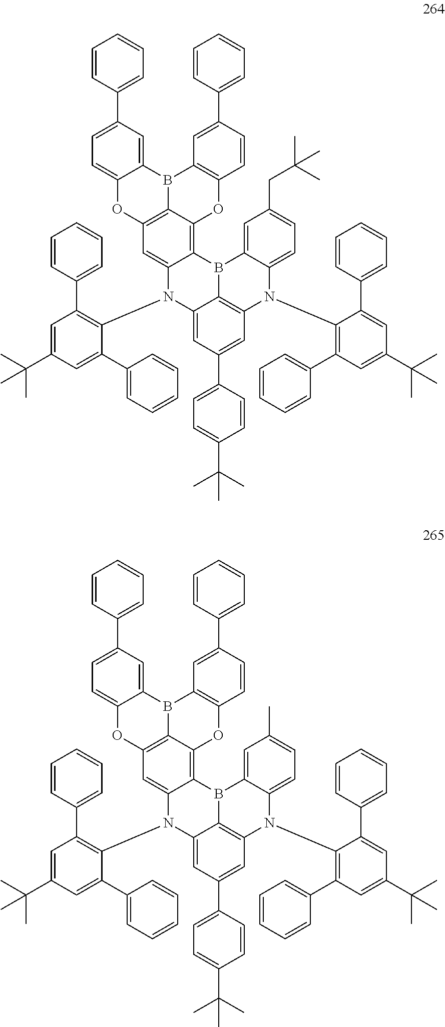

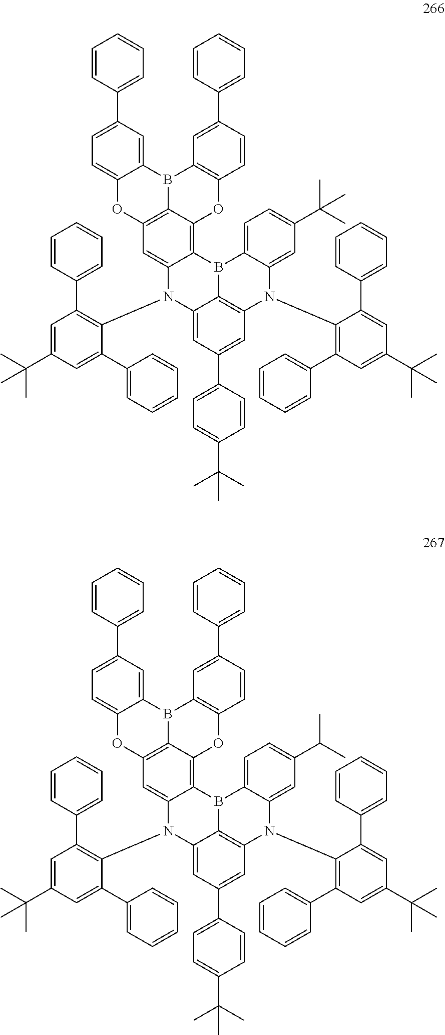

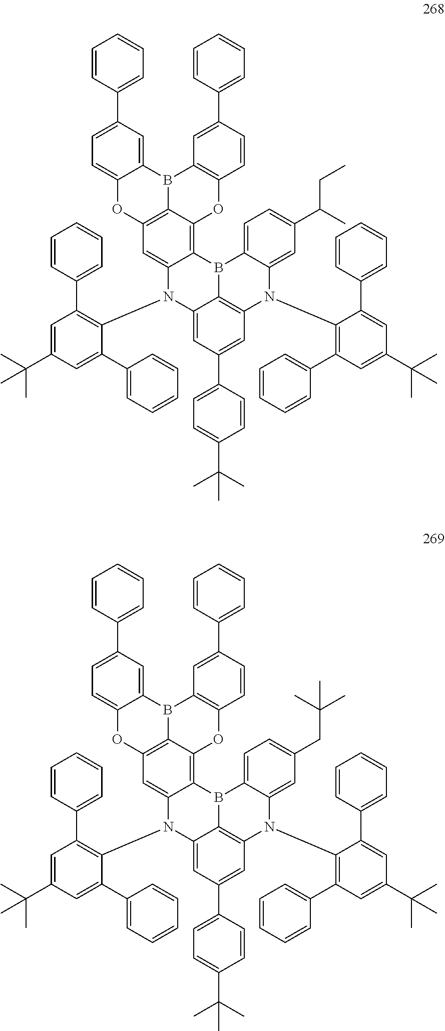

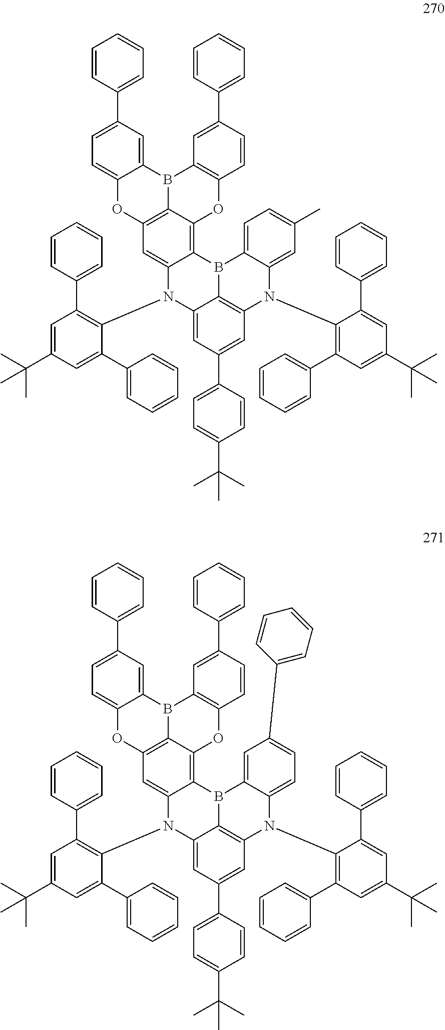

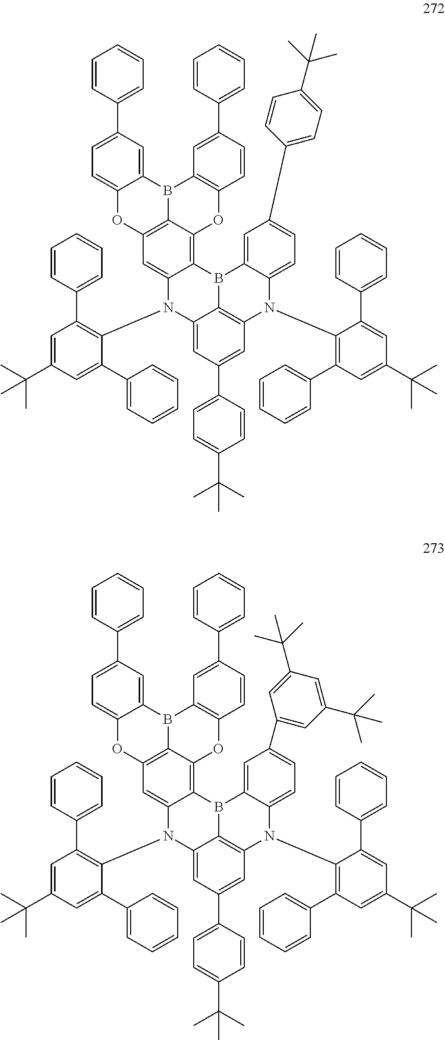

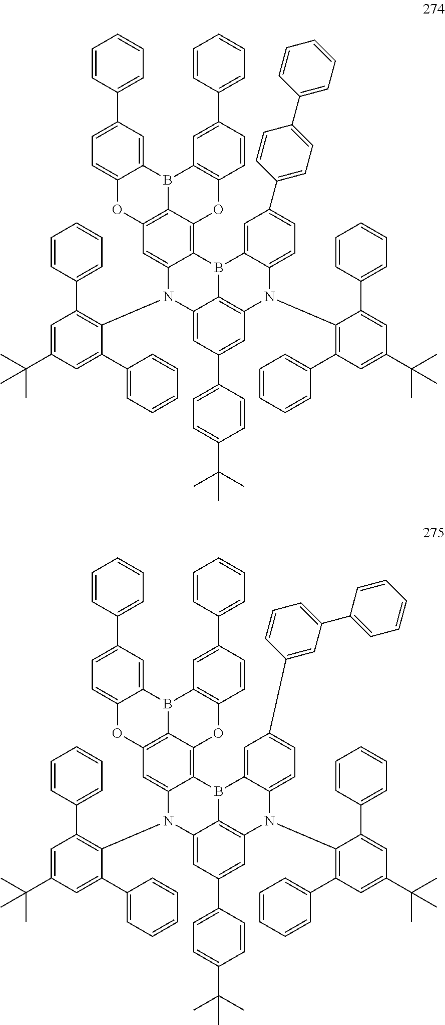

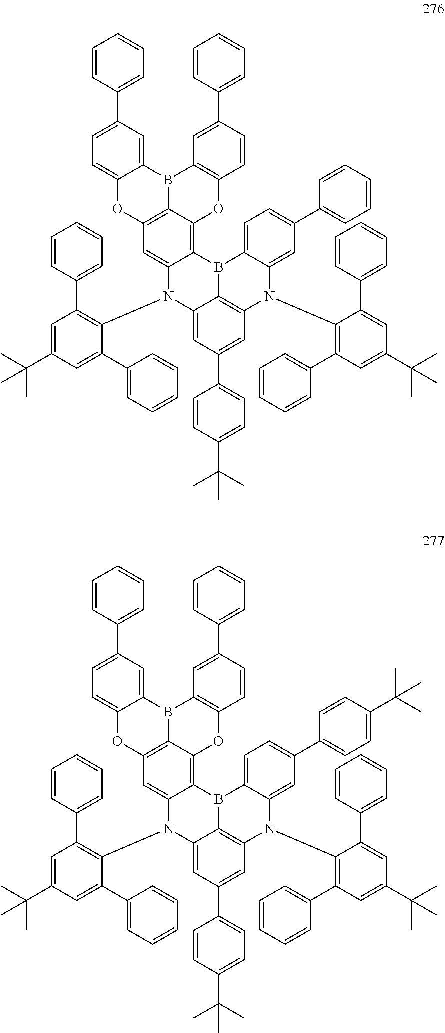

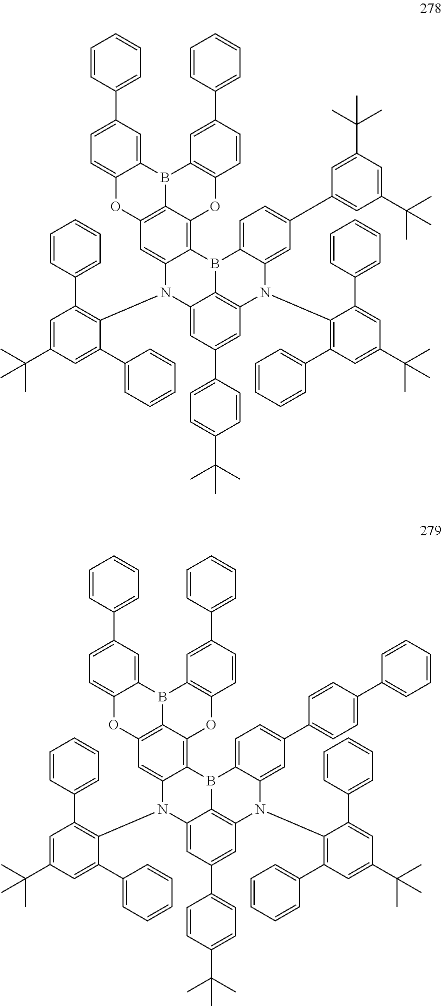

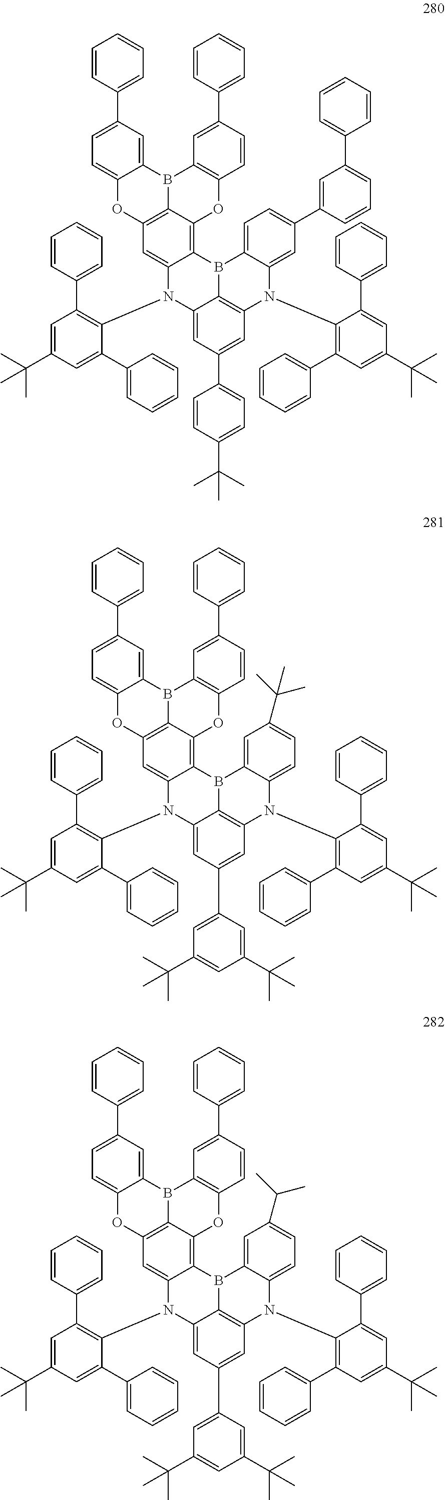

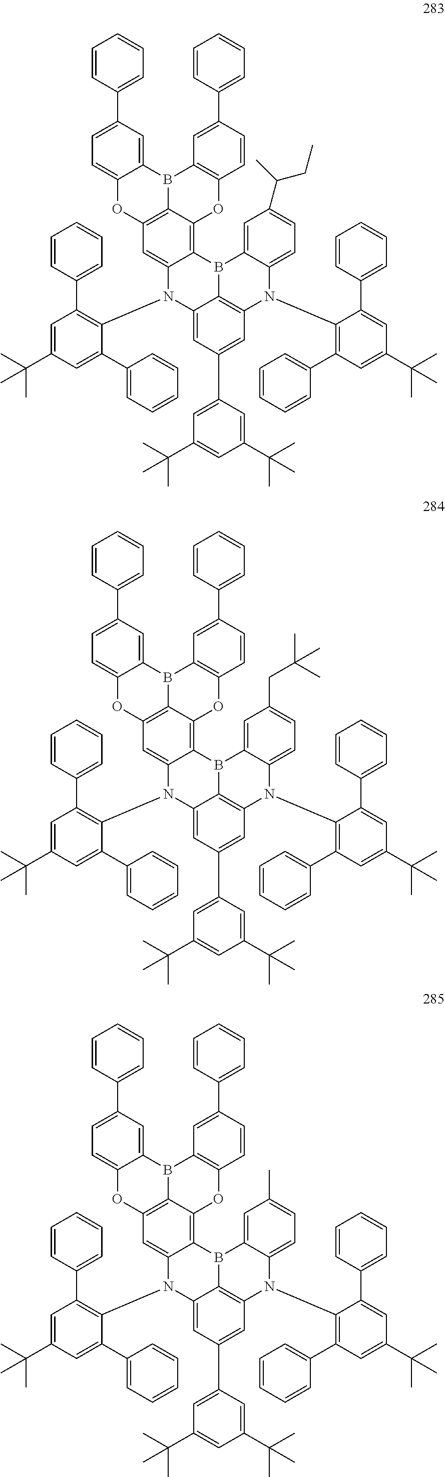

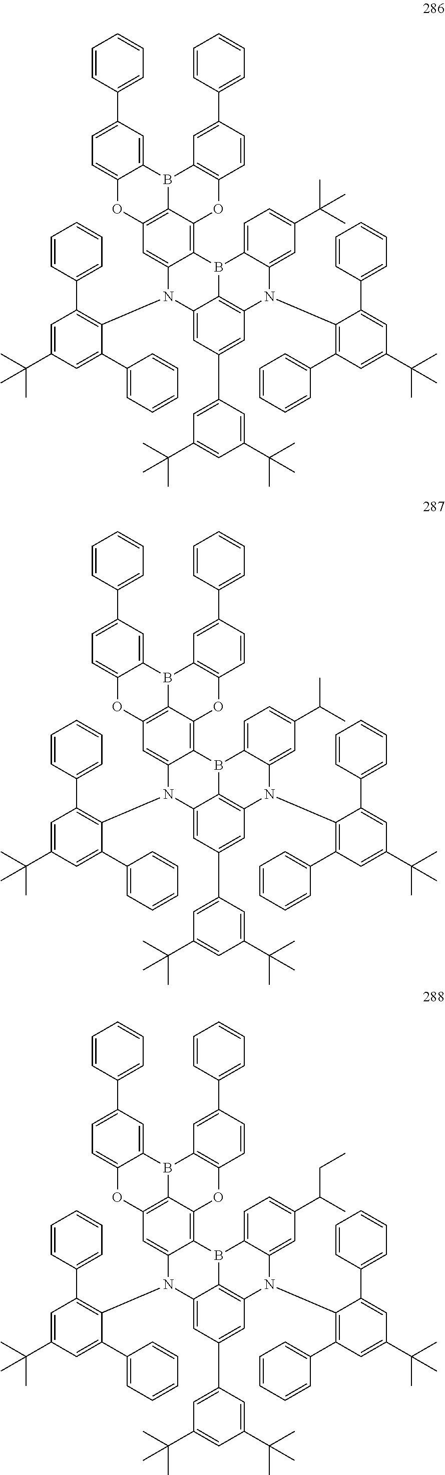

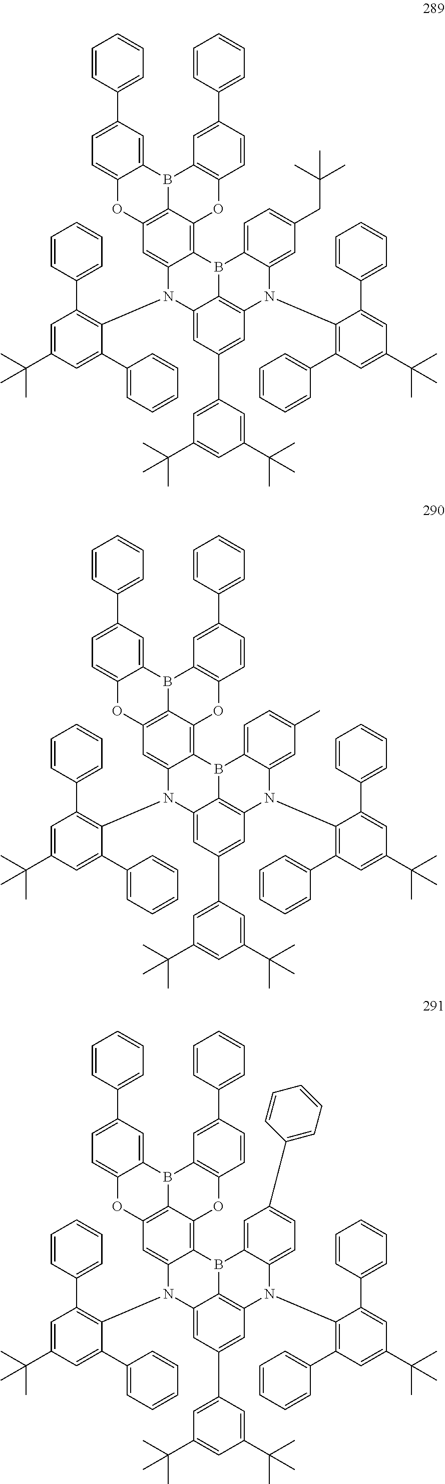

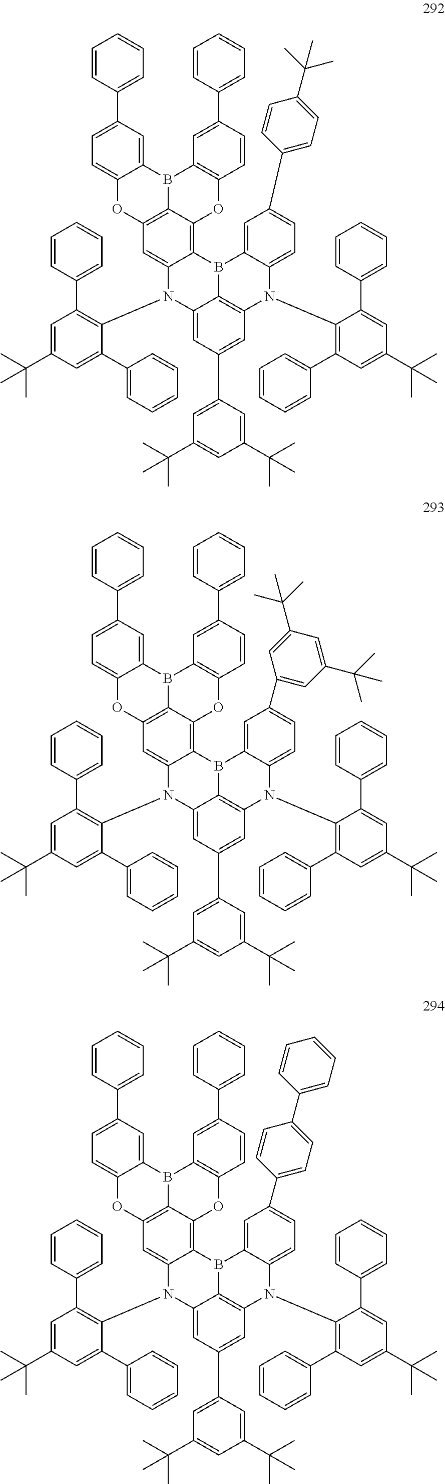

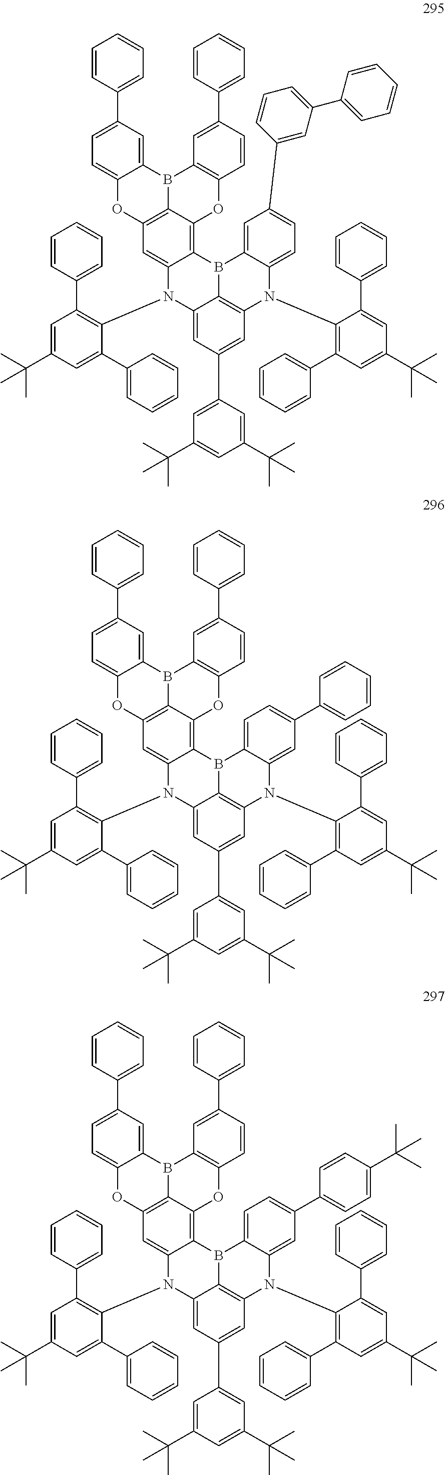

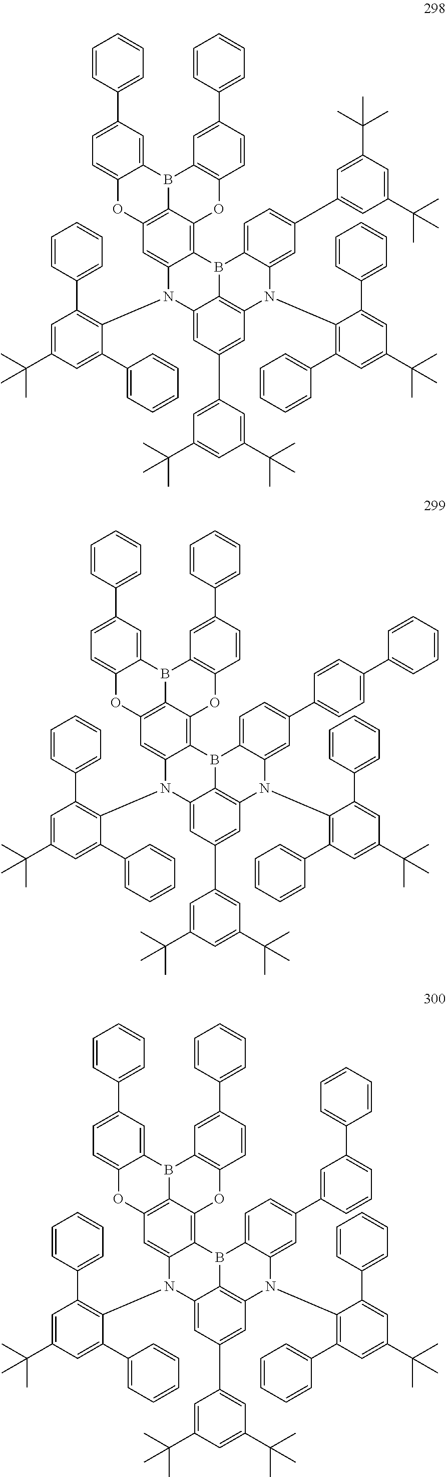

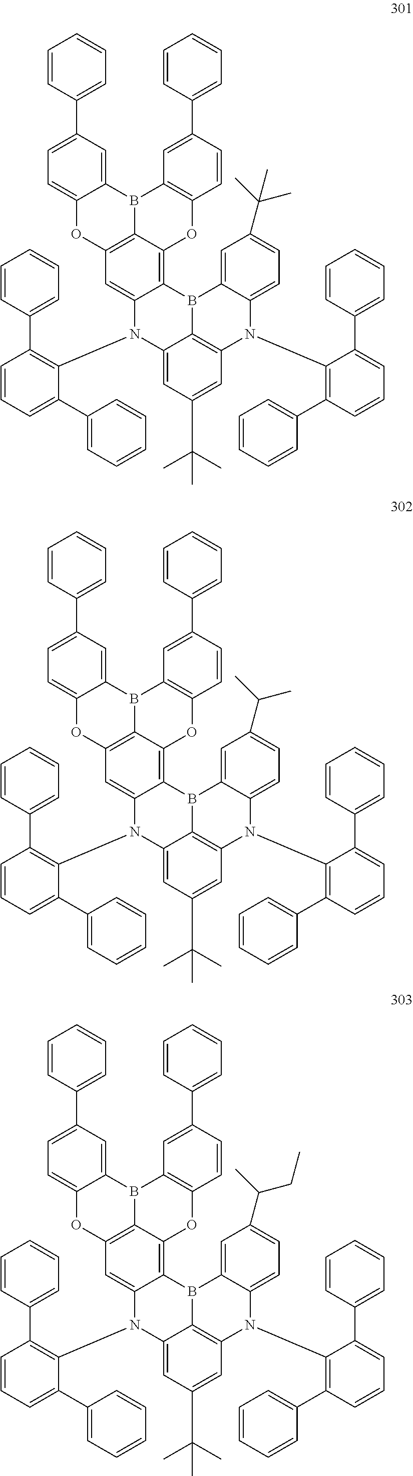

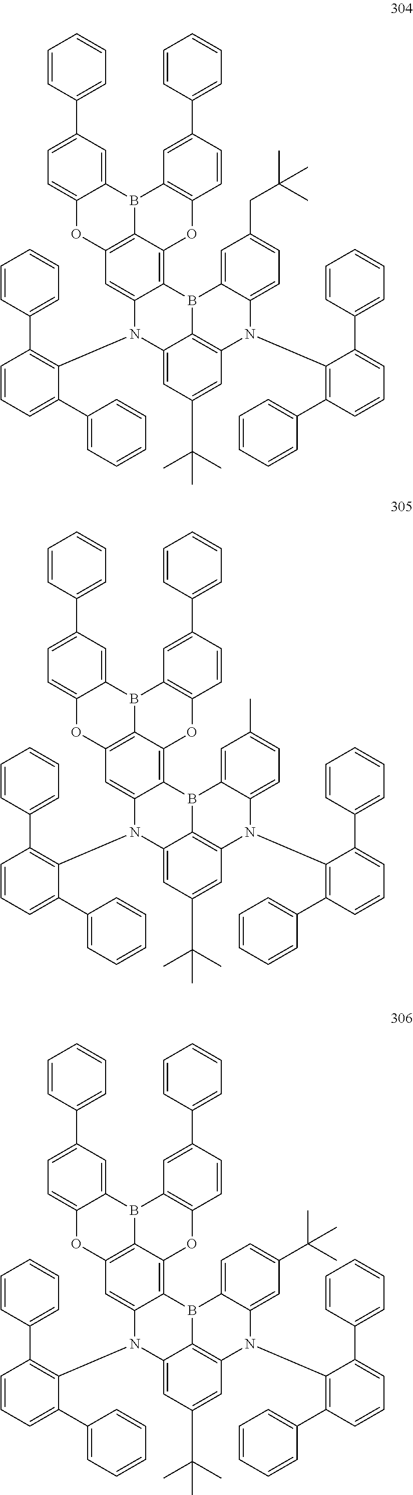 [SMILES: CC(C)(C)Cc1ccc2c(c1)B1c3c(cc(C(C)(C)C)cc3N(c3c(-c4ccccc4)cccc3-c3ccccc3)c3cc4c5c(c31)Oc1ccc(-c3ccccc3)cc1B5c1cc(-c3ccccc3)ccc1O4)N2c1c(-c2ccccc2)cccc1-c1ccccc1 ; Cc1ccc2c(c1)B1c3c(cc(C(C)(C)C)cc3N(c3c(-c4ccccc4)cccc3-c3ccccc3)c3cc4c5c(c31)Oc1ccc(-c3ccccc3)cc1B5c1cc(-c3ccccc3)ccc1O4)N2c1c(-c2ccccc2)cccc1-c1ccccc1 ; CC(C)(C)c1ccc2c(c1)N(c1c(-c3ccccc3)cccc1-c1ccccc1)c1cc(C(C)(C)C)cc3c1B2c1c(cc2c4c1Oc1ccc(-c5ccccc5)cc1B4c1cc(-c4ccccc4)ccc1O2)N3c1c(-c2ccccc2)cccc1-c1ccccc1]

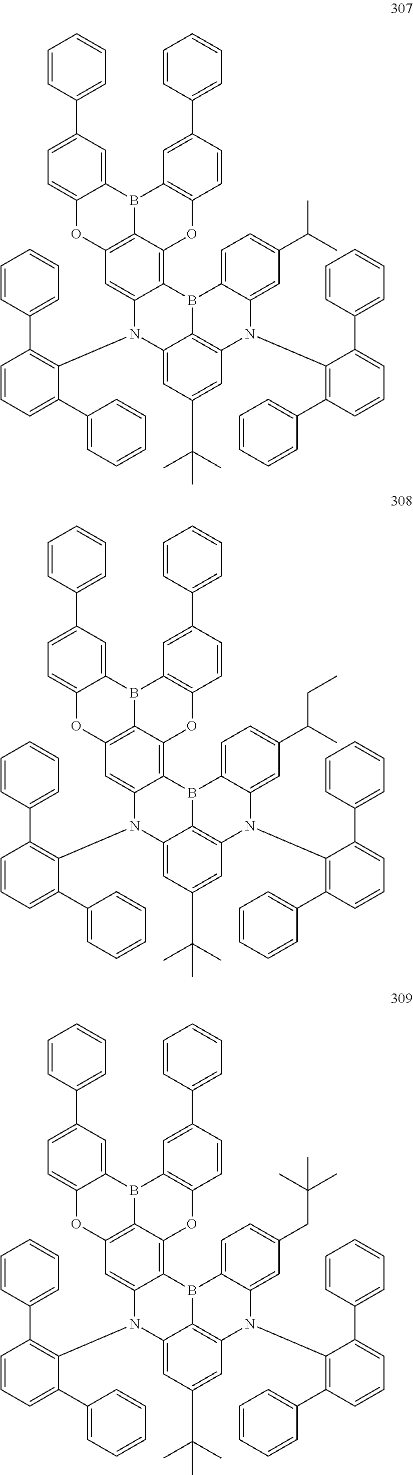

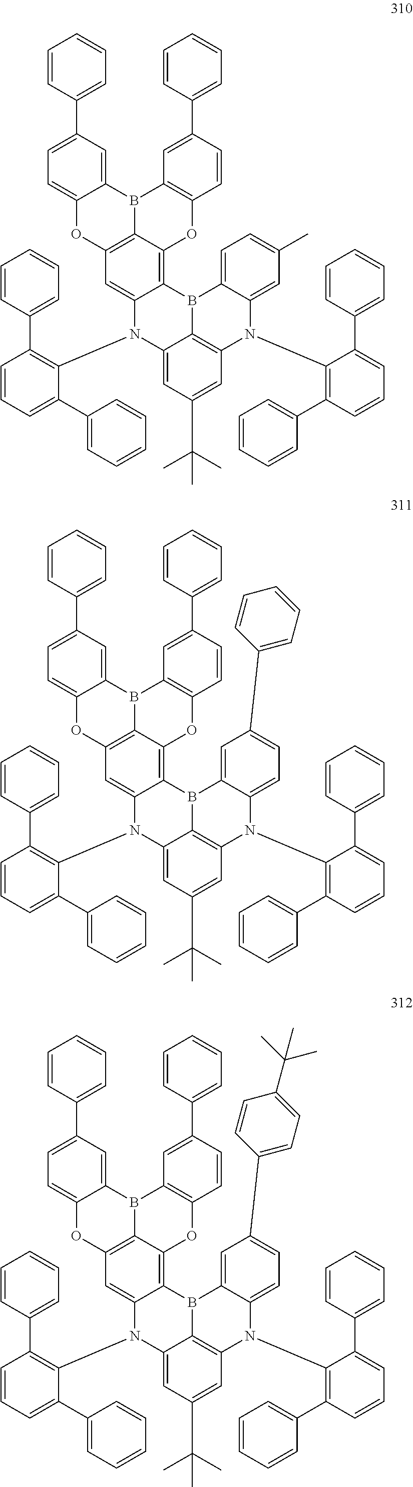

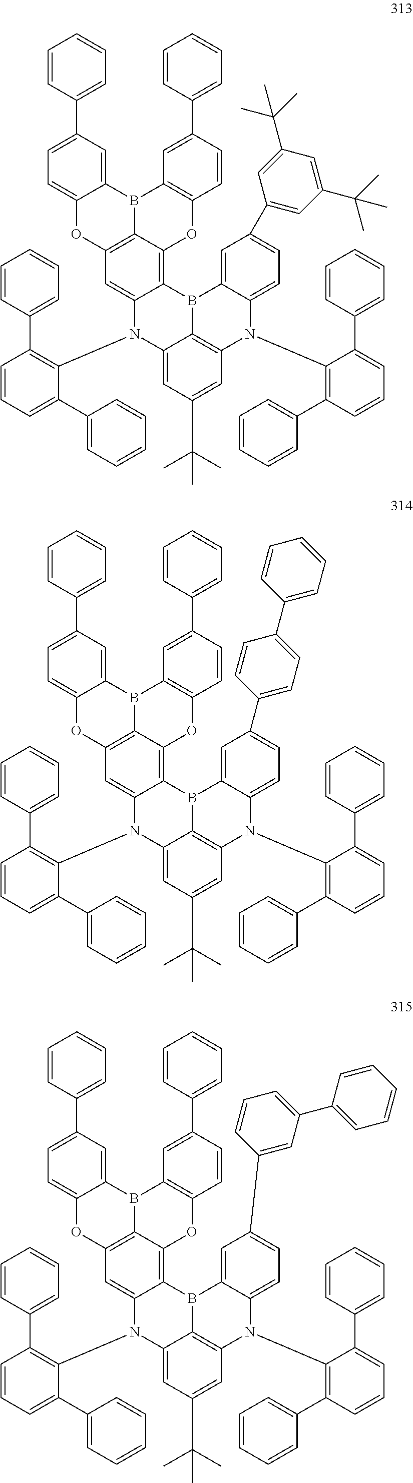

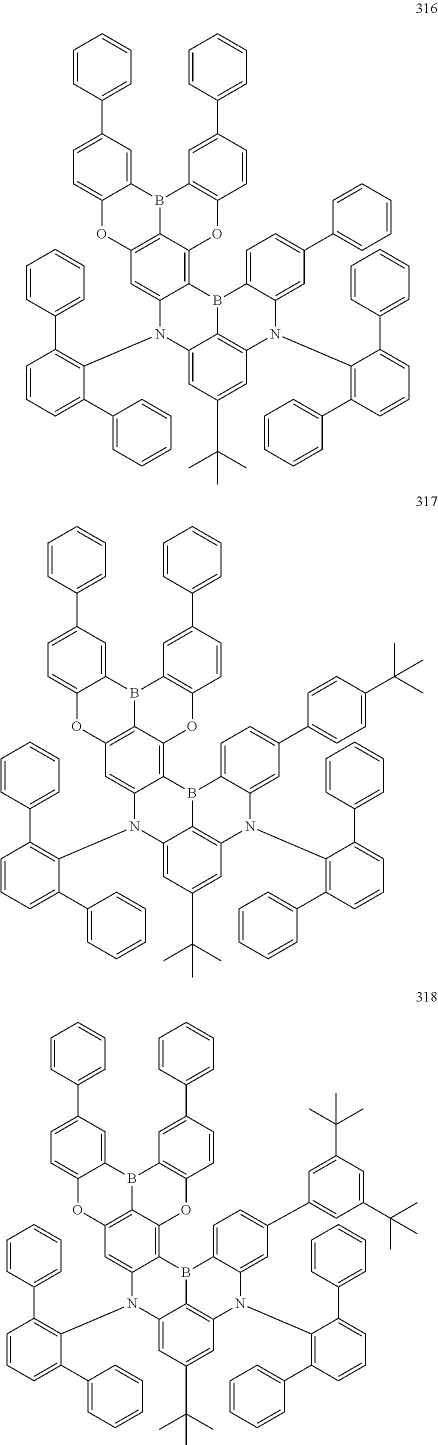

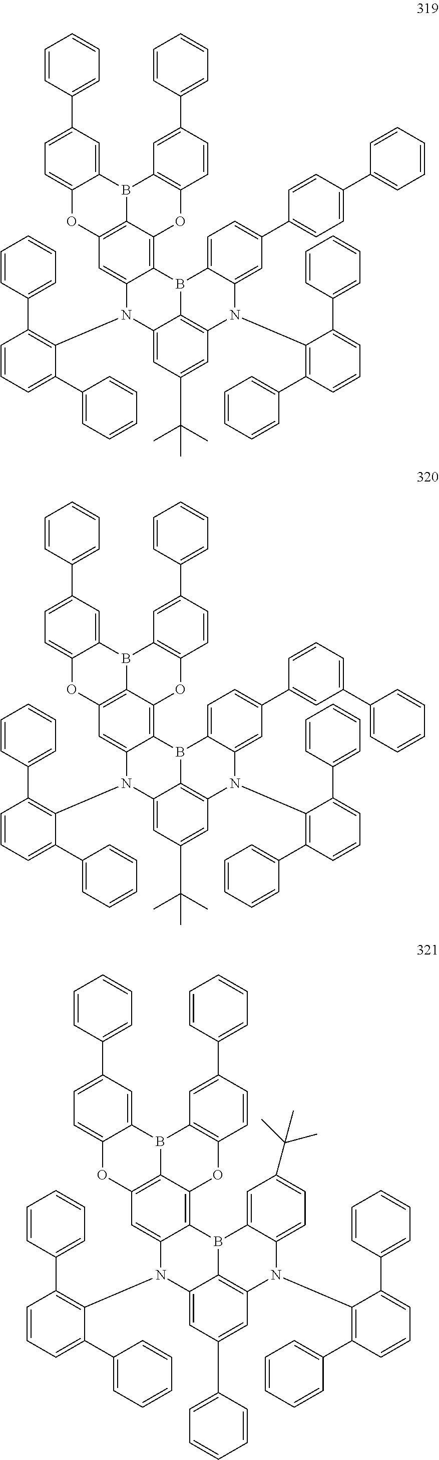

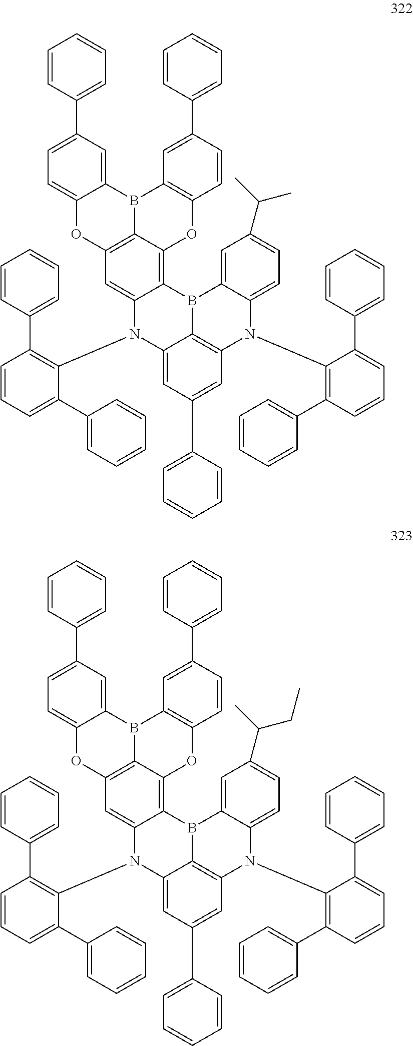

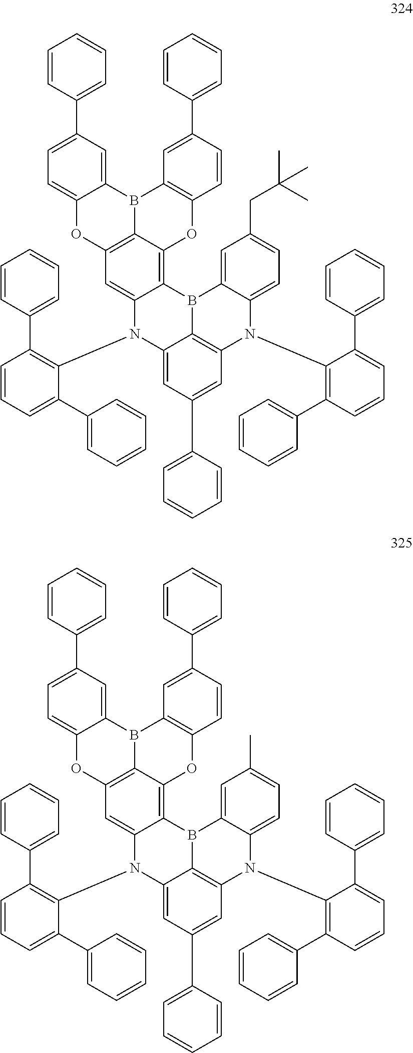 [SMILES: CC(C)(C)Cc1ccc2c(c1)B1c3c(cc(-c4ccccc4)cc3N(c3c(-c4ccccc4)cccc3-c3ccccc3)c3cc4c5c(c31)Oc1ccc(-c3ccccc3)cc1B5c1cc(-c3ccccc3)ccc1O4)N2c1c(-c2ccccc2)cccc1-c1ccccc1 ; Cc1ccc2c(c1)B1c3c(cc(-c4ccccc4)cc3N(c3c(-c4ccccc4)cccc3-c3ccccc3)c3cc4c5c(c31)Oc1ccc(-c3ccccc3)cc1B5c1cc(-c3ccccc3)ccc1O4)N2c1c(-c2ccccc2)cccc1-c1ccccc1]

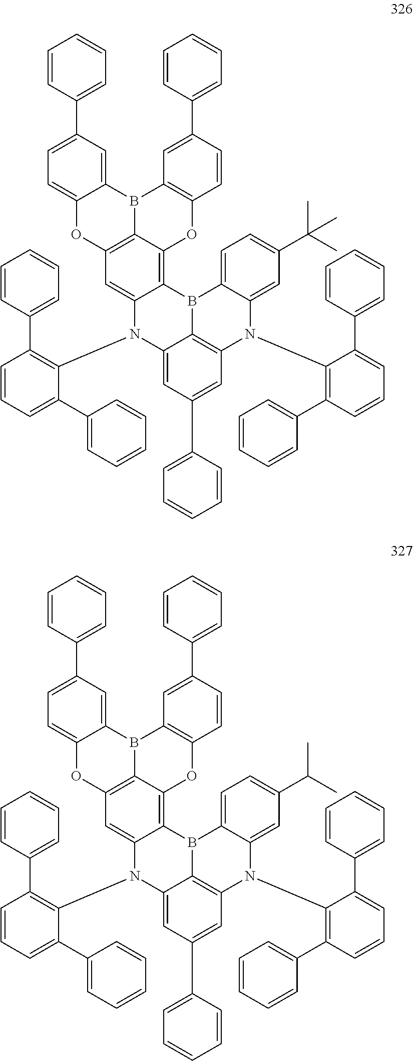 [SMILES: CC(C)(C)c1ccc2c(c1)N(c1c(-c3ccccc3)cccc1-c1ccccc1)c1cc(-c3ccccc3)cc3c1B2c1c(cc2c4c1Oc1ccc(-c5ccccc5)cc1B4c1cc(-c4ccccc4)ccc1O2)N3c1c(-c2ccccc2)cccc1-c1ccccc1 ; CC(C)c1ccc2c(c1)N(c1c(-c3ccccc3)cccc1-c1ccccc1)c1cc(-c3ccccc3)cc3c1B2c1c(cc2c4c1Oc1ccc(-c5ccccc5)cc1B4c1cc(-c4ccccc4)ccc1O2)N3c1c(-c2ccccc2)cccc1-c1ccccc1]

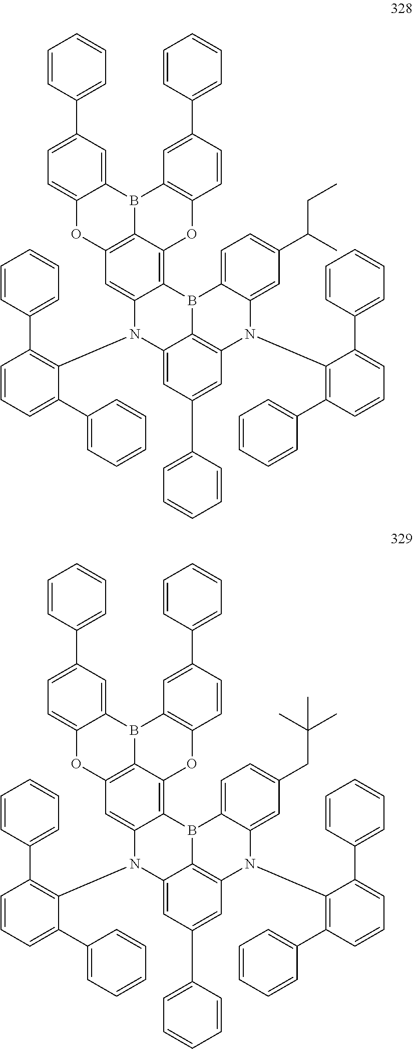

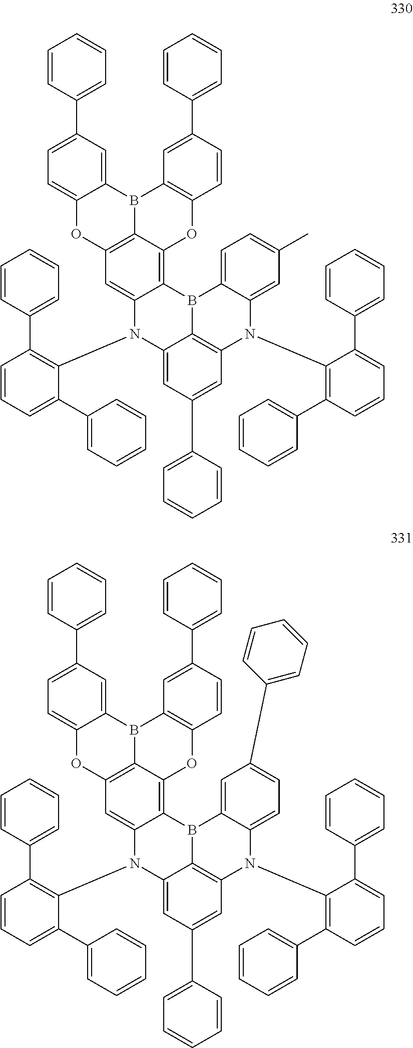

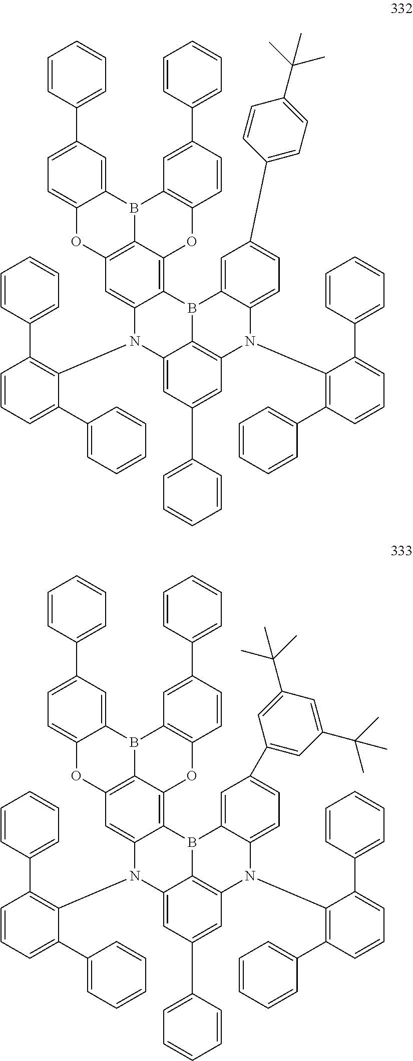 [SMILES: CC(C)(C)c1ccc(-c2ccc3c(c2)B2c4c(cc(-c5ccccc5)cc4N(c4c(-c5ccccc5)cccc4-c4ccccc4)c4cc5c6c(c42)Oc2ccc(-c4ccccc4)cc2B6c2cc(-c4ccccc4)ccc2O5)N3c2c(-c3ccccc3)cccc2-c2ccccc2)cc1 ; CC(C)(C)c1cc(-c2ccc3c(c2)B2c4c(cc(-c5ccccc5)cc4N(c4c(-c5ccccc5)cccc4-c4ccccc4)c4cc5c6c(c42)Oc2ccc(-c4ccccc4)cc2B6c2cc(-c4ccccc4)ccc2O5)N3c2c(-c3ccccc3)cccc2-c2ccccc2)cc(C(C)(C)C)c1]

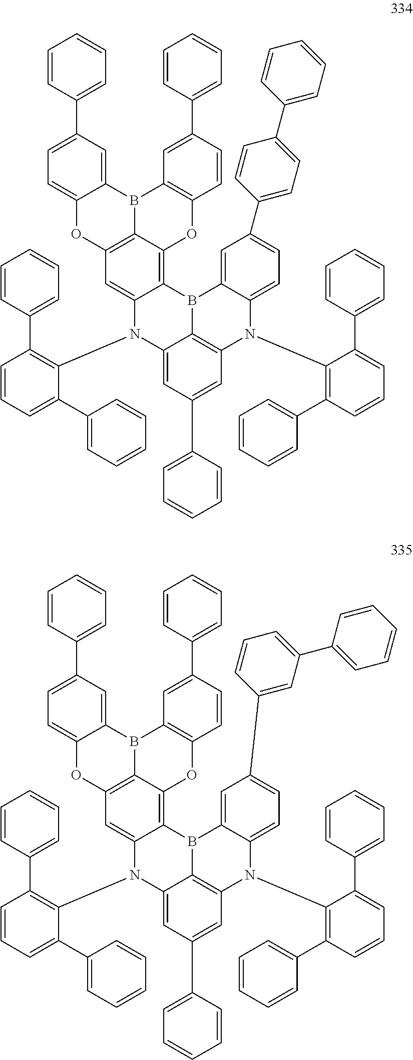 [SMILES: c1ccc(-c2ccc(-c3ccc4c(c3)B3c5c(cc(-c6ccccc6)cc5N(c5c(-c6ccccc6)cccc5-c5ccccc5)c5cc6c7c(c53)Oc3ccc(-c5ccccc5)cc3B7c3cc(-c5ccccc5)ccc3O6)N4c3c(-c4ccccc4)cccc3-c3ccccc3)cc2)cc1 ; c1ccc(-c2cccc(-c3ccc4c(c3)B3c5c(cc(-c6ccccc6)cc5N(c5c(-c6ccccc6)cccc5-c5ccccc5)c5cc6c7c(c53)Oc3ccc(-c5ccccc5)cc3B7c3cc(-c5ccccc5)ccc3O6)N4c3c(-c4ccccc4)cccc3-c3ccccc3)c2)cc1]

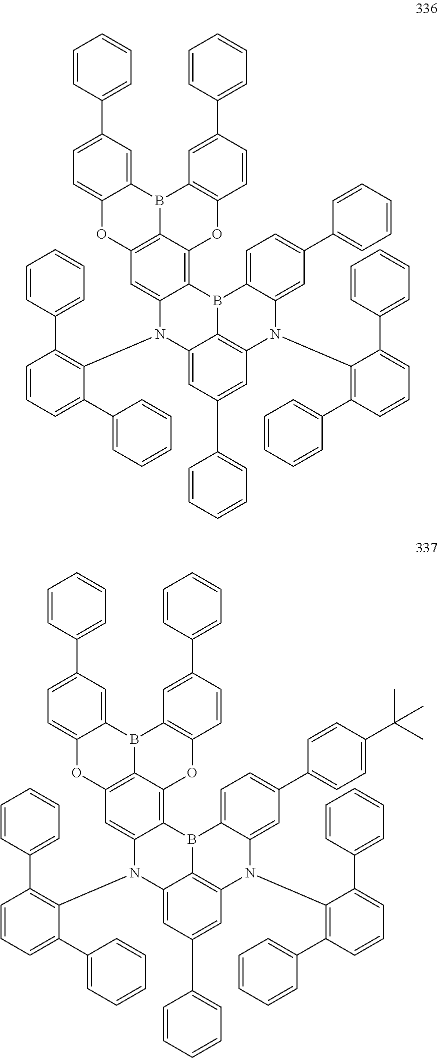 [SMILES: c1ccc(-c2ccc3c(c2)B2c4cc(-c5ccccc5)ccc4Oc4c2c(cc2c4B4c5ccc(-c6ccccc6)cc5N(c5c(-c6ccccc6)cccc5-c5ccccc5)c5cc(-c6ccccc6)cc(c54)N2c2c(-c4ccccc4)cccc2-c2ccccc2)O3)cc1 ; CC(C)(C)c1ccc(-c2ccc3c(c2)N(c2c(-c4ccccc4)cccc2-c2ccccc2)c2cc(-c4ccccc4)cc4c2B3c2c(cc3c5c2Oc2ccc(-c6ccccc6)cc2B5c2cc(-c5ccccc5)ccc2O3)N4c2c(-c3ccccc3)cccc2-c2ccccc2)cc1]

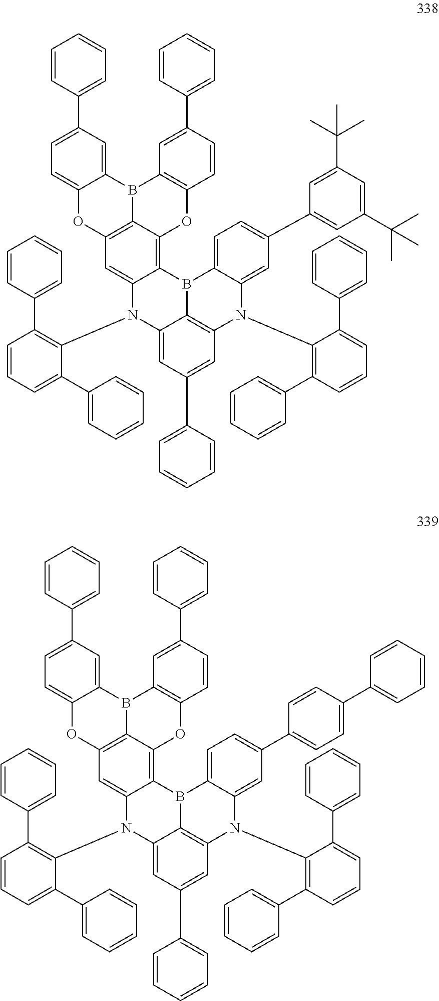 [SMILES: CC(C)(C)c1cc(-c2ccc3c(c2)N(c2c(-c4ccccc4)cccc2-c2ccccc2)c2cc(-c4ccccc4)cc4c2B3c2c(cc3c5c2Oc2ccc(-c6ccccc6)cc2B5c2cc(-c5ccccc5)ccc2O3)N4c2c(-c3ccccc3)cccc2-c2ccccc2)cc(C(C)(C)C)c1 ; c1ccc(-c2ccc(-c3ccc4c(c3)N(c3c(-c5ccccc5)cccc3-c3ccccc3)c3cc(-c5ccccc5)cc5c3B4c3c(cc4c6c3Oc3ccc(-c7ccccc7)cc3B6c3cc(-c6ccccc6)ccc3O4)N5c3c(-c4ccccc4)cccc3-c3ccccc3)cc2)cc1]

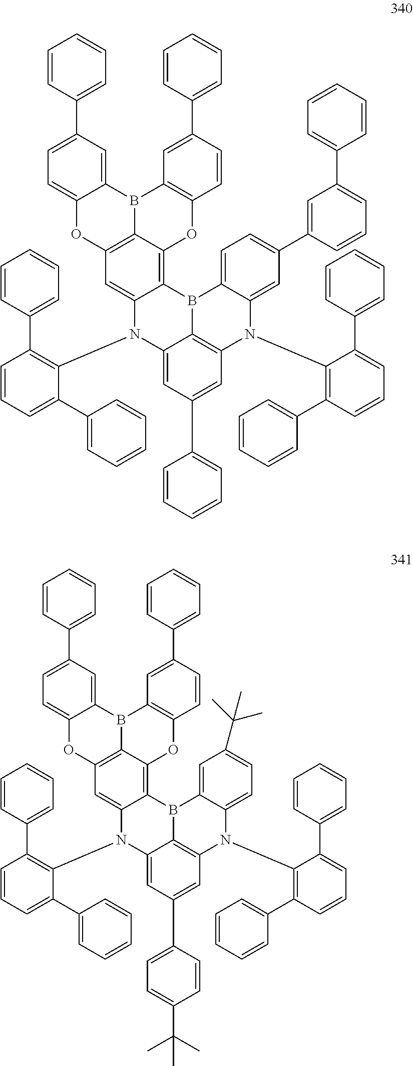 [SMILES: c1ccc(-c2cccc(-c3ccc4c(c3)N(c3c(-c5ccccc5)cccc3-c3ccccc3)c3cc(-c5ccccc5)cc5c3B4c3c(cc4c6c3Oc3ccc(-c7ccccc7)cc3B6c3cc(-c6ccccc6)ccc3O4)N5c3c(-c4ccccc4)cccc3-c3ccccc3)c2)cc1 ; CC(C)(C)c1ccc(-c2cc3c4c(c2)N(c2c(-c5ccccc5)cccc2-c2ccccc2)c2cc5c6c(c2B4c2cc(C(C)(C)C)ccc2N3c2c(-c3ccccc3)cccc2-c2ccccc2)Oc2ccc(-c3ccccc3)cc2B6c2cc(-c3ccccc3)ccc2O5)cc1]

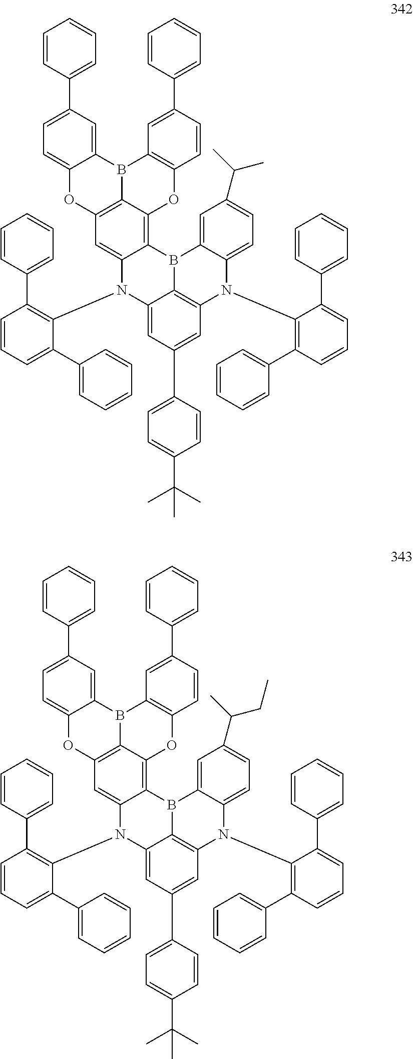 [SMILES: CC(C)c1ccc2c(c1)B1c3c(cc(-c4ccc(C(C)(C)C)cc4)cc3N(c3c(-c4ccccc4)cccc3-c3ccccc3)c3cc4c5c(c31)Oc1ccc(-c3ccccc3)cc1B5c1cc(-c3ccccc3)ccc1O4)N2c1c(-c2ccccc2)cccc1-c1ccccc1 ; CCC(C)c1ccc2c(c1)B1c3c(cc(-c4ccc(C(C)(C)C)cc4)cc3N(c3c(-c4ccccc4)cccc3-c3ccccc3)c3cc4c5c(c31)Oc1ccc(-c3ccccc3)cc1B5c1cc(-c3ccccc3)ccc1O4)N2c1c(-c2ccccc2)cccc1-c1ccccc1]

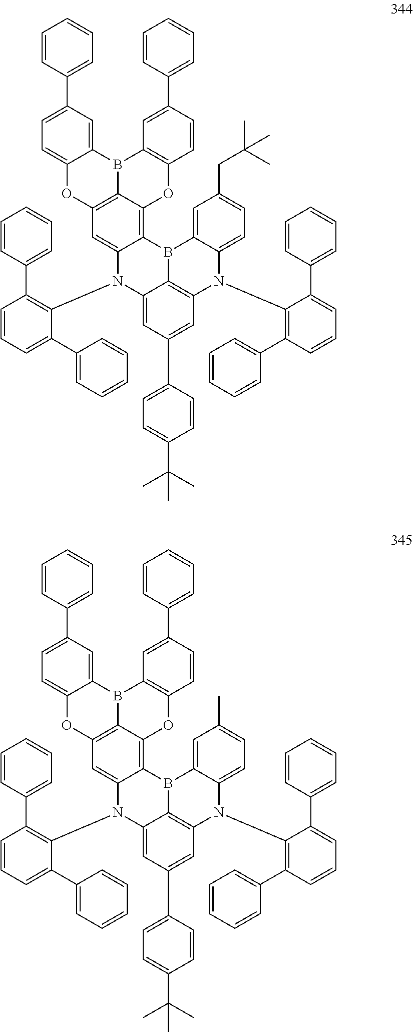 [SMILES: CC(C)(C)Cc1ccc2c(c1)B1c3c(cc(-c4ccc(C(C)(C)C)cc4)cc3N(c3c(-c4ccccc4)cccc3-c3ccccc3)c3cc4c5c(c31)Oc1ccc(-c3ccccc3)cc1B5c1cc(-c3ccccc3)ccc1O4)N2c1c(-c2ccccc2)cccc1-c1ccccc1 ; Cc1ccc2c(c1)B1c3c(cc(-c4ccc(C(C)(C)C)cc4)cc3N(c3c(-c4ccccc4)cccc3-c3ccccc3)c3cc4c5c(c31)Oc1ccc(-c3ccccc3)cc1B5c1cc(-c3ccccc3)ccc1O4)N2c1c(-c2ccccc2)cccc1-c1ccccc1]

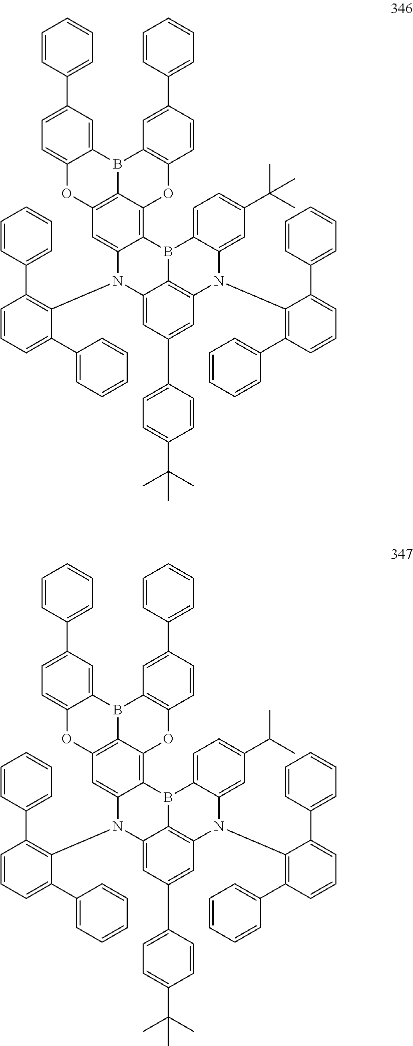 [SMILES: CC(C)(C)c1ccc(-c2cc3c4c(c2)N(c2c(-c5ccccc5)cccc2-c2ccccc2)c2cc5c6c(c2B4c2ccc(C(C)(C)C)cc2N3c2c(-c3ccccc3)cccc2-c2ccccc2)Oc2ccc(-c3ccccc3)cc2B6c2cc(-c3ccccc3)ccc2O5)cc1 ; CC(C)c1ccc2c(c1)N(c1c(-c3ccccc3)cccc1-c1ccccc1)c1cc(-c3ccc(C(C)(C)C)cc3)cc3c1B2c1c(cc2c4c1Oc1ccc(-c5ccccc5)cc1B4c1cc(-c4ccccc4)ccc1O2)N3c1c(-c2ccccc2)cccc1-c1ccccc1]

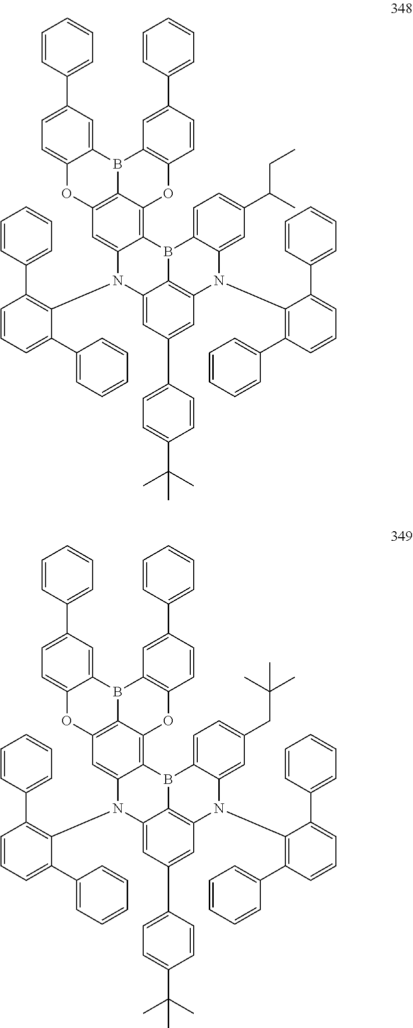 [SMILES: CCC(C)c1ccc2c(c1)N(c1c(-c3ccccc3)cccc1-c1ccccc1)c1cc(-c3ccc(C(C)(C)C)cc3)cc3c1B2c1c(cc2c4c1Oc1ccc(-c5ccccc5)cc1B4c1cc(-c4ccccc4)ccc1O2)N3c1c(-c2ccccc2)cccc1-c1ccccc1 ; CC(C)(C)Cc1ccc2c(c1)N(c1c(-c3ccccc3)cccc1-c1ccccc1)c1cc(-c3ccc(C(C)(C)C)cc3)cc3c1B2c1c(cc2c4c1Oc1ccc(-c5ccccc5)cc1B4c1cc(-c4ccccc4)ccc1O2)N3c1c(-c2ccccc2)cccc1-c1ccccc1]

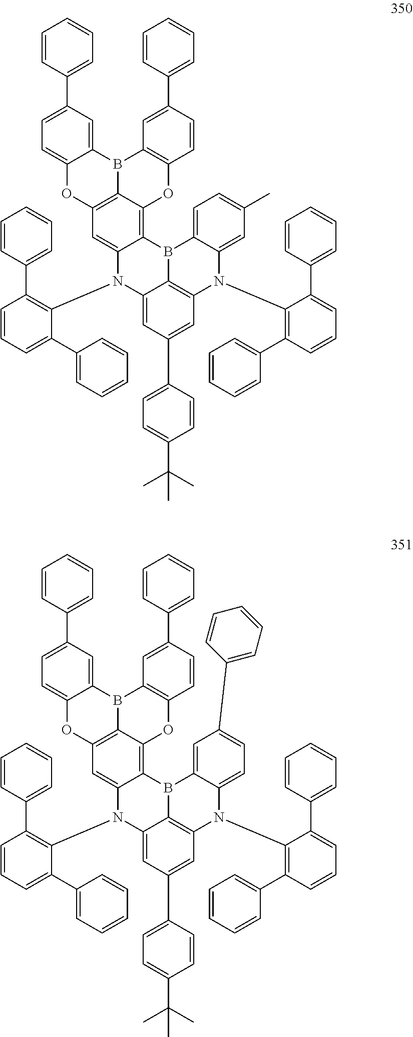 [SMILES: Cc1ccc2c(c1)N(c1c(-c3ccccc3)cccc1-c1ccccc1)c1cc(-c3ccc(C(C)(C)C)cc3)cc3c1B2c1c(cc2c4c1Oc1ccc(-c5ccccc5)cc1B4c1cc(-c4ccccc4)ccc1O2)N3c1c(-c2ccccc2)cccc1-c1ccccc1 ; CC(C)(C)c1ccc(-c2cc3c4c(c2)N(c2c(-c5ccccc5)cccc2-c2ccccc2)c2cc5c6c(c2B4c2cc(-c4ccccc4)ccc2N3c2c(-c3ccccc3)cccc2-c2ccccc2)Oc2ccc(-c3ccccc3)cc2B6c2cc(-c3ccccc3)ccc2O5)cc1]

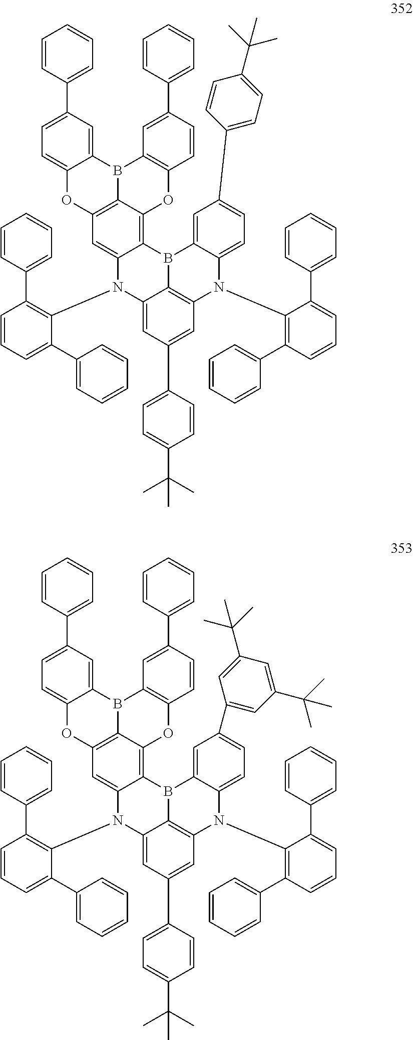 [SMILES: CC(C)(C)c1ccc(-c2ccc3c(c2)B2c4c(cc(-c5ccc(C(C)(C)C)cc5)cc4N(c4c(-c5ccccc5)cccc4-c4ccccc4)c4cc5c6c(c42)Oc2ccc(-c4ccccc4)cc2B6c2cc(-c4ccccc4)ccc2O5)N3c2c(-c3ccccc3)cccc2-c2ccccc2)cc1 ; CC(C)(C)c1ccc(-c2cc3c4c(c2)N(c2c(-c5ccccc5)cccc2-c2ccccc2)c2cc5c6c(c2B4c2cc(-c4cc(C(C)(C)C)cc(C(C)(C)C)c4)ccc2N3c2c(-c3ccccc3)cccc2-c2ccccc2)Oc2ccc(-c3ccccc3)cc2B6c2cc(-c3ccccc3)ccc2O5)cc1]

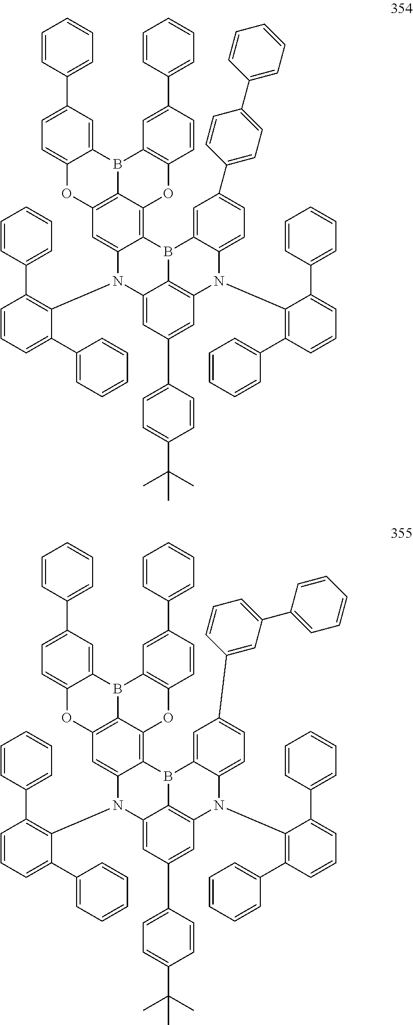 [SMILES: CC(C)(C)c1ccc(-c2cc3c4c(c2)N(c2c(-c5ccccc5)cccc2-c2ccccc2)c2cc5c6c(c2B4c2cc(-c4ccc(-c7ccccc7)cc4)ccc2N3c2c(-c3ccccc3)cccc2-c2ccccc2)Oc2ccc(-c3ccccc3)cc2B6c2cc(-c3ccccc3)ccc2O5)cc1 ; CC(C)(C)c1ccc(-c2cc3c4c(c2)N(c2c(-c5ccccc5)cccc2-c2ccccc2)c2cc5c6c(c2B4c2cc(-c4cccc(-c7ccccc7)c4)ccc2N3c2c(-c3ccccc3)cccc2-c2ccccc2)Oc2ccc(-c3ccccc3)cc2B6c2cc(-c3ccccc3)ccc2O5)cc1]

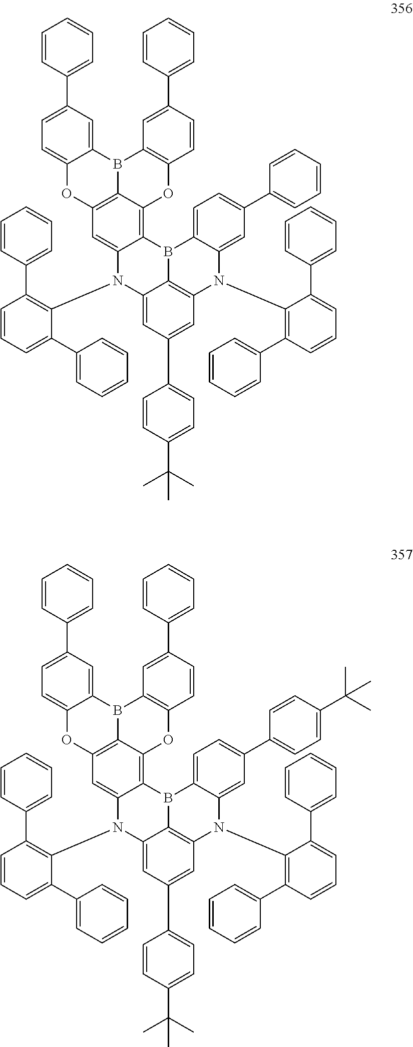 [SMILES: CC(C)(C)c1ccc(-c2cc3c4c(c2)N(c2c(-c5ccccc5)cccc2-c2ccccc2)c2cc5c6c(c2B4c2ccc(-c4ccccc4)cc2N3c2c(-c3ccccc3)cccc2-c2ccccc2)Oc2ccc(-c3ccccc3)cc2B6c2cc(-c3ccccc3)ccc2O5)cc1 ; CC(C)(C)c1ccc(-c2ccc3c(c2)N(c2c(-c4ccccc4)cccc2-c2ccccc2)c2cc(-c4ccc(C(C)(C)C)cc4)cc4c2B3c2c(cc3c5c2Oc2ccc(-c6ccccc6)cc2B5c2cc(-c5ccccc5)ccc2O3)N4c2c(-c3ccccc3)cccc2-c2ccccc2)cc1]

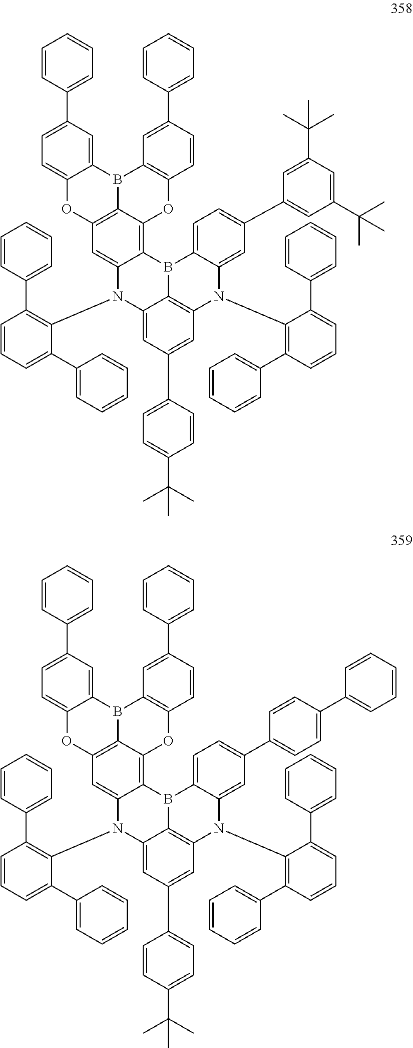 [SMILES: CC(C)(C)c1ccc(-c2cc3c4c(c2)N(c2c(-c5ccccc5)cccc2-c2ccccc2)c2cc5c6c(c2B4c2ccc(-c4cc(C(C)(C)C)cc(C(C)(C)C)c4)cc2N3c2c(-c3ccccc3)cccc2-c2ccccc2)Oc2ccc(-c3ccccc3)cc2B6c2cc(-c3ccccc3)ccc2O5)cc1 ; CC(C)(C)c1ccc(-c2cc3c4c(c2)N(c2c(-c5ccccc5)cccc2-c2ccccc2)c2cc5c6c(c2B4c2ccc(-c4ccc(-c7ccccc7)cc4)cc2N3c2c(-c3ccccc3)cccc2-c2ccccc2)Oc2ccc(-c3ccccc3)cc2B6c2cc(-c3ccccc3)ccc2O5)cc1]

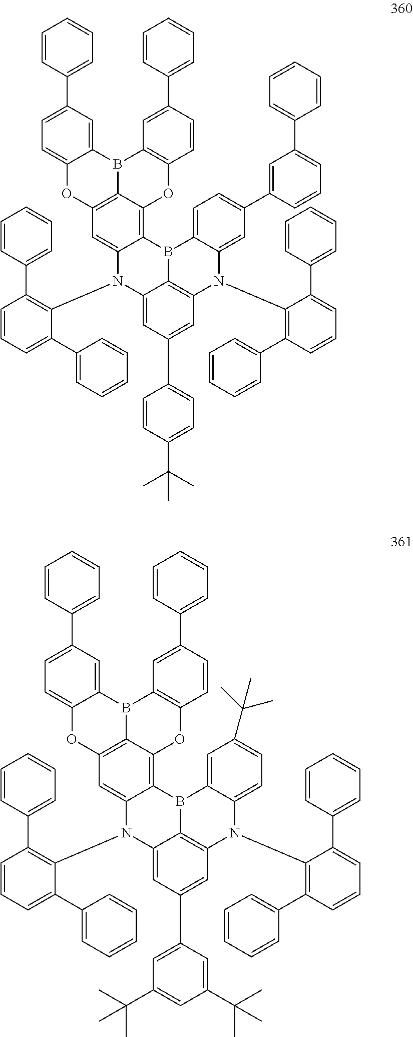 [SMILES: CC(C)(C)c1ccc(-c2cc3c4c(c2)N(c2c(-c5ccccc5)cccc2-c2ccccc2)c2cc5c6c(c2B4c2ccc(-c4cccc(-c7ccccc7)c4)cc2N3c2c(-c3ccccc3)cccc2-c2ccccc2)Oc2ccc(-c3ccccc3)cc2B6c2cc(-c3ccccc3)ccc2O5)cc1 ; CC(C)(C)c1cc(-c2cc3c4c(c2)N(c2c(-c5ccccc5)cccc2-c2ccccc2)c2cc5c6c(c2B4c2cc(C(C)(C)C)ccc2N3c2c(-c3ccccc3)cccc2-c2ccccc2)Oc2ccc(-c3ccccc3)cc2B6c2cc(-c3ccccc3)ccc2O5)cc(C(C)(C)C)c1]

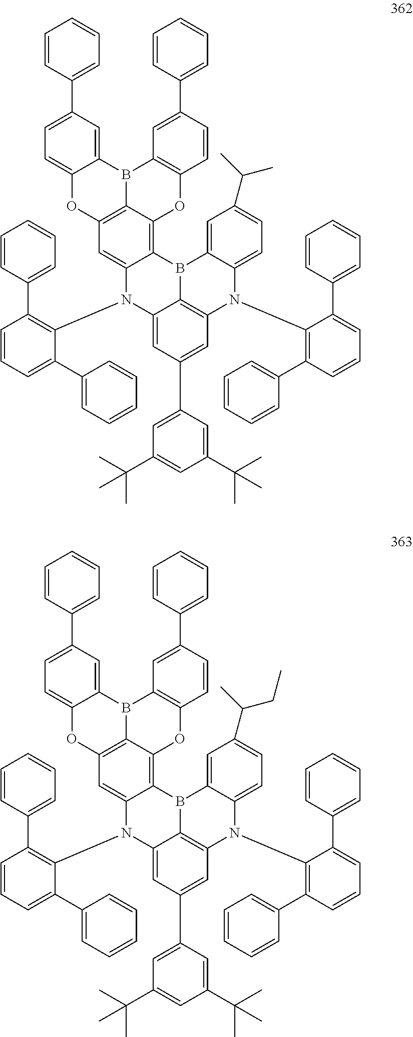 [SMILES: CC(C)c1ccc2c(c1)B1c3c(cc(-c4cc(C(C)(C)C)cc(C(C)(C)C)c4)cc3N(c3c(-c4ccccc4)cccc3-c3ccccc3)c3cc4c5c(c31)Oc1ccc(-c3ccccc3)cc1B5c1cc(-c3ccccc3)ccc1O4)N2c1c(-c2ccccc2)cccc1-c1ccccc1 ; CCC(C)c1ccc2c(c1)B1c3c(cc(-c4cc(C(C)(C)C)cc(C(C)(C)C)c4)cc3N(c3c(-c4ccccc4)cccc3-c3ccccc3)c3cc4c5c(c31)Oc1ccc(-c3ccccc3)cc1B5c1cc(-c3ccccc3)ccc1O4)N2c1c(-c2ccccc2)cccc1-c1ccccc1]

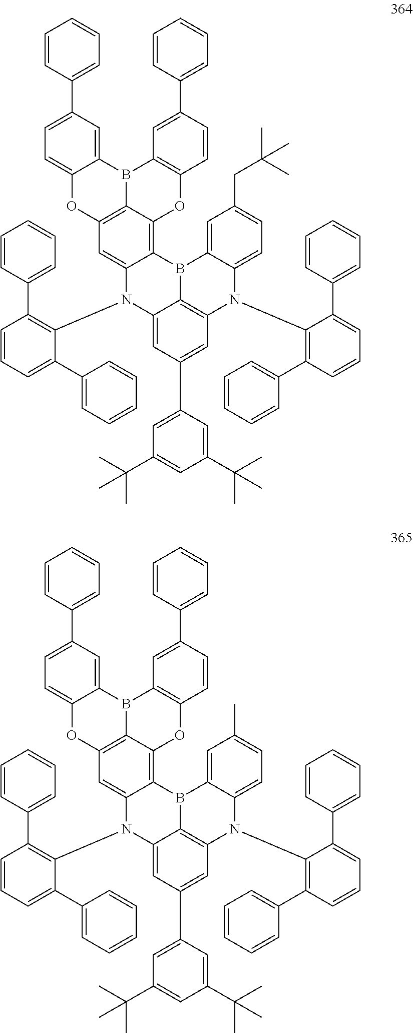 [SMILES: CC(C)(C)Cc1ccc2c(c1)B1c3c(cc(-c4cc(C(C)(C)C)cc(C(C)(C)C)c4)cc3N(c3c(-c4ccccc4)cccc3-c3ccccc3)c3cc4c5c(c31)Oc1ccc(-c3ccccc3)cc1B5c1cc(-c3ccccc3)ccc1O4)N2c1c(-c2ccccc2)cccc1-c1ccccc1 ; Cc1ccc2c(c1)B1c3c(cc(-c4cc(C(C)(C)C)cc(C(C)(C)C)c4)cc3N(c3c(-c4ccccc4)cccc3-c3ccccc3)c3cc4c5c(c31)Oc1ccc(-c3ccccc3)cc1B5c1cc(-c3ccccc3)ccc1O4)N2c1c(-c2ccccc2)cccc1-c1ccccc1]

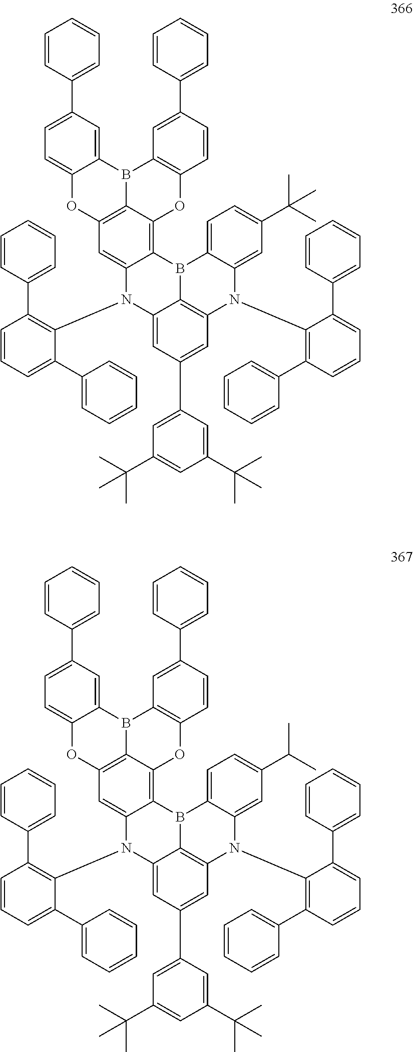 [SMILES: CC(C)(C)c1cc(-c2cc3c4c(c2)N(c2c(-c5ccccc5)cccc2-c2ccccc2)c2cc5c6c(c2B4c2ccc(C(C)(C)C)cc2N3c2c(-c3ccccc3)cccc2-c2ccccc2)Oc2ccc(-c3ccccc3)cc2B6c2cc(-c3ccccc3)ccc2O5)cc(C(C)(C)C)c1 ; CC(C)c1ccc2c(c1)N(c1c(-c3ccccc3)cccc1-c1ccccc1)c1cc(-c3cc(C(C)(C)C)cc(C(C)(C)C)c3)cc3c1B2c1c(cc2c4c1Oc1ccc(-c5ccccc5)cc1B4c1cc(-c4ccccc4)ccc1O2)N3c1c(-c2ccccc2)cccc1-c1ccccc1]

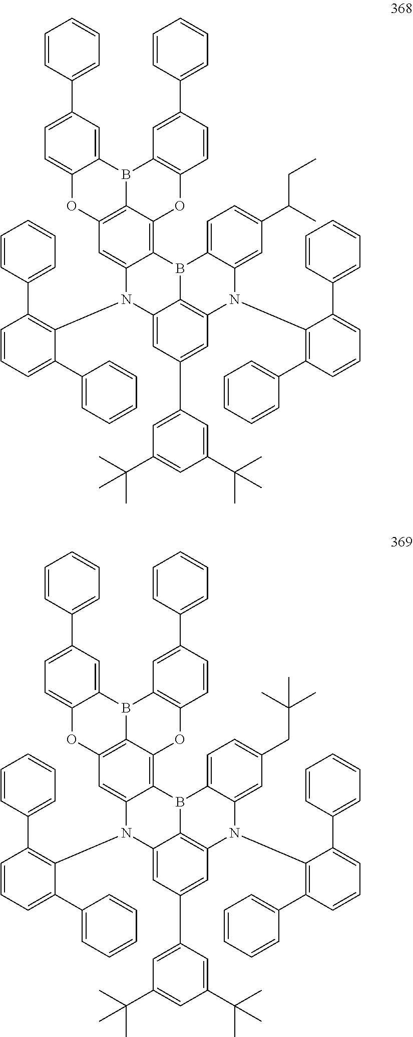 [SMILES: CCC(C)c1ccc2c(c1)N(c1c(-c3ccccc3)cccc1-c1ccccc1)c1cc(-c3cc(C(C)(C)C)cc(C(C)(C)C)c3)cc3c1B2c1c(cc2c4c1Oc1ccc(-c5ccccc5)cc1B4c1cc(-c4ccccc4)ccc1O2)N3c1c(-c2ccccc2)cccc1-c1ccccc1 ; CC(C)(C)Cc1ccc2c(c1)N(c1c(-c3ccccc3)cccc1-c1ccccc1)c1cc(-c3cc(C(C)(C)C)cc(C(C)(C)C)c3)cc3c1B2c1c(cc2c4c1Oc1ccc(-c5ccccc5)cc1B4c1cc(-c4ccccc4)ccc1O2)N3c1c(-c2ccccc2)cccc1-c1ccccc1]

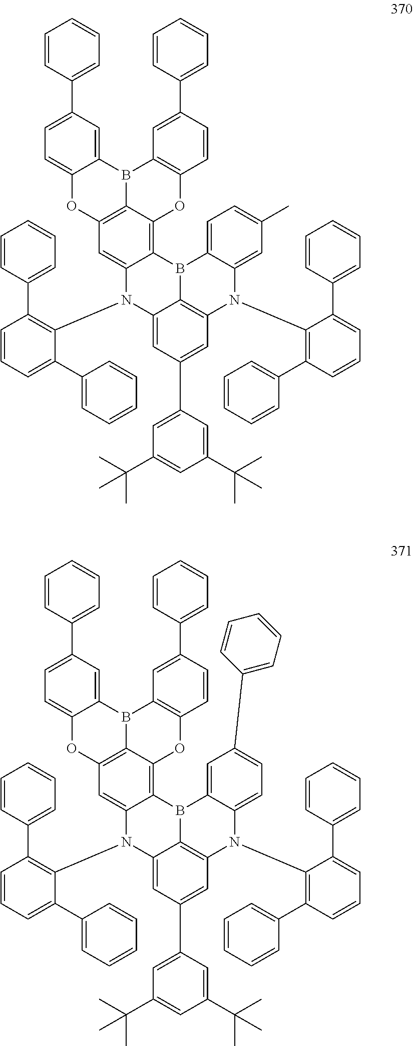 [SMILES: Cc1ccc2c(c1)N(c1c(-c3ccccc3)cccc1-c1ccccc1)c1cc(-c3cc(C(C)(C)C)cc(C(C)(C)C)c3)cc3c1B2c1c(cc2c4c1Oc1ccc(-c5ccccc5)cc1B4c1cc(-c4ccccc4)ccc1O2)N3c1c(-c2ccccc2)cccc1-c1ccccc1 ; CC(C)(C)c1cc(-c2cc3c4c(c2)N(c2c(-c5ccccc5)cccc2-c2ccccc2)c2cc5c6c(c2B4c2cc(-c4ccccc4)ccc2N3c2c(-c3ccccc3)cccc2-c2ccccc2)Oc2ccc(-c3ccccc3)cc2B6c2cc(-c3ccccc3)ccc2O5)cc(C(C)(C)C)c1]

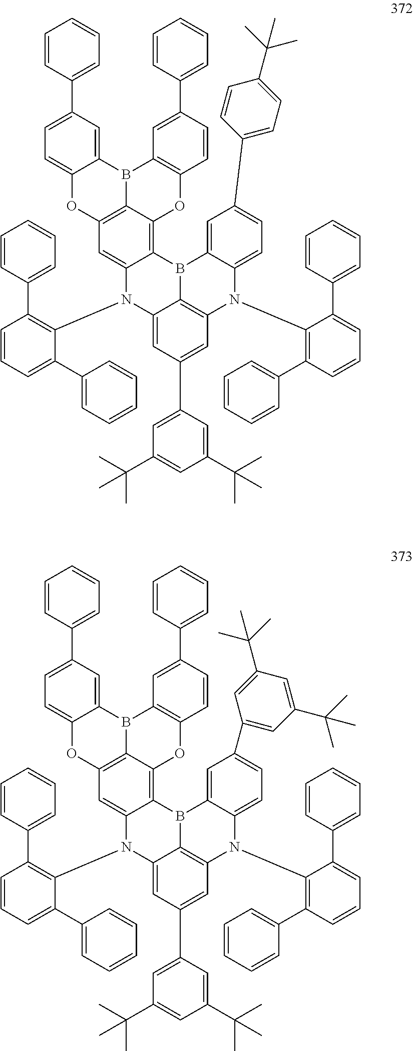 [SMILES: CC(C)(C)c1ccc(-c2ccc3c(c2)B2c4c(cc(-c5cc(C(C)(C)C)cc(C(C)(C)C)c5)cc4N(c4c(-c5ccccc5)cccc4-c4ccccc4)c4cc5c6c(c42)Oc2ccc(-c4ccccc4)cc2B6c2cc(-c4ccccc4)ccc2O5)N3c2c(-c3ccccc3)cccc2-c2ccccc2)cc1 ; CC(C)(C)c1cc(-c2ccc3c(c2)B2c4c(cc(-c5cc(C(C)(C)C)cc(C(C)(C)C)c5)cc4N(c4c(-c5ccccc5)cccc4-c4ccccc4)c4cc5c6c(c42)Oc2ccc(-c4ccccc4)cc2B6c2cc(-c4ccccc4)ccc2O5)N3c2c(-c3ccccc3)cccc2-c2ccccc2)cc(C(C)(C)C)c1]

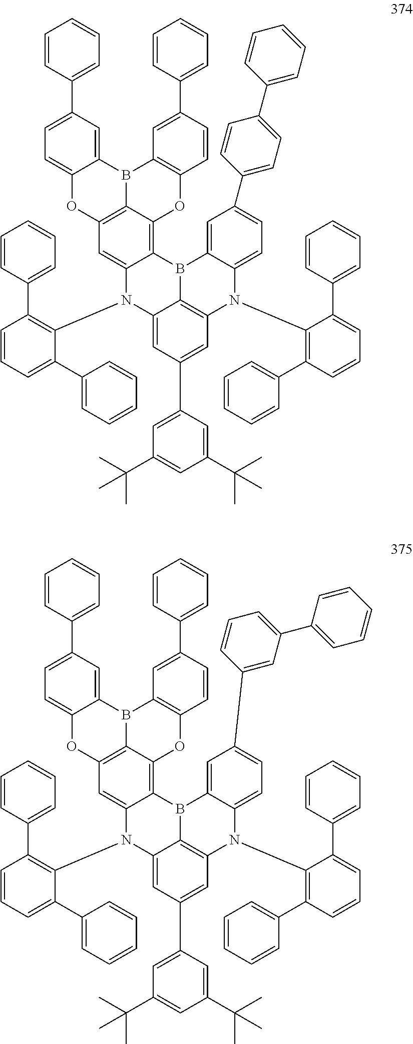 [SMILES: CC(C)(C)c1cc(-c2cc3c4c(c2)N(c2c(-c5ccccc5)cccc2-c2ccccc2)c2cc5c6c(c2B4c2cc(-c4ccc(-c7ccccc7)cc4)ccc2N3c2c(-c3ccccc3)cccc2-c2ccccc2)Oc2ccc(-c3ccccc3)cc2B6c2cc(-c3ccccc3)ccc2O5)cc(C(C)(C)C)c1 ; CC(C)(C)c1cc(-c2cc3c4c(c2)N(c2c(-c5ccccc5)cccc2-c2ccccc2)c2cc5c6c(c2B4c2cc(-c4cccc(-c7ccccc7)c4)ccc2N3c2c(-c3ccccc3)cccc2-c2ccccc2)Oc2ccc(-c3ccccc3)cc2B6c2cc(-c3ccccc3)ccc2O5)cc(C(C)(C)C)c1]

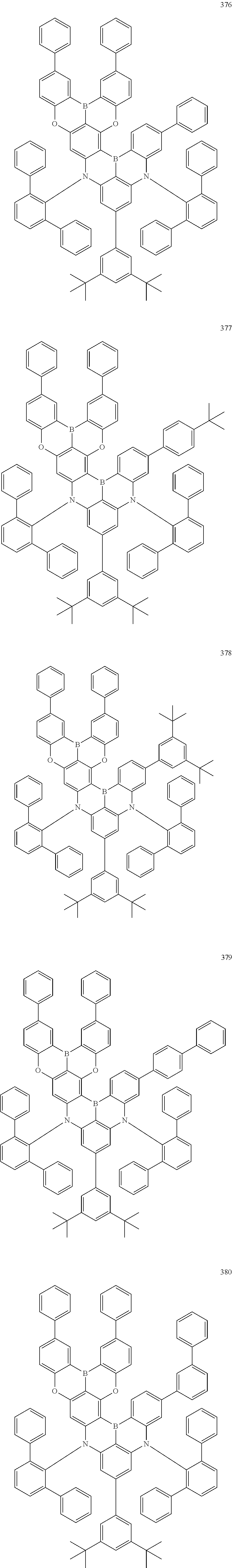

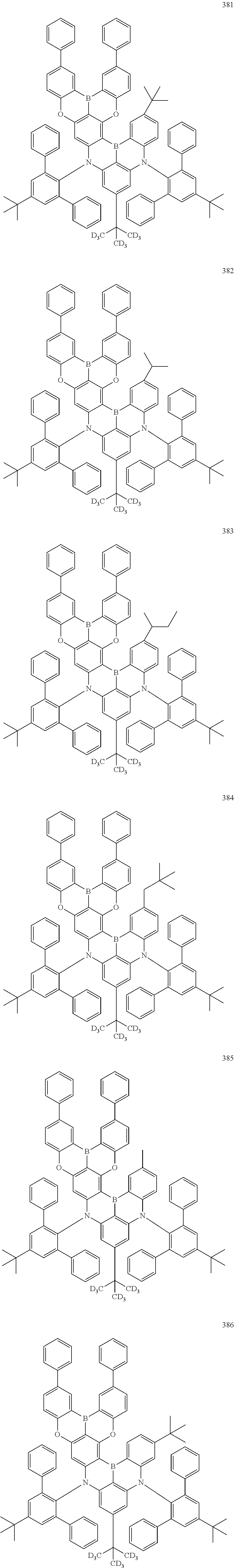

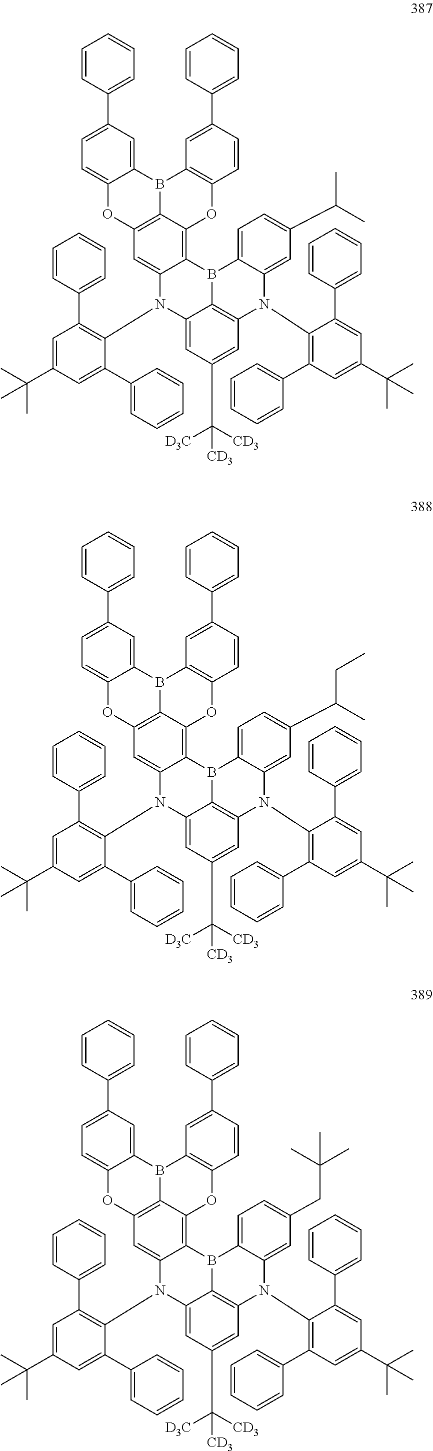

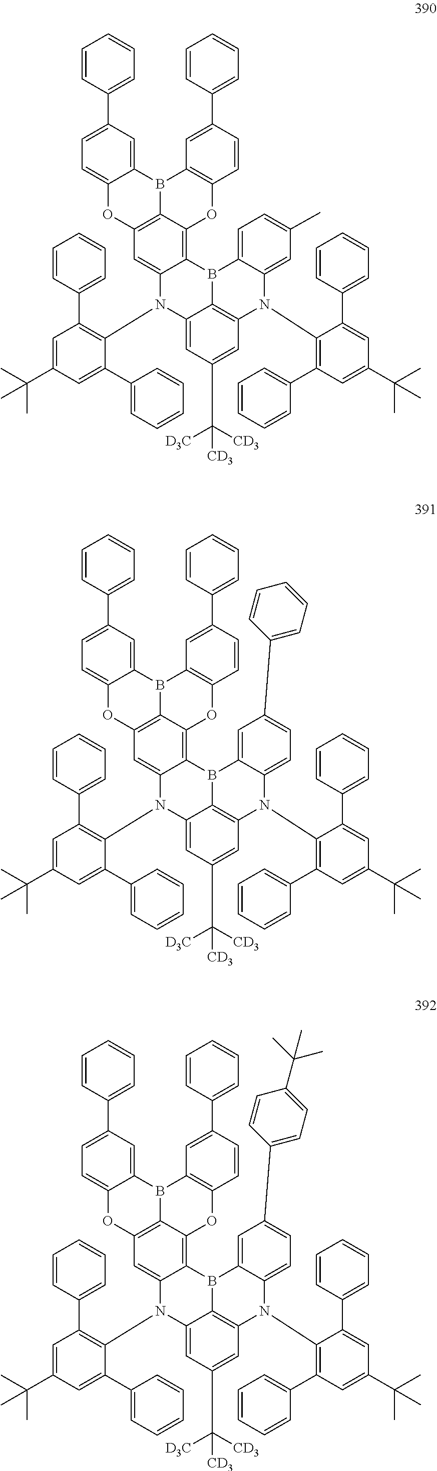

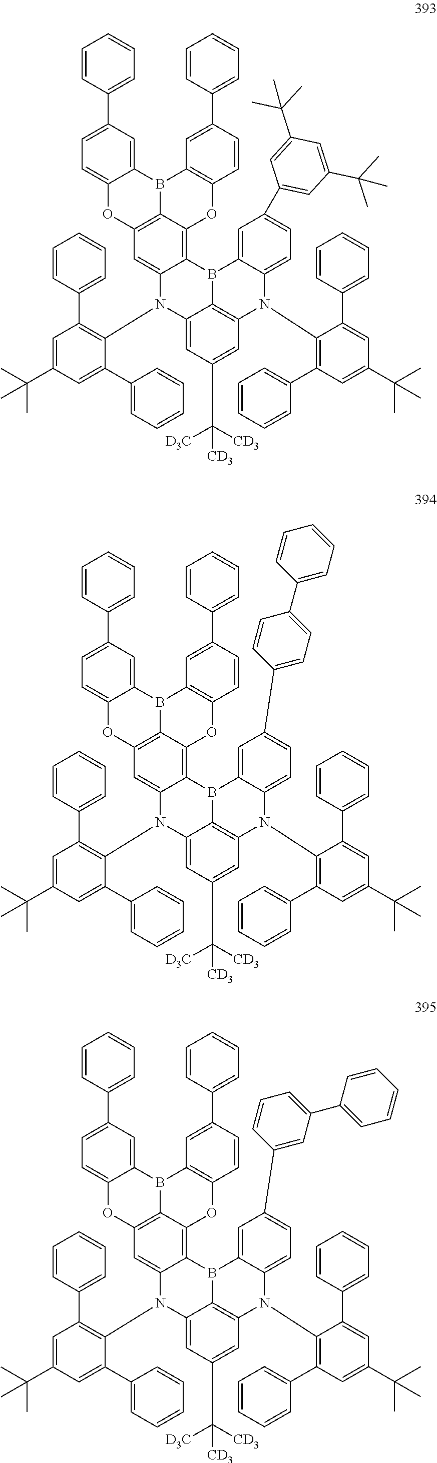

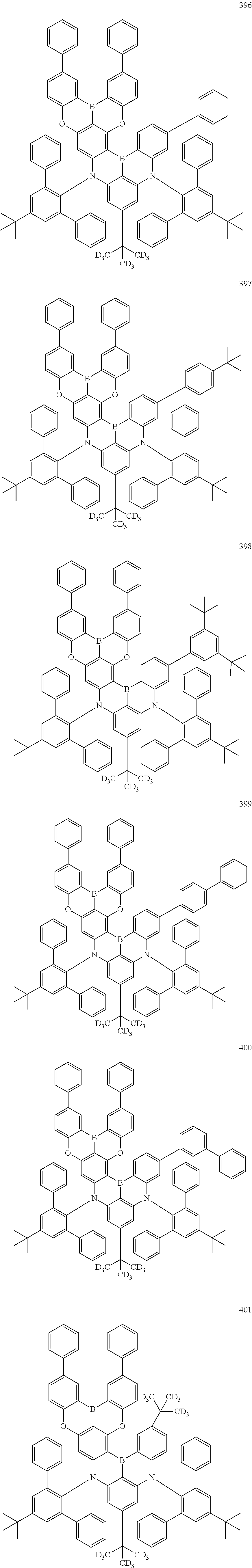

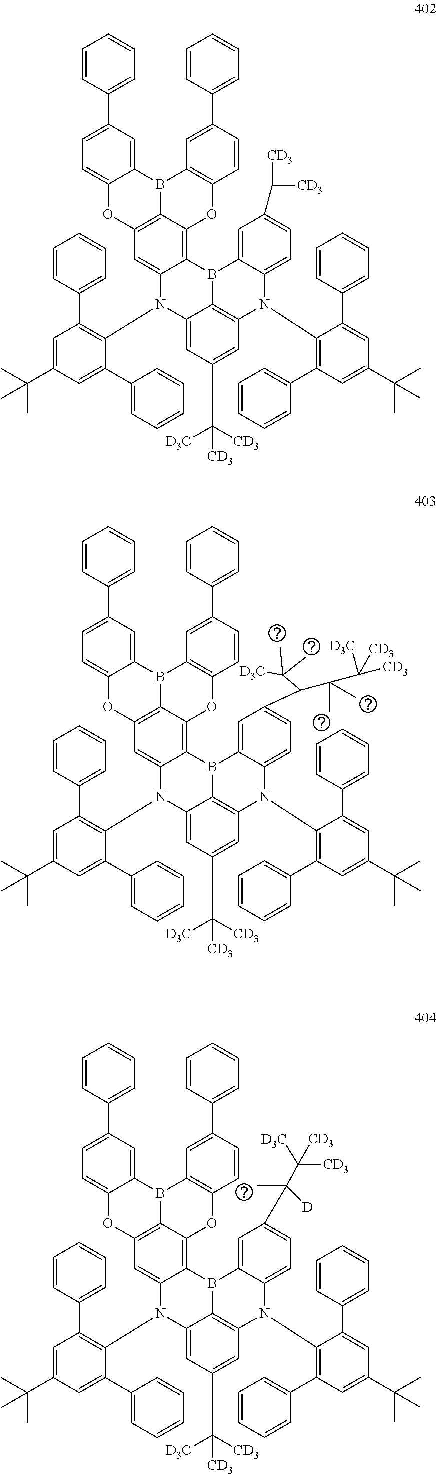

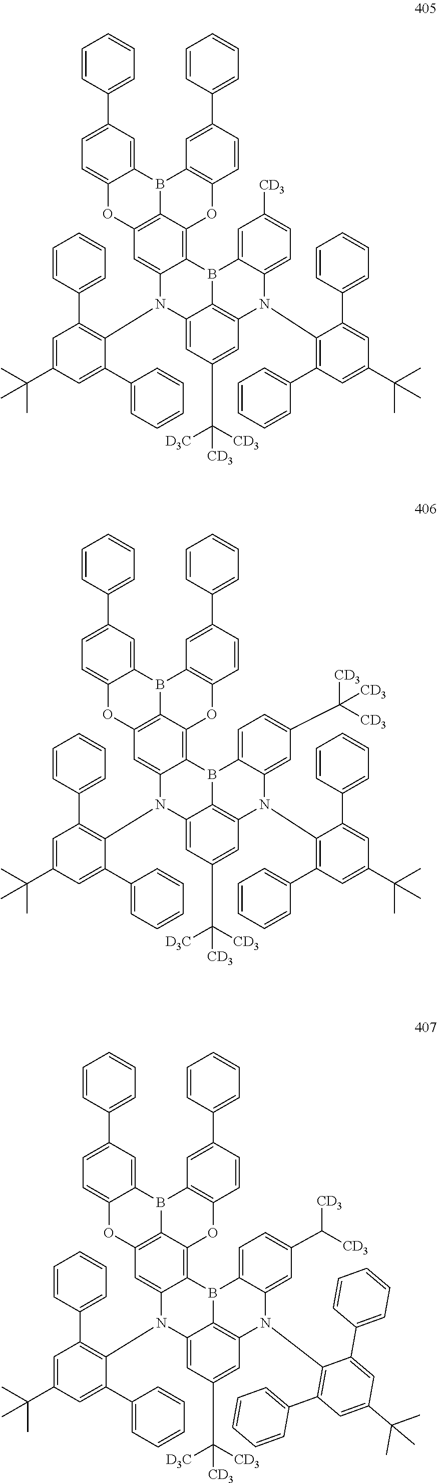

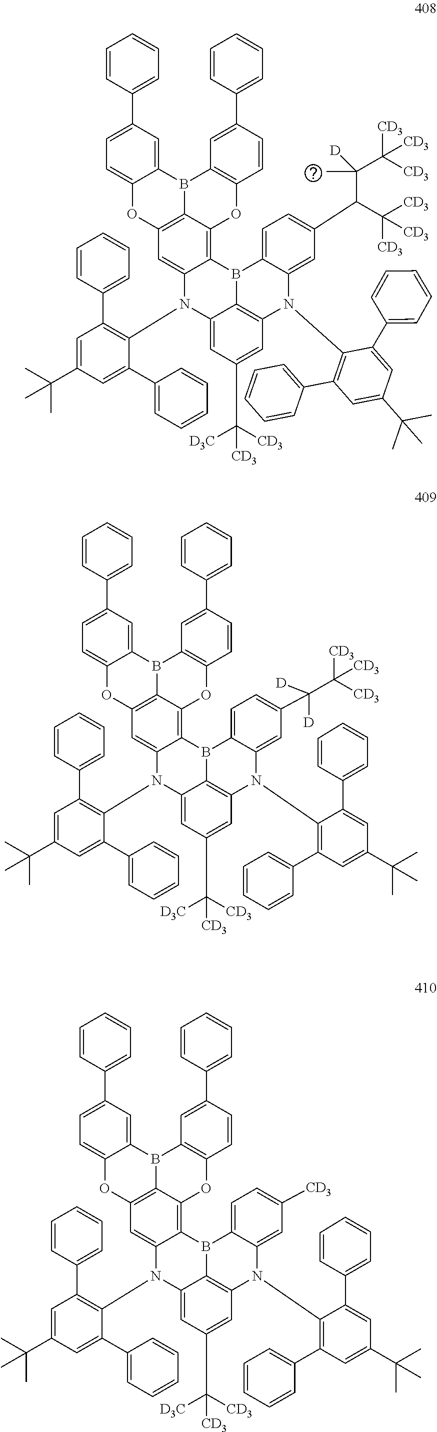

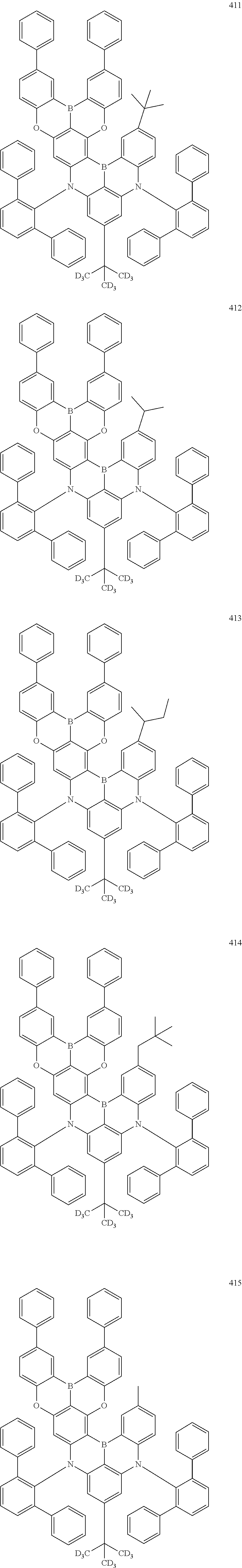

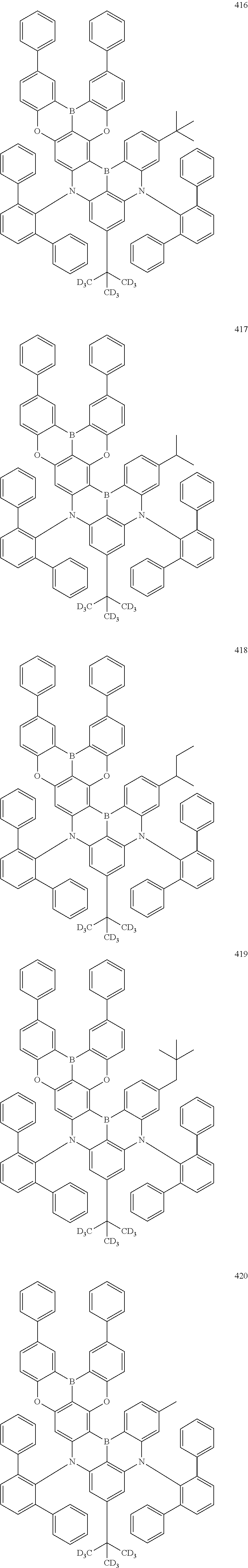

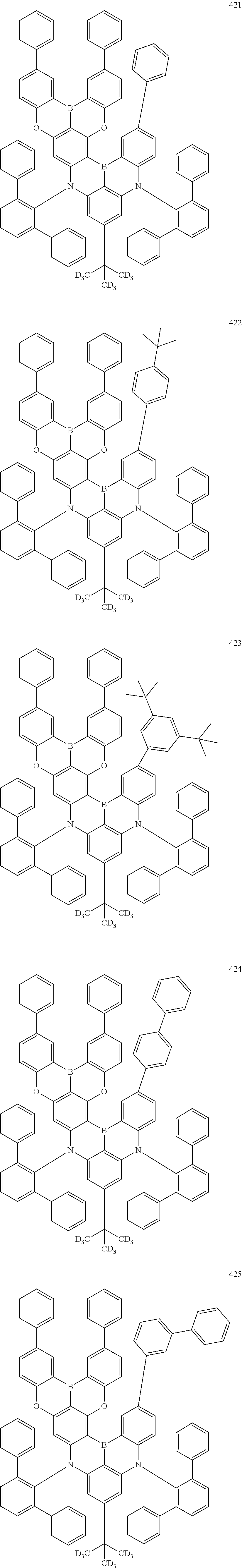

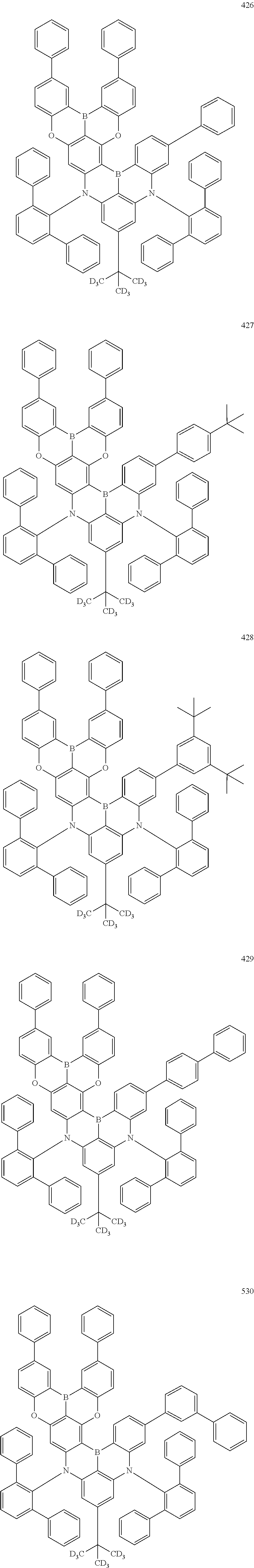

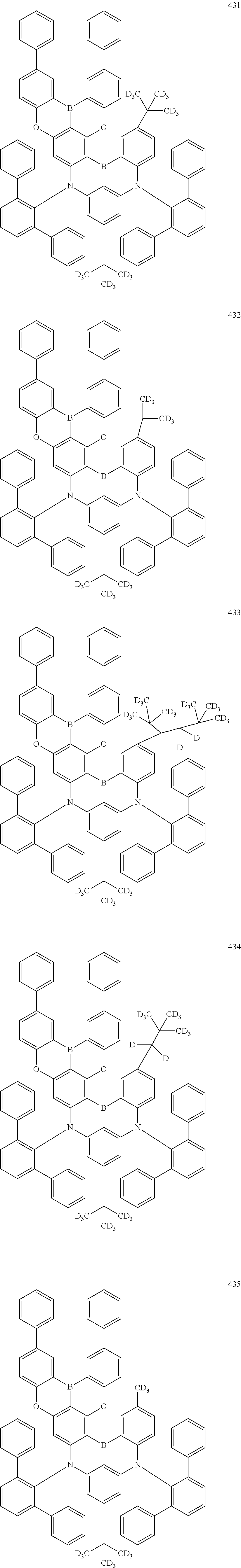

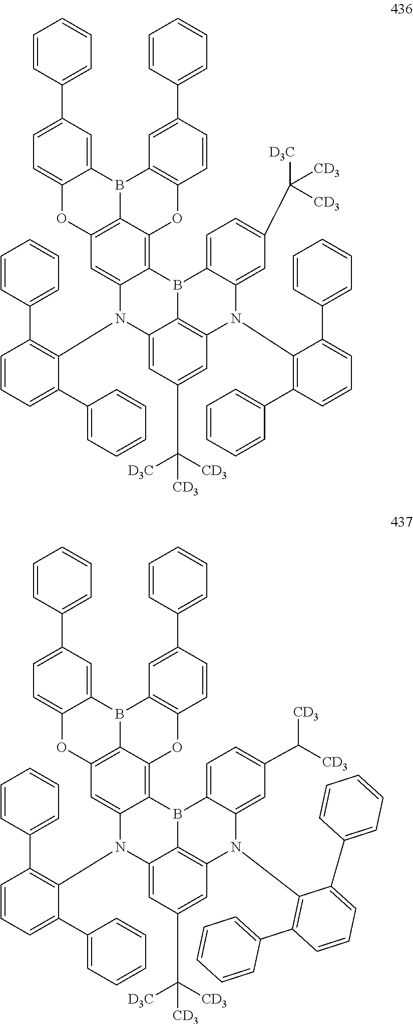 [SMILES: [2H]C([2H])([2H])C(c1ccc2c(c1)N(c1c(-c3ccccc3)cccc1-c1ccccc1)c1cc(C(C([2H])([2H])[2H])(C([2H])([2H])[2H])C([2H])([2H])[2H])cc3c1B2c1c(cc2c4c1Oc1ccc(-c5ccccc5)cc1B4c1cc(-c4ccccc4)ccc1O2)N3c1c(-c2ccccc2)cccc1-c1ccccc1)(C([2H])([2H])[2H])C([2H])([2H])[2H] ; [2H]C([2H])([2H])C(c1ccc2c(c1)N(c1c(-c3ccccc3)cccc1-c1ccccc1)c1cc(C(C([2H])([2H])[2H])(C([2H])([2H])[2H])C([2H])([2H])[2H])cc3c1B2c1c(cc2c4c1Oc1ccc(-c5ccccc5)cc1B4c1cc(-c4ccccc4)ccc1O2)N3c1c(-c2ccccc2)cccc1-c1ccccc1)C([2H])([2H])[2H]]

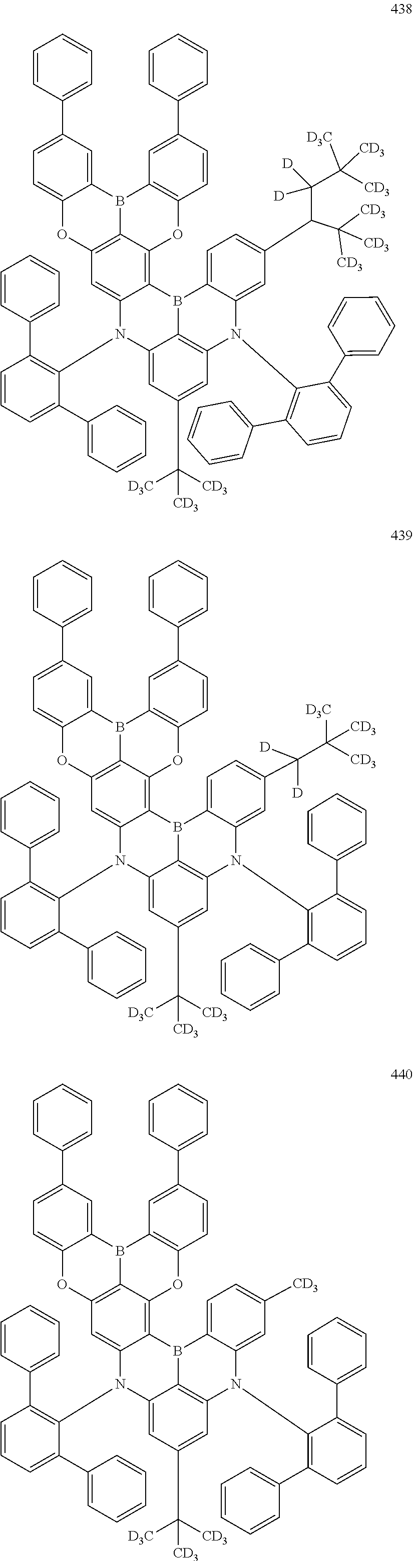

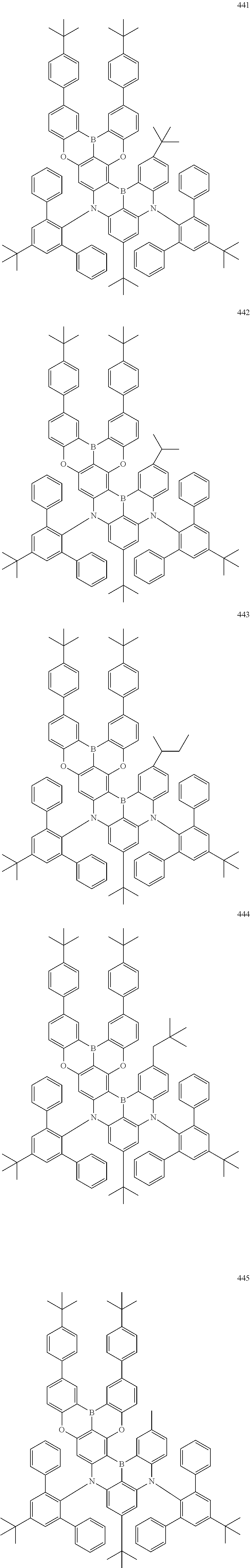

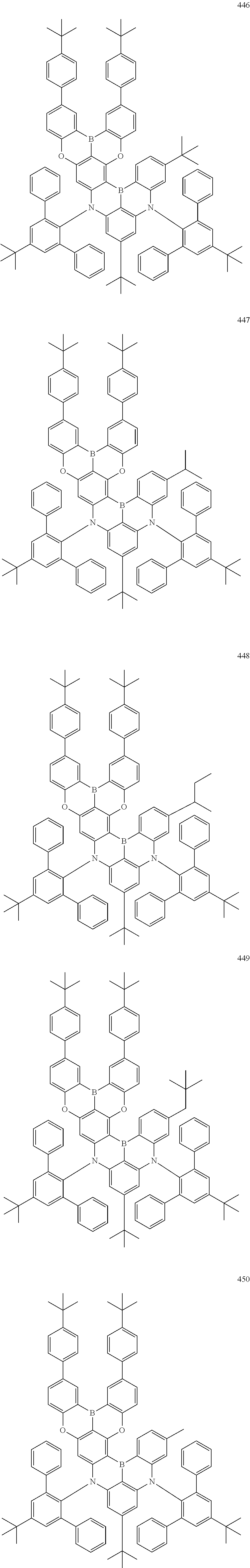

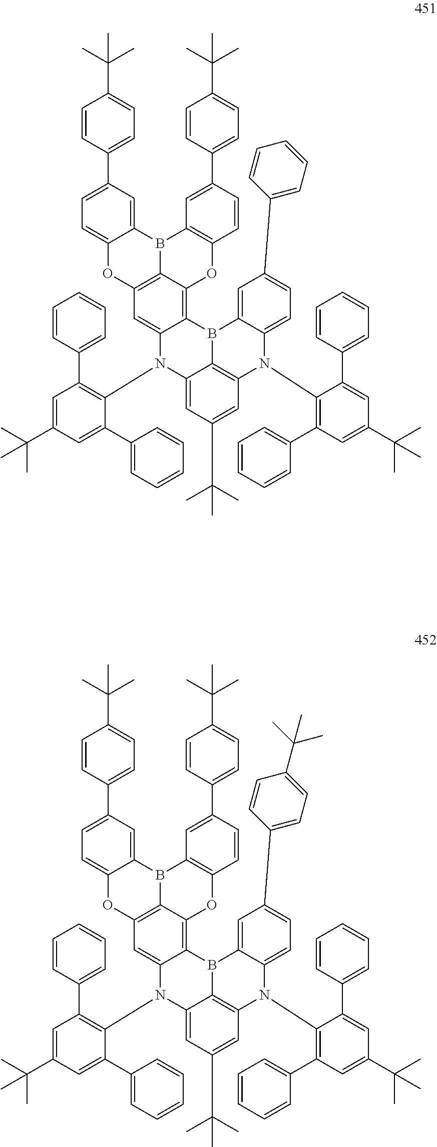

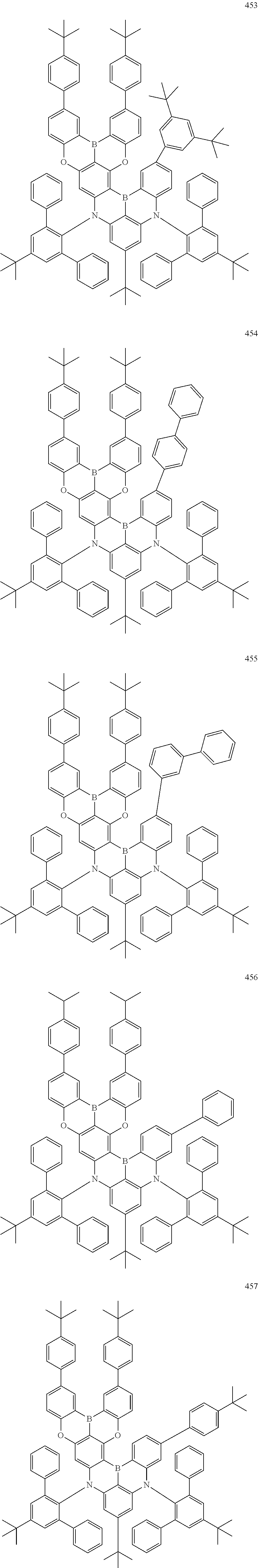

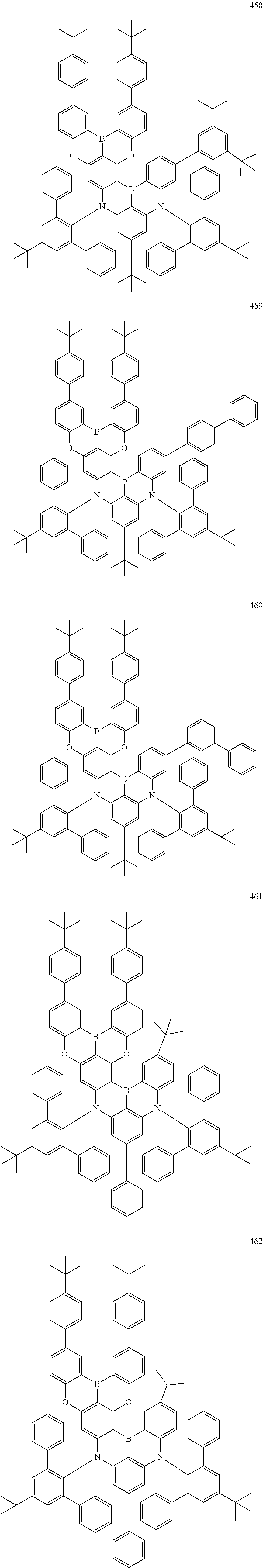

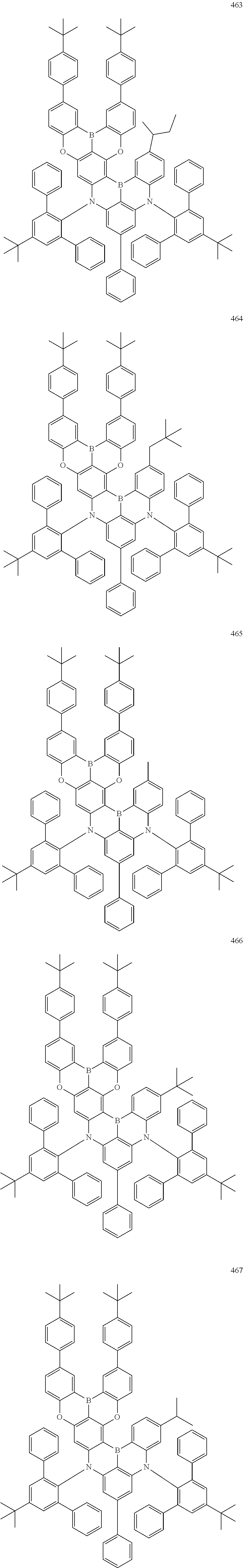

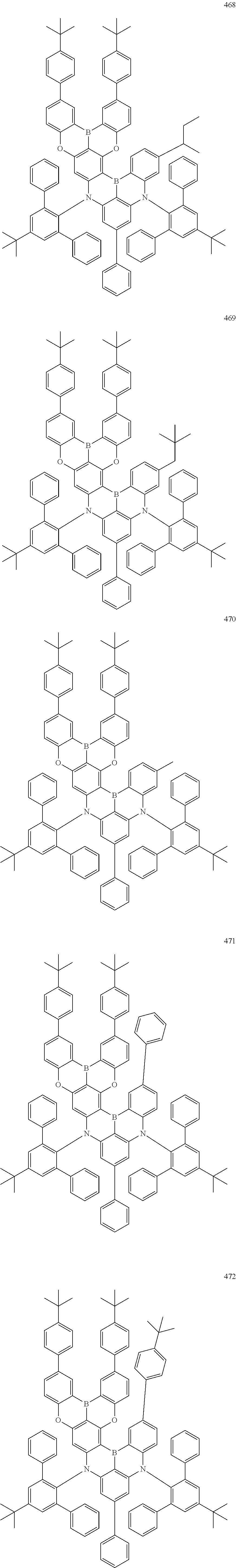

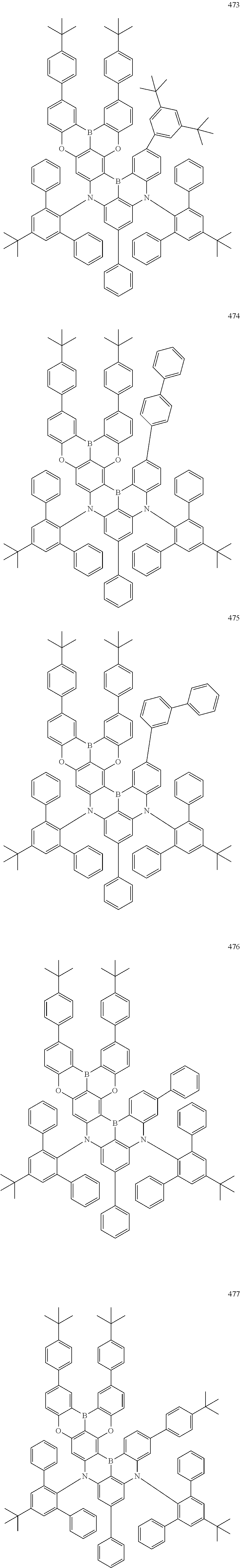

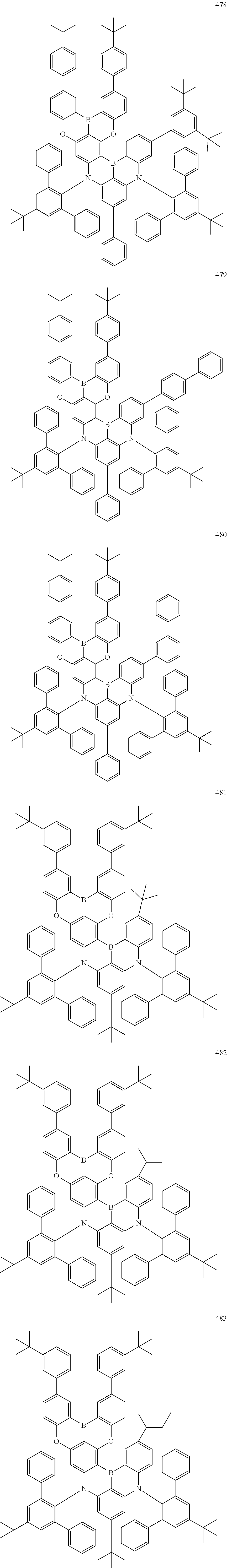

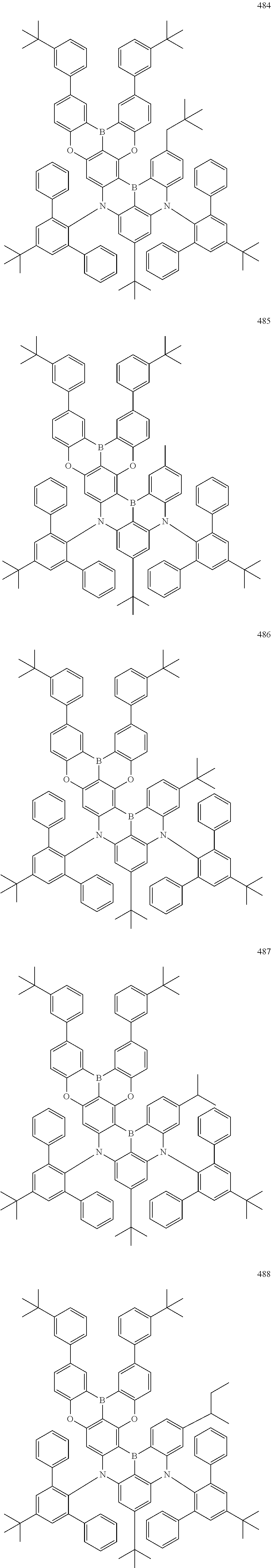

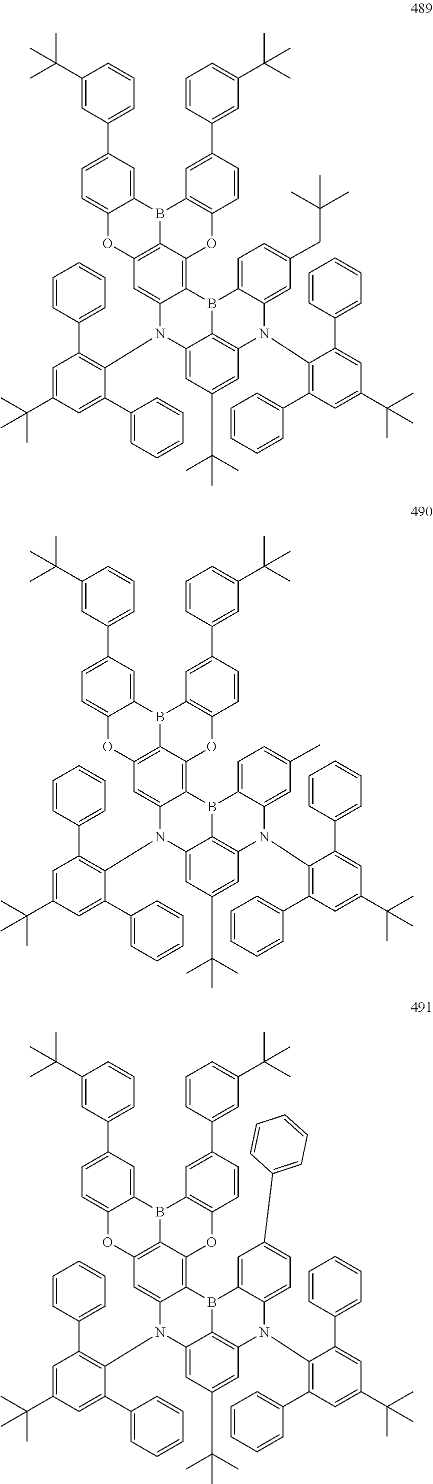

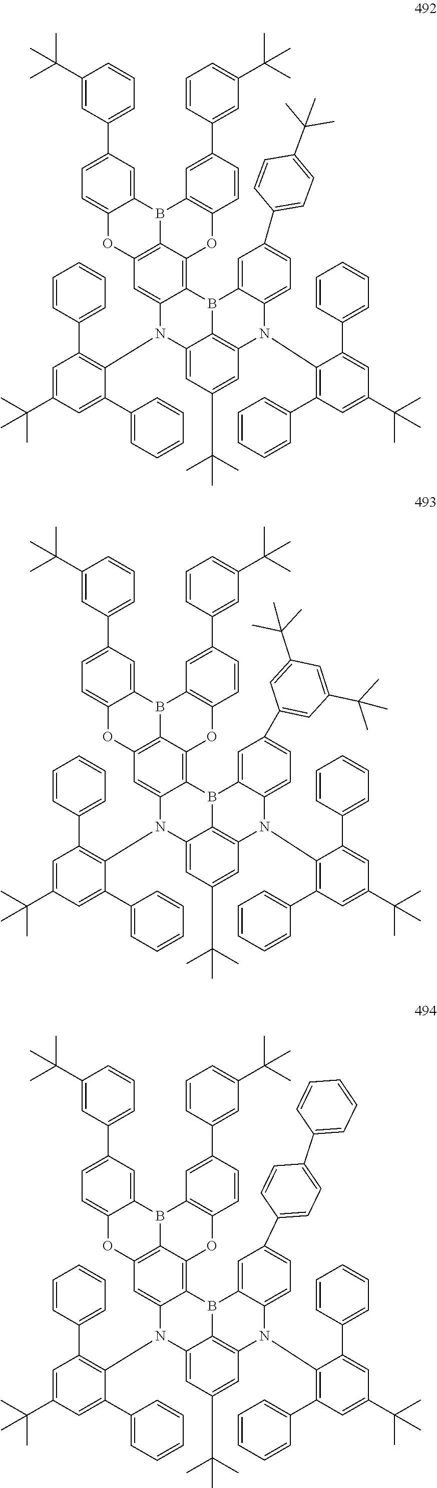

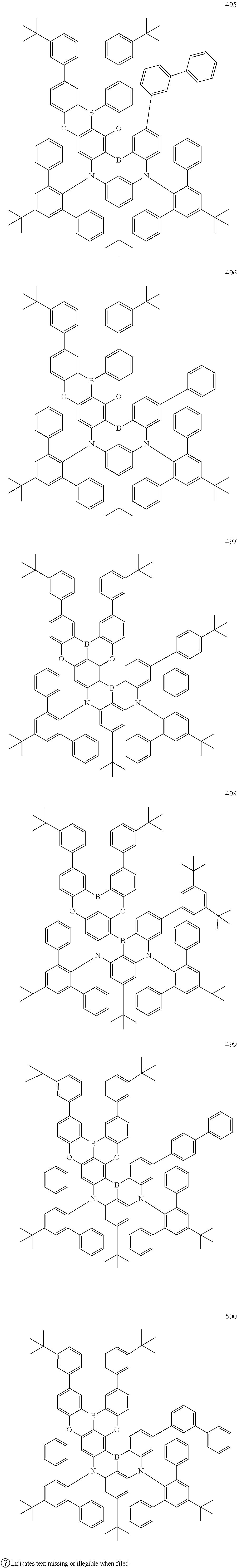

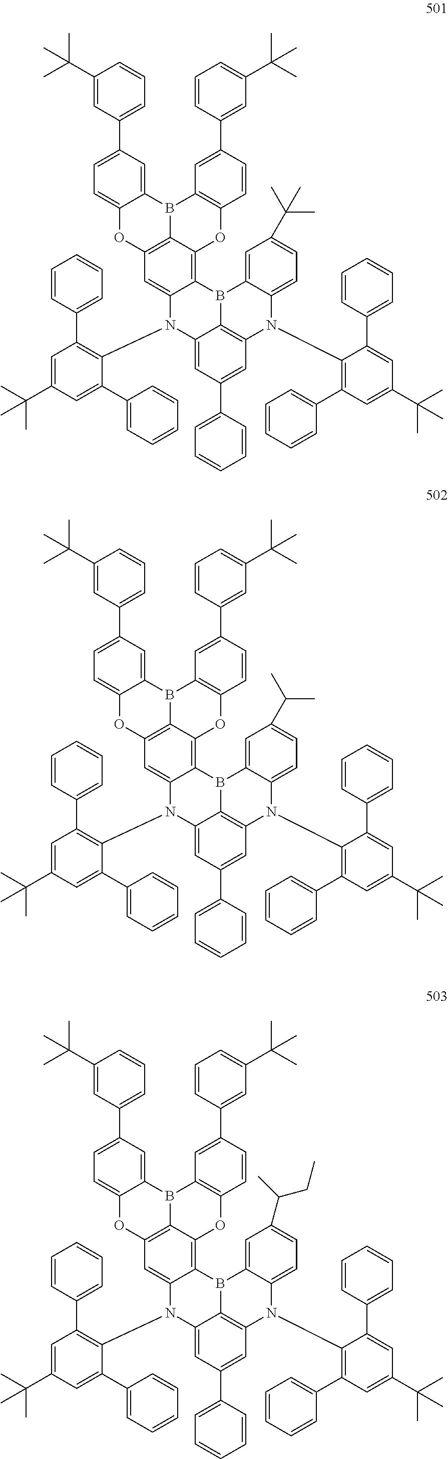

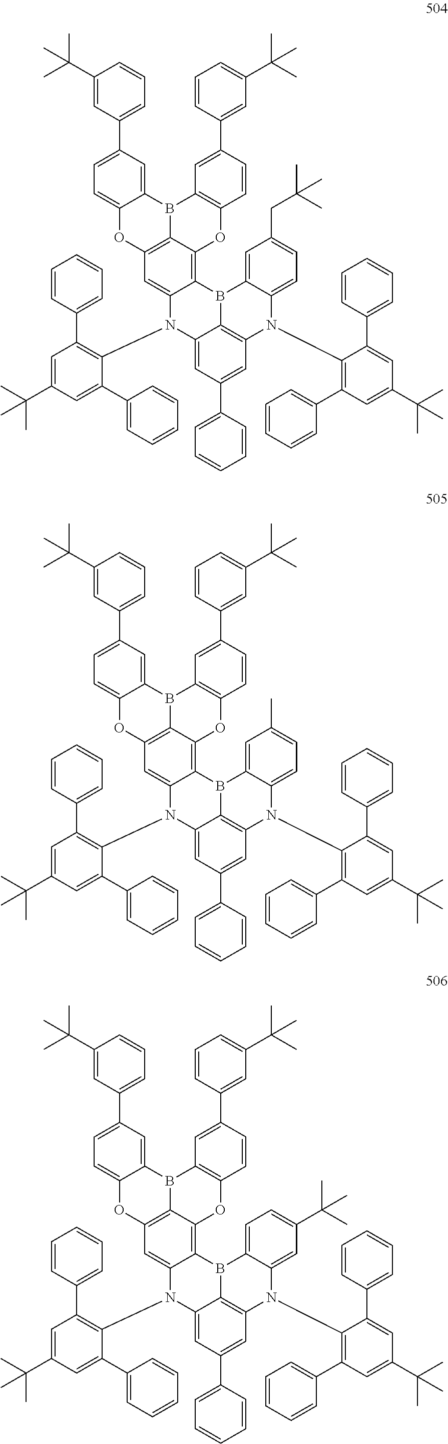

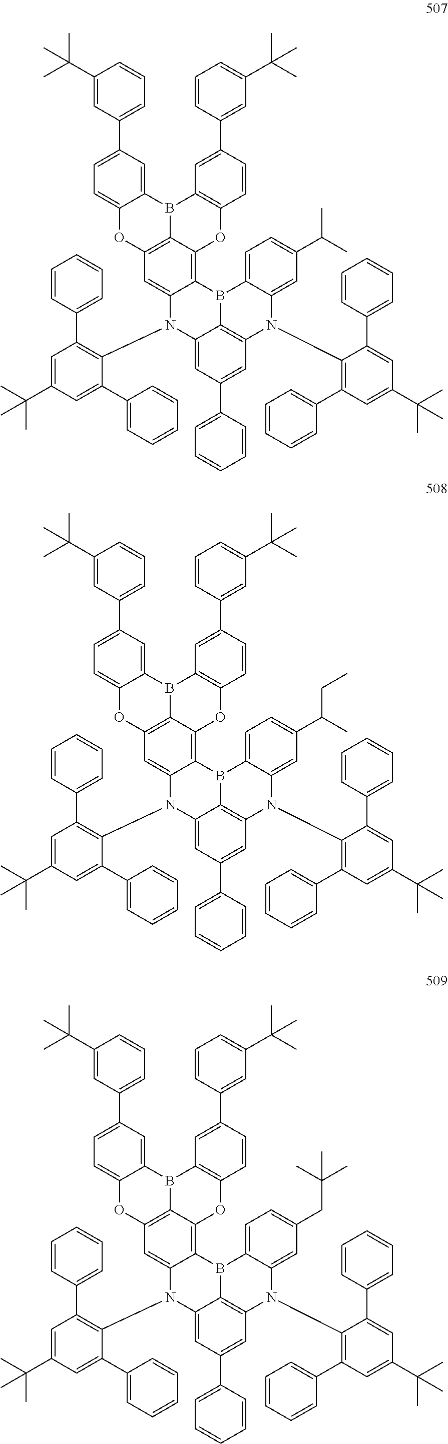

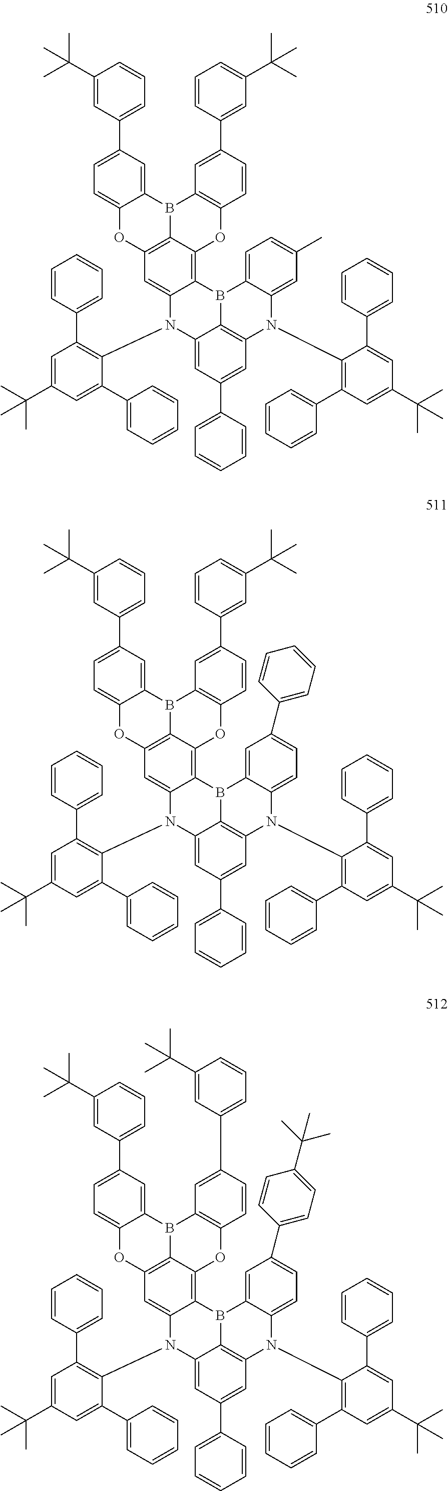

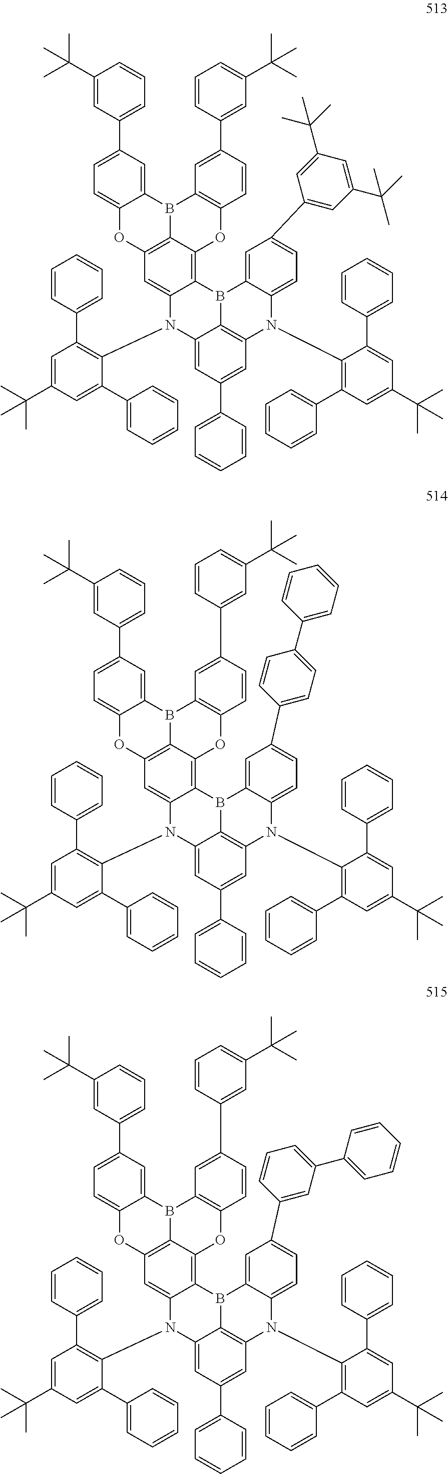

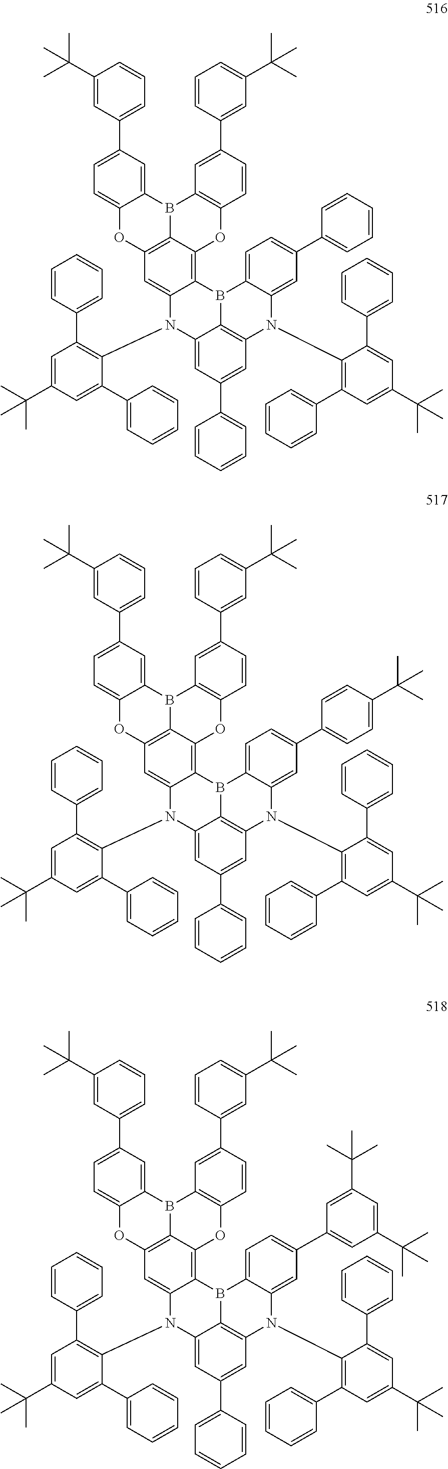

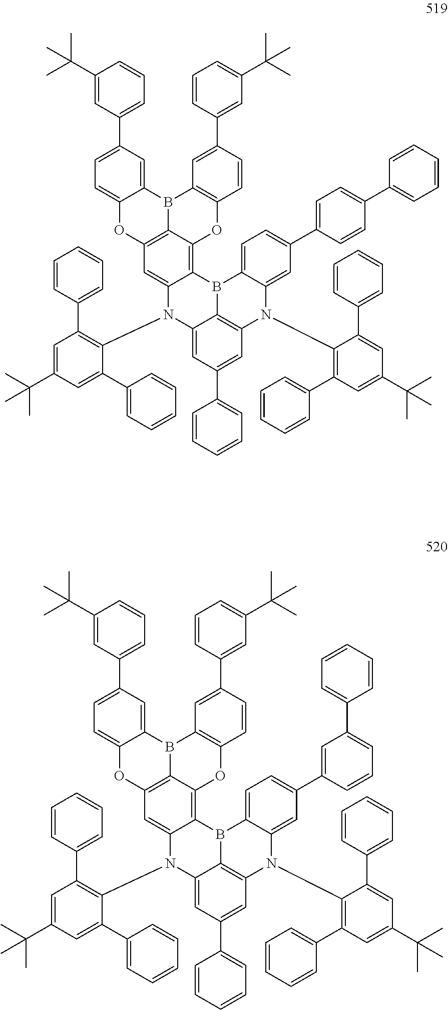 [SMILES: CC(C)(C)c1cccc(-c2ccc3c(c2)B2c4cc(-c5cccc(C(C)(C)C)c5)ccc4Oc4c2c(cc2c4B4c5ccc(-c6ccc(-c7ccccc7)cc6)cc5N(c5c(-c6ccccc6)cc(C(C)(C)C)cc5-c5ccccc5)c5cc(-c6ccccc6)cc(c54)N2c2c(-c4ccccc4)cc(C(C)(C)C)cc2-c2ccccc2)O3)c1 ; CC(C)(C)c1cccc(-c2ccc3c(c2)B2c4cc(-c5cccc(C(C)(C)C)c5)ccc4Oc4c2c(cc2c4B4c5ccc(-c6cccc(-c7ccccc7)c6)cc5N(c5c(-c6ccccc6)cc(C(C)(C)C)cc5-c5ccccc5)c5cc(-c6ccccc6)cc(c54)N2c2c(-c4ccccc4)cc(C(C)(C)C)cc2-c2ccccc2)O3)c1]

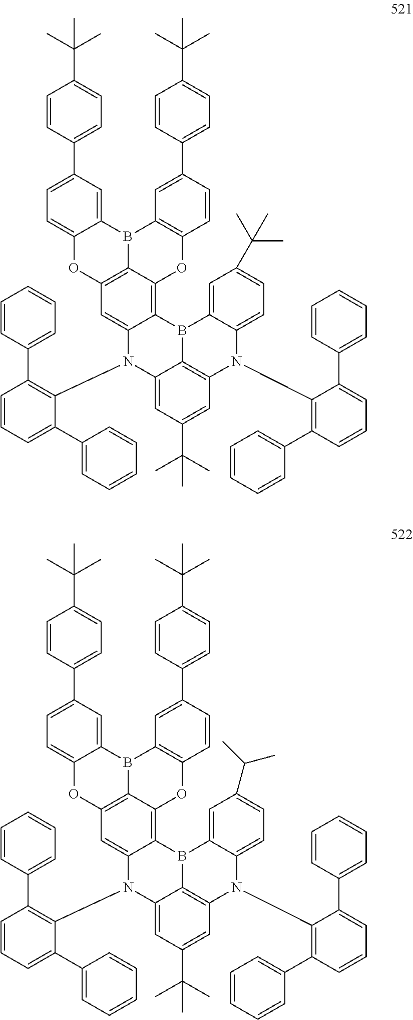 [SMILES: CC(C)(C)c1ccc(-c2ccc3c(c2)B2c4cc(-c5ccc(C(C)(C)C)cc5)ccc4Oc4c2c(cc2c4B4c5cc(C(C)(C)C)ccc5N(c5c(-c6ccccc6)cccc5-c5ccccc5)c5cc(C(C)(C)C)cc(c54)N2c2c(-c4ccccc4)cccc2-c2ccccc2)O3)cc1 ; CC(C)c1ccc2c(c1)B1c3c(cc(C(C)(C)C)cc3N(c3c(-c4ccccc4)cccc3-c3ccccc3)c3cc4c5c(c31)Oc1ccc(-c3ccc(C(C)(C)C)cc3)cc1B5c1cc(-c3ccc(C(C)(C)C)cc3)ccc1O4)N2c1c(-c2ccccc2)cccc1-c1ccccc1]

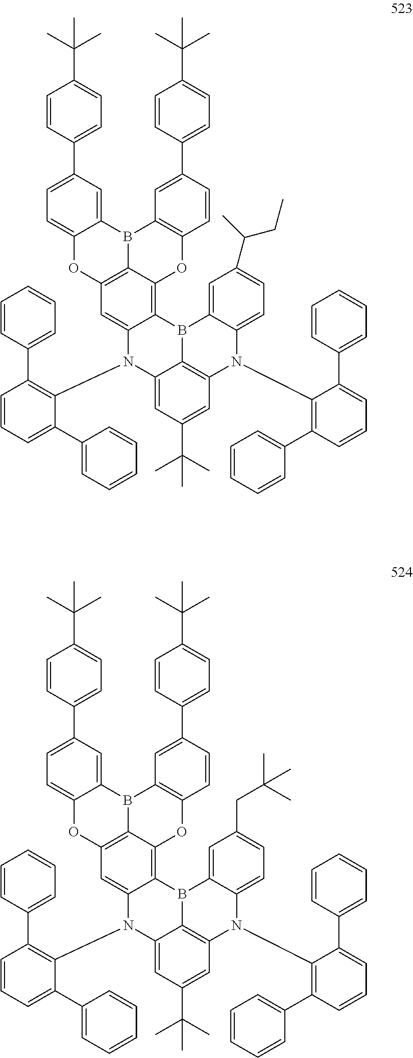 [SMILES: CCC(C)c1ccc2c(c1)B1c3c(cc(C(C)(C)C)cc3N(c3c(-c4ccccc4)cccc3-c3ccccc3)c3cc4c5c(c31)Oc1ccc(-c3ccc(C(C)(C)C)cc3)cc1B5c1cc(-c3ccc(C(C)(C)C)cc3)ccc1O4)N2c1c(-c2ccccc2)cccc1-c1ccccc1 ; CC(C)(C)Cc1ccc2c(c1)B1c3c(cc(C(C)(C)C)cc3N(c3c(-c4ccccc4)cccc3-c3ccccc3)c3cc4c5c(c31)Oc1ccc(-c3ccc(C(C)(C)C)cc3)cc1B5c1cc(-c3ccc(C(C)(C)C)cc3)ccc1O4)N2c1c(-c2ccccc2)cccc1-c1ccccc1]

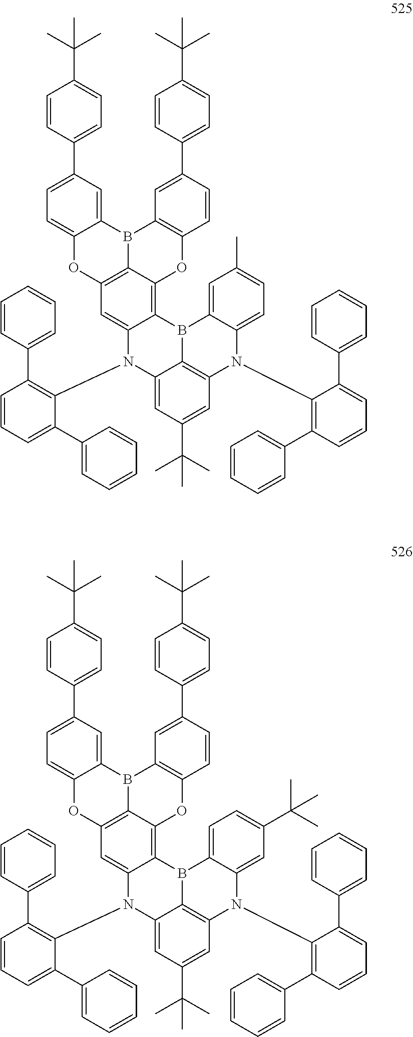 [SMILES: Cc1ccc2c(c1)B1c3c(cc(C(C)(C)C)cc3N(c3c(-c4ccccc4)cccc3-c3ccccc3)c3cc4c5c(c31)Oc1ccc(-c3ccc(C(C)(C)C)cc3)cc1B5c1cc(-c3ccc(C(C)(C)C)cc3)ccc1O4)N2c1c(-c2ccccc2)cccc1-c1ccccc1 ; CC(C)(C)c1ccc(-c2ccc3c(c2)B2c4cc(-c5ccc(C(C)(C)C)cc5)ccc4Oc4c2c(cc2c4B4c5ccc(C(C)(C)C)cc5N(c5c(-c6ccccc6)cccc5-c5ccccc5)c5cc(C(C)(C)C)cc(c54)N2c2c(-c4ccccc4)cccc2-c2ccccc2)O3)cc1]

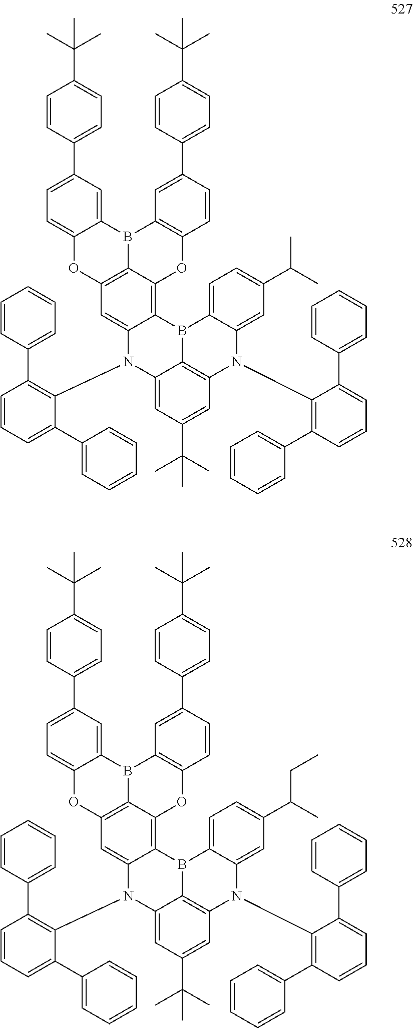 [SMILES: CC(C)c1ccc2c(c1)N(c1c(-c3ccccc3)cccc1-c1ccccc1)c1cc(C(C)(C)C)cc3c1B2c1c(cc2c4c1Oc1ccc(-c5ccc(C(C)(C)C)cc5)cc1B4c1cc(-c4ccc(C(C)(C)C)cc4)ccc1O2)N3c1c(-c2ccccc2)cccc1-c1ccccc1 ; CCC(C)c1ccc2c(c1)N(c1c(-c3ccccc3)cccc1-c1ccccc1)c1cc(C(C)(C)C)cc3c1B2c1c(cc2c4c1Oc1ccc(-c5ccc(C(C)(C)C)cc5)cc1B4c1cc(-c4ccc(C(C)(C)C)cc4)ccc1O2)N3c1c(-c2ccccc2)cccc1-c1ccccc1]

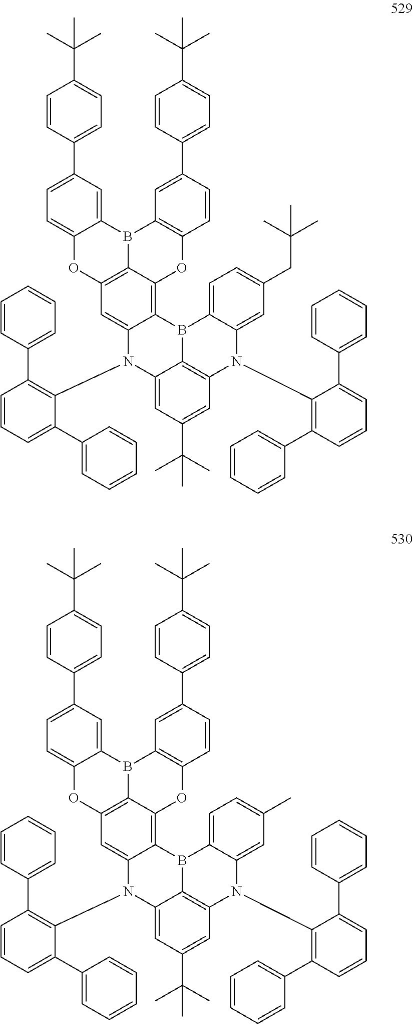 [SMILES: CC(C)(C)Cc1ccc2c(c1)N(c1c(-c3ccccc3)cccc1-c1ccccc1)c1cc(C(C)(C)C)cc3c1B2c1c(cc2c4c1Oc1ccc(-c5ccc(C(C)(C)C)cc5)cc1B4c1cc(-c4ccc(C(C)(C)C)cc4)ccc1O2)N3c1c(-c2ccccc2)cccc1-c1ccccc1 ; Cc1ccc2c(c1)N(c1c(-c3ccccc3)cccc1-c1ccccc1)c1cc(C(C)(C)C)cc3c1B2c1c(cc2c4c1Oc1ccc(-c5ccc(C(C)(C)C)cc5)cc1B4c1cc(-c4ccc(C(C)(C)C)cc4)ccc1O2)N3c1c(-c2ccccc2)cccc1-c1ccccc1]

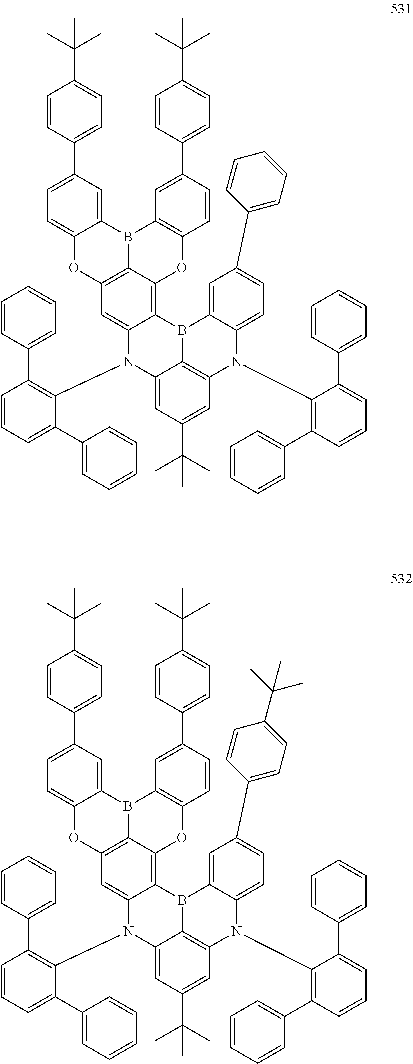 [SMILES: CC(C)(C)c1ccc(-c2ccc3c(c2)B2c4cc(-c5ccc(C(C)(C)C)cc5)ccc4Oc4c2c(cc2c4B4c5cc(-c6ccccc6)ccc5N(c5c(-c6ccccc6)cccc5-c5ccccc5)c5cc(C(C)(C)C)cc(c54)N2c2c(-c4ccccc4)cccc2-c2ccccc2)O3)cc1 ; CC(C)(C)c1ccc(-c2ccc3c(c2)B2c4cc(-c5ccc(C(C)(C)C)cc5)ccc4Oc4c2c(cc2c4B4c5cc(-c6ccc(C(C)(C)C)cc6)ccc5N(c5c(-c6ccccc6)cccc5-c5ccccc5)c5cc(C(C)(C)C)cc(c54)N2c2c(-c4ccccc4)cccc2-c2ccccc2)O3)cc1]

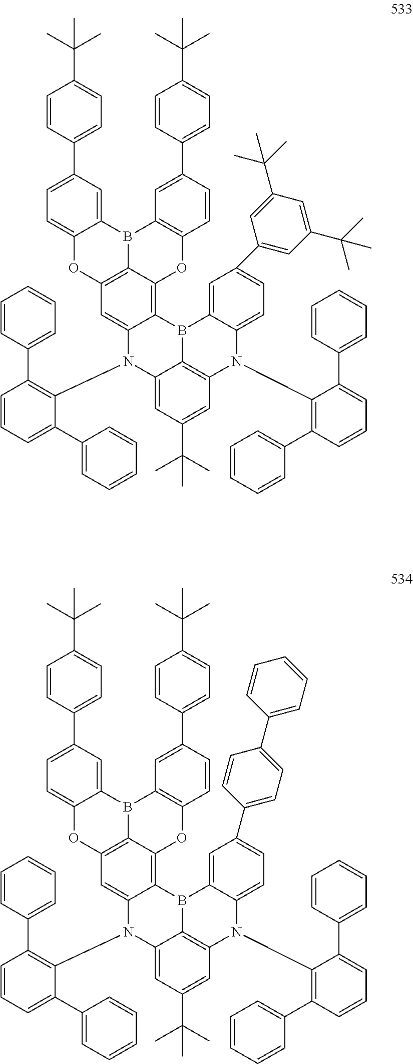 [SMILES: CC(C)(C)c1ccc(-c2ccc3c(c2)B2c4cc(-c5ccc(C(C)(C)C)cc5)ccc4Oc4c2c(cc2c4B4c5cc(-c6cc(C(C)(C)C)cc(C(C)(C)C)c6)ccc5N(c5c(-c6ccccc6)cccc5-c5ccccc5)c5cc(C(C)(C)C)cc(c54)N2c2c(-c4ccccc4)cccc2-c2ccccc2)O3)cc1 ; CC(C)(C)c1ccc(-c2ccc3c(c2)B2c4cc(-c5ccc(C(C)(C)C)cc5)ccc4Oc4c2c(cc2c4B4c5cc(-c6ccc(-c7ccccc7)cc6)ccc5N(c5c(-c6ccccc6)cccc5-c5ccccc5)c5cc(C(C)(C)C)cc(c54)N2c2c(-c4ccccc4)cccc2-c2ccccc2)O3)cc1]

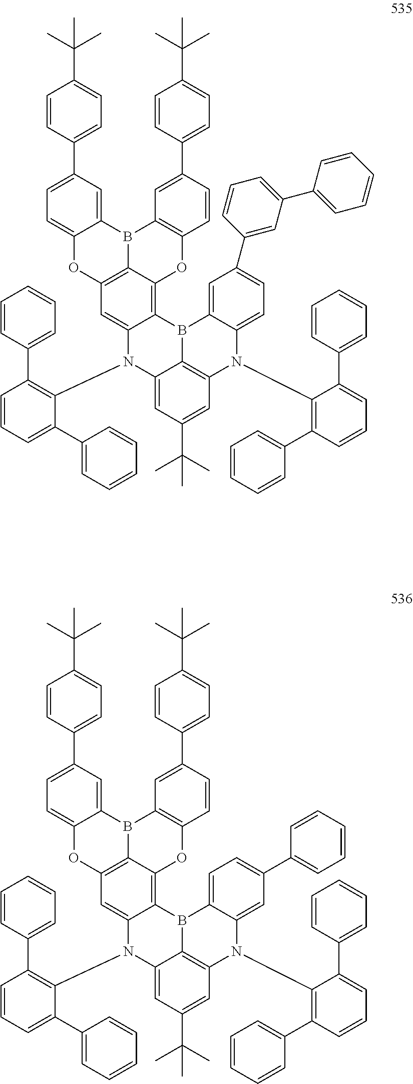 [SMILES: CC(C)(C)c1ccc(-c2ccc3c(c2)B2c4cc(-c5ccc(C(C)(C)C)cc5)ccc4Oc4c2c(cc2c4B4c5cc(-c6cccc(-c7ccccc7)c6)ccc5N(c5c(-c6ccccc6)cccc5-c5ccccc5)c5cc(C(C)(C)C)cc(c54)N2c2c(-c4ccccc4)cccc2-c2ccccc2)O3)cc1 ; CC(C)(C)c1ccc(-c2ccc3c(c2)B2c4cc(-c5ccc(C(C)(C)C)cc5)ccc4Oc4c2c(cc2c4B4c5ccc(-c6ccccc6)cc5N(c5c(-c6ccccc6)cccc5-c5ccccc5)c5cc(C(C)(C)C)cc(c54)N2c2c(-c4ccccc4)cccc2-c2ccccc2)O3)cc1]

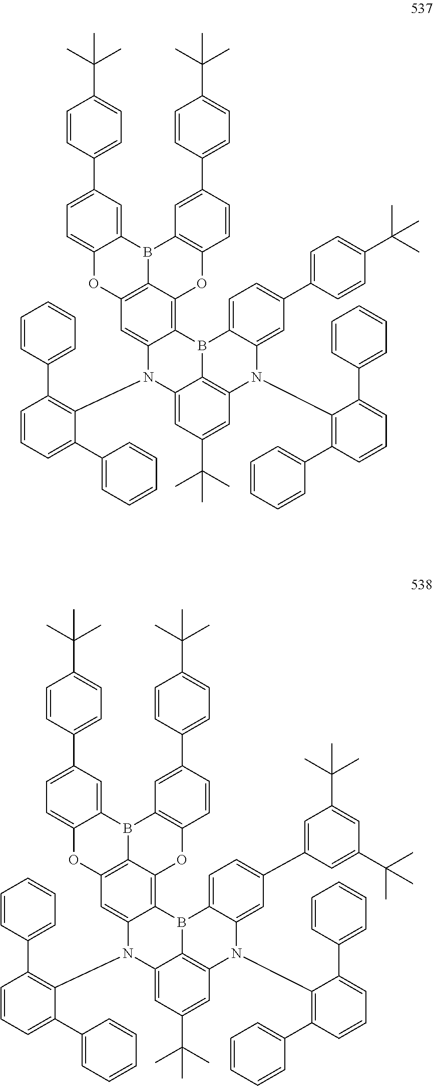 [SMILES: CC(C)(C)c1ccc(-c2ccc3c(c2)B2c4cc(-c5ccc(C(C)(C)C)cc5)ccc4Oc4c2c(cc2c4B4c5ccc(-c6ccc(C(C)(C)C)cc6)cc5N(c5c(-c6ccccc6)cccc5-c5ccccc5)c5cc(C(C)(C)C)cc(c54)N2c2c(-c4ccccc4)cccc2-c2ccccc2)O3)cc1 ; CC(C)(C)c1ccc(-c2ccc3c(c2)B2c4cc(-c5ccc(C(C)(C)C)cc5)ccc4Oc4c2c(cc2c4B4c5ccc(-c6cc(C(C)(C)C)cc(C(C)(C)C)c6)cc5N(c5c(-c6ccccc6)cccc5-c5ccccc5)c5cc(C(C)(C)C)cc(c54)N2c2c(-c4ccccc4)cccc2-c2ccccc2)O3)cc1]

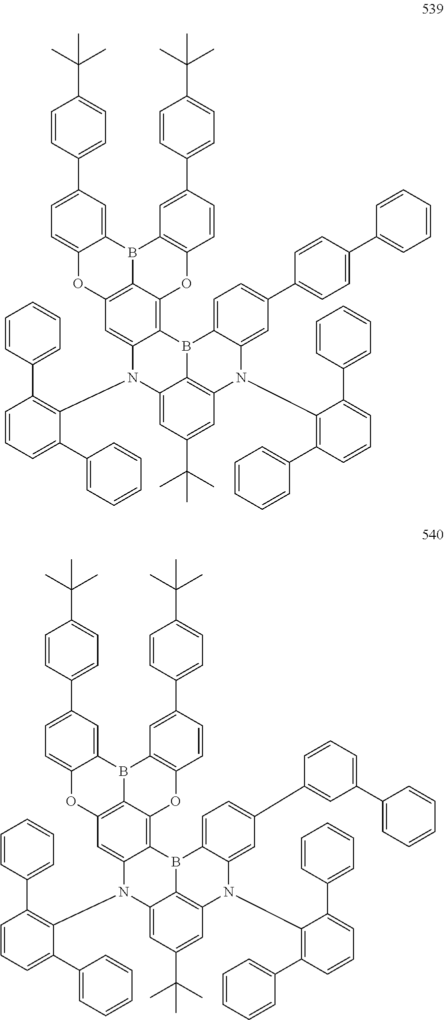 [SMILES: CC(C)(C)c1ccc(-c2ccc3c(c2)B2c4cc(-c5ccc(C(C)(C)C)cc5)ccc4Oc4c2c(cc2c4B4c5ccc(-c6ccc(-c7ccccc7)cc6)cc5N(c5c(-c6ccccc6)cccc5-c5ccccc5)c5cc(C(C)(C)C)cc(c54)N2c2c(-c4ccccc4)cccc2-c2ccccc2)O3)cc1 ; CC(C)(C)c1ccc(-c2ccc3c(c2)B2c4cc(-c5ccc(C(C)(C)C)cc5)ccc4Oc4c2c(cc2c4B4c5ccc(-c6cccc(-c7ccccc7)c6)cc5N(c5c(-c6ccccc6)cccc5-c5ccccc5)c5cc(C(C)(C)C)cc(c54)N2c2c(-c4ccccc4)cccc2-c2ccccc2)O3)cc1]

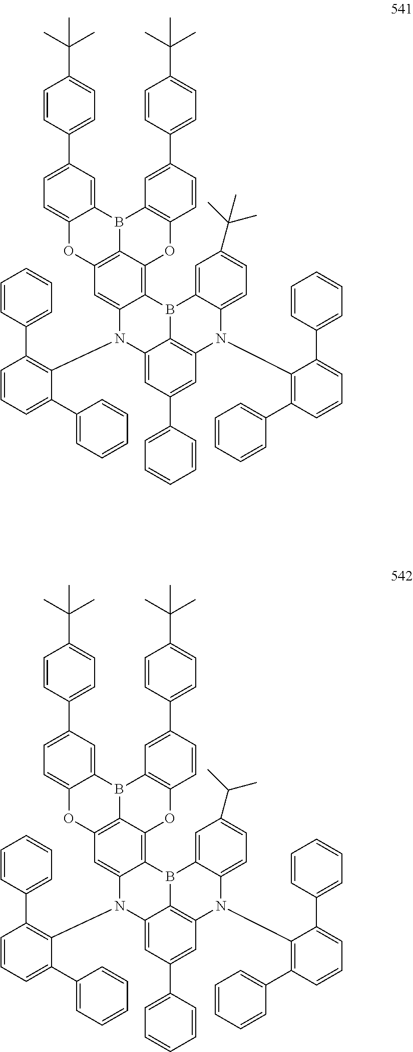 [SMILES: CC(C)(C)c1ccc(-c2ccc3c(c2)B2c4cc(-c5ccc(C(C)(C)C)cc5)ccc4Oc4c2c(cc2c4B4c5cc(C(C)(C)C)ccc5N(c5c(-c6ccccc6)cccc5-c5ccccc5)c5cc(-c6ccccc6)cc(c54)N2c2c(-c4ccccc4)cccc2-c2ccccc2)O3)cc1 ; CC(C)c1ccc2c(c1)B1c3c(cc(-c4ccccc4)cc3N(c3c(-c4ccccc4)cccc3-c3ccccc3)c3cc4c5c(c31)Oc1ccc(-c3ccc(C(C)(C)C)cc3)cc1B5c1cc(-c3ccc(C(C)(C)C)cc3)ccc1O4)N2c1c(-c2ccccc2)cccc1-c1ccccc1]

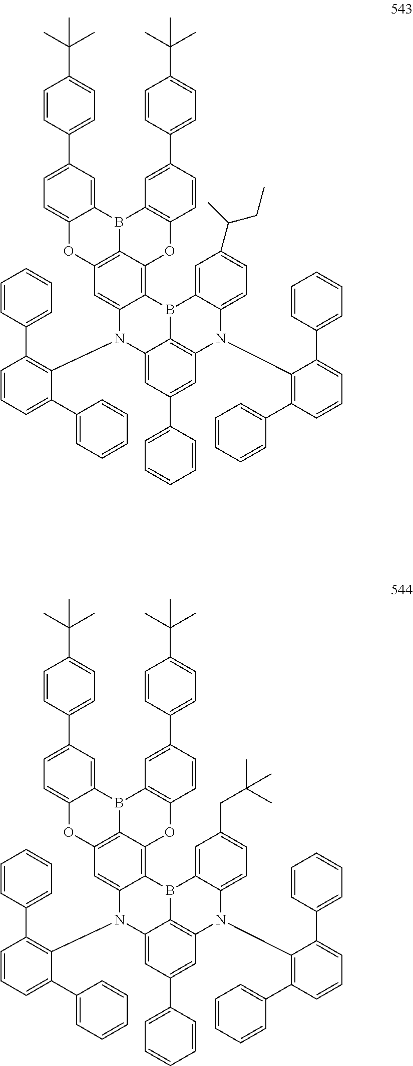 [SMILES: CCC(C)c1ccc2c(c1)B1c3c(cc(-c4ccccc4)cc3N(c3c(-c4ccccc4)cccc3-c3ccccc3)c3cc4c5c(c31)Oc1ccc(-c3ccc(C(C)(C)C)cc3)cc1B5c1cc(-c3ccc(C(C)(C)C)cc3)ccc1O4)N2c1c(-c2ccccc2)cccc1-c1ccccc1 ; CC(C)(C)Cc1ccc2c(c1)B1c3c(cc(-c4ccccc4)cc3N(c3c(-c4ccccc4)cccc3-c3ccccc3)c3cc4c5c(c31)Oc1ccc(-c3ccc(C(C)(C)C)cc3)cc1B5c1cc(-c3ccc(C(C)(C)C)cc3)ccc1O4)N2c1c(-c2ccccc2)cccc1-c1ccccc1]

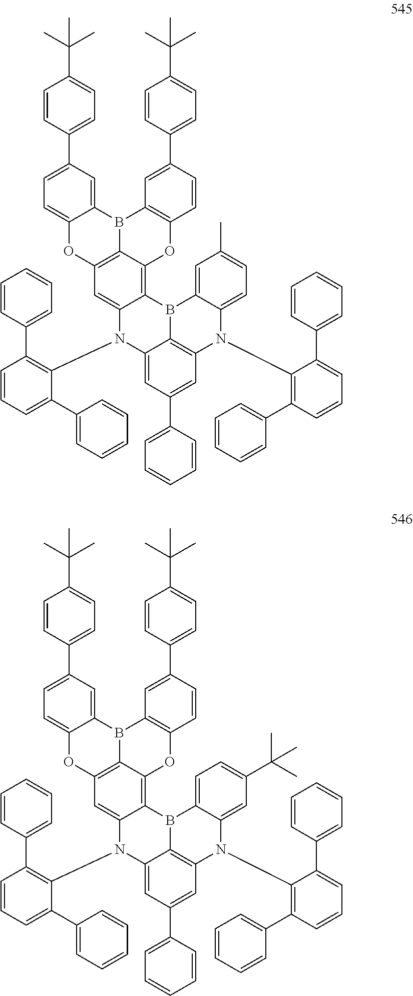 [SMILES: Cc1ccc2c(c1)B1c3c(cc(-c4ccccc4)cc3N(c3c(-c4ccccc4)cccc3-c3ccccc3)c3cc4c5c(c31)Oc1ccc(-c3ccc(C(C)(C)C)cc3)cc1B5c1cc(-c3ccc(C(C)(C)C)cc3)ccc1O4)N2c1c(-c2ccccc2)cccc1-c1ccccc1 ; CC(C)(C)c1ccc(-c2ccc3c(c2)B2c4cc(-c5ccc(C(C)(C)C)cc5)ccc4Oc4c2c(cc2c4B4c5ccc(C(C)(C)C)cc5N(c5c(-c6ccccc6)cccc5-c5ccccc5)c5cc(-c6ccccc6)cc(c54)N2c2c(-c4ccccc4)cccc2-c2ccccc2)O3)cc1]

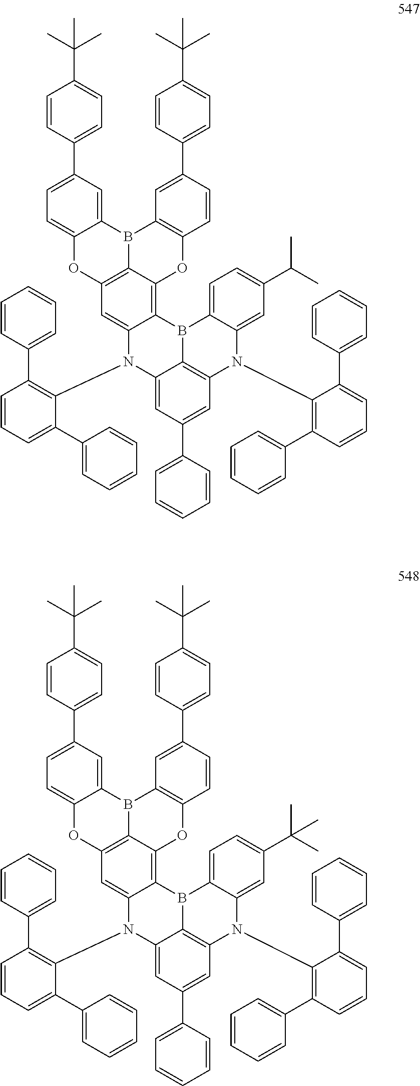 [SMILES: CC(C)c1ccc2c(c1)N(c1c(-c3ccccc3)cccc1-c1ccccc1)c1cc(-c3ccccc3)cc3c1B2c1c(cc2c4c1Oc1ccc(-c5ccc(C(C)(C)C)cc5)cc1B4c1cc(-c4ccc(C(C)(C)C)cc4)ccc1O2)N3c1c(-c2ccccc2)cccc1-c1ccccc1 ; CC(C)(C)c1ccc(-c2ccc3c(c2)B2c4cc(-c5ccc(C(C)(C)C)cc5)ccc4Oc4c2c(cc2c4B4c5ccc(C(C)(C)C)cc5N(c5c(-c6ccccc6)cccc5-c5ccccc5)c5cc(-c6ccccc6)cc(c54)N2c2c(-c4ccccc4)cccc2-c2ccccc2)O3)cc1]

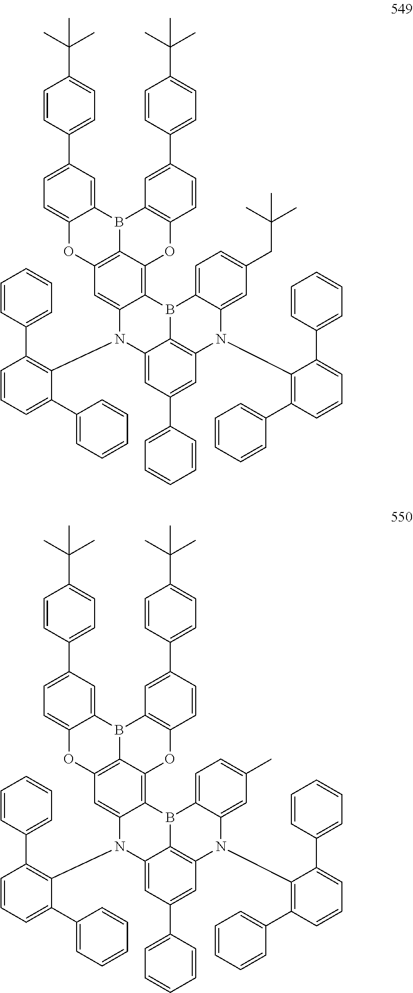 [SMILES: CC(C)(C)Cc1ccc2c(c1)N(c1c(-c3ccccc3)cccc1-c1ccccc1)c1cc(-c3ccccc3)cc3c1B2c1c(cc2c4c1Oc1ccc(-c5ccc(C(C)(C)C)cc5)cc1B4c1cc(-c4ccc(C(C)(C)C)cc4)ccc1O2)N3c1c(-c2ccccc2)cccc1-c1ccccc1 ; Cc1ccc2c(c1)N(c1c(-c3ccccc3)cccc1-c1ccccc1)c1cc(-c3ccccc3)cc3c1B2c1c(cc2c4c1Oc1ccc(-c5ccc(C(C)(C)C)cc5)cc1B4c1cc(-c4ccc(C(C)(C)C)cc4)ccc1O2)N3c1c(-c2ccccc2)cccc1-c1ccccc1]

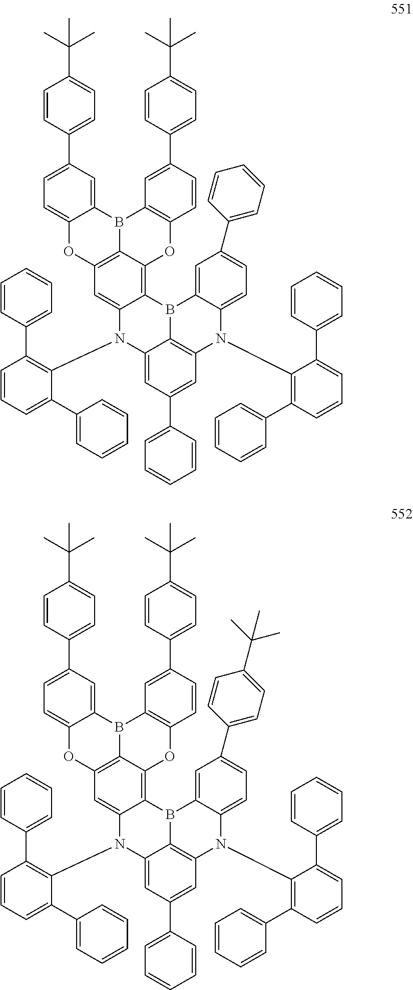

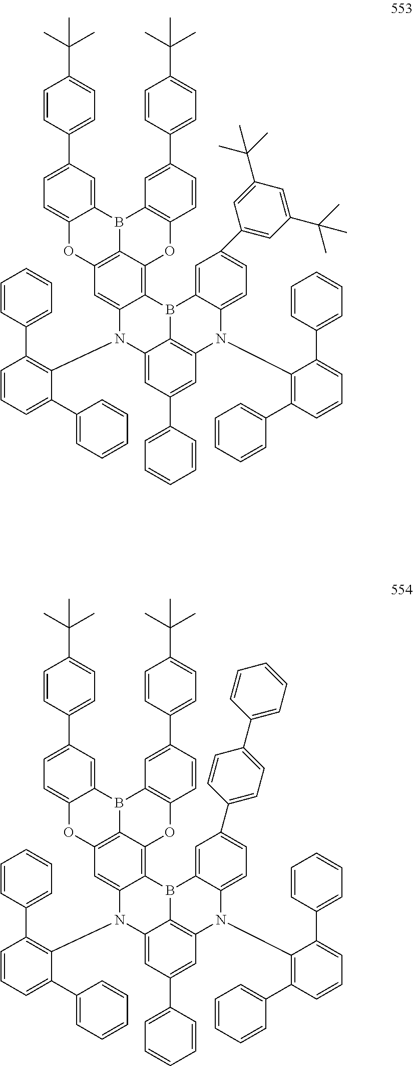 [SMILES: CC(C)(C)c1ccc(-c2ccc3c(c2)B2c4cc(-c5ccc(C(C)(C)C)cc5)ccc4Oc4c2c(cc2c4B4c5cc(-c6cc(C(C)(C)C)cc(C(C)(C)C)c6)ccc5N(c5c(-c6ccccc6)cccc5-c5ccccc5)c5cc(-c6ccccc6)cc(c54)N2c2c(-c4ccccc4)cccc2-c2ccccc2)O3)cc1 ; CC(C)(C)c1ccc(-c2ccc3c(c2)B2c4cc(-c5ccc(C(C)(C)C)cc5)ccc4Oc4c2c(cc2c4B4c5cc(-c6ccc(-c7ccccc7)cc6)ccc5N(c5c(-c6ccccc6)cccc5-c5ccccc5)c5cc(-c6ccccc6)cc(c54)N2c2c(-c4ccccc4)cccc2-c2ccccc2)O3)cc1]

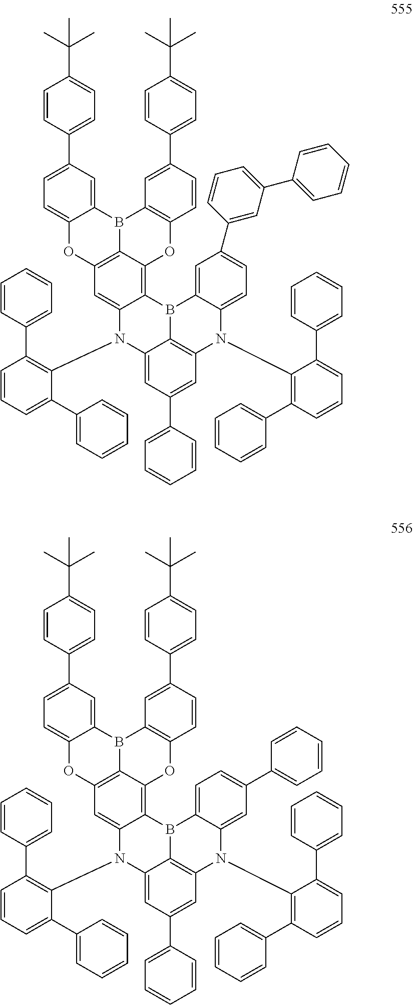 [SMILES: CC(C)(C)c1ccc(-c2ccc3c(c2)B2c4cc(-c5ccc(C(C)(C)C)cc5)ccc4Oc4c2c(cc2c4B4c5cc(-c6cccc(-c7ccccc7)c6)ccc5N(c5c(-c6ccccc6)cccc5-c5ccccc5)c5cc(-c6ccccc6)cc(c54)N2c2c(-c4ccccc4)cccc2-c2ccccc2)O3)cc1 ; CC(C)(C)c1ccc(-c2ccc3c(c2)B2c4cc(-c5ccc(C(C)(C)C)cc5)ccc4Oc4c2c(cc2c4B4c5ccc(-c6ccccc6)cc5N(c5c(-c6ccccc6)cccc5-c5ccccc5)c5cc(-c6ccccc6)cc(c54)N2c2c(-c4ccccc4)cccc2-c2ccccc2)O3)cc1]

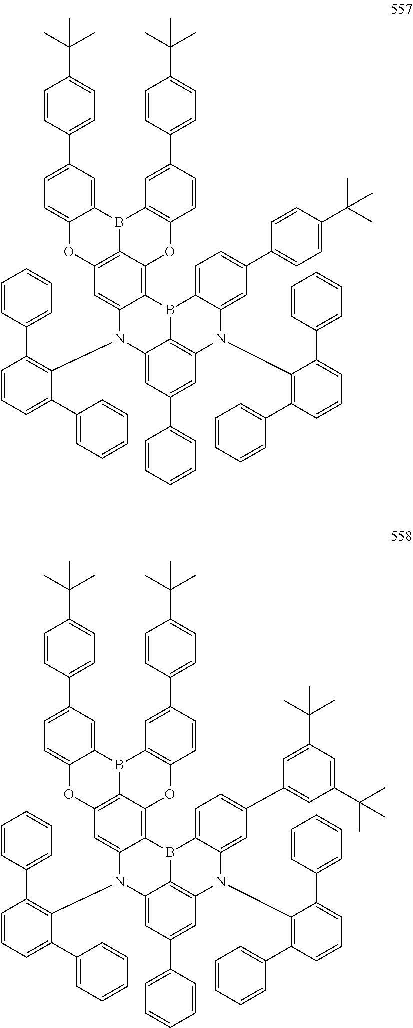 [SMILES: CC(C)(C)c1ccc(-c2ccc3c(c2)B2c4cc(-c5ccc(C(C)(C)C)cc5)ccc4Oc4c2c(cc2c4B4c5ccc(-c6ccc(C(C)(C)C)cc6)cc5N(c5c(-c6ccccc6)cccc5-c5ccccc5)c5cc(-c6ccccc6)cc(c54)N2c2c(-c4ccccc4)cccc2-c2ccccc2)O3)cc1 ; CC(C)(C)c1ccc(-c2ccc3c(c2)B2c4cc(-c5ccc(C(C)(C)C)cc5)ccc4Oc4c2c(cc2c4B4c5ccc(-c6cc(C(C)(C)C)cc(C(C)(C)C)c6)cc5N(c5c(-c6ccccc6)cccc5-c5ccccc5)c5cc(-c6ccccc6)cc(c54)N2c2c(-c4ccccc4)cccc2-c2ccccc2)O3)cc1]

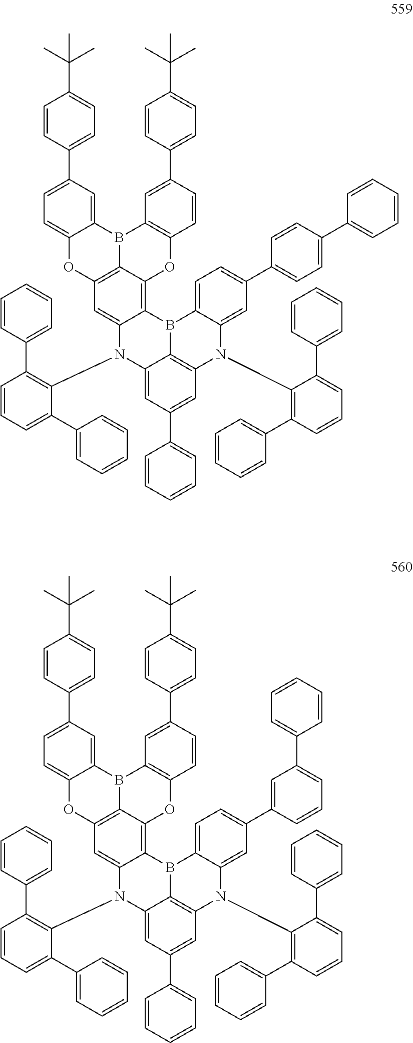 [SMILES: CC(C)(C)c1ccc(-c2ccc3c(c2)B2c4cc(-c5ccc(C(C)(C)C)cc5)ccc4Oc4c2c(cc2c4B4c5ccc(-c6ccc(-c7ccccc7)cc6)cc5N(c5c(-c6ccccc6)cccc5-c5ccccc5)c5cc(-c6ccccc6)cc(c54)N2c2c(-c4ccccc4)cccc2-c2ccccc2)O3)cc1 ; CC(C)(C)c1ccc(-c2ccc3c(c2)B2c4cc(-c5ccc(C(C)(C)C)cc5)ccc4Oc4c2c(cc2c4B4c5ccc(-c6cccc(-c7ccccc7)c6)cc5N(c5c(-c6ccccc6)cccc5-c5ccccc5)c5cc(-c6ccccc6)cc(c54)N2c2c(-c4ccccc4)cccc2-c2ccccc2)O3)cc1]

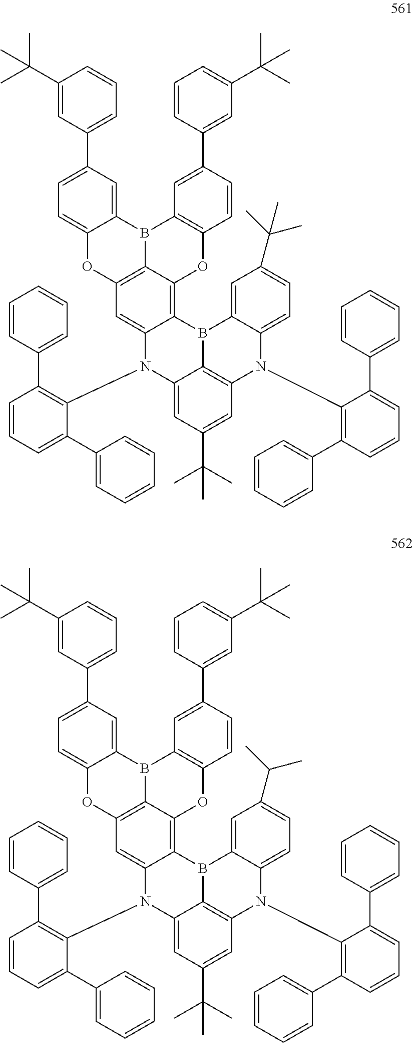 [SMILES: CC(C)(C)c1cccc(-c2ccc3c(c2)B2c4cc(-c5cccc(C(C)(C)C)c5)ccc4Oc4c2c(cc2c4B4c5cc(C(C)(C)C)ccc5N(c5c(-c6ccccc6)cccc5-c5ccccc5)c5cc(C(C)(C)C)cc(c54)N2c2c(-c4ccccc4)cccc2-c2ccccc2)O3)c1 ; CC(C)c1ccc2c(c1)B1c3c(cc(C(C)(C)C)cc3N(c3c(-c4ccccc4)cccc3-c3ccccc3)c3cc4c5c(c31)Oc1ccc(-c3cccc(C(C)(C)C)c3)cc1B5c1cc(-c3cccc(C(C)(C)C)c3)ccc1O4)N2c1c(-c2ccccc2)cccc1-c1ccccc1]

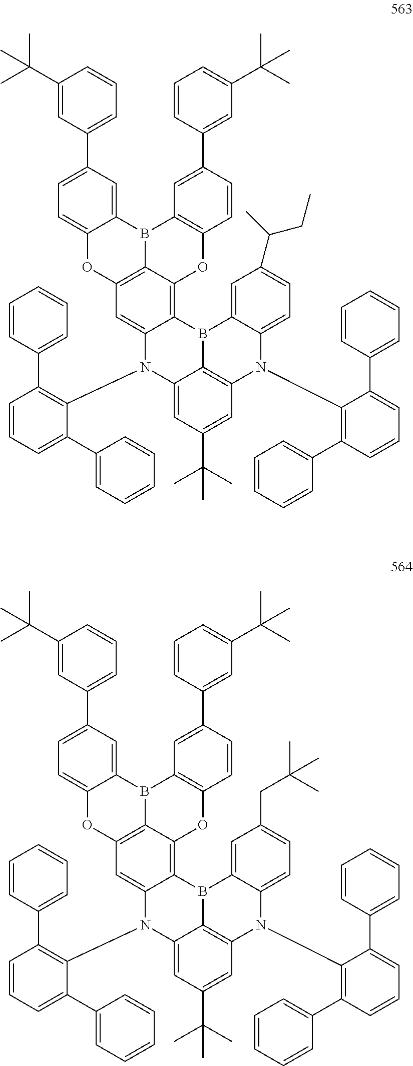 [SMILES: CCC(C)c1ccc2c(c1)B1c3c(cc(C(C)(C)C)cc3N(c3c(-c4ccccc4)cccc3-c3ccccc3)c3cc4c5c(c31)Oc1ccc(-c3cccc(C(C)(C)C)c3)cc1B5c1cc(-c3cccc(C(C)(C)C)c3)ccc1O4)N2c1c(-c2ccccc2)cccc1-c1ccccc1 ; CC(C)(C)Cc1ccc2c(c1)B1c3c(cc(C(C)(C)C)cc3N(c3c(-c4ccccc4)cccc3-c3ccccc3)c3cc4c5c(c31)Oc1ccc(-c3cccc(C(C)(C)C)c3)cc1B5c1cc(-c3cccc(C(C)(C)C)c3)ccc1O4)N2c1c(-c2ccccc2)cccc1-c1ccccc1]

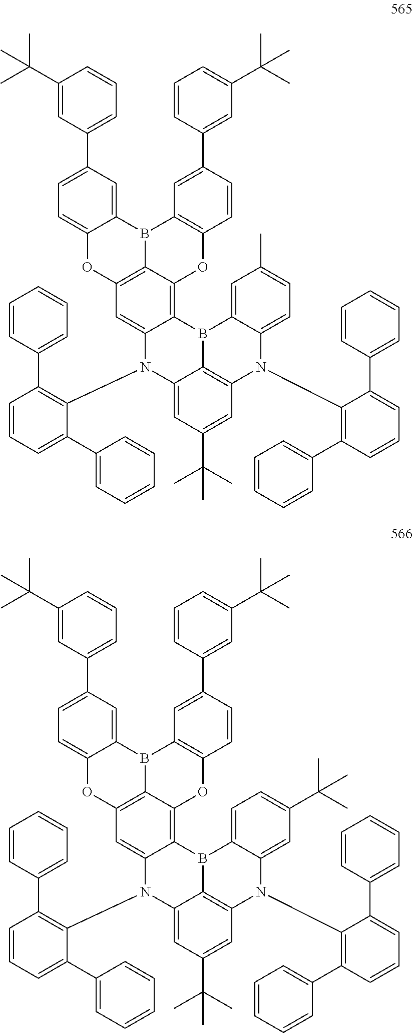 [SMILES: Cc1ccc2c(c1)B1c3c(cc(C(C)(C)C)cc3N(c3c(-c4ccccc4)cccc3-c3ccccc3)c3cc4c5c(c31)Oc1ccc(-c3cccc(C(C)(C)C)c3)cc1B5c1cc(-c3cccc(C(C)(C)C)c3)ccc1O4)N2c1c(-c2ccccc2)cccc1-c1ccccc1 ; CC(C)(C)c1cccc(-c2ccc3c(c2)B2c4cc(-c5cccc(C(C)(C)C)c5)ccc4Oc4c2c(cc2c4B4c5ccc(C(C)(C)C)cc5N(c5c(-c6ccccc6)cccc5-c5ccccc5)c5cc(C(C)(C)C)cc(c54)N2c2c(-c4ccccc4)cccc2-c2ccccc2)O3)c1]

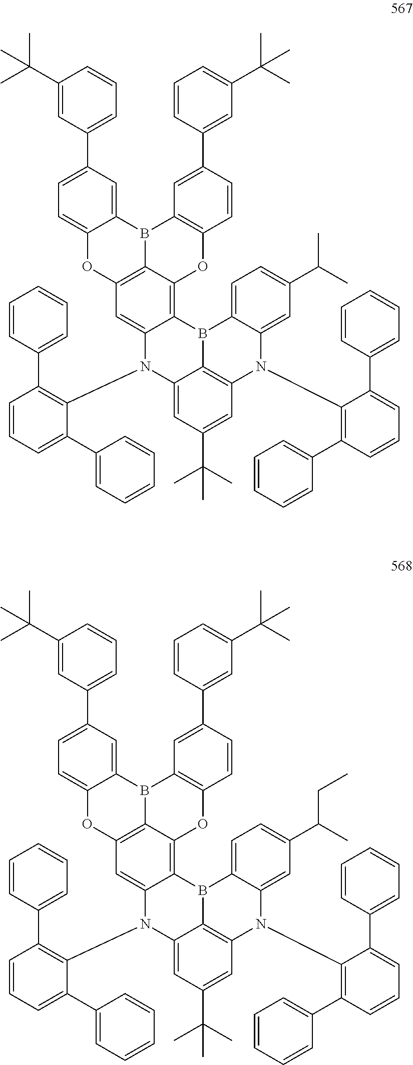 [SMILES: CC(C)c1ccc2c(c1)N(c1c(-c3ccccc3)cccc1-c1ccccc1)c1cc(C(C)(C)C)cc3c1B2c1c(cc2c4c1Oc1ccc(-c5cccc(C(C)(C)C)c5)cc1B4c1cc(-c4cccc(C(C)(C)C)c4)ccc1O2)N3c1c(-c2ccccc2)cccc1-c1ccccc1 ; CCC(C)c1ccc2c(c1)N(c1c(-c3ccccc3)cccc1-c1ccccc1)c1cc(C(C)(C)C)cc3c1B2c1c(cc2c4c1Oc1ccc(-c5cccc(C(C)(C)C)c5)cc1B4c1cc(-c4cccc(C(C)(C)C)c4)ccc1O2)N3c1c(-c2ccccc2)cccc1-c1ccccc1]

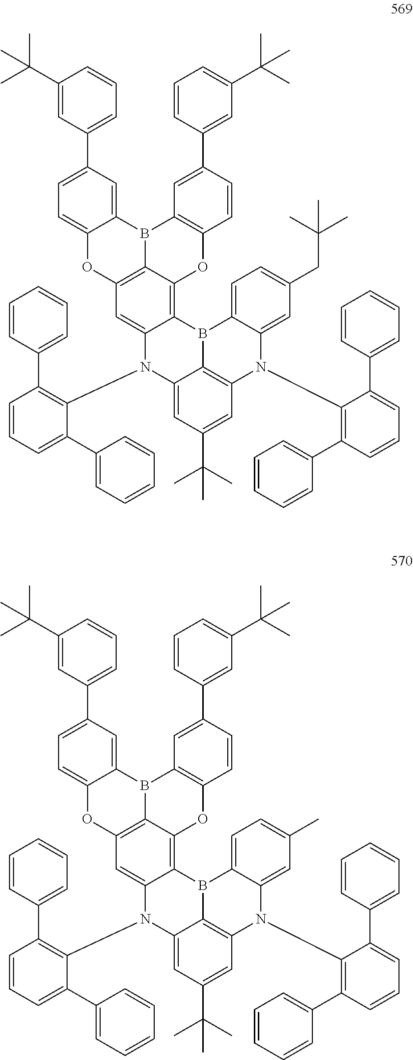 [SMILES: CC(C)(C)Cc1ccc2c(c1)N(c1c(-c3ccccc3)cccc1-c1ccccc1)c1cc(C(C)(C)C)cc3c1B2c1c(cc2c4c1Oc1ccc(-c5cccc(C(C)(C)C)c5)cc1B4c1cc(-c4cccc(C(C)(C)C)c4)ccc1O2)N3c1c(-c2ccccc2)cccc1-c1ccccc1 ; Cc1ccc2c(c1)N(c1c(-c3ccccc3)cccc1-c1ccccc1)c1cc(C(C)(C)C)cc3c1B2c1c(cc2c4c1Oc1ccc(-c5cccc(C(C)(C)C)c5)cc1B4c1cc(-c4cccc(C(C)(C)C)c4)ccc1O2)N3c1c(-c2ccccc2)cccc1-c1ccccc1]

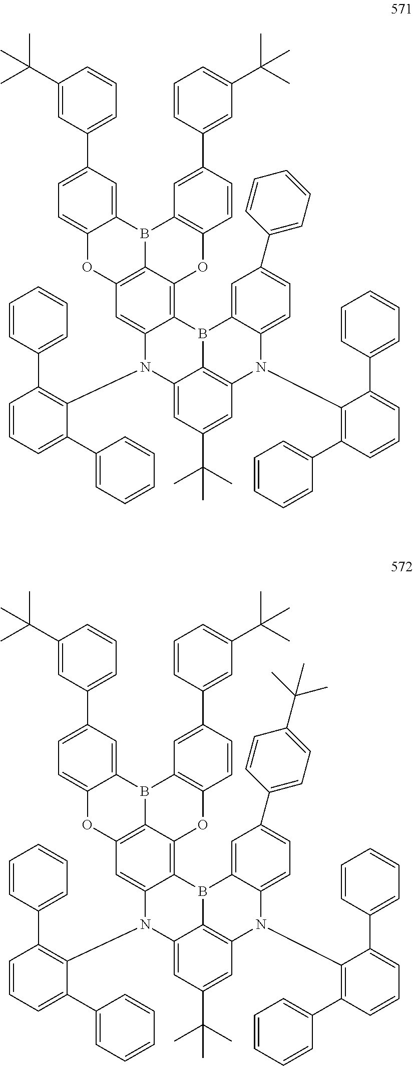 [SMILES: CC(C)(C)c1cccc(-c2ccc3c(c2)B2c4cc(-c5cccc(C(C)(C)C)c5)ccc4Oc4c2c(cc2c4B4c5cc(-c6ccccc6)ccc5N(c5c(-c6ccccc6)cccc5-c5ccccc5)c5cc(C(C)(C)C)cc(c54)N2c2c(-c4ccccc4)cccc2-c2ccccc2)O3)c1 ; CC(C)(C)c1ccc(-c2ccc3c(c2)B2c4c(cc(C(C)(C)C)cc4N(c4c(-c5ccccc5)cccc4-c4ccccc4)c4cc5c6c(c42)Oc2ccc(-c4cccc(C(C)(C)C)c4)cc2B6c2cc(-c4cccc(C(C)(C)C)c4)ccc2O5)N3c2c(-c3ccccc3)cccc2-c2ccccc2)cc1]

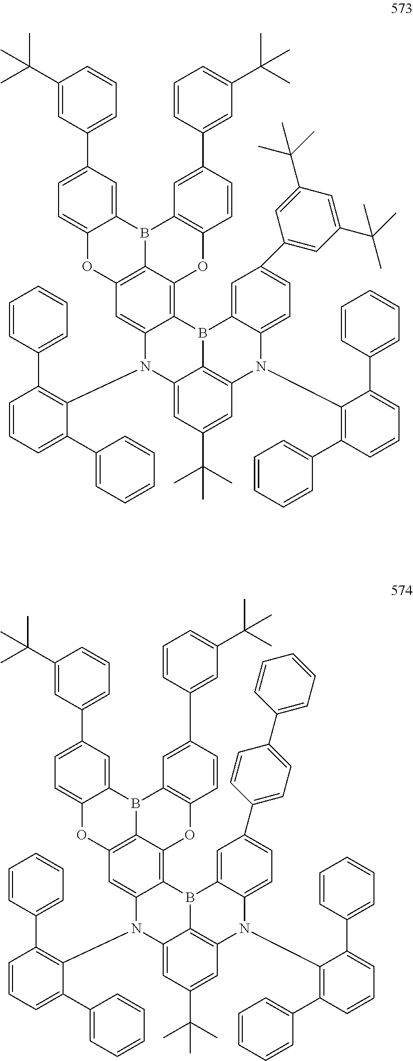 [SMILES: CC(C)(C)c1cccc(-c2ccc3c(c2)B2c4cc(-c5cccc(C(C)(C)C)c5)ccc4Oc4c2c(cc2c4B4c5cc(-c6cc(C(C)(C)C)cc(C(C)(C)C)c6)ccc5N(c5c(-c6ccccc6)cccc5-c5ccccc5)c5cc(C(C)(C)C)cc(c54)N2c2c(-c4ccccc4)cccc2-c2ccccc2)O3)c1 ; CC(C)(C)c1cccc(-c2ccc3c(c2)B2c4cc(-c5cccc(C(C)(C)C)c5)ccc4Oc4c2c(cc2c4B4c5cc(-c6ccc(-c7ccccc7)cc6)ccc5N(c5c(-c6ccccc6)cccc5-c5ccccc5)c5cc(C(C)(C)C)cc(c54)N2c2c(-c4ccccc4)cccc2-c2ccccc2)O3)c1]

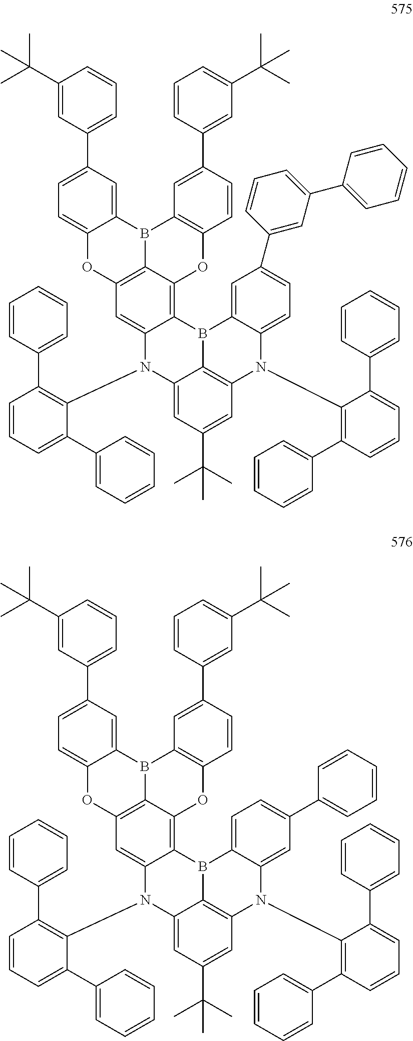 [SMILES: CC(C)(C)c1cccc(-c2ccc3c(c2)B2c4cc(-c5cccc(C(C)(C)C)c5)ccc4Oc4c2c(cc2c4B4c5cc(-c6cccc(-c7ccccc7)c6)ccc5N(c5c(-c6ccccc6)cccc5-c5ccccc5)c5cc(C(C)(C)C)cc(c54)N2c2c(-c4ccccc4)cccc2-c2ccccc2)O3)c1 ; CC(C)(C)c1cccc(-c2ccc3c(c2)B2c4cc(-c5cccc(C(C)(C)C)c5)ccc4Oc4c2c(cc2c4B4c5ccc(-c6ccccc6)cc5N(c5c(-c6ccccc6)cccc5-c5ccccc5)c5cc(C(C)(C)C)cc(c54)N2c2c(-c4ccccc4)cccc2-c2ccccc2)O3)c1]

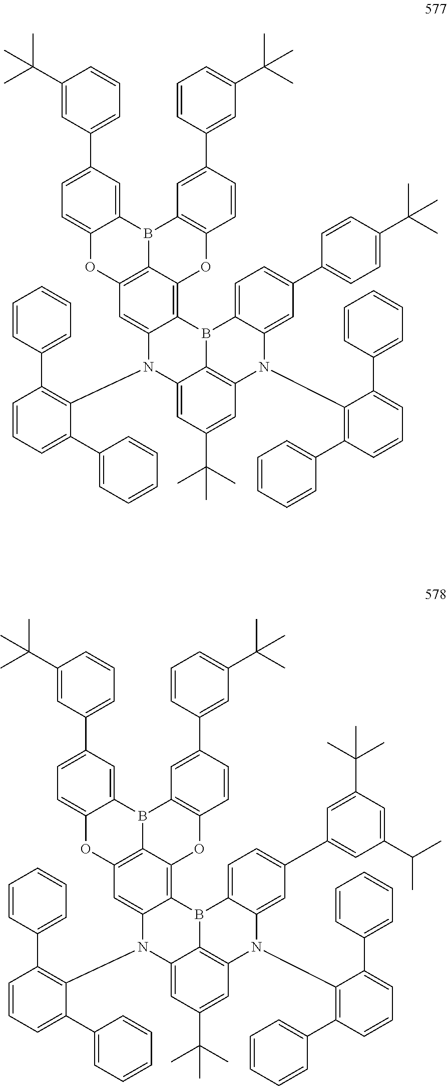

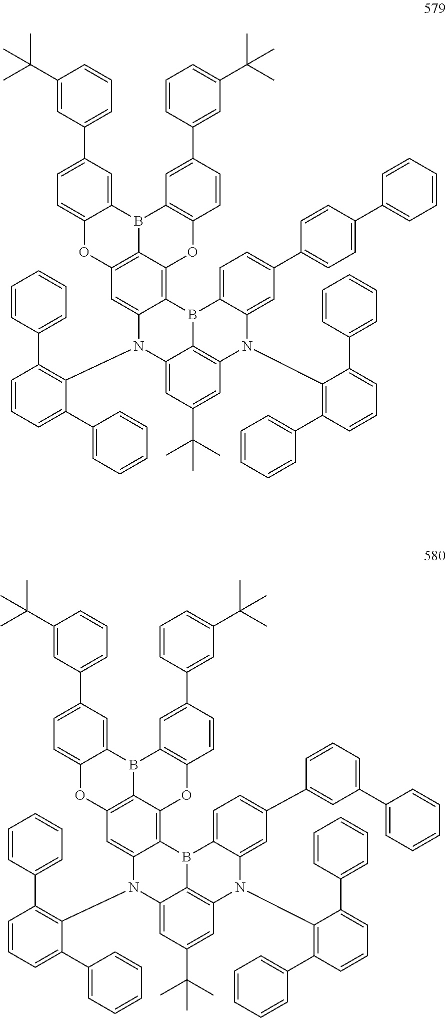 [SMILES: CC(C)(C)c1cccc(-c2ccc3c(c2)B2c4cc(-c5cccc(C(C)(C)C)c5)ccc4Oc4c2c(cc2c4B4c5ccc(-c6ccc(-c7ccccc7)cc6)cc5N(c5c(-c6ccccc6)cccc5-c5ccccc5)c5cc(C(C)(C)C)cc(c54)N2c2c(-c4ccccc4)cccc2-c2ccccc2)O3)c1 ; CC(C)(C)c1cccc(-c2ccc3c(c2)B2c4cc(-c5cccc(C(C)(C)C)c5)ccc4Oc4c2c(cc2c4B4c5ccc(-c6cccc(-c7ccccc7)c6)cc5N(c5c(-c6ccccc6)cccc5-c5ccccc5)c5cc(C(C)(C)C)cc(c54)N2c2c(-c4ccccc4)cccc2-c2ccccc2)O3)c1]

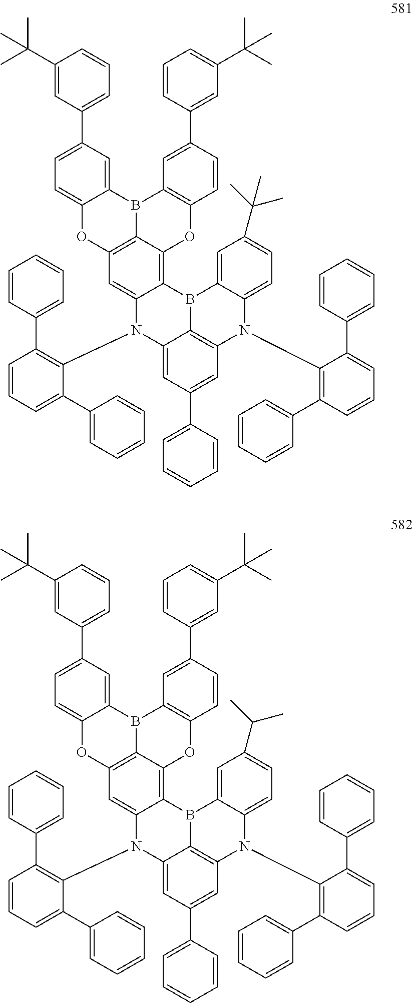 [SMILES: CC(C)(C)c1cccc(-c2ccc3c(c2)B2c4cc(-c5cccc(C(C)(C)C)c5)ccc4Oc4c2c(cc2c4B4c5cc(C(C)(C)C)ccc5N(c5c(-c6ccccc6)cccc5-c5ccccc5)c5cc(-c6ccccc6)cc(c54)N2c2c(-c4ccccc4)cccc2-c2ccccc2)O3)c1 ; CC(C)c1ccc2c(c1)B1c3c(cc(-c4ccccc4)cc3N(c3c(-c4ccccc4)cccc3-c3ccccc3)c3cc4c5c(c31)Oc1ccc(-c3cccc(C(C)(C)C)c3)cc1B5c1cc(-c3cccc(C(C)(C)C)c3)ccc1O4)N2c1c(-c2ccccc2)cccc1-c1ccccc1]

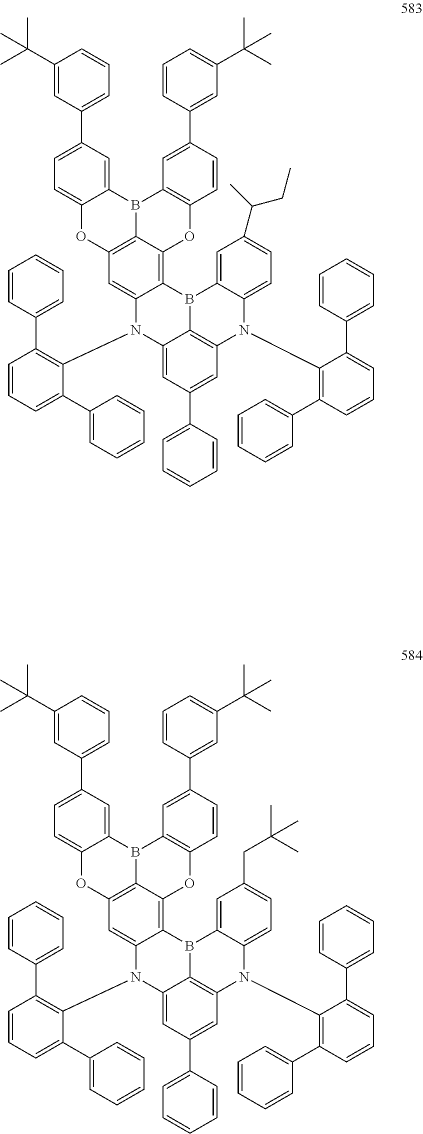 [SMILES: CCC(C)c1ccc2c(c1)B1c3c(cc(-c4ccccc4)cc3N(c3c(-c4ccccc4)cccc3-c3ccccc3)c3cc4c5c(c31)Oc1ccc(-c3cccc(C(C)(C)C)c3)cc1B5c1cc(-c3cccc(C(C)(C)C)c3)ccc1O4)N2c1c(-c2ccccc2)cccc1-c1ccccc1 ; CC(C)(C)Cc1ccc2c(c1)B1c3c(cc(-c4ccccc4)cc3N(c3c(-c4ccccc4)cccc3-c3ccccc3)c3cc4c5c(c31)Oc1ccc(-c3cccc(C(C)(C)C)c3)cc1B5c1cc(-c3cccc(C(C)(C)C)c3)ccc1O4)N2c1c(-c2ccccc2)cccc1-c1ccccc1]

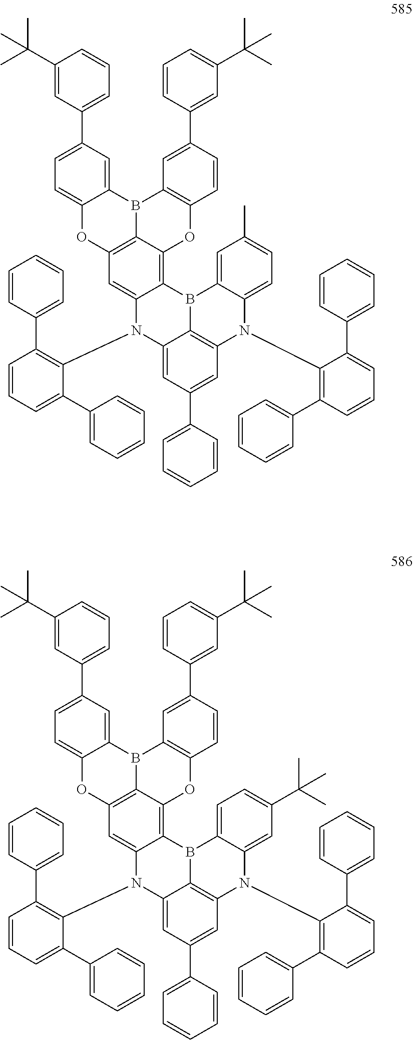 [SMILES: Cc1ccc2c(c1)B1c3c(cc(-c4ccccc4)cc3N(c3c(-c4ccccc4)cccc3-c3ccccc3)c3cc4c5c(c31)Oc1ccc(-c3cccc(C(C)(C)C)c3)cc1B5c1cc(-c3cccc(C(C)(C)C)c3)ccc1O4)N2c1c(-c2ccccc2)cccc1-c1ccccc1 ; CC(C)(C)c1cccc(-c2ccc3c(c2)B2c4cc(-c5cccc(C(C)(C)C)c5)ccc4Oc4c2c(cc2c4B4c5ccc(C(C)(C)C)cc5N(c5c(-c6ccccc6)cccc5-c5ccccc5)c5cc(-c6ccccc6)cc(c54)N2c2c(-c4ccccc4)cccc2-c2ccccc2)O3)c1]

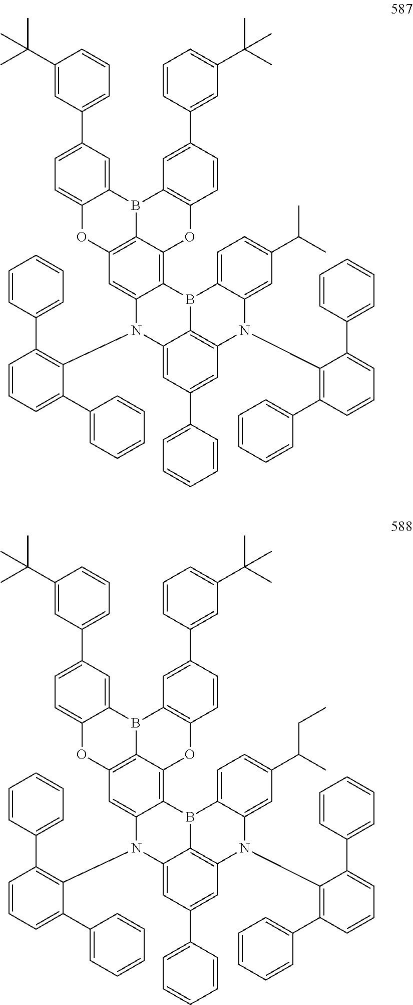 [SMILES: CC(C)c1ccc2c(c1)N(c1c(-c3ccccc3)cccc1-c1ccccc1)c1cc(-c3ccccc3)cc3c1B2c1c(cc2c4c1Oc1ccc(-c5cccc(C(C)(C)C)c5)cc1B4c1cc(-c4cccc(C(C)(C)C)c4)ccc1O2)N3c1c(-c2ccccc2)cccc1-c1ccccc1 ; CCC(C)c1ccc2c(c1)N(c1c(-c3ccccc3)cccc1-c1ccccc1)c1cc(-c3ccccc3)cc3c1B2c1c(cc2c4c1Oc1ccc(-c5cccc(C(C)(C)C)c5)cc1B4c1cc(-c4cccc(C(C)(C)C)c4)ccc1O2)N3c1c(-c2ccccc2)cccc1-c1ccccc1]

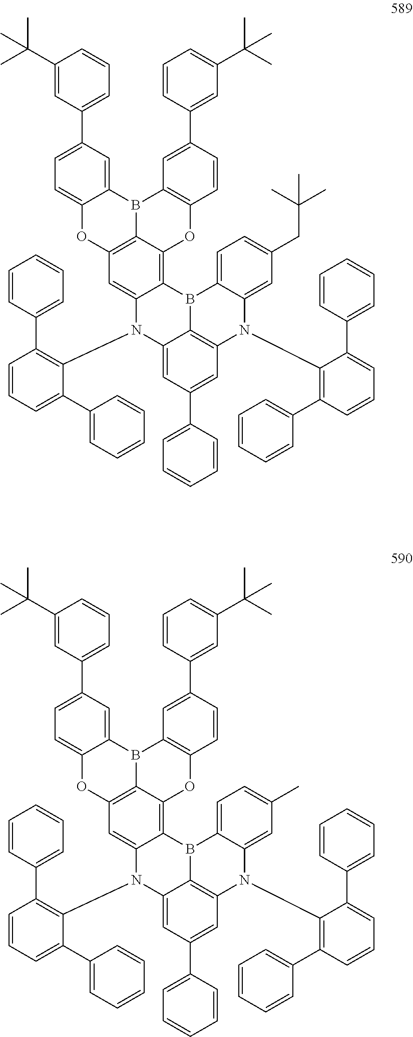 [SMILES: CC(C)(C)Cc1ccc2c(c1)N(c1c(-c3ccccc3)cccc1-c1ccccc1)c1cc(-c3ccccc3)cc3c1B2c1c(cc2c4c1Oc1ccc(-c5cccc(C(C)(C)C)c5)cc1B4c1cc(-c4cccc(C(C)(C)C)c4)ccc1O2)N3c1c(-c2ccccc2)cccc1-c1ccccc1 ; Cc1ccc2c(c1)N(c1c(-c3ccccc3)cccc1-c1ccccc1)c1cc(-c3ccccc3)cc3c1B2c1c(cc2c4c1Oc1ccc(-c5cccc(C(C)(C)C)c5)cc1B4c1cc(-c4cccc(C(C)(C)C)c4)ccc1O2)N3c1c(-c2ccccc2)cccc1-c1ccccc1]

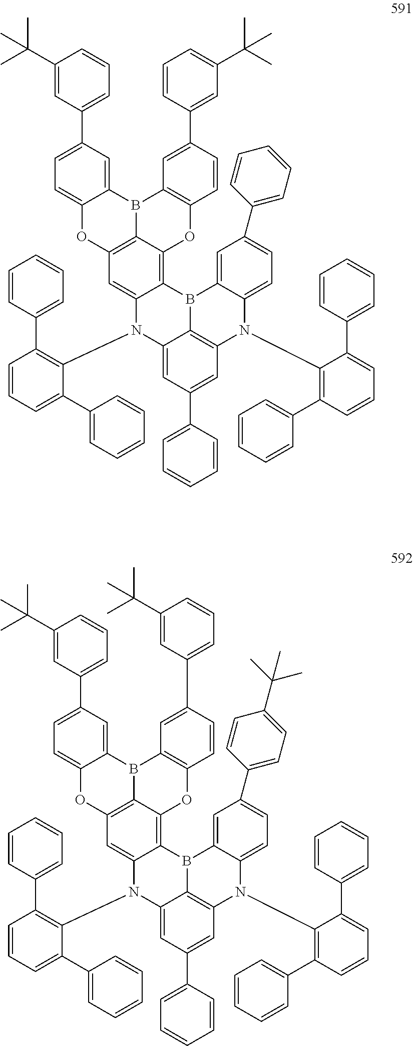 [SMILES: CC(C)(C)c1cccc(-c2ccc3c(c2)B2c4cc(-c5cccc(C(C)(C)C)c5)ccc4Oc4c2c(cc2c4B4c5cc(-c6ccccc6)ccc5N(c5c(-c6ccccc6)cccc5-c5ccccc5)c5cc(-c6ccccc6)cc(c54)N2c2c(-c4ccccc4)cccc2-c2ccccc2)O3)c1 ; CC(C)(C)c1ccc(-c2ccc3c(c2)B2c4c(cc(-c5ccccc5)cc4N(c4c(-c5ccccc5)cccc4-c4ccccc4)c4cc5c6c(c42)Oc2ccc(-c4cccc(C(C)(C)C)c4)cc2B6c2cc(-c4cccc(C(C)(C)C)c4)ccc2O5)N3c2c(-c3ccccc3)cccc2-c2ccccc2)cc1]

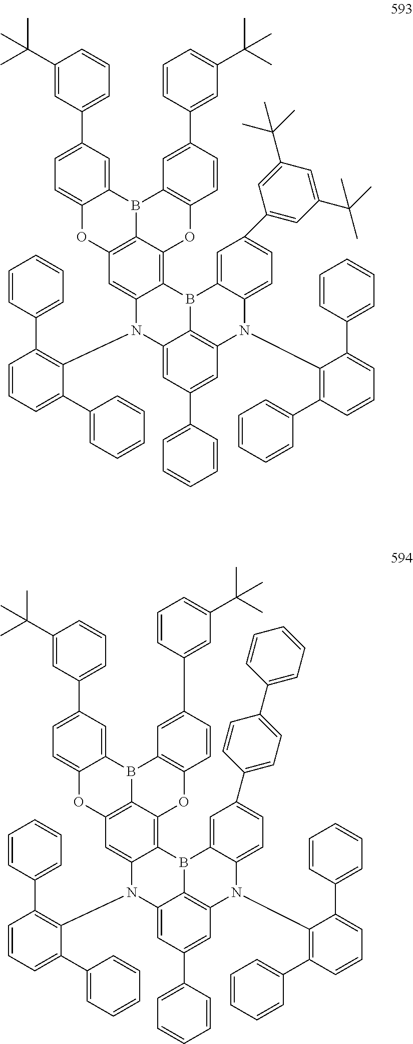 [SMILES: CC(C)(C)c1cccc(-c2ccc3c(c2)B2c4cc(-c5cccc(C(C)(C)C)c5)ccc4Oc4c2c(cc2c4B4c5cc(-c6cc(C(C)(C)C)cc(C(C)(C)C)c6)ccc5N(c5c(-c6ccccc6)cccc5-c5ccccc5)c5cc(-c6ccccc6)cc(c54)N2c2c(-c4ccccc4)cccc2-c2ccccc2)O3)c1 ; CC(C)(C)c1cccc(-c2ccc3c(c2)B2c4cc(-c5cccc(C(C)(C)C)c5)ccc4Oc4c2c(cc2c4B4c5cc(-c6ccc(-c7ccccc7)cc6)ccc5N(c5c(-c6ccccc6)cccc5-c5ccccc5)c5cc(-c6ccccc6)cc(c54)N2c2c(-c4ccccc4)cccc2-c2ccccc2)O3)c1]

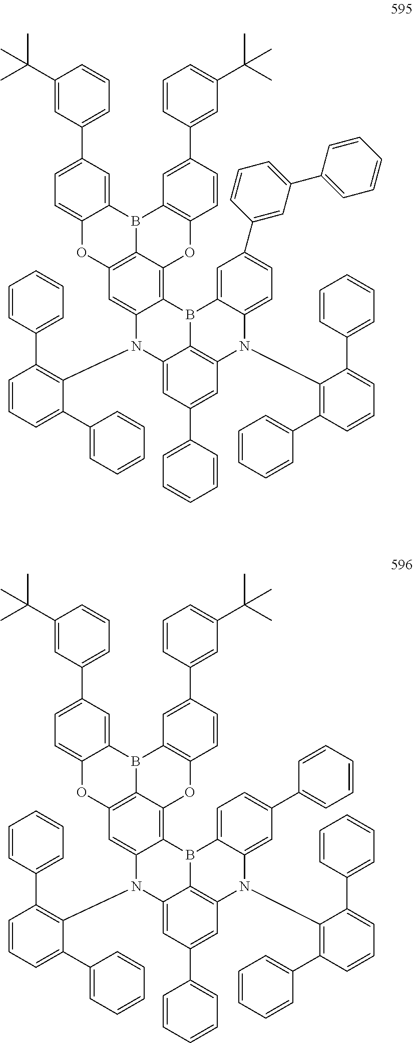 [SMILES: CC(C)(C)c1cccc(-c2ccc3c(c2)B2c4cc(-c5cccc(C(C)(C)C)c5)ccc4Oc4c2c(cc2c4B4c5cc(-c6cccc(-c7ccccc7)c6)ccc5N(c5c(-c6ccccc6)cccc5-c5ccccc5)c5cc(-c6ccccc6)cc(c54)N2c2c(-c4ccccc4)cccc2-c2ccccc2)O3)c1 ; CC(C)(C)c1cccc(-c2ccc3c(c2)B2c4cc(-c5cccc(C(C)(C)C)c5)ccc4Oc4c2c(cc2c4B4c5ccc(-c6ccccc6)cc5N(c5c(-c6ccccc6)cccc5-c5ccccc5)c5cc(-c6ccccc6)cc(c54)N2c2c(-c4ccccc4)cccc2-c2ccccc2)O3)c1]

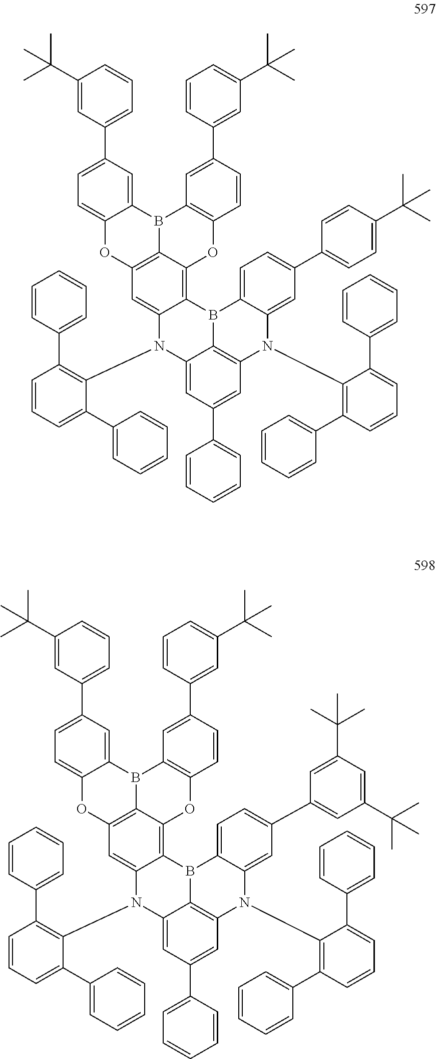

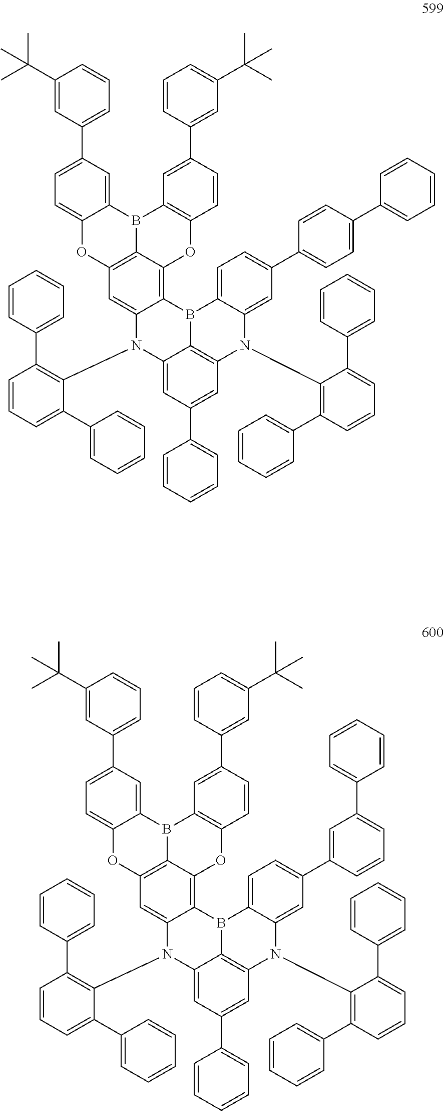 [SMILES: CC(C)(C)c1cccc(-c2ccc3c(c2)B2c4cc(-c5cccc(C(C)(C)C)c5)ccc4Oc4c2c(cc2c4B4c5ccc(-c6ccc(-c7ccccc7)cc6)cc5N(c5c(-c6ccccc6)cccc5-c5ccccc5)c5cc(-c6ccccc6)cc(c54)N2c2c(-c4ccccc4)cccc2-c2ccccc2)O3)c1 ; CC(C)(C)c1cccc(-c2ccc3c(c2)B2c4cc(-c5cccc(C(C)(C)C)c5)ccc4Oc4c2c(cc2c4B4c5ccc(-c6cccc(-c7ccccc7)c6)cc5N(c5c(-c6ccccc6)cccc5-c5ccccc5)c5cc(-c6ccccc6)cc(c54)N2c2c(-c4ccccc4)cccc2-c2ccccc2)O3)c1]

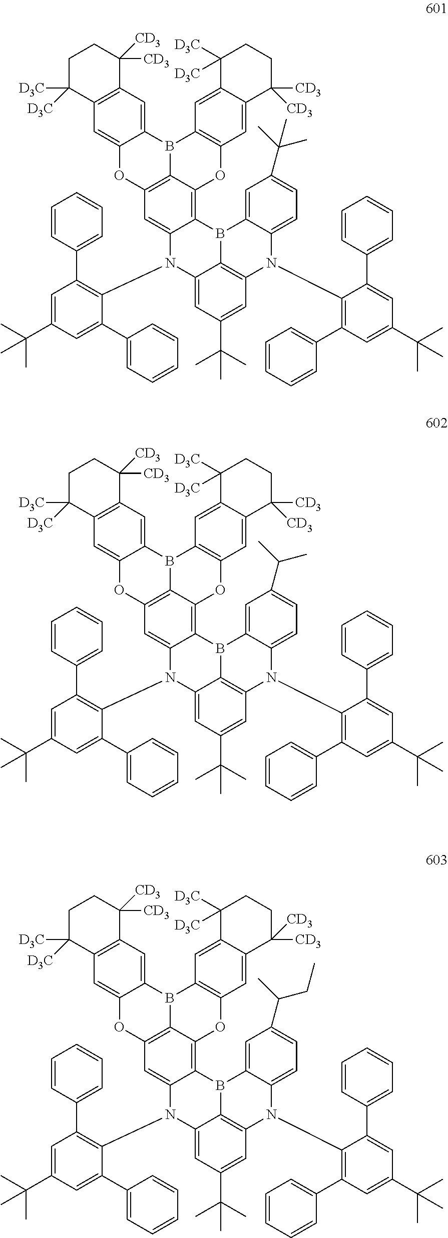

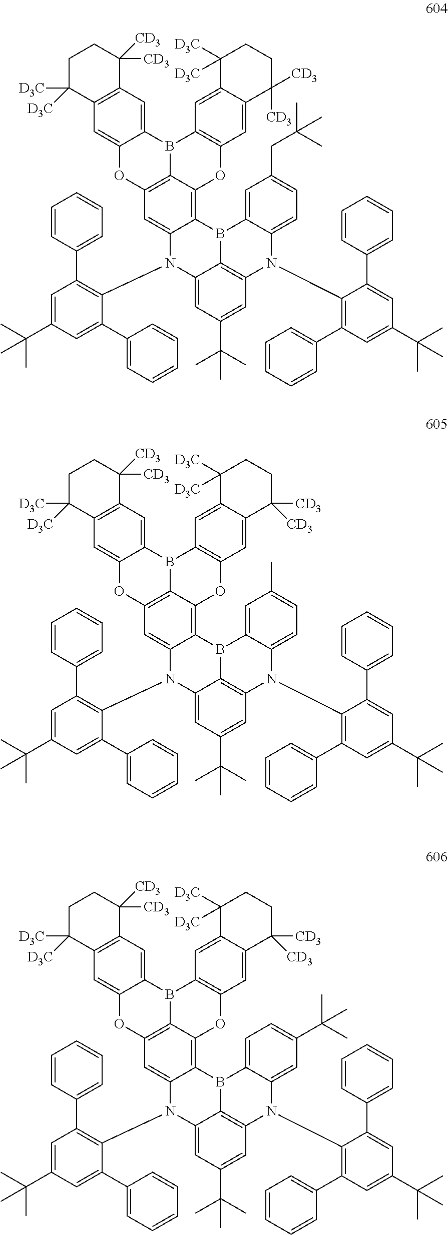

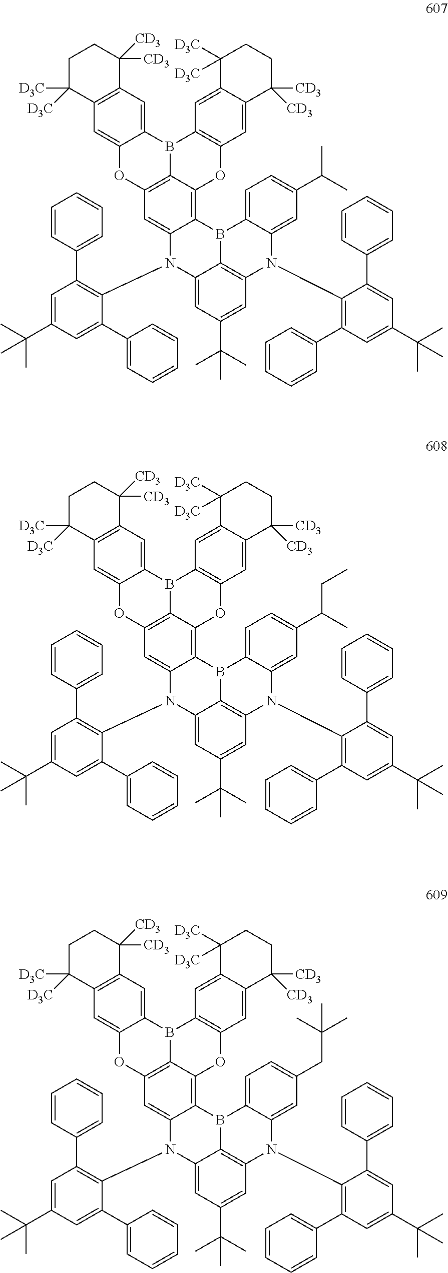

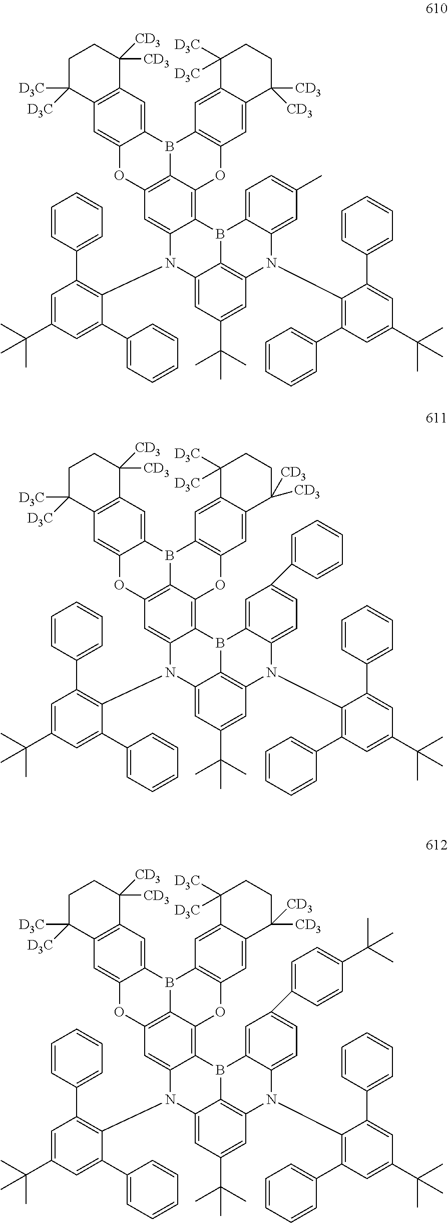

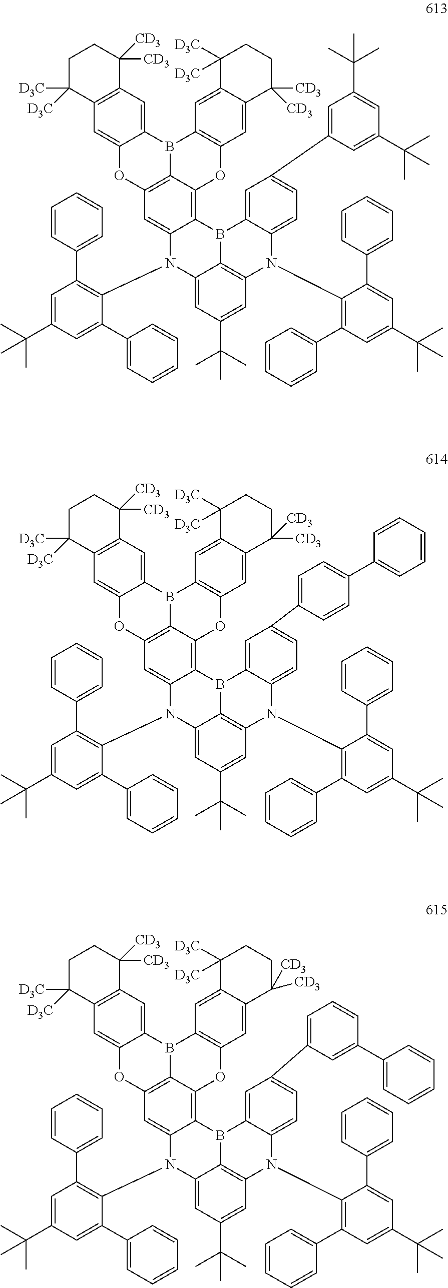

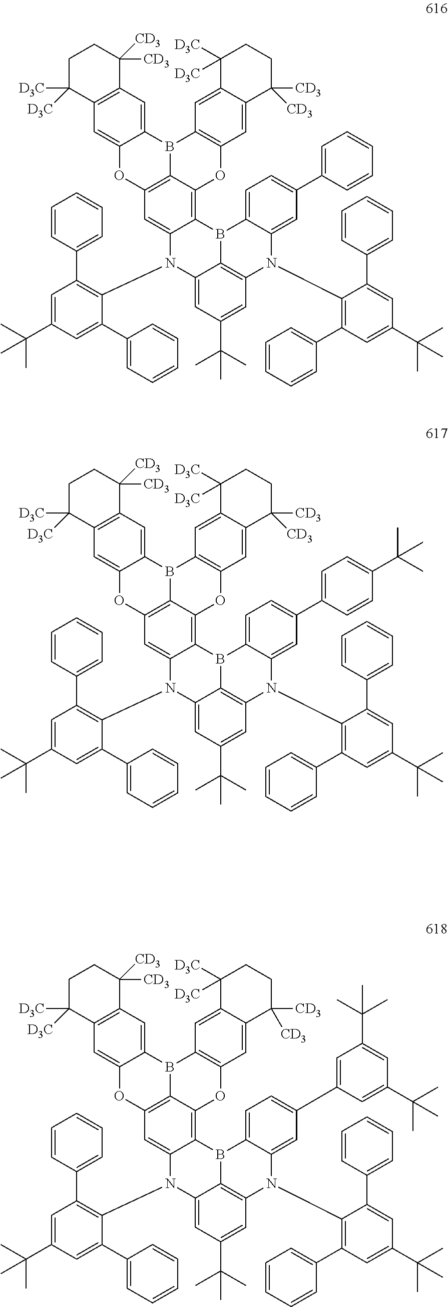

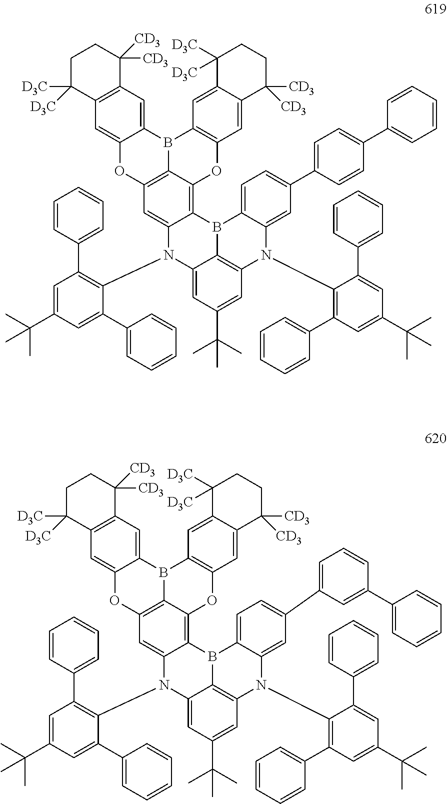

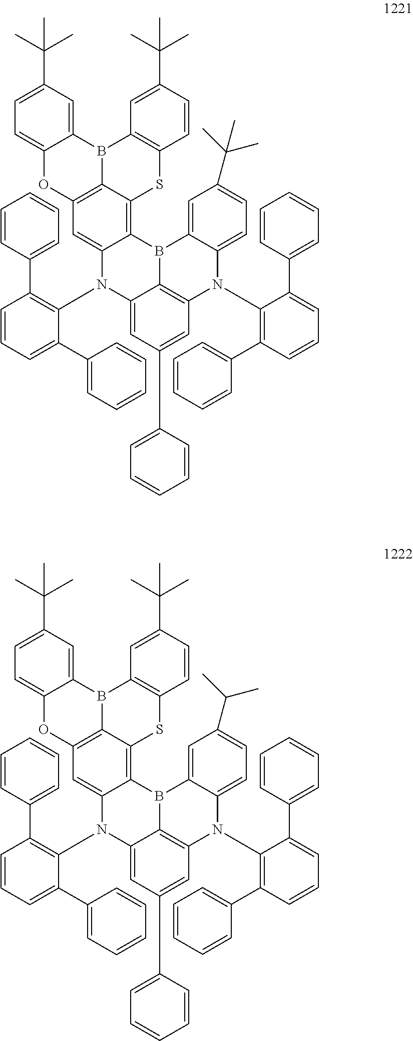 [SMILES: CC(C)(C)c1ccc2c(c1)B1c3cc(C(C)(C)C)ccc3Sc3c1c(cc1c3B3c4cc(C(C)(C)C)ccc4N(c4c(-c5ccccc5)cccc4-c4ccccc4)c4cc(-c5ccccc5)cc(c43)N1c1c(-c3ccccc3)cccc1-c1ccccc1)O2 ; CC(C)c1ccc2c(c1)B1c3c(cc(-c4ccccc4)cc3N(c3c(-c4ccccc4)cccc3-c3ccccc3)c3cc4c5c(c31)Sc1ccc(C(C)(C)C)cc1B5c1cc(C(C)(C)C)ccc1O4)N2c1c(-c2ccccc2)cccc1-c1ccccc1]

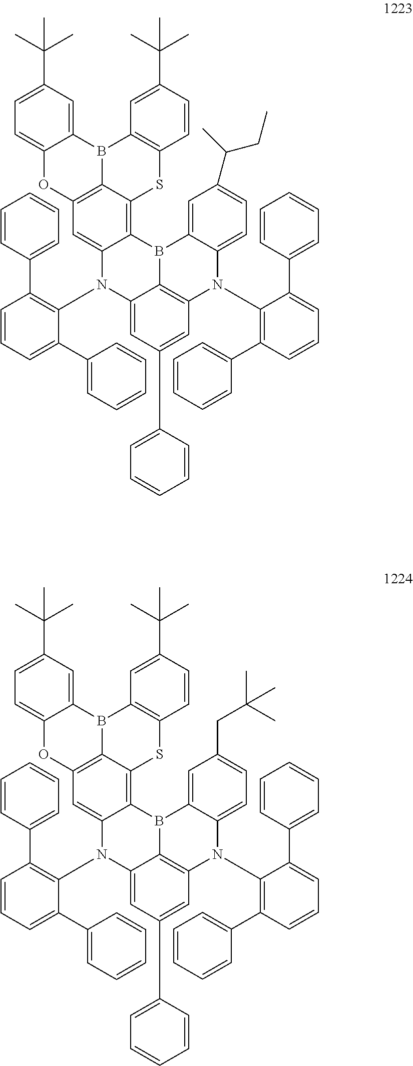 [SMILES: CCC(C)c1ccc2c(c1)B1c3c(cc(-c4ccccc4)cc3N(c3c(-c4ccccc4)cccc3-c3ccccc3)c3cc4c5c(c31)Sc1ccc(C(C)(C)C)cc1B5c1cc(C(C)(C)C)ccc1O4)N2c1c(-c2ccccc2)cccc1-c1ccccc1 ; CC(C)(C)Cc1ccc2c(c1)B1c3c(cc(-c4ccccc4)cc3N(c3c(-c4ccccc4)cccc3-c3ccccc3)c3cc4c5c(c31)Sc1ccc(C(C)(C)C)cc1B5c1cc(C(C)(C)C)ccc1O4)N2c1c(-c2ccccc2)cccc1-c1ccccc1]

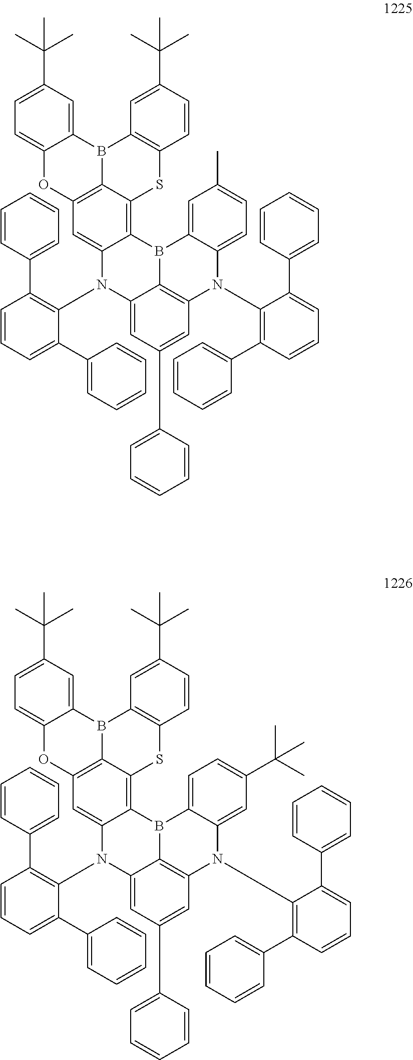 [SMILES: Cc1ccc2c(c1)B1c3c(cc(-c4ccccc4)cc3N(c3c(-c4ccccc4)cccc3-c3ccccc3)c3cc4c5c(c31)Sc1ccc(C(C)(C)C)cc1B5c1cc(C(C)(C)C)ccc1O4)N2c1c(-c2ccccc2)cccc1-c1ccccc1 ; CC(C)(C)c1ccc2c(c1)B1c3cc(C(C)(C)C)ccc3Sc3c1c(cc1c3B3c4ccc(C(C)(C)C)cc4N(c4c(-c5ccccc5)cccc4-c4ccccc4)c4cc(-c5ccccc5)cc(c43)N1c1c(-c3ccccc3)cccc1-c1ccccc1)O2]

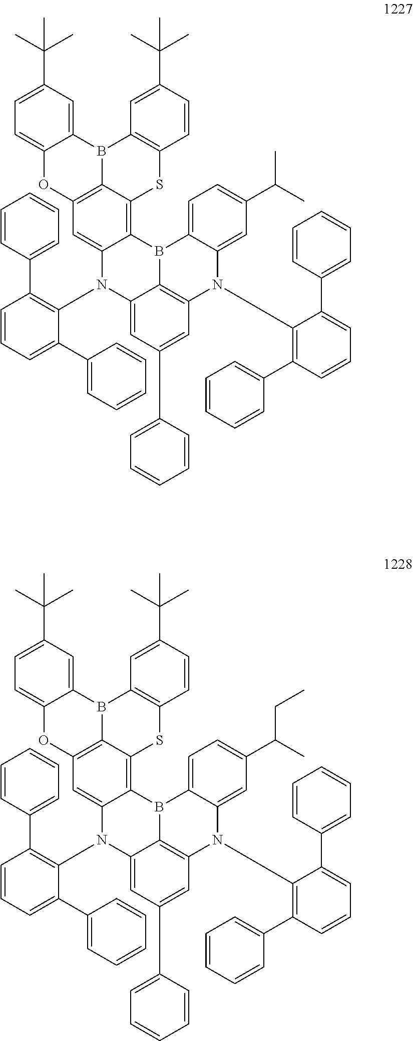 [SMILES: CC(C)c1ccc2c(c1)N(c1c(-c3ccccc3)cccc1-c1ccccc1)c1cc(-c3ccccc3)cc3c1B2c1c(cc2c4c1Sc1ccc(C(C)(C)C)cc1B4c1cc(C(C)(C)C)ccc1O2)N3c1c(-c2ccccc2)cccc1-c1ccccc1 ; CCC(C)c1ccc2c(c1)N(c1c(-c3ccccc3)cccc1-c1ccccc1)c1cc(-c3ccccc3)cc3c1B2c1c(cc2c4c1Sc1ccc(C(C)(C)C)cc1B4c1cc(C(C)(C)C)ccc1O2)N3c1c(-c2ccccc2)cccc1-c1ccccc1]

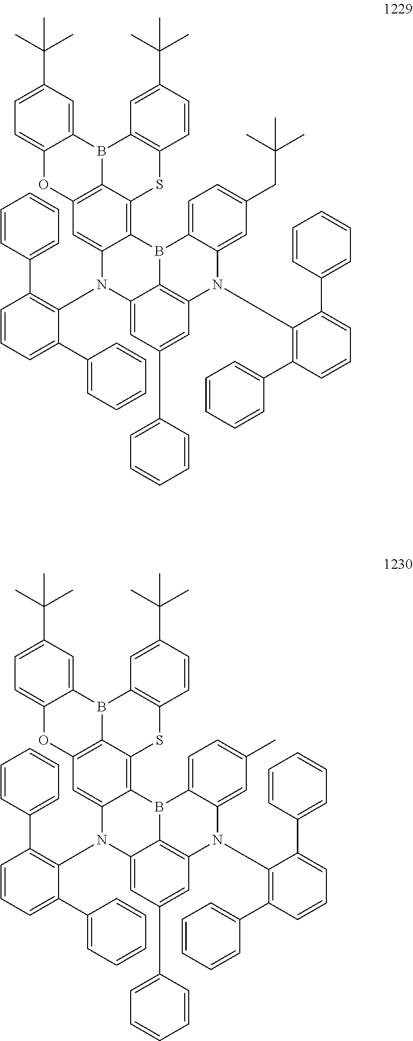 [SMILES: CC(C)(C)Cc1ccc2c(c1)N(c1c(-c3ccccc3)cccc1-c1ccccc1)c1cc(-c3ccccc3)cc3c1B2c1c(cc2c4c1Sc1ccc(C(C)(C)C)cc1B4c1cc(C(C)(C)C)ccc1O2)N3c1c(-c2ccccc2)cccc1-c1ccccc1 ; Cc1ccc2c(c1)N(c1c(-c3ccccc3)cccc1-c1ccccc1)c1cc(-c3ccccc3)cc3c1B2c1c(cc2c4c1Sc1ccc(C(C)(C)C)cc1B4c1cc(C(C)(C)C)ccc1O2)N3c1c(-c2ccccc2)cccc1-c1ccccc1]

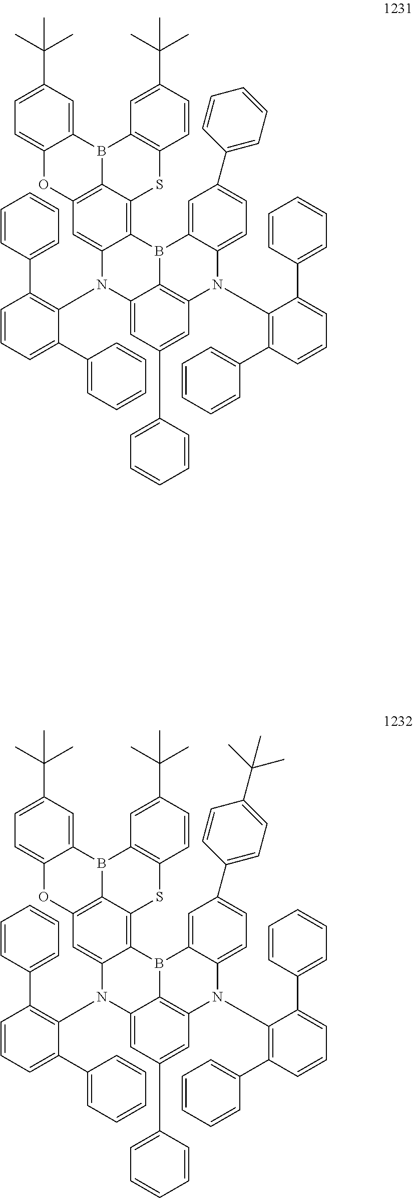 [SMILES: CC(C)(C)c1ccc2c(c1)B1c3cc(C(C)(C)C)ccc3Sc3c1c(cc1c3B3c4cc(-c5ccccc5)ccc4N(c4c(-c5ccccc5)cccc4-c4ccccc4)c4cc(-c5ccccc5)cc(c43)N1c1c(-c3ccccc3)cccc1-c1ccccc1)O2 ; CC(C)(C)c1ccc(-c2ccc3c(c2)B2c4c(cc(-c5ccccc5)cc4N(c4c(-c5ccccc5)cccc4-c4ccccc4)c4cc5c6c(c42)Sc2ccc(C(C)(C)C)cc2B6c2cc(C(C)(C)C)ccc2O5)N3c2c(-c3ccccc3)cccc2-c2ccccc2)cc1]

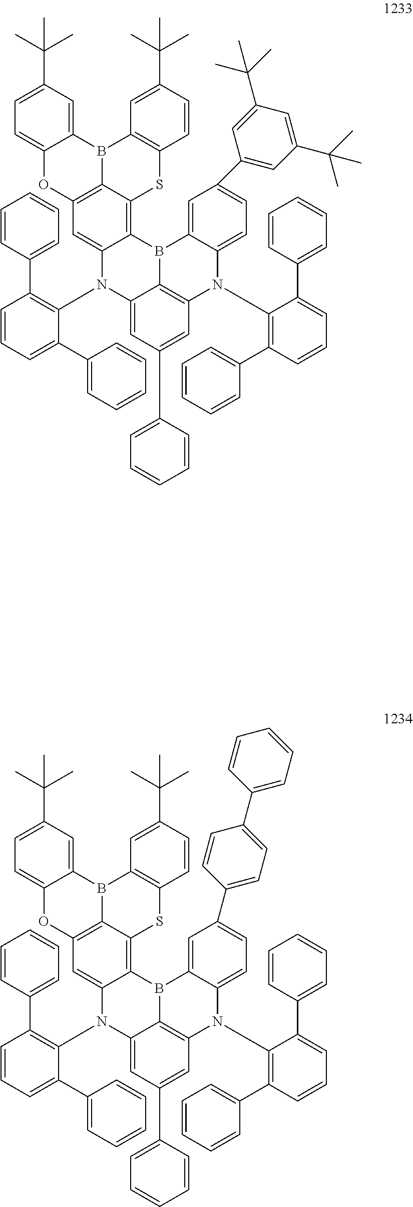 [SMILES: CC(C)(C)c1cc(-c2ccc3c(c2)B2c4c(cc(-c5ccccc5)cc4N(c4c(-c5ccccc5)cccc4-c4ccccc4)c4cc5c6c(c42)Sc2ccc(C(C)(C)C)cc2B6c2cc(C(C)(C)C)ccc2O5)N3c2c(-c3ccccc3)cccc2-c2ccccc2)cc(C(C)(C)C)c1 ; CC(C)(C)c1ccc2c(c1)B1c3cc(C(C)(C)C)ccc3Sc3c1c(cc1c3B3c4cc(-c5ccc(-c6ccccc6)cc5)ccc4N(c4c(-c5ccccc5)cccc4-c4ccccc4)c4cc(-c5ccccc5)cc(c43)N1c1c(-c3ccccc3)cccc1-c1ccccc1)O2]

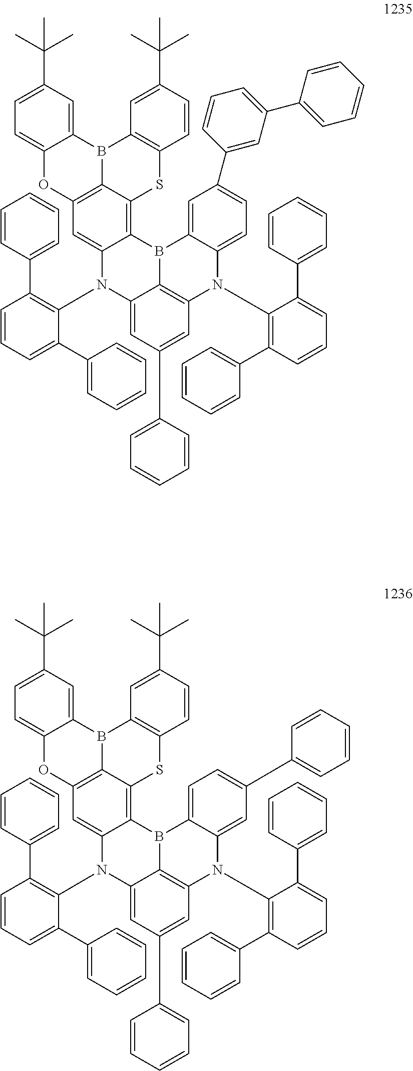 [SMILES: CC(C)(C)c1ccc2c(c1)B1c3cc(C(C)(C)C)ccc3Sc3c1c(cc1c3B3c4cc(-c5cccc(-c6ccccc6)c5)ccc4N(c4c(-c5ccccc5)cccc4-c4ccccc4)c4cc(-c5ccccc5)cc(c43)N1c1c(-c3ccccc3)cccc1-c1ccccc1)O2 ; CC(C)(C)c1ccc2c(c1)B1c3cc(C(C)(C)C)ccc3Sc3c1c(cc1c3B3c4ccc(-c5ccccc5)cc4N(c4c(-c5ccccc5)cccc4-c4ccccc4)c4cc(-c5ccccc5)cc(c43)N1c1c(-c3ccccc3)cccc1-c1ccccc1)O2]

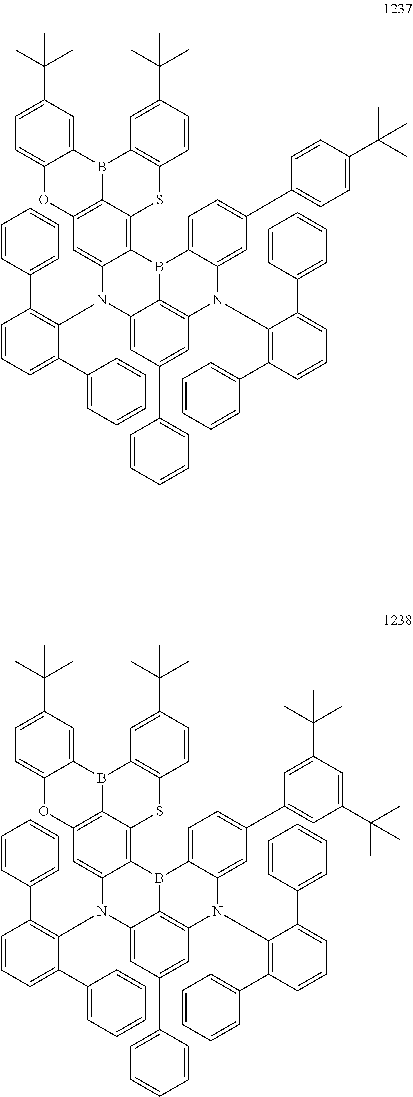 [SMILES: CC(C)(C)c1ccc(-c2ccc3c(c2)N(c2c(-c4ccccc4)cccc2-c2ccccc2)c2cc(-c4ccccc4)cc4c2B3c2c(cc3c5c2Sc2ccc(C(C)(C)C)cc2B5c2cc(C(C)(C)C)ccc2O3)N4c2c(-c3ccccc3)cccc2-c2ccccc2)cc1 ; CC(C)(C)c1cc(-c2ccc3c(c2)N(c2c(-c4ccccc4)cccc2-c2ccccc2)c2cc(-c4ccccc4)cc4c2B3c2c(cc3c5c2Sc2ccc(C(C)(C)C)cc2B5c2cc(C(C)(C)C)ccc2O3)N4c2c(-c3ccccc3)cccc2-c2ccccc2)cc(C(C)(C)C)c1]

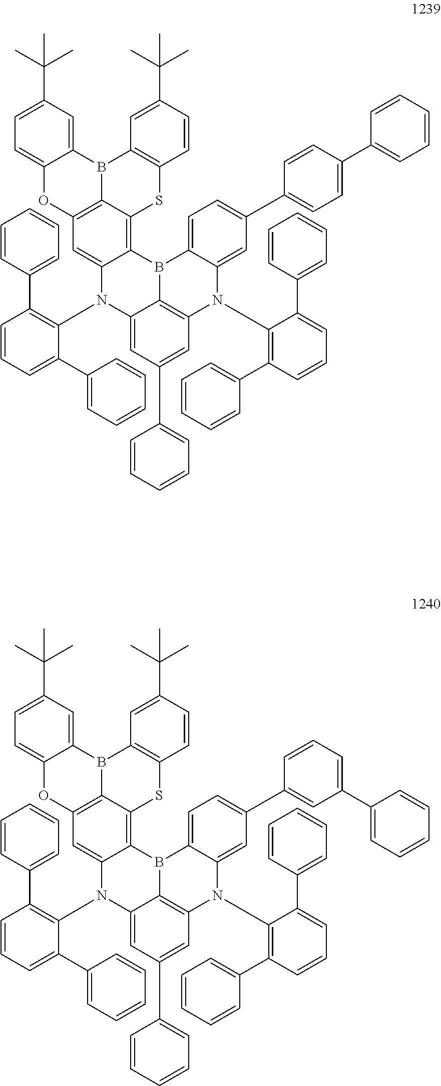 [SMILES: CC(C)(C)c1ccc2c(c1)B1c3cc(C(C)(C)C)ccc3Sc3c1c(cc1c3B3c4ccc(-c5ccc(-c6ccccc6)cc5)cc4N(c4c(-c5ccccc5)cccc4-c4ccccc4)c4cc(-c5ccccc5)cc(c43)N1c1c(-c3ccccc3)cccc1-c1ccccc1)O2 ; CC(C)(C)c1ccc2c(c1)B1c3cc(C(C)(C)C)ccc3Sc3c1c(cc1c3B3c4ccc(-c5cccc(-c6ccccc6)c5)cc4N(c4c(-c5ccccc5)cccc4-c4ccccc4)c4cc(-c5ccccc5)cc(c43)N1c1c(-c3ccccc3)cccc1-c1ccccc1)O2]

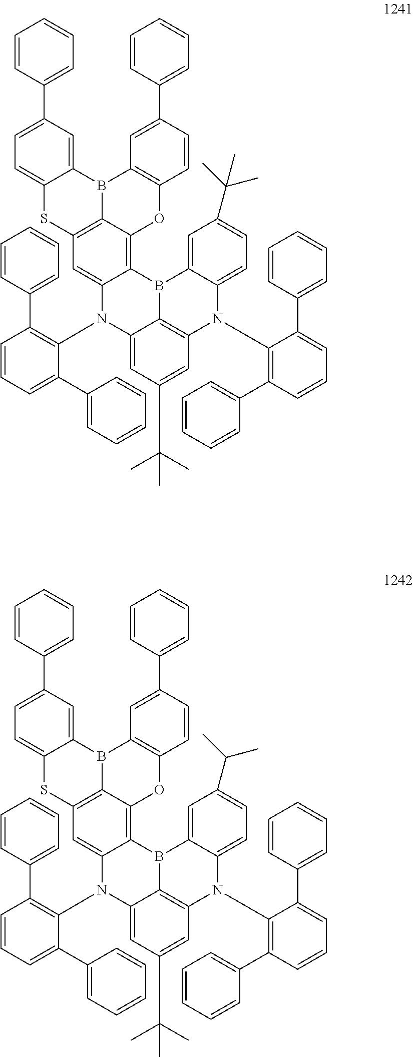 [SMILES: CC(C)(C)c1ccc2c(c1)B1c3c(cc(C(C)(C)C)cc3N(c3c(-c4ccccc4)cccc3-c3ccccc3)c3cc4c5c(c31)Oc1ccc(-c3ccccc3)cc1B5c1cc(-c3ccccc3)ccc1S4)N2c1c(-c2ccccc2)cccc1-c1ccccc1 ; CC(C)c1ccc2c(c1)B1c3c(cc(C(C)(C)C)cc3N(c3c(-c4ccccc4)cccc3-c3ccccc3)c3cc4c5c(c31)Oc1ccc(-c3ccccc3)cc1B5c1cc(-c3ccccc3)ccc1S4)N2c1c(-c2ccccc2)cccc1-c1ccccc1]

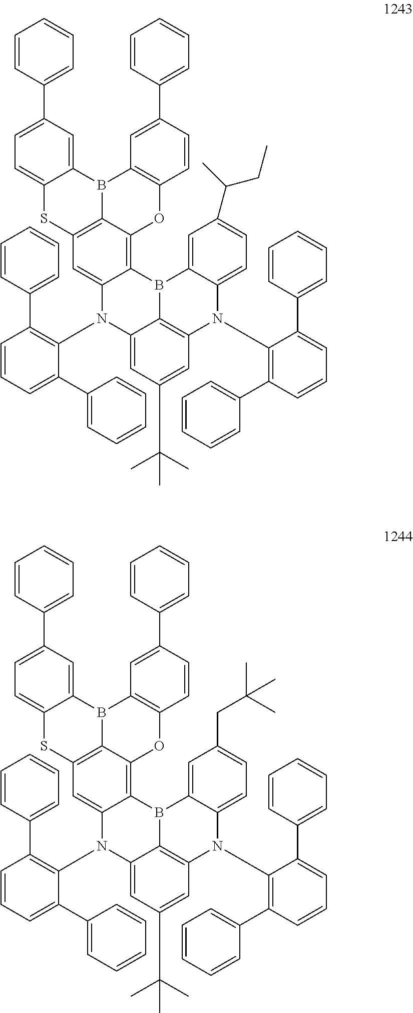 [SMILES: CCC(C)c1ccc2c(c1)B1c3c(cc(C(C)(C)C)cc3N(c3c(-c4ccccc4)cccc3-c3ccccc3)c3cc4c5c(c31)Oc1ccc(-c3ccccc3)cc1B5c1cc(-c3ccccc3)ccc1S4)N2c1c(-c2ccccc2)cccc1-c1ccccc1 ; CC(C)(C)Cc1ccc2c(c1)B1c3c(cc(C(C)(C)C)cc3N(c3c(-c4ccccc4)cccc3-c3ccccc3)c3cc4c5c(c31)Oc1ccc(-c3ccccc3)cc1B5c1cc(-c3ccccc3)ccc1S4)N2c1c(-c2ccccc2)cccc1-c1ccccc1]

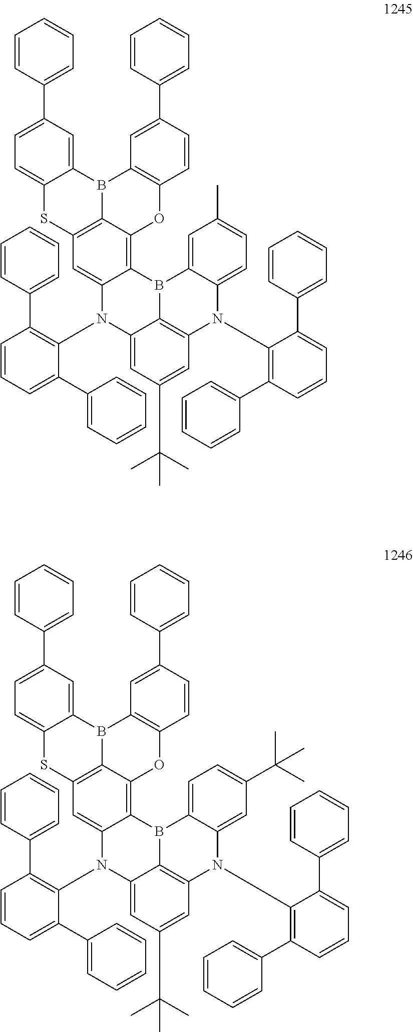 [SMILES: Cc1ccc2c(c1)B1c3c(cc(C(C)(C)C)cc3N(c3c(-c4ccccc4)cccc3-c3ccccc3)c3cc4c5c(c31)Oc1ccc(-c3ccccc3)cc1B5c1cc(-c3ccccc3)ccc1S4)N2c1c(-c2ccccc2)cccc1-c1ccccc1 ; CC(C)(C)c1ccc2c(c1)N(c1c(-c3ccccc3)cccc1-c1ccccc1)c1cc(C(C)(C)C)cc3c1B2c1c(cc2c4c1Oc1ccc(-c5ccccc5)cc1B4c1cc(-c4ccccc4)ccc1S2)N3c1c(-c2ccccc2)cccc1-c1ccccc1]

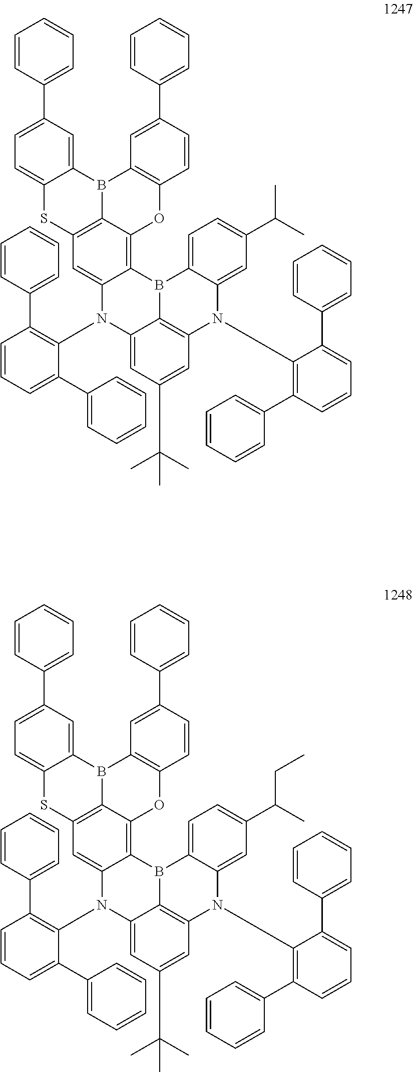 [SMILES: CC(C)c1ccc2c(c1)N(c1c(-c3ccccc3)cccc1-c1ccccc1)c1cc(C(C)(C)C)cc3c1B2c1c(cc2c4c1Oc1ccc(-c5ccccc5)cc1B4c1cc(-c4ccccc4)ccc1S2)N3c1c(-c2ccccc2)cccc1-c1ccccc1 ; CCC(C)c1ccc2c(c1)N(c1c(-c3ccccc3)cccc1-c1ccccc1)c1cc(C(C)(C)C)cc3c1B2c1c(cc2c4c1Oc1ccc(-c5ccccc5)cc1B4c1cc(-c4ccccc4)ccc1S2)N3c1c(-c2ccccc2)cccc1-c1ccccc1]

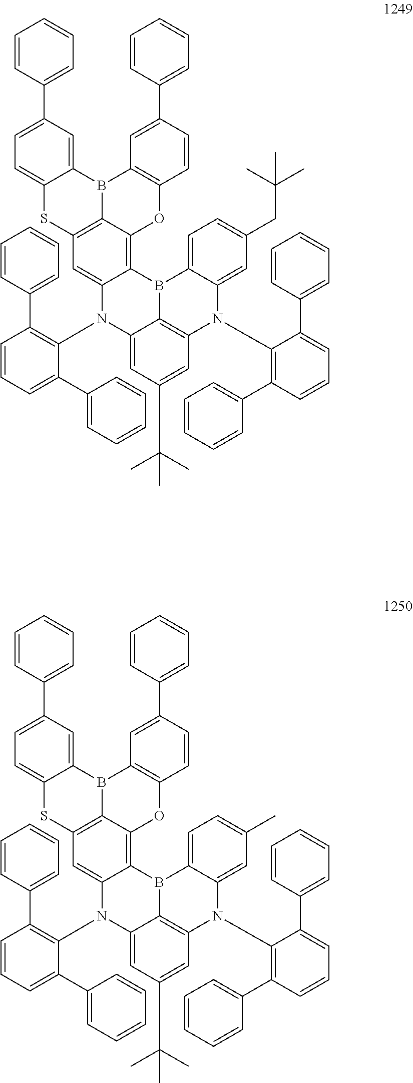 [SMILES: CC(C)(C)Cc1ccc2c(c1)N(c1c(-c3ccccc3)cccc1-c1ccccc1)c1cc(C(C)(C)C)cc3c1B2c1c(cc2c4c1Oc1ccc(-c5ccccc5)cc1B4c1cc(-c4ccccc4)ccc1S2)N3c1c(-c2ccccc2)cccc1-c1ccccc1 ; Cc1ccc2c(c1)N(c1c(-c3ccccc3)cccc1-c1ccccc1)c1cc(C(C)(C)C)cc3c1B2c1c(cc2c4c1Oc1ccc(-c5ccccc5)cc1B4c1cc(-c4ccccc4)ccc1S2)N3c1c(-c2ccccc2)cccc1-c1ccccc1]

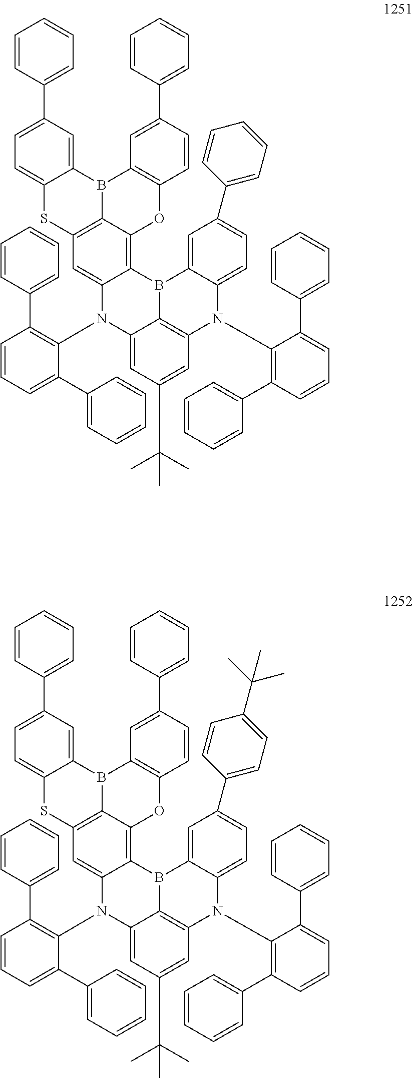 [SMILES: CC(C)(C)c1cc2c3c(c1)N(c1c(-c4ccccc4)cccc1-c1ccccc1)c1cc4c5c(c1B3c1cc(-c3ccccc3)ccc1N2c1c(-c2ccccc2)cccc1-c1ccccc1)Oc1ccc(-c2ccccc2)cc1B5c1cc(-c2ccccc2)ccc1S4 ; CC(C)(C)c1ccc(-c2ccc3c(c2)B2c4c(cc(C(C)(C)C)cc4N(c4c(-c5ccccc5)cccc4-c4ccccc4)c4cc5c6c(c42)Oc2ccc(-c4ccccc4)cc2B6c2cc(-c4ccccc4)ccc2S5)N3c2c(-c3ccccc3)cccc2-c2ccccc2)cc1]

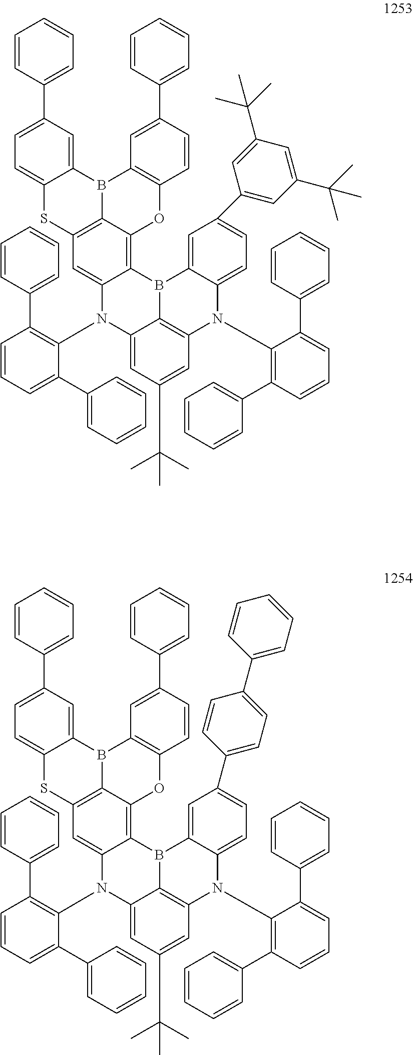 [SMILES: CC(C)(C)c1cc(-c2ccc3c(c2)B2c4c(cc(C(C)(C)C)cc4N(c4c(-c5ccccc5)cccc4-c4ccccc4)c4cc5c6c(c42)Oc2ccc(-c4ccccc4)cc2B6c2cc(-c4ccccc4)ccc2S5)N3c2c(-c3ccccc3)cccc2-c2ccccc2)cc(C(C)(C)C)c1 ; CC(C)(C)c1cc2c3c(c1)N(c1c(-c4ccccc4)cccc1-c1ccccc1)c1cc4c5c(c1B3c1cc(-c3ccc(-c6ccccc6)cc3)ccc1N2c1c(-c2ccccc2)cccc1-c1ccccc1)Oc1ccc(-c2ccccc2)cc1B5c1cc(-c2ccccc2)ccc1S4]

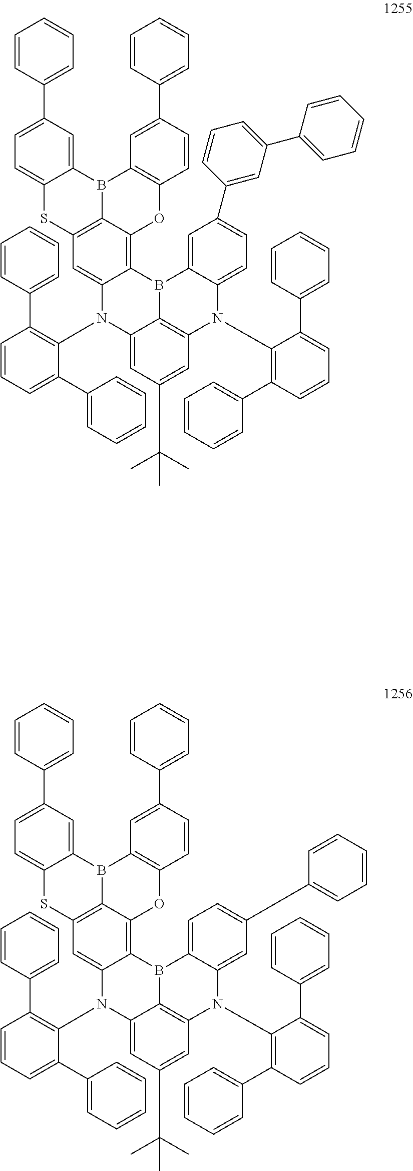 [SMILES: CC(C)(C)c1cc2c3c(c1)N(c1c(-c4ccccc4)cccc1-c1ccccc1)c1cc4c5c(c1B3c1cc(-c3cccc(-c6ccccc6)c3)ccc1N2c1c(-c2ccccc2)cccc1-c1ccccc1)Oc1ccc(-c2ccccc2)cc1B5c1cc(-c2ccccc2)ccc1S4 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1ccc(-c2ccccc2)cc1B5c1cc(-c2ccccc2)ccc1S4]

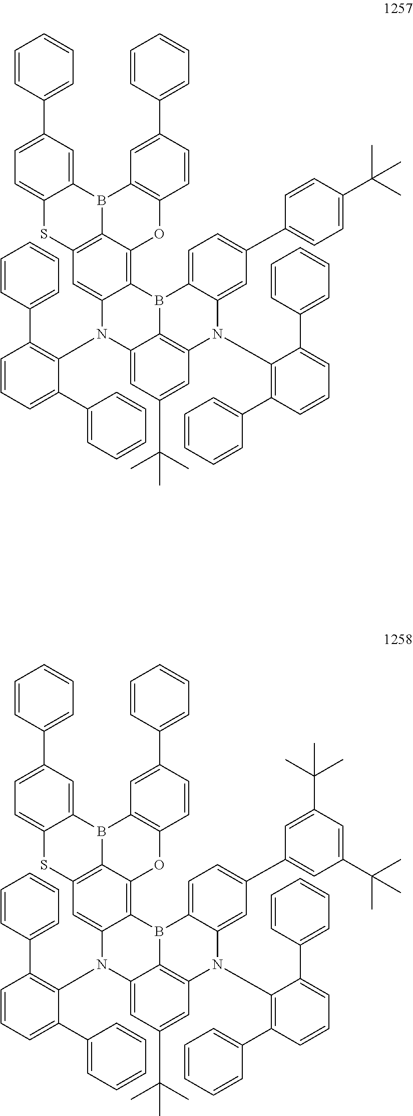 [SMILES: CC(C)(C)c1ccc(-c2ccc3c(c2)N(c2c(-c4ccccc4)cccc2-c2ccccc2)c2cc(C(C)(C)C)cc4c2B3c2c(cc3c5c2Oc2ccc(-c6ccccc6)cc2B5c2cc(-c5ccccc5)ccc2S3)N4c2c(-c3ccccc3)cccc2-c2ccccc2)cc1 ; CC(C)(C)c1cc(-c2ccc3c(c2)N(c2c(-c4ccccc4)cccc2-c2ccccc2)c2cc(C(C)(C)C)cc4c2B3c2c(cc3c5c2Oc2ccc(-c6ccccc6)cc2B5c2cc(-c5ccccc5)ccc2S3)N4c2c(-c3ccccc3)cccc2-c2ccccc2)cc(C(C)(C)C)c1]

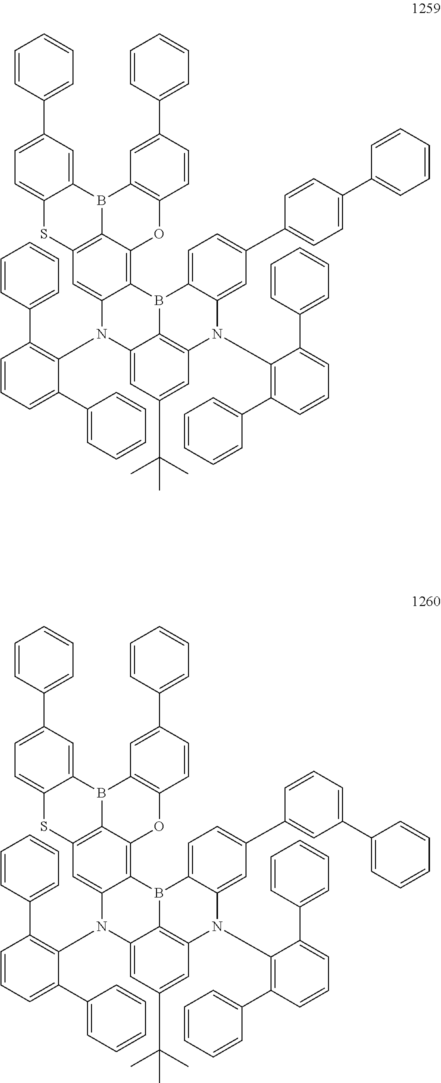 [SMILES: CC(C)(C)c1cc2c3c(c1)N(c1c(-c4ccccc4)cccc1-c1ccccc1)c1cc4c5c(c1B3c1ccc(-c3ccc(-c6ccccc6)cc3)cc1N2c1c(-c2ccccc2)cccc1-c1ccccc1)Oc1ccc(-c2ccccc2)cc1B5c1cc(-c2ccccc2)ccc1S4 ; CC(C)(C)c1cc2c3c(c1)N(c1c(-c4ccccc4)cccc1-c1ccccc1)c1cc4c5c(c1B3c1ccc(-c3cccc(-c6ccccc6)c3)cc1N2c1c(-c2ccccc2)cccc1-c1ccccc1)Oc1ccc(-c2ccccc2)cc1B5c1cc(-c2ccccc2)ccc1S4]

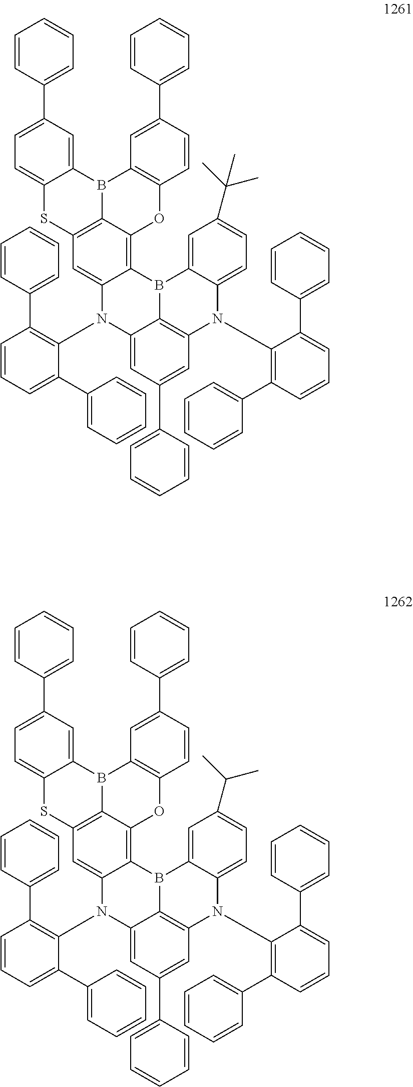 [SMILES: CC(C)(C)c1ccc2c(c1)B1c3c(cc(-c4ccccc4)cc3N(c3c(-c4ccccc4)cccc3-c3ccccc3)c3cc4c5c(c31)Oc1ccc(-c3ccccc3)cc1B5c1cc(-c3ccccc3)ccc1S4)N2c1c(-c2ccccc2)cccc1-c1ccccc1 ; CC(C)c1ccc2c(c1)B1c3c(cc(-c4ccccc4)cc3N(c3c(-c4ccccc4)cccc3-c3ccccc3)c3cc4c5c(c31)Oc1ccc(-c3ccccc3)cc1B5c1cc(-c3ccccc3)ccc1S4)N2c1c(-c2ccccc2)cccc1-c1ccccc1]

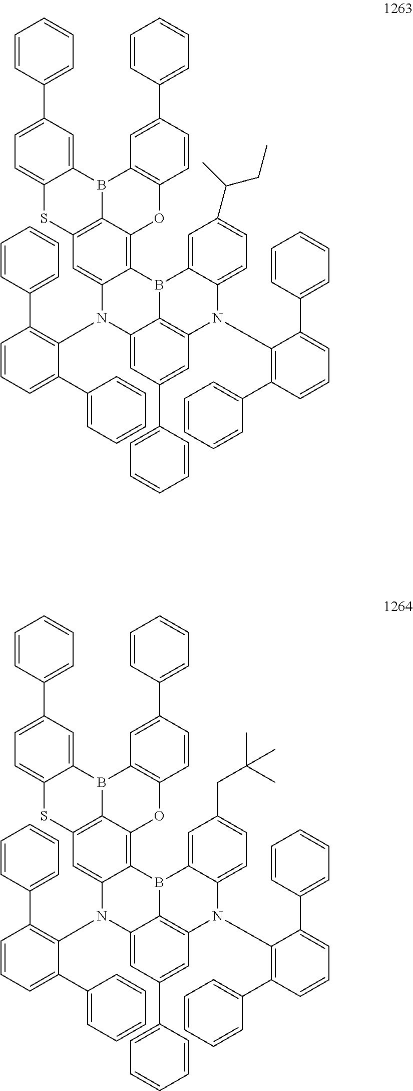 [SMILES: CCC(C)c1ccc2c(c1)B1c3c(cc(-c4ccccc4)cc3N(c3c(-c4ccccc4)cccc3-c3ccccc3)c3cc4c5c(c31)Oc1ccc(-c3ccccc3)cc1B5c1cc(-c3ccccc3)ccc1S4)N2c1c(-c2ccccc2)cccc1-c1ccccc1 ; CC(C)(C)Cc1ccc2c(c1)B1c3c(cc(-c4ccccc4)cc3N(c3c(-c4ccccc4)cccc3-c3ccccc3)c3cc4c5c(c31)Oc1ccc(-c3ccccc3)cc1B5c1cc(-c3ccccc3)ccc1S4)N2c1c(-c2ccccc2)cccc1-c1ccccc1]

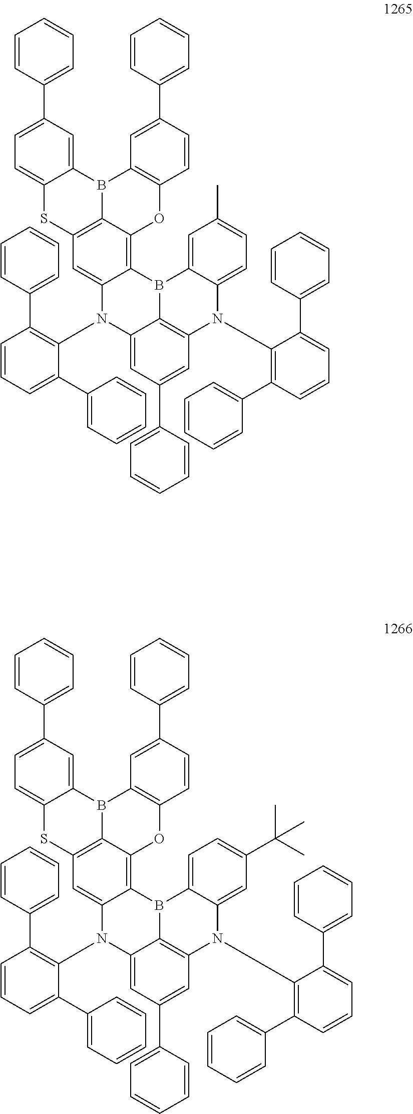 [SMILES: Cc1ccc2c(c1)B1c3c(cc(-c4ccccc4)cc3N(c3c(-c4ccccc4)cccc3-c3ccccc3)c3cc4c5c(c31)Oc1ccc(-c3ccccc3)cc1B5c1cc(-c3ccccc3)ccc1S4)N2c1c(-c2ccccc2)cccc1-c1ccccc1 ; CC(C)(C)c1ccc2c(c1)N(c1c(-c3ccccc3)cccc1-c1ccccc1)c1cc(-c3ccccc3)cc3c1B2c1c(cc2c4c1Oc1ccc(-c5ccccc5)cc1B4c1cc(-c4ccccc4)ccc1S2)N3c1c(-c2ccccc2)cccc1-c1ccccc1]

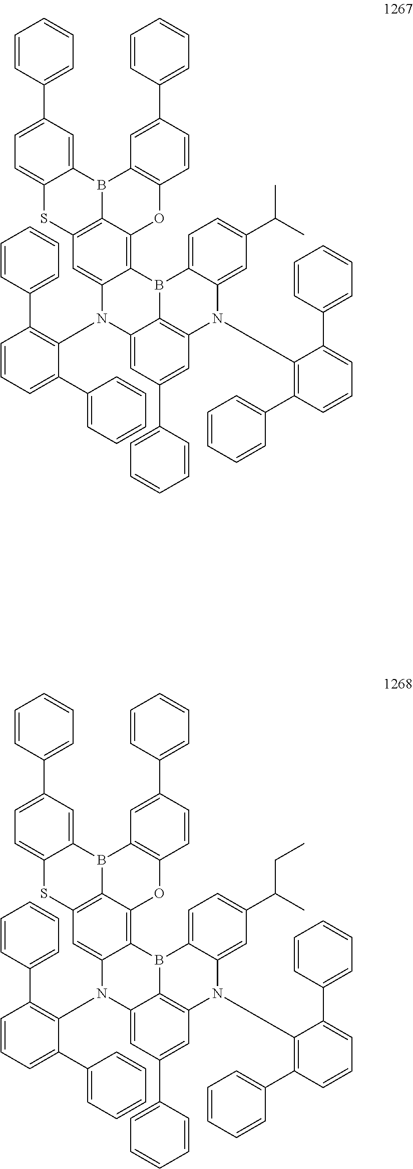 [SMILES: CC(C)c1ccc2c(c1)N(c1c(-c3ccccc3)cccc1-c1ccccc1)c1cc(-c3ccccc3)cc3c1B2c1c(cc2c4c1Oc1ccc(-c5ccccc5)cc1B4c1cc(-c4ccccc4)ccc1S2)N3c1c(-c2ccccc2)cccc1-c1ccccc1 ; CCC(C)c1ccc2c(c1)N(c1c(-c3ccccc3)cccc1-c1ccccc1)c1cc(-c3ccccc3)cc3c1B2c1c(cc2c4c1Oc1ccc(-c5ccccc5)cc1B4c1cc(-c4ccccc4)ccc1S2)N3c1c(-c2ccccc2)cccc1-c1ccccc1]

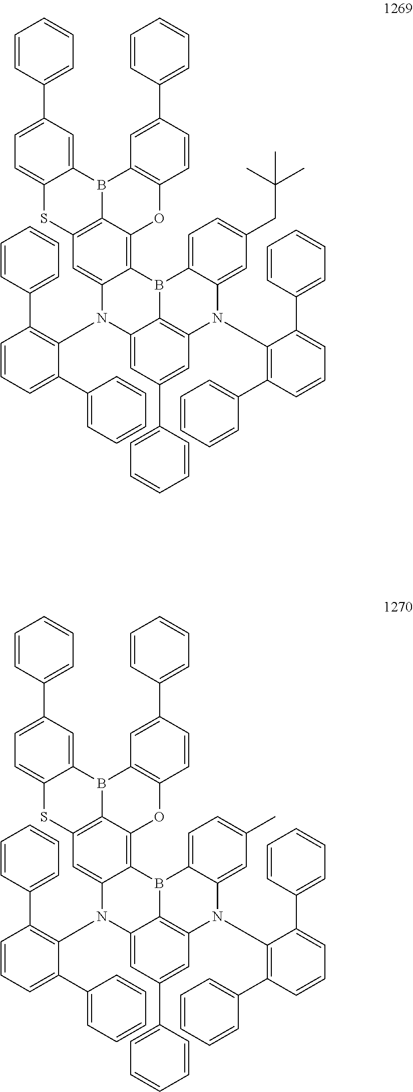 [SMILES: CC(C)(C)Cc1ccc2c(c1)N(c1c(-c3ccccc3)cccc1-c1ccccc1)c1cc(-c3ccccc3)cc3c1B2c1c(cc2c4c1Oc1ccc(-c5ccccc5)cc1B4c1cc(-c4ccccc4)ccc1S2)N3c1c(-c2ccccc2)cccc1-c1ccccc1 ; Cc1ccc2c(c1)N(c1c(-c3ccccc3)cccc1-c1ccccc1)c1cc(-c3ccccc3)cc3c1B2c1c(cc2c4c1Oc1ccc(-c5ccccc5)cc1B4c1cc(-c4ccccc4)ccc1S2)N3c1c(-c2ccccc2)cccc1-c1ccccc1]

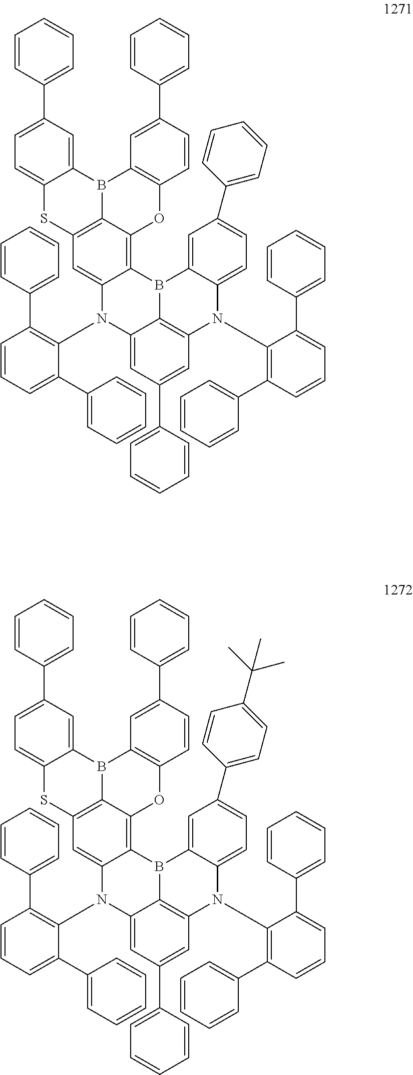 [SMILES: c1ccc(-c2ccc3c(c2)B2c4cc(-c5ccccc5)ccc4Sc4cc5c(c(c42)O3)B2c3cc(-c4ccccc4)ccc3N(c3c(-c4ccccc4)cccc3-c3ccccc3)c3cc(-c4ccccc4)cc(c32)N5c2c(-c3ccccc3)cccc2-c2ccccc2)cc1 ; CC(C)(C)c1ccc(-c2ccc3c(c2)B2c4c(cc(-c5ccccc5)cc4N(c4c(-c5ccccc5)cccc4-c4ccccc4)c4cc5c6c(c42)Oc2ccc(-c4ccccc4)cc2B6c2cc(-c4ccccc4)ccc2S5)N3c2c(-c3ccccc3)cccc2-c2ccccc2)cc1]

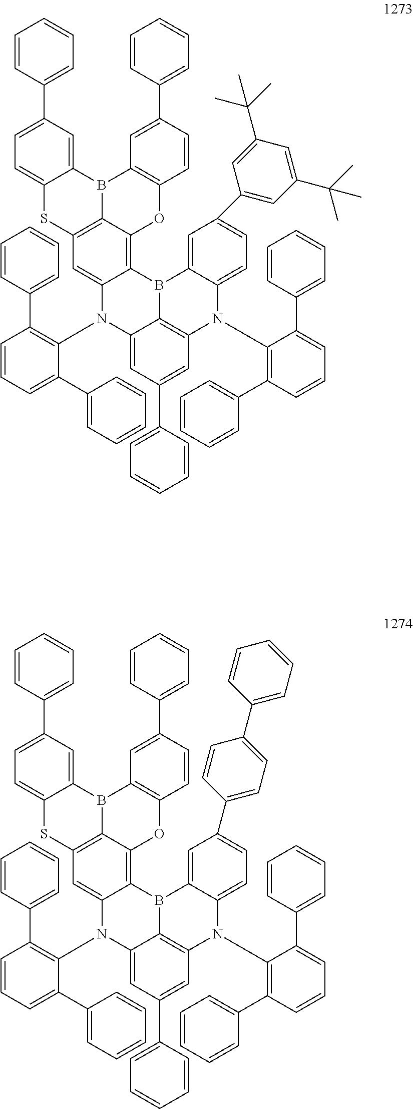 [SMILES: CC(C)(C)c1cc(-c2ccc3c(c2)B2c4c(cc(-c5ccccc5)cc4N(c4c(-c5ccccc5)cccc4-c4ccccc4)c4cc5c6c(c42)Oc2ccc(-c4ccccc4)cc2B6c2cc(-c4ccccc4)ccc2S5)N3c2c(-c3ccccc3)cccc2-c2ccccc2)cc(C(C)(C)C)c1 ; c1ccc(-c2ccc(-c3ccc4c(c3)B3c5c(cc(-c6ccccc6)cc5N(c5c(-c6ccccc6)cccc5-c5ccccc5)c5cc6c7c(c53)Oc3ccc(-c5ccccc5)cc3B7c3cc(-c5ccccc5)ccc3S6)N4c3c(-c4ccccc4)cccc3-c3ccccc3)cc2)cc1]

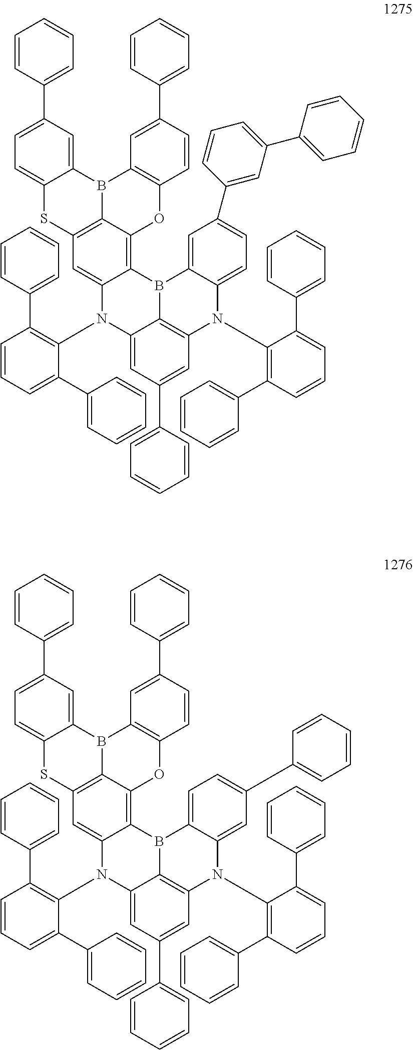 [SMILES: c1ccc(-c2cccc(-c3ccc4c(c3)B3c5c(cc(-c6ccccc6)cc5N(c5c(-c6ccccc6)cccc5-c5ccccc5)c5cc6c7c(c53)Oc3ccc(-c5ccccc5)cc3B7c3cc(-c5ccccc5)ccc3S6)N4c3c(-c4ccccc4)cccc3-c3ccccc3)c2)cc1 ; c1ccc(-c2ccc3c(c2)B2c4cc(-c5ccccc5)ccc4Sc4cc5c(c(c42)O3)B2c3ccc(-c4ccccc4)cc3N(c3c(-c4ccccc4)cccc3-c3ccccc3)c3cc(-c4ccccc4)cc(c32)N5c2c(-c3ccccc3)cccc2-c2ccccc2)cc1]

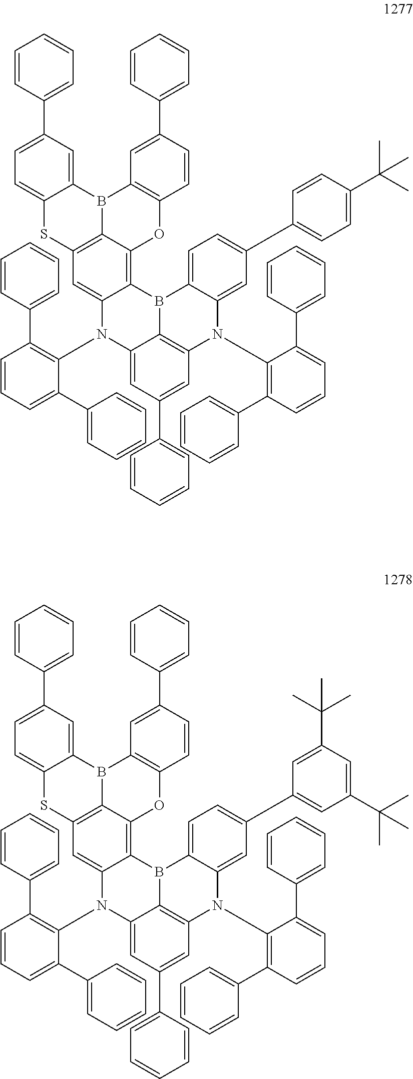 [SMILES: CC(C)(C)c1ccc(-c2ccc3c(c2)N(c2c(-c4ccccc4)cccc2-c2ccccc2)c2cc(-c4ccccc4)cc4c2B3c2c(cc3c5c2Oc2ccc(-c6ccccc6)cc2B5c2cc(-c5ccccc5)ccc2S3)N4c2c(-c3ccccc3)cccc2-c2ccccc2)cc1 ; CC(C)(C)c1cc(-c2ccc3c(c2)N(c2c(-c4ccccc4)cccc2-c2ccccc2)c2cc(-c4ccccc4)cc4c2B3c2c(cc3c5c2Oc2ccc(-c6ccccc6)cc2B5c2cc(-c5ccccc5)ccc2S3)N4c2c(-c3ccccc3)cccc2-c2ccccc2)cc(C(C)(C)C)c1]

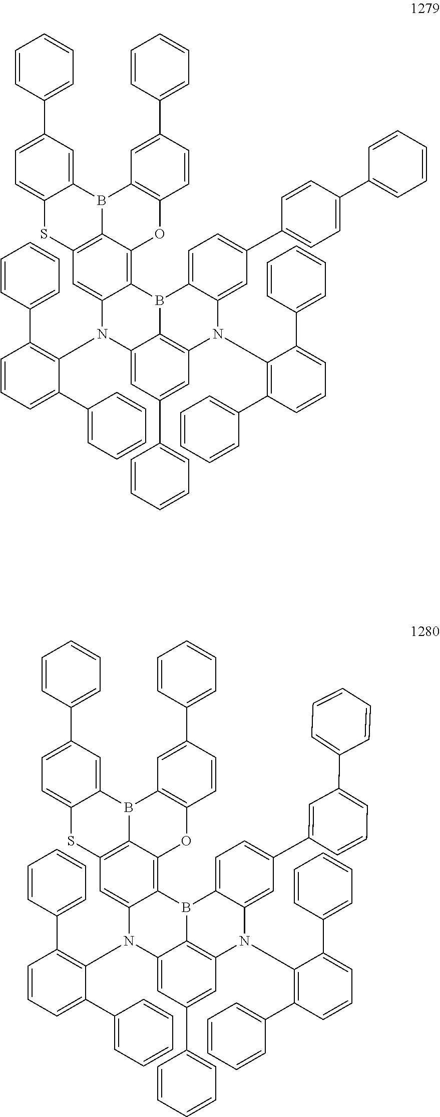 [SMILES: c1ccc(-c2ccc(-c3ccc4c(c3)N(c3c(-c5ccccc5)cccc3-c3ccccc3)c3cc(-c5ccccc5)cc5c3B4c3c(cc4c6c3Oc3ccc(-c7ccccc7)cc3B6c3cc(-c6ccccc6)ccc3S4)N5c3c(-c4ccccc4)cccc3-c3ccccc3)cc2)cc1 ; c1ccc(-c2cccc(-c3ccc4c(c3)N(c3c(-c5ccccc5)cccc3-c3ccccc3)c3cc(-c5ccccc5)cc5c3B4c3c(cc4c6c3Oc3ccc(-c7ccccc7)cc3B6c3cc(-c6ccccc6)ccc3S4)N5c3c(-c4ccccc4)cccc3-c3ccccc3)c2)cc1]

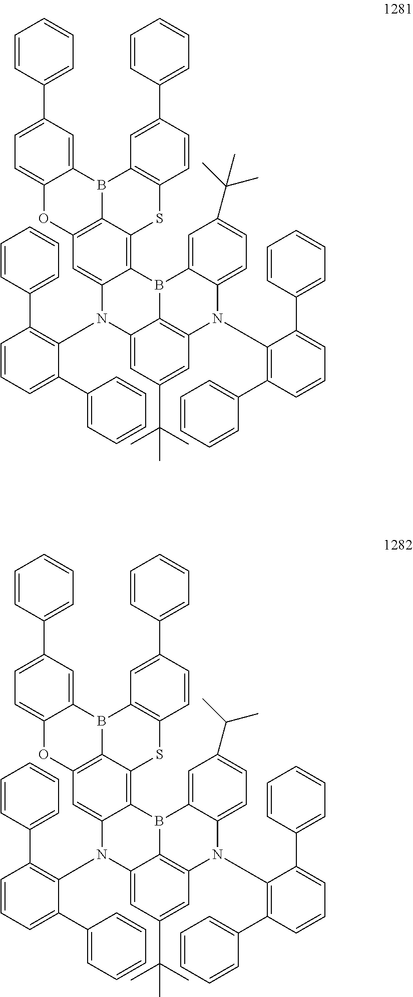 [SMILES: CC(C)(C)c1ccc2c(c1)B1c3c(cc(C(C)(C)C)cc3N(c3c(-c4ccccc4)cccc3-c3ccccc3)c3cc4c5c(c31)Sc1ccc(-c3ccccc3)cc1B5c1cc(-c3ccccc3)ccc1O4)N2c1c(-c2ccccc2)cccc1-c1ccccc1 ; CC(C)c1ccc2c(c1)B1c3c(cc(C(C)(C)C)cc3N(c3c(-c4ccccc4)cccc3-c3ccccc3)c3cc4c5c(c31)Sc1ccc(-c3ccccc3)cc1B5c1cc(-c3ccccc3)ccc1O4)N2c1c(-c2ccccc2)cccc1-c1ccccc1]

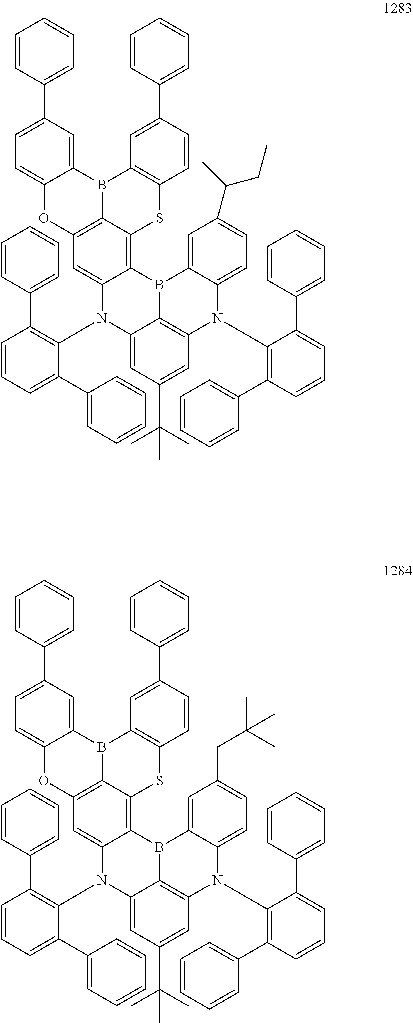 [SMILES: CCC(C)c1ccc2c(c1)B1c3c(cc(C(C)(C)C)cc3N(c3c(-c4ccccc4)cccc3-c3ccccc3)c3cc4c5c(c31)Sc1ccc(-c3ccccc3)cc1B5c1cc(-c3ccccc3)ccc1O4)N2c1c(-c2ccccc2)cccc1-c1ccccc1 ; CC(C)(C)Cc1ccc2c(c1)B1c3c(cc(C(C)(C)C)cc3N(c3c(-c4ccccc4)cccc3-c3ccccc3)c3cc4c5c(c31)Sc1ccc(-c3ccccc3)cc1B5c1cc(-c3ccccc3)ccc1O4)N2c1c(-c2ccccc2)cccc1-c1ccccc1]

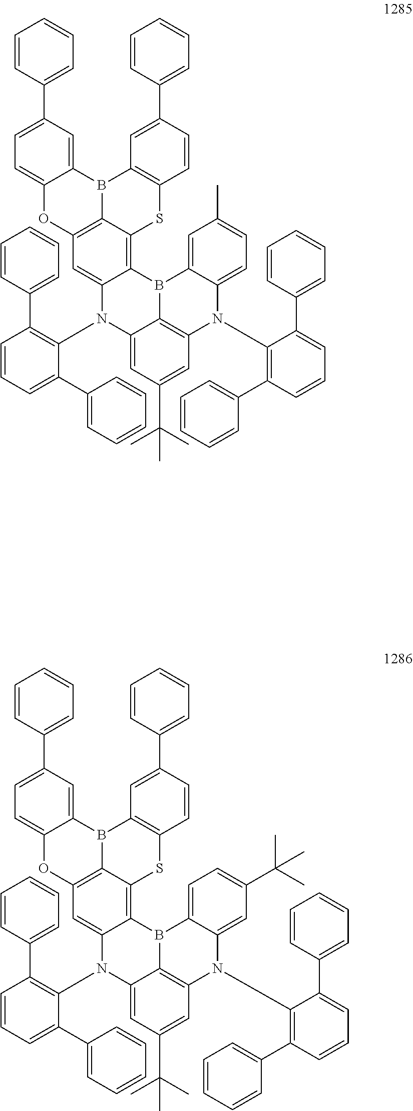 [SMILES: Cc1ccc2c(c1)B1c3c(cc(C(C)(C)C)cc3N(c3c(-c4ccccc4)cccc3-c3ccccc3)c3cc4c5c(c31)Sc1ccc(-c3ccccc3)cc1B5c1cc(-c3ccccc3)ccc1O4)N2c1c(-c2ccccc2)cccc1-c1ccccc1 ; CC(C)(C)c1ccc2c(c1)N(c1c(-c3ccccc3)cccc1-c1ccccc1)c1cc(C(C)(C)C)cc3c1B2c1c(cc2c4c1Sc1ccc(-c5ccccc5)cc1B4c1cc(-c4ccccc4)ccc1O2)N3c1c(-c2ccccc2)cccc1-c1ccccc1]

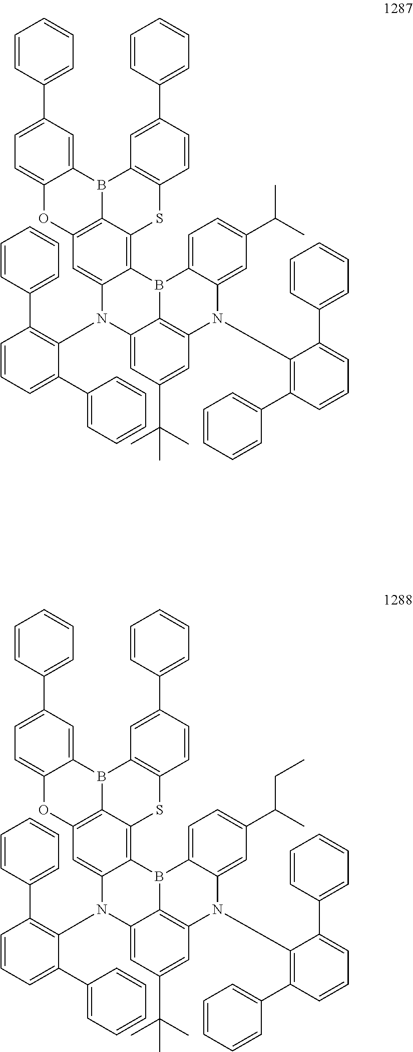 [SMILES: CC(C)c1ccc2c(c1)N(c1c(-c3ccccc3)cccc1-c1ccccc1)c1cc(C(C)(C)C)cc3c1B2c1c(cc2c4c1Sc1ccc(-c5ccccc5)cc1B4c1cc(-c4ccccc4)ccc1O2)N3c1c(-c2ccccc2)cccc1-c1ccccc1 ; CCC(C)c1ccc2c(c1)N(c1c(-c3ccccc3)cccc1-c1ccccc1)c1cc(C(C)(C)C)cc3c1B2c1c(cc2c4c1Sc1ccc(-c5ccccc5)cc1B4c1cc(-c4ccccc4)ccc1O2)N3c1c(-c2ccccc2)cccc1-c1ccccc1]

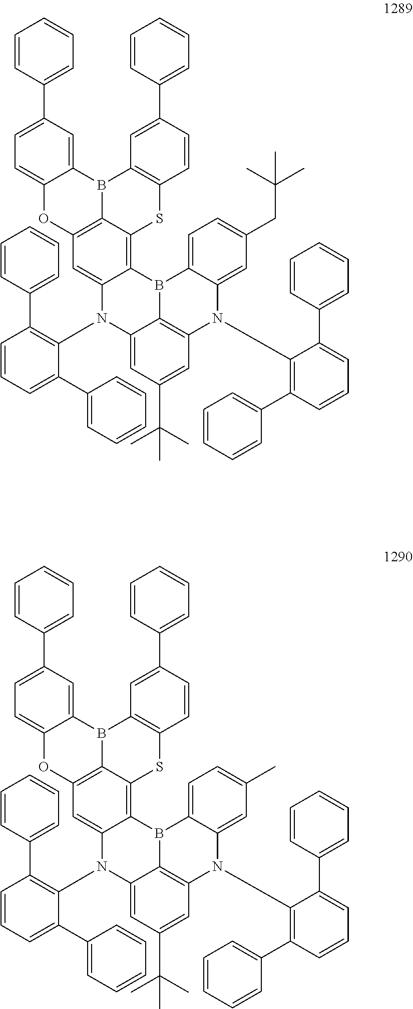 [SMILES: CC(C)(C)Cc1ccc2c(c1)N(c1c(-c3ccccc3)cccc1-c1ccccc1)c1cc(C(C)(C)C)cc3c1B2c1c(cc2c4c1Sc1ccc(-c5ccccc5)cc1B4c1cc(-c4ccccc4)ccc1O2)N3c1c(-c2ccccc2)cccc1-c1ccccc1 ; Cc1ccc2c(c1)N(c1c(-c3ccccc3)cccc1-c1ccccc1)c1cc(C(C)(C)C)cc3c1B2c1c(cc2c4c1Sc1ccc(-c5ccccc5)cc1B4c1cc(-c4ccccc4)ccc1O2)N3c1c(-c2ccccc2)cccc1-c1ccccc1]

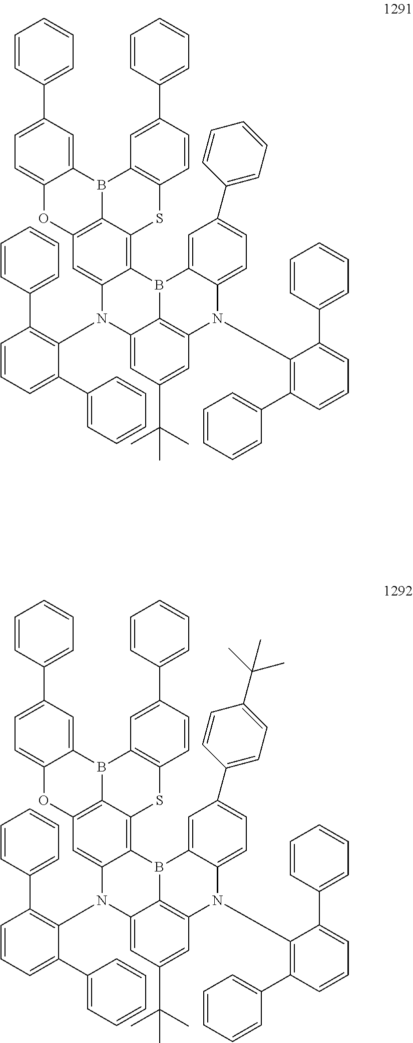 [SMILES: CC(C)(C)c1cc2c3c(c1)N(c1c(-c4ccccc4)cccc1-c1ccccc1)c1cc4c5c(c1B3c1cc(-c3ccccc3)ccc1N2c1c(-c2ccccc2)cccc1-c1ccccc1)Sc1ccc(-c2ccccc2)cc1B5c1cc(-c2ccccc2)ccc1O4 ; CC(C)(C)c1ccc(-c2ccc3c(c2)B2c4c(cc(C(C)(C)C)cc4N(c4c(-c5ccccc5)cccc4-c4ccccc4)c4cc5c6c(c42)Sc2ccc(-c4ccccc4)cc2B6c2cc(-c4ccccc4)ccc2O5)N3c2c(-c3ccccc3)cccc2-c2ccccc2)cc1]

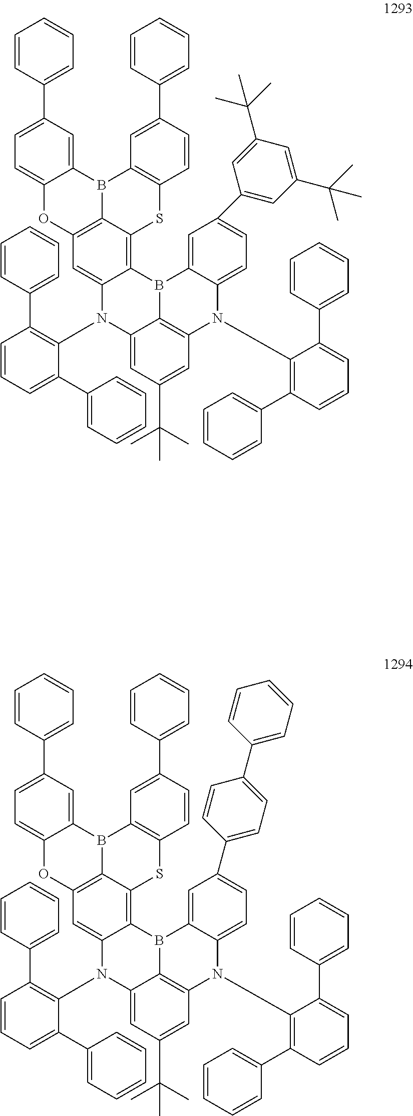 [SMILES: CC(C)(C)c1cc(-c2ccc3c(c2)B2c4c(cc(C(C)(C)C)cc4N(c4c(-c5ccccc5)cccc4-c4ccccc4)c4cc5c6c(c42)Sc2ccc(-c4ccccc4)cc2B6c2cc(-c4ccccc4)ccc2O5)N3c2c(-c3ccccc3)cccc2-c2ccccc2)cc(C(C)(C)C)c1 ; CC(C)(C)c1cc2c3c(c1)N(c1c(-c4ccccc4)cccc1-c1ccccc1)c1cc4c5c(c1B3c1cc(-c3ccc(-c6ccccc6)cc3)ccc1N2c1c(-c2ccccc2)cccc1-c1ccccc1)Sc1ccc(-c2ccccc2)cc1B5c1cc(-c2ccccc2)ccc1O4]

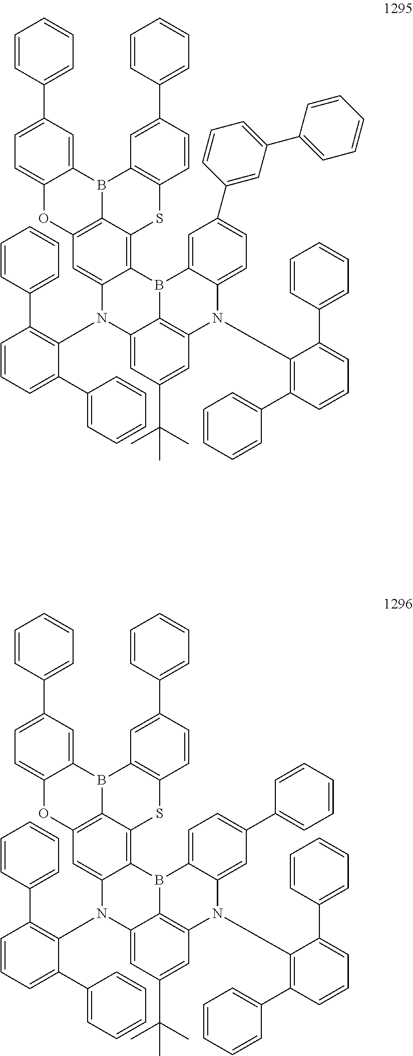 [SMILES: CC(C)(C)c1cc2c3c(c1)N(c1c(-c4ccccc4)cccc1-c1ccccc1)c1cc4c5c(c1B3c1cc(-c3cccc(-c6ccccc6)c3)ccc1N2c1c(-c2ccccc2)cccc1-c1ccccc1)Sc1ccc(-c2ccccc2)cc1B5c1cc(-c2ccccc2)ccc1O4 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Sc1ccc(-c2ccccc2)cc1B5c1cc(-c2ccccc2)ccc1O4]

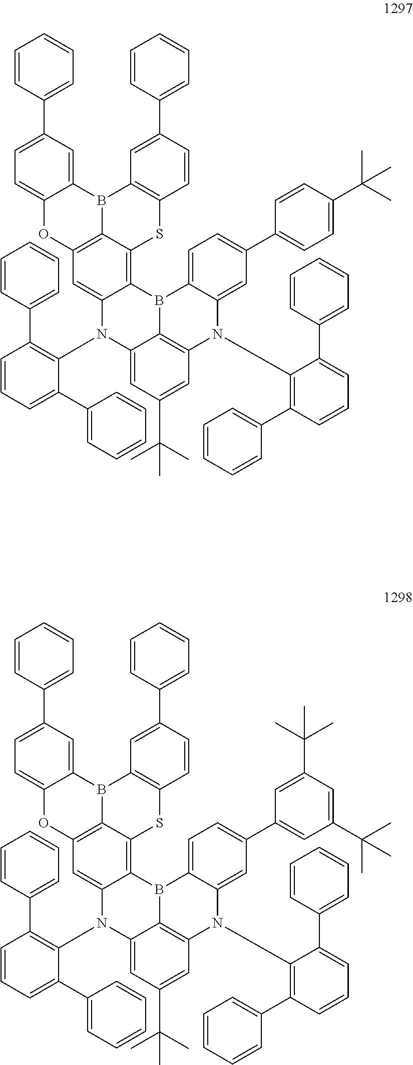 [SMILES: CC(C)(C)c1ccc(-c2ccc3c(c2)N(c2c(-c4ccccc4)cccc2-c2ccccc2)c2cc(C(C)(C)C)cc4c2B3c2c(cc3c5c2Sc2ccc(-c6ccccc6)cc2B5c2cc(-c5ccccc5)ccc2O3)N4c2c(-c3ccccc3)cccc2-c2ccccc2)cc1 ; CC(C)(C)c1cc(-c2ccc3c(c2)N(c2c(-c4ccccc4)cccc2-c2ccccc2)c2cc(C(C)(C)C)cc4c2B3c2c(cc3c5c2Sc2ccc(-c6ccccc6)cc2B5c2cc(-c5ccccc5)ccc2O3)N4c2c(-c3ccccc3)cccc2-c2ccccc2)cc(C(C)(C)C)c1]

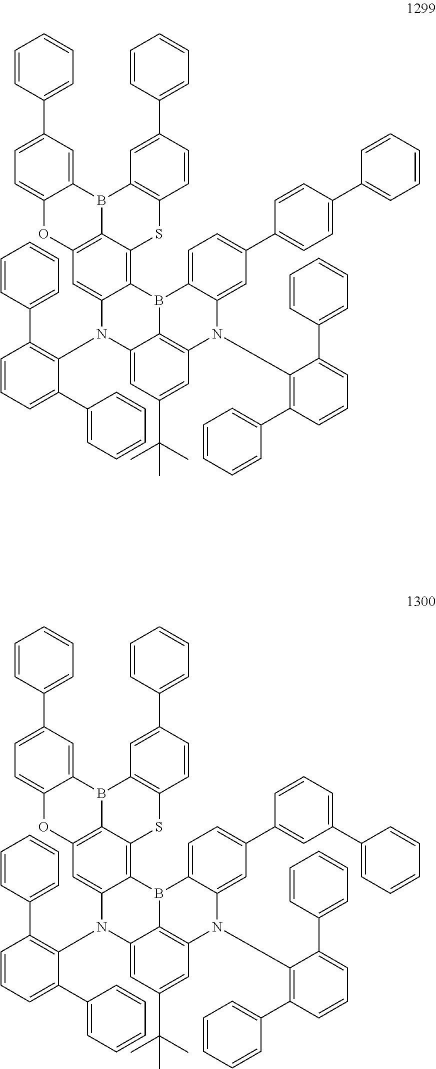 [SMILES: CC(C)(C)c1cc2c3c(c1)N(c1c(-c4ccccc4)cccc1-c1ccccc1)c1cc4c5c(c1B3c1ccc(-c3ccc(-c6ccccc6)cc3)cc1N2c1c(-c2ccccc2)cccc1-c1ccccc1)Sc1ccc(-c2ccccc2)cc1B5c1cc(-c2ccccc2)ccc1O4 ; CC(C)(C)c1cc2c3c(c1)N(c1c(-c4ccccc4)cccc1-c1ccccc1)c1cc4c5c(c1B3c1ccc(-c3cccc(-c6ccccc6)c3)cc1N2c1c(-c2ccccc2)cccc1-c1ccccc1)Sc1ccc(-c2ccccc2)cc1B5c1cc(-c2ccccc2)ccc1O4]

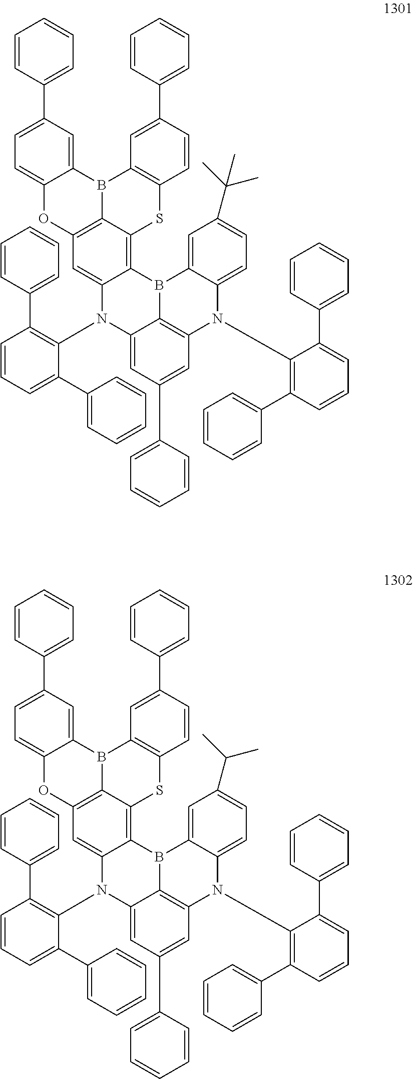 [SMILES: CC(C)(C)c1ccc2c(c1)B1c3c(cc(Cc4ccccc4)cc3N(c3c(-c4ccccc4)cccc3-c3ccccc3)c3cc4c5c(c31)Sc1ccc(-c3ccccc3)cc1B5c1cc(-c3ccccc3)ccc1O4)N2c1c(-c2ccccc2)cccc1-c1ccccc1 ; CC(C)c1ccc2c(c1)B1c3c(cc(Cc4ccccc4)cc3N(c3c(-c4ccccc4)cccc3-c3ccccc3)c3cc4c5c(c31)Sc1ccc(-c3ccccc3)cc1B5c1cc(-c3ccccc3)ccc1O4)N2c1c(-c2ccccc2)cccc1-c1ccccc1]

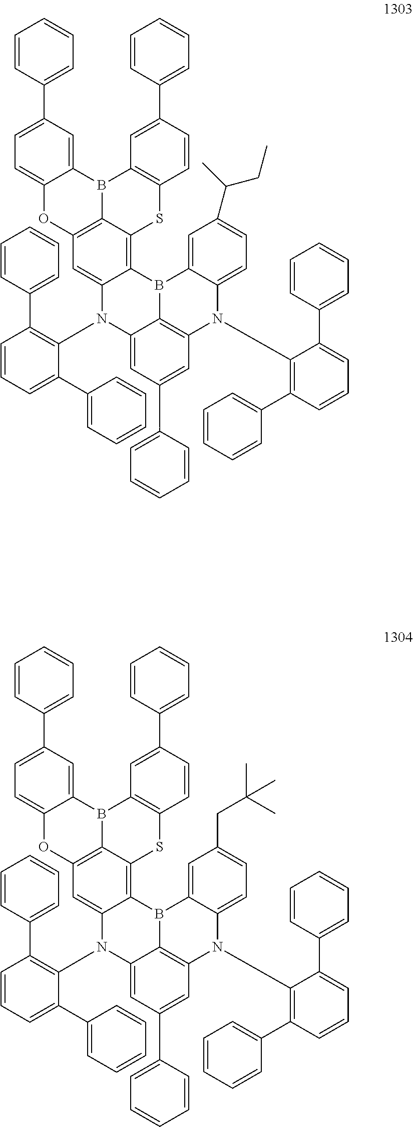 [SMILES: CCC(C)c1ccc2c(c1)B1c3c(cc(Cc4ccccc4)cc3N(c3c(-c4ccccc4)cccc3-c3ccccc3)c3cc4c5c(c31)Sc1ccc(-c3ccccc3)cc1B5c1cc(-c3ccccc3)ccc1O4)N2c1c(-c2ccccc2)cccc1-c1ccccc1 ; CC(C)(C)Cc1ccc2c(c1)B1c3c(cc(Cc4ccccc4)cc3N(c3c(-c4ccccc4)cccc3-c3ccccc3)c3cc4c5c(c31)Sc1ccc(-c3ccccc3)cc1B5c1cc(-c3ccccc3)ccc1O4)N2c1c(-c2ccccc2)cccc1-c1ccccc1]

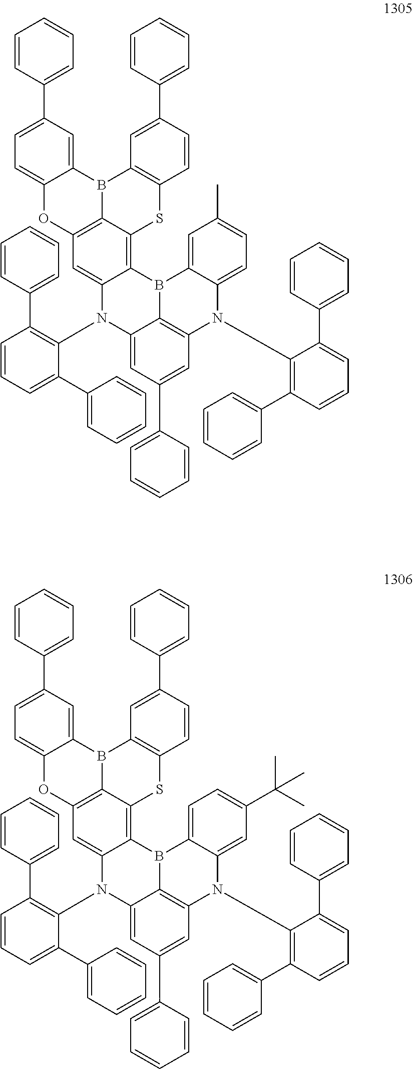 [SMILES: Cc1ccc2c(c1)B1c3c(cc(Cc4ccccc4)cc3N(c3c(-c4ccccc4)cccc3-c3ccccc3)c3cc4c5c(c31)Sc1ccc(-c3ccccc3)cc1B5c1cc(-c3ccccc3)ccc1O4)N2c1c(-c2ccccc2)cccc1-c1ccccc1 ; CC(C)(C)c1ccc2c(c1)N(c1c(-c3ccccc3)cccc1-c1ccccc1)c1cc(Cc3ccccc3)cc3c1B2c1c(cc2c4c1Sc1ccc(-c5ccccc5)cc1B4c1cc(-c4ccccc4)ccc1O2)N3c1c(-c2ccccc2)cccc1-c1ccccc1]

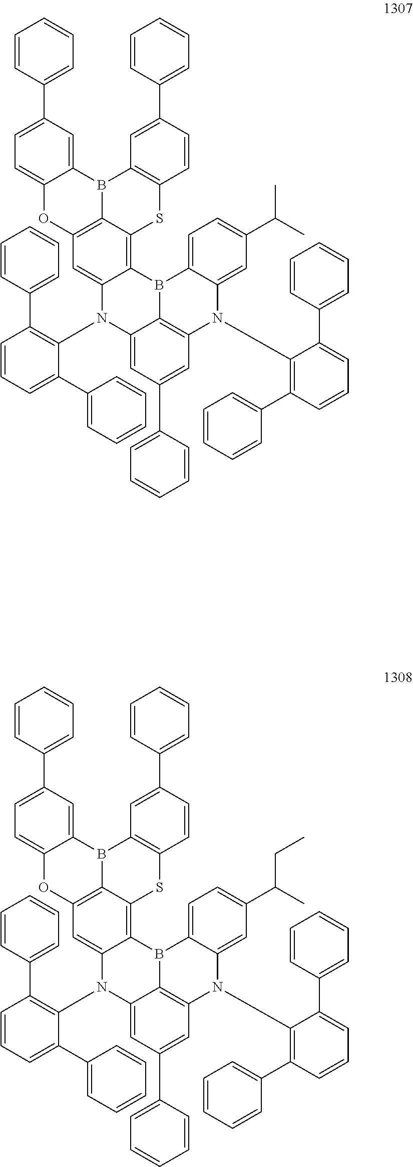 [SMILES: CC(C)c1ccc2c(c1)N(c1c(-c3ccccc3)cccc1-c1ccccc1)c1cc(Cc3ccccc3)cc3c1B2c1c(cc2c4c1Sc1ccc(-c5ccccc5)cc1B4c1cc(-c4ccccc4)ccc1O2)N3c1c(-c2ccccc2)cccc1-c1ccccc1 ; CCC(C)c1ccc2c(c1)N(c1c(-c3ccccc3)cccc1-c1ccccc1)c1cc(Cc3ccccc3)cc3c1B2c1c(cc2c4c1Sc1ccc(-c5ccccc5)cc1B4c1cc(-c4ccccc4)ccc1O2)N3c1c(-c2ccccc2)cccc1-c1ccccc1]

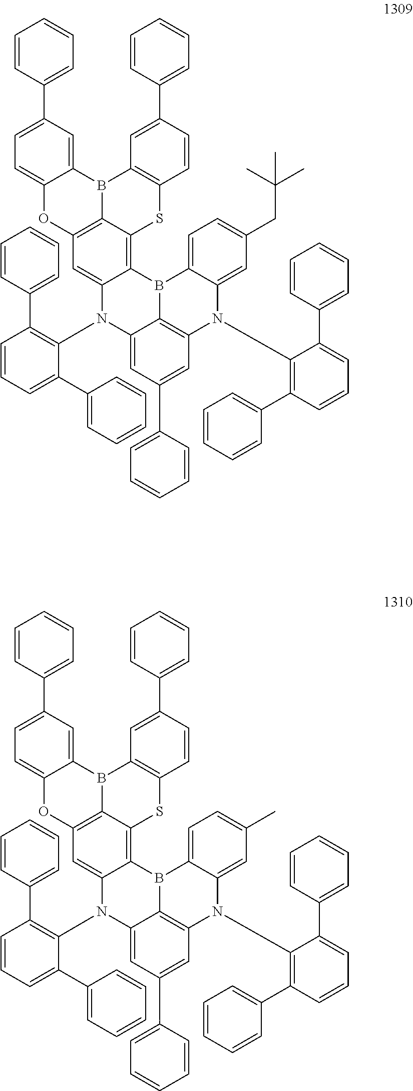 [SMILES: CC(C)(C)Cc1ccc2c(c1)N(c1c(-c3ccccc3)cccc1-c1ccccc1)c1cc(Cc3ccccc3)cc3c1B2c1c(cc2c4c1Sc1ccc(-c5ccccc5)cc1B4c1cc(-c4ccccc4)ccc1O2)N3c1c(-c2ccccc2)cccc1-c1ccccc1 ; Cc1ccc2c(c1)N(c1c(-c3ccccc3)cccc1-c1ccccc1)c1cc(Cc3ccccc3)cc3c1B2c1c(cc2c4c1Sc1ccc(-c5ccccc5)cc1B4c1cc(-c4ccccc4)ccc1O2)N3c1c(-c2ccccc2)cccc1-c1ccccc1]

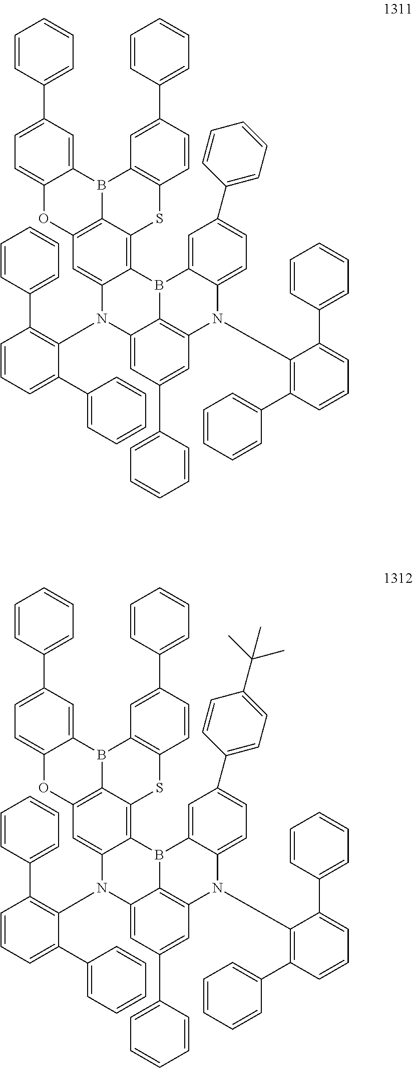 [SMILES: c1ccc(Cc2cc3c4c(c2)N(c2c(-c5ccccc5)cccc2-c2ccccc2)c2cc5c6c(c2B4c2cc(-c4ccccc4)ccc2N3c2c(-c3ccccc3)cccc2-c2ccccc2)Sc2ccc(-c3ccccc3)cc2B6c2cc(-c3ccccc3)ccc2O5)cc1 ; CC(C)(C)c1ccc(-c2ccc3c(c2)B2c4c(cc(Cc5ccccc5)cc4N(c4c(-c5ccccc5)cccc4-c4ccccc4)c4cc5c6c(c42)Sc2ccc(-c4ccccc4)cc2B6c2cc(-c4ccccc4)ccc2O5)N3c2c(-c3ccccc3)cccc2-c2ccccc2)cc1]

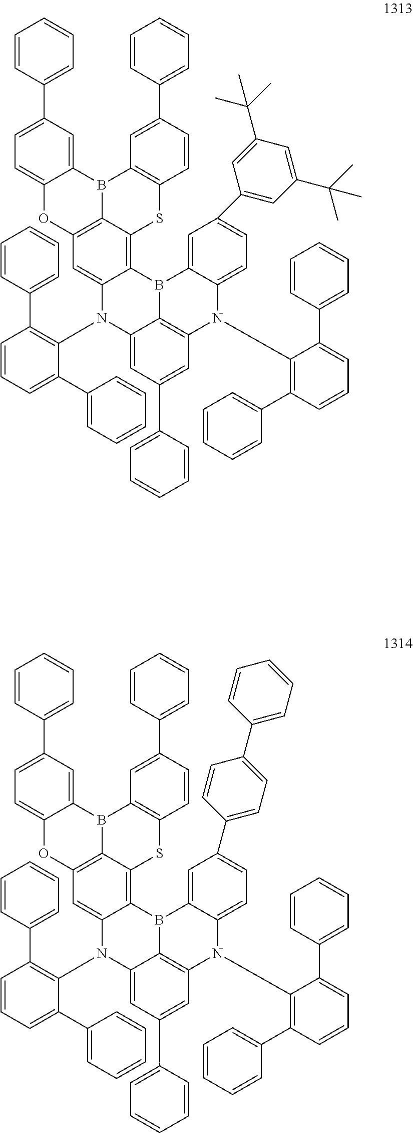 [SMILES: CC(C)(C)c1cc(-c2ccc3c(c2)B2c4c(cc(Cc5ccccc5)cc4N(c4c(-c5ccccc5)cccc4-c4ccccc4)c4cc5c6c(c42)Sc2ccc(-c4ccccc4)cc2B6c2cc(-c4ccccc4)ccc2O5)N3c2c(-c3ccccc3)cccc2-c2ccccc2)cc(C(C)(C)C)c1 ; c1ccc(Cc2cc3c4c(c2)N(c2c(-c5ccccc5)cccc2-c2ccccc2)c2cc5c6c(c2B4c2cc(-c4ccc(-c7ccccc7)cc4)ccc2N3c2c(-c3ccccc3)cccc2-c2ccccc2)Sc2ccc(-c3ccccc3)cc2B6c2cc(-c3ccccc3)ccc2O5)cc1]

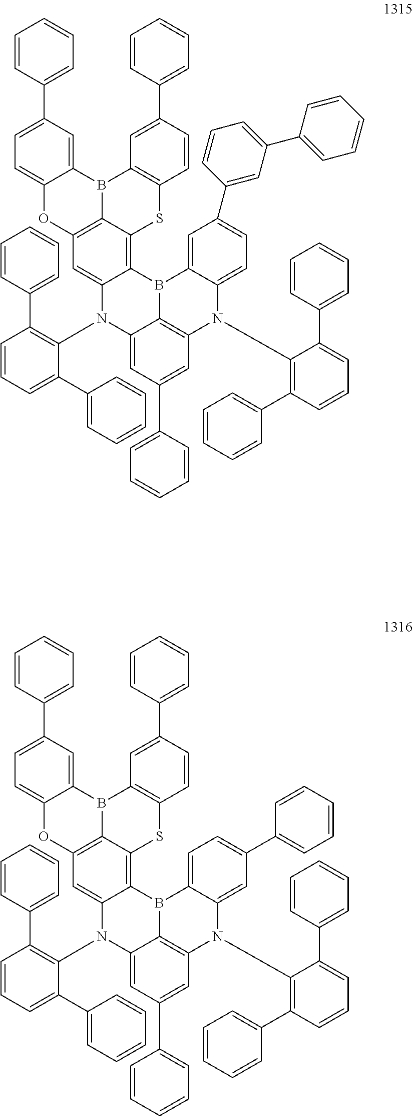 [SMILES: c1ccc(Cc2cc3c4c(c2)N(c2c(-c5ccccc5)cccc2-c2ccccc2)c2cc5c6c(c2B4c2cc(-c4cccc(-c7ccccc7)c4)ccc2N3c2c(-c3ccccc3)cccc2-c2ccccc2)Sc2ccc(-c3ccccc3)cc2B6c2cc(-c3ccccc3)ccc2O5)cc1 ; c1ccc(Cc2cc3c4c(c2)N(c2c(-c5ccccc5)cccc2-c2ccccc2)c2cc5c6c(c2B4c2ccc(-c4ccccc4)cc2N3c2c(-c3ccccc3)cccc2-c2ccccc2)Sc2ccc(-c3ccccc3)cc2B6c2cc(-c3ccccc3)ccc2O5)cc1]

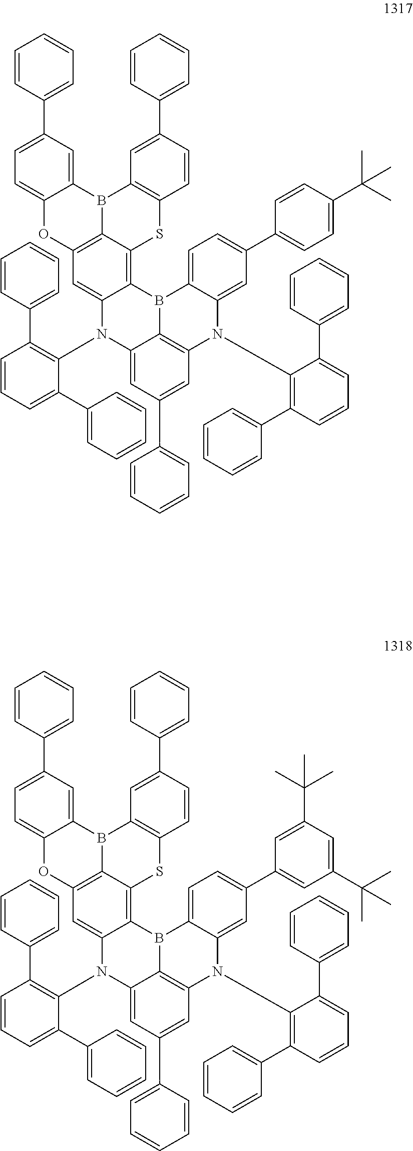 [SMILES: CC(C)(C)c1ccc(-c2ccc3c(c2)N(c2c(-c4ccccc4)cccc2-c2ccccc2)c2cc(Cc4ccccc4)cc4c2B3c2c(cc3c5c2Sc2ccc(-c6ccccc6)cc2B5c2cc(-c5ccccc5)ccc2O3)N4c2c(-c3ccccc3)cccc2-c2ccccc2)cc1 ; CC(C)(C)c1cc(-c2ccc3c(c2)N(c2c(-c4ccccc4)cccc2-c2ccccc2)c2cc(Cc4ccccc4)cc4c2B3c2c(cc3c5c2Sc2ccc(-c6ccccc6)cc2B5c2cc(-c5ccccc5)ccc2O3)N4c2c(-c3ccccc3)cccc2-c2ccccc2)cc(C(C)(C)C)c1]

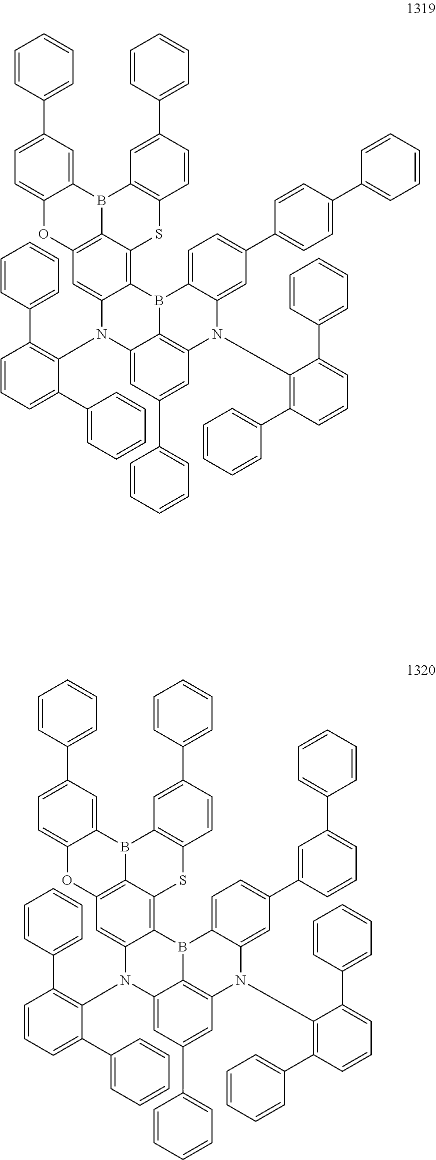 [SMILES: c1ccc(Cc2cc3c4c(c2)N(c2c(-c5ccccc5)cccc2-c2ccccc2)c2cc5c6c(c2B4c2ccc(-c4ccc(-c7ccccc7)cc4)cc2N3c2c(-c3ccccc3)cccc2-c2ccccc2)Sc2ccc(-c3ccccc3)cc2B6c2cc(-c3ccccc3)ccc2O5)cc1 ; c1ccc(Cc2cc3c4c(c2)N(c2c(-c5ccccc5)cccc2-c2ccccc2)c2cc5c6c(c2B4c2ccc(-c4cccc(-c7ccccc7)c4)cc2N3c2c(-c3ccccc3)cccc2-c2ccccc2)Sc2ccc(-c3ccccc3)cc2B6c2cc(-c3ccccc3)ccc2O5)cc1]

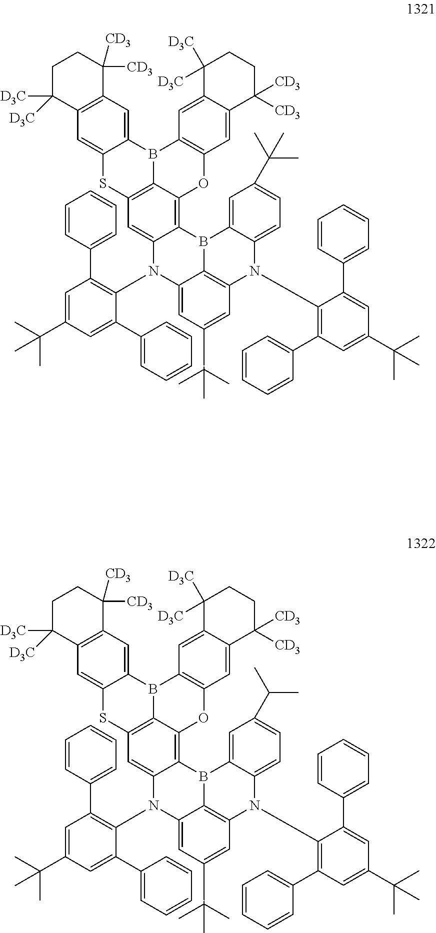

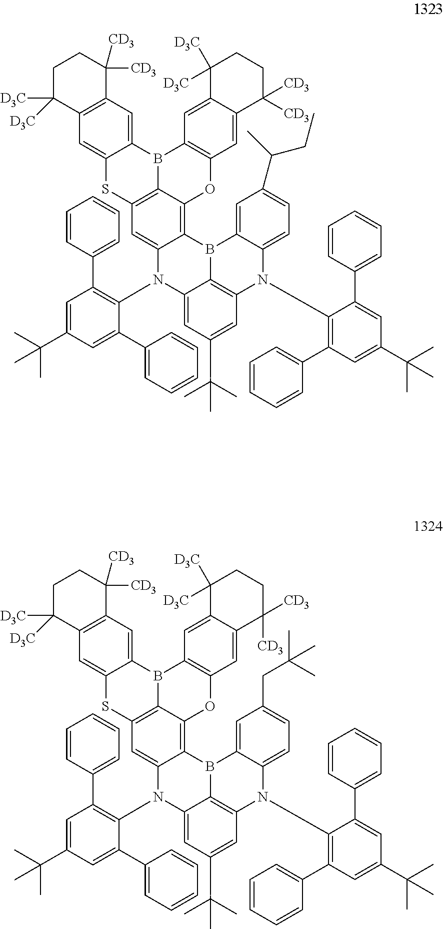

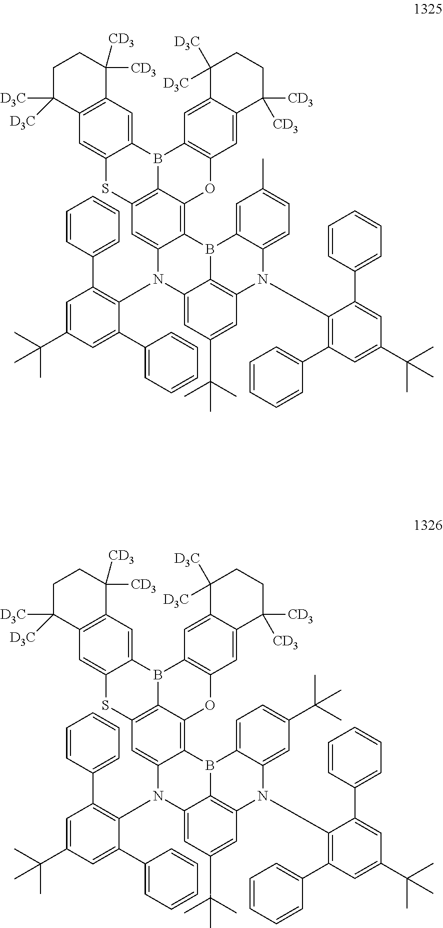

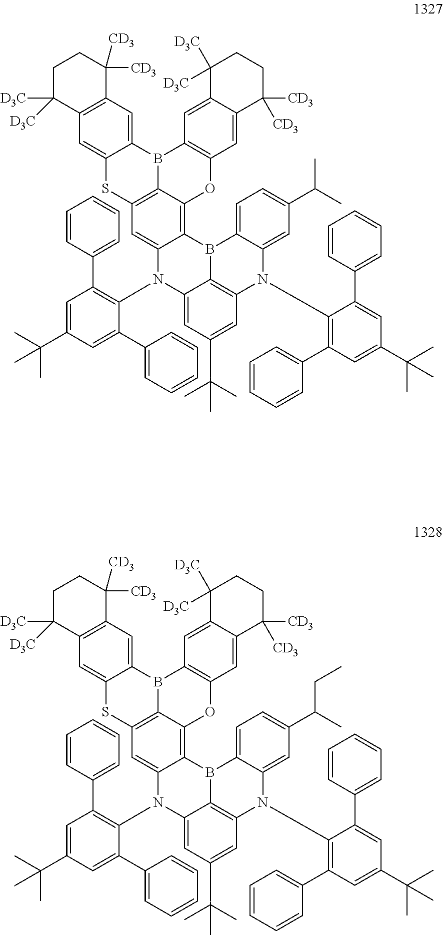

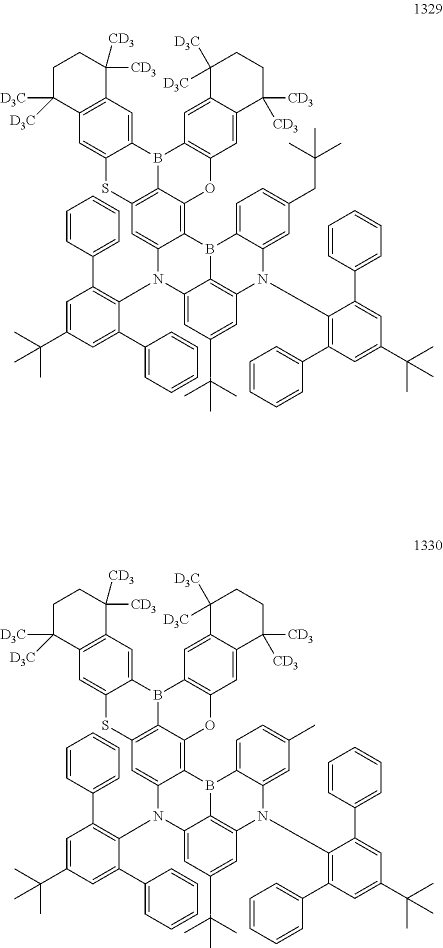

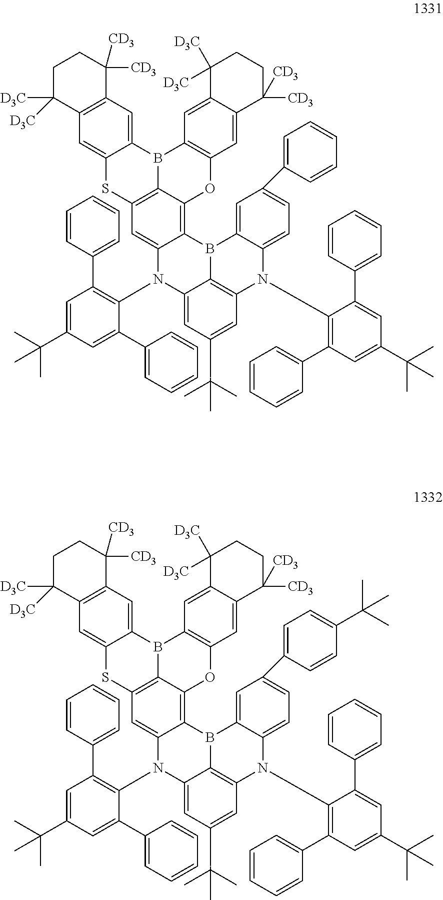

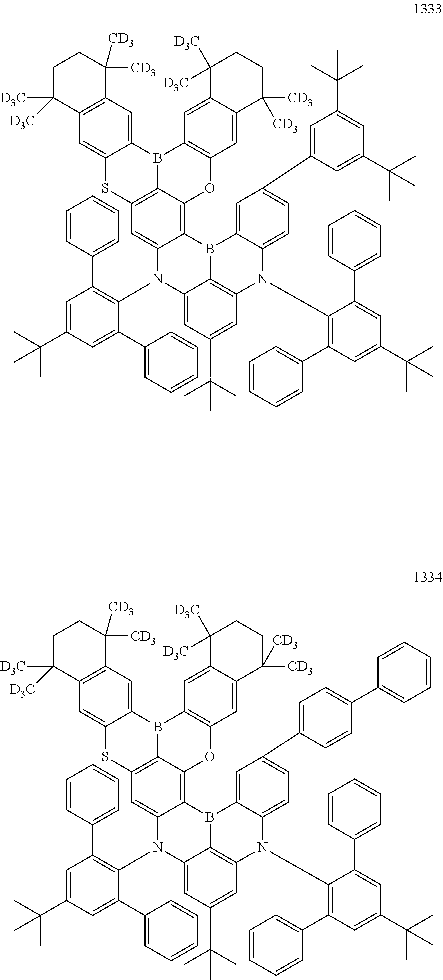

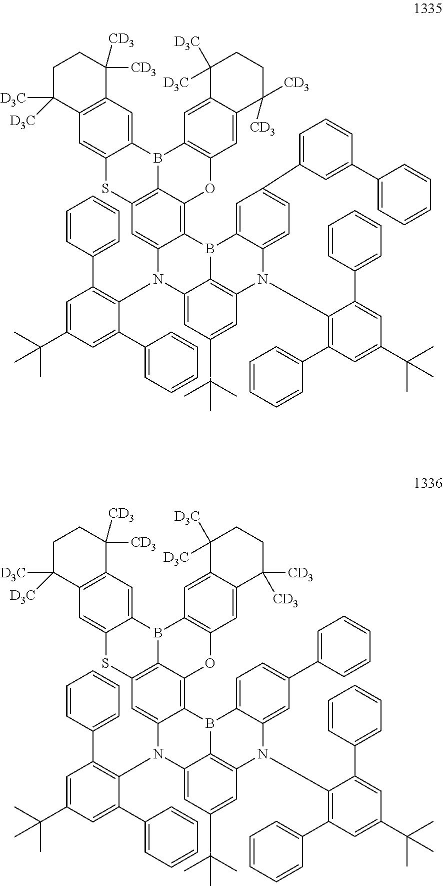

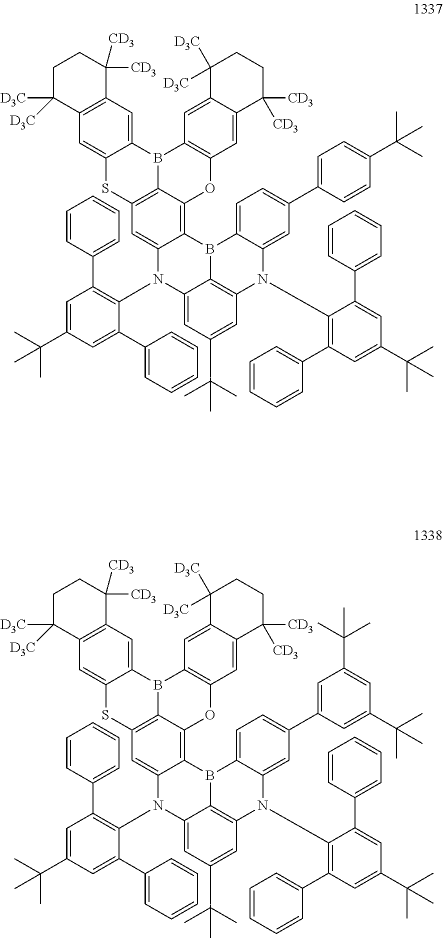

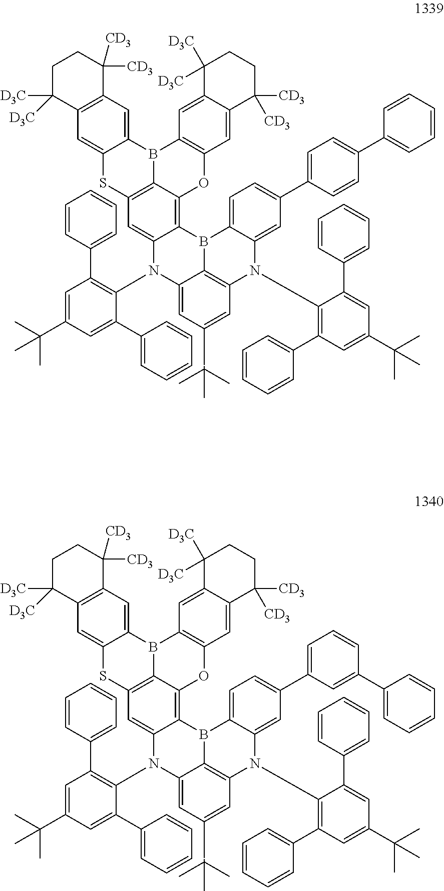

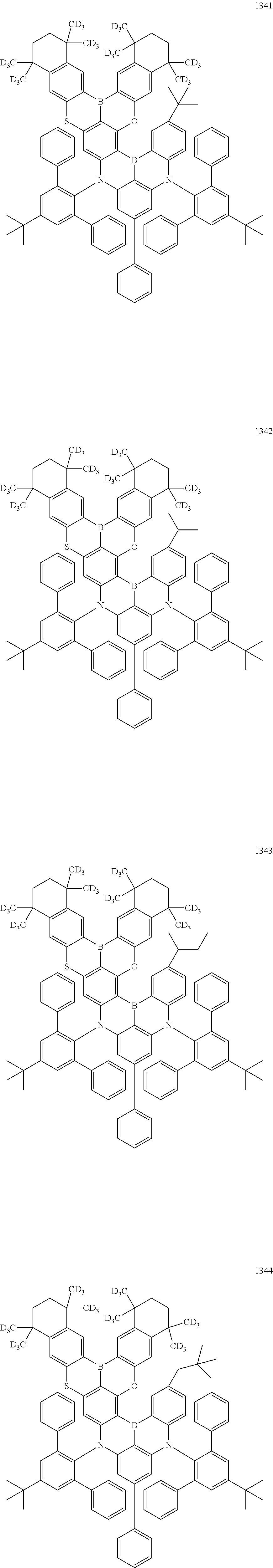

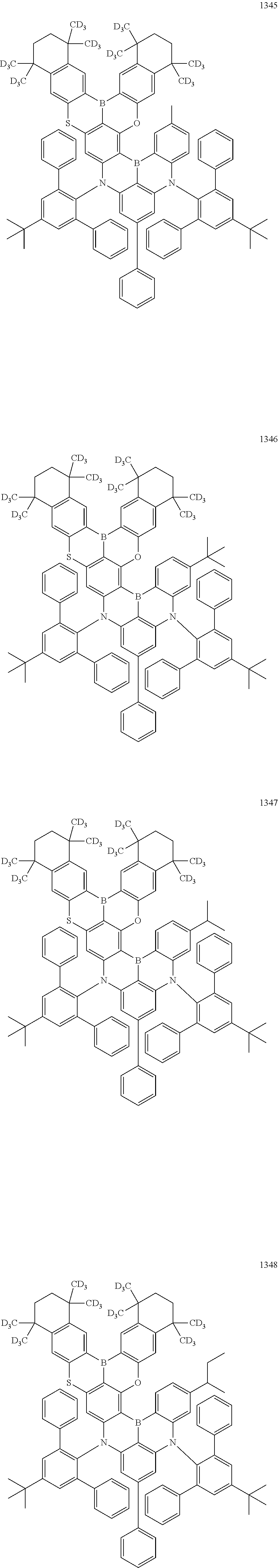

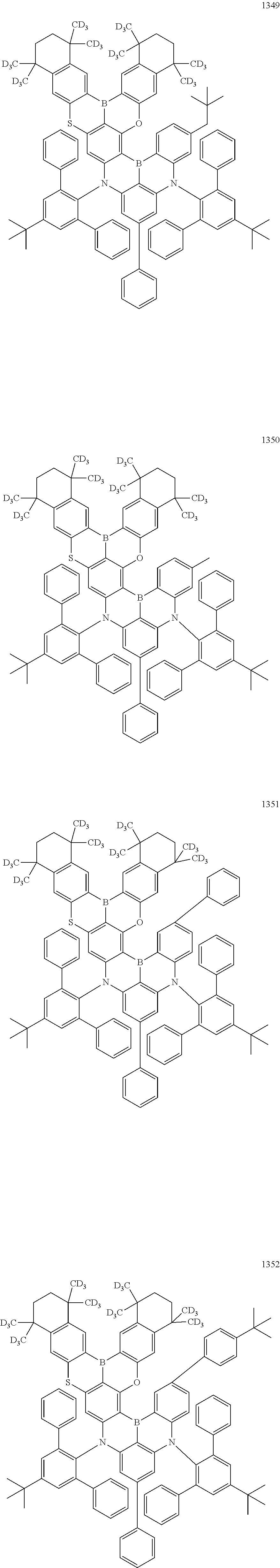

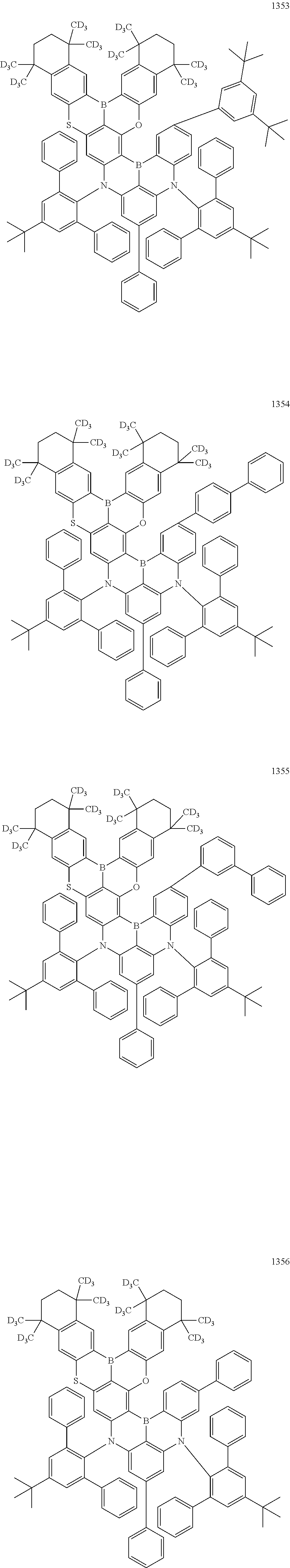

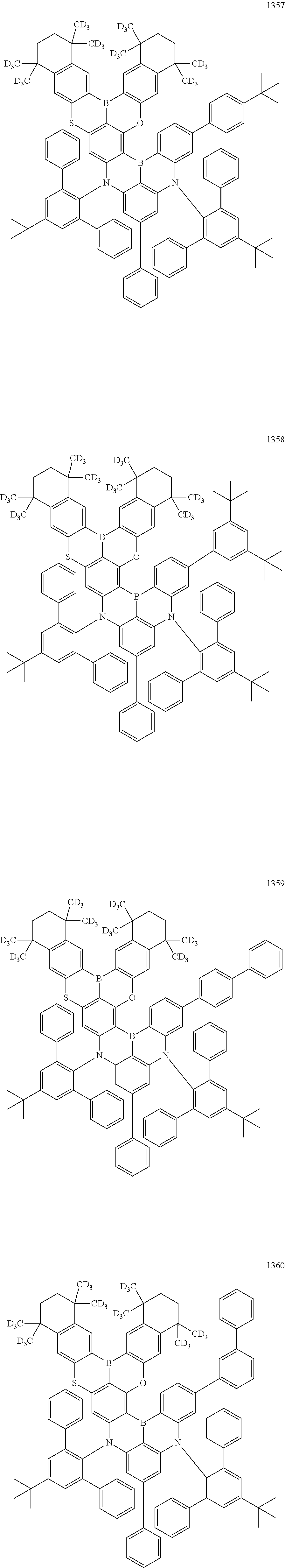

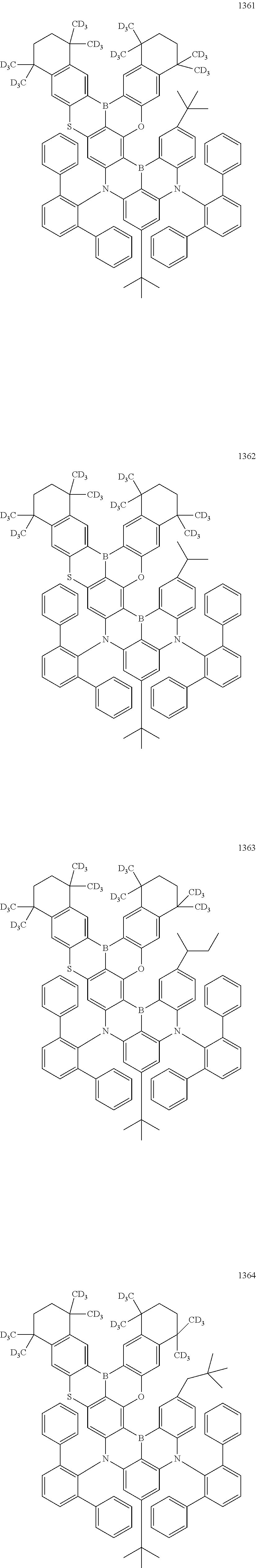

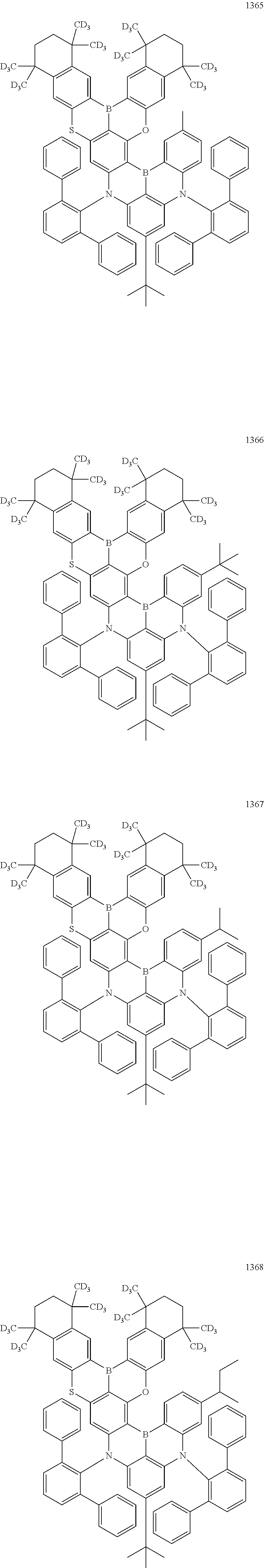

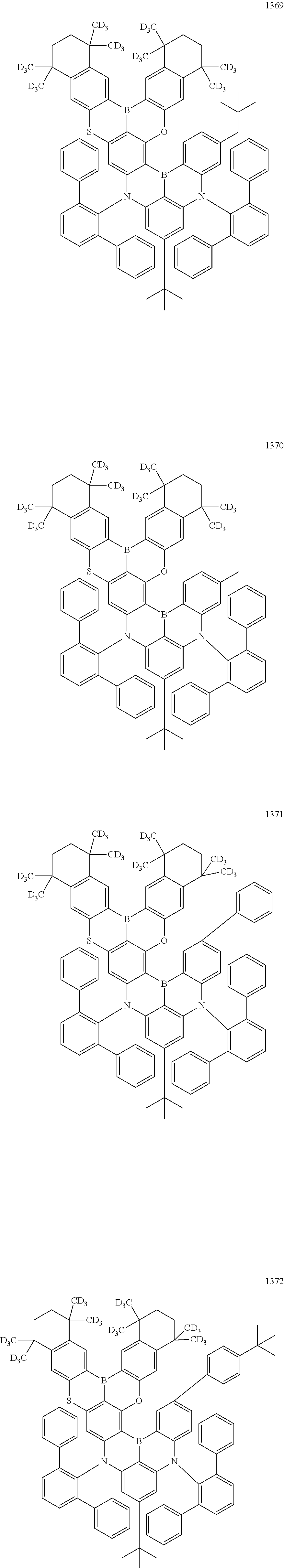

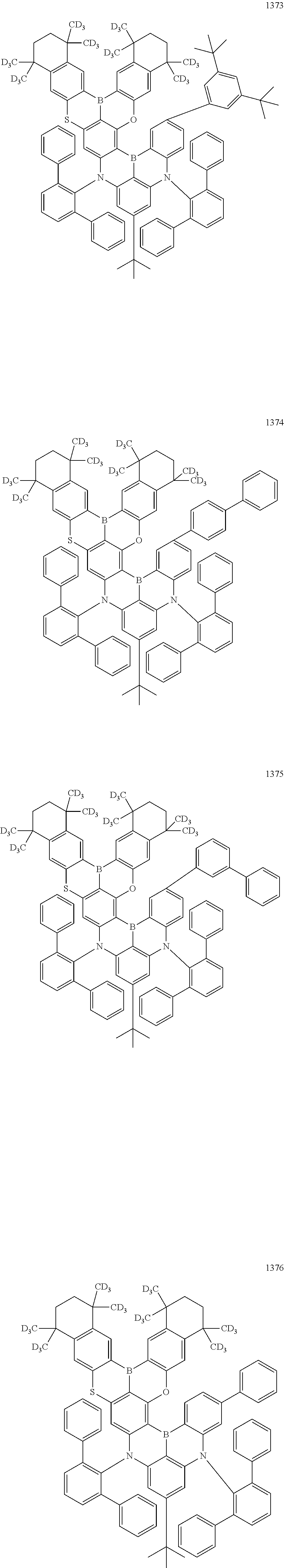

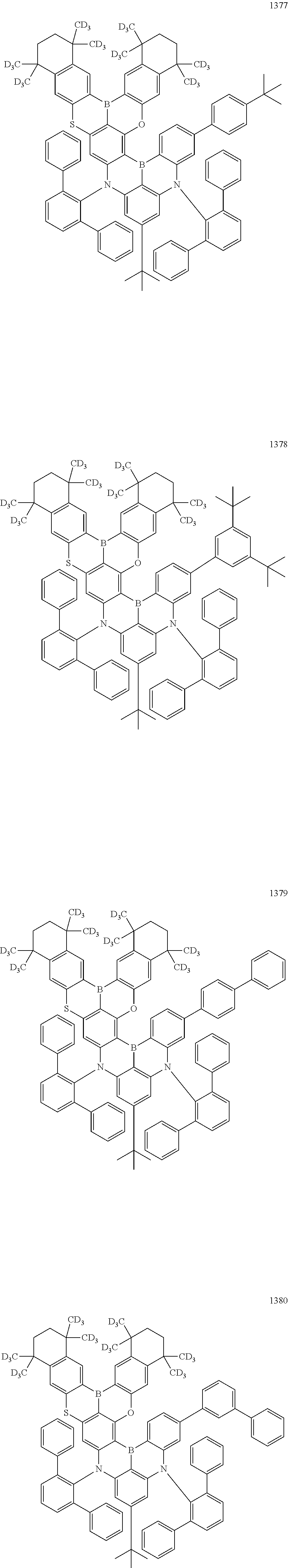

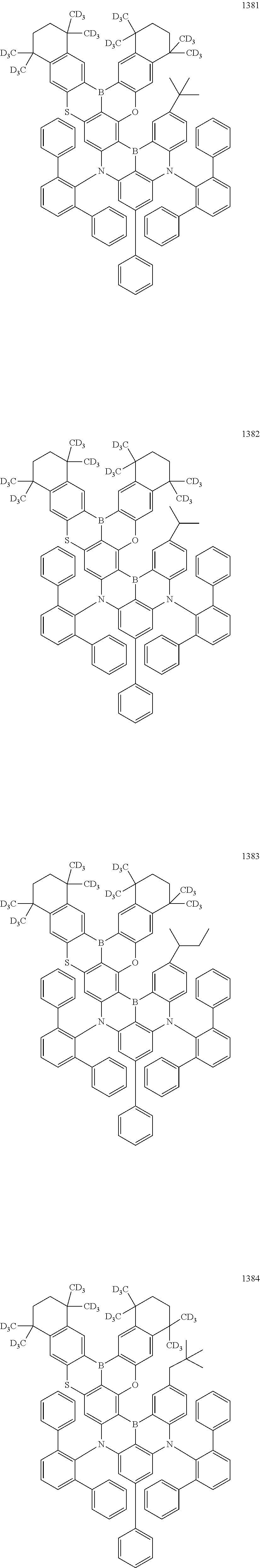

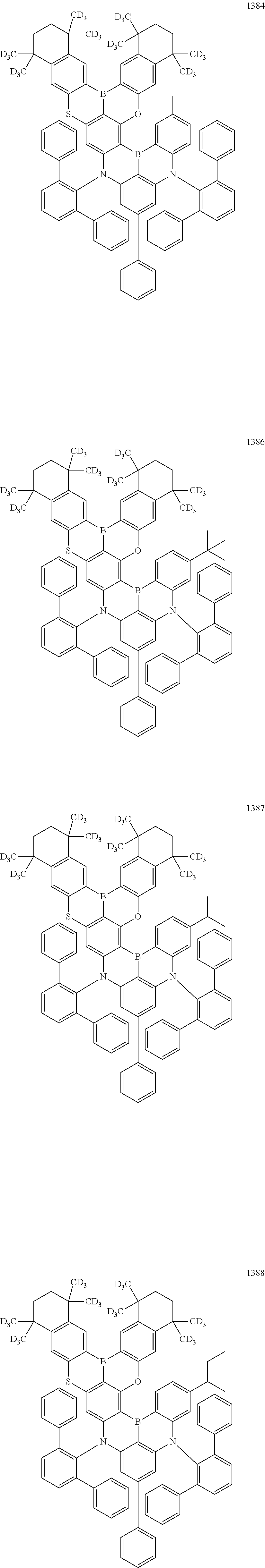

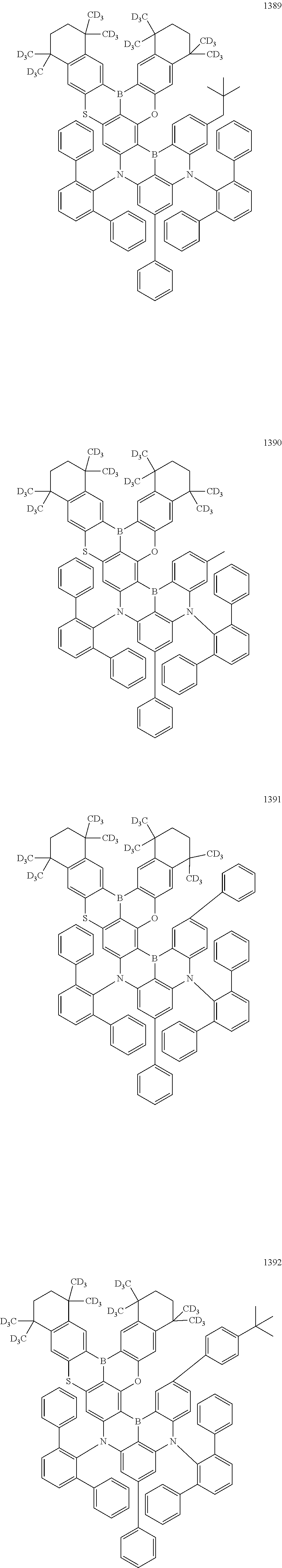

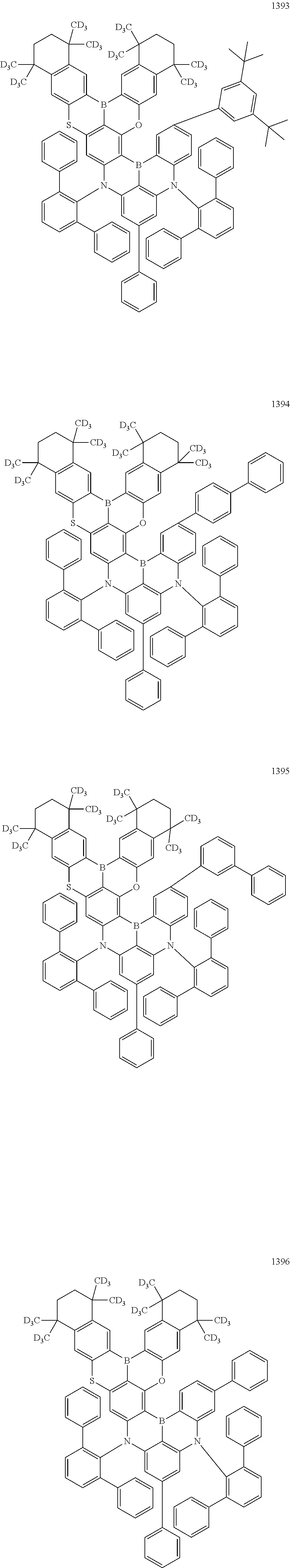

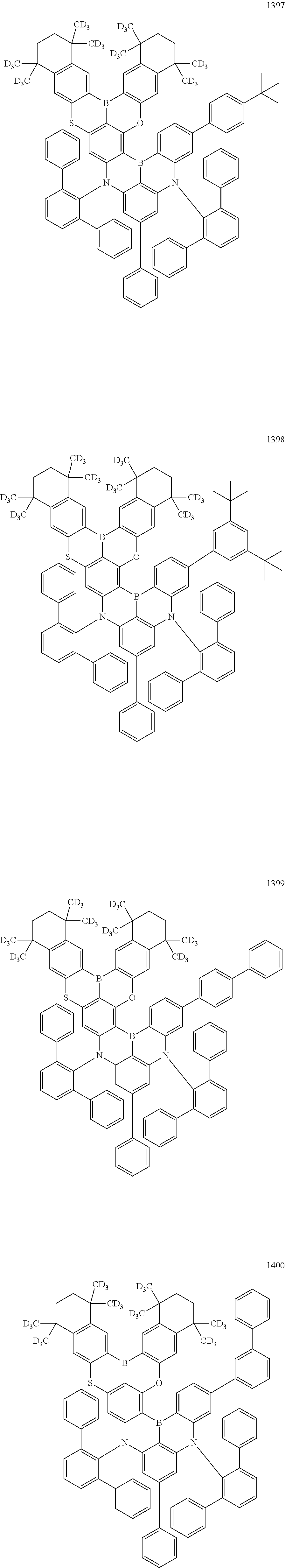

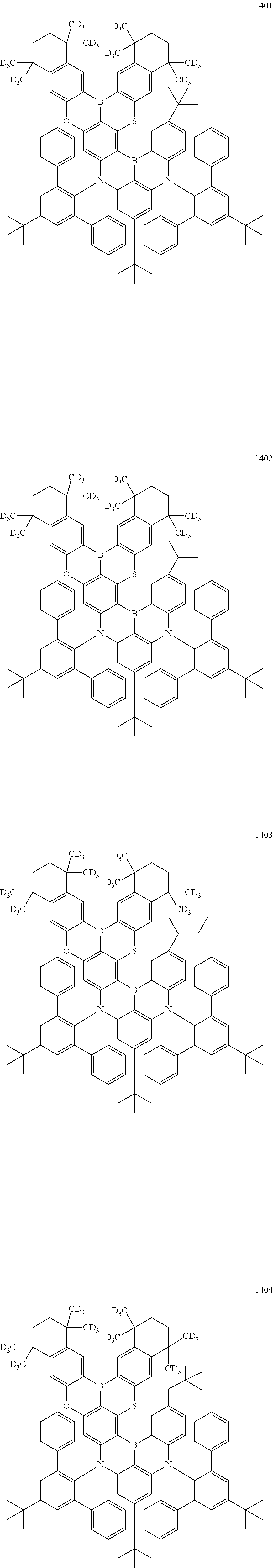

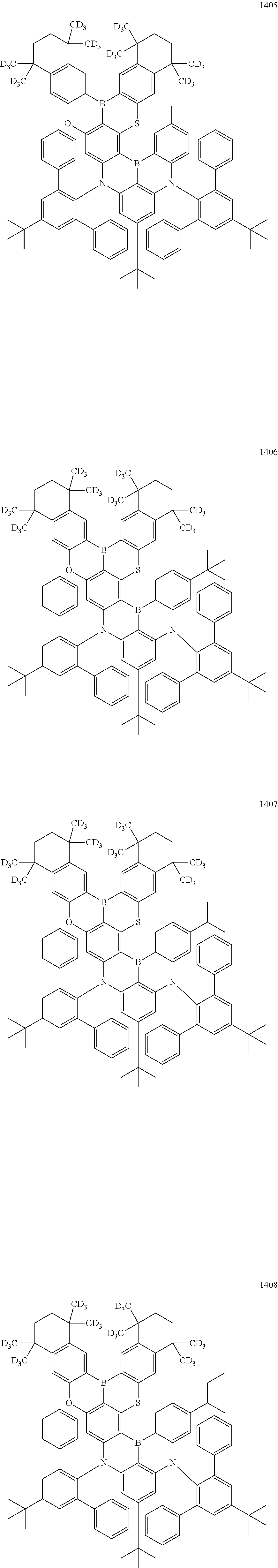

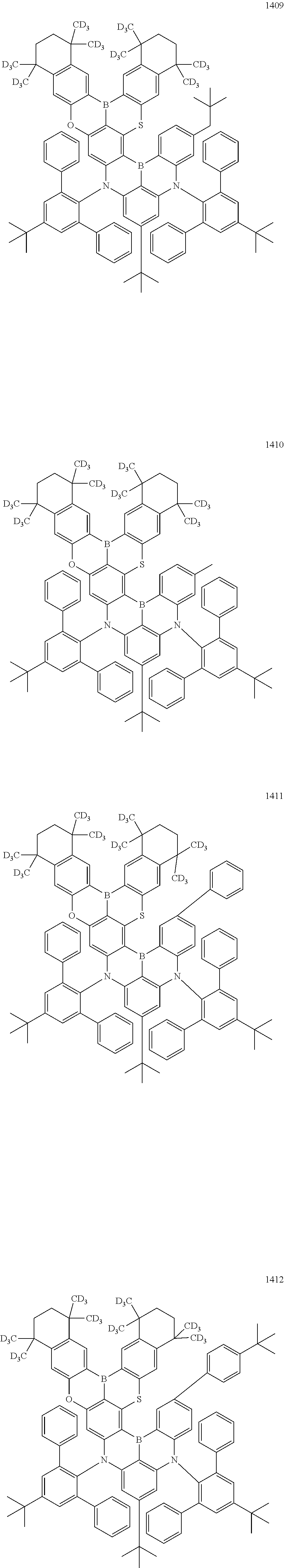

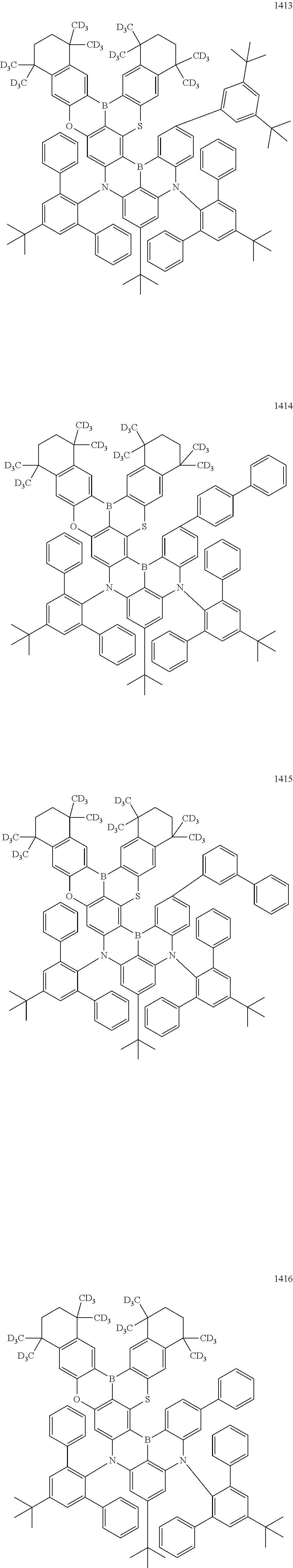

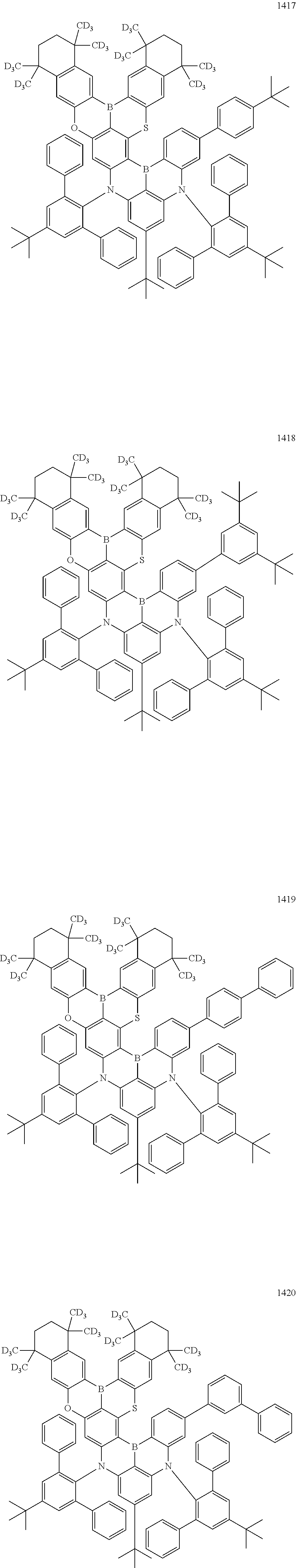

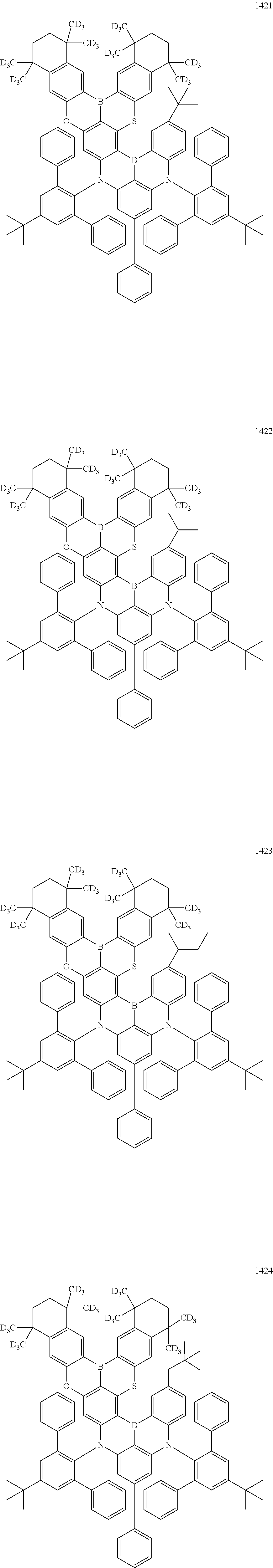

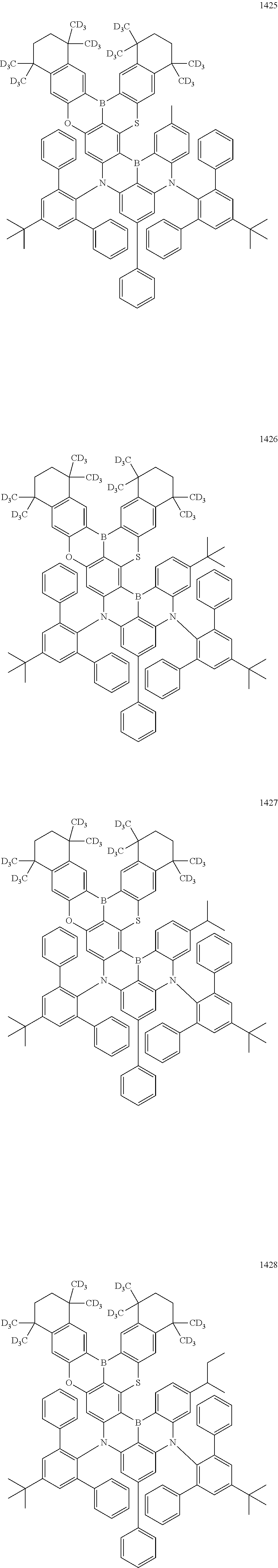

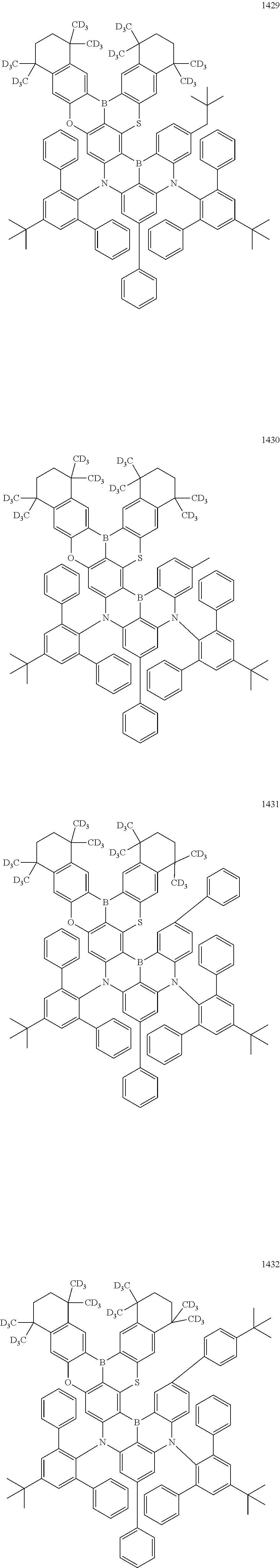

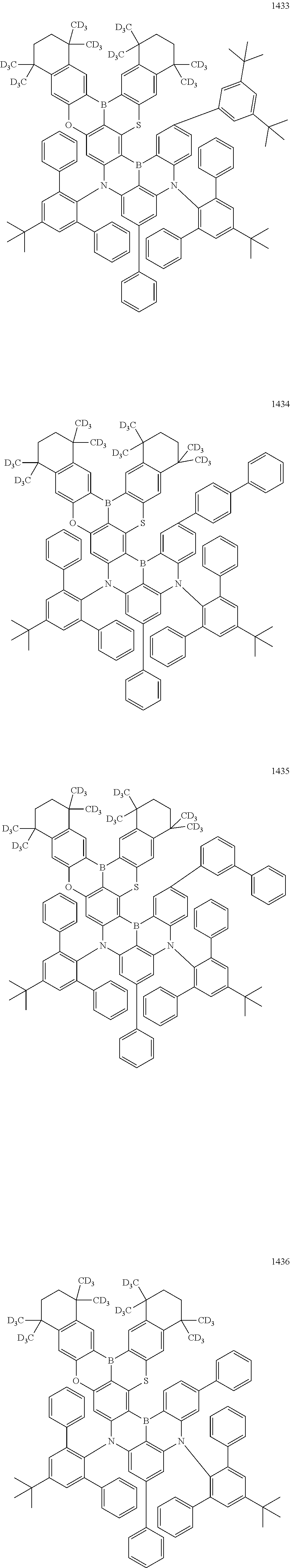

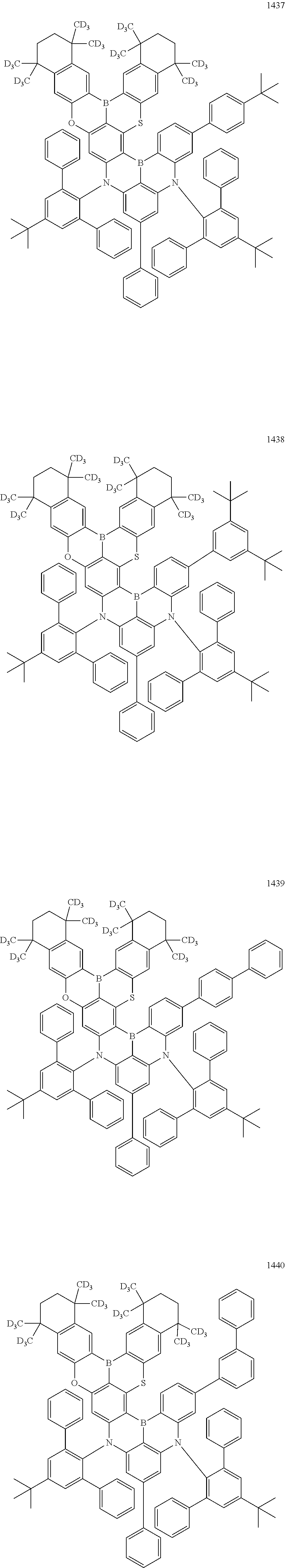

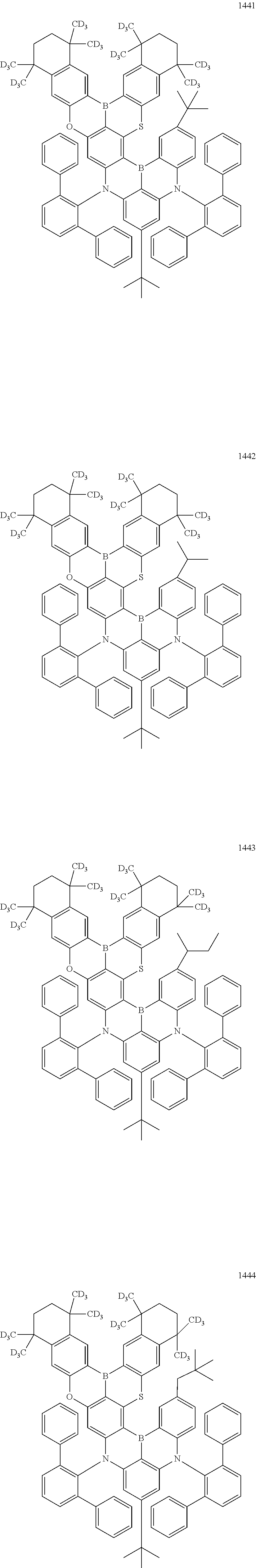

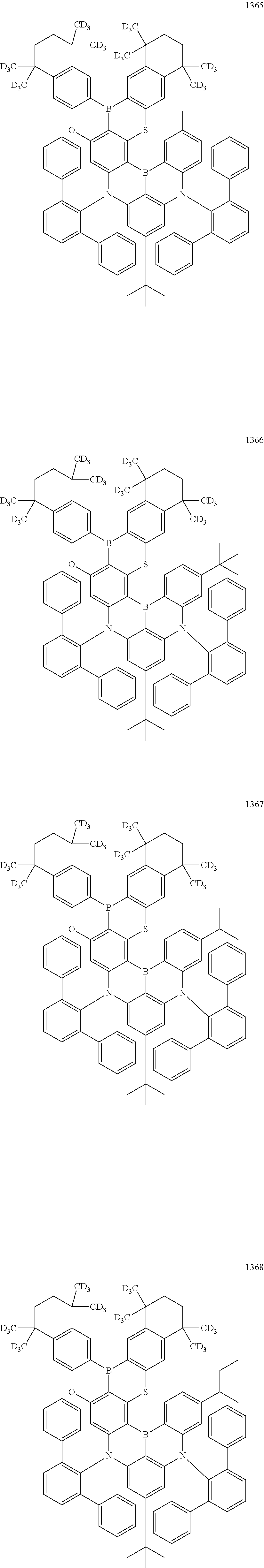

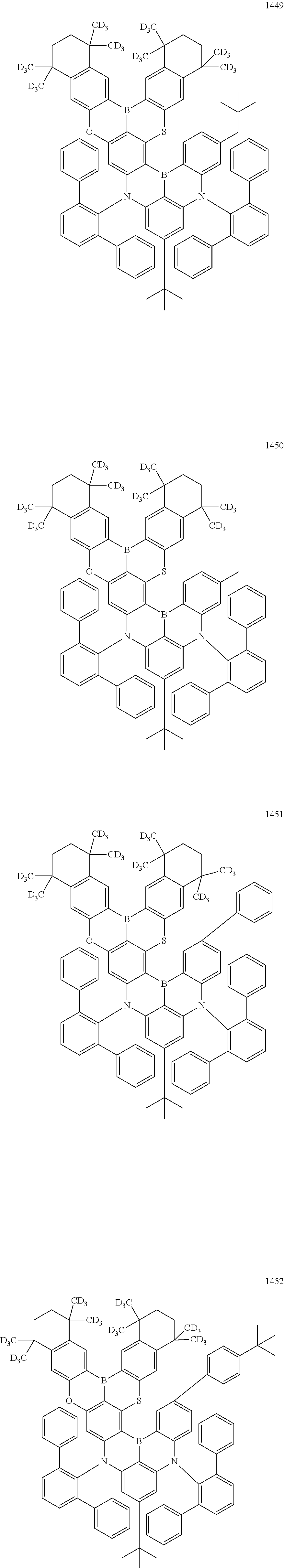

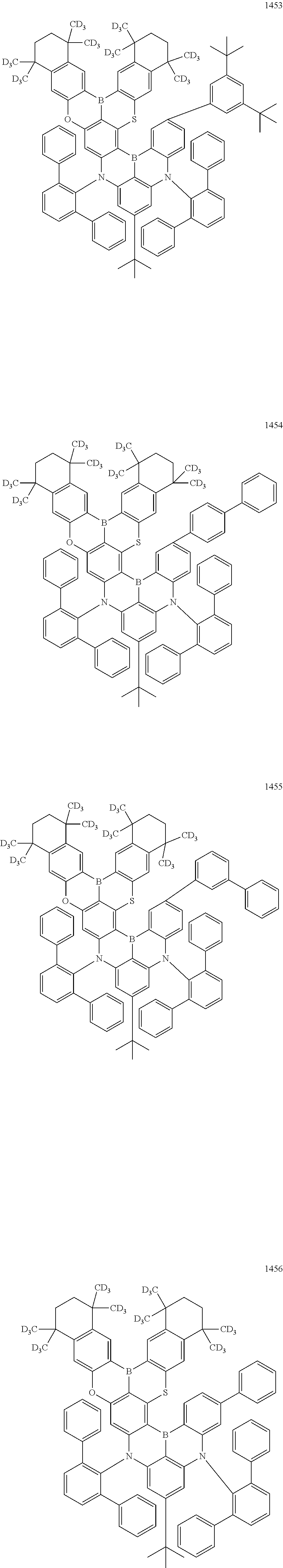

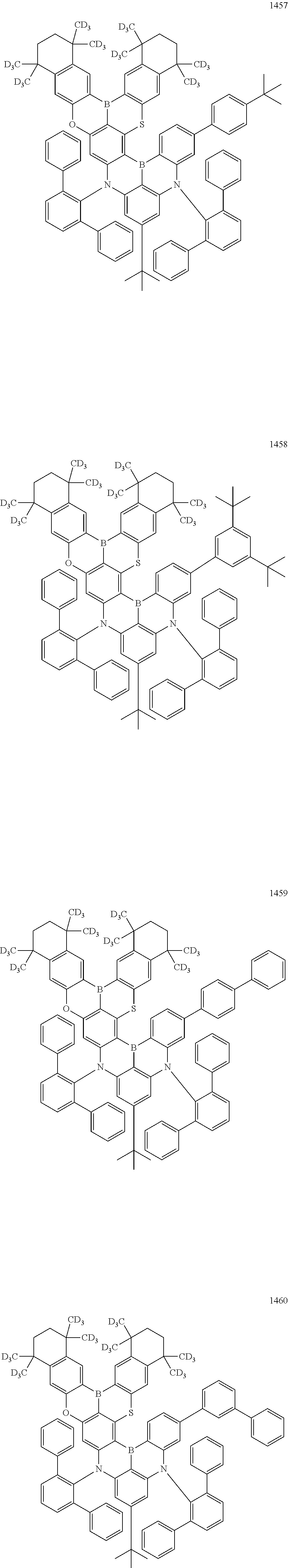

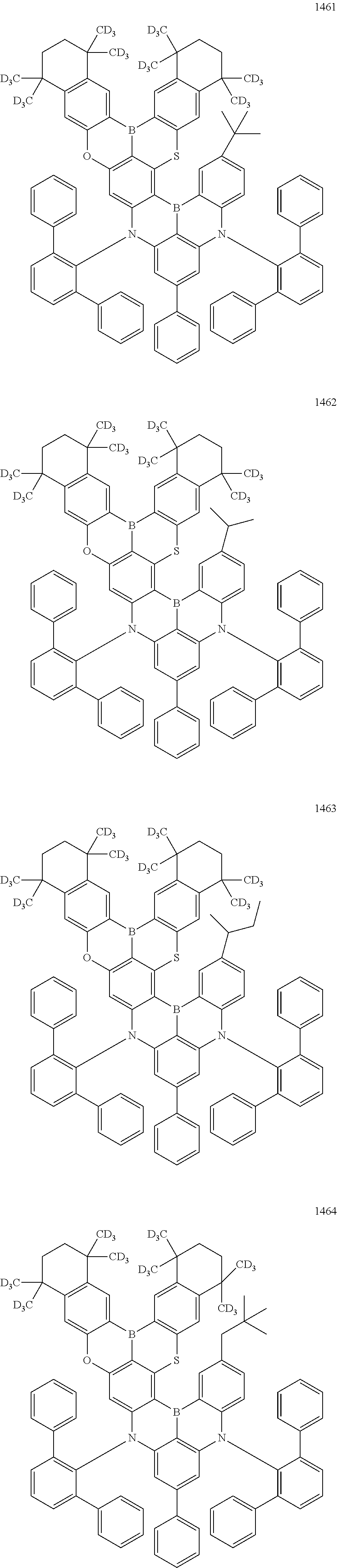

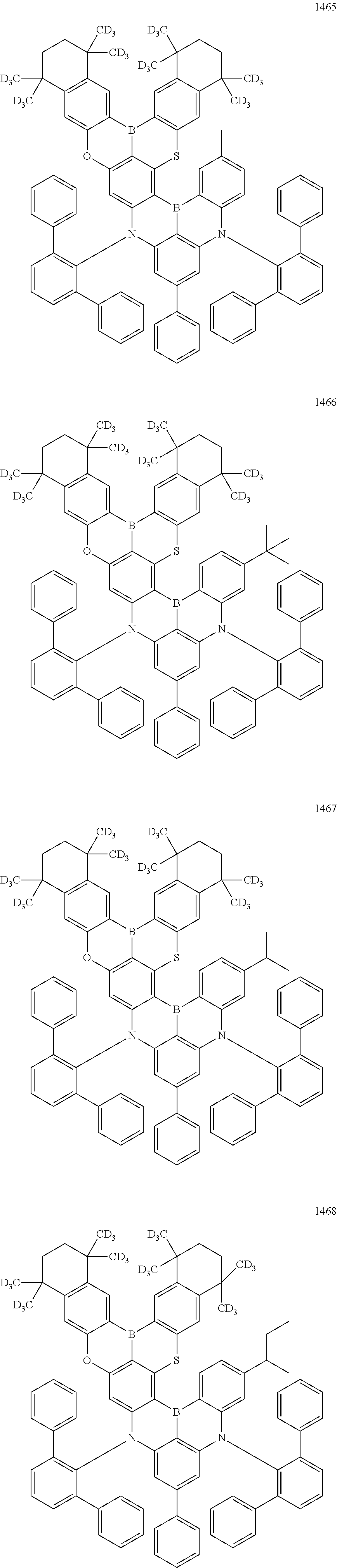

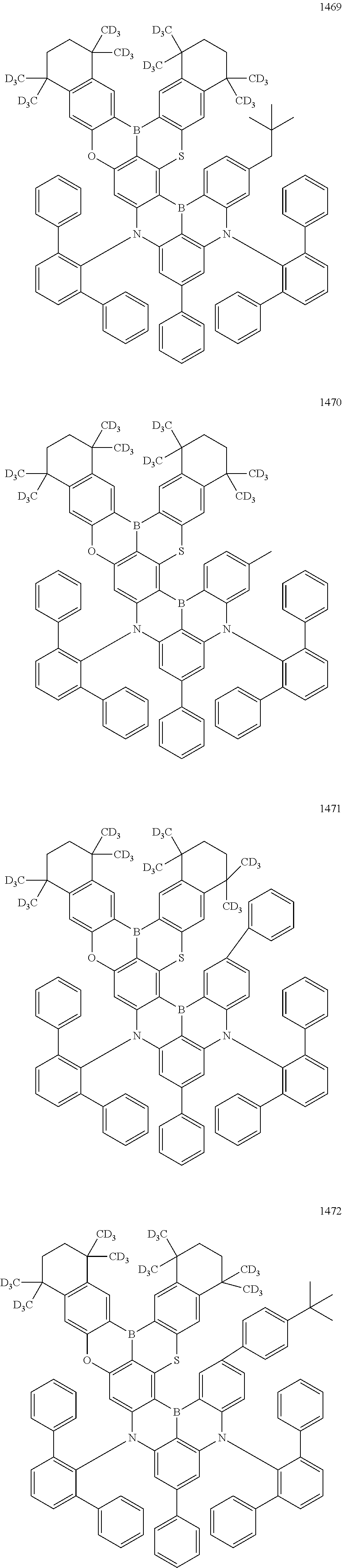

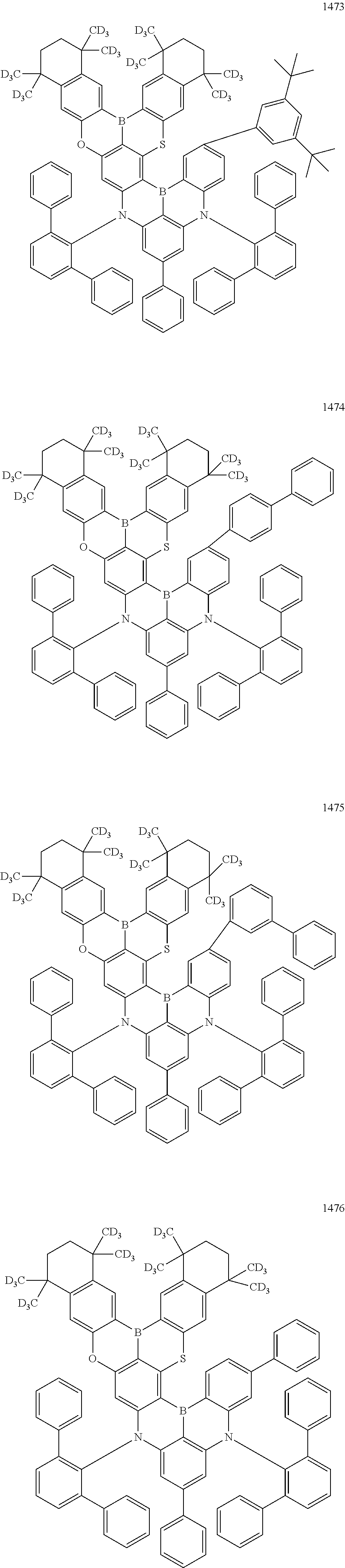

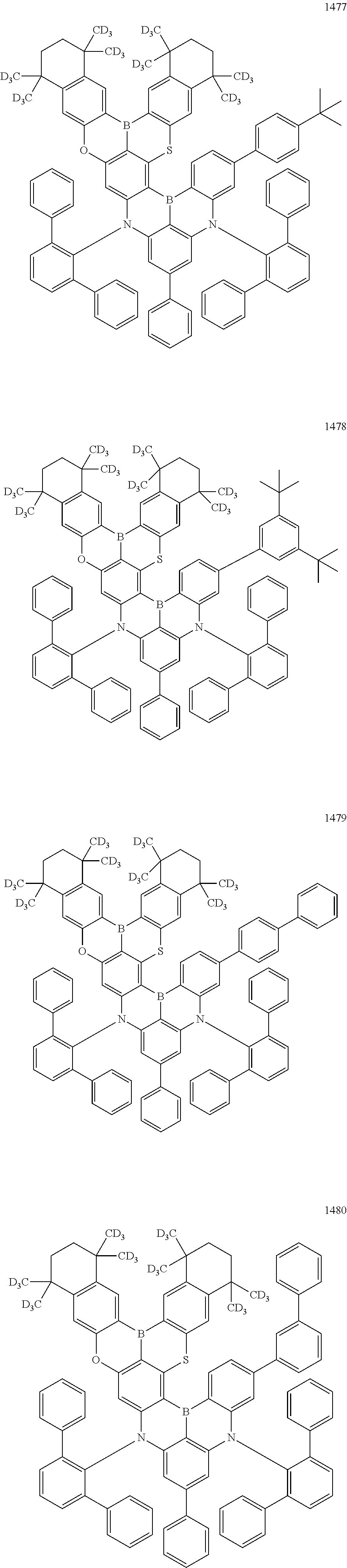

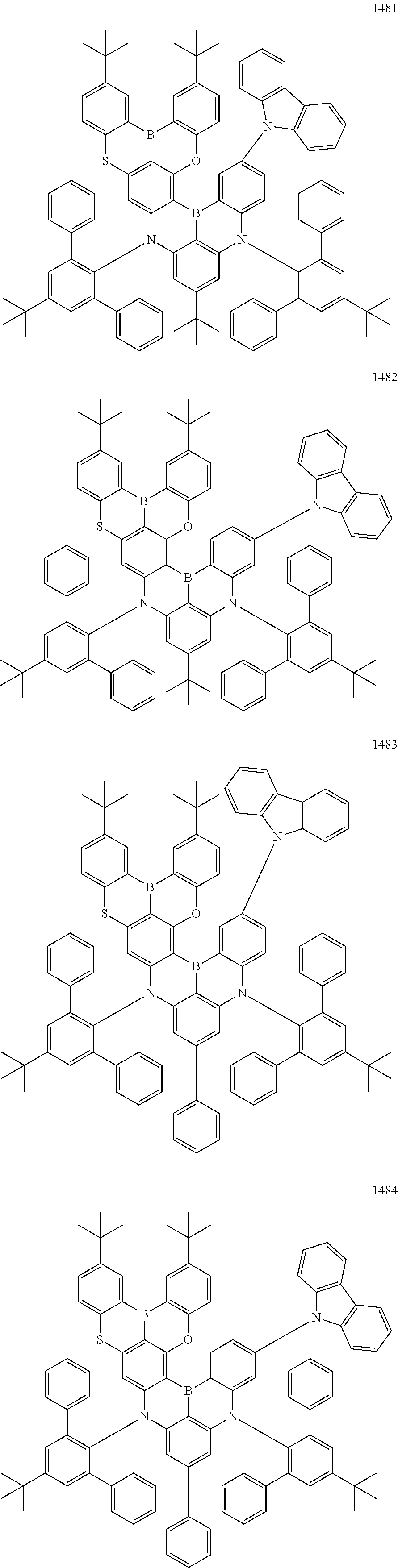

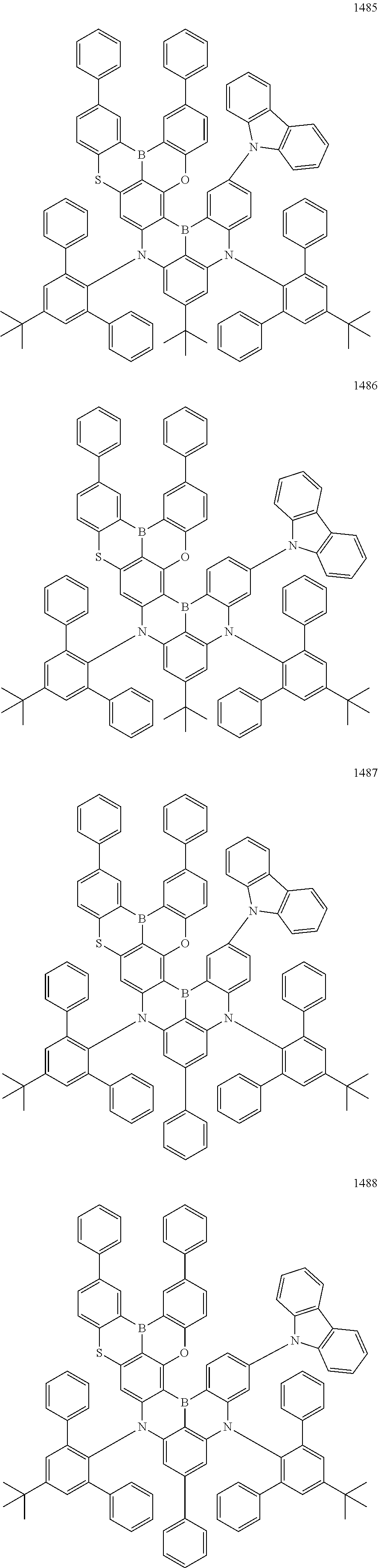

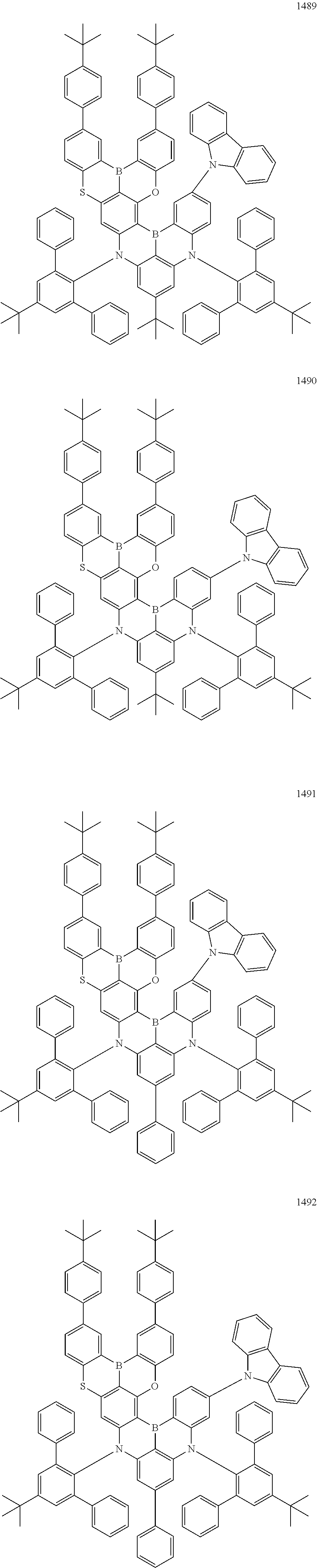

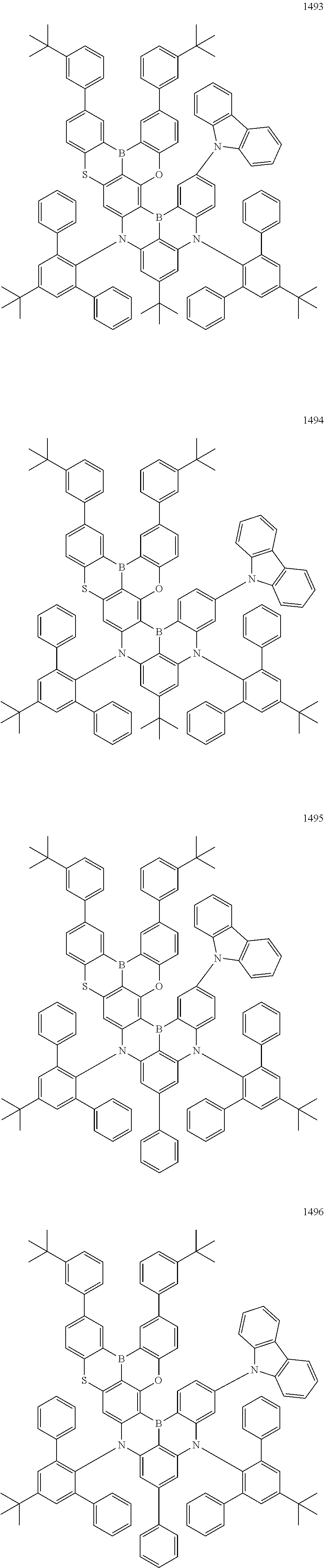

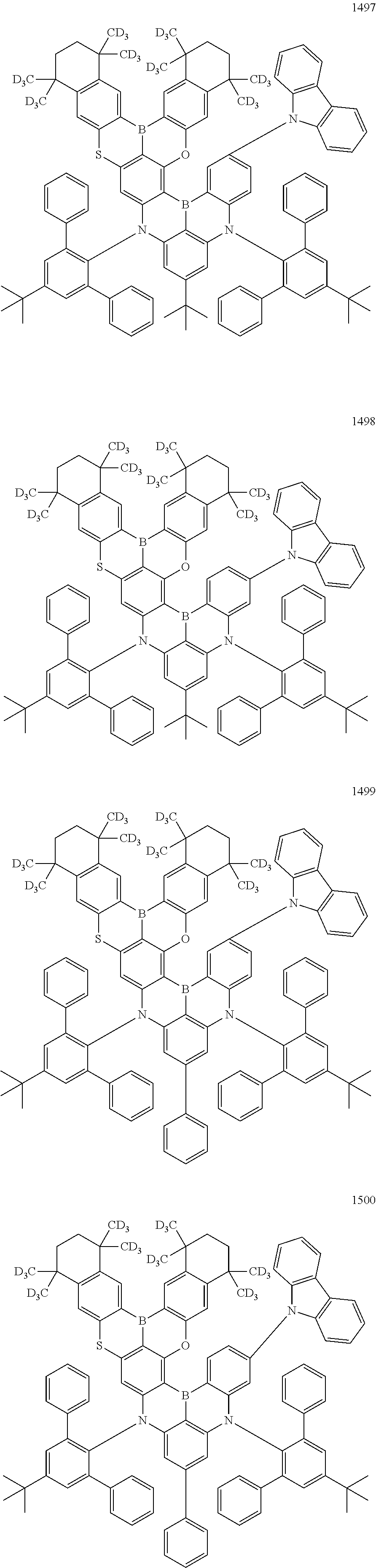

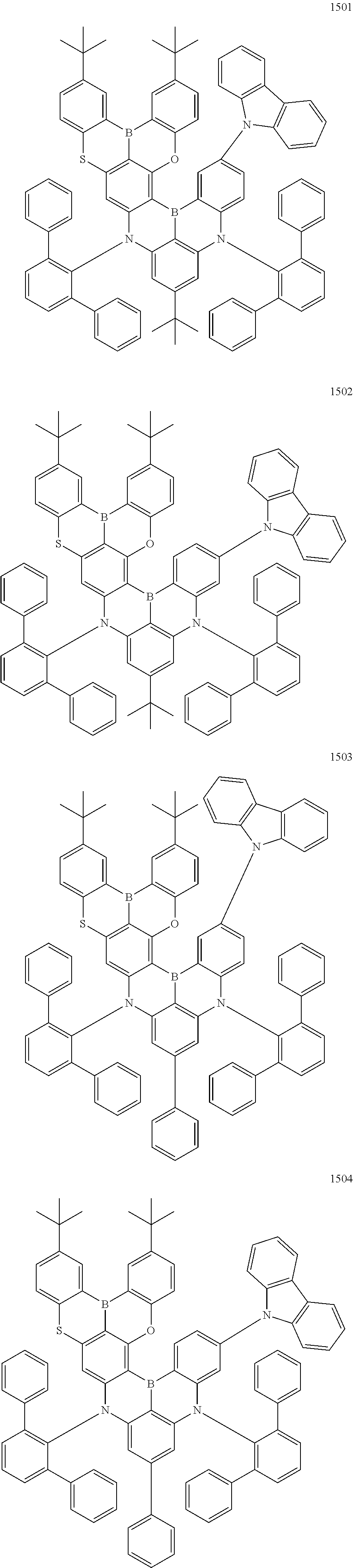

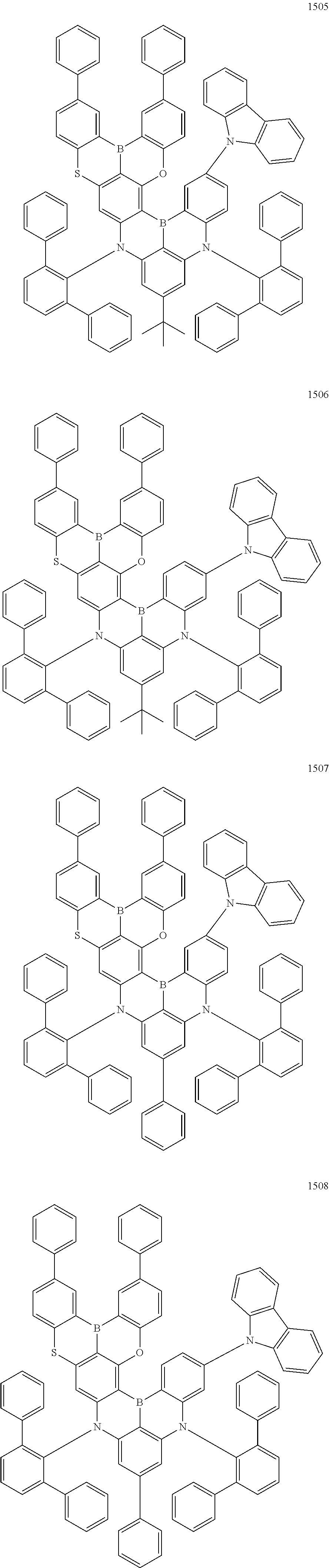

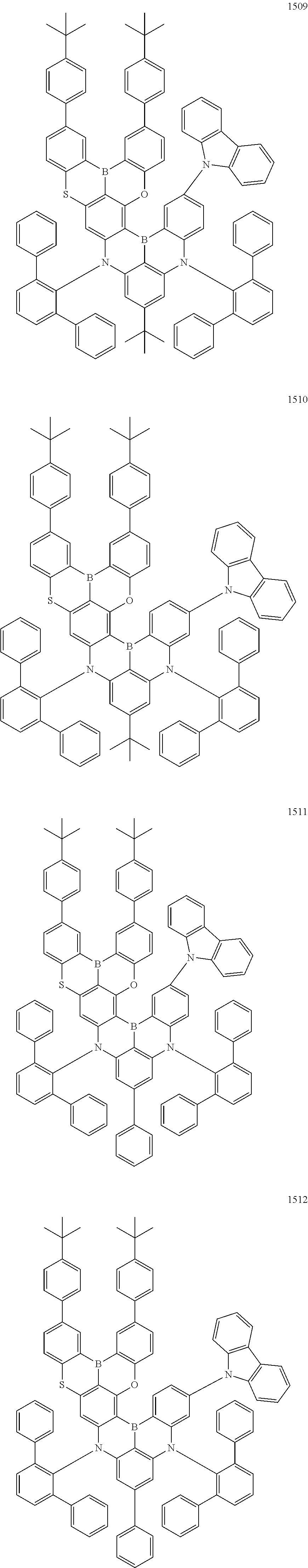

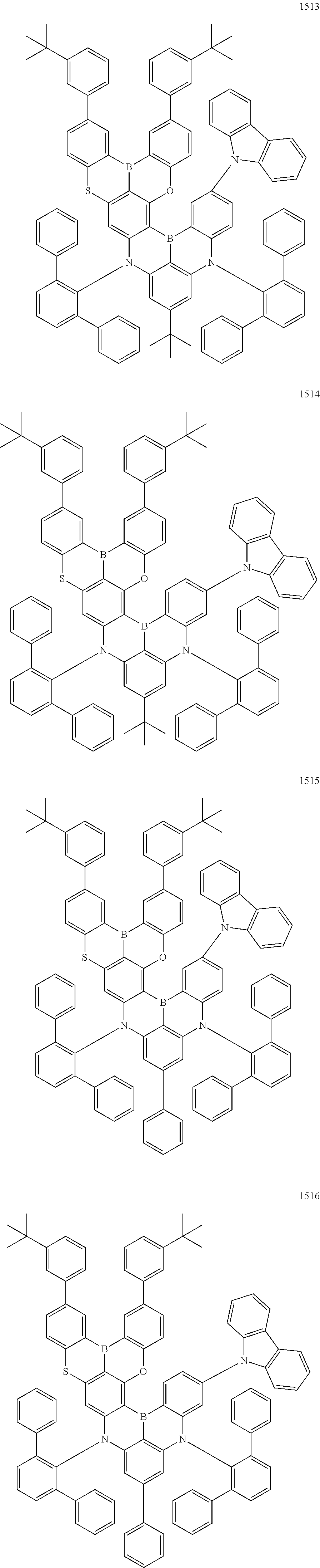

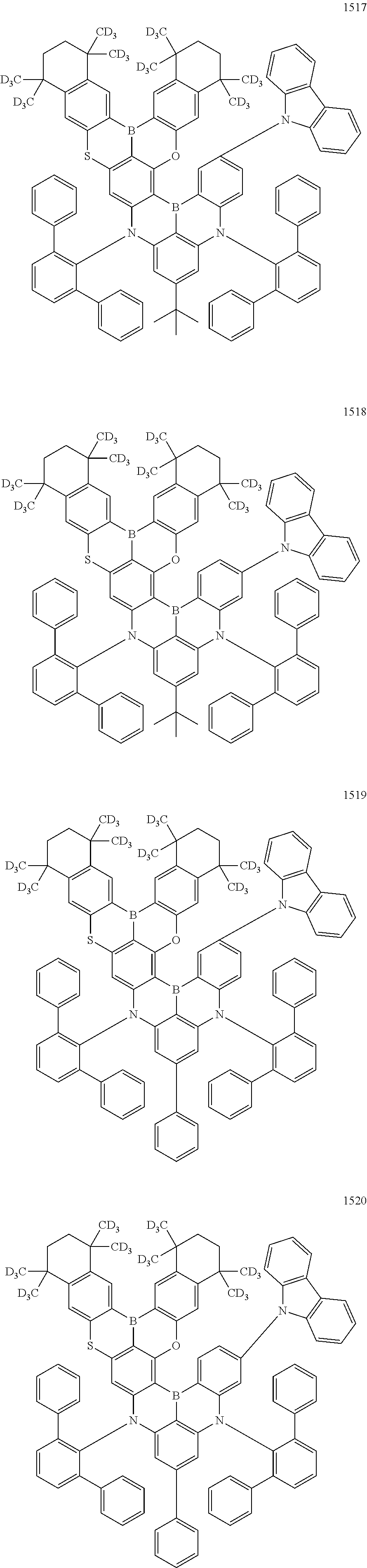

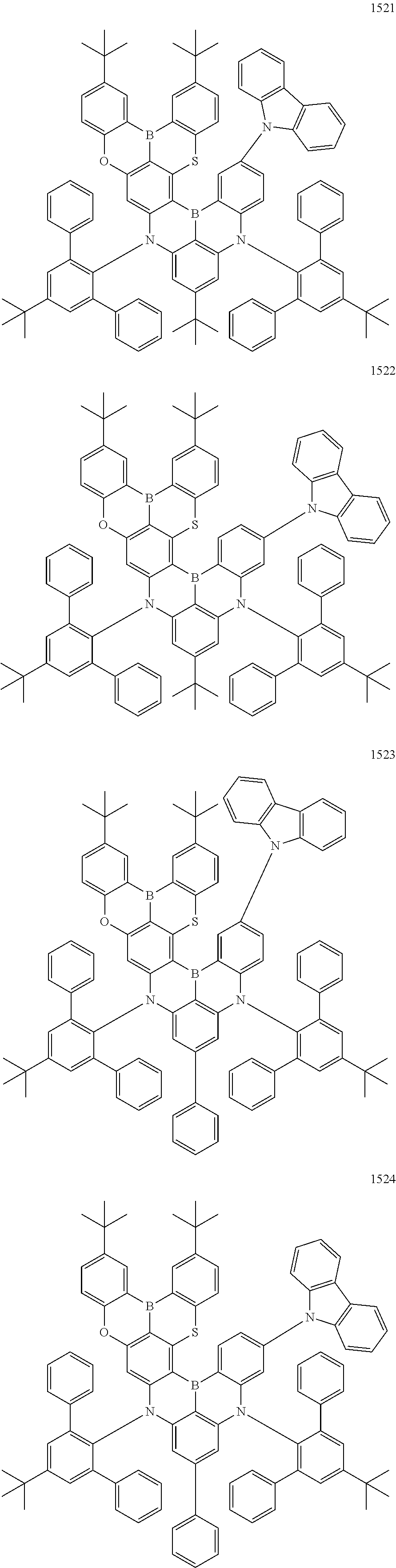

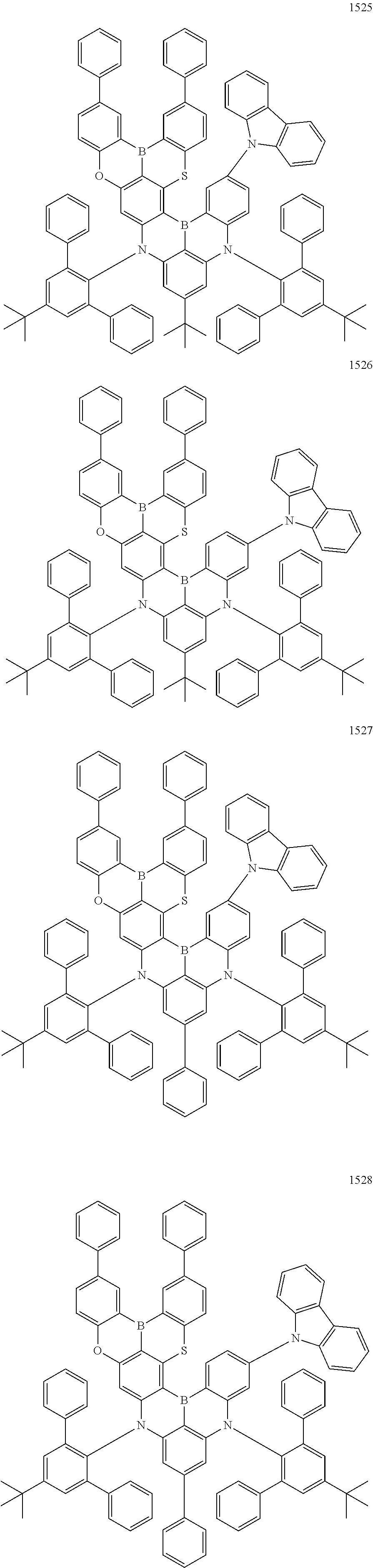

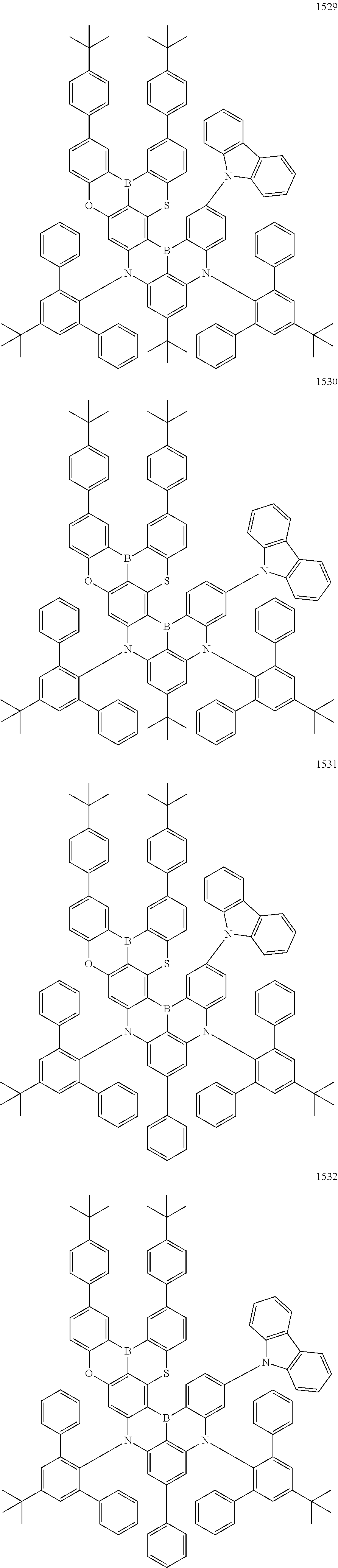

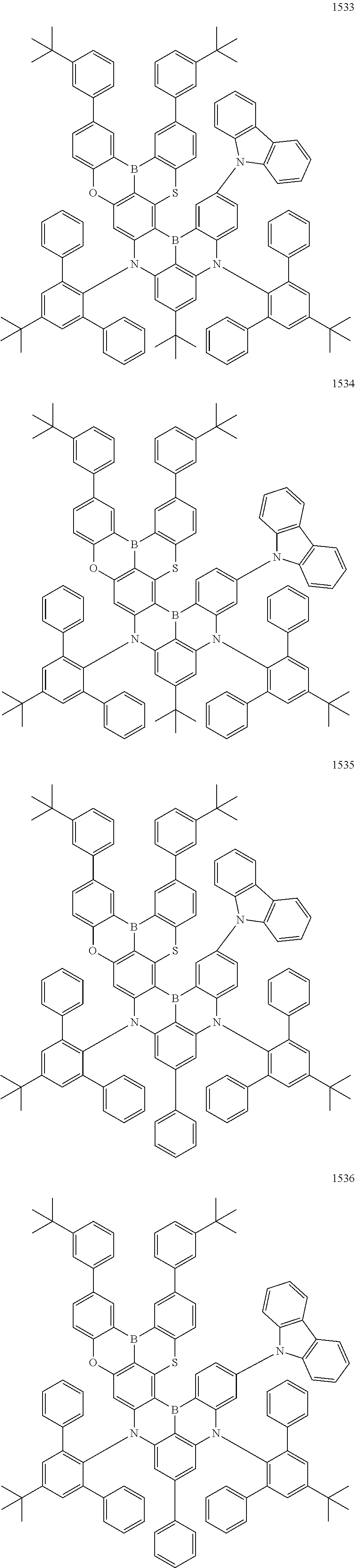

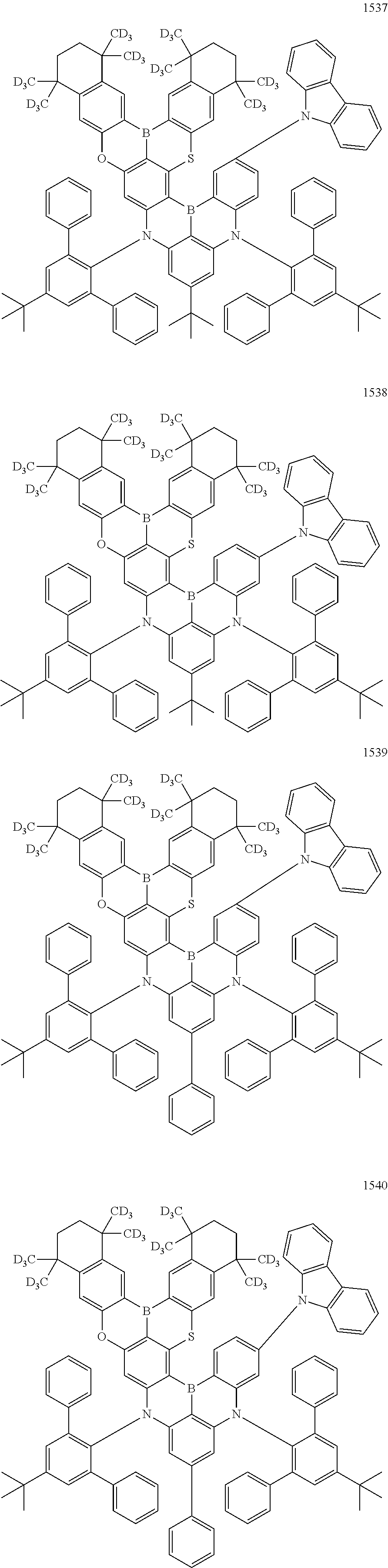

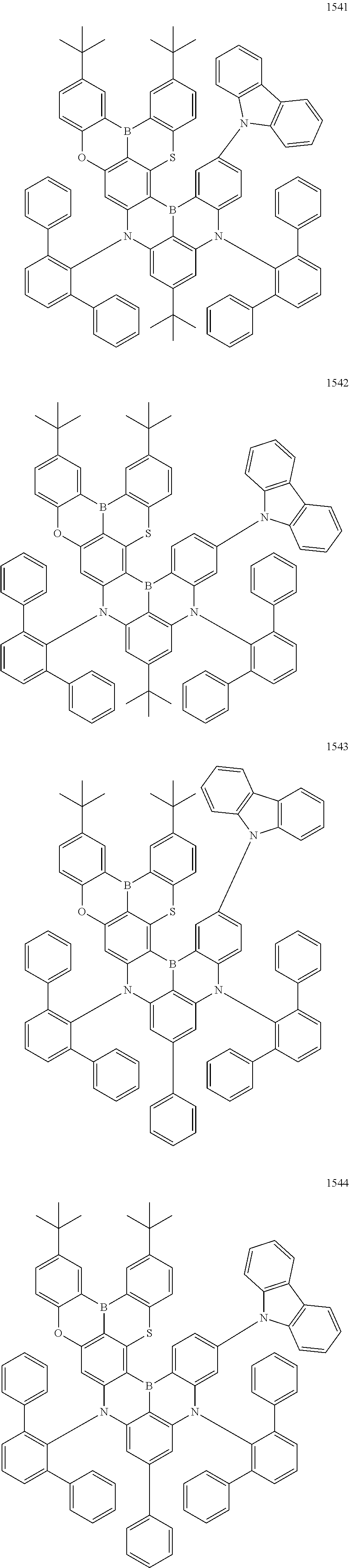

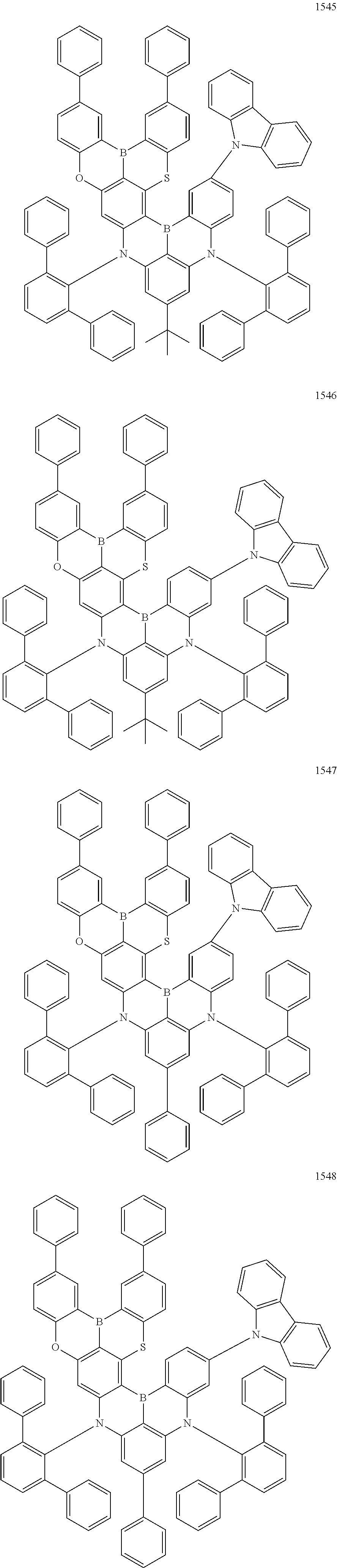

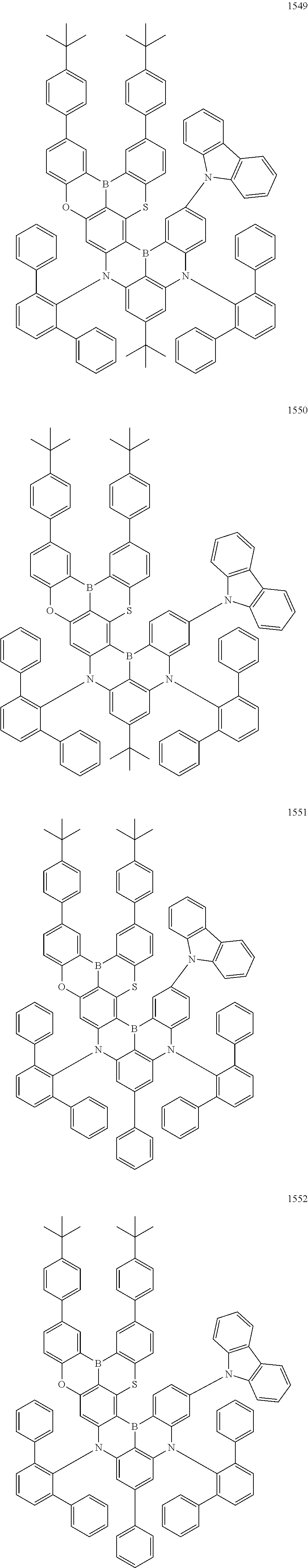

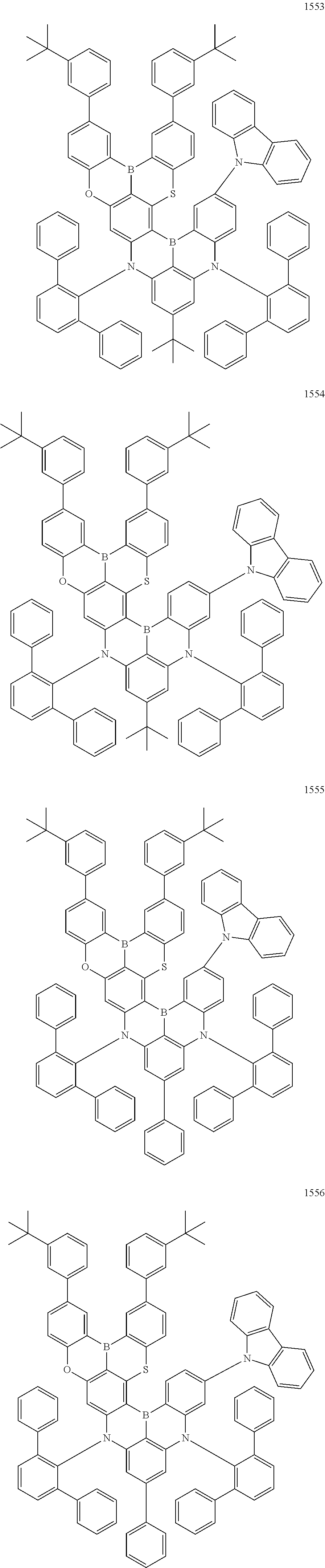

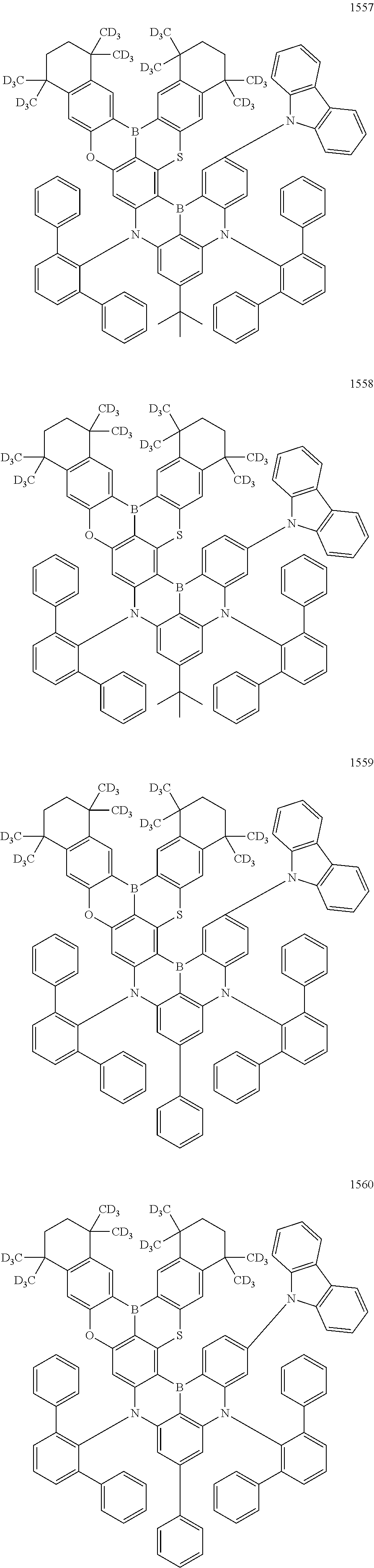

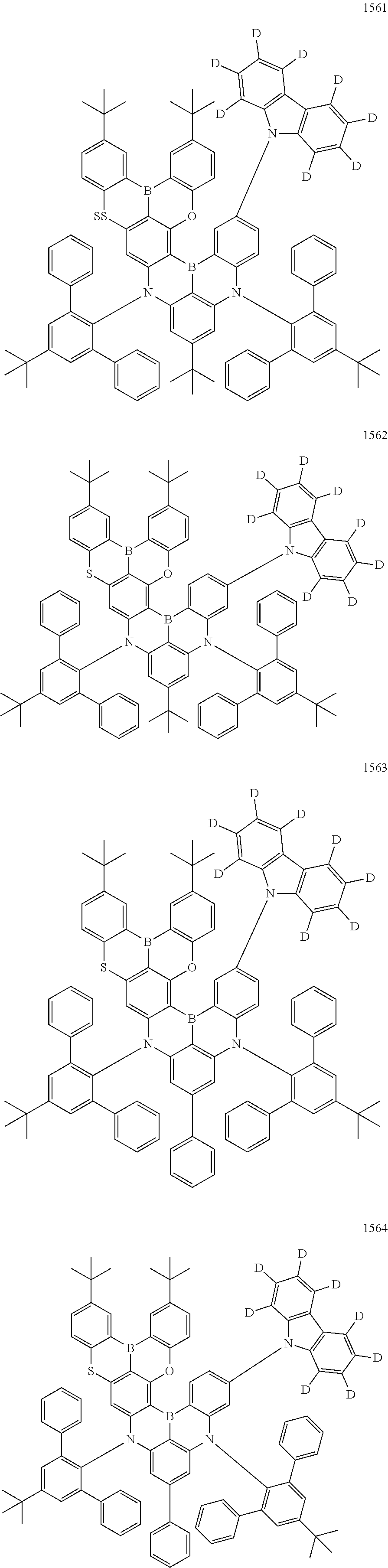

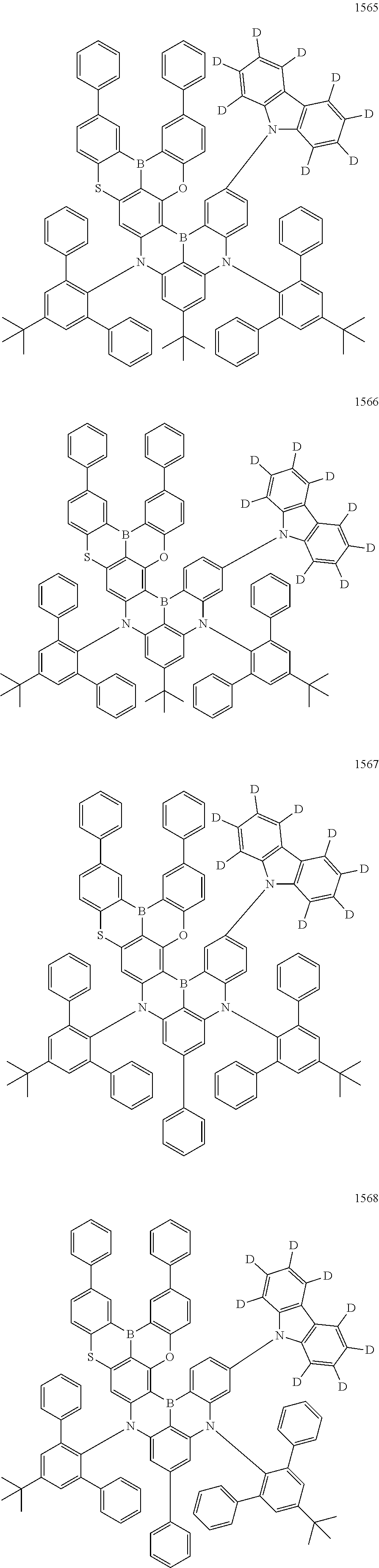

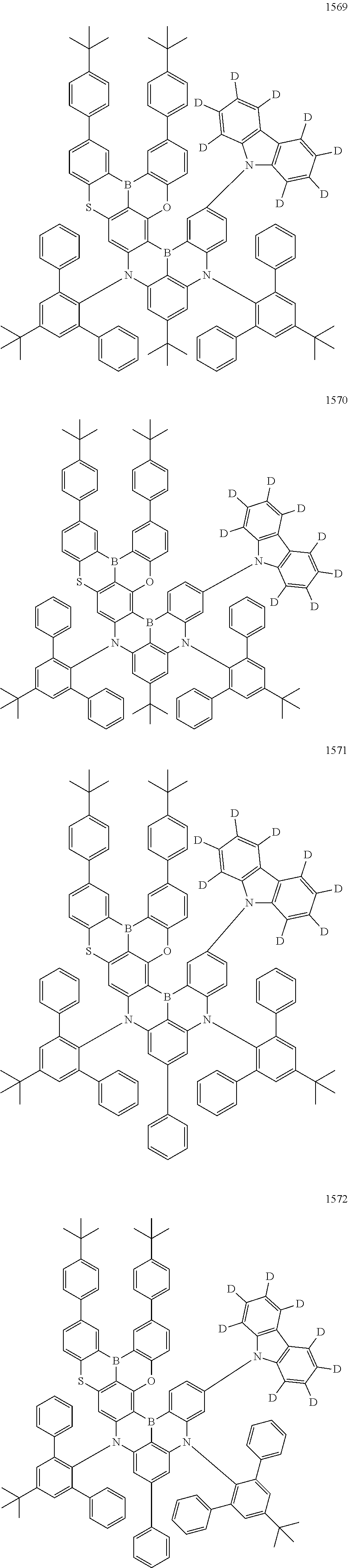

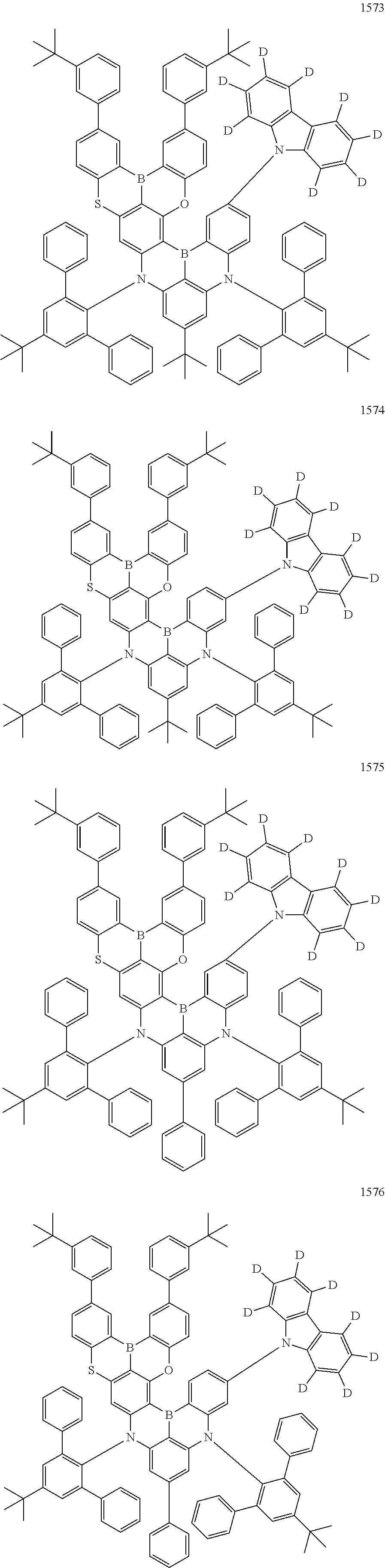

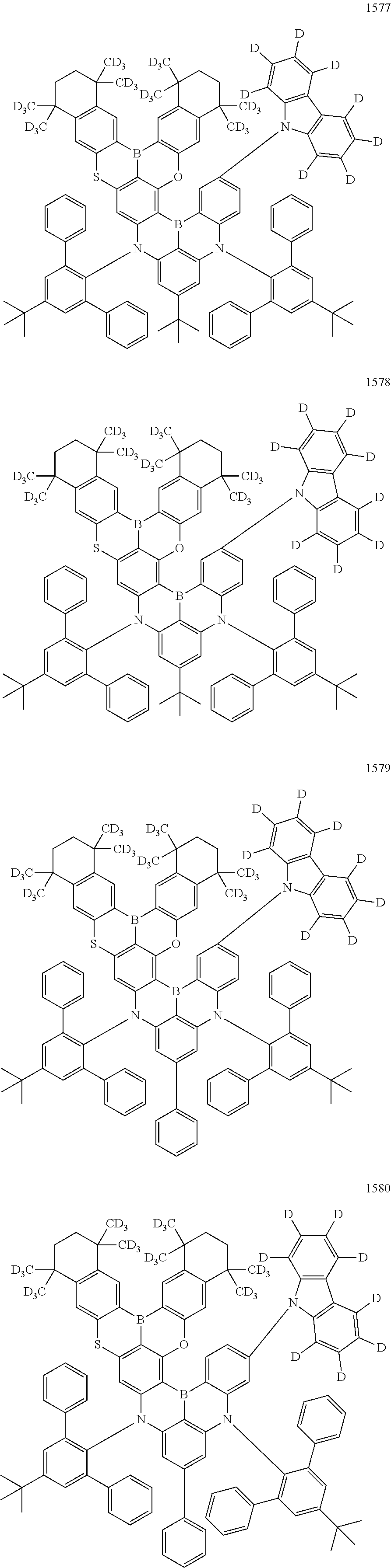

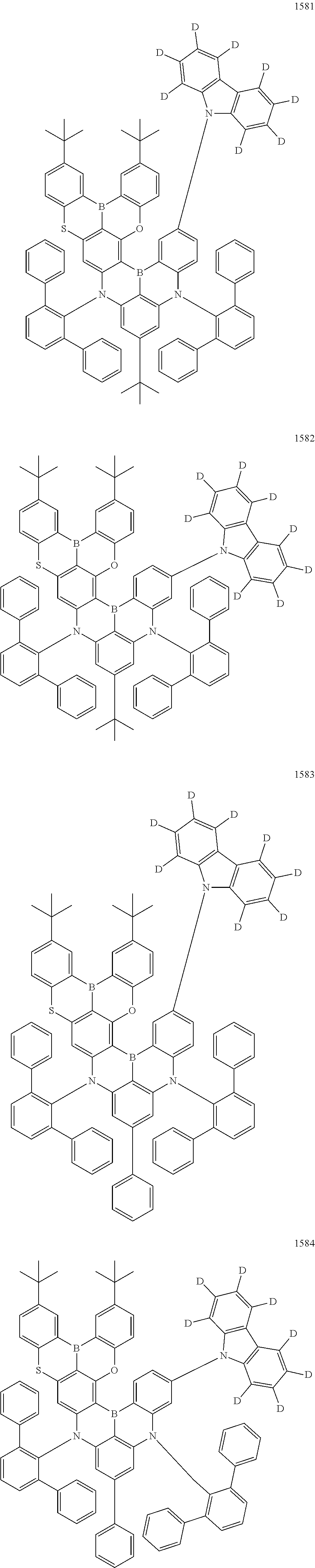

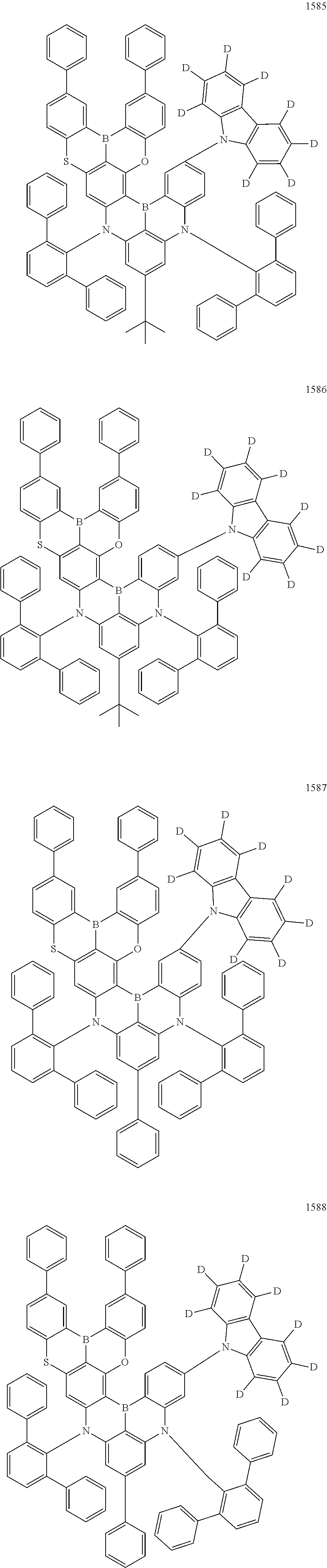

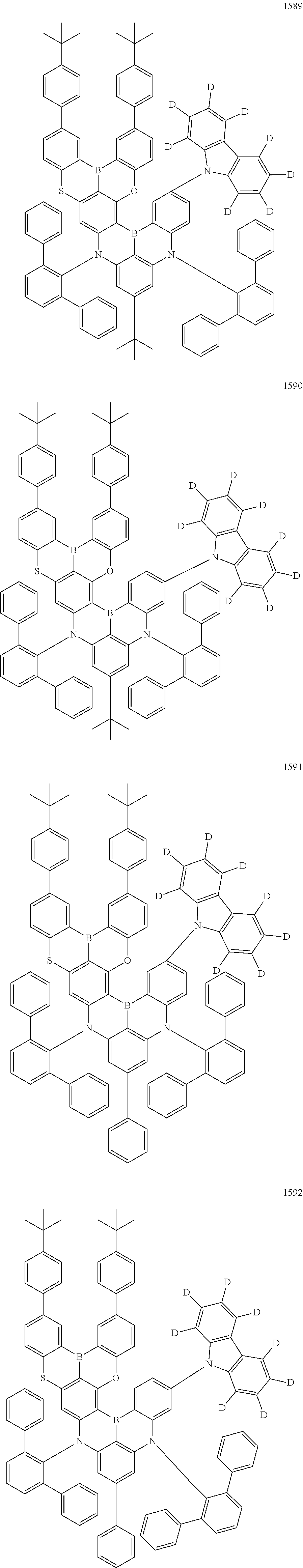

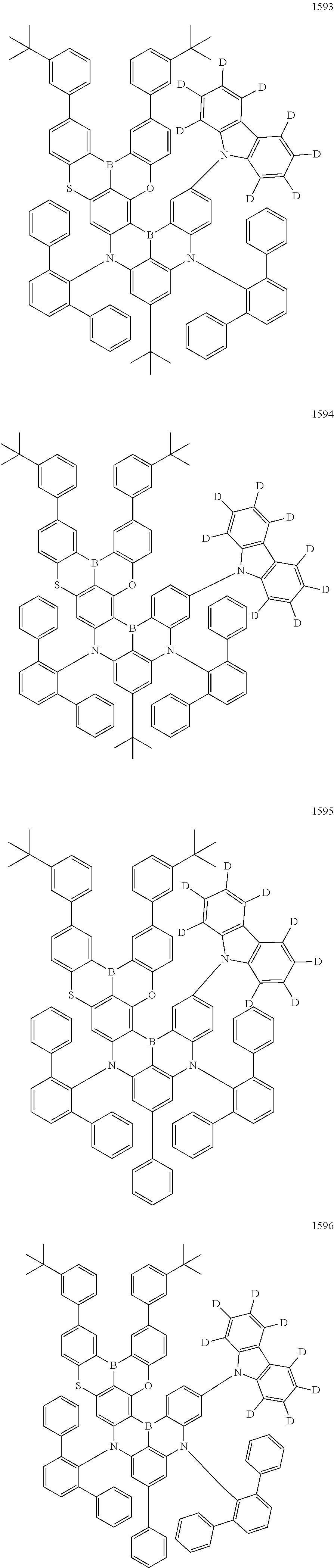

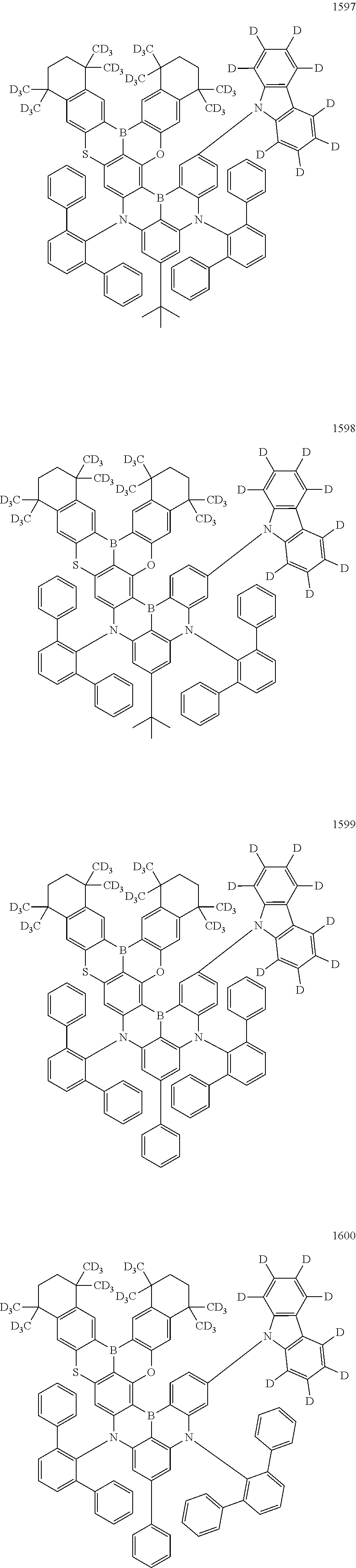

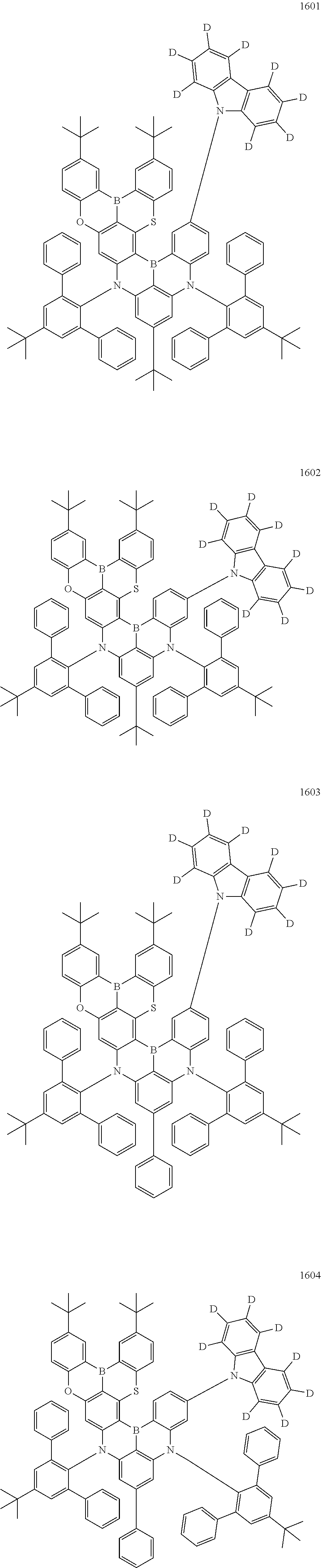

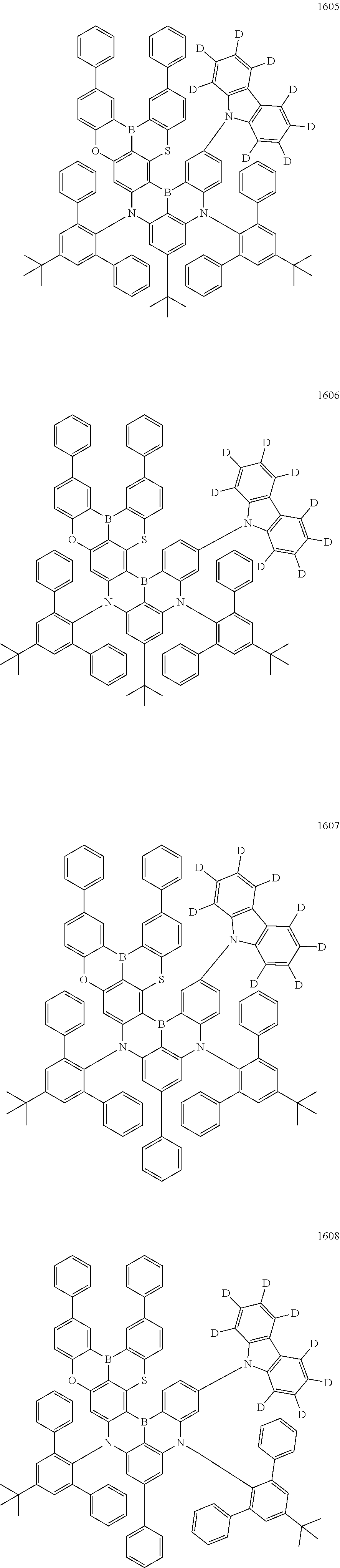

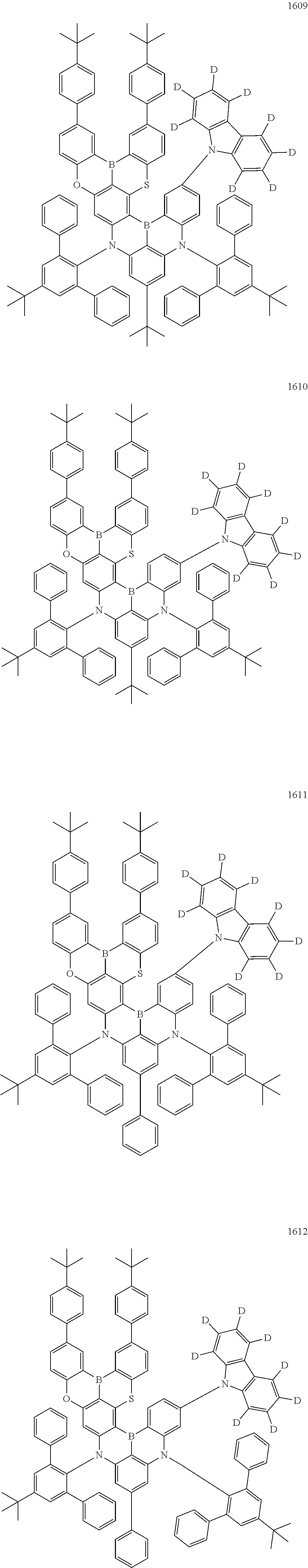

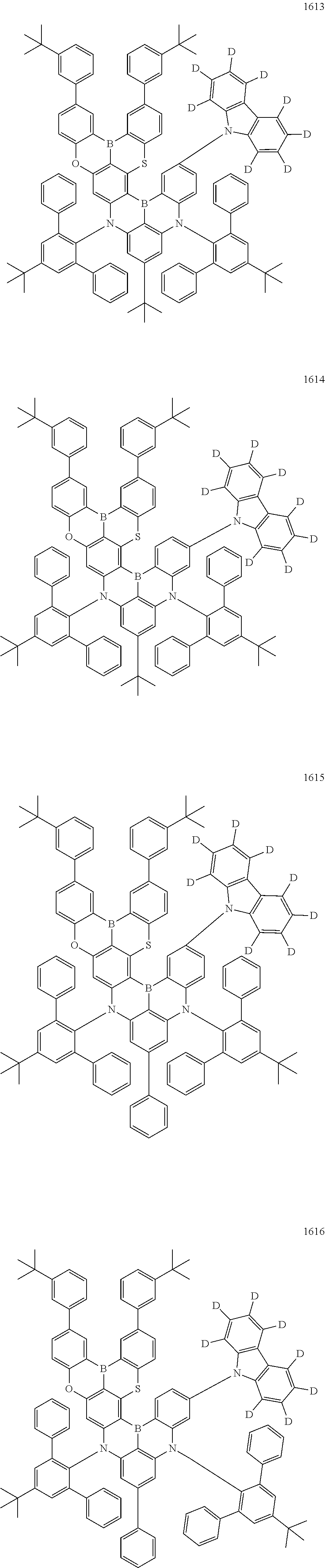

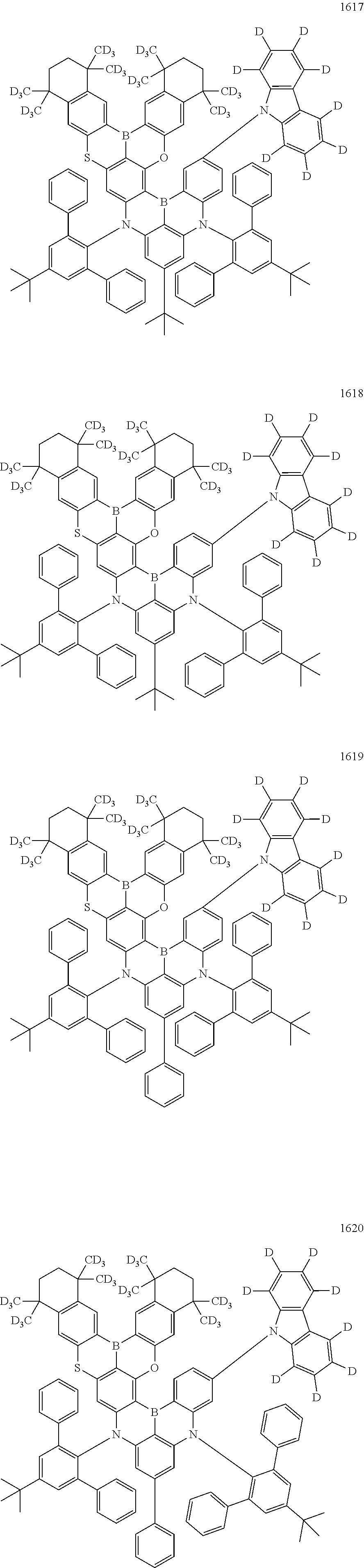

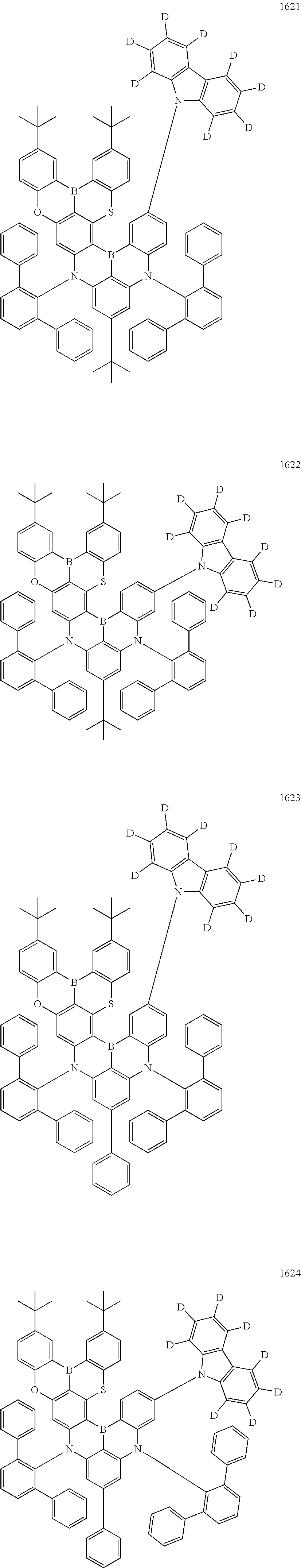

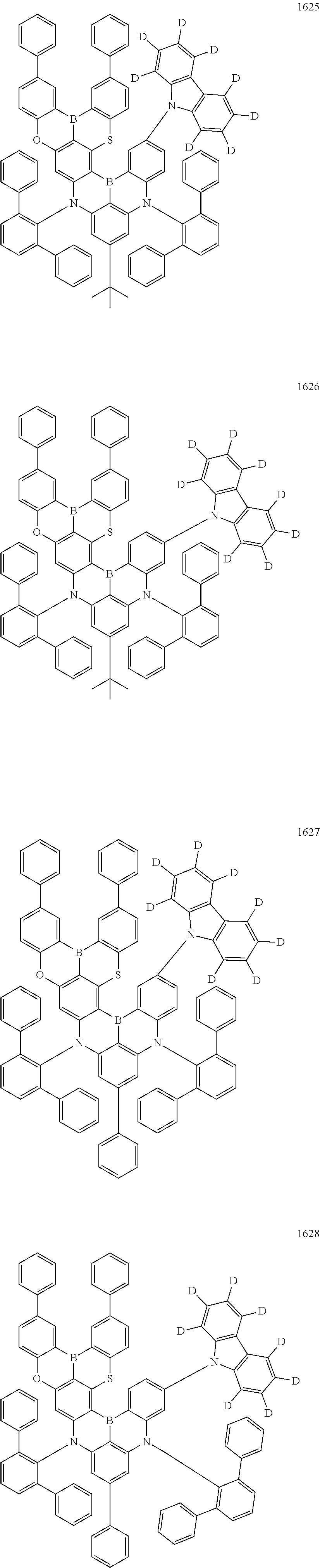

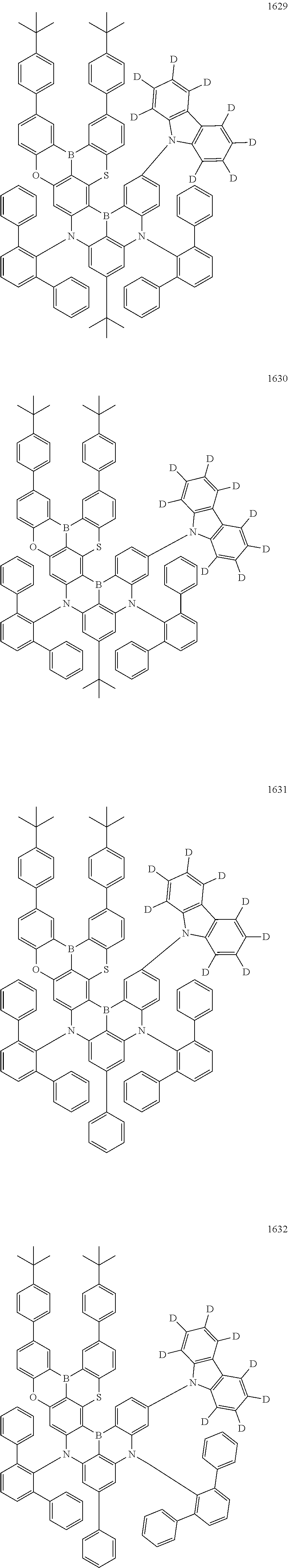

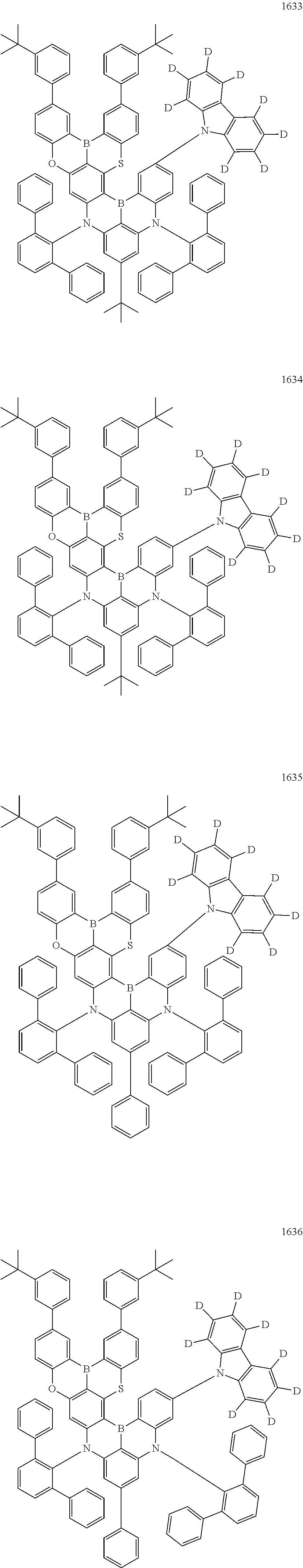

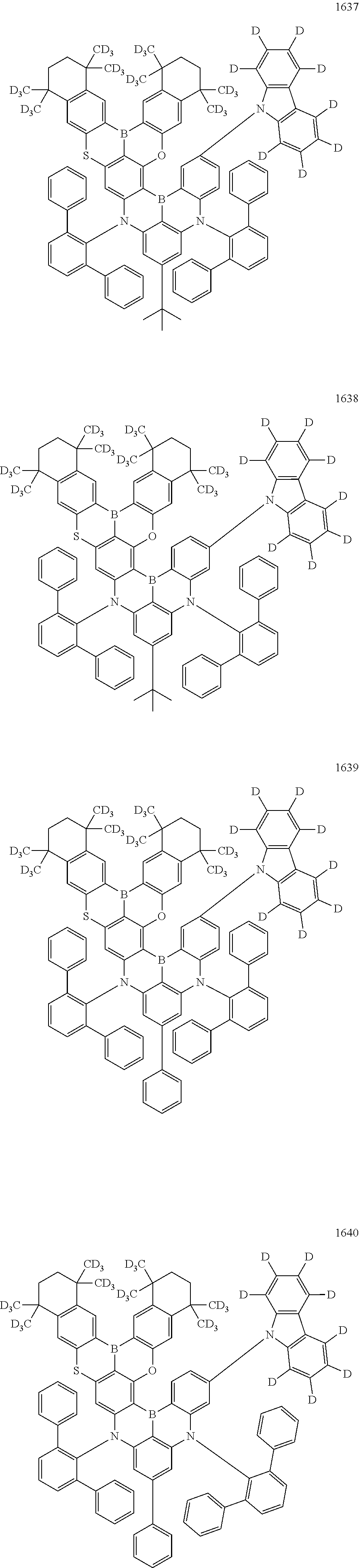

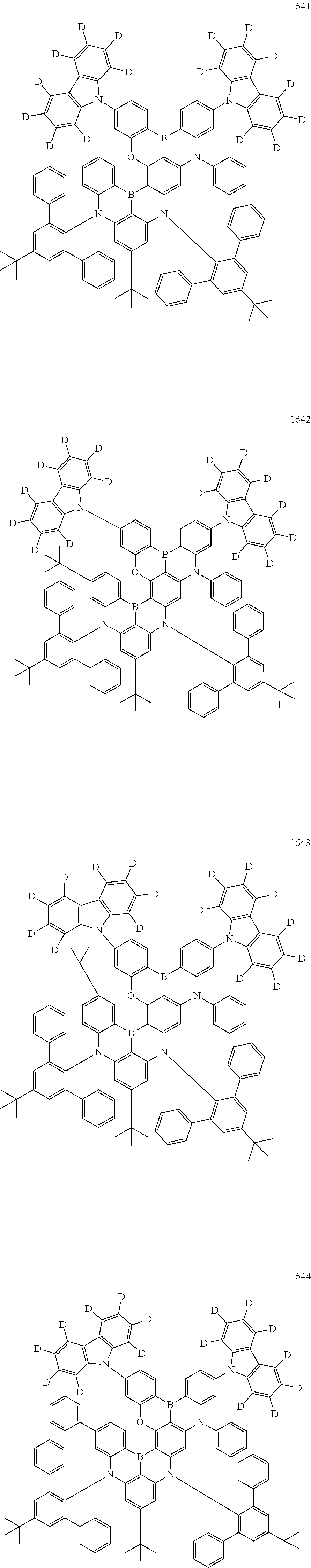

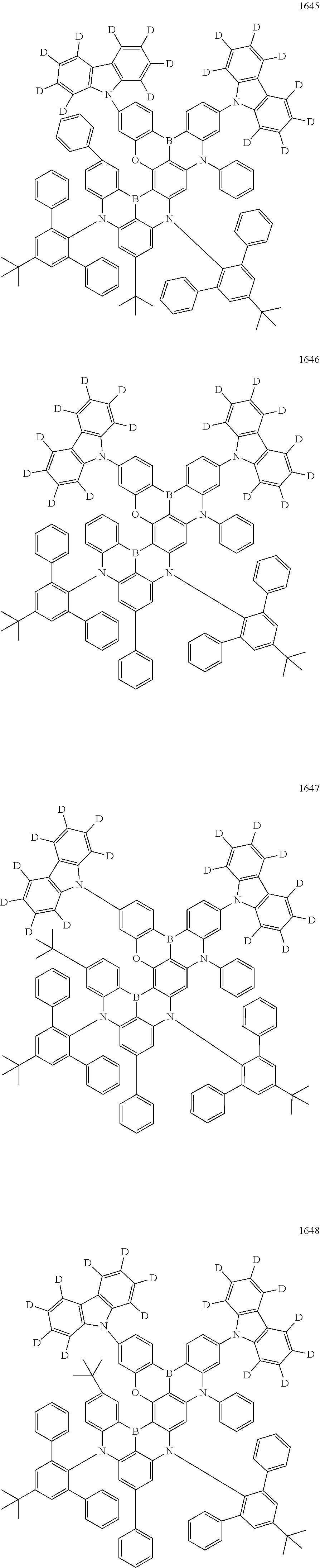

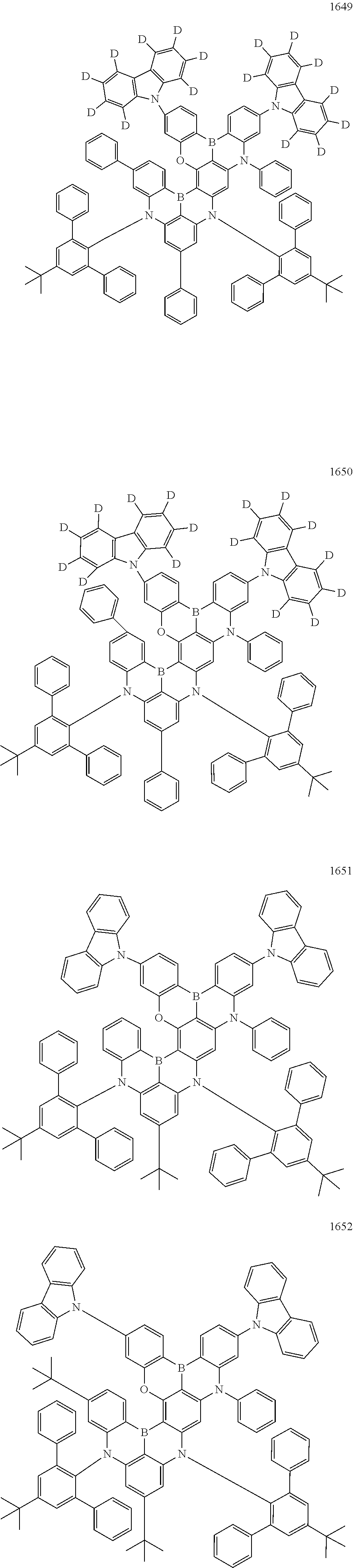

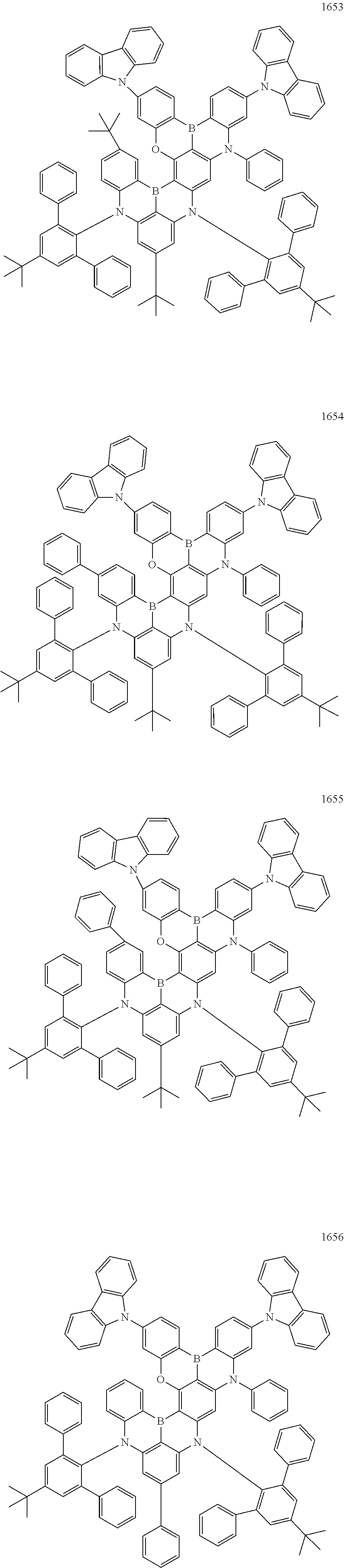

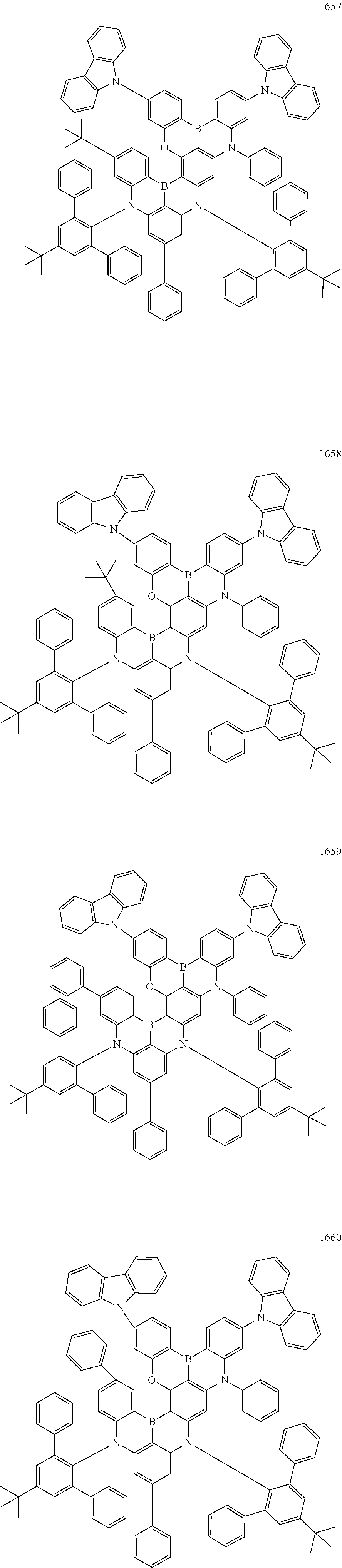

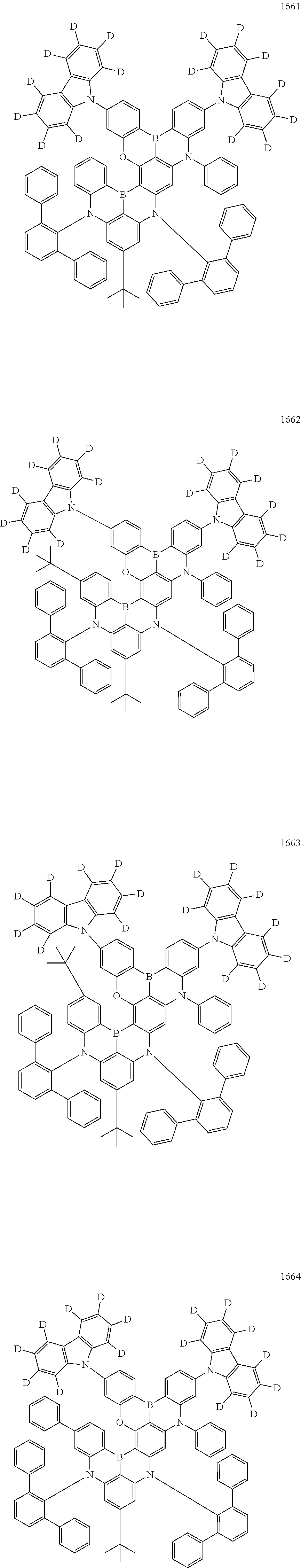

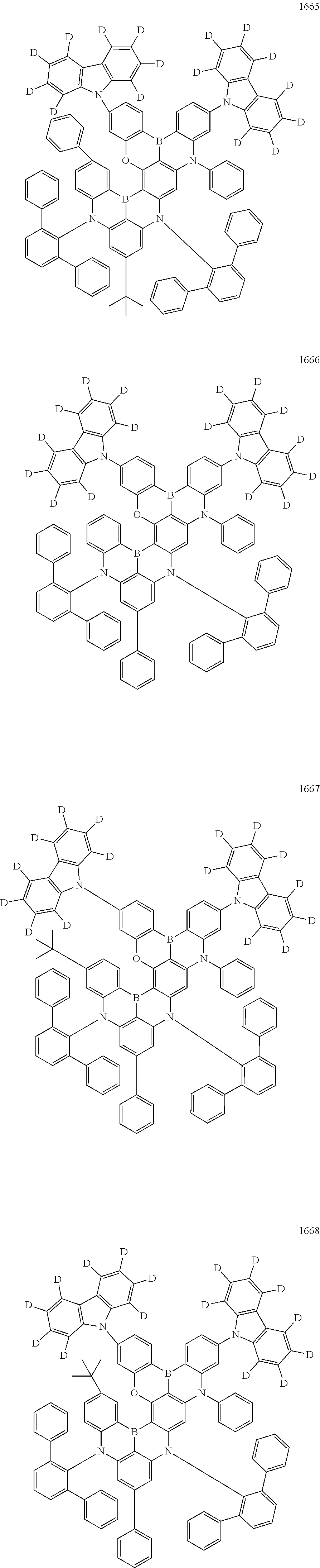

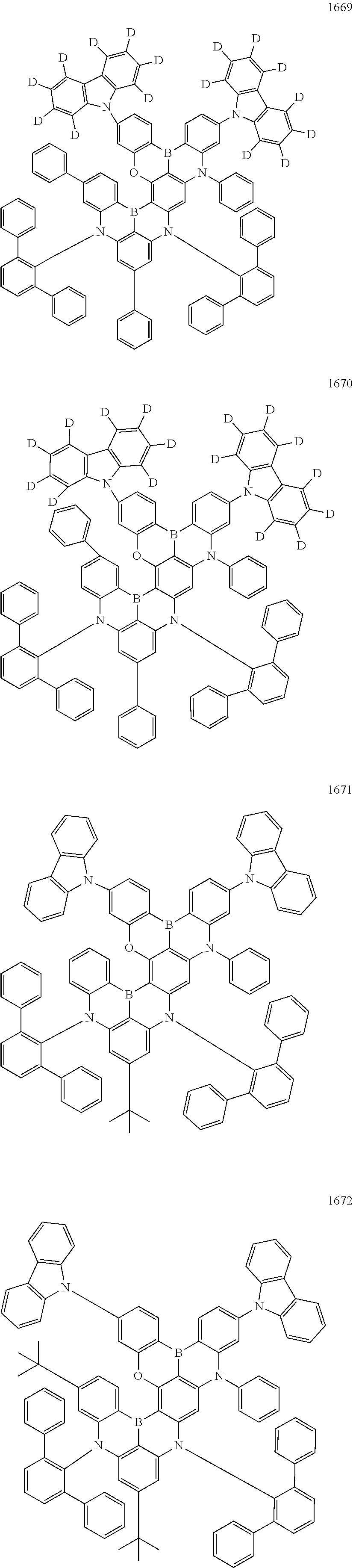

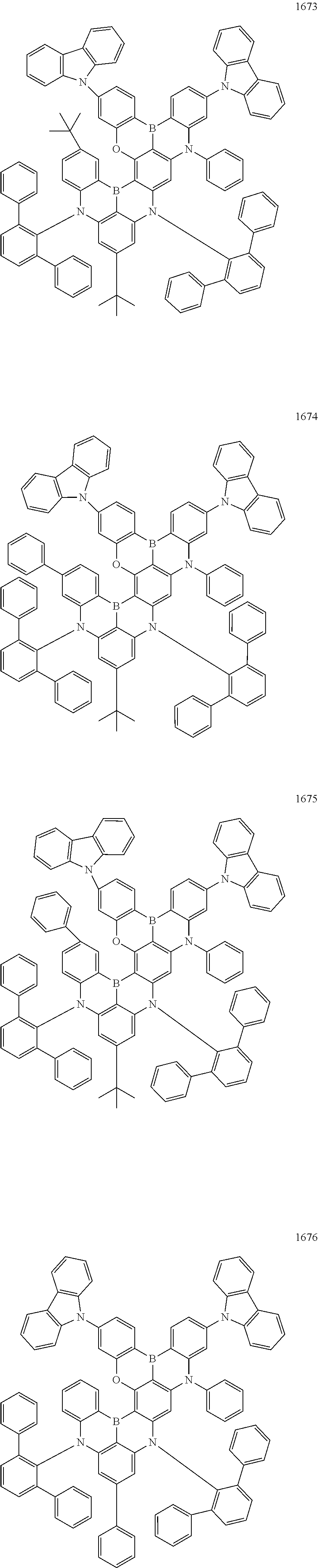

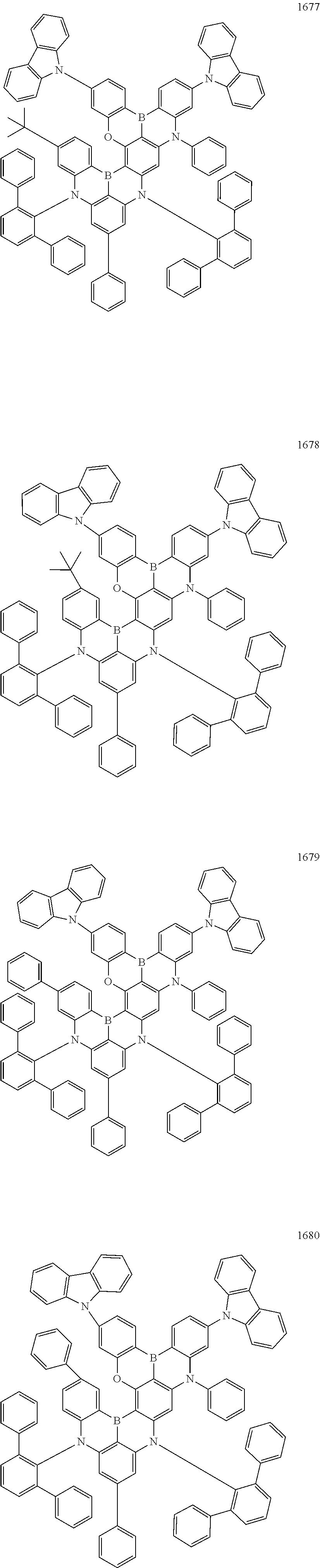

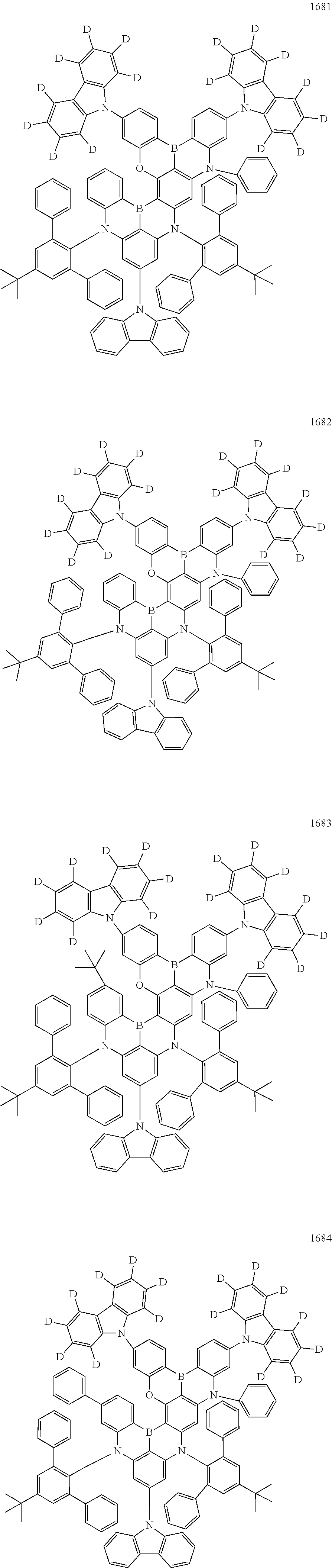

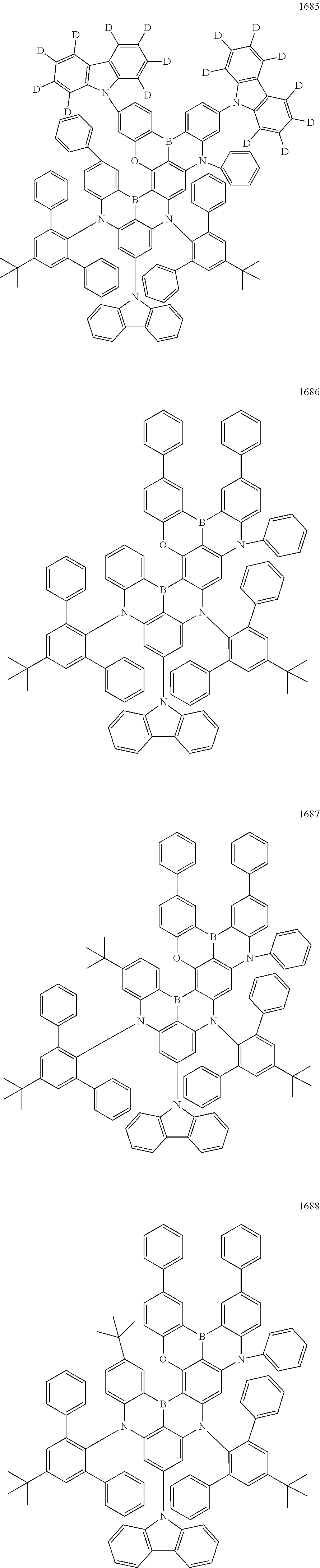

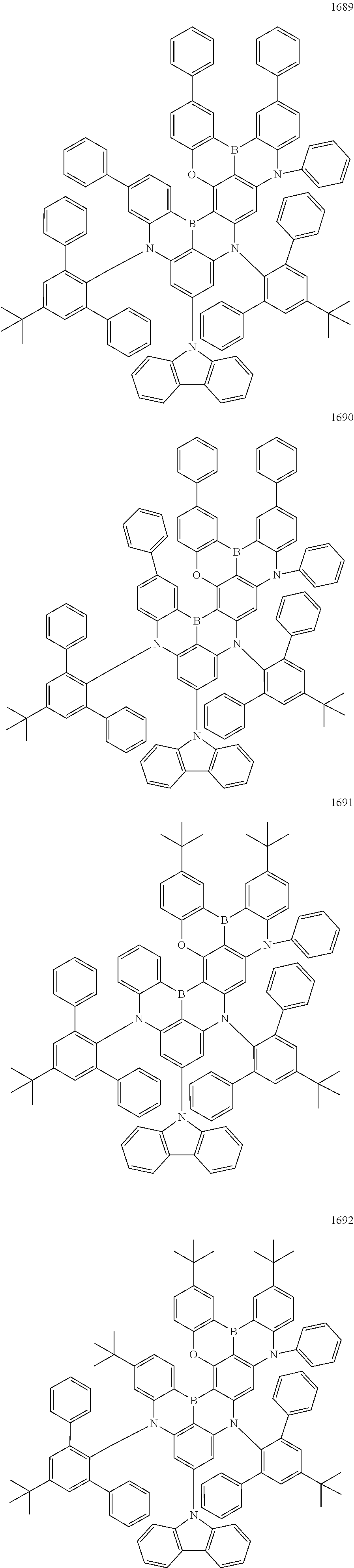

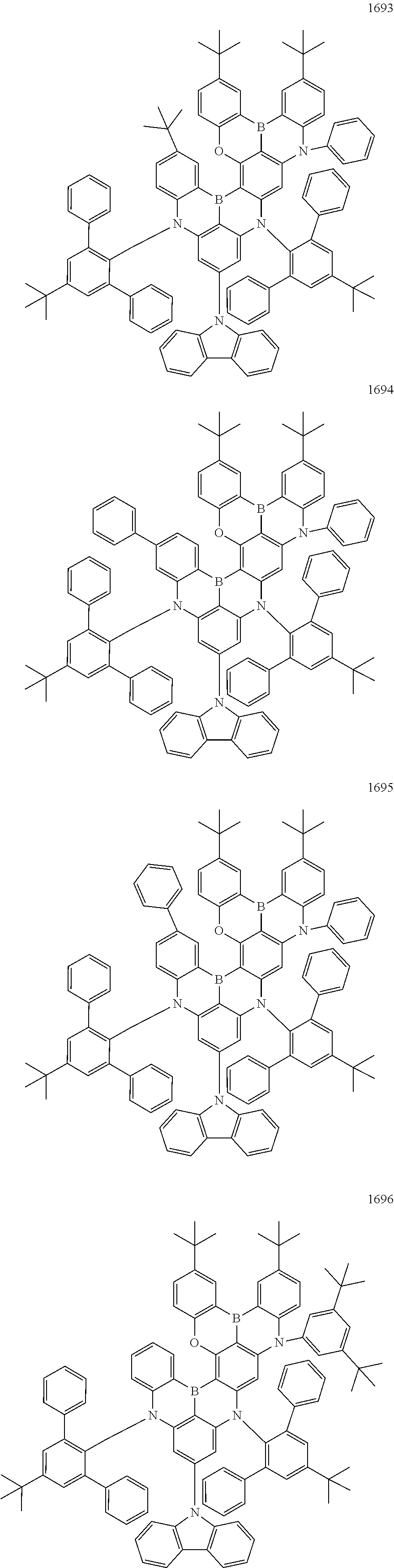

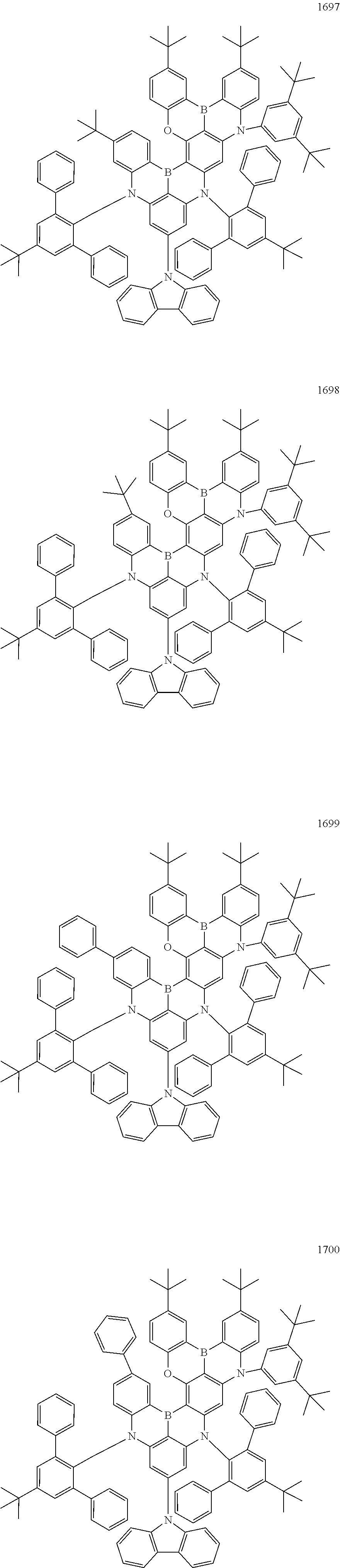

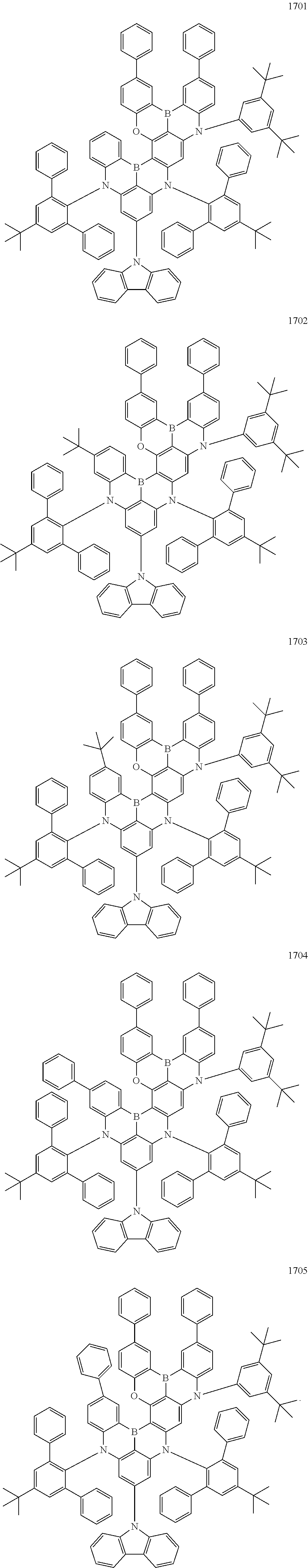

The heterocyclic compound represented by Formula 1 satisfies the structure of Formula 1 and includes a structure in which Ar₁ and Ar₂ are each independently a group represented by Formula 2. Due to this structure, the heterocyclic compound represented by Formula 1 has excellent luminescence characteristics, and in particular, may implement a deep blue color with a short wavelength.

Without being limited to any particular theory, the heterocyclic compound represented by Formula 1 may exhibit advantageous characteristics such as narrow full width at half maximum (FWHM), a small Stokes shift, and/or a fast delayed fluorescence excitation time (tau) due to the increased molecular rigidity resulting from having the backbone represented by Formula 1, which leads to a small singlet-triplet energy difference. Furthermore, as described above, due to the inclusion of the group represented by Formula 2, that is, a bulky substituent in which ring CY₇ and ring CY₈ are connected at the ortho position of ring CY₆, a singlet (S₁) energy level is high, intermolecular interactions are suppressed to achieve high color purity, photo-orientability is high, and consequently, when the heterocyclic compound represented by Formula 1 is used as a luminescent material, Dexter energy transfer is suppressed, resulting in excellent lifespan characteristics.

Therefore, an electronic device, for example, an organic light-emitting device including at least one of the heterocyclic compounds represented by Formula 1 can exhibit a high efficiency and/or a long lifespan.

The highest occupied molecular orbital (HOMO) energy level, lowest unoccupied molecular orbital (LUMO) energy level, S₁ energy level, and triplet (T₁) energy level of some compounds among heterocyclic compounds represented by Formula 1 and compounds A and B were evaluated using the Gaussian 09 program involving molecular structure optimization based on density functional theory (DFT) using B3LYP level optimization. Results thereof are shown in Table 1, where the energy levels are reported in electron volts (eV).

TABLE 1

| | HOMO | LUMO | S₁ | T₁ |
|---|---|---|---|---|
| | (eV) | (eV) | (eV) | (eV) |
| Compound 1 | −4.703 | −1.345 | 2.771 | 2.674 |
| Compound 16 | −4.769 | −1.362 | 2.735 | 2.623 |
| Compound A | −4.743 | −1.125 | 2.820 | 2.627 |
| Compound B | −4.754 | −1.253 | 2.795 | 2.701 |

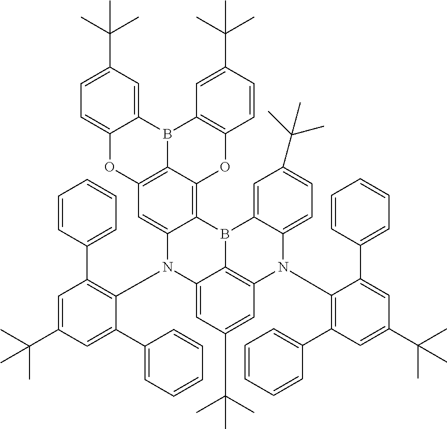 [SMILES: CC(C)(C)c1ccc2c(c1)B1c3cc(C(C)(C)C)ccc3Oc3c1c(cc1c3B3c4cc(C(C)(C)C)ccc4N(c4c(-c5ccccc5)cc(C(C)(C)C)cc4-c4ccccc4)c4cc(C(C)(C)C)cc(c43)N1c1c(-c3ccccc3)cc(C(C)(C)C)cc1-c1ccccc1)O2]

1 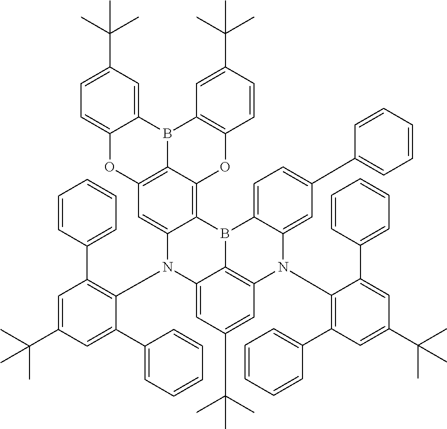 [SMILES: CC(C)(C)c1ccc2c(c1)B1c3cc(C(C)(C)C)ccc3Oc3c1c(cc1c3B3c4ccc(-c5ccccc5)cc4N(c4c(-c5ccccc5)cc(C(C)(C)C)cc4-c4ccccc4)c4cc(C(C)(C)C)cc(c43)N1c1c(-c3ccccc3)cc(C(C)(C)C)cc1-c1ccccc1)O2]
16 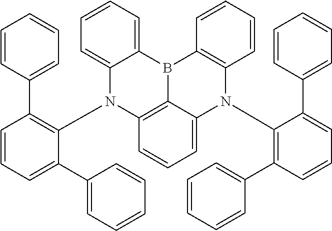 [SMILES: c1ccc(-c2cccc(-c3ccccc3)c2N2c3ccccc3B3c4ccccc4N(c4c(-c5ccccc5)cccc4-c4ccccc4)c4cccc2c43)cc1]
A 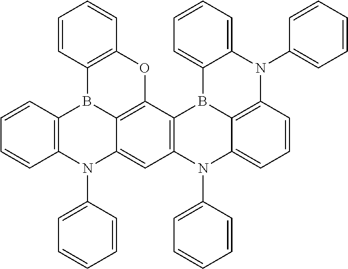 [SMILES: c1ccc(N2c3ccccc3B3c4c2cccc4N(c2ccccc2)c2cc4c5c(c23)Oc2ccccc2B5c2ccccc2N4c2ccccc2)cc1]
B

From Table 1, it was confirmed that the heterocyclic compound represented by Formula 1 has electrical properties suitable for use as a dopant (e.g., an emitter or a sensitizer) in an electronic device, for example, an organic light-emitting device.

According to one or more embodiments, the full width at half maximum (FWHM) of an emission peak of an emission spectrum or electroluminescence spectrum of the heterocyclic compound represented by Formula 1 may be about 60 nanometers (nm) or less. For example, the FWHM of an emission peak of an emission spectrum or electroluminescence spectrum of the heterocyclic compound represented by Formula 1 may be about 5 nm to about 50 nm, about 7 nm to about 40 nm, or about 10 nm to about 30 nm.

Synthesis methods of the heterocyclic compound represented by Formula 1 may be recognizable by one of ordinary skill in the art and by referring to Synthesis Examples provided herein.

There is no particular limitation on the method for confirming the structure of the heterocyclic compound represented by Formula 1. According to one or more embodiments, the structure of the heterocyclic compound represented by Formula 1 may be confirmed by a known method (e.g., NMR, LC-MS, or the like).

### Organic Light-Emitting Device

According to another aspect, an organic light-emitting device includes at least one heterocyclic compound represented by Formula 1.

According to one or more embodiments, the organic light-emitting device includes: a first electrode; a second electrode; and an organic layer disposed between the first electrode and the second electrode, wherein the organic layer includes an emission layer, and wherein the organic layer further includes at least one of the heterocyclic compounds represented by Formula 1.

In one or more embodiments, the emission layer may include the at least one heterocyclic compound represented by Formula 1.

According to one or more embodiments, the emission layer may include a host and an emitter, and the emitter may include at least one of the heterocyclic compounds represented by Formula 1.

According to one or more embodiments, the amount of the host in the emission layer may be greater than the amount of the at least one heterocyclic compound represented by Formula 1 in the emission layer, based on weight.

According to one or more embodiments, the emission layer may further include a sensitizer.

According to one or more embodiments, the sensitizer may include a phosphorescent compound, a delayed fluorescence compound, or a combination thereof.

Detailed descriptions of the host, the emitter, and the sensitizer are as provided herein.

The organic light-emitting device may have a relatively narrow FWHM of the electroluminescence (EL) spectrum emission peak, excellent efficiency, and/or lifespan characteristics by having an emission layer including at least one of the heterocyclic compounds represented by Formula 1 as described herein.

According to one or more embodiments, the heterocyclic compound represented by Formula 1 acts as a dopant (e.g., an emitter or a sensitizer) in the emission layer, and the emission layer may further include a host (i.e., in the emission layer, the amount of the at least one heterocyclic compound represented by Formula 1 may be smaller than the amount of the host, based on weight).

In one or more embodiments, the emission layer may emit a blue light. For example, the emission layer may emit a blue light having a maximum emission wavelength in a range of about 400 nm to about 490 nm.

According to one or more embodiments, the emission layer may emit a deep blue light having a maximum emission wavelength of about 410 nm to about 450 nm. For example, the emission layer may emit a deep blue light having a maximum emission wavelength of about 410 nm to about 445 nm.

The expression that an “(emission layer) includes at least one heterocyclic compound represented by Formula 1” as used herein may be construed as meaning that the “(emission layer) may include one heterocyclic compound of Formula 1 or two or more different heterocyclic compounds of Formula 1.”

For example, the emission layer may include only the compound 1 as the at least one heterocyclic compound represented by Formula 1. At this time, compound 1 may be present in the emission layer of the organic light-emitting device. In some embodiments, the emission layer may include compound 1 and compound 2 as the at least one heterocyclic compound represented by Formula 1, wherein compound 1 and compound 2 are different.

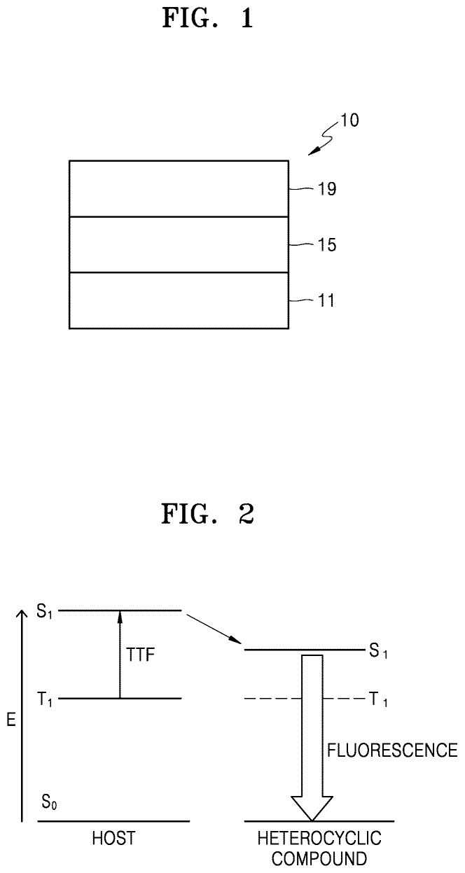

### Description of FIG. 1

FIG. 1 is a schematic cross-sectional view of an organic light-emitting device 10 according to one or more embodiments. Hereinafter, the structure and manufacturing method of an organic light-emitting device according to one or more embodiments will be described in further detail with reference to FIG. 1.

The organic light-emitting device 10 of FIG. 1 includes a first electrode 11, a second electrode 19 facing the first electrode 11, and an organic layer 15 between the first electrode 11 and the second electrode 19.

The organic layer 15 may include an emission layer, and may further include a hole transport region arranged between the first electrode 11 and the emission layer, and an electron transport region arranged between the emission layer and the second electrode 19.

A substrate may be further disposed under the first electrode 11 or on the second electrode 19. The substrate may be a substrate commonly used in organic light-emitting devices, e.g., a glass substrate or a transparent plastic substrate, which have excellent mechanical strength, thermal stability, transparency, surface smoothness, ease of handling, and/or water repellency.

### First Electrode 11

The first electrode 11 may be formed by, for example, depositing or sputtering, onto the substrate, a material for forming the first electrode 11. The first electrode 11 may be an anode. The material for forming the first electrode 11 may be selected from materials with a high work function for easy hole injection.

The first electrode 11 may be a reflective electrode, a transflective electrode, or a transmissive electrode. When the first electrode 11 is a transmissive electrode, a material for forming the first electrode 11 may be indium tin oxide (ITO), indium zinc oxide (IZO), tin oxide (SnO₂), zinc oxide (ZnO), or a combination thereof, but embodiments are not limited thereto. In some embodiments, when the first electrode 11 is a transflective electrode or a reflective electrode, as a material for forming the first electrode 11, at least one of magnesium (Mg), silver (Ag), aluminum (Al), aluminum-lithium (Al—Li), calcium (Ca), magnesium-indium (Mg—In), magnesium-silver (Mg—Ag), or a combination thereof may be used, but embodiments are not limited thereto.

The first electrode 11 may have a single-layered structure or a multi-layered structure including two or more layers.

### Emission Layer

The emission layer includes at least one the heterocyclic compounds represented by Formula 1.

A thickness of the emission layer may be about 100 Å to about 1,000 Å, for example, about 200 Å to about 600 Å. When the thickness of the emission layer is within the range described above, excellent luminescence characteristics may be obtained without a substantial increase in driving voltage.

The features and aspects of FIG. 1 are described in further detail below.

### Description of FIG. 2

According to one or more embodiments, the heterocyclic compound represented by Formula 1 may be a fluorescent emitter.

According to one or more embodiments, the emission layer may further include a host (hereinafter referred to as ‘host A’, and host A is not the same as the heterocyclic compound represented by Formula 1). Host A may be understood by referring to the description of the host material as provided herein, but embodiments are not limited thereto. Host A may be a fluorescent host.

Referring to FIG. 2, the energy transfer according to one or more embodiments will be described in detail.

A singlet exciton is formed in host A in the emission layer, and the singlet exciton formed in host A is transferred to a fluorescent emitter via a Förster energy transfer (or, Förster resonance energy transfer (FRET)).

Since only 25% of excitons formed in host A are singlet excitons, by enabling the triplet excitons, which constitute 75% of the excitons formed in host A, to fuse with each other and convert to singlet excitons, the efficiency of the organic light-emitting device may be further improved. That is, the efficiency of organic light-emitting devices may be further improved by utilizing the triplet-triplet fusion (TTF) mechanism.

According to one or more embodiments, among the total emission components emitted from the emission layer, the ratio of the emission components emitted from the heterocyclic compound represented by Formula 1 may be about 80% or more, for example, about 90% or more. In some embodiments, a ratio of emission components emitted from the heterocyclic compound represented by Formula 1 may be about 95% or more to the total emission components emitted from the emission layer.

The heterocyclic compound represented by Formula 1 may emit fluorescence, and the host may not emit a light.

According to one or more embodiments, when the emission layer further includes host A in addition to the heterocyclic compound represented by Formula 1, the amount of the heterocyclic compound represented by Formula 1 may be about 50 parts by weight or less, for example, about 30 parts by weight or less, based on 100 parts by weight of the emission layer, and the amount of host A in the emission layer may be about 50 parts by weight or more, for example, about 70 parts by weight or more, based on 100 parts by weight of the emission layer, but is not limited thereto.

According to one or more embodiments, when the emission layer further includes host A in addition to the heterocyclic compound represented by Formula 1, host A and the heterocyclic compound represented by Formula 1 may satisfy condition A:

E(H_{A})_{S1}>E_{S1} Condition A

wherein, in condition A,
E(H_{A})_{S1} indicates a lowest excited singlet energy level of Host A, and
E_{S1} indicates a lowest excited singlet energy level of the heterocyclic compound represented by Formula 1.

In this regard, E(H_{A})_{S1} and E_{S1} may be evaluated by using a Gaussian program according to a density functional theory (DFT) method (wherein structure optimization is performed at a level of B3LYP and 6-31G(d,p)).

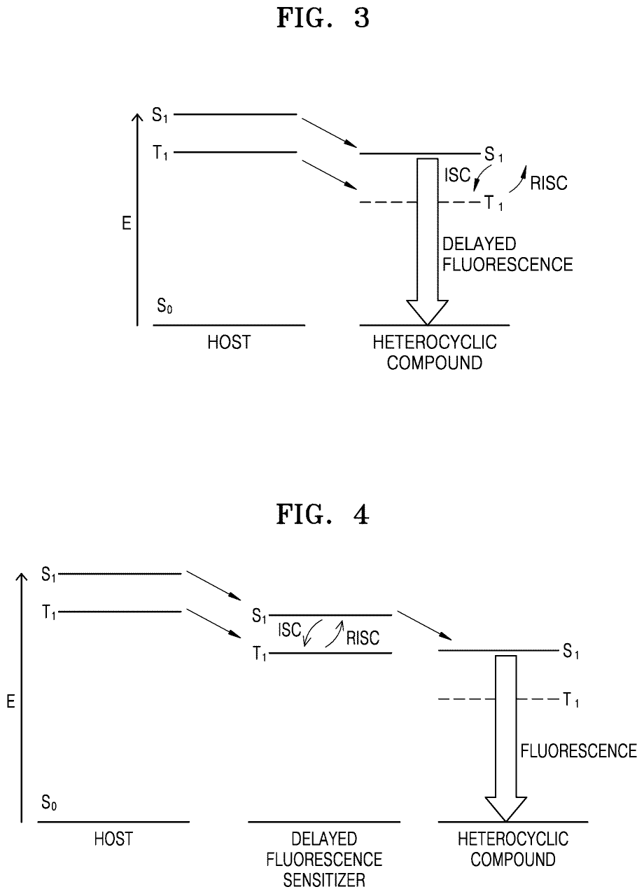

### Description For FIG. 3

According to one or more embodiments, the heterocyclic compound represented by Formula 1 may be a delayed fluorescence emitter.

According to one or more embodiments, the emission layer may further include a host (hereinafter referred to as ‘host B’, and host B is not the same as the heterocyclic compound represented by Formula 1). Host B may be understood by referring to the description of the host material as provided herein, but embodiments are not limited thereto.

Referring to FIG. 3, the energy transfer according to one or more embodiments will be described in detail.

25% of singlet excitons produced from Host B in the emission layer may be transferred to a delayed fluorescence emitter through FRET. Additionally, 75% of triplet excitons formed in host B in the emission layer may transferred to the delayed fluorescence emitter via Dexter energy transfer. At least part of the energy of the singlet state in this delayed fluorescence emitter may be transferred to the triplet state by intersystem crossing (ISC). The energy transferred to the triplet state of the delayed fluorescence emitter may be reverse intersystem crossing (RISC) to the singlet state. Accordingly, by transferring all the singlet excitons and triplet excitons generated in the emission layer to the heterocyclic compound represented by Formula 1, an organic light-emitting device having improved efficiency can be obtained.

According to one or more embodiments, among the total emission components emitted from the emission layer, the ratio of the emission components emitted from the heterocyclic compound represented by Formula 1 may be about 80% or more, for example, about 90% or more. For example, among the total emission components emitted from the emission layer, the ratio of the emission component emitted from the heterocyclic compound represented by Formula 1 may be about 95% or more.

In this regard, the heterocyclic compound represented by Formula 1 may emit fluorescence and/or delayed fluorescence, and the emission component of the heterocyclic compound represented by Formula 1 may be the sum of a prompt emission component of the heterocyclic compound represented by Formula 1 and the delayed fluorescence component by RISC of the heterocyclic compound represented by Formula 1. In addition, host B may not emit a light.

According to one or more embodiments, when the emission layer further includes host B in addition to the heterocyclic compound represented by Formula 1, the amount of the heterocyclic compound represented by Formula 1 may be about 50 parts by weight or less, for example, about 30 parts by weight or less, based on 100 parts by weight of the emission layer, and the amount of the host B in the emission layer may be about 50 parts by weight or more, for example, about 70 parts by weight or more, based on 100 parts by weight of the emission layer, but embodiments are not limited thereto.

According to one or more embodiments, when the emission layer further includes host B in addition to the heterocyclic compound represented by Formula 1, host B and the heterocyclic compound represented by Formula 1 may satisfy condition B:

E(H_{B})_{S1}>E_{S1} Condition B

wherein, in condition B,
E(H_{B})_{S1} indicates a lowest excited singlet energy level of Host B, and
E_{S1} indicates a lowest excited singlet energy level of the heterocyclic compound represented by Formula 1.

In this regard, E(H_{B})_{S1} and E_{S1} may be evaluated by using a Gaussian program according to a density functional theory (DFT) method (wherein structure optimization is performed at a level of B3LYP and 6-31G(d,p)).

### Description of FIG. 4

According to one or more embodiments, the heterocyclic compound represented by Formula 1 is used as a fluorescence emitter, and the emission layer includes a sensitizer, specifically, a delayed fluorescence sensitizer. According to one or more embodiments, the emission layer may further include a host (hereinafter referred to as ‘host C’, and host C is not identical to the heterocyclic compound represented by Formula 1 or the sensitizer) and a sensitizer (hereinafter referred to as ‘sensitizer A’, and sensitizer A is not identical to host C or the heterocyclic compound represented by Formula 1). Host C and sensitizer A may respectively be understood by referring to the description of the host material and the sensitizer material as provided herein, but embodiments are not limited thereto.

According to one or more embodiments, among the total emission components emitted from the emission layer, the ratio of the emission components emitted from the heterocyclic compound represented by Formula 1 may be about 80% or more, for example, about 90% or more (for example, about 95% or more). For example, the heterocyclic compound represented by Formula 1 may emit fluorescence. In some embodiments, each of host C and sensitizer A may not emit a light.

Referring to FIG. 4, the energy transfer according to one or more embodiments will be described in detail.

Singlet and triplet excitons may be produced from host C in the emission layer, and singlet excitons and triplet excitons produced from host C may be transferred to sensitizer A and then to the heterocyclic compound represented by Formula 1 through FRET. The singlet excitons formed in host C at a ratio of 25% may be transferred to sensitizer A via FRET, and the energy of the triplet excitons formed in host C at a ratio of 75% may be transferred to the singlet and triplet excitons of sensitizer A. At least part of the energy of the singlet state of sensitizer A may be transferred to the triplet state by the ISC. The energy transferred to the triplet state of sensitizer A may be subjected to RISC to a singlet state, and then the singlet energy of sensitizer A may be transferred to the heterocyclic compound represented by Formula 1 through FRET.

Accordingly, by transferring all the singlet excitons and triplet excitons generated in the emission layer to the dopant (for example, an emitter), an organic light-emitting device having improved efficiency may be obtained. In addition, since an organic light-emitting device can be obtained with significantly reduced energy loss, the lifespan characteristics of the organic light-emitting device can be improved.

Referring to FIG. 4, when the emission layer further includes host C and sensitizer A in addition to the heterocyclic compound represented by Formula 1, host C and sensitizer A, and the heterocyclic compound represented by Formula 1 may satisfy conditions C-1 and/or C-2:

S₁(H_{C})≥S₁(S_{A}) Condition C-1

S₁(S_{A})≥S₁(HC) Condition C-2

wherein, in Conditions C-1 and C-2,
S₁(H_{C}) indicates a lowest excited singlet energy level of Host C,
S₁(S_{A}) indicates a lowest excited singlet energy level of Sensitizer A, and
S₁(HC) indicates a lowest excited singlet energy level of the heterocyclic compound represented by Formula 1.

S₁(H_{C}), S₁(S_{A}), and S₁(HC) may be evaluated using a Gaussian program according to a DFT method, wherein structure optimization is performed at a level of B3LYP and 6-31G(d,p).

When Host C, Sensitizer A, and the heterocyclic compound represented by Formula 1 satisfy Condition C-1 and/or C-2, FRET from Sensitizer A to the heterocyclic compound represented by Formula 1 may be facilitated, and accordingly, the organic light-emitting device may have improved luminescence efficiency.

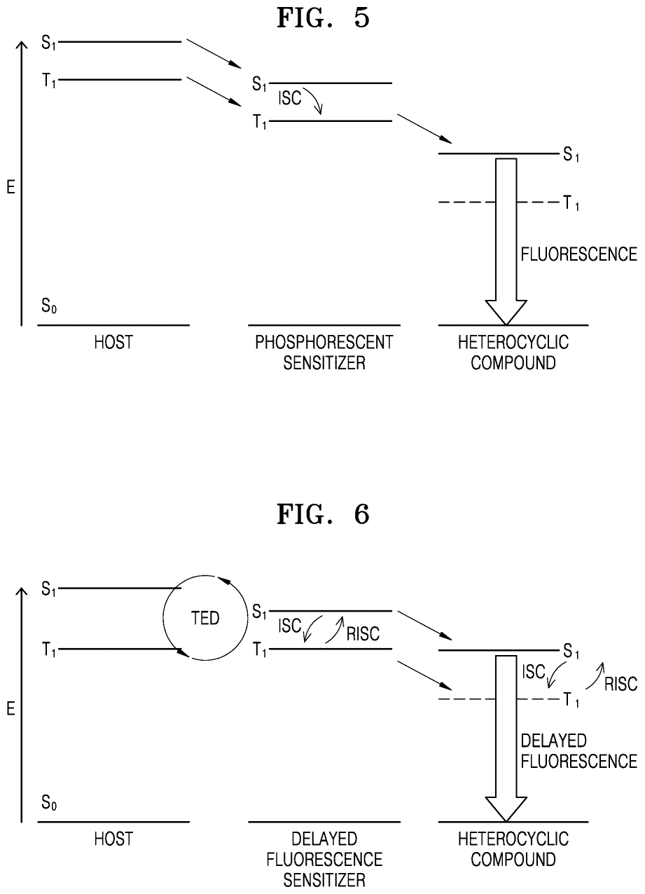

### Description of FIG. 5

According to one or more embodiments, the heterocyclic compound represented by Formula 1 may be used as a fluorescent emitter, and the emission layer may further include a sensitizer, specifically, a phosphorescent sensitizer.

According to one or more embodiments, the emission layer may further include a host (hereinafter referred to as ‘host D’, and host D is not identical to the heterocyclic compound represented by Formula 1 or the sensitizer) and a sensitizer (hereinafter referred to as ‘sensitizer B’, and sensitizer B is not identical to host D or the heterocyclic compound represented by Formula 1). Host D and sensitizer B may each be understood by referring to the description of the host material and the sensitizer material as provided herein, but embodiments are not limited thereto.

According to one or more embodiments, among the total emission components emitted from the emission layer, the ratio of the emission components emitted from the heterocyclic compound represented by Formula 1 may be about 80% or more, for example, about 90% or more (for example, about 95% or more). For example, the heterocyclic compound represented by Formula 1 may emit fluorescence. In some embodiments, the host and the sensitizer may each not emit a light.

Referring to FIG. 5, the energy transfer according to one or more embodiments will be described in detail.

75% of triplet excitons formed in host D in the emission layer may be transferred to sensitizer B through Dexter energy transfer, and the energy of 25% of singlet excitons formed in host D may be transferred to the singlet and triplet states of sensitizer B, among which the energy transferred to the singlet state of sensitizer B undergoes ISC to the triplet state, and then the triplet energy of sensitizer B may be transferred to the heterocyclic compound represented by Formula 1 through FRET.

Accordingly, by transferring all the singlet excitons and triplet excitons generated in the emission layer to the dopant (for example, an emitter), an organic light-emitting device having improved efficiency may be obtained. In addition, since an organic light-emitting device can be obtained with significantly reduced energy loss, the lifespan characteristics of the organic light-emitting device can be improved.

According to one or more embodiments, when the emission layer further includes host D and sensitizer B in addition to the heterocyclic compound represented by Formula 1, host D and sensitizer B, and the heterocyclic compound represented by Formula 1 may satisfy conditions D-1 and/or D-2:

T₁(H_{D})≥T₁(S_{B}) Condition D-1

T₁(S_{B})≥S₁(HC) Condition D-2

wherein, in Conditions D-1 and D-2,
T₁(H_{D}) indicates a lowest excited triplet energy level of Host D,
T₁(S_{B}) indicates a lowest excited triplet energy level of Sensitizer B, and
S₁(HC) indicates a lowest excited singlet energy level of the heterocyclic compound represented by Formula 1.

T₁(H_{D}), T₁(S_{B}), and S₁(HC) may be evaluated using a Gaussian program according to a DFT method, wherein structure optimization is performed at a level of B3LYP and 6-31G(d,p).

When host D, sensitizer B, and the heterocyclic compound represented by Formula 1 satisfy condition D-1 and/or D-2, FRET from sensitizer B to the heterocyclic compound represented by Formula 1 may be facilitated, and accordingly, the organic light-emitting device may have improved luminescence efficiency.

According to one or more embodiments, the amount of the sensitizer in the emission layer may be about 5 wt % to about 50 wt %, for example, about 10 wt % to about 30 wt %, based on total weight of the emission layer. When the amount is within these ranges, energy transfer in the emission layer may effectively occur. Thus, the organic light-emitting device may have high efficiency and/or long lifespan.

According to one or more embodiments, the amount of the heterocyclic compound represented by Formula 1 in the emission layer may be about 0.01 wt % to about 15 wt %, for example, within a range of about 0.05 wt % to about 3 wt %, each based on total weight of the emission layer, but embodiments are not limited thereto.

According to one or more embodiments, the heterocyclic compound represented by Formula 1 may further satisfy condition 5:

0 μs<T_{decay}(HC)<5 μs Condition 5

wherein, inn Condition 5,
T_{decay}(HC) indicates a decay time of the heterocyclic compound represented by Formula 1.

The decay time of the heterocyclic compound represented by Formula 1 is a value calculated from the time-resolved photoluminescence (TRPL) spectrum at room temperature for a 40 nm thick film (hereinafter referred to as “film (HC)”) obtained by vacuum co-depositing the host and the heterocyclic compound represented by Formula included in the emission layer at a weight ratio of 90:10 at a vacuum level of 10⁻⁷ torr on a quartz substrate.

### Description of FIG. 6

According to one or more embodiments, the heterocyclic compound represented by Formula 1 may be used as a delayed fluorescence emitter, and the emission layer may include a sensitizer, specifically, a delayed fluorescence sensitizer.

According to one or more embodiments, the emission layer may further include a host (hereinafter referred to as ‘host E’, and host E is not identical to the heterocyclic compound represented by Formula 1 or the sensitizer) and a sensitizer (hereinafter referred to as ‘sensitizer C’, and sensitizer C is not identical to host E or the heterocyclic compound represented by Formula 1). Host E and Sensitizer C may respectively be understood by referring to the description of the host material and the sensitizer material as provided herein, but embodiments are not limited thereto.

According to one or more embodiments, among the total emission components emitted from the emission layer, the ratio of the emission components emitted from the heterocyclic compound represented by Formula 1 may be about 80% or more, for example, about 90% or more (for example, about 95% or more). In some embodiments, the heterocyclic compound represented by Formula 1 may emit fluorescence and/or delayed fluorescence. In addition, Host E and Sensitizer C may not each emit a light.

In this regard, the heterocyclic compound represented by Formula 1 emits fluorescence and/or delayed fluorescence, and the emission component of the heterocyclic compound represented by Formula 1 is the sum of the prompt emission component of the heterocyclic compound represented by Formula 1 and the delayed fluorescence component by RISC of the heterocyclic compound represented by Formula 1.

Referring to FIG. 6, the energy transfer according to one or more embodiments will be described in detail.

25% of singlet excitons produced from host E in the emission layer may be transferred to a singlet state of Sensitizer C through FRET, and energy of 75% of triplet excitons produced from host E may be transferred to a triplet state of sensitizer C, and then singlet energy of sensitizer C may be transferred to the heterocyclic compound represented by Formula 1 through FRET. Subsequently, the triplet energy of sensitizer C may be transferred to the heterocyclic compound represented by Formula 1 through Dexter energy transfer. Among these, the energy transferred to the triplet state of sensitizer C may also be subjected to RISC to the singlet state. Additionally, in the case of sensitizer C, the energy of the triplet state formed in sensitizer C may be transferred backward to host E (triplet exciton distributing, TED) and then transferred back to the heterocyclic compound represented by Formula 1 to emit light through RISC.

Accordingly, by transferring all of the singlet excitons and triplet excitons generated in the emission layer to the dopant (for example, an emitter), an organic light-emitting device having improved efficiency may be obtained. In addition, since an organic light-emitting device can be obtained with significantly reduced energy loss, the lifespan characteristics of the organic light-emitting device can be improved.

According to one or more embodiments, when the emission layer further includes host E and sensitizer C in addition to the heterocyclic compound represented by Formula 1, host E and sensitizer C, and the heterocyclic compound represented by Formula 1 may satisfy conditions E-1, E-2, and/or E-3:

S₁(H_{E})≥S₁(S_{C}) Condition E-1

S₁(S_{C})≥S₁(HC) Condition E-2

T₁(S_{C})≥T₁(HC) Condition E-3

wherein, in Conditions E-1, E-2, and E-3,
S₁(H_{E}) indicates a lowest excited singlet energy level of Host E,
S₁(S_{C}) indicates a lowest excited singlet energy level of Sensitizer C,
S₁(HC) indicates a lowest excited singlet energy level of the heterocyclic compound represented by Formula 1,
T₁(S_{C}) indicates a lowest excited triplet energy level of Sensitizer C, and
T₁(HC) indicates a lowest excited triplet energy level of the heterocyclic compound represented by Formula 1.

S₁(H_{E}), S₁(S_{C}), S₁(HC), T₁(S_{C}), and T₁(HC) may be evaluated using a Gaussian program according to the DFT method, wherein structure optimization is performed at a level of B3LYP and 6-31G(d,p).

When host E, Sensitizer C, and the heterocyclic compound represented by Formula 1 satisfy condition E-1, E-2, and/or E-3, Dexter energy transfer and FRET from sensitizer C to the heterocyclic compound represented by Formula 1 may be facilitated, and accordingly, the organic light-emitting device may have improved luminescence efficiency.

According to one or more embodiments, the amount of the sensitizer in the emission layer may be about 5 wt % to about 50 wt %, for example, about 10 wt % to about 30 wt %, based on total weight of the emission layer. When the content is within this range, energy transfer in the emission layer may effectively occur. Thus, the organic light-emitting device may have high efficiency and/or long lifespan.

According to one or more embodiments, the amount of the heterocyclic compound represented by Formula 1 in the emission layer may be about 0.01 wt % to about 15 wt %, for example, about 0.05 wt % to about 3 wt %, based on total weight of the emission layer, but embodiments are not limited thereto.

### Host in Emission Layer

According to one or more embodiments, the host may not include metal atoms.

According to one or more embodiments, the host may include at least one of a fluorene-containing compound, a carbazole-containing compound, a dibenzofuran-containing compound, a dibenzothiophene-containing compound, an indenocarbazole-containing compound, an indolocarbazole-containing compound, a benzofurocarbazole-containing compound, a benzothienocarbazole-containing compound, an acridine-containing compound, a dihydroacridine-containing compound, a triindolobenzene-containing compound, a pyridine-containing compound, a pyrimidine-containing compound, a triazine-containing compound, a silicon-containing compound, a cyano group-containing compound, a phosphine oxide-containing compound, a sulfoxide-containing compound, or a sulfonyl-containing compound.

For example, the host may be a compound including at least one carbazole ring and at least one cyano group, or a phosphine oxide-containing compound.

According to one or more embodiments, the host may include one type of host. When the host includes one type of host, the one type of host may be a bipolar host, an electron-transporting host, or a hole-transporting host, which will be described herein.

According to one or more embodiments, the host may be a mixture of two or more different hosts. For example, the host may be a mixture of an electron-transporting host and a hole-transporting host, a mixture of two types of electron-transporting hosts different from each other, or a mixture of two types of hole-transporting hosts different from each other. The electron-transporting host and the hole-transporting host may be understood by referring to the related description as provided herein.

According to one or more embodiments, the host may include an electron-transporting host including at least one electron-transporting moiety and a hole-transporting host not including an electron-transporting moiety.

The electron-transporting moiety as used herein may be a cyano group, a π electron-deficient nitrogen-containing cyclic group, or a group represented by one of the following Formulae:

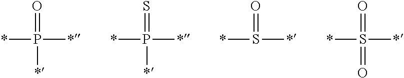

wherein, in the formulae above, *, *′, and *″ each indicate a binding site to a neighboring atom.

According to one or more embodiments, the electron-transporting host in the emission layer may include at least one of a cyano group or a π electron-deficient nitrogen-containing cyclic group.

According to one or more embodiments, the electron-transporting host in the emission layer may include at least one cyano group.

According to one or more embodiments, the electron-transporting host in the emission layer may include at least one cyano group and at least one π electron-deficient nitrogen-containing cyclic group.

According to one or more embodiments, the host may include an electron-transporting host and a hole-transporting host, wherein the electron-transporting host may include at least one π electron-deficient nitrogen-free cyclic group and at least one electron-transporting moiety, and the hole-transporting host may include at least one π electron-deficient nitrogen-free cyclic group and may not include an electron-transporting moiety.

The term “π electron-deficient nitrogen-containing cyclic group” as used herein refers to a cyclic group having at least one *—N═*′ moiety, and for example, may be an imidazole group, a pyrazole group, a thiazole group, an isothiazole group, an oxazole group, an isoxazole group, a pyridine group, a pyrazine group, a pyridazine group, a pyrimidine group, an indazole group, a purine group, a quinoline group, an isoquinoline group, a benzoquinoline group, a phthalazine group, a naphthyridine group, a quinoxaline group, a quinazoline group, a cinnoline group, a phenanthridine group, an acridine group, a phenanthroline group, a phenazine group, a benzimidazole group, an isobenzothiazole group, a benzoxazole group, an isobenzoxazole group, a triazole group, a tetrazole group, an oxadiazole group, a triazine group, a thiadiazole group, an imidazopyridine group, an imidazopyrimidine group, an azacarbazole group; or a condensed cyclic group in which two or more π electron-deficient nitrogen-containing cyclic groups are condensed with each other.

Meanwhile, the π electron-deficient nitrogen-free cyclic group may be a benzene group, a heptalene group, an indene group, a naphthalene group, an azulene group, an indacene group, an acenaphthylene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentacene group, a hexacene group, a pentaphene group, a rubicene group, a coronene group, an ovalene group, a pyrrole group, an isoindole group, an indole group, a furan group, a thiophene group, a benzofuran group, a benzothiophene group, a benzocarbazole group, a dibenzocarbazole group, a dibenzofuran group, a dibenzothiophene group, a dibenzothiophene sulfone group, a carbazole group, a dibenzosilole group, an indenocarbazole group, an indolocarbazole group, a benzofurocarbazole group, a benzothienocarbazole group, a triindolobenzene group; or a condensed cyclic group of two or more π electron-deficient nitrogen-free cyclic groups that are condensed with each other, but embodiments are not limited thereto.

According to one or more embodiments, when the host is a mixture of an electron-transporting host and a hole-transporting host, the weight ratio of the electron-transporting host to the hole-transporting host may be about 1:9 to 9:1, about 2:8 to 8:2, about 3:7 to 7:3, about 4:6 to 6:4, or about 5:5. When the weight ratio of the electron transport host and the hole transport host satisfies the above-described ranges, the hole-and-electron transport balance in the emission layer may be made.

The host may include at least one of 1,3,5-tri(1-phenyl-1H-benzo[d]imidazol-2-yl)benzene (TPBi), 3-tert-butyl-9,10-di(naphth-2-yl)anthracene (TBADN), 9,10-di(naphth-2-yl)anthracene (ADN) (also referred to as “DNA”), 4,4′-bis(N-carbazolyl)-1,1′-biphenyl (CBP), 4,4′-bis(9-carbazolyl)-2,2′-dimethyl-biphenyl (CDBP), 1,3,5-tris(carbazol-9-yl)benzene (TCP), 1,3-bis(N-carbazolyl)benzene (mCP), Compound H50, or Compound H51, but embodiments are not limited thereto:

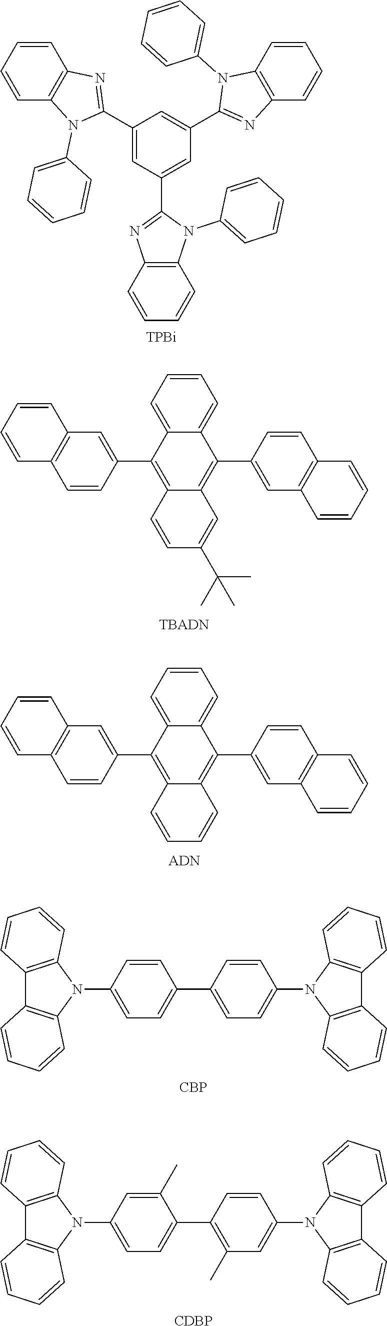

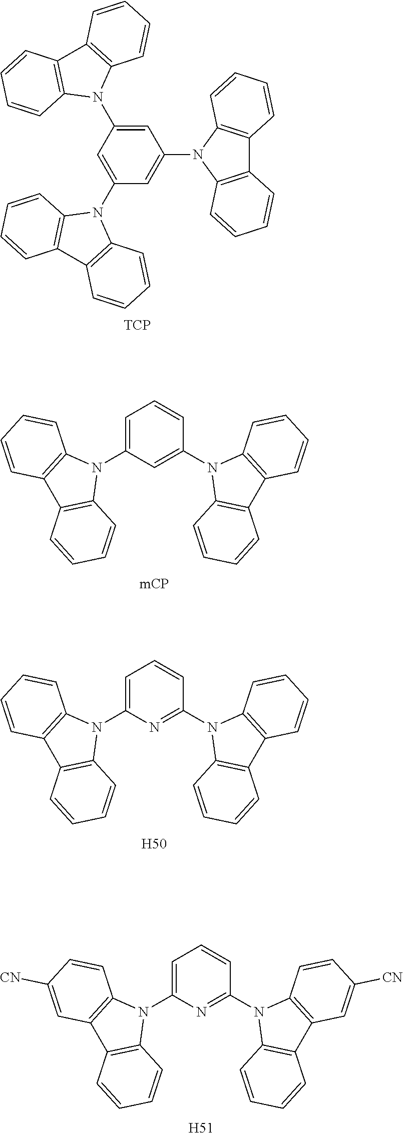

In one or more embodiments, the host may further include a compound represented by Formula 301, but embodiments are not limited thereto:

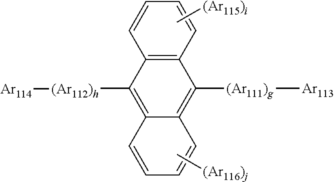

wherein Ar₁₁₁ and Ar₁₁₂ in Formula 301 may each independently be:
a phenylene group, a naphthylene group, a phenanthrenylene group, or a pyrenylene group; or
a phenylene group, a naphthylene group, a phenanthrenylene group, or a pyrenylene group, each substituted with at least one of a phenyl group, a naphthyl group, or an anthracenyl group.

Ar₁₁₃ to Ar₁₁₆ in Formula 301 may each independently be:
a C₁-C₁₀ alkyl group, a phenyl group, a naphthyl group, a phenanthrenyl group, or a pyrenyl group; or
a phenyl group, a naphthyl group, a phenanthrenyl group, or a pyrenyl group, each substituted with at least one of a phenyl group, a naphthyl group, or an anthracenyl group.

g, h, i, and j in Formula 301 may each independently be an integer from 0 to 4, and may be, for example, 0, 1, or 2.

Ar₁₁₃ to Ar₁₁₆ in Formula 301 may each independently be:
a C₁-C₁₀ alkyl group, substituted with at least one of a phenyl group, a naphthyl group, or an anthracenyl group;
a phenyl group, a naphthyl group, an anthracenyl group, a pyrenyl, a phenanthrenyl group, or a fluorenyl group;
a phenyl group, a naphthyl group, an anthracenyl group, a pyrenyl group, a phenanthrenyl group, or a fluorenyl group, each substituted with deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a phenyl group, a naphthyl group, an anthracenyl group, a pyrenyl group, a phenanthrenyl group, a fluorenyl group, or a combination thereof; or

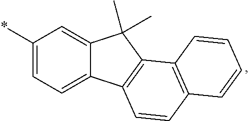 [SMILES: *c1ccc2c(c1)C(C)(C)c1c-2ccc2ccccc12]

but embodiments are not limited thereto.

In one or more embodiments, the host may include a compound represented by Formula 302, but embodiments are not limited thereto:

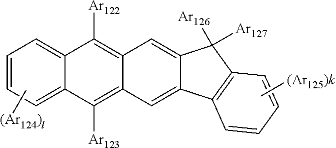

wherein Ar₁₂₂ to Ar₁₂₅ in Formula 302 are defined the same as defined for Ar₁₁₃ in Formula 301.

Ar₁₂₆ and Ar₁₂₇ in Formula 302 may each independently be a C₁-C₁₀ alkyl group (for example, a methyl group, an ethyl group, a propyl group, or the like).

k and l in Formula 302 may each independently be an integer from 0 to 4. For example, k and l may each independently be 0, 1, or 2.

According to one or more embodiments, the host may include at least one compound from H1 to H26, but embodiments are not limited thereto:

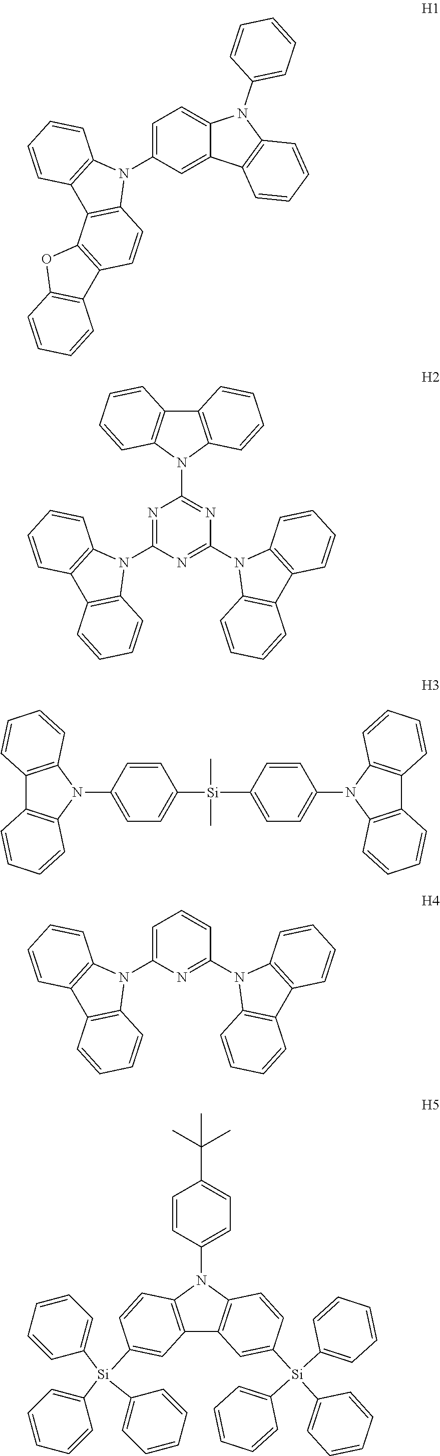 [SMILES: c1ccc(-n2c3ccccc3c3cc(-n4c5ccccc5c5c6oc7ccccc7c6ccc54)ccc32)cc1 ; c1ccc2c(c1)c1ccccc1n2-c1nc(-n2c3ccccc3c3ccccc32)nc(-n2c3ccccc3c3ccccc32)n1 ; C[Si](C)(c1ccc(-n2c3ccccc3c3ccccc32)cc1)c1ccc(-n2c3ccccc3c3ccccc32)cc1 ; c1cc(-n2c3ccccc3c3ccccc32)nc(-n2c3ccccc3c3ccccc32)c1 ; CC(C)(C)c1ccc(-n2c3ccc([Si](c4ccccc4)(c4ccccc4)c4ccccc4)cc3c3cc([Si](c4ccccc4)(c4ccccc4)c4ccccc4)ccc32)cc1]

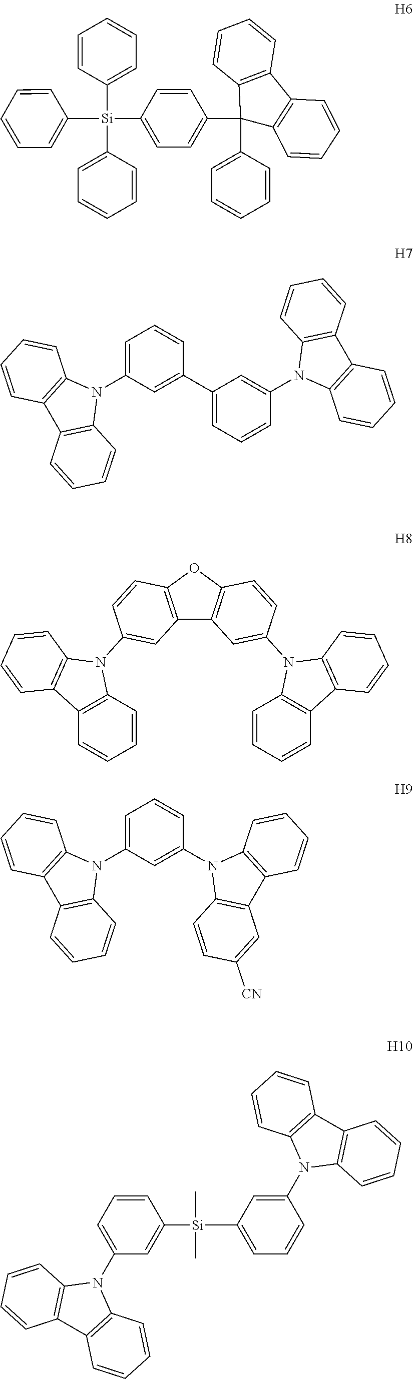 [SMILES: c1ccc(C2(c3ccc([Si](c4ccccc4)(c4ccccc4)c4ccccc4)cc3)c3ccccc3-c3ccccc32)cc1 ; c1cc(-c2cccc(-n3c4ccccc4c4ccccc43)c2)cc(-n2c3ccccc3c3ccccc32)c1 ; c1ccc2c(c1)c1ccccc1n2-c1ccc2oc3ccc(-n4c5ccccc5c5ccccc54)cc3c2c1 ; N#Cc1ccc2c(c1)c1ccccc1n2-c1cccc(-n2c3ccccc3c3ccccc32)c1 ; C[Si](C)(c1cccc(-n2c3ccccc3c3ccccc32)c1)c1cccc(-n2c3ccccc3c3ccccc32)c1]

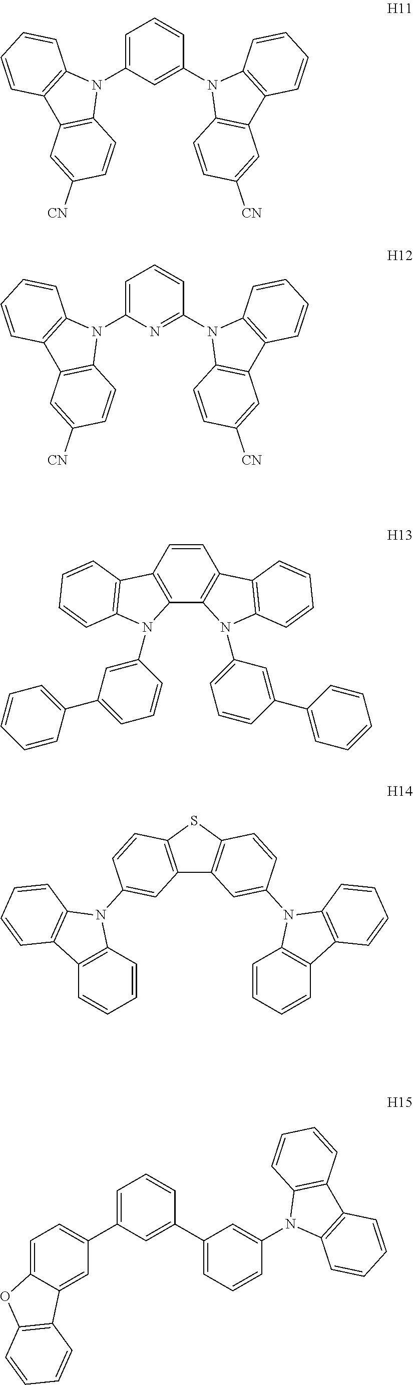

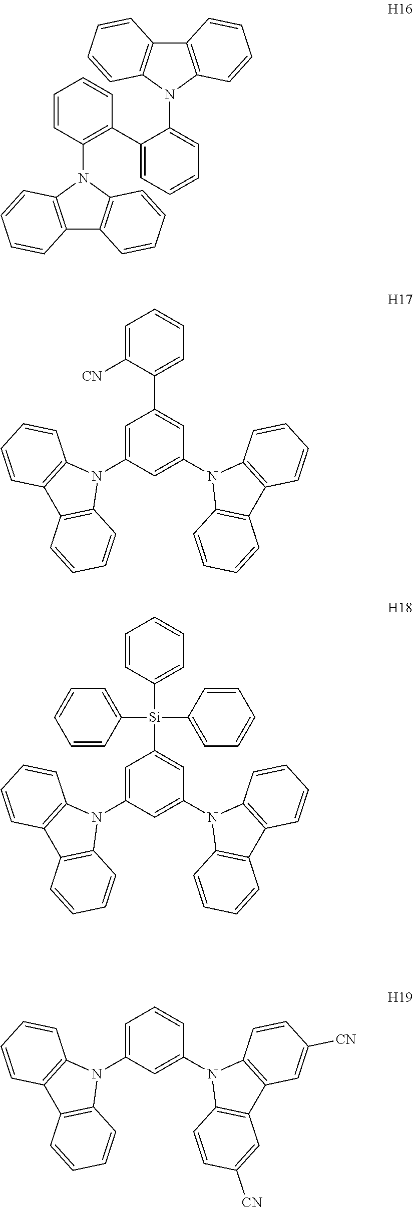

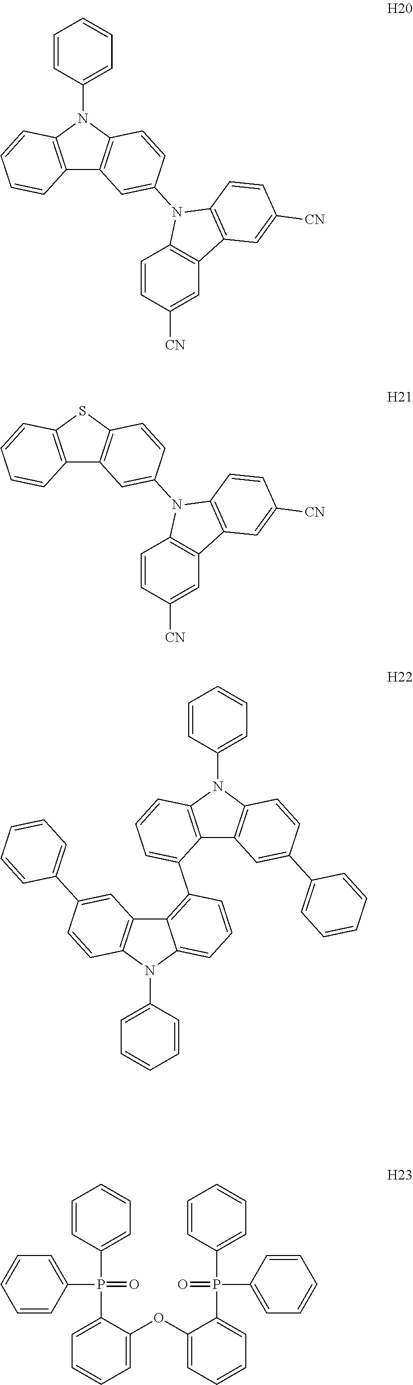 [SMILES: N#Cc1ccc2c(c1)c1cc(C#N)ccc1n2-c1ccc2c(c1)c1ccccc1n2-c1ccccc1 ; N#Cc1ccc2c(c1)c1cc(C#N)ccc1n2-c1ccc2sc3ccccc3c2c1 ; c1ccc(-c2ccc3c(c2)c2c(-c4cccc5c4c4cc(-c6ccccc6)ccc4n5-c4ccccc4)cccc2n3-c2ccccc2)cc1 ; O=P(c1ccccc1)(c1ccccc1)c1ccccc1Oc1ccccc1P(=O)(c1ccccc1)c1ccccc1]

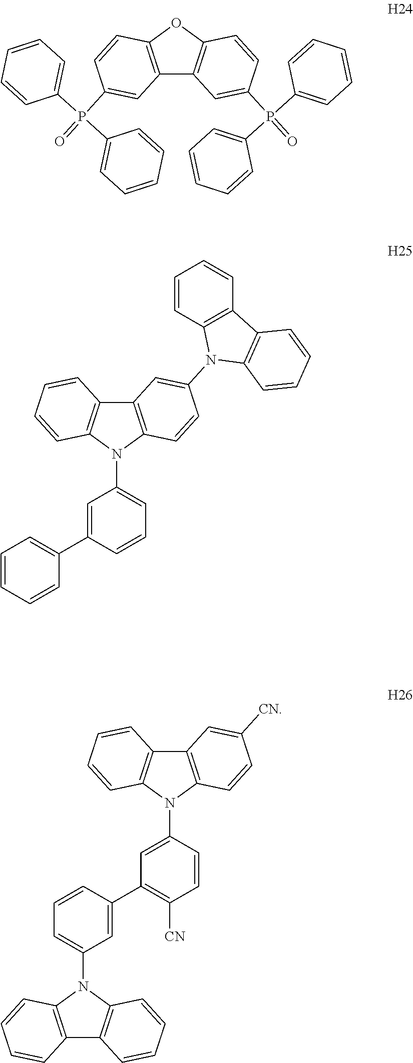 [SMILES: O=P(c1ccccc1)(c1ccccc1)c1ccc2oc3ccc(P(=O)(c4ccccc4)c4ccccc4)cc3c2c1 ; c1ccc(-c2cccc(-n3c4ccccc4c4cc(-n5c6ccccc6c6ccccc65)ccc43)c2)cc1 ; N#Cc1ccc2c(c1)c1ccccc1n2-c1ccc(C#N)c(-c2cccc(-n3c4ccccc4c4ccccc43)c2)c1]

According to one or more embodiments, the host may consist of one type of compound. For example, the one type of compound may be arbitrarily selected from a first material (hole-transporting host) or a second material (electron-transporting host) described above.

According to one or more embodiments, the host may include two or more compounds. For example, the host may include two or more different hole-transporting hosts, two or more different electron-transporting hosts, or a combination of one or more hole-transporting hosts and one or more electron-transporting hosts.

### Emitter in the Emission Layer

The emitter may include the heterocyclic compound represented by Formula 1.

### Sensitizer in the Emission Layer

According to one or more embodiments, the sensitizer may include a phosphorescent compound.

According to one or more embodiments, the phosphorescent compound may include an organometallic compound including one or more metals.

According to one or more embodiments, the organometallic compound may include at least one metal (M₁₁) selected from transition metals, and an organic ligand (L₁₁), and L₁₁ and M₁₁ may form 1, 2, 3 or 4 cyclometallated rings.

According to one or more embodiments, the organometallic compound may be represented by Formula 101.

M₁₁(L₁₁)ₙ₁₁(L₁₂)ₙ₁₂ Formula 101

wherein, in Formula 101,
M₁₁ may be a transition metal,
L₁₁ may be a ligand represented by any one of Formulae 1-1 to 1-4;
L₁₂ may be a monodentate ligand or a bidentate ligand,
n11 may be 1, and
n12 may be 0, 1, or 2,

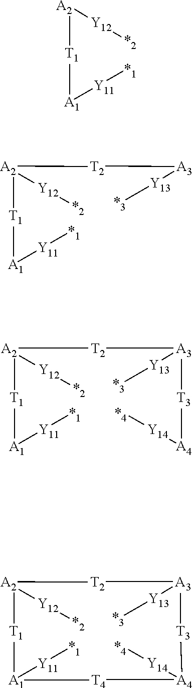

wherein, in Formulae 1-1 to 1-4,
A₁ to A₄ may each independently be a substituted or unsubstituted C₅-C₃₀ carbocyclic group, a substituted or unsubstituted C₁-C₃₀ heterocyclic group, or a non-cyclic group,
Y₁₁ to Y₁₄ may each independently be a chemical bond, O, S, N(R₉₁), B(R₉₁), P(R₉₁), or C(R₉₁)(R₉₂),
T₁ to T₄ may each independently be a single bond, a double bond, *—N(R₉₃)—*′, *—B(R₉₃)—*′, *—P(R₉₃)—*′, *—C(R₉₃)(R₉₄)—*′, *—Si(R₉₃)(R₉₄)—*′, *—Ge(R₉₃)(R₉₄)—*′, *—S—*′, *—Se—*′, *—O—*′, *—C(═O)*′, *—S(═O)—*′, *—S(═O)₂—*′, *—C(R₉₃)═*′, *═C(R₉₃)—*′, *—C(R₉₃)═C(R₉₄)—*′, *—C(═S)—*′, or *—C≡C—*′,
a substituent of the substituted C₅-C₃₀ carbocyclic group, a substituent of the substituted C₁-C₃₀ heterocyclic group, and R₉₁ to R₉₄ may each independently be hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent aromatic condensed polycyclic group, a substituted or unsubstituted monovalent aromatic condensed heteropolycyclic group, a substituted or unsubstituted monovalent non-aromatic condensed polycyclic group, a substituted or unsubstituted monovalent non-aromatic condensed heteropolycyclic group, —Si(Q₁)(Q₂)(Q₃), —Ge(Q₁)(Q₂)(Q₃), —C(Q₁)(Q₂)(Q₃), —B(Q₁)(Q₂), —N(Q₁)(Q₂), —C(═O)(Q₁), —S(═O)(Q₁), —S(═O)₂(Q₁), —P(Q₁)(Q₂), —P(═O)(Q₁)(Q₂), or —P(═S)(Q₁)(Q₂), wherein the substituent of the substituted C₅-C₃₀ carbocyclic group and the substituent of the substituted C₁-C₃₀ heterocyclic group is not hydrogen,
*₁, *₂, *₃, and *₄ each indicate a binding site to M₁₁, and
Q₁ to Q₃ may each independently be hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₇-C₆₀ aryl alkyl group, a C₆-C₆₀ aryloxy group, a C₆-C₆₀ arylthio group, a C₁-C₆₀ heteroaryl group, a C₂-C₆₀ alkyl heteroaryl group, a C₂-C₆₀ heteroaryl alkyl group, a C₂-C₆₀ alkyl heteroaryl group, a C₂-C₆₀ heteroaryl alkyl group, a monovalent non-aromatic condensed polycyclic group, or a monovalent non-aromatic condensed heteropolycyclic group; or
a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₇-C₆₀ aryl alkyl group, a C₆-C₆₀ aryloxy group, a C₆-C₆₀ arylthio group, a C₁-C₆₀ heteroaryl group, a C₂-C₆₀ alkyl heteroaryl group, a C₂-C₆₀ heteroaryl alkyl group, a C₁-C₆₀ heteroaryloxy group, a C₁-C₆₀ heteroarylthio group, a monovalent non-aromatic condensed polycyclic group, or a monovalent non-aromatic condensed heteropolycyclic group, each substituted with deuterium, —F, —Cl, —Br, —I, —SF₅, a hydroxyl group, a cyano group, a C₁-C₆₀ alkyl group, a C₆-C₆₀ aryl group, a C₁-C₆₀ heteroaryl group, a monovalent non-aromatic condensed heteropolycyclic group, a monovalent non-aromatic condensed heteropolycyclic group, or a combination thereof.

According to one or more embodiments, the transition metal may be platinum (Pt), palladium (Pd), gold (Au), iridium (Ir), osmium (Os), titanium (Ti), zirconium (Zr), hafnium (Hf), europium (Eu), terbium (Tb), thulium (Tm), or rhodium (Rh).

According to one or more embodiments, the sensitizer may include a delayed fluorescence compound.

According to one or more embodiments, the delayed fluorescent compound may be represented by Formulae 101 or 102.

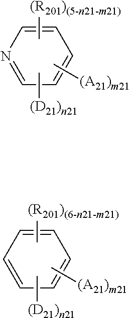

wherein, in Formulae 101 and 102,
A₂₁ is an acceptor group,
D₂₁ is a donor group,
m21 may be 1, 2, or 3, n21 may be 1, 2, or 3,
a sum of n21 and m21 in Formula 101 may be 5 or less, and a sum of n21 and m21 in Formula 102 may be 6 or less,
R₂₀₁ may be hydrogen, deuterium, —F, —Cl, —Br, —I, —SF₅, a hydroxyl group, a cyano group, a nitro group, an amino group, an amidino group, a hydrazino group, a hydrazono group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent non-aromatic condensed heteropolycyclic group, a substituted or unsubstituted monovalent non-aromatic condensed heteropolycyclic group, —Si(Q₁)(Q₂)(Q₃), —Ge(Q₁)(Q₂)(Q₃), —C(Q₁)(Q₂)(Q₃), —B(Q₁)(Q₂), —N(Q₁)(Q₂), —C(═O)(Q₁), —S(═O)(Q₁), —S(═O)₂(Q₁), —P(Q₁)(Q₂), —P(═O)(Q₁)(Q₂), or —P(═S)(Q₁)(Q₂), and a plurality of R₂₀₁ may optionally be bonded to each other to form a substituted or unsubstituted C₅-C₃₀ carbocyclic group or a substituted or unsubstituted C₁-C₃₀ heterocyclic group, and
Q₁ to Q₃ may each independently be hydrogen, deuterium, —F, —Cl, —Br, —I, —SF₅, a hydroxyl group, a cyano group, a nitro group, an amino group, an amidino group, a hydrazino group, a hydrazono group, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₇-C₆₀ aryl alkyl group, a C₆-C₆₀ aryloxy group, a C₆-C₆₀ arylthio group, a C₁-C₆₀ heteroaryl group, a C₂-C₆₀ alkyl heteroaryl group, a C₂-C₆₀ heteroaryl alkyl group, a C₁-C₆₀ heteroaryloxy group, a C₁-C₆₀ heteroarylthio group, a monovalent aromatic condensed polycyclic group, a monovalent aromatic condensed heteropolycyclic group, a monovalent non-aromatic condensed polycyclic group, a monovalent non-aromatic condensed heteropolycyclic group, a C₁-C₆₀ alkyl group that is substituted with at least one of deuterium, —F, a cyano group, a C₁-C₆₀ alkyl group, or a C₆-C₆₀ aryl group; or a C₆-C₆₀ aryl group that is substituted with at least one of deuterium, —F, a cyano group, a C₁-C₆₀ alkyl group, or a C₆-C₆₀ aryl group.

According to one or more embodiments, in Formulae 101 and 102, D21 may be a substituted or unsubstituted electron-deficient nitrogen-free cyclic group.

In one or more embodiments, the π electron-deficient nitrogen-free cyclic group may be a benzene group, a heptalene group, an indene group, a naphthalene group, an azulene group, an indacene group, an acenaphthylene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentacene group, a hexacene group, a pentacene group, a rubicene group, a coronene group, an ovalene group, a pyrrole group, an isoindole group, an indole group, a furan group, a thiophene group, a benzofuran group, a benzothiophene group, a benzocarbazole group, a dibenzocarbazole group, a dibenzofuran group, a dibenzothiophene group, a dibenzothiophene sulfone group, a carbazole group, a dibenzosilole group, an indenocarbazole group, an indolocarbazole group, a benzofurocarbazole group, a benzothienocarbazole group, a triindolobenzene group; or a condensed cyclic group of two or more π electron-deficient nitrogen-free cyclic groups, but embodiments are not limited thereto.

For example, A₂₁ in Formulae 101 and 102 may be
—F, a cyano group, or a π electron-deficient nitrogen-containing cyclic group;
a C₁-C₆₀ alkyl group, an π electron-deficient nitrogen-containing cyclic group, or an π electron-deficient nitrogen-free cyclic group, each substituted with at least one of —F or a cyano group; or
an π electron deficient nitrogen-containing cyclic group substituted with at least one of deuterium, a C₁-C₆₀ alkyl group, an π electron deficient nitrogen-containing cyclic group, or an π electron-deficient nitrogen-free cyclic group.

In one or more embodiments, the π electron-deficient nitrogen-free cyclic group is the same as described above.

The term “π electron-deficient nitrogen-containing cyclic group” used herein refers to a cyclic group having at least one *—N═*′ moiety, and, for example, may be an imidazole group, a pyrazole group, a thiazole group, an isothiazole group, an oxazole group, an isoxazole group, a pyridine group, a pyrazine group, a pyridazine group, a pyrimidine group, an indazole group, a purine group, a quinoline group, an isoquinoline group, a benzoquinoline group, a phthalazine group, a naphthyridine group, a quinoxaline group, a quinazoline group, a cinnoline group, a phenanthridine group, an acridine group, a phenanthroline group, a phenazine group, a benzimidazole group, an isobenzothiazole group, a benzoxazole group, an isobenzoxazole group, a triazole group, a tetrazole group, an oxadiazole group, a triazine group, a thiadiazole group, an imidazopyridine group, an imidazopyrimidine group, an azacarbazole group, a benzimidazolobenzimidazole group; or a condensed cyclic group in which two or more π electron-deficient nitrogen-containing cyclic groups are condensed with each other.

According to one or more embodiments, the amount of the sensitizer in the organic layer (e.g. an emission layer) may be greater than the amount of the emitter in the organic layer (e.g. an emission layer). For example, the volume ratio of the sensitizer to the emitter may be about 30:0.1 to about 10:3, or about 10:0.1 to about 20:5. In some embodiments, the weight ratio of the sensitizer to the emitter may be about 10:0.1 to about 20:5. In some embodiments, the volume ratio of the host to the sensitizer in the organic layer (e.g. an emission layer) may be about 60:40 to about 95:5 or about 70:30 to about 90:10. In some embodiments, the weight ratio of the host to the sensitizer may be from about 60:40 to about 95:5. Within these amount ranges as described above, the organic light-emitting device may have improved luminescence efficiency and/or lifespan characteristics.

FIG. 1 is a schematic cross-sectional view of an organic light-emitting device 10 according to one or more embodiments. Hereinafter, the structure and manufacturing method of the organic light-emitting device 10 according to one or more embodiments will be described with reference to FIG. 1. The organic light-emitting device 10 may have a structure in which a first electrode 11, an organic layer 15, and a second electrode 19 are sequentially stacked.

A substrate may be further disposed under the first electrode 11 or on the second electrode 19. The substrate may be a substrate commonly used in organic light-emitting devices, e.g., a glass substrate or a transparent plastic substrate, which have excellent mechanical strength, thermal stability, transparency, surface smoothness, ease of handling, and/or water repellency.

The first electrode 11 may be formed by, for example, depositing or sputtering, onto the substrate, a material for forming the first electrode 11. The first electrode 11 may be an anode. The material for forming the first electrode 11 may be selected from materials with a high work function for easy hole injection. The first electrode 11 may be a reflective electrode, a transflective electrode, or a transmissive electrode. The material for forming the first electrode 11 may be indium tin oxide (ITO), indium zinc oxide (IZO), tin oxide (SnO₂), or zinc oxide (ZnO). In one or more embodiments, the material for forming the first electrode 11 may be a metal, such as magnesium (Mg), aluminum (Al), silver (Ag), aluminum-lithium (Al—Li), calcium (Ca), magnesium-indium (Mg—In), or magnesium-silver (Mg—Ag).

The first electrode 11 may have a single-layered structure or a multi-layered structure including two or more layers. For example, the first electrode 11 may have a three-layered structure of ITO/Ag/ITO, but the structure of the first electrode 11 is not limited thereto.

The organic layer 15 may be disposed on the first electrode 11.

The organic layer 15 may include an emission layer, and may further include a hole transport region and an electron transport region.

The hole transport region may be disposed between the first electrode 11 and the emission layer.

The hole transport region may include a hole injection layer, a hole transport layer, an electron-blocking layer, a buffer layer, or a combination thereof.

The hole transport region may include only either a hole injection layer or a hole transport layer. In one or more embodiments, the hole transport region may have a hole injection layer/hole transport layer structure or a hole injection layer/hole transport layer/electron-blocking layer structure, or a hole injection layer/a first hole transport layer/a second hole transport layer/electron-blocking layer structure, in which respective layers of each structure are sequentially stacked in the stated order from the first electrode 11.

When the hole transport region includes a hole injection layer, the hole injection layer may be formed on the first electrode 11 by using various methods, for example, vacuum deposition, spin coating, casting, and/or Langmuir-Blodgett (LB) deposition, but embodiments are not limited thereto.

When the hole injection layer is formed by a vacuum deposition method, deposition conditions may vary depending on a compound used as a material for forming the hole injection layer, a structure and thermal characteristics of the desired hole injection layer, and the like. For example, a deposition temperature may be about 100° C. to about 500° C., a vacuum degree may be about 10⁻⁸ torr to about 10⁻³ torr, and a deposition rate may be about 0.01 angstroms per second (Å/sec) to about 100 Å/sec, but embodiments are not limited thereto.

When the hole injection layer is formed by spin coating, the coating conditions may vary according to a compound that is used as a material for forming the hole injection layer, and the structure and thermal characteristics of the hole injection layer, and may include a coating speed of about 2,000 revolutions per minute (rpm) to about 5,000 rpm and a heat treatment temperature for removing a solvent after coating of about 80° C. to about 200° C. However, the coating conditions are not limited thereto.

The conditions for forming the hole transport layer and the electron-blocking layer may be referred to the description provided for the conditions for forming the hole injection layer.

The hole transport region may include at least one of 4,4′,4″-tris(3-methylphenylphenylamino)triphenylamine (m-MTDATA), 4,4′,4″-tris(N,N-diphenylamino)triphenylamine (TDATA), 4,4′,4″-tris{N-(2-naphthyl)-N-phenylamino}-triphenylamine (2-TNATA), N,N′-di(1-naphthyl)-N,N′-diphenylberizidine (NPB), p-NPB, N,N′-bis(3-methylphenyl)-N,N′-diphenyl-[1,1-biphenyl]-4,4′-diarnine (TPD), Spiro-TPD, Spiro-NPB, methylated NPB, 4,4′-cyclohexylidene bis[N,N-bis(4-methylphenyl)benzenamine](TAPC), 4,4′-bis[N,N′-(3-tolyl)amino]-3,3′-dimethylbiphenyl (HMTPD), 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate) (PANI/PSS), a compound represented by Formula 201, or a compound represented by Formula 202, but embodiments are not limited thereto:

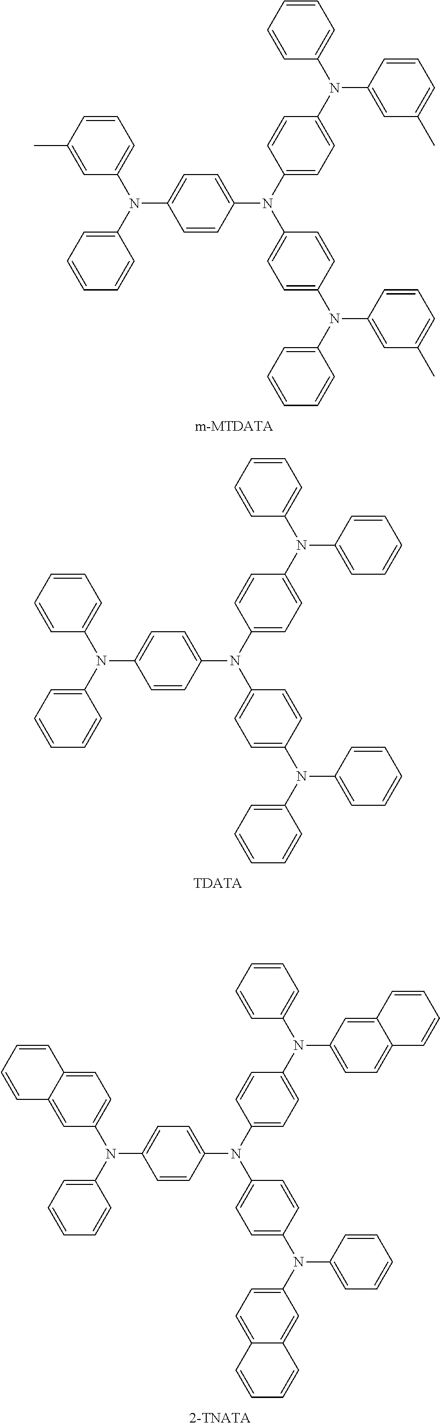

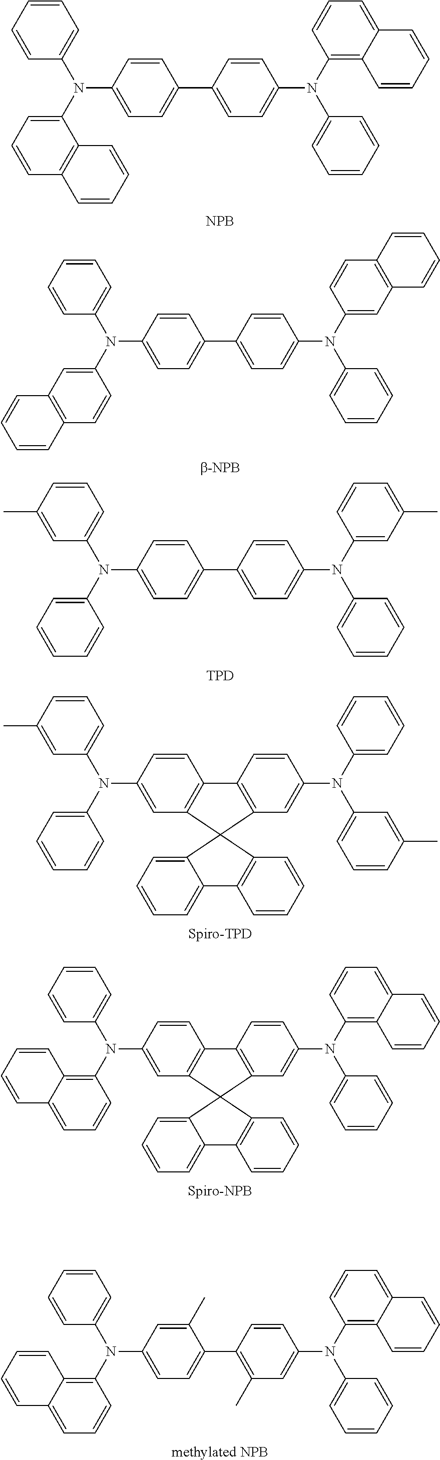

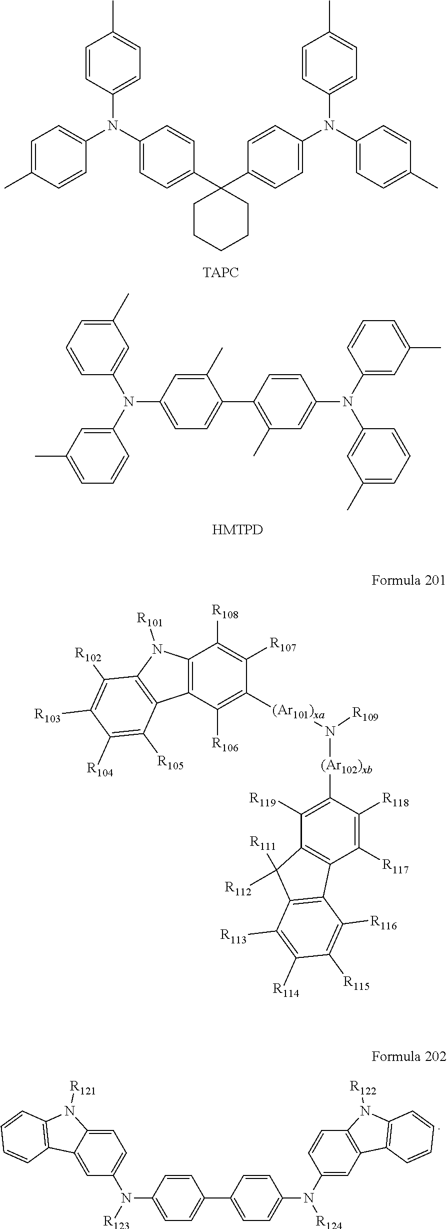

Ar₁₀₁ and Ar₁₀₂ in Formula 201 may each independently be:
a phenylene group, a pentalenylene group, an indenylene group, a naphthylene group, an azulenylene group, a heptalenylene group, an acenaphthenylene group, a fluorenylene group, a phenalenylene group, a phenanthrenylene group, an anthracenylene group, a fluoranthenylene group, a triphenylenylene group, a pyrenylene group, a chrysenylenylene group, a naphthacenylene group, a picenylene group, a perylenylene group, or a pentacenylene group; or
a phenylene group, a pentalenylene group, an indenylene group, a naphthylene group, an azulenylene group, a heptalenylene group, an acenaphthenylene group, a fluorenylene group, a phenalenylene group, a phenanthrenylene group, an anthracenylene group, a fluoranthenylene group, a triphenylenylene group, a pyrenylene group, a chrysenylenylene group, a naphthacenylene group, a picenylene group, a perylenylene group, or a pentacenylene group, each substituted with at least one of deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₃-C₁₀ cycloalkenyl group, a C₁-C₁₀ heterocycloalkyl group, a C₁-C₁₀ heterocycloalkenyl group, a C₆-C₆₀ aryl group, a C₇-C₆₀ alkyl aryl group, a C₇-C₆₀ aryl alkyl group, a C₆-C₆₀ aryloxy group, a C₆-C₆₀ arylthio group, a C₁-C₆₀ heteroaryl group, a C₂-C₆₀ alkyl heteroaryl group, a C₂-C₆₀ heteroaryl alkyl group, a C₁-C₆₀ heteroaryloxy group, a C₁-C₆₀ heteroarylthio group, a monovalent non-aromatic condensed polycyclic group, a monovalent non-aromatic condensed heteropolycyclic group, or a combination thereof.

xa and xb in Formula 201 may each independently be an integer from 0 to 5, or 0, 1, or 2. For example, xa may be 1, and xb may be 0, but xa and xb are not limited thereto.

R₁₀₁ to R₁₀₈, R₁₁₁ to R₁₁₉, and R₁₂₁ to R₁₂₄ in Formulae 201 and 202 may each independently be:
hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group (e.g., a methyl group, an ethyl group, a propyl group, a butyl group, pentyl group, or a hexyl group), a C₁-C₁₀ alkoxy group (e.g., a methoxy group, an ethoxy group, a propoxy group, a butoxy group, or a pentoxy group), or a C₁-C₁₀ alkylthio group;
a C₁-C₁₀ alkyl group, a C₁-C₁₀ alkoxy group, or a C₁-C₁₀ alkylthio group, each substituted with deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, or a combination thereof;
a phenyl group, a naphthyl group, an anthracenyl group, a fluorenyl group, or a pyrenyl group; or
a phenyl group, a naphthyl group, an anthracenyl group, a fluorenyl group, or a pyrenyl group, each substituted with deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a C₁-C₁₀ alkoxy group, a C₁-C₁₀ alkylthio group, or a combination thereof, but embodiments are not limited thereto.

R₁₀₉ in Formula 201 may be:
a phenyl group, a naphthyl group, an anthracenyl group, or a pyridinyl group; or
a phenyl group, a naphthyl group, an anthracenyl group, or a pyridinyl group, each substituted with deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a C₁-C₂₀ alkylthio group, a phenyl group, a naphthyl group, an anthracenyl group, a pyridinyl group, or a combination thereof.

In one or more embodiments, the compound represented by Formula 201 may be represented by Formula 201A, but embodiments are not limited thereto:

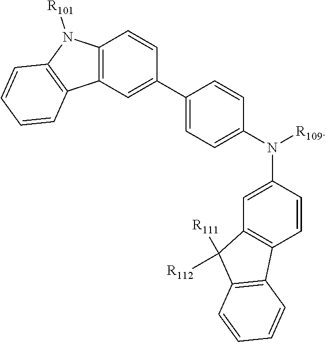

R₁₀₁, R₁₁₁, R₁₁₂, and R₁₀₉ in Formula 201A may each be as described herein.

For example, the compound represented by Formula 201 and the compound represented by Formula 202 may include, but are not limited to, one of compounds HT1 to HT20:

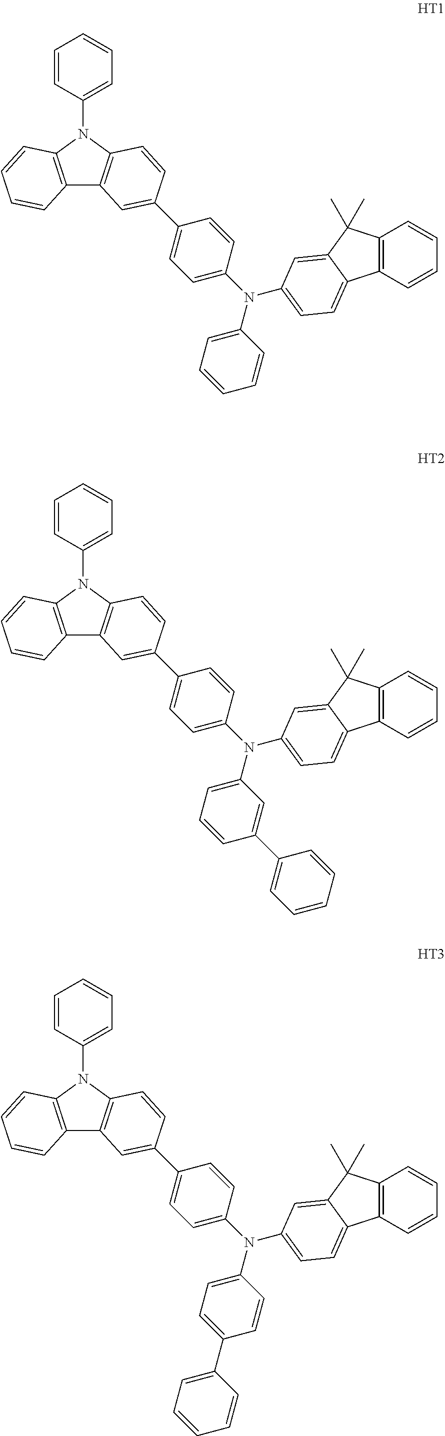 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

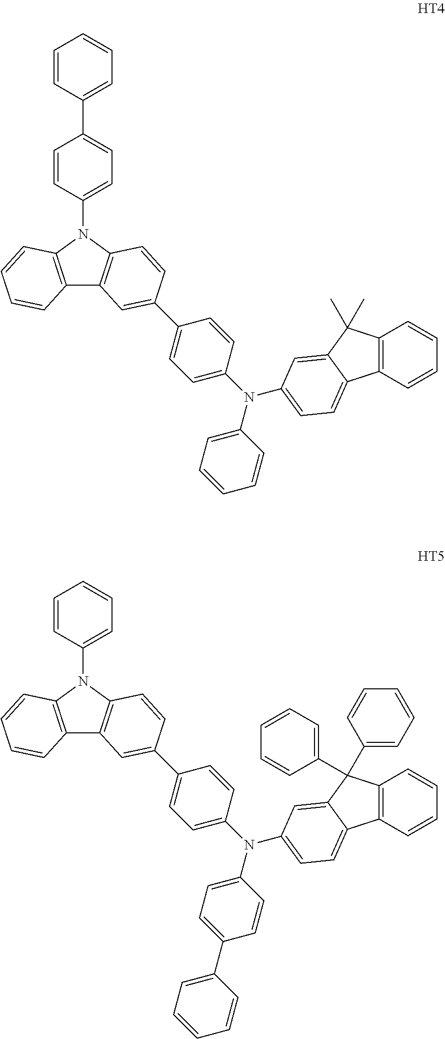 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

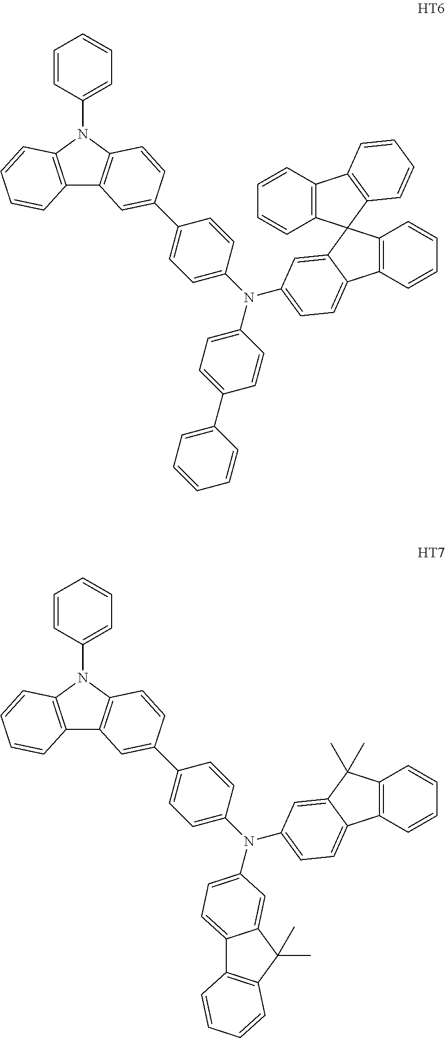 [SMILES: c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21]

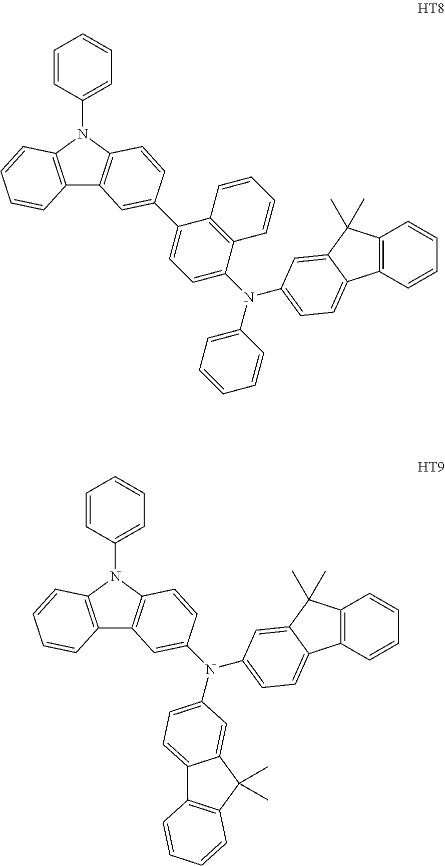 [SMILES: CC1(C)c2ccccc2-c2ccc(N(c3ccccc3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21]

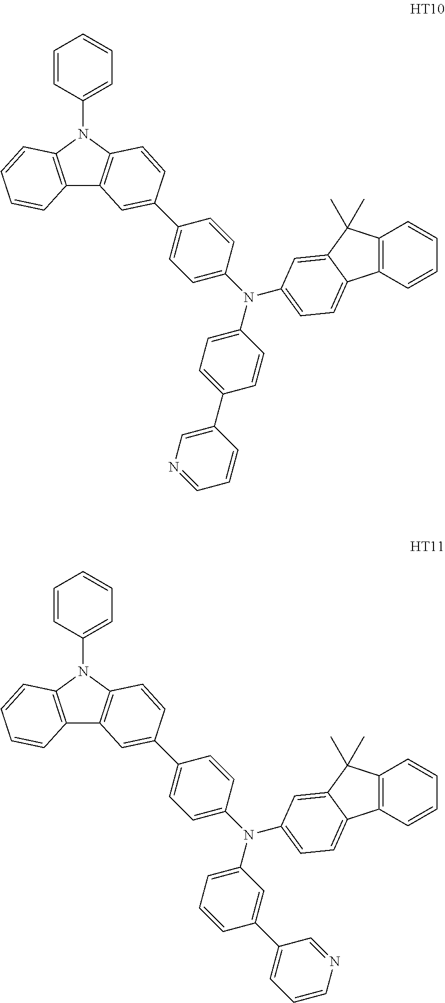 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21]

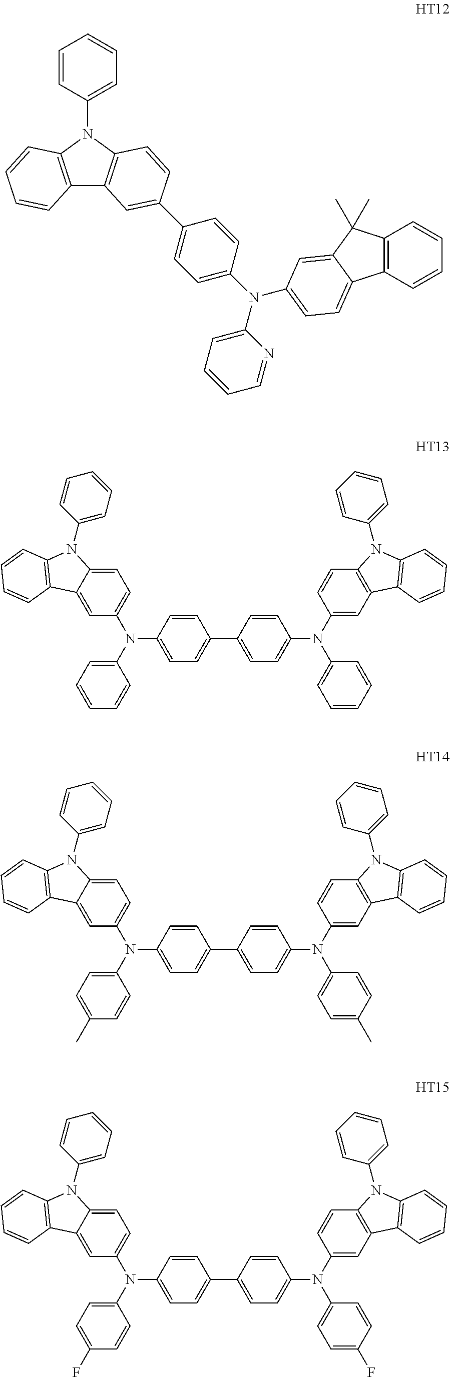 [SMILES: CC1(C)c2ccccc2-c2ccc(N(c3ccc(-c4ccc5c(c4)c4ccccc4n5-c4ccccc4)cc3)c3ccccn3)cc21 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1]

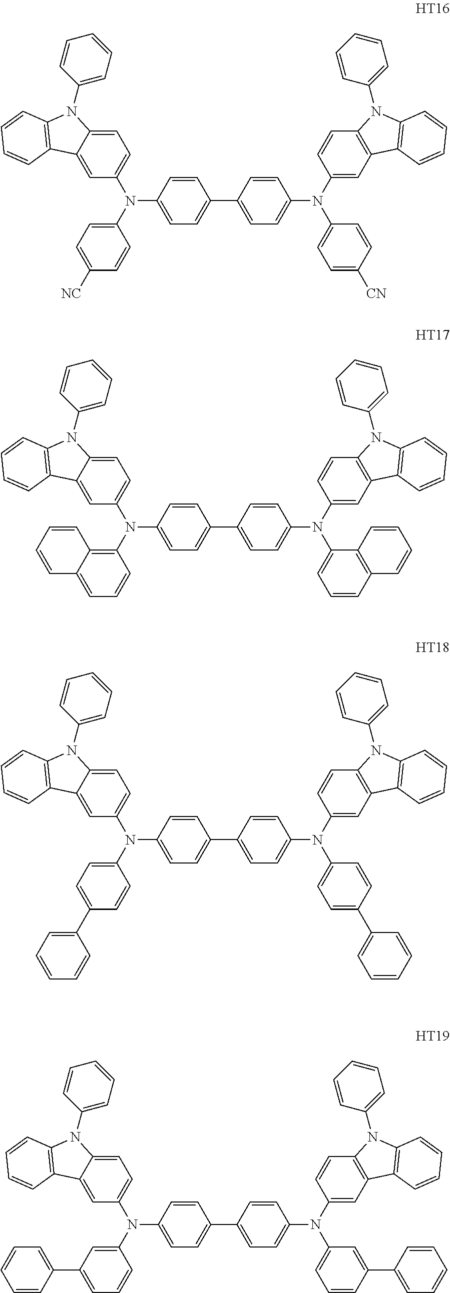 [SMILES: N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1 ; c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1]

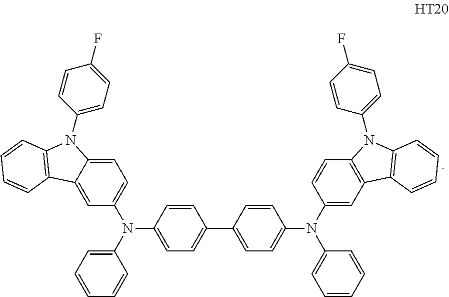 [SMILES: Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

A thickness of the hole transport region may be about 100 Å to about 10,000 Å, for example, about 100 Å to about 1,000 Å. When the hole transport region includes at least one of a hole injection layer and a hole transport layer, a thickness of the hole injection layer may be about 50 Å to about 10,000 Å, for example, about 100 Å to about 1,000 Å, and a thickness of the hole transport layer may be about 50 Å to about 2,000 Å, for example, about 100 Å to about 1,500 Å. When the thicknesses of the hole transport region, the hole injection layer, and the hole transport layer are within these ranges, satisfactory hole transporting characteristics may be obtained without a substantial increase in driving voltage.

The hole transport region may further include, in addition to the above-described materials, a charge-generation material for improving conductivity. The charge-generation material may be homogeneously or non-homogeneously dispersed in the hole transport region.

The charge-generation material may be, for example, a p-dopant. The p-dopant may be, but is not limited to, one of a quinone derivative, a metal oxide, or a cyano group-containing compound. Non-limiting examples of the p-dopant include a quinone derivative, such as tetracyanoquinonedimethane (TCNQ) or 2,3,5,6-tetrafluoro-tetracyano-1,4-benzoquinonedimethane (F4-TCNQ); a metal oxide, such as a tungsten oxide or a molybdenum oxide; or a cyano group-containing compound, such as Compound HT-D1 or F12, but embodiments are not limited thereto:

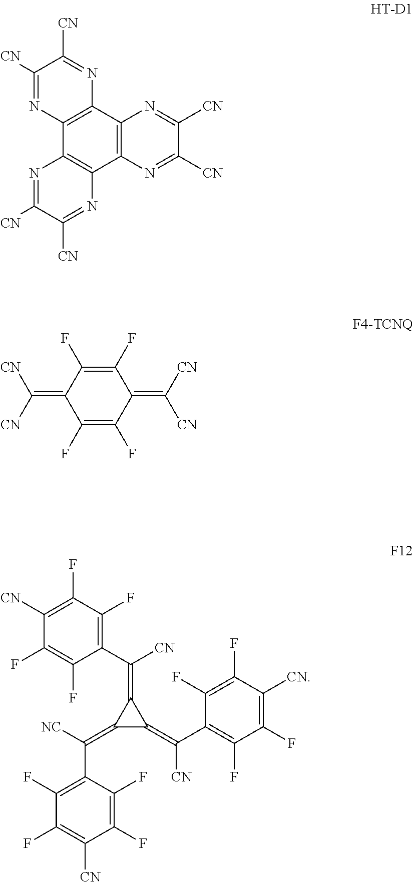

The hole transport region may include a buffer layer.

The buffer layer may compensate for an optical resonance distance according to a wavelength of light emitted from the emission layer, and thus, efficiency of a formed organic light-emitting device may be improved.

In some embodiments, when the hole transport region includes an electron-blocking layer, a material for forming the electron-blocking layer may be selected from, but is not limited to, the above-described materials that may be used in the hole transport region and a host material described below. For example, when the hole transport region includes an electron-blocking layer, a material for forming the electron-blocking layer may be mCP, which will be described herein.

The emission layer (EML) may be formed on the hole transport region by vacuum deposition, spin coating, casting, LB deposition, or the like, but embodiments are not limited thereto. When the emission layer is formed by vacuum deposition or spin coating, the deposition or coating conditions may generally be similar to those applied in forming the hole injection layer, although the deposition or coating conditions may vary according to a material that is used to form the emission layer.

When the organic light-emitting device is a full-color organic light-emitting device, the emission layer may be patterned into a red emission layer, a green emission layer, and/or a blue emission layer. In one or more embodiments, the emission layer may have a structure in which a red emission layer, a green emission layer, and/or a blue emission layer are stacked, and thus, various modifications such as emission of white light are possible.

When the emission layer includes a host and a dopant, the amount of the dopant may generally be about 0.01 parts by weight to about 15 parts by weight with respect to 100 parts by weight of the host, but embodiments are not limited thereto.

A thickness of the emission layer may be about 100 Å to about 1,000 Å, for example, about 200 Å to about 600 Å. When the thickness of the emission layer is within the range described above, excellent luminescence characteristics may be obtained without a substantial increase in driving voltage.

Next, an electron transport region may be located on the emission layer.

The electron transport region may include a hole-blocking layer, an electron transport layer, an electron injection layer (EIL), or a combination thereof.

For example, the electron transport region may have a hole-blocking layer/electron transport layer/electron injection layer structure or an electron transport layer/electron injection layer structure, but the structure of the electron transport region is not limited thereto. The electron transport layer may have a single-layered structure or a multi-layered structure including two or more different materials.

Conditions for forming the hole-blocking layer, the electron transport layer, and the electron injection layer which constitute the electron transport region may be referred to the description provided for the conditions for forming the hole injection layer.

When the electron transport region includes a hole-blocking layer, the hole-blocking layer may include, for example, at least one of 2,9-dimethyl-4,7-diphenyl-1,10-phenanthroline (BCP), 4,7-diphenyl-1,10-phenanthroline (Bphen), or bis(2-methyl-8-quinolinolato-N1,O8)-(1,1′-biphenyl-4-olato)aluminum (BAlq), but embodiments are not limited thereto.

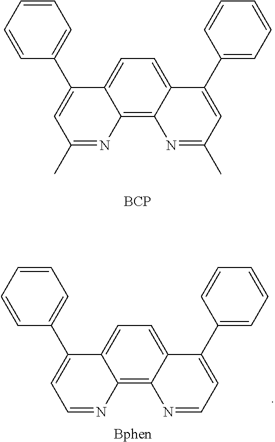

A thickness of the hole-blocking layer may be about 20 Å to about 1,000 Å, for example, about 30 Å to about 300 Å. When the thickness of the hole-blocking layer is within these ranges, excellent hole-blocking characteristics may be obtained without a substantial increase in driving voltage.

The electron transport layer may further include at least one of DBFPO, 2,9-dimethyl-4,7-diphenyl-1,10-phenanthroline (BCP), 4,7-diphenyl-1,10-phenanthroline (Bphen), tris(8-hydroxy-quinolinato)aluminum (Alq3), bis(2-methyl-8-quinolinolato-N1,O8)-(1,1′-biphenyl-4-olato)aluminum (BAlq), 3-(4-biphenylyl)-4-phenyl-5-tert-butylphenyl-1,2,4-triazole (TAZ), or 4-(naphthalen-1-yl)-3,5-diphenyl-4H-1,2,4-triazole (NTAZ), but embodiments are not limited thereto:

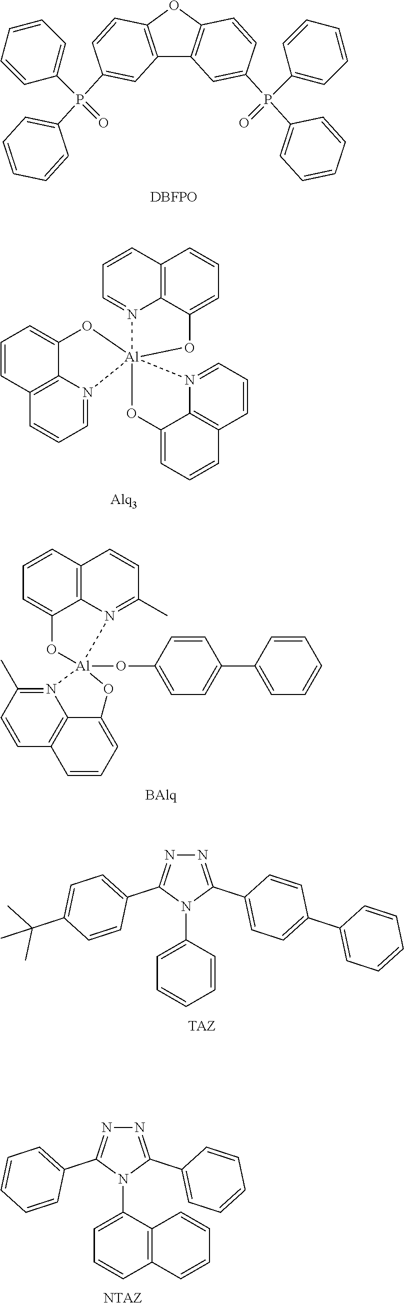

In one or more embodiments, the electron transport layer may include at least one of compounds ET1 to ET25, but embodiments are not limited thereto:

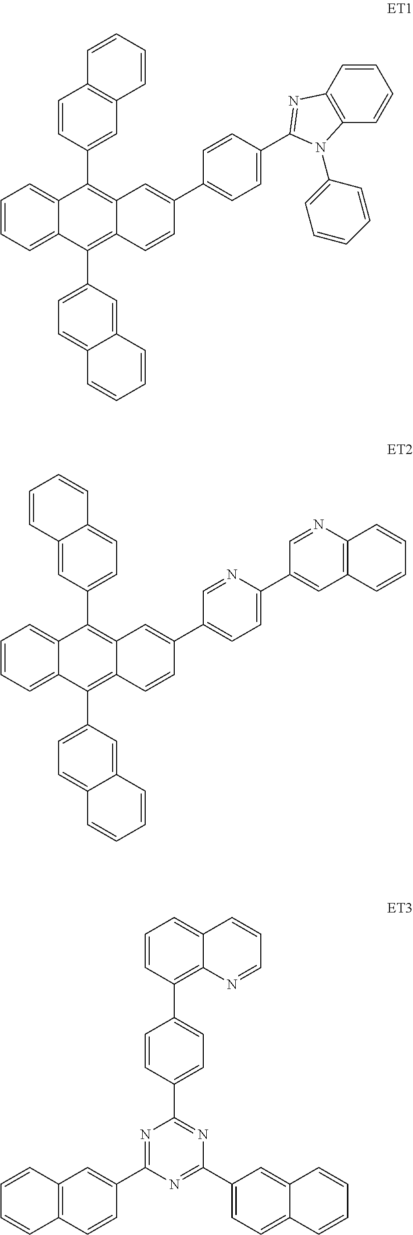 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc2cc(-c3nc(-c4ccc(-c5cccc6cccnc56)cc4)nc(-c4ccc5ccccc5c4)n3)ccc2c1]

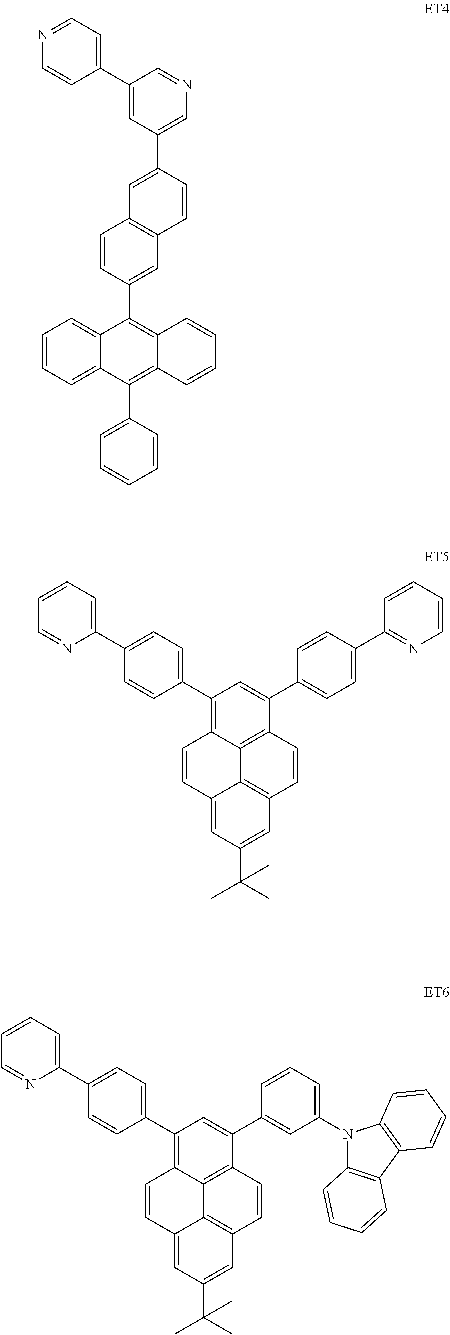 [SMILES: c1ccc(-c2c3ccccc3c(-c3ccc4cc(-c5cncc(-c6ccncc6)c5)ccc4c3)c3ccccc23)cc1 ; CC(C)(C)c1cc2ccc3c(-c4ccc(-c5ccccn5)cc4)cc(-c4ccc(-c5ccccn5)cc4)c4ccc(c1)c2c34 ; CC(C)(C)c1cc2ccc3c(-c4ccc(-c5ccccn5)cc4)cc(-c4cccc(-n5c6ccccc6c6ccccc65)c4)c4ccc(c1)c2c34]

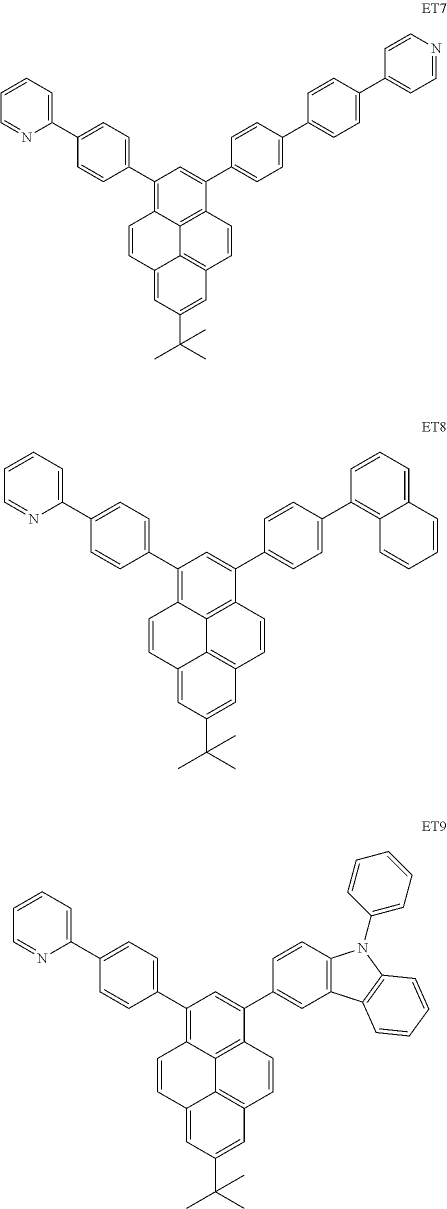 [SMILES: CC(C)(C)c1cc2ccc3c(-c4ccc(-c5ccc(-c6ccncc6)cc5)cc4)cc(-c4ccc(-c5ccccn5)cc4)c4ccc(c1)c2c34 ; CC(C)(C)c1cc2ccc3c(-c4ccc(-c5ccccn5)cc4)cc(-c4ccc(-c5cccc6ccccc56)cc4)c4ccc(c1)c2c34 ; CC(C)(C)c1cc2ccc3c(-c4ccc(-c5ccccn5)cc4)cc(-c4ccc5c(c4)c4ccccc4n5-c4ccccc4)c4ccc(c1)c2c34]

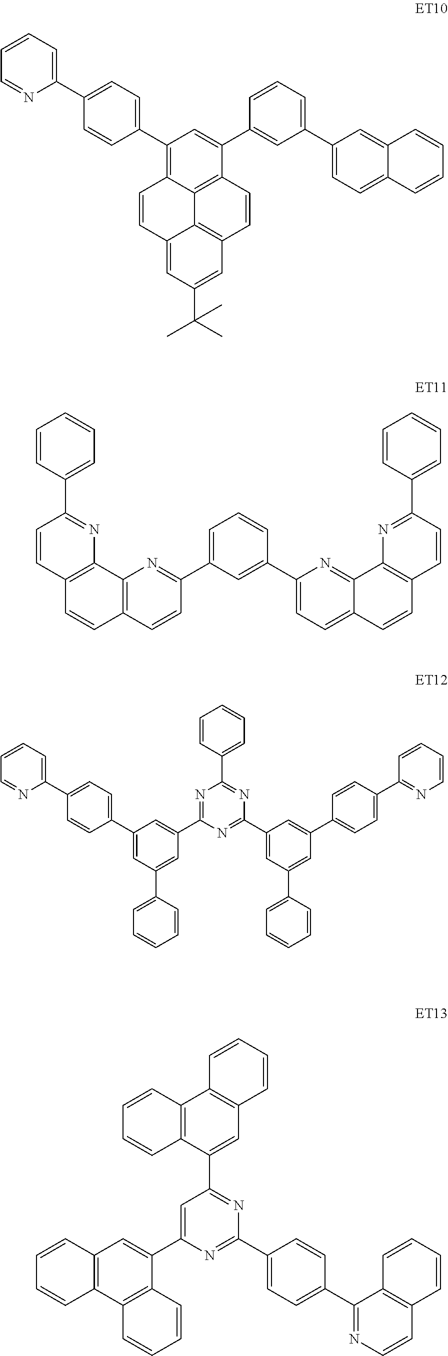 [SMILES: CC(C)(C)c1cc2ccc3c(-c4ccc(-c5ccccn5)cc4)cc(-c4cccc(-c5ccc6ccccc6c5)c4)c4ccc(c1)c2c34 ; c1ccc(-c2ccc3ccc4ccc(-c5cccc(-c6ccc7ccc8ccc(-c9ccccc9)nc8c7n6)c5)nc4c3n2)cc1 ; c1ccc(-c2cc(-c3ccc(-c4ccccn4)cc3)cc(-c3nc(-c4ccccc4)nc(-c4cc(-c5ccccc5)cc(-c5ccc(-c6ccccn6)cc5)c4)n3)c2)cc1 ; c1ccc2c(-c3ccc(-c4nc(-c5cc6ccccc6c6ccccc56)cc(-c5cc6ccccc6c6ccccc56)n4)cc3)nccc2c1]

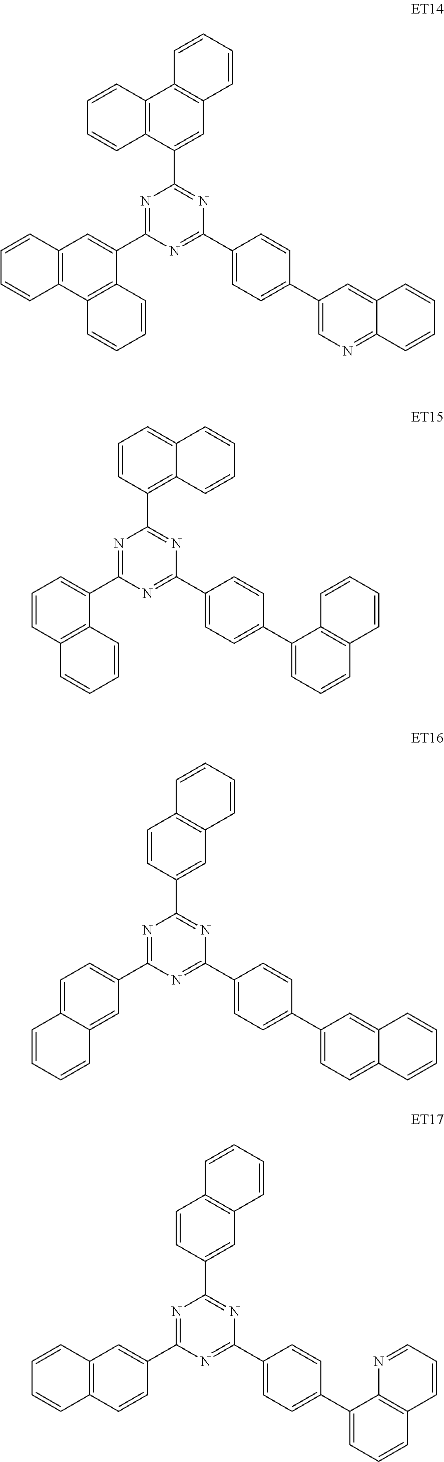 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc2c(-c3ccc(-c4nc(-c5cccc6ccccc56)nc(-c5cccc6ccccc56)n4)cc3)cccc2c1 ; c1ccc2cc(-c3ccc(-c4nc(-c5ccc6ccccc6c5)nc(-c5ccc6ccccc6c5)n4)cc3)ccc2c1 ; c1ccc2cc(-c3nc(-c4ccc(-c5cccc6cccnc56)cc4)nc(-c4ccc5ccccc5c4)n3)ccc2c1]

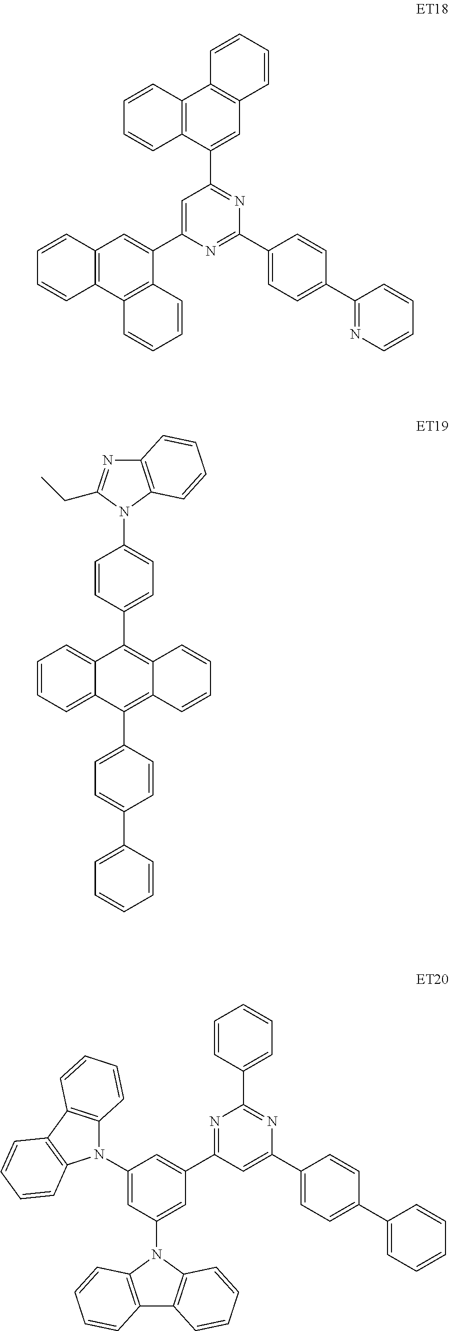 [SMILES: c1ccc(-c2ccc(-c3nc(-c4cc5ccccc5c5ccccc45)cc(-c4cc5ccccc5c5ccccc45)n3)cc2)nc1 ; CCc1nc2ccccc2n1-c1ccc(-c2c3ccccc3c(-c3ccc(-c4ccccc4)cc3)c3ccccc23)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1]

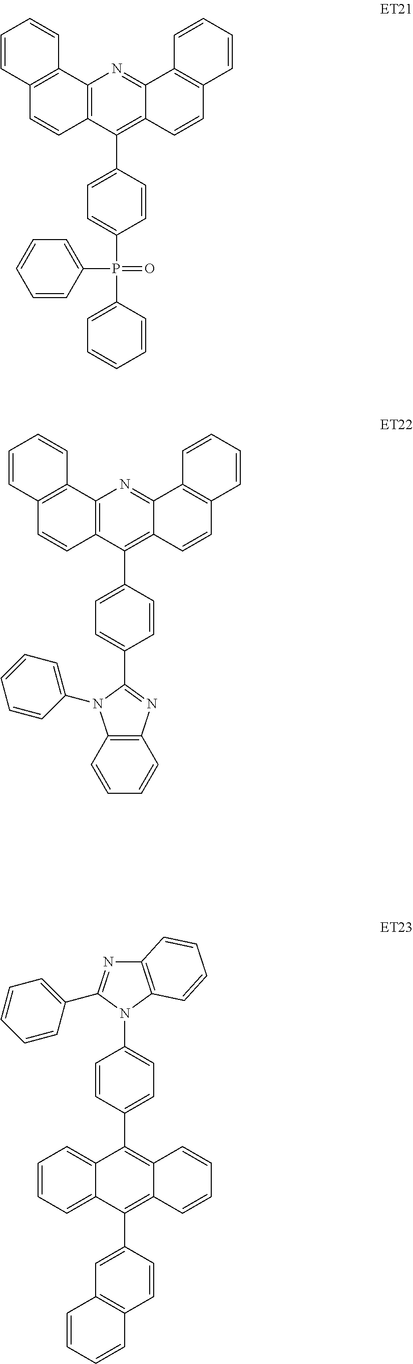 [SMILES: O=P(c1ccccc1)(c1ccccc1)c1ccc(-c2c3ccc4ccccc4c3nc3c2ccc2ccccc23)cc1 ; c1ccc(-n2c(-c3ccc(-c4c5ccc6ccccc6c5nc5c4ccc4ccccc45)cc3)nc3ccccc32)cc1 ; c1ccc(-c2nc3ccccc3n2-c2ccc(-c3c4ccccc4c(-c4ccc5ccccc5c4)c4ccccc34)cc2)cc1]

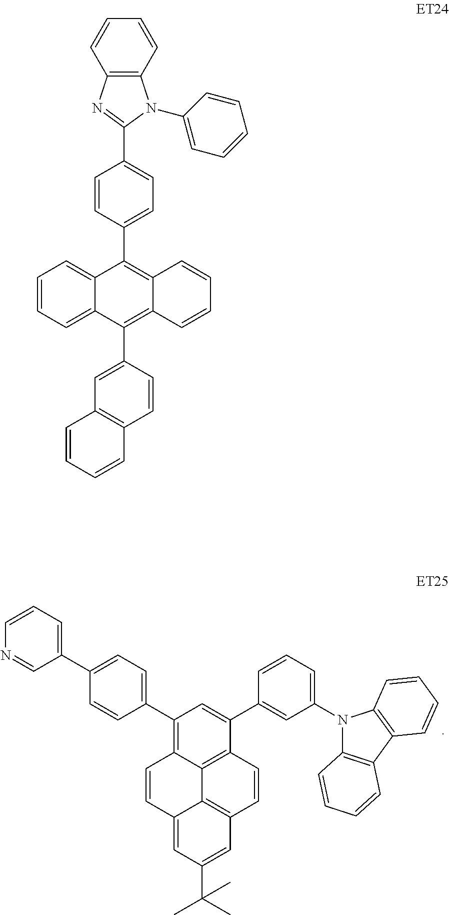 [SMILES: c1ccc(-n2c(-c3ccc(-c4c5ccccc5c(-c5ccc6ccccc6c5)c5ccccc45)cc3)nc3ccccc32)cc1 ; CC(C)(C)c1cc2ccc3c(-c4ccc(-c5cccnc5)cc4)cc(-c4cccc(-n5c6ccccc6c6ccccc65)c4)c4ccc(c1)c2c34]

The thickness of the electron transport layer may be about 100 Å to about 1,000 Å, for example, about 150 Å to about 500 Å. When the thickness of the electron transport layer is within these ranges, satisfactory electron transporting characteristics may be obtained without a substantial increase in driving voltage.

The electron transport layer may further include a metal-containing material, in addition to the material as described above.

The metal-containing material may include a Li complex. The Li complex may include, for example, Compound ET-D1 (lithium quinolate, LiQ) or ET-D2, but embodiments are not limited thereto:

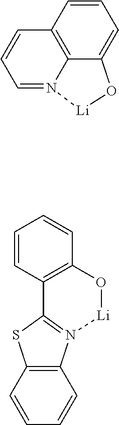

The electron transport region may include an electron injection layer (EIL) that facilitates the injection of electrons from the second electrode 19.

The EIL may include LiQ, LiF, NaCl, CsF, Li₂O, BaO, or a combination thereof.

A thickness of the electron injection layer may be about 1 Å to about 100 Å, and, for example, about 3 Å to about 90 Å. When the thickness of the electron injection layer is within the range as described above, satisfactory electron injection characteristics may be obtained without a substantial increase in driving voltage.

The second electrode 19 may be disposed on the organic layer 15. The second electrode 19 may be a cathode. A material for forming the second electrode 19 may be a metal, an alloy, an electrically conductive compound, or a combination thereof, which have a relatively low work function. For example, lithium (Li), magnesium (Mg), aluminum (Al), silver (Ag), aluminum-lithium (Al—Li), calcium (Ca), magnesium-indium (Mg—In), or magnesium-silver (Mg—Ag) may be used as the material for forming the second electrode 19. In one or more embodiments, to manufacture a top-emission type light-emitting device, various modifications, such as formation of a transmissive second electrode using ITO or IZO, is possible.

The organic light-emitting device has been described with reference to FIG. 1, but embodiments are not limited thereto.

According to another aspect of the disclosure, an electronic apparatus includes the organic light-emitting device.

The electronic apparatus may further include a thin-film transistor in addition to the organic light-emitting device as described above. The thin-film transistor may include a source electrode, a drain electrode, and an active layer, wherein any one of the source electrode and the drain electrode may be electrically connected to any one of the first electrode and the second electrode of the organic light-emitting device.

According to another aspect, a diagnostic composition is provided, including at least one of the heterocyclic compounds represented by Formula 1.

The diagnostic composition may include at least one heterocyclic compound represented by Formula 1.

Since the heterocyclic compound represented by Formula 1 may provide high luminescence efficiency, a diagnostic composition including at least one of the heterocyclic compounds represented by Formula 1 can have high diagnostic efficiency.

The diagnostic composition may be used in various applications including a diagnosis kit, a diagnosis reagent, a biosensor, a biomarker, or the like, but embodiments are not limited thereto.

The term “C₁-C₆₀ alkyl group” as used herein refers to a linear or branched saturated aliphatic hydrocarbon monovalent group having 1 to 60 carbon atoms, and non-limiting examples thereof include a methyl group, an ethyl group, a propyl group, an isobutyl group, a sec-butyl group, a tert-butyl group, a pentyl group, an iso-amyl group, a hexyl group, or the like. The term “C₁-C₆₀ alkylene group” as used herein refers to a divalent group having the same structure as the C₁-C₆₀ alkyl group.

Additional examples of the C₁-C₆₀ alkyl group, the C₁-C₂₀ alkyl group, and/or the C₁-C₁₀ alkyl group include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, or the like, each unsubstituted or substituted with a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, or a combination thereof. For example, Formula 9-33 is a branched C₆ alkyl group, for example, a tert-butyl group that is substituted with two methyl groups.

The term “C₁-C₆₀ alkoxy group” as used herein refers to a monovalent group represented by —OA₁₀₁ (wherein A₁₀₁ is the C₁-C₆₀ alkyl group), and non-limiting examples thereof include a methoxy group, an ethoxy group, an isopropyloxy group, or the like.

Additional examples of the C₁-C₆₀ alkoxy group, a C₁-C₂₀ alkoxy group or C₁-C₁₀ alkoxy group include a methoxy group, an ethoxy group, a propoxy group, a butoxy group, a pentoxy group, or the like.

The term “C₁-C₆₀ alkylthio group” as used herein refers to a monovalent group represented by —SA_{101′} (wherein A_{101′} is the C₁-C₆₀ alkyl group).

The term “C₂-C₆₀ alkenyl group” as used herein refers to a structure containing at least one carbon-carbon double bond in the middle or at the end of the C₂-C₆₀ alkyl group, and non-limiting examples thereof include an ethenyl group, a propenyl group, a butenyl group, or the like. The term “C₂-C₆₀ alkenylene group” as used herein refers to a divalent group having the same structure as the C₂-C₆₀ alkenyl group.

The term “C₂-C₆₀ alkynyl group” as used herein refers to a hydrocarbon group formed by substituting at least one carbon-carbon triple bond in the middle or at the terminus of the C₂-C₆₀ alkyl group, and non-limiting examples thereof include an ethynyl group, a propynyl group, or the like. The term “C₂-C₆₀ alkynylene group” as used herein refers to a divalent group having the same structure as the C₂-C₆₀ alkynyl group.

The term “C₃-C₁₀ cycloalkyl group” as used herein refers to a monovalent saturated hydrocarbon ring group having 3 to 10 carbon atoms, and non-limiting examples thereof include a cyclopropyl group, a cyclobutyl group, a cyclopentyl group, a cyclohexyl group, a cycloheptyl group, or the like. The term “C₃-C₁₀ cycloalkylene group” as used herein refers to a divalent group having the same structure as the C₃-C₁₀ cycloalkyl group.

The term “C₃-C₁₀ cycloalkyl group” as used herein may also include a cyclopropyl group, a cyclobutyl group, a cyclopentyl group, a cyclohexyl group, a cycloheptyl group, a cyclooctyl group, an adamantanyl group, a bicyclo[1.1.1]pentyl group, a bicyclo[2.1.1]hexyl group, a bicyclo[2.2.1]heptyl(norbornanyl) group, a bicyclo[2.2.2]octyl group, or the like.

The term “C₁-C₁₀ heterocycloalkyl group” as used herein refers to a monovalent saturated ring group having at least one heteroatom selected from B, N, O, P, Si, S, Se, and Ge as a ring-forming atom and 1 to 10 carbon atoms as ring-forming atom(s), and non-limiting examples thereof include a tetrahydrofuranyl group, a tetrahydrothiophenyl group, or the like. The term “C₁-C₁₀ heterocycloalkylene group” as used herein refers to a divalent group having the same structure as the C₁-C₁₀ heterocycloalkyl group.

Additional non-limiting examples of the C₁-C₁₀ heterocycloalkyl group include a silolanyl group, a silinanyl group, a tetrahydro-2H-pyranyl group, or the like.

The term “C₃-C₁₀ cycloalkenyl group” as used herein refers to a monovalent ring group that has 3 to 10 carbon atoms and at least one carbon-carbon double bond in the ring thereof and no aromaticity, and non-limiting examples thereof include a cyclopentenyl group, a cyclohexenyl group, a cycloheptenyl group, or the like. The term “C₃-C₁₀ cycloalkenylene group” as used herein refers to a divalent group having the same structure as the C₃-C₁₀ cycloalkenyl group.

The term “C₁-C₁₀ heterocycloalkenyl group” as used herein refers to a monovalent ring group that has at least one heteroatom selected from B, N, O, P, Si, S, Se, and Ge as a ring-forming atom, 1 to 10 carbon atoms as a ring-forming atom, and at least one double bond in its ring. Non-limiting examples of the C₁-C₁₀ heterocycloalkenyl group include a 2,3-dihydrofuranyl group, a 2,3-dihydrothiophenyl group, or the like. The term “C₁-C₁₀ heterocycloalkenylene group” as used herein refers to a divalent group having the same structure as the C₁-C₁₀ heterocycloalkenyl group.

The term “C₆-C₆₀ aryl group” as used herein refers to a monovalent group having a carbocyclic aromatic ring system having 6 to 60 carbon atoms, and the term “C₆-C₆₀ arylene group” as used herein refers to a divalent group having a carbocyclic aromatic ring system having 6 to 60 carbon atoms. Non-limiting examples of the C₆-C₆₀ aryl group include a phenyl group, a naphthyl group, an anthracenyl group, a phenanthrenyl group, a pyrenyl group, a chrysenyl group, or the like. When the C₆-C₆₀ aryl group and the C₆-C₆₀ arylene group each include two or more rings, the rings may be fused with each other.

The term “C₇-C₆₀ alkyl aryl group” as used herein refers to a C₆-C₆₀ aryl group substituted with at least one C₁-C₆₀ alkyl group. The term “C₇-C₆₀ aryl alkyl group” as used herein refers to a C₁-C₆₀ alkyl group substituted with at least one C₆-C₆₀ aryl group.

The term “C₁-C₆₀ heteroaryl group” as used herein refers to a monovalent group having a heteroaromatic ring system that has at least one heteroatom selected from B, N, O, P, Si, S, Se, and Ge as a ring-forming atom, and 1 to 60 carbon atoms as ring-forming atom(s). The term “C₁-C₆₀ heteroarylene group” as used herein refers to a divalent group having a heteroaromatic system that has at least one heteroatom selected from B, N, O, P, Si, S, Se, and Ge as a ring-forming atom, and 1 to 60 carbon atoms as ring-forming atom(s). Non-limiting examples of the C₁-C₆₀ heteroaryl group include a pyridinyl group, a pyrimidinyl group, a pyrazinyl group, a pyridazinyl group, a triazinyl group, a quinolinyl group, an isoquinolinyl group, or the like. When the C₁-C₆₀ heteroaryl group and the C₁-C₆₀ heteroarylene group each include two or more rings, the rings may be fused with each other.

The term “C₂-C₆₀ alkyl heteroaryl group” as used herein refers to a C₁-C₆₀ heteroaryl group substituted with at least one C₁-C₆₀ alkyl group. The term “C₂-C₆₀ heteroaryl alkyl group” as used herein refers to a C₁-C₆₀ alkyl group substituted with at least one C₁-C₆₀ heteroaryl group.

The term “C₆-C₆₀ aryloxy group” as used herein refers to —OA₁₀₂ (wherein A₁₀₂ is the C₆-C₆₀ aryl group), and the term “C₆-C₆₀ arylthio group” as used herein refers to —SA₁₀₃ (wherein A₁₀₃ is the C₆-C₆₀ aryl group).

The term “C₁-C₆₀ heteroaryloxy group” as used herein indicates —OA₁₀₄ (wherein A₁₀₄ is a C₁-C₆₀ heteroaryl group), and the term “C₁-C₆₀ heteroarylthio group” as used herein indicates —SA₁₀₅ (wherein A₁₀₅ is the C₁-C₆₀ heteroaryl group).

The term “monovalent non-aromatic condensed polycyclic group” as used herein refers to a monovalent group (for example, having 8 to 60 carbon atoms) having two or more rings condensed with each other, only carbon atoms as ring-forming atoms, and no aromaticity in its entire molecular structure. Non-limiting examples of the monovalent non-aromatic condensed polycyclic group include a fluorenyl group or the like. The term “divalent non-aromatic condensed polycyclic group” as used herein refers to a divalent group having the same structure as the monovalent non-aromatic condensed polycyclic group.

The term “monovalent non-aromatic condensed heteropolycyclic group” as used herein refers to a monovalent group (for example, having 1 to 60 carbon atoms) having two or more rings condensed with each other, a heteroatom selected from B, N, O, P, Si, S, Se, and Ge, other than carbon atoms, as ring-forming atom(s), and no aromaticity in its entire molecular structure. Non-limiting examples of the monovalent non-aromatic condensed heteropolycyclic group include a carbazolyl group or the like. The term “divalent non-aromatic condensed heteropolycyclic group” as used herein refers to a divalent group having the same structure as the monovalent non-aromatic condensed heteropolycyclic group.

The term “C₅-C₃₀ carbocyclic group” as used herein refers to a saturated or unsaturated cyclic group having, as a ring-forming atom, 5 to 30 carbon atoms only. The C₅-C₃₀ carbocyclic group may be a monocyclic group or a polycyclic group. Non-limiting examples of the “C₅-C₃₀ carbocyclic group (unsubstituted or substituted with at least one R₁₀ₐ)” as used herein may include an adamantane group, a norbornene group, a bicyclo[1.1.1]pentane group, a bicyclo[2.1.1]hexane group, a bicyclo[2.2.1]heptane(norbornane) group, a bicyclo[2.2.2]octane group, a cyclopentane group, a cyclohexane group, a cyclohexene group, a benzene group, a naphthalene group, an anthracene group, a phenanthrene group, a triphenylene group, a pyrene group, a chrysene group, a 1,2,3,4-tetrahydronaphthalene group, a cyclopentadiene group, an indene group, a fluorene group, or the like (each unsubstituted or substituted with at least one R₁₀ₐ).

The term “C₁-C₃₀ heterocyclic group” as used herein refers to a saturated or unsaturated cyclic group having, as a ring-forming atom, at least one heteroatom selected from B, N, O, Si, P, S, Se, and Ge other than 1 to 30 carbon atoms as ring-forming atom(s). The C₁-C₃₀ heterocyclic group may be a monocyclic group or a polycyclic group. Non-limiting examples of the “C₁-C₃₀ heterocyclic group (unsubstituted or substituted with at least one R₁₀ₐ)” as used herein may include a thiophene group, a furan group, a pyrrole group, a silole group, a borole group, a phosphole group, a selenophene group, a germole group, a benzothiophene group, a benzofuran group, an indole group, a benzosilole group, a benzoborole group, a benzophosphole group, a benzoselenophene group, a benzogermole group, a dibenzothiophene group, a dibenzofuran group, a carbazole group, a dibenzosilole group, a dibenzoborole group, a dibenzophosphole group, a dibenzoselenophene group, a dibenzogermole group, a dibenzothiophene 5-oxide group, a 9H-fluoren-9-one group, a dibenzothiophene 5,5-dioxide group, an azabenzothiophene group, an azabenzofuran group, an azaindole group, an azaindene group, an azabenzosilole group, an azabenzoborole group, an azabenzophosphole group, an azabenzoselenophene group, an azabenzogermole group, an azadibenzothiophene group, an azadibenzofuran group, an azacarbazole group, an azafluorene group, an azadibenzosilole group, an azadibenzoborole group, an azadibenzophosphole group, an azadibenzoselenophene group, an azadibenzogermole group, an azadibenzothiophene 5-oxide group, an aza-9H-fluoren-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrazole group, an imidazole group, a triazole group, an oxazole group, an isoxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a 5,6,7,8-tetrahydroisoquinoline group, a 5,6,7,8-tetrahydroquinoline group, or the like (each unsubstituted or substituted with at least one R₁₀ₐ).

As used herein, “TMS” represents * —Si(CH₃)₃, and “TMG” represents * —Ge(CH₃)₃.

At least one substituent of the substituted C₅-C₃₀ carbocyclic group, the substituted C₁-C₃₀ heterocyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₁-C₆₀ alkylthio group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₇-C₆₀ alkyl aryl group, the substituted C₇-C₆₀ aryl alkyl group, the substituted C₆-C₆₀ aryloxy group, the substituted C₆-C₆₀ arylthio group, the substituted C₁-C₆₀ heteroaryl group, the substituted C₂-C₆₀ alkyl heteroaryl group, the substituted C₂-C₆₀ heteroaryl alkyl group, the substituted C₁-C₆₀ heteroaryloxy group, the substituted C₁-C₆₀ heteroarylthio group, the substituted monovalent non-aromatic condensed polycyclic group, the substituted monovalent non-aromatic condensed heteropolycyclic group, the substituted C₃-C₁₀ cycloalkylene group, the substituted C₁-C₁₀ heterocycloalkylene group, the substituted C₃-C₁₀ cycloalkenylene group, the substituted C₁-C₁₀ heterocycloalkenylene group, the substituted C₆-C₆₀ arylene group, the substituted C₁-C₆₀ heteroarylene group, the substituted divalent non-aromatic condensed polycyclic group, and the substituted divalent non-aromatic condensed heteropolycyclic group may be:
deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, or a C₁-C₆₀ alkylthio group,
a C₁-C₆₀ alkyl group, a C₂-C₆₀ alkenyl group, a C₂-C₆₀ alkynyl group, a C₁-C₆₀ alkoxy group, or a C₁-C₆₀ alkylthio group, each substituted with deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₁₁)(Q₁₂), —Si(Q₁₁)(Q₁₂)(Q₁₃), —Ge(Q₁₁)(Q₁₂)(Q₁₃), —C(═O)(Q₁₁), —S(═O)(Q₁₁), —S(═O)₂(Q₁₁), —B(Q₁₁)(Q₁₂), —P(Q₁₁)(Q₁₂), —P(═O)(Q₁₁)(Q₁₂), —P(═S)(Q₁₁)(Q₁₂), or a combination thereof,
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, or a monovalent non-aromatic condensed heteropolycyclic group, each unsubstituted or substituted with deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₇-C₆₀ aryl alkyl group, a C₆-C₆₀ aryloxy group, a C₆-C₆₀ arylthio group, a C₁-C₆₀ heteroaryl group, a C₂-C₆₀ alkyl heteroaryl group, a C₂-C₆₀ heteroaryl alkyl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₂₁)(Q₂₂), —Si(Q₂₁)(Q₂₂)(Q₂₃), —Ge(Q₂₁)(Q₂₂)(Q₂₃), —C(═O)(Q₂₁), —S(═O)(Q₂₁), —S(═O)₂(Q₂₁), —B(Q₂₁)(Q₂₂), —P(Q₂₁)(Q₂₂), —P(═O)(Q₂₁)(Q₂₂), —P(═S)(Q₂₁)(Q₂₂), or a combination thereof;
—N(Q₃₁)(Q₃₂), —Si(Q₃₁)(Q₃₂)(Q₃₃), —Ge(Q₃₁)(Q₃₂)(Q₃₃), —C(═O)(Q₃₁), —S(═O)(Q₃₁), —S(═O)₂(Q₃₁), —B(Q₃₁)(Q₃₂), —P(Q₃₁)(Q₃₂), —P(═O)(Q₃₁)(Q₃₂), or —P(═S)(Q₃₁)(Q₃₂); or
a combination thereof.

Q₁ to Q₃, Q₁₁ to Q₁₃, Q₂₁ to Q₂₃, and Q₃₁ to Q₃₃ may each independently be hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, or a substituted or unsubstituted monovalent non-aromatic condensed heteropolycyclic group.

For example, Q₁ to Q₃, Q₁₁ to Q₁₃, Q₂₁ to Q₂₃ and Q₃₁ to Q₃₃ may each independently be:
hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₇-C₆₀ aryl alkyl group, a C₆-C₆₀ aryloxy group, a C₆-C₆₀ arylthio group, a C₁-C₆₀ heteroaryl group, a C₂-C₆₀ alkyl heteroaryl group, a C₂-C₆₀ heteroaryl alkyl group, a C₁-C₆₀ heteroaryloxy group, a C₁-C₆₀ heteroarylthio group, a monovalent non-aromatic condensed polycyclic group, or a monovalent non-aromatic condensed heteropolycyclic group; or
a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₇-C₆₀ aryl alkyl group, a C₆-C₆₀ aryloxy group, a C₆-C₆₀ arylthio group, a C₁-C₆₀ heteroaryl group, a C₂-C₆₀ alkyl heteroaryl group, a C₂-C₆₀ heteroaryl alkyl group, a C₁-C₆₀ heteroaryloxy group, a C₁-C₆₀ heteroarylthio group, a monovalent non-aromatic condensed polycyclic group, or a monovalent non-aromatic condensed heteropolycyclic group, each substituted with deuterium, —F, —Cl, —Br, —I, —SF₅, a hydroxyl group, a cyano group, a C₁-C₆₀ alkyl group, a C₆-C₆₀ aryl group, a C₁-C₆₀ heteroaryl group, a monovalent non-aromatic condensed heteropolycyclic group, a monovalent non-aromatic condensed heteropolycyclic group, or a combination thereof.

Hereinafter, compounds and organic light-emitting devices, according to one or more embodiments, will be described in further detail with reference to Synthesis Examples and Examples. However, the following examples are not intended to limit the scope of the subject matter. The wording “‘B’ was used instead of ‘A’” used in describing Synthesis Examples means that an amount of ‘A’ used was identical to an amount of ‘B’ used, in terms of a molar equivalent.

### EXAMPLES

### Synthesis Examples

### Synthesis Example 1: Synthesis of Compound 1

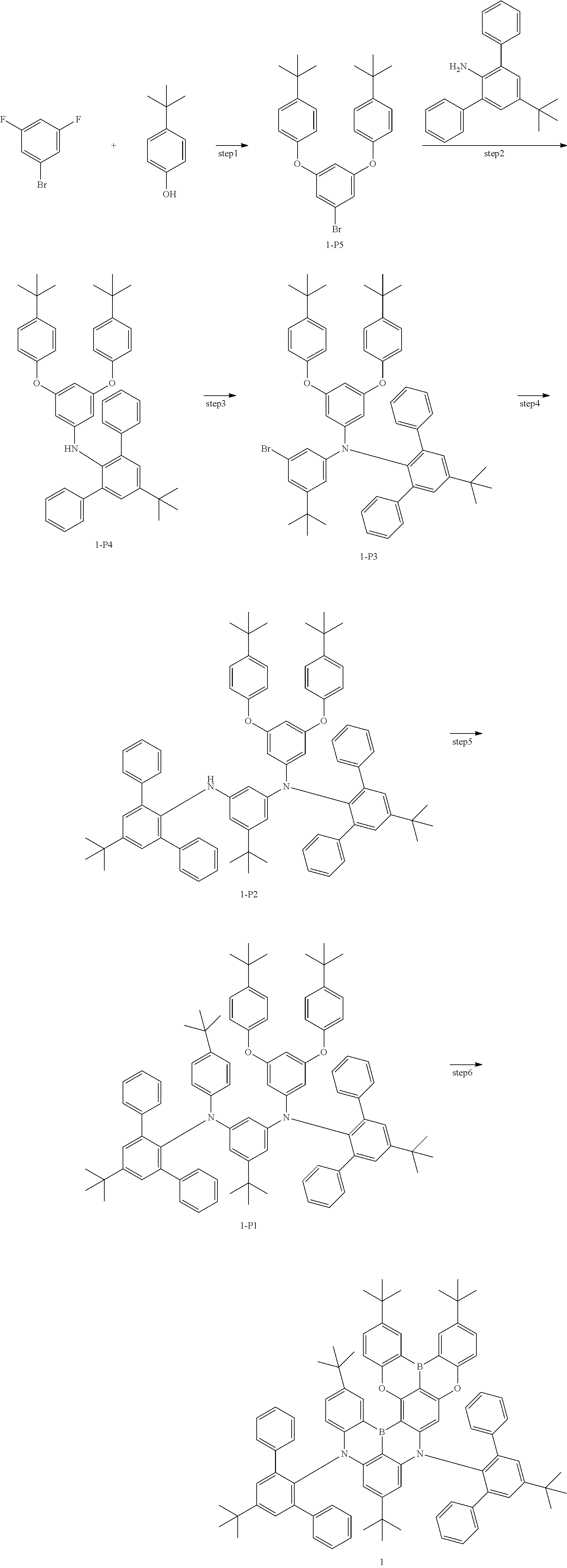

### (1) Synthesis of Compound 1-P5

Under a nitrogen atmosphere, 1-bromo-3,5-difluorobenzene (10 grams (g), 51.93 millimoles (mmol)), 4-(tert-butyl)phenol (8.58 g, 57.13 mmol), and potassium carbonate (21.53 g, 155.79 mmol) were added to 300 milliliters (mL) of N-methylpyrrolidone (NMP), and the mixture was heated to 150° C. After 12 hours, the mixture was cooled to room temperature, and the reaction was quenched with an ammonium chloride solution. After extraction with methylene chloride (MC), drying with MgSO₄, and removal of the solvent under reduced pressure, the product was purified by column chromatography using MC:hexane (1:3) to obtain 18 g of a white solid. (Yield of 80%)

### (2) Synthesis of Compound 1-P4

Under a nitrogen atmosphere, 1-P5 (5 g, 11.03 mmol), 5′-(tert-butyl)-[1,1′:3′,1″-terphenyl]-2′-amine (3.32 g, 11.03 mmol), tris(dibenzylideneacetone)dipalladium(0) (Pd₂(dba)₃) (0.50 g, 0.55 mmol), 2-dicyclohexylphosphino-2′,6′-dimethoxybiphenyl (SPhos) (0.45 g, 1.1 mmol), and sodium t-butoxide (1.59 g, 16.55 mmol) were added to 110 mL of toluene, and the mixture was heated at 110° C. After 2 hours, the mixture was cooled to room temperature, and the reaction was quenched with an ammonium chloride solution. After extraction with ethyl acetate, drying with MgSO₄, and removal of the solvent under reduced pressure, the product was purified by column chromatography using MC:hexane (1:3) to obtain 6.5 g of a white solid. (Yield of 88%)

### (3) Synthesis of Compound 1-P3

Under a nitrogen atmosphere, 1-P4 (6.5 g, 9.64 mmol), 1-bromo-3-(tert-butyl)-5-iodobenzene (6.53 g, 19.28 mmol), Pd₂(dba)₃ (0.88 g, 0.96 mmol), 2,4,6-tri-tert-butylpyrimidine (TTBP) (0.39 g, 1.92 mmol), sodium t-butoxide (2.04 g, 21.2 mmol) were added to 100 mL of xylene, and the mixture was heated at 140° C. After 1 hour, the mixture was cooled to room temperature, and the reaction was quenched with an ammonium chloride solution. After extraction with ethyl acetate, drying with MgSO₄, and removal of the solvent under reduced pressure, the product was purified by column chromatography using MC:hexane (1:3) to obtain 5.1 g of a white solid. (Yield of 60%)

### (4) Synthesis of Compound 1-P2

Under a nitrogen atmosphere, 1-P3 (5.1 g, 5.76 mmol), 5′-(tert-butyl)-[1,1′:3′,1″-terphenyl]-2′-amine (2.08 g, 6.91 mmol), Pd₂(dba)₃ (0.53 g, 0.58 mmol), Sphos (0.48 g, 1.16 mmol), and sodium t-butoxide (0.83 g, 8.64 mmol) were added to 110 mL of toluene, and the mixture was heated at 110° C. After 2 hours, the mixture was cooled to room temperature, and the reaction was quenched with an ammonium chloride solution. After extraction with ethyl acetate, drying with MgSO₄, and removal of the solvent under reduced pressure, the product was purified by column chromatography using MC:hexane (1:2) to obtain 5.4 g of a white solid. (Yield of 85%)

### (5) Synthesis of Compound 1-P1

Under a nitrogen atmosphere, 1-P2 (5.4 g, 4.88 mmol), 1-(tert-butyl)-4-iodobenzene (3.81 g, 14.65 mmol), CuI (1.86 g, 9.76 mmol), and cesium carbonate (3.18 g, 9.76 mmol) were added to 50 mL of t-butylbenzene, and the mixture as stirred at 165° C. The mixture was cooled to room temperature and stirring was continued for 24 hours. The mixture was then filtered through celite, and the solvent was removed under reduced pressure. The product was purified by column chromatography using MC:hexane (1:2) to obtain 5.01 g of a white solid. (Yield of 83%)

### (6) Synthesis of Compound 1

Under a nitrogen atmosphere, compound 1-P1 (5 g, 4.05 mmol) was placed in 50 mL of 1,2-dichlorobenzene with B13 (4.76 g, 12.15 mmol), and the temperature was raised to 120° C. with stirring for 4 hours. After lowering the temperature to room temperature, the reaction was quenched with a sodium bicarbonate solution. The organic layer was extracted with MC, dried with MgSO₄, and the solvent was removed under reduced pressure. The product was purified by column chromatography using MC:hexane (1:4) to obtain 2.1 g of a solid. (Yield of 42%)

Liquid chromatography mass spectrometry (LCMS) (m/z) Calculated: 1252.719 g/mol, Found: [M+]1253.864 g/mol.

### Synthesis Example 2: Synthesis of Compound 16

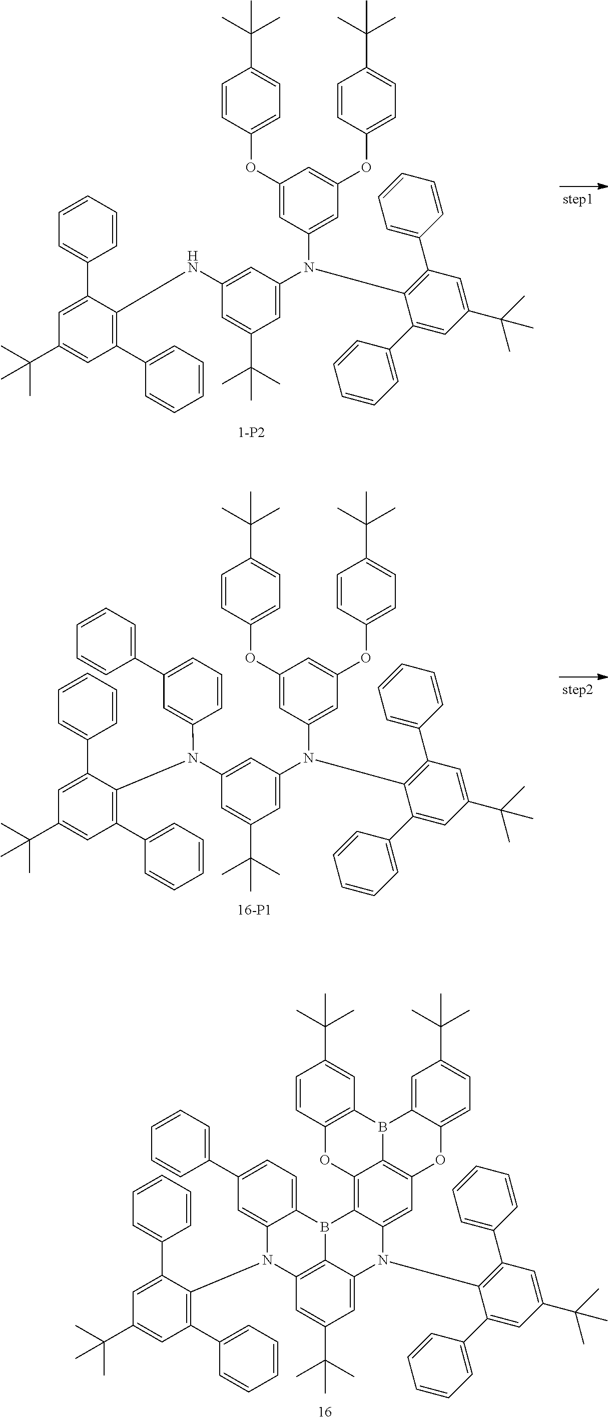

### (1) Synthesis of Compound 16-P1

Under a nitrogen atmosphere, intermediate 1-P2 (5 g, 4.52 mmol), which was synthesized in the same manner as used to prepare compound 1, 3-iodo-1,1′-biphenyl (3.8 g, 13.56 mmol), CuI (1.72 g, 9.04 mmol), and cesium carbonate (2.95 g, 9.04 mmol) were added to 50 mL of t-butylbenzene, and the mixture was stirred at 165° C. After cooling and stirring for 24 hours, the mixture was passed through a celite filter and the solvent was then removed under reduced pressure. The product was purified by column chromatography using MC:hexane (1:2) to obtain 5.5 g of a white solid. (Yield of 97%)

### (2) Synthesis of Compound 16

Under a nitrogen atmosphere, compound 16-P1 (5.5 g, 4.37 mmol) was added to 50 mL of 1,2-dichlorobenzene and B13 (5.14 g, 13.12 mmol), and the temperature was raised to 120° C. and stirred for 4 hours. After the temperature was lowered to room temperature, the reaction was terminated with addition of a sodium bicarbonate solution. The organic layer was extracted with MC, dried with MgSO₄, and the solvent was removed under reduced pressure. The product was purified by column chromatography using MC:hexane (1:4) to obtain 2.9 g of a solid. (Yield of 52%)

LCMS (m/z) Calculated: 1272.688 g/mol, Found: [M+] 1273.712 g/mol.

### Example 1

An ITO glass substrate was cut to a size of 50 millimeters (mm)×50 mm×0.5 mm, ultrasonically cleaned in acetone, isopropyl alcohol, and deionized (DI) water for 15 minutes each, followed by ultraviolet (UV) ozone cleaning for 30 minutes.

Then, HAT-CN was deposited on the ITO electrode (anode) on the glass substrate to form a hole injection layer having the thickness of 100 Å, NPB was deposited on the hole injection layer to form a first hole transport layer having the thickness of 500 Å, TCTA was deposited on the first hole transport layer to form a second hole transport layer having the thickness of 50 Å, and mCP was deposited on the second hole transport layer to form an electron-blocking layer having the thickness of 50 Å.

A first host (H25), a second host (H26), a sensitizer (PT1), and an emitter (Compound 1) were co-deposited on the electron-blocking layer to form an emission layer having the thickness of 400 Å. At this time, the first host and the second host were mixed at a weight ratio of 65:35, and the sensitizer and the emitter were adjusted to be 13 wt % and 1.2 wt %, respectively, based on the total weight of the first host, the second host, the sensitizer, and the emitter.

DBFPO was deposited on the emission layer to form a hole-blocking layer having the thickness of 100 Å, DBFPO and LiQ were co-deposited on the hole-blocking layer at a weight ratio of 5:5 to form an electron transport layer having the thickness of 300 Å, LiQ was deposited on the electron transport layer to form an electron injection layer having the thickness of 10 Å, and Al was deposited on the electron injection layer to form a cathode having a thickness of 1,000 Å, thereby completing the manufacture of an organic light-emitting device.

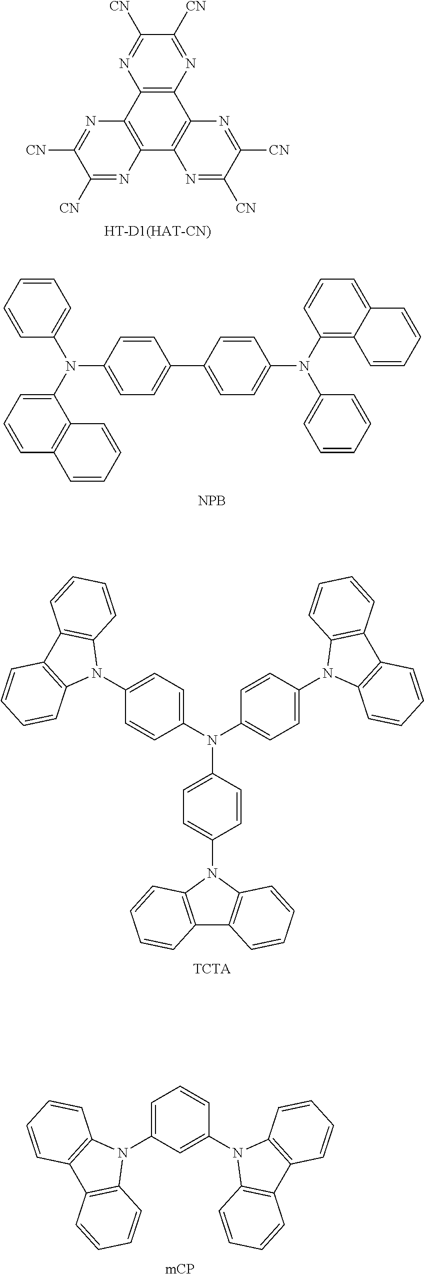

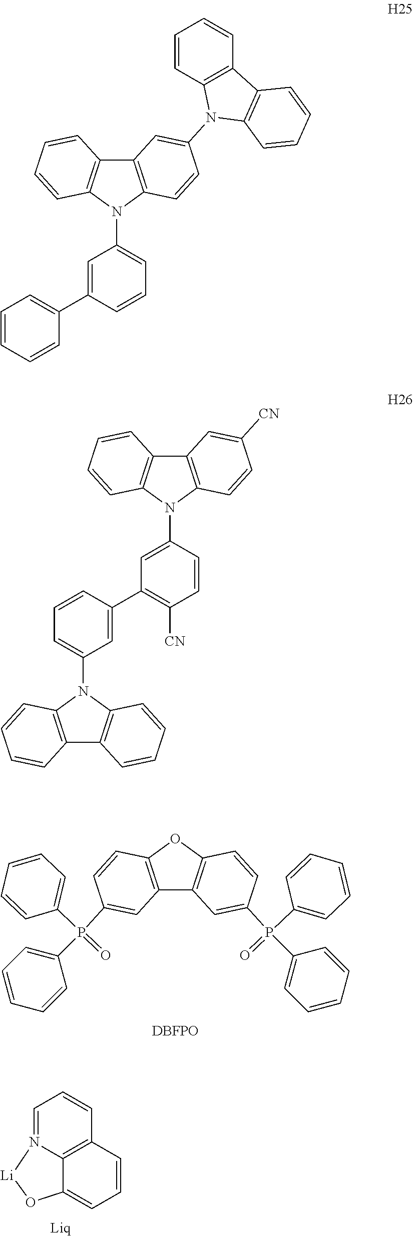

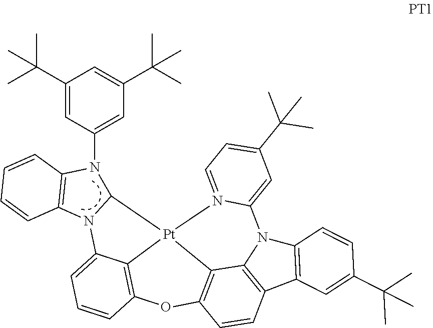

### Example 2 and Comparative Examples 1 to 3

Organic light-emitting devices were manufactured using the same method as in Example 1, except that each compound listed in Table 2 was used as an emitter when forming the emission layer.

The FWHM (nm), roll-off ratio (%), external quantum efficiency (EQE at 1000 cd/m², %), relative luminescent efficiency (relative %) and relative lifespan (relative %) of the organic light-emitting devices manufactured in Examples 1 to 2 and Comparative Examples 1 to 3 were measured and evaluated by using a current-voltage meter (Keithley 2400) and a luminance meter (Minolta Cs-1000A). Results thereof are shown in Table 2 below. Relative lifespan (LT₉₇ at 1000 nit) was evaluated as the time (hr) taken for the luminance to reach 97% of the initial luminance of 100%, and is expressed as a relative value (%) to Comparative Example 1. The relative efficiency is reported relative to Comparative Example 1. The roll-off ratio was calculated according to Equation 1 below.

Roll-off ratio={1−(efficiency/maximum luminescence efficiency)}×100% Equation 1

TABLE 2

| | | | Roll-off | | Relative | Relative |
|---|---|---|---|---|---|---|
| | Emitter in emission | | ratio | EQE | efficiency | lifespan |
| | layer | FWHM | (%) | (%) | (%) | (%) |
| Example 1 | Compound 1 | 20 | 14.5 | 17.3 | 275 | 490 |
| Example 2 | Compound 16 | 21 | 21.9 | 16.2 | 257 | 574 |
| Comparative | Compound C | 22 | 55.8 | 6.3 | 100 | 100 |
| Example 1 | | | | | | |
| Comparative | Compound D | 23 | 57.1 | 7.9 | 125 | 40 |
| Example 2 | | | | | | |
| Comparative | Compound E | 22 | 69 | 7.3 | 117 | 56 |
| Example 3 | | | | | | |

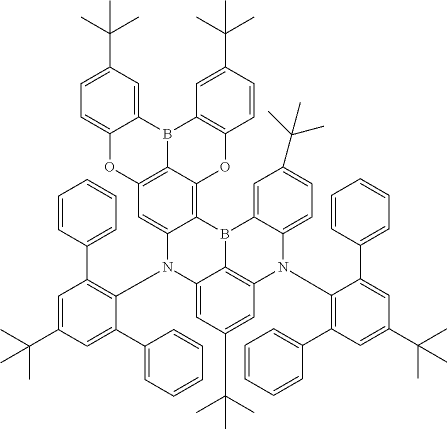 [SMILES: CC(C)(C)c1ccc2c(c1)B1c3cc(C(C)(C)C)ccc3Oc3c1c(cc1c3B3c4cc(C(C)(C)C)ccc4N(c4c(-c5ccccc5)cc(C(C)(C)C)cc4-c4ccccc4)c4cc(C(C)(C)C)cc(c43)N1c1c(-c3ccccc3)cc(C(C)(C)C)cc1-c1ccccc1)O2]

1 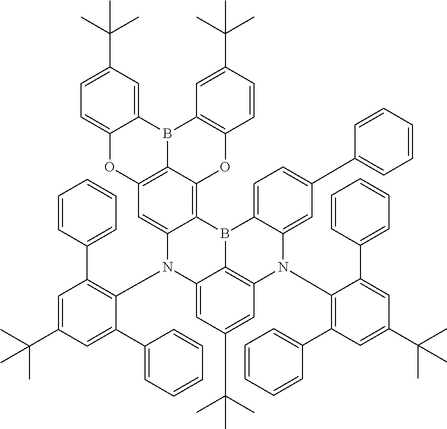 [SMILES: CC(C)(C)c1ccc2c(c1)B1c3cc(C(C)(C)C)ccc3Oc3c1c(cc1c3B3c4ccc(-c5ccccc5)cc4N(c4c(-c5ccccc5)cc(C(C)(C)C)cc4-c4ccccc4)c4cc(C(C)(C)C)cc(c43)N1c1c(-c3ccccc3)cc(C(C)(C)C)cc1-c1ccccc1)O2]
16 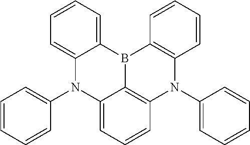 [SMILES: c1ccc(N2c3ccccc3B3c4ccccc4N(c4ccccc4)c4cccc2c43)cc1]
B 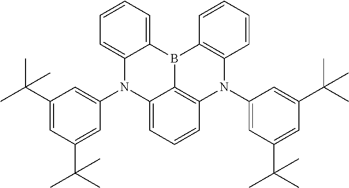 [SMILES: CC(C)(C)c1cc(N2c3ccccc3B3c4ccccc4N(c4cc(C(C)(C)C)cc(C(C)(C)C)c4)c4cccc2c43)cc(C(C)(C)C)c1]
C 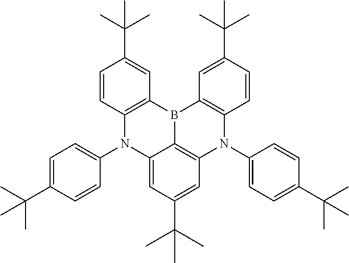 [SMILES: CC(C)(C)c1ccc(N2c3ccc(C(C)(C)C)cc3B3c4cc(C(C)(C)C)ccc4N(c4ccc(C(C)(C)C)cc4)c4cc(C(C)(C)C)cc2c43)cc1]
D

Referring to Table 2, organic light-emitting devices according to one or more embodiments were found to have relatively low driving voltage and roll-off ratio, and excellent external quantum efficiency, relative efficiency, and relative lifespan. In addition, the organic light-emitting devices of Examples 1 and 2 were found to have lower driving voltage and roll-off ratio, and significantly superior external quantum efficiency, relative efficiency, and relative lifetime compared to organic light-emitting devices of Comparative Examples 1 to 3.

The heterocyclic compound represented by Formula 1 according to one or more embodiments has excellent light luminescence characteristics and charge mobility characteristics. Accordingly, electronic devices employing at least one of the heterocyclic compounds represented by Formula 1, for example, organic light-emitting devices, may have relatively low driving voltage, high efficiency, and/or long lifespan characteristics. Therefore, high-quality organic light-emitting devices may be implemented using the heterocyclic compound represented by Formula 1. In addition, diagnostic compositions with excellent diagnostic efficiency can be implemented by using the heterocyclic compound represented by Formula 1.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

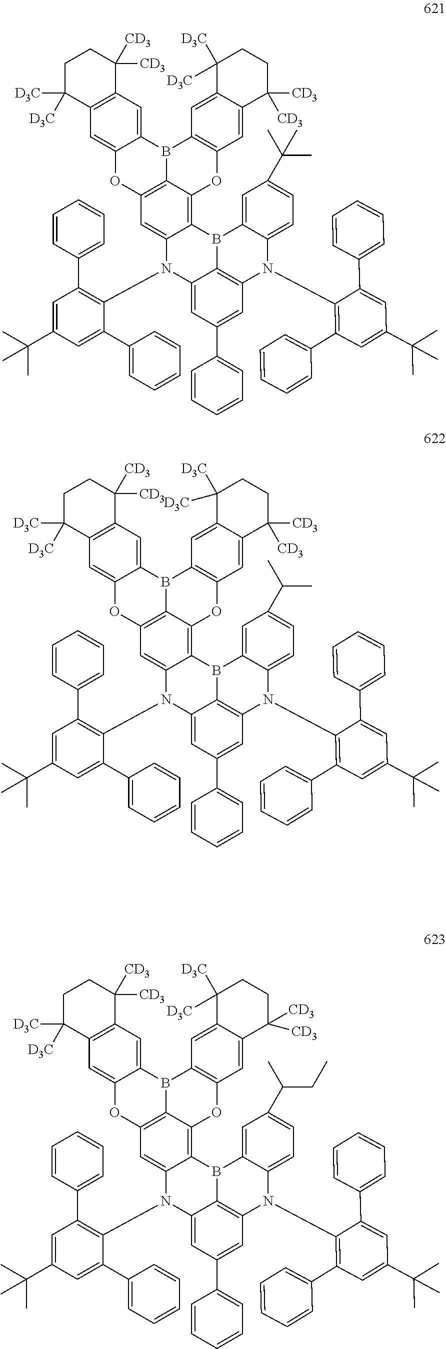

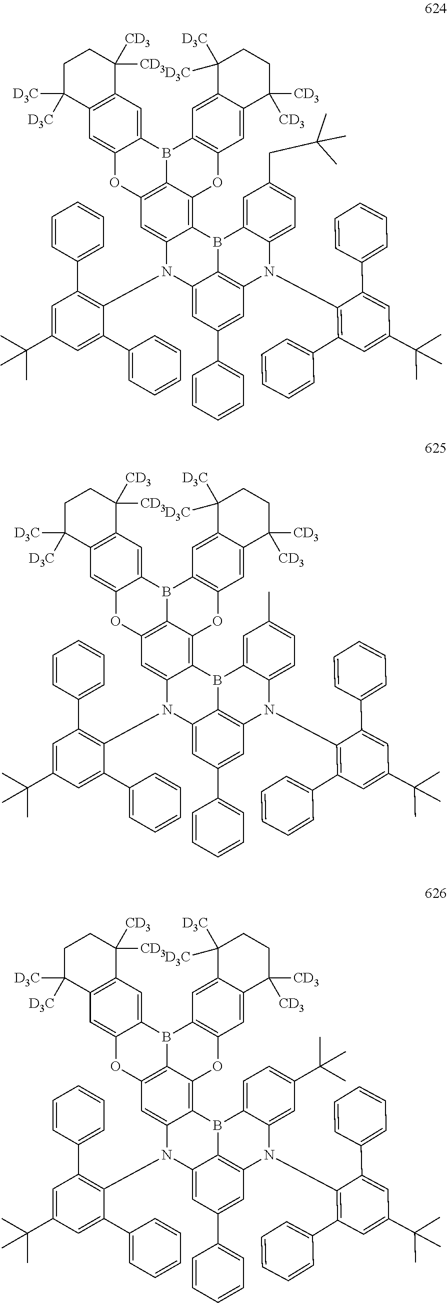

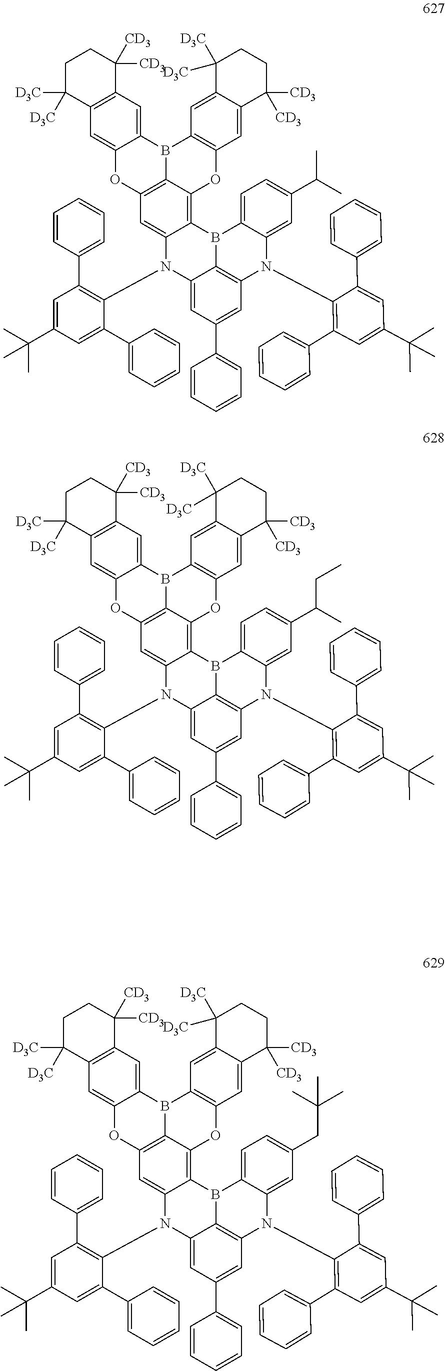

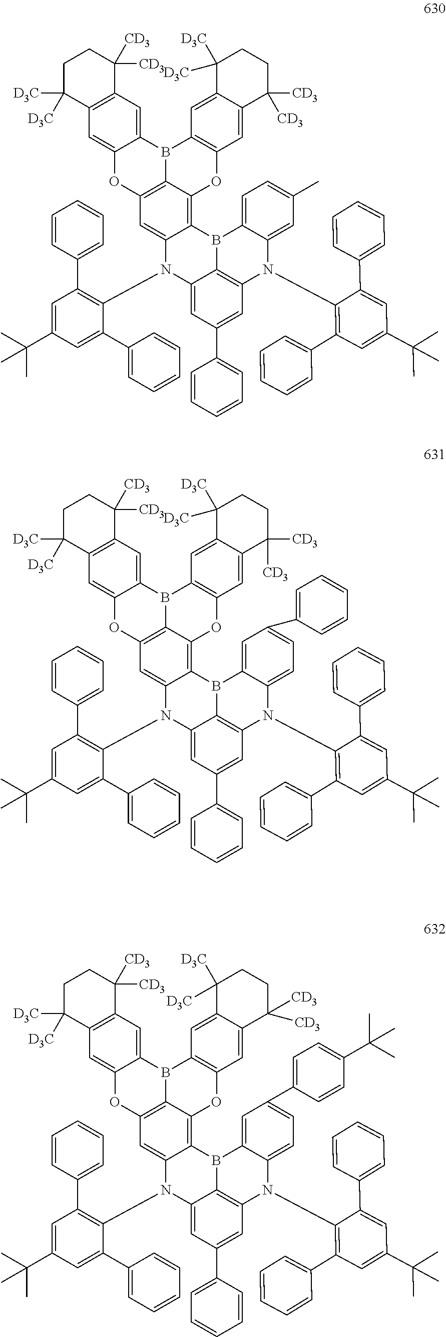

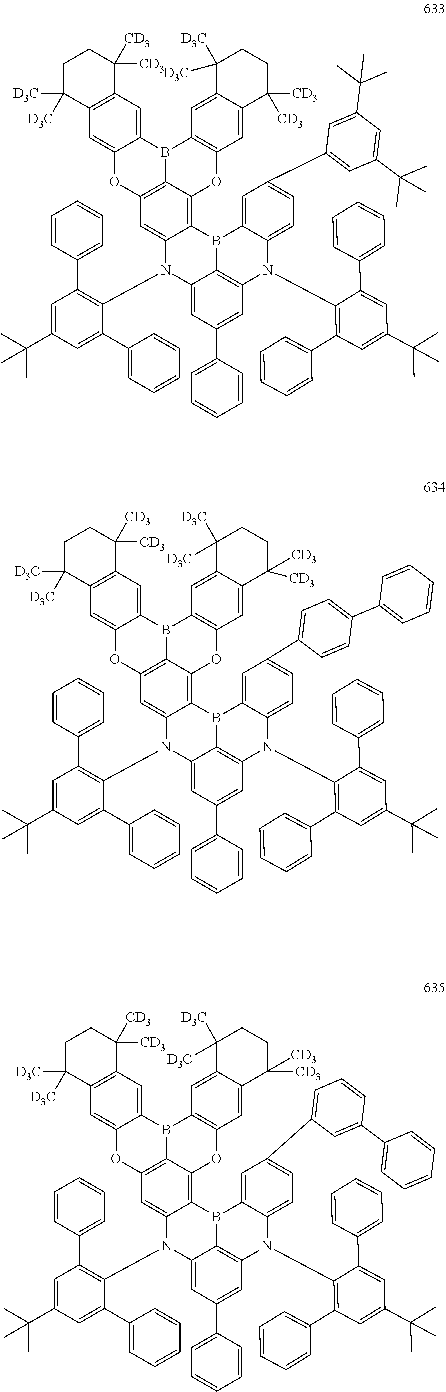

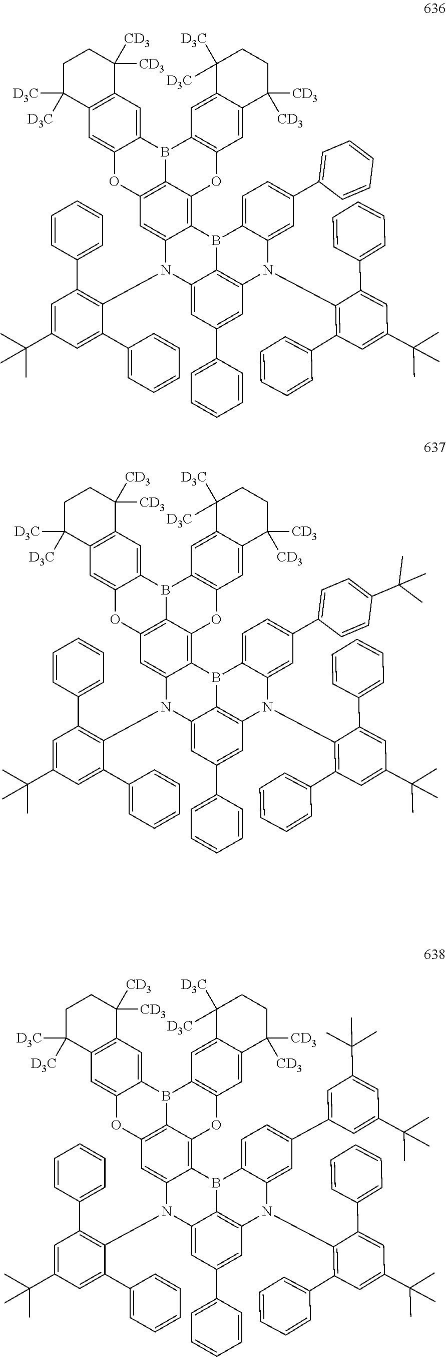

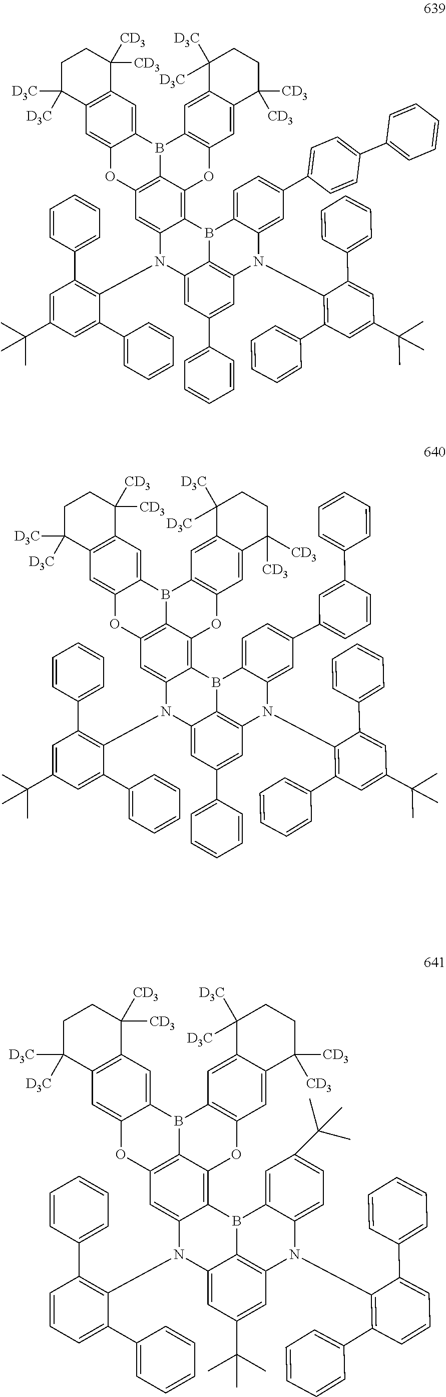

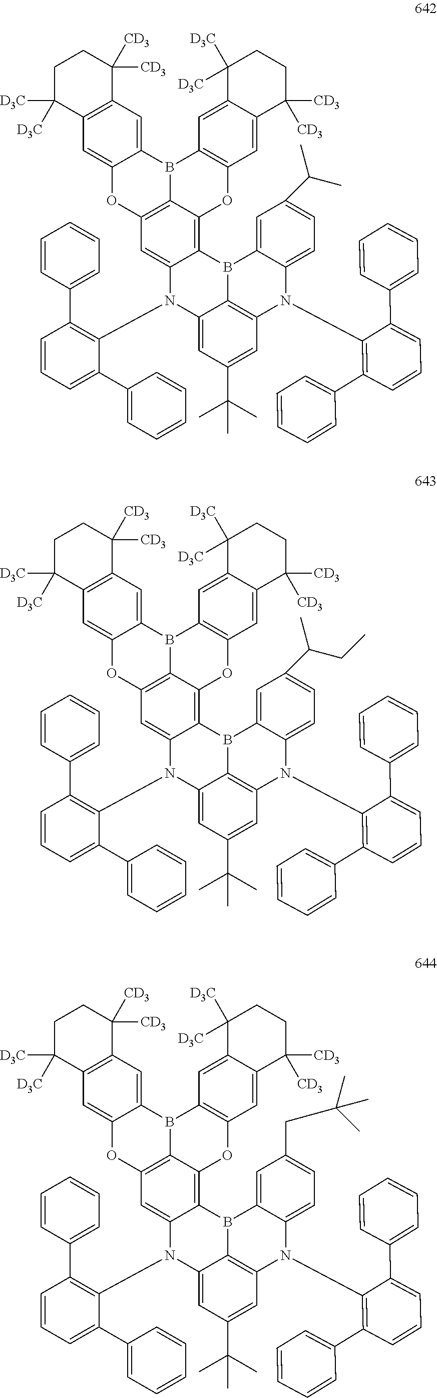

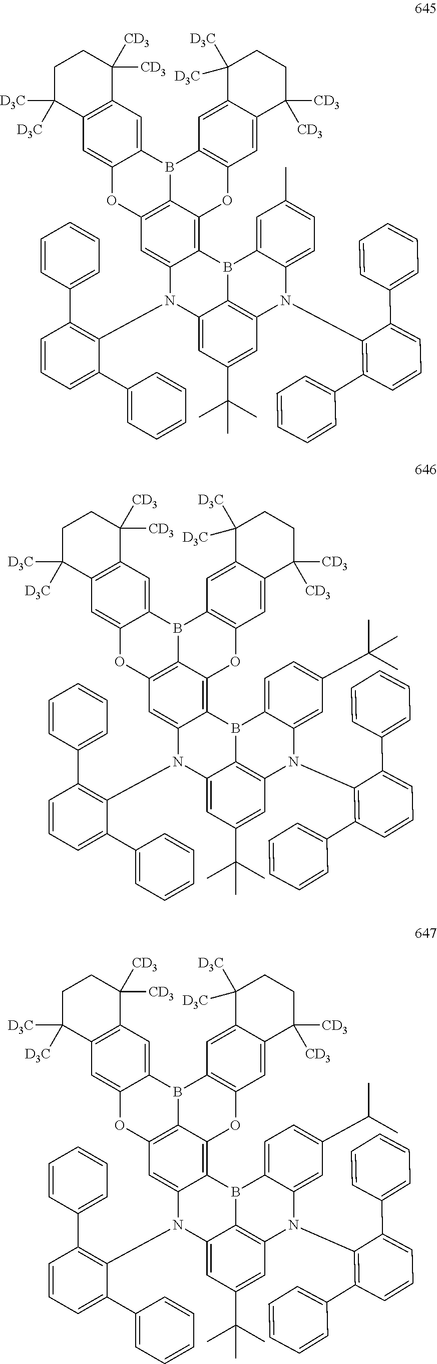

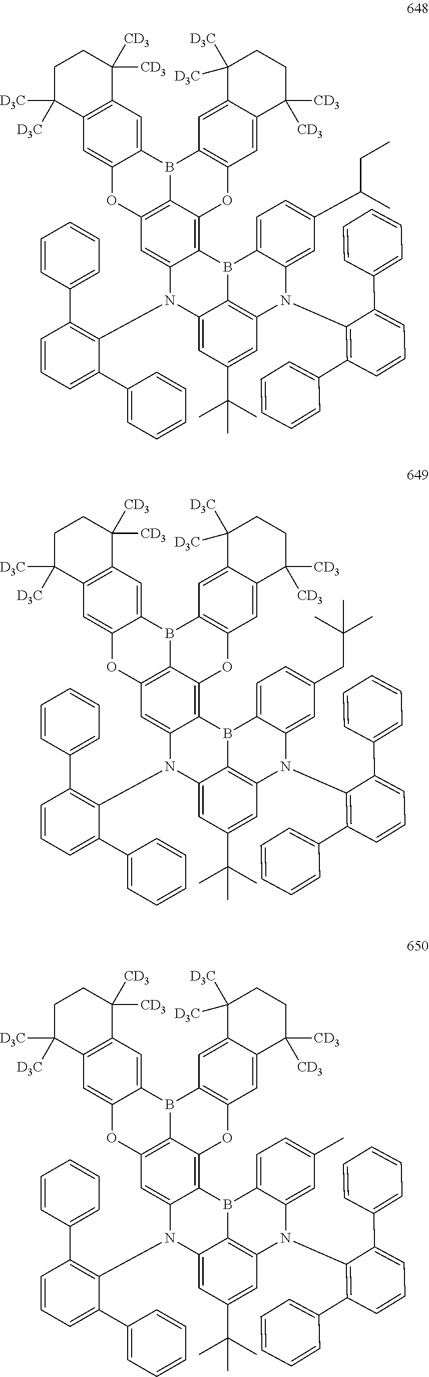

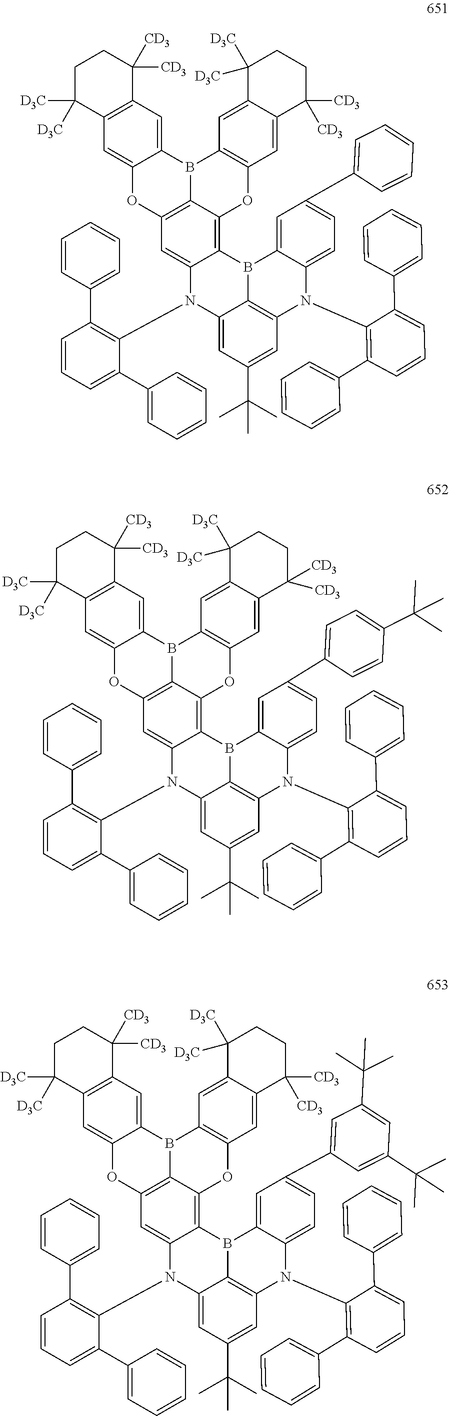

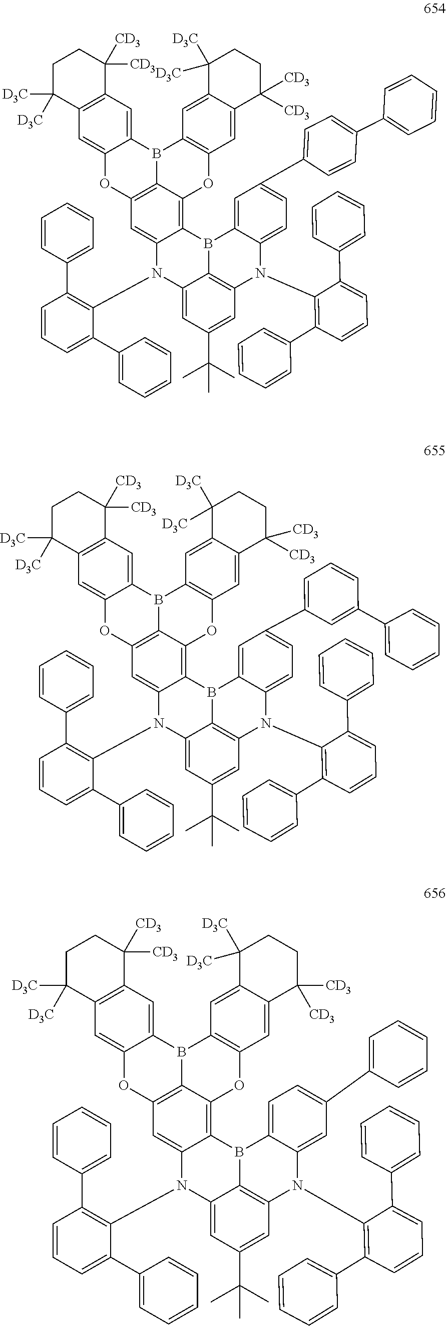

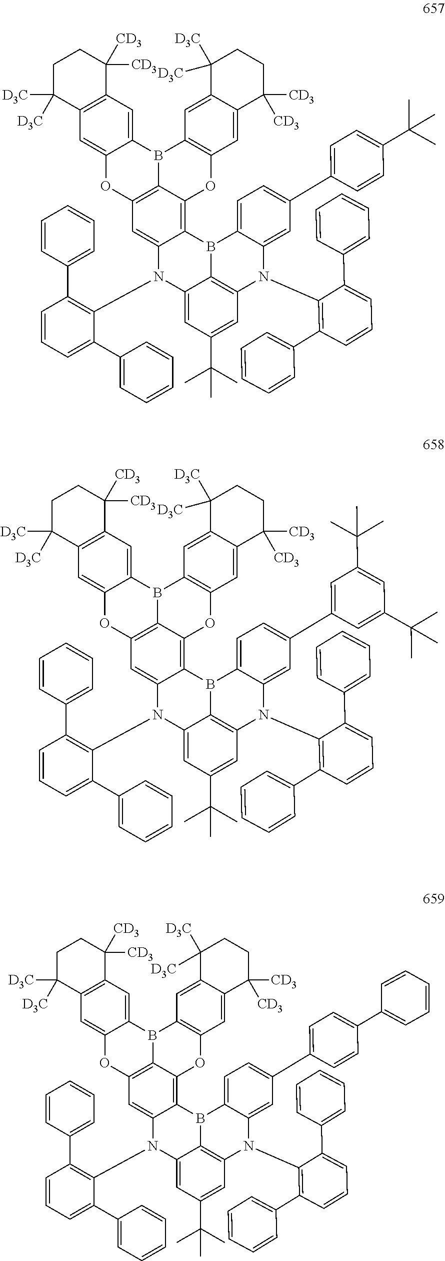

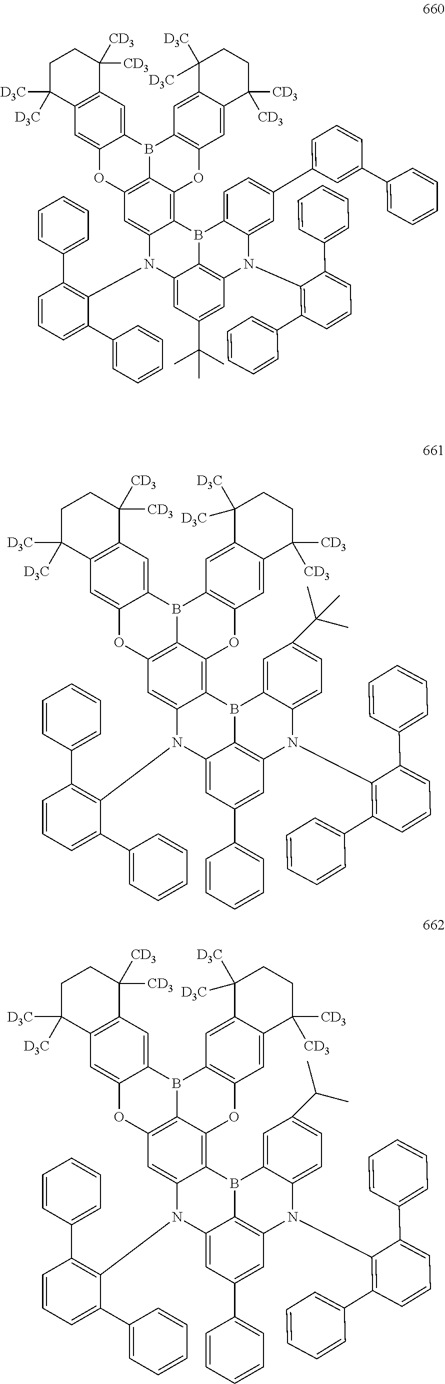

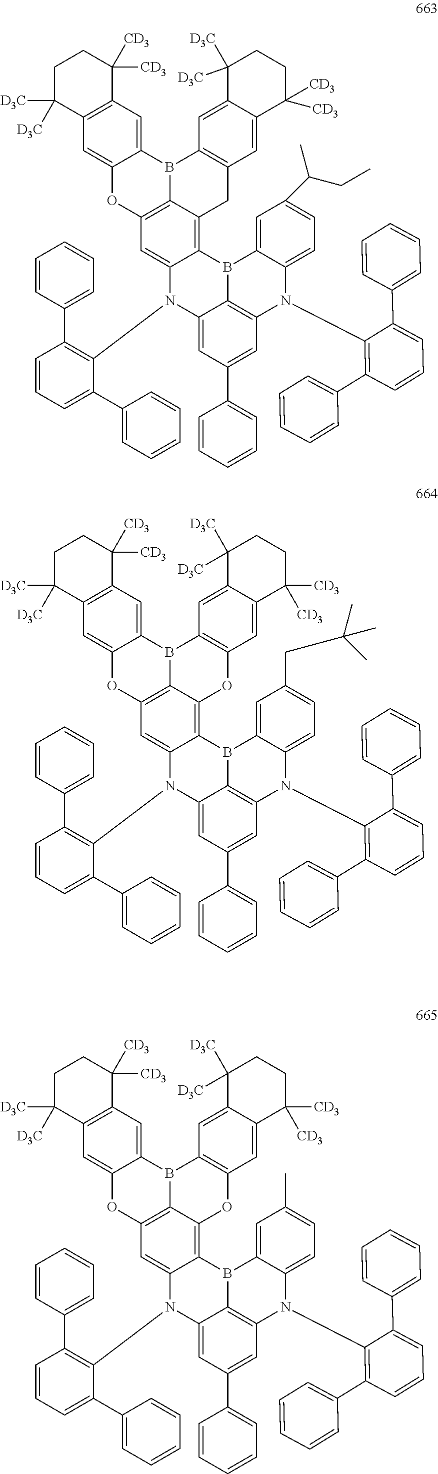

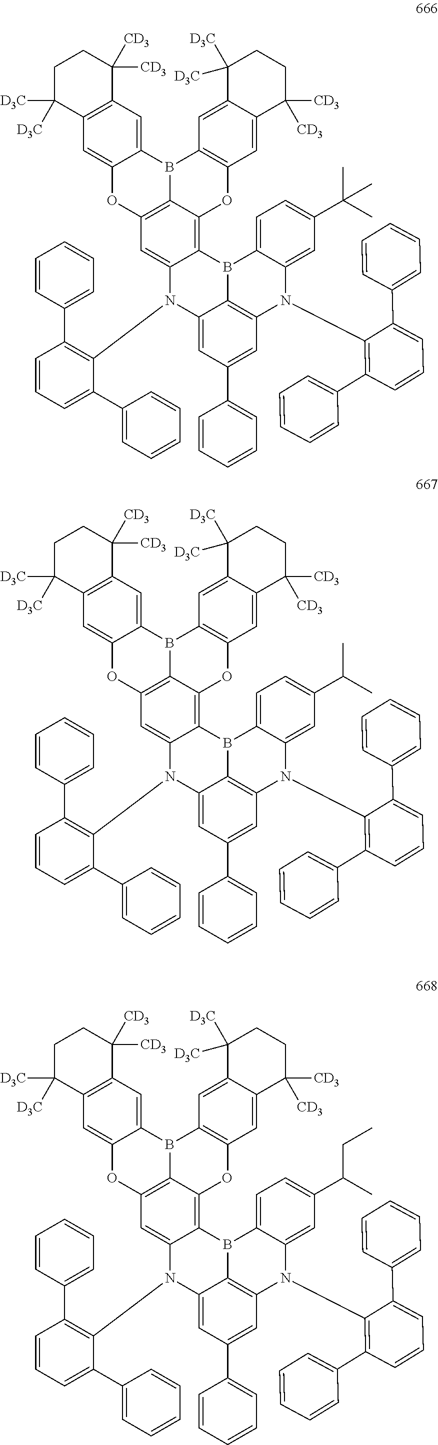

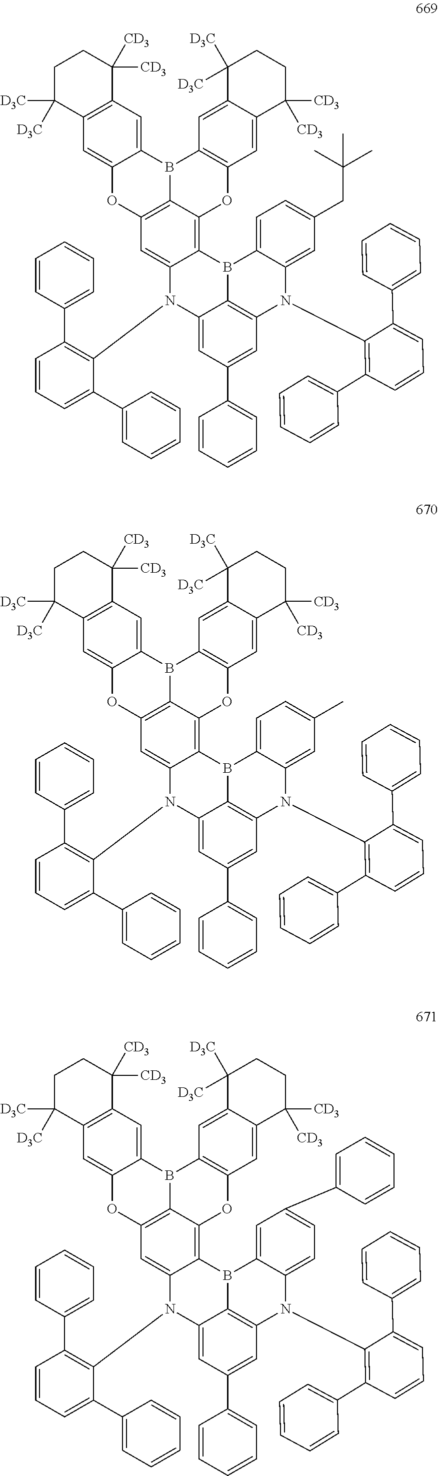

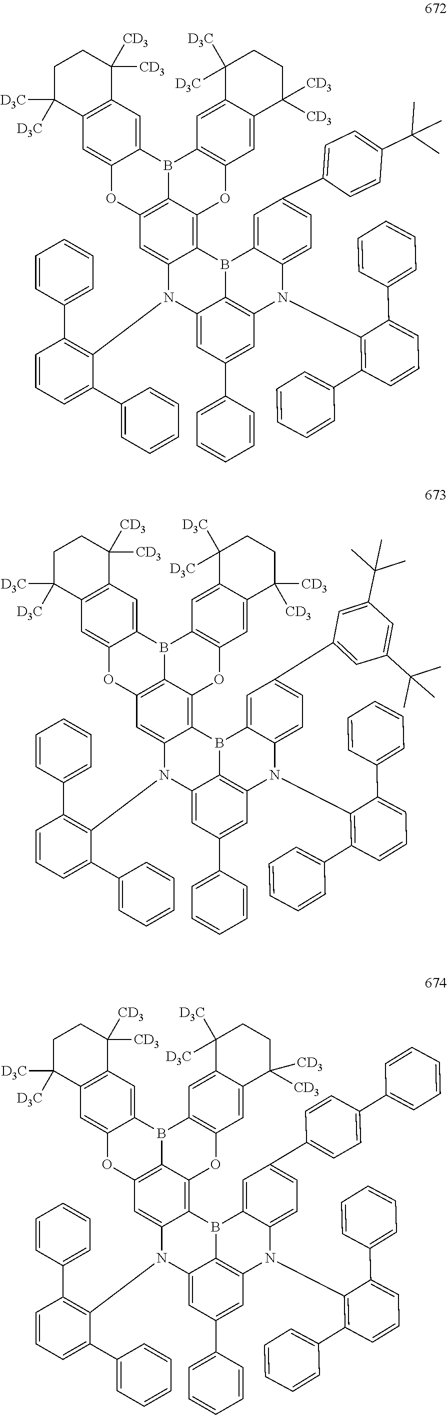

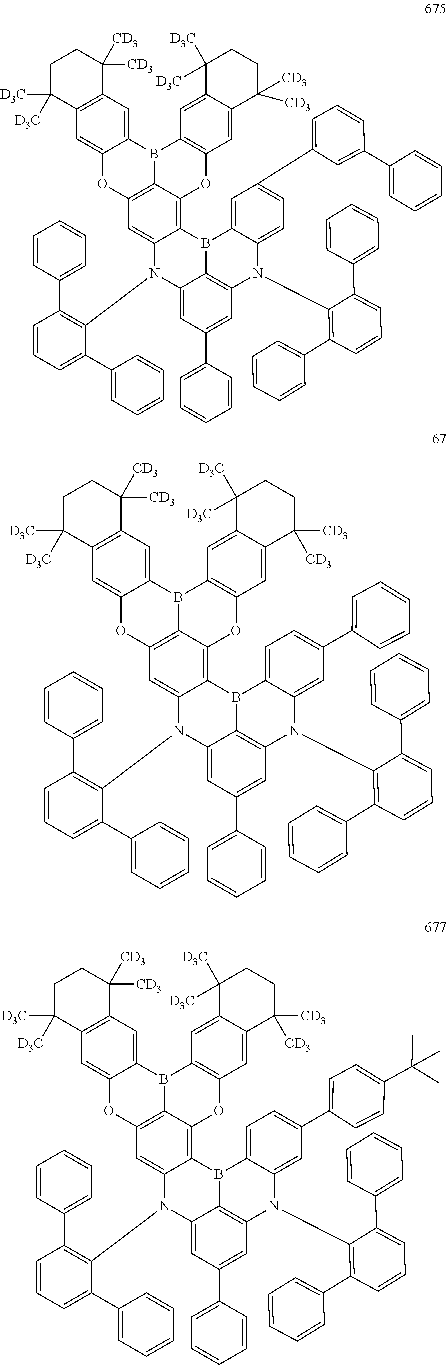

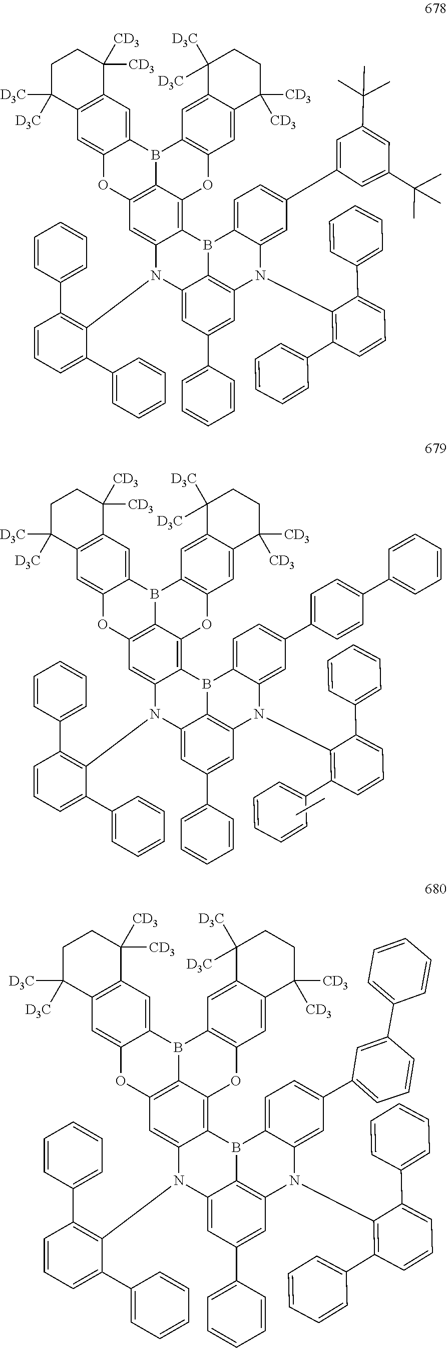

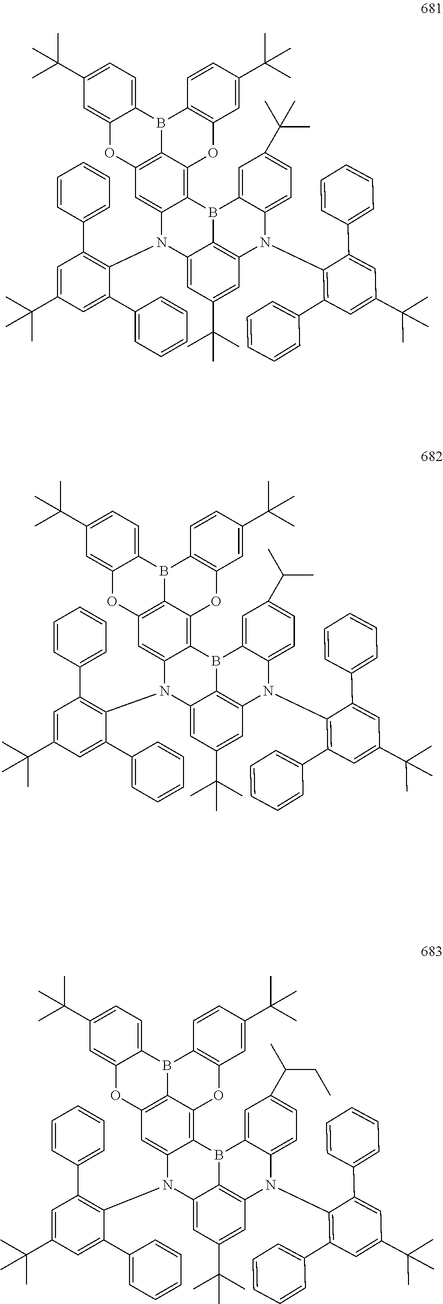

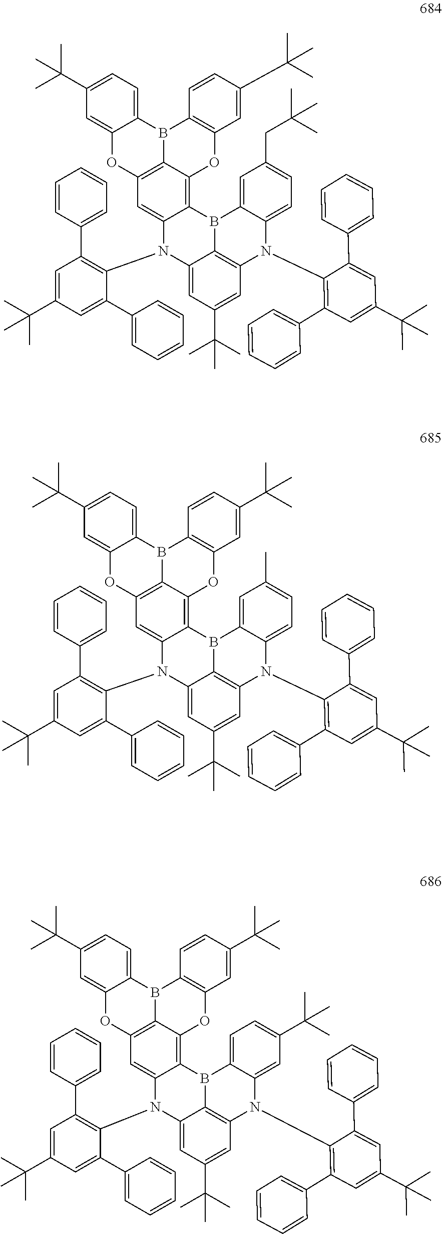

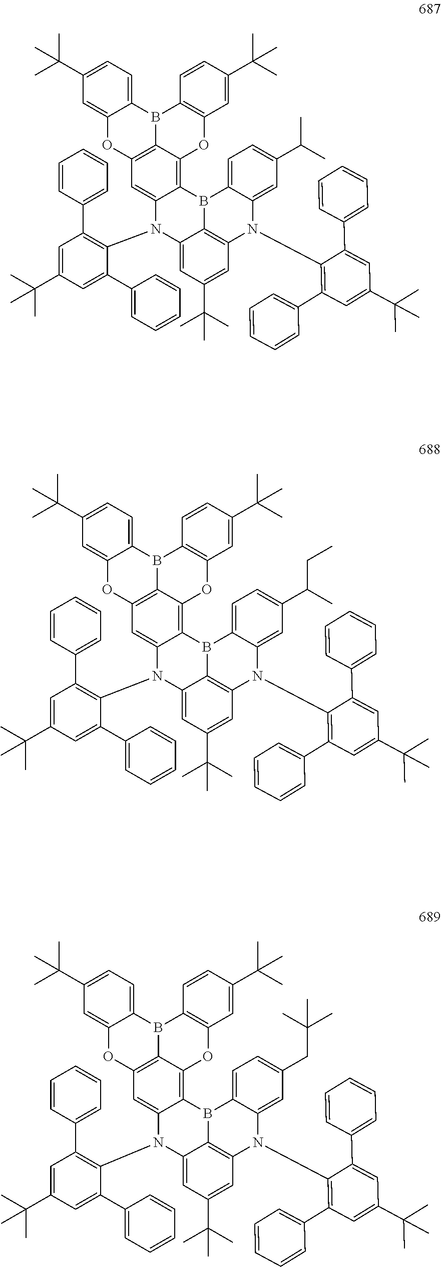

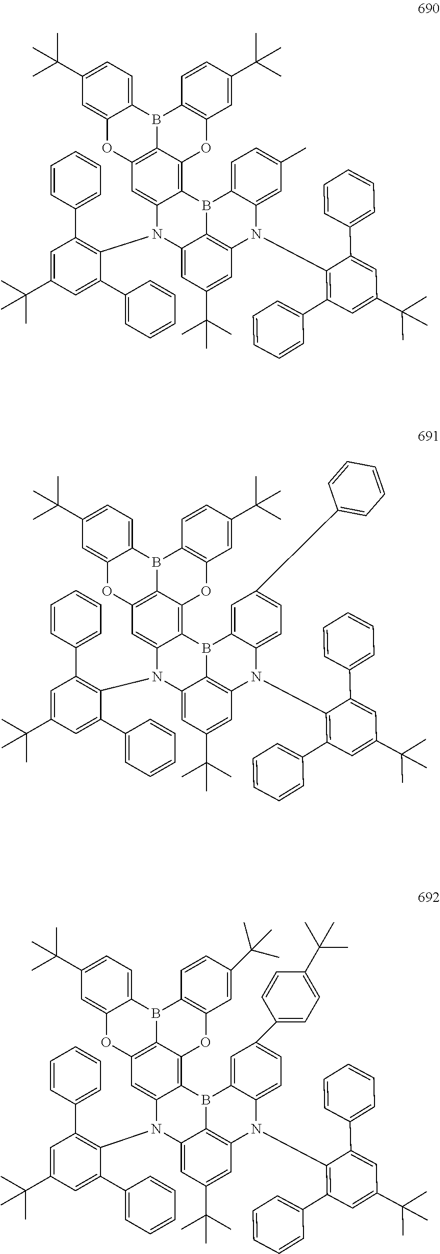

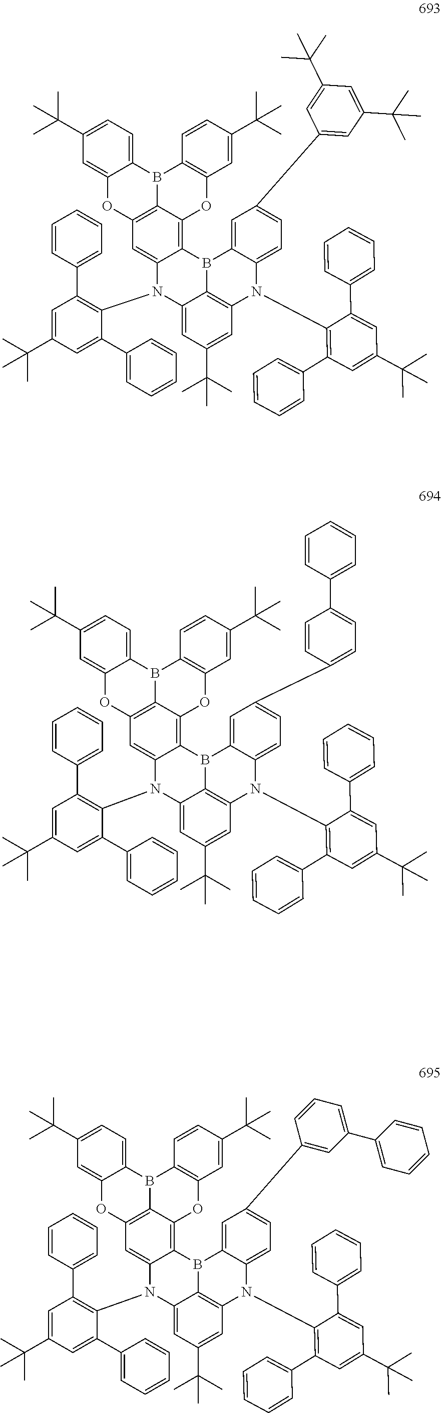

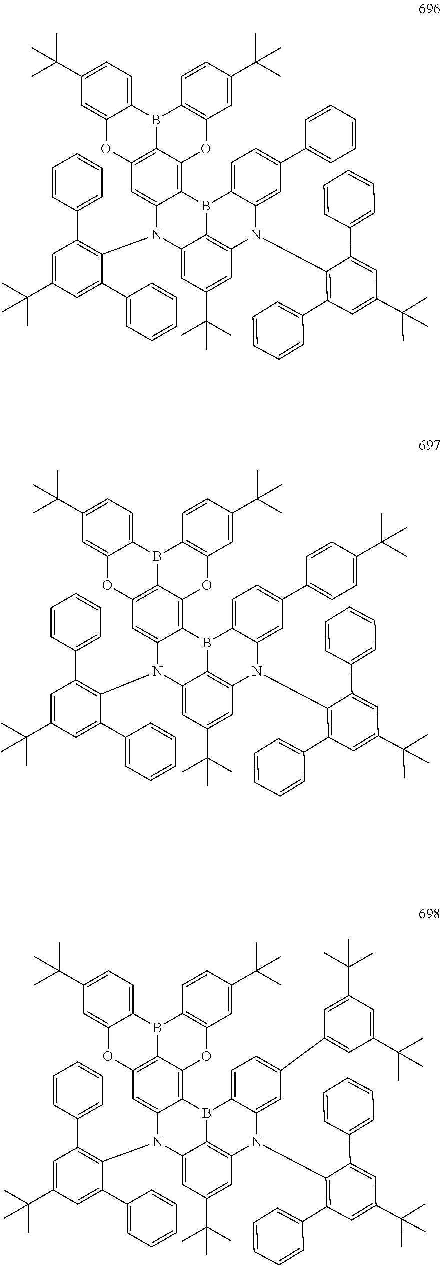

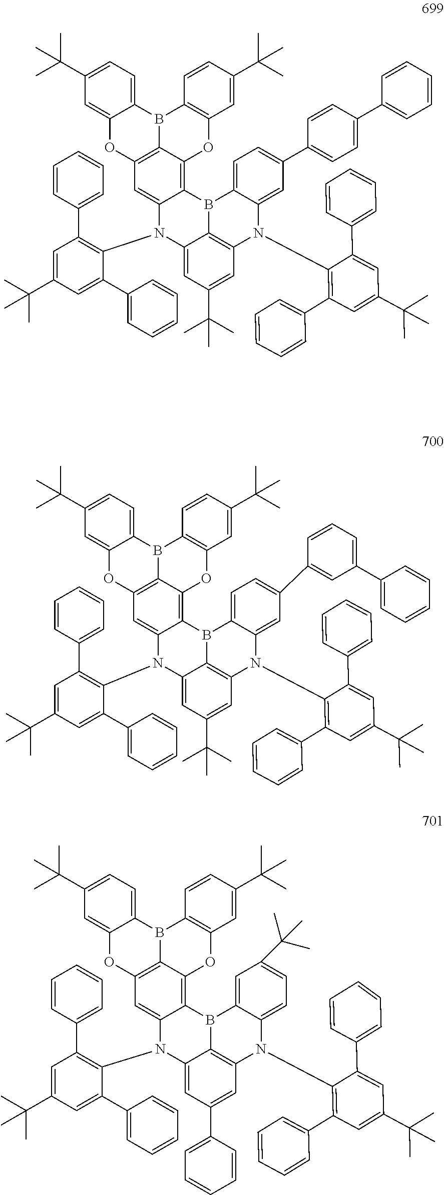

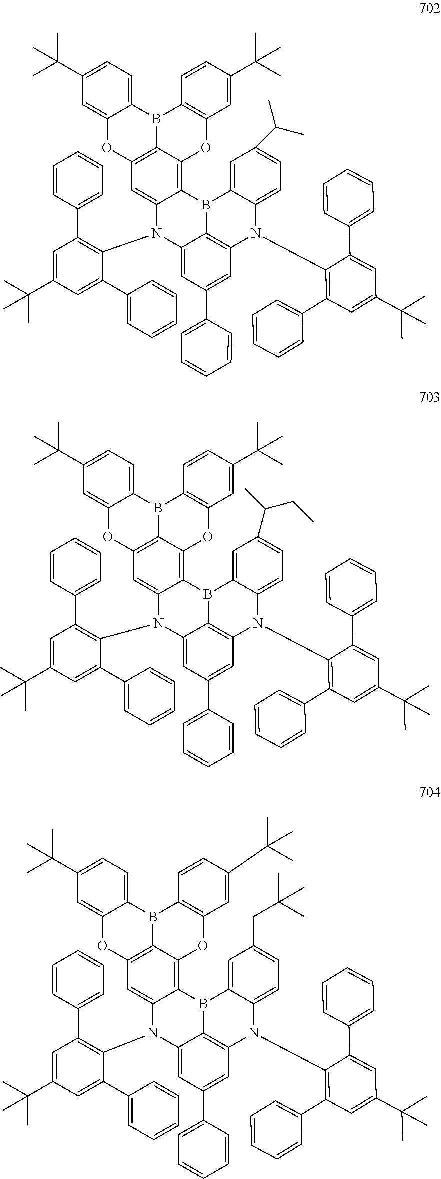

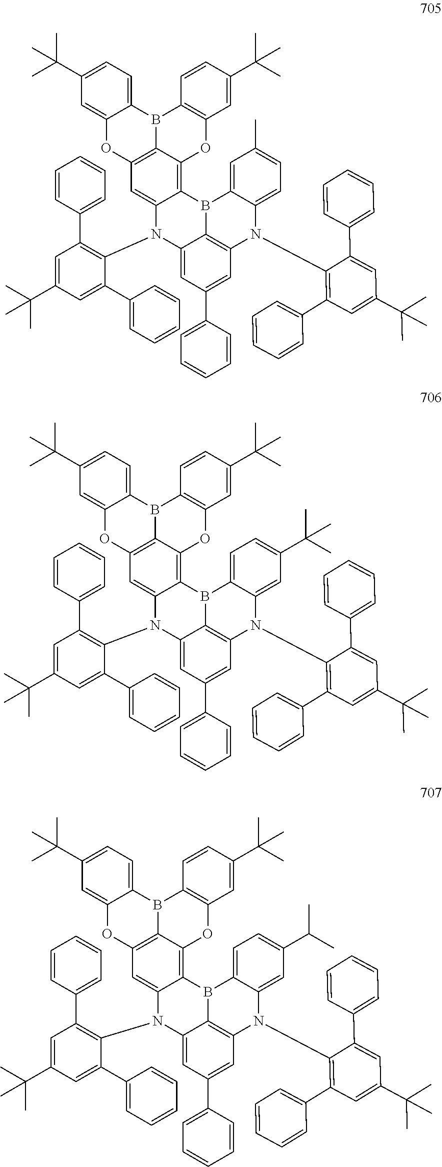

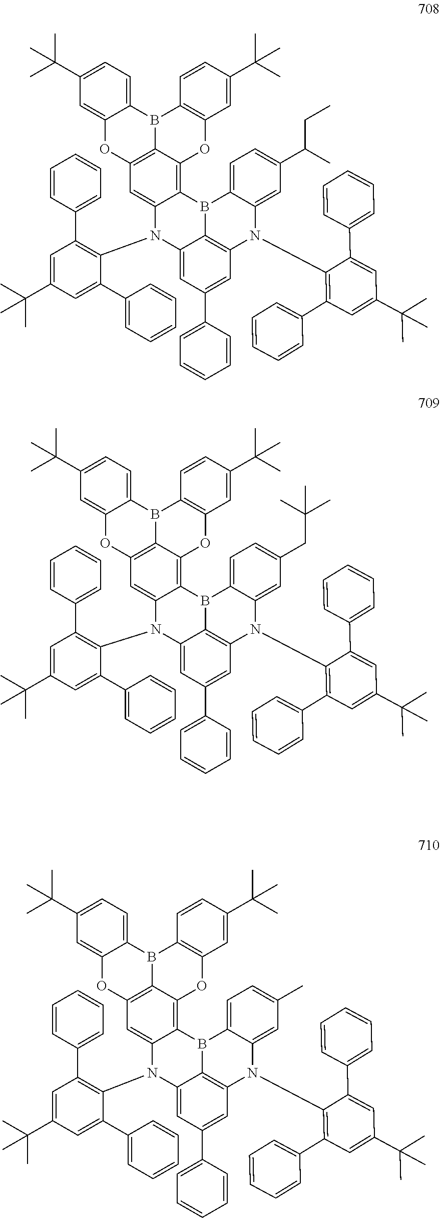

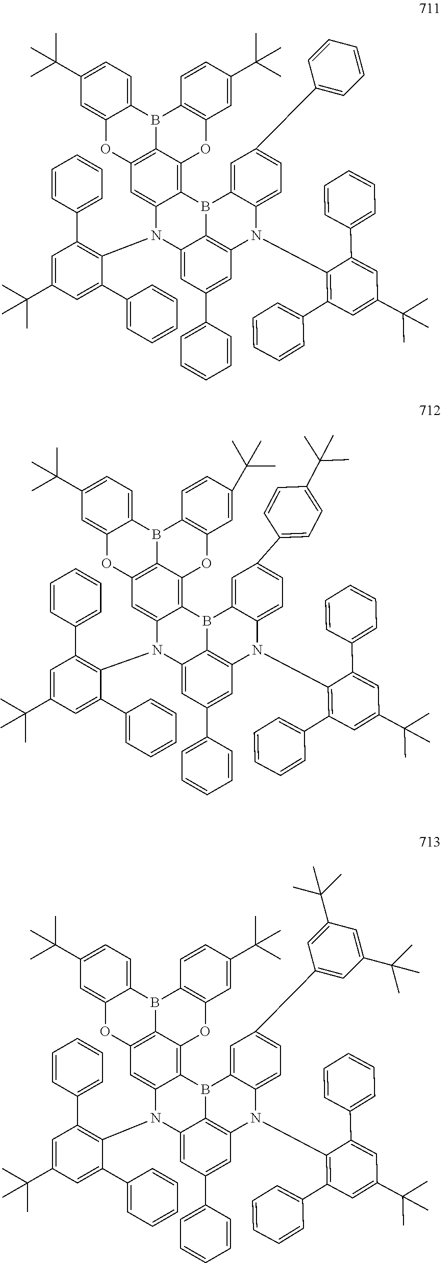

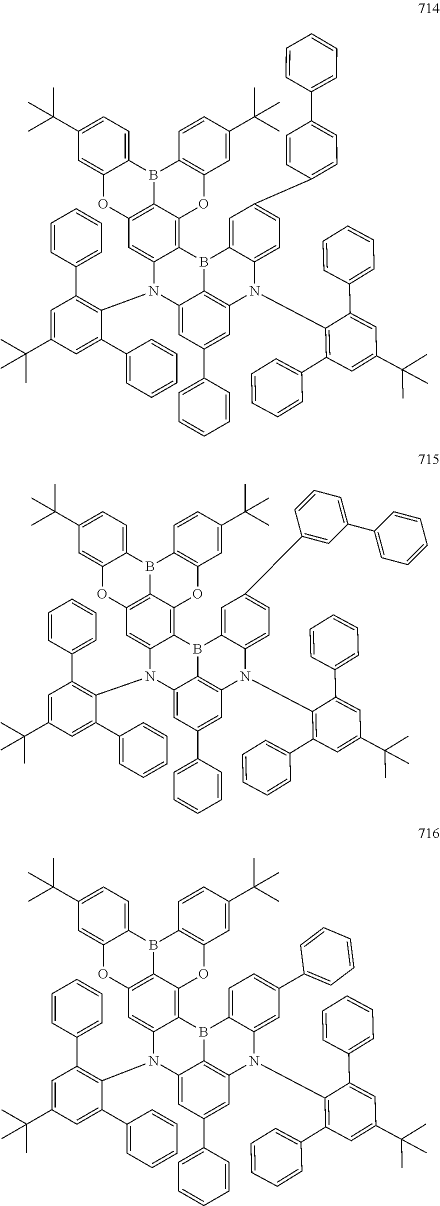

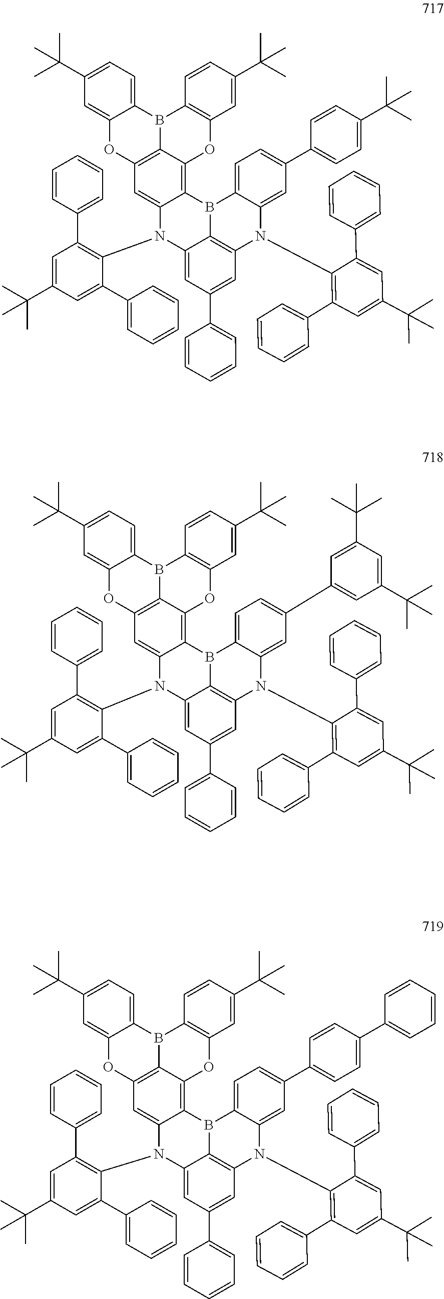

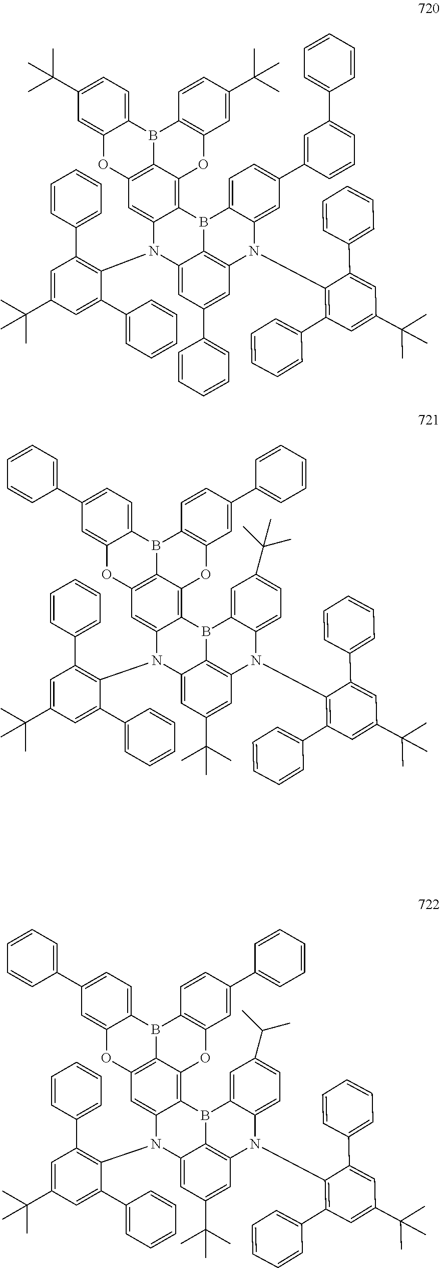

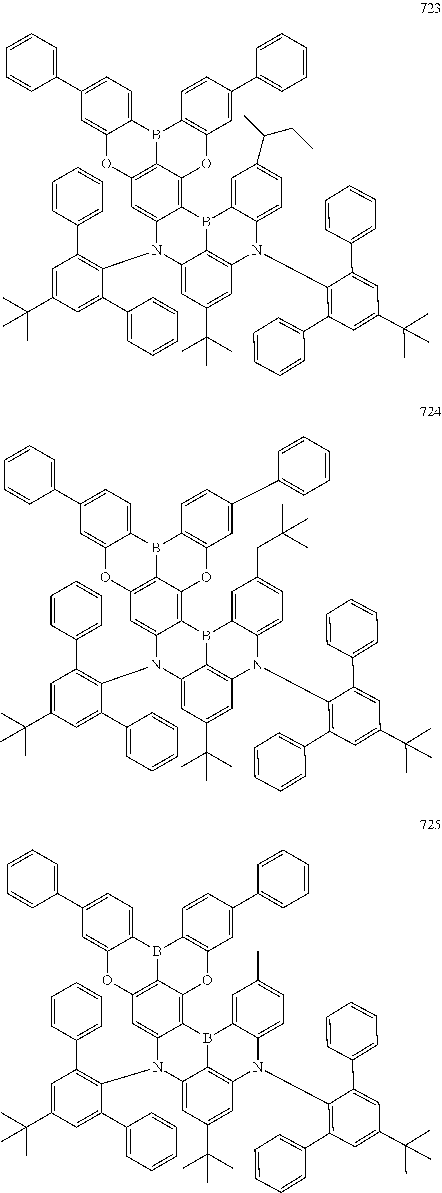

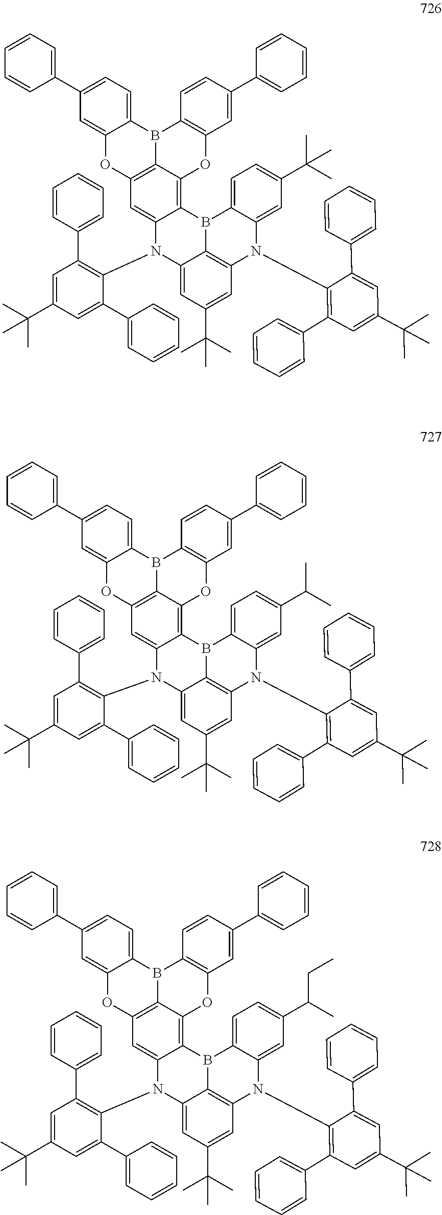

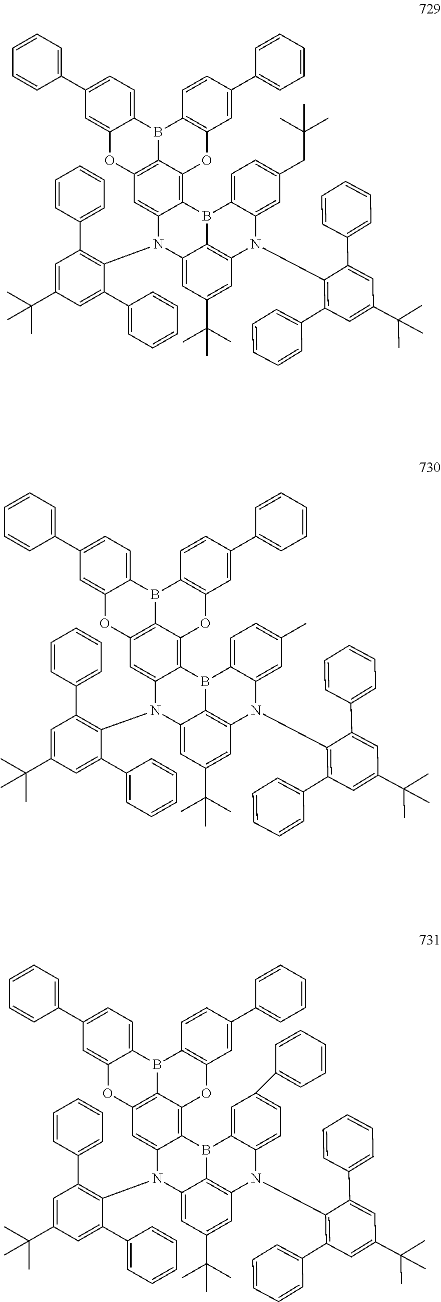

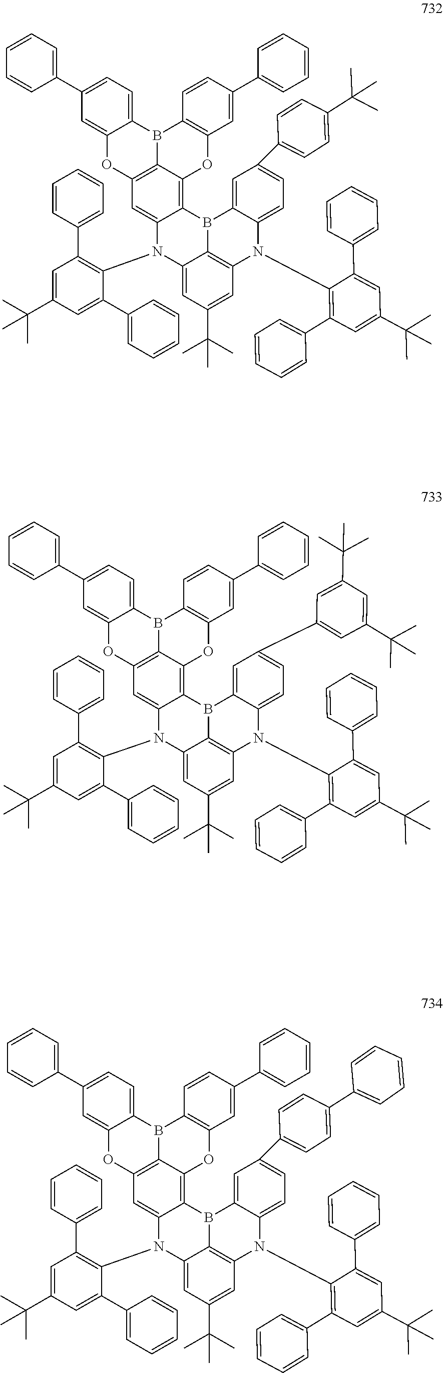

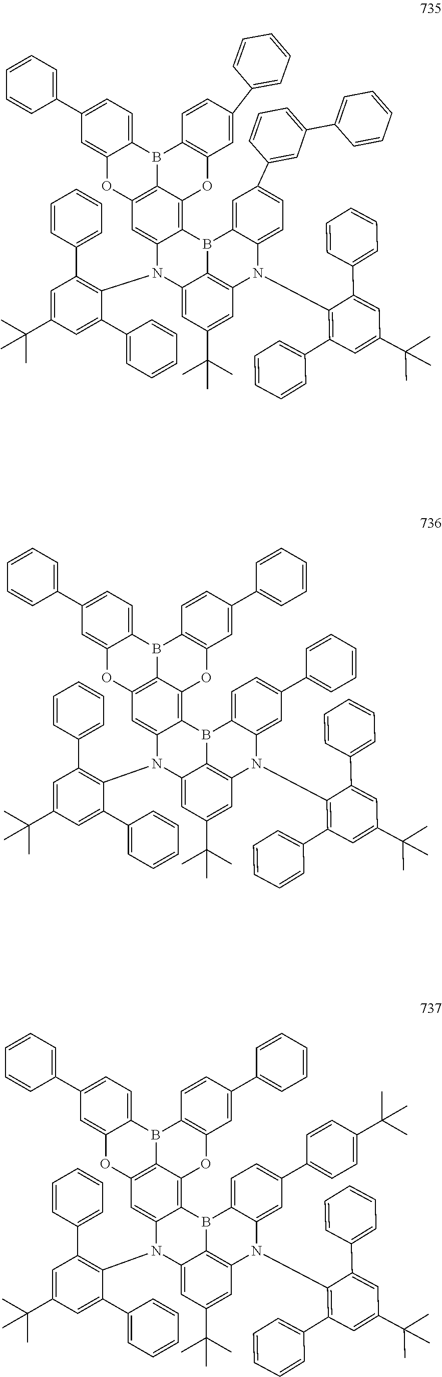

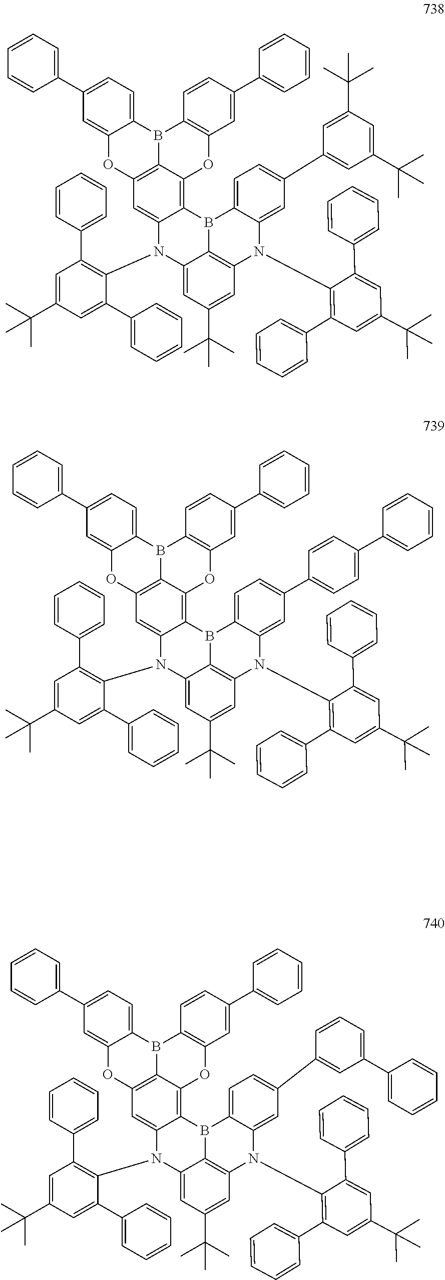

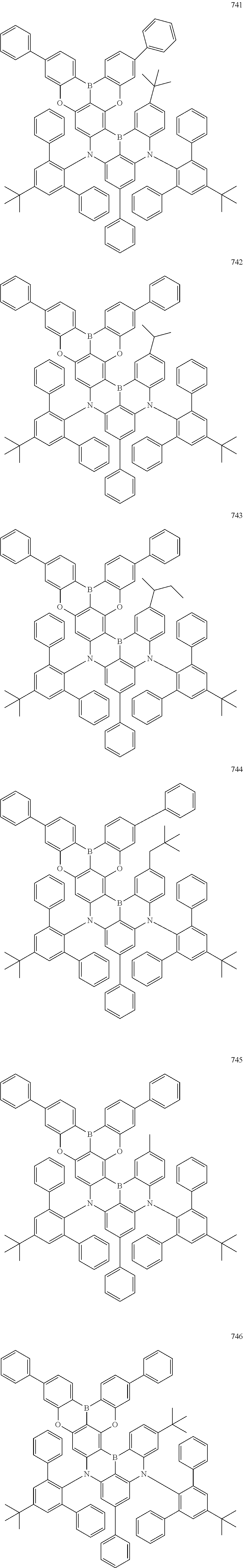

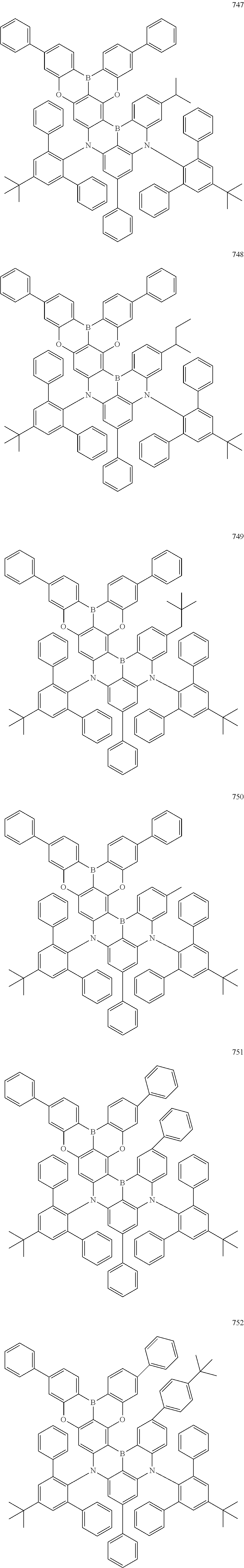

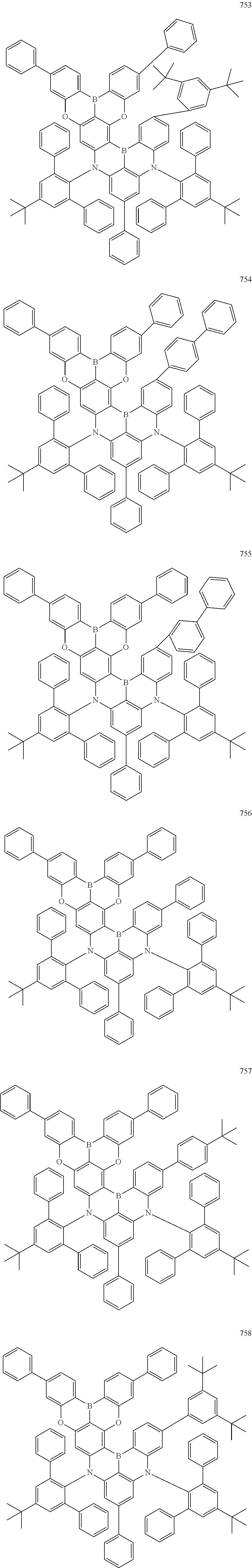

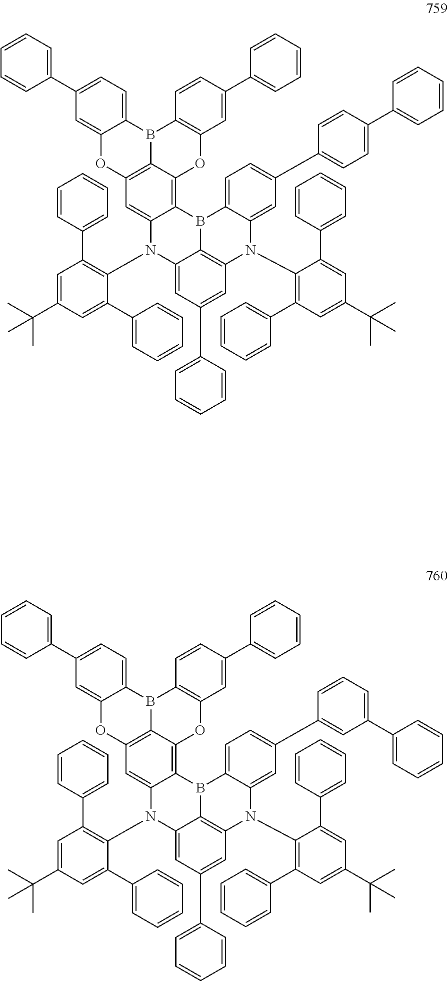 [SMILES: CC(C)(C)c1cc(-c2ccccc2)c(N2c3cc(-c4ccc(-c5ccccc5)cc4)ccc3B3c4c2cc(-c2ccccc2)cc4N(c2c(-c4ccccc4)cc(C(C)(C)C)cc2-c2ccccc2)c2cc4c5c(c23)Oc2cc(-c3ccccc3)ccc2B5c2ccc(-c3ccccc3)cc2O4)c(-c2ccccc2)c1 ; CC(C)(C)c1cc(-c2ccccc2)c(N2c3cc(-c4cccc(-c5ccccc5)c4)ccc3B3c4c2cc(-c2ccccc2)cc4N(c2c(-c4ccccc4)cc(C(C)(C)C)cc2-c2ccccc2)c2cc4c5c(c23)Oc2cc(-c3ccccc3)ccc2B5c2ccc(-c3ccccc3)cc2O4)c(-c2ccccc2)c1]

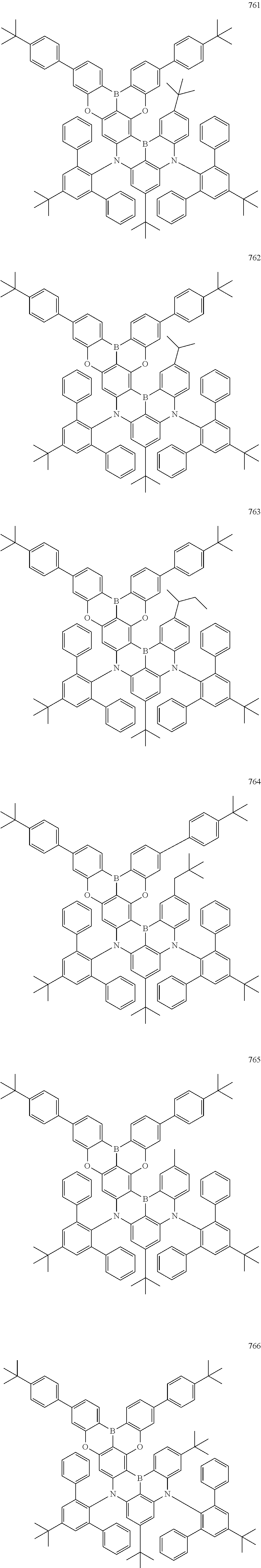

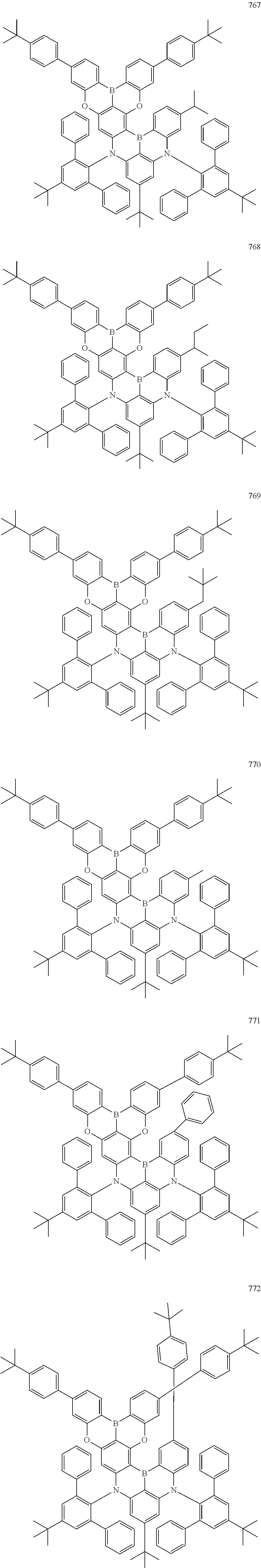

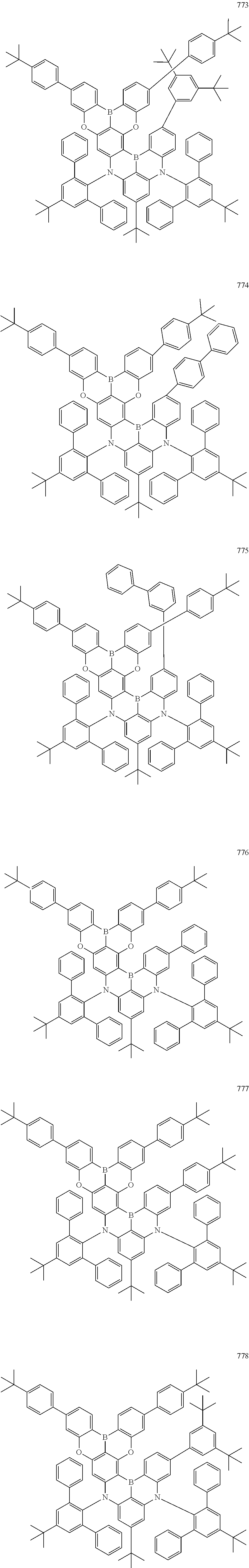

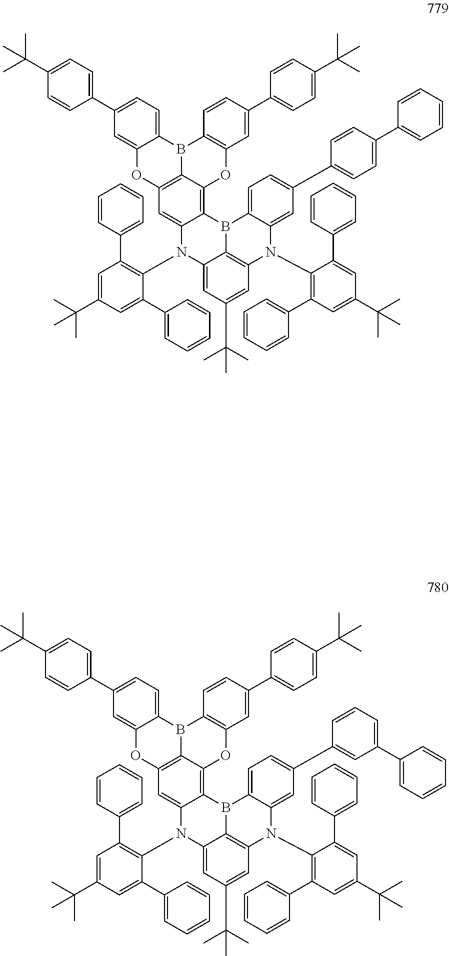 [SMILES: CC(C)(C)c1ccc(-c2ccc3c(c2)Oc2cc4c(c5c2B3c2ccc(-c3ccc(C(C)(C)C)cc3)cc2O5)B2c3ccc(-c5ccc(-c6ccccc6)cc5)cc3N(c3c(-c5ccccc5)cc(C(C)(C)C)cc3-c3ccccc3)c3cc(C(C)(C)C)cc(c32)N4c2c(-c3ccccc3)cc(C(C)(C)C)cc2-c2ccccc2)cc1 ; CC(C)(C)c1ccc(-c2ccc3c(c2)Oc2cc4c(c5c2B3c2ccc(-c3ccc(C(C)(C)C)cc3)cc2O5)B2c3ccc(-c5cccc(-c6ccccc6)c5)cc3N(c3c(-c5ccccc5)cc(C(C)(C)C)cc3-c3ccccc3)c3cc(C(C)(C)C)cc(c32)N4c2c(-c3ccccc3)cc(C(C)(C)C)cc2-c2ccccc2)cc1]

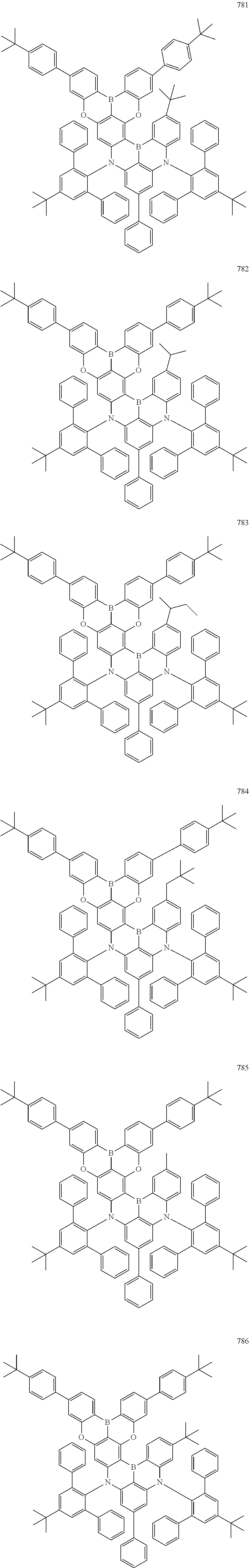

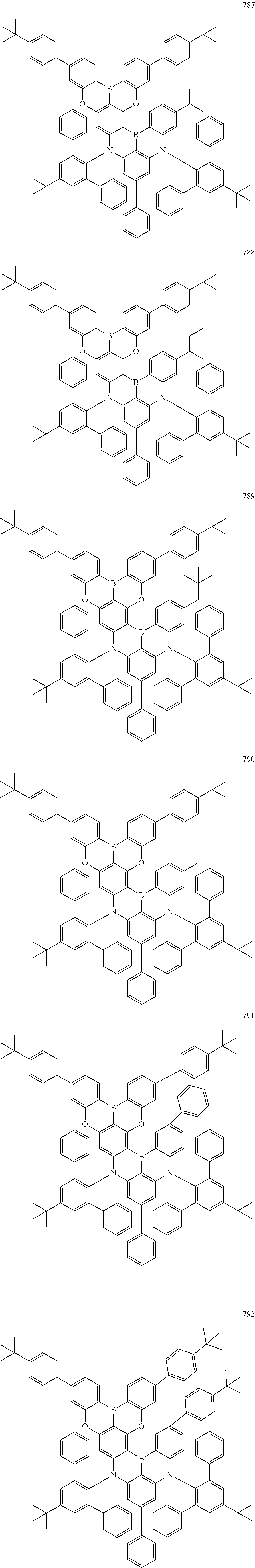

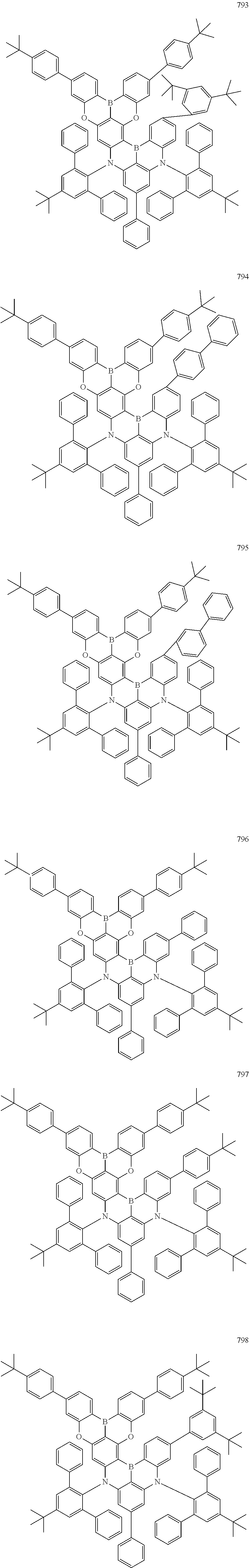

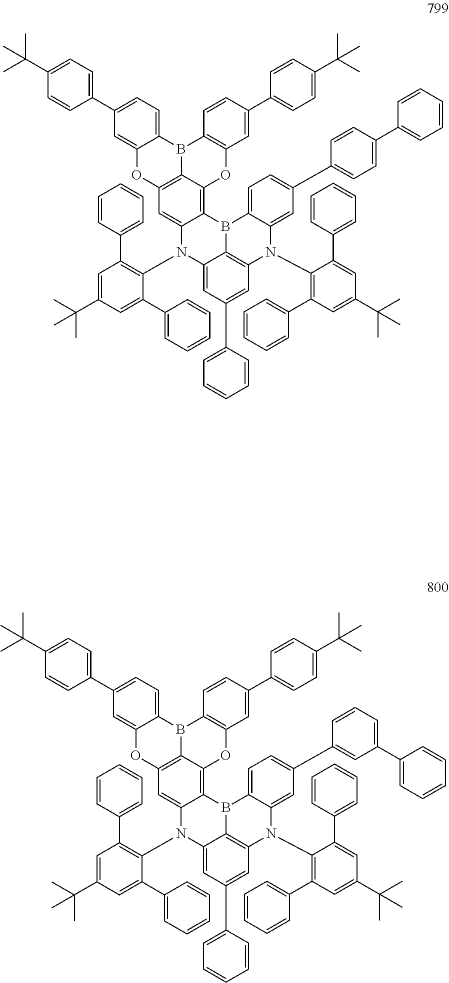 [SMILES: CC(C)(C)c1ccc(-c2ccc3c(c2)Oc2cc4c(c5c2B3c2ccc(-c3ccc(C(C)(C)C)cc3)cc2O5)B2c3ccc(-c5ccc(-c6ccccc6)cc5)cc3N(c3c(-c5ccccc5)cc(C(C)(C)C)cc3-c3ccccc3)c3cc(-c5ccccc5)cc(c32)N4c2c(-c3ccccc3)cc(C(C)(C)C)cc2-c2ccccc2)cc1 ; CC(C)(C)c1ccc(-c2ccc3c(c2)Oc2cc4c(c5c2B3c2ccc(-c3ccc(C(C)(C)C)cc3)cc2O5)B2c3ccc(-c5cccc(-c6ccccc6)c5)cc3N(c3c(-c5ccccc5)cc(C(C)(C)C)cc3-c3ccccc3)c3cc(-c5ccccc5)cc(c32)N4c2c(-c3ccccc3)cc(C(C)(C)C)cc2-c2ccccc2)cc1]

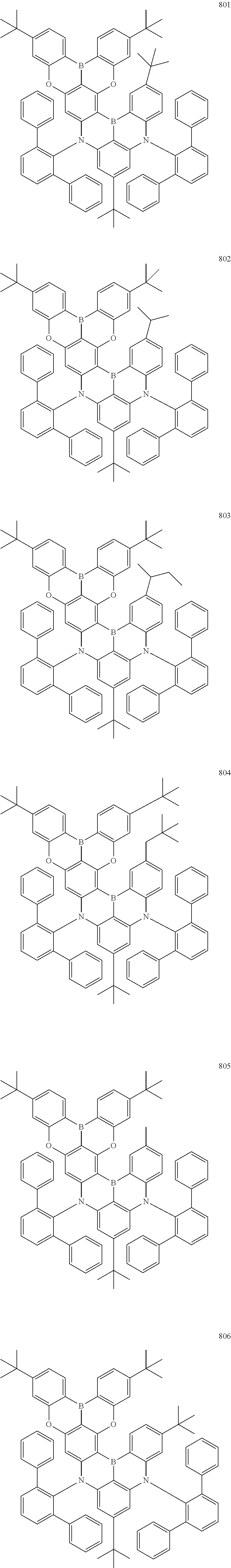

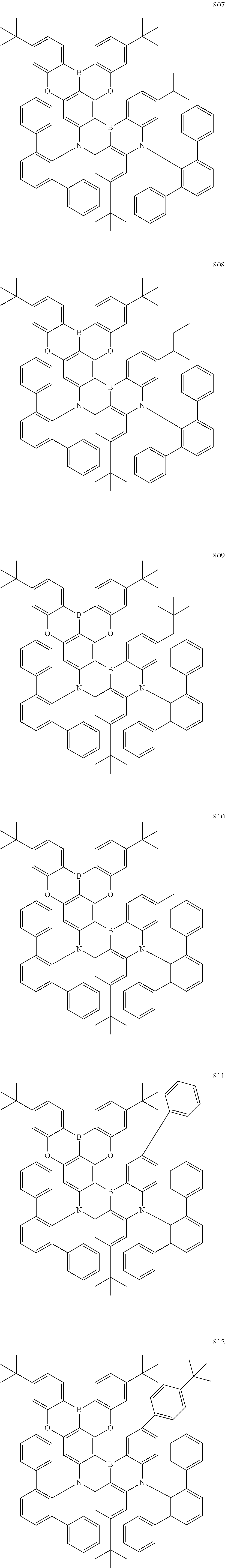

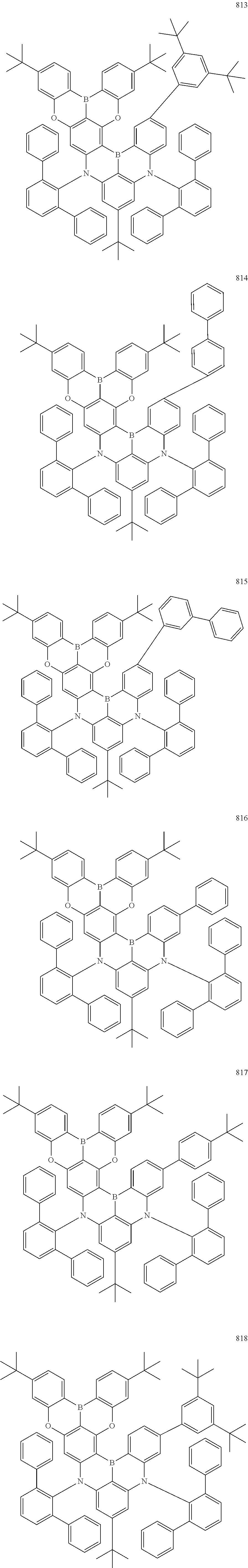

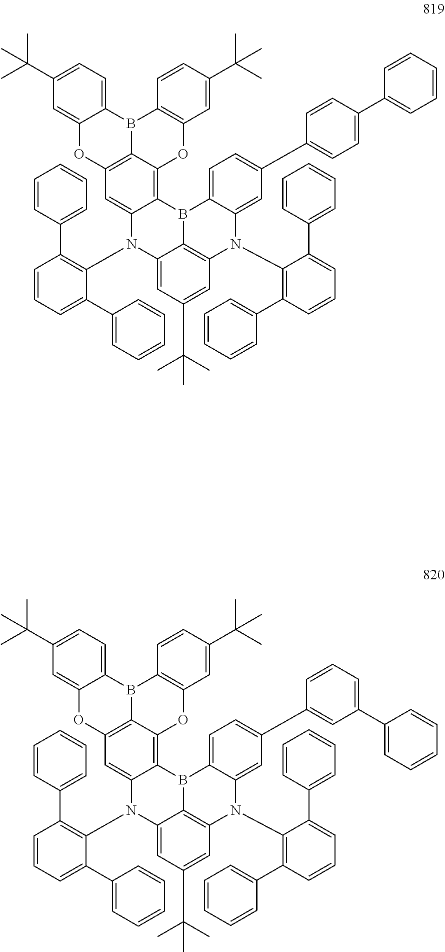 [SMILES: CC(C)(C)c1ccc2c(c1)Oc1cc3c(c4c1B2c1ccc(C(C)(C)C)cc1O4)B1c2ccc(-c4ccc(-c5ccccc5)cc4)cc2N(c2c(-c4ccccc4)cccc2-c2ccccc2)c2cc(C(C)(C)C)cc(c21)N3c1c(-c2ccccc2)cccc1-c1ccccc1 ; CC(C)(C)c1ccc2c(c1)Oc1cc3c(c4c1B2c1ccc(C(C)(C)C)cc1O4)B1c2ccc(-c4cccc(-c5ccccc5)c4)cc2N(c2c(-c4ccccc4)cccc2-c2ccccc2)c2cc(C(C)(C)C)cc(c21)N3c1c(-c2ccccc2)cccc1-c1ccccc1]

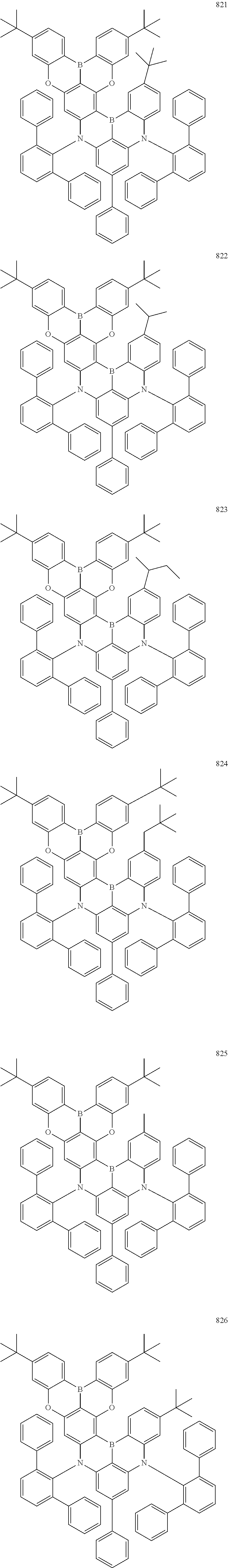

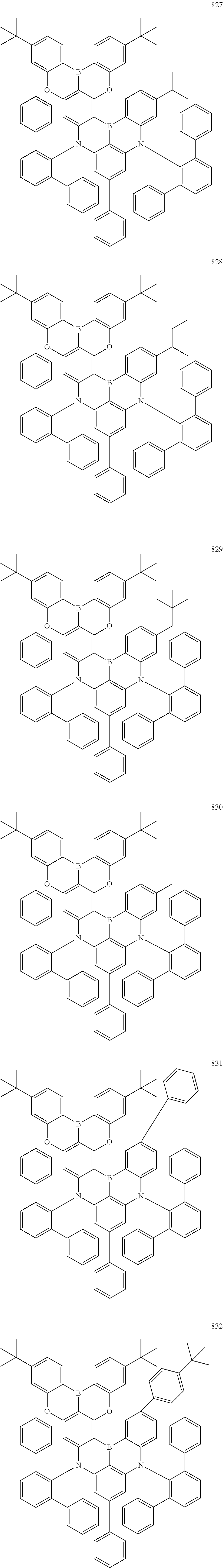

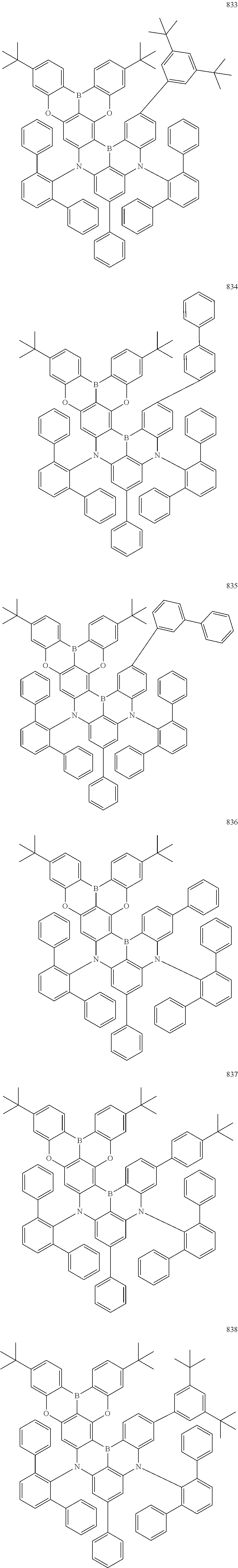

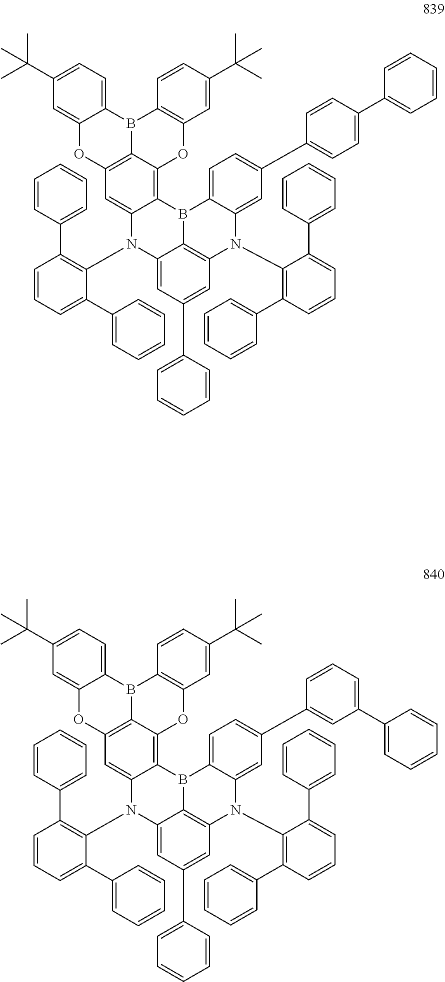 [SMILES: CC(C)(C)c1ccc2c(c1)Oc1cc3c(c4c1B2c1ccc(C(C)(C)C)cc1O4)B1c2ccc(-c4ccc(-c5ccccc5)cc4)cc2N(c2c(-c4ccccc4)cccc2-c2ccccc2)c2cc(-c4ccccc4)cc(c21)N3c1c(-c2ccccc2)cccc1-c1ccccc1 ; CC(C)(C)c1ccc2c(c1)Oc1cc3c(c4c1B2c1ccc(C(C)(C)C)cc1O4)B1c2ccc(-c4cccc(-c5ccccc5)c4)cc2N(c2c(-c4ccccc4)cccc2-c2ccccc2)c2cc(-c4ccccc4)cc(c21)N3c1c(-c2ccccc2)cccc1-c1ccccc1]

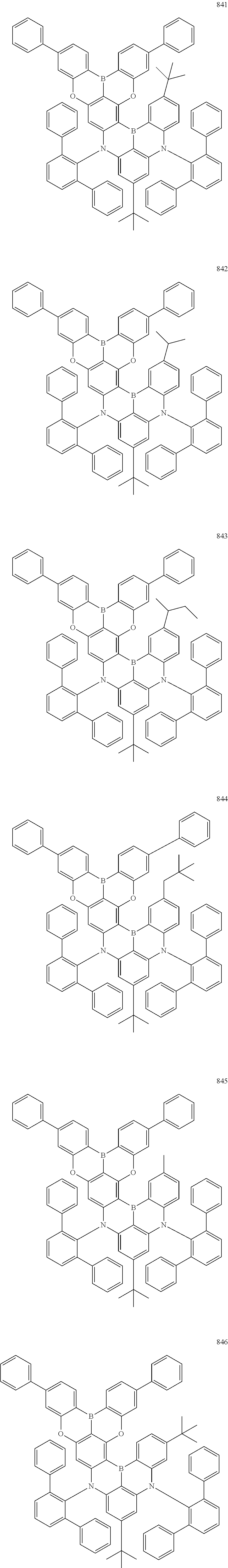

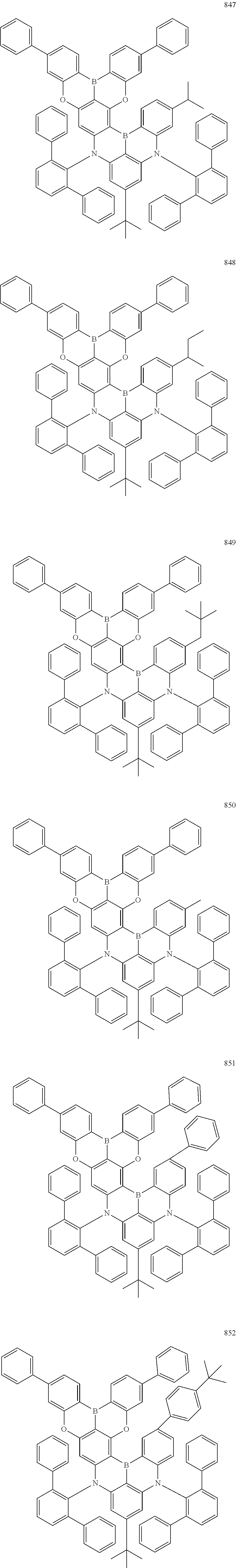

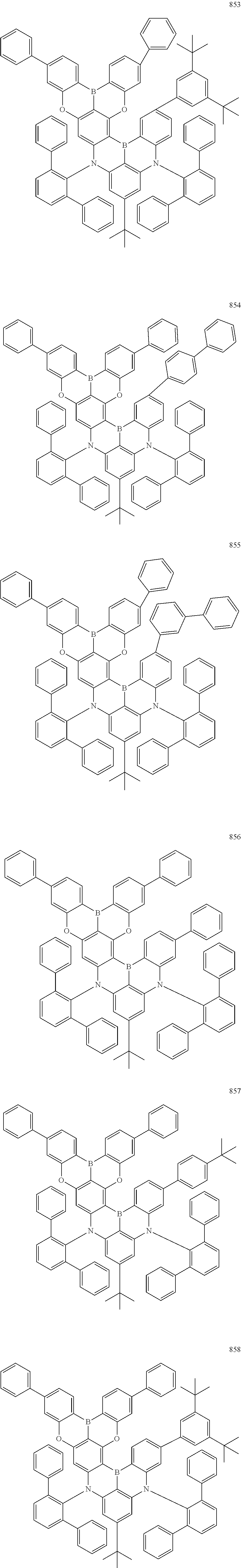

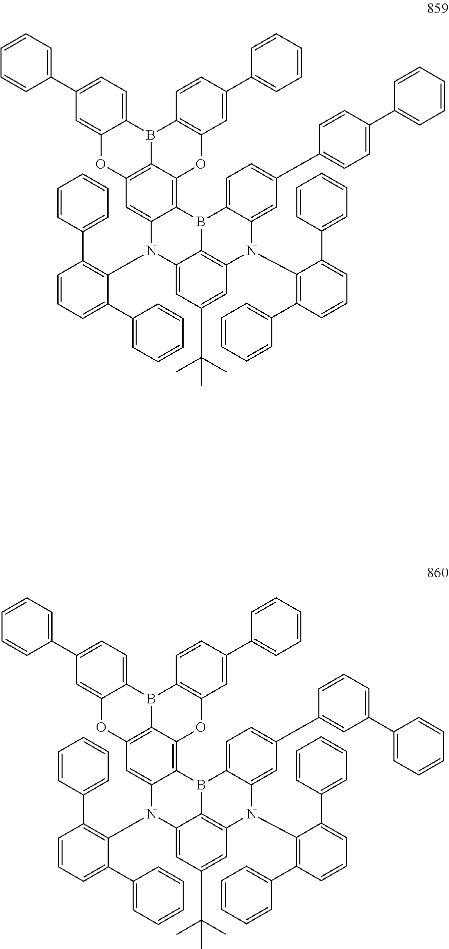 [SMILES: CC(C)(C)c1cc2c3c(c1)N(c1c(-c4ccccc4)cccc1-c1ccccc1)c1cc4c5c(c1B3c1ccc(-c3ccc(-c6ccccc6)cc3)cc1N2c1c(-c2ccccc2)cccc1-c1ccccc1)Oc1cc(-c2ccccc2)ccc1B5c1ccc(-c2ccccc2)cc1O4 ; CC(C)(C)c1cc2c3c(c1)N(c1c(-c4ccccc4)cccc1-c1ccccc1)c1cc4c5c(c1B3c1ccc(-c3cccc(-c6ccccc6)c3)cc1N2c1c(-c2ccccc2)cccc1-c1ccccc1)Oc1cc(-c2ccccc2)ccc1B5c1ccc(-c2ccccc2)cc1O4]

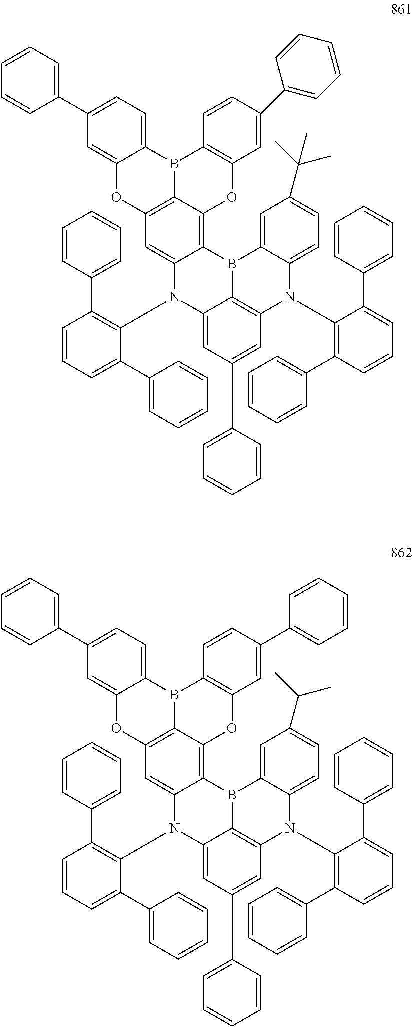 [SMILES: CC(C)(C)c1ccc2c(c1)B1c3c(cc(-c4ccccc4)cc3N(c3c(-c4ccccc4)cccc3-c3ccccc3)c3cc4c5c(c31)Oc1cc(-c3ccccc3)ccc1B5c1ccc(-c3ccccc3)cc1O4)N2c1c(-c2ccccc2)cccc1-c1ccccc1 ; CC(C)c1ccc2c(c1)B1c3c(cc(-c4ccccc4)cc3N(c3c(-c4ccccc4)cccc3-c3ccccc3)c3cc4c5c(c31)Oc1cc(-c3ccccc3)ccc1B5c1ccc(-c3ccccc3)cc1O4)N2c1c(-c2ccccc2)cccc1-c1ccccc1]

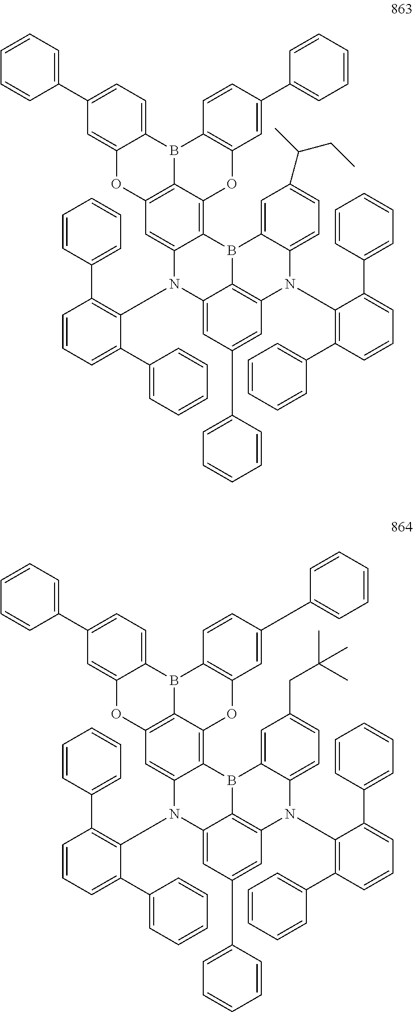 [SMILES: CCC(C)c1ccc2c(c1)B1c3c(cc(-c4ccccc4)cc3N(c3c(-c4ccccc4)cccc3-c3ccccc3)c3cc4c5c(c31)Oc1cc(-c3ccccc3)ccc1B5c1ccc(-c3ccccc3)cc1O4)N2c1c(-c2ccccc2)cccc1-c1ccccc1 ; CC(C)(C)Cc1ccc2c(c1)B1c3c(cc(-c4ccccc4)cc3N(c3c(-c4ccccc4)cccc3-c3ccccc3)c3cc4c5c(c31)Oc1cc(-c3ccccc3)ccc1B5c1ccc(-c3ccccc3)cc1O4)N2c1c(-c2ccccc2)cccc1-c1ccccc1]

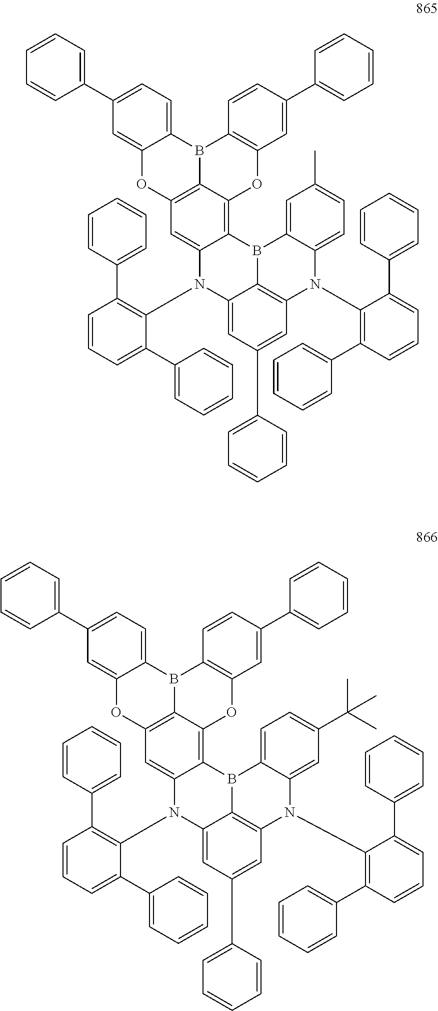 [SMILES: Cc1ccc2c(c1)B1c3c(cc(-c4ccccc4)cc3N(c3c(-c4ccccc4)cccc3-c3ccccc3)c3cc4c5c(c31)Oc1cc(-c3ccccc3)ccc1B5c1ccc(-c3ccccc3)cc1O4)N2c1c(-c2ccccc2)cccc1-c1ccccc1 ; CC(C)(C)c1ccc2c(c1)N(c1c(-c3ccccc3)cccc1-c1ccccc1)c1cc(-c3ccccc3)cc3c1B2c1c(cc2c4c1Oc1cc(-c5ccccc5)ccc1B4c1ccc(-c4ccccc4)cc1O2)N3c1c(-c2ccccc2)cccc1-c1ccccc1]

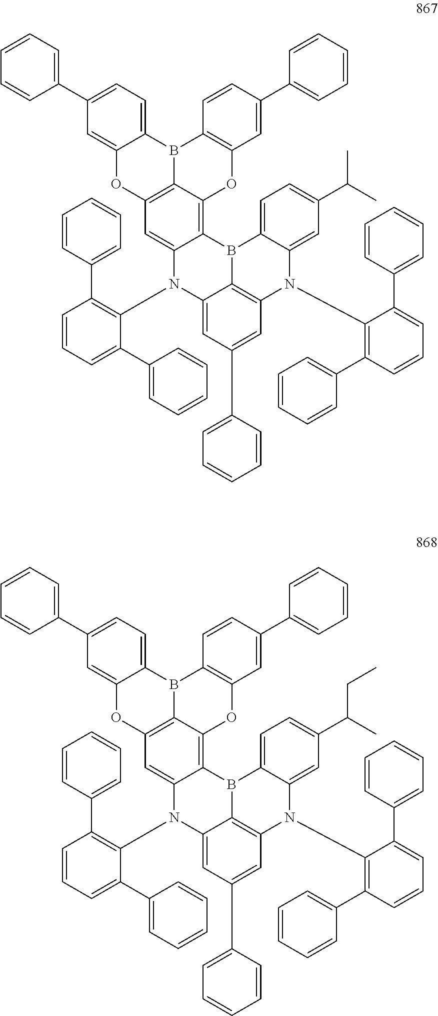 [SMILES: CC(C)c1ccc2c(c1)N(c1c(-c3ccccc3)cccc1-c1ccccc1)c1cc(-c3ccccc3)cc3c1B2c1c(cc2c4c1Oc1cc(-c5ccccc5)ccc1B4c1ccc(-c4ccccc4)cc1O2)N3c1c(-c2ccccc2)cccc1-c1ccccc1 ; CCC(C)c1ccc2c(c1)N(c1c(-c3ccccc3)cccc1-c1ccccc1)c1cc(-c3ccccc3)cc3c1B2c1c(cc2c4c1Oc1cc(-c5ccccc5)ccc1B4c1ccc(-c4ccccc4)cc1O2)N3c1c(-c2ccccc2)cccc1-c1ccccc1]

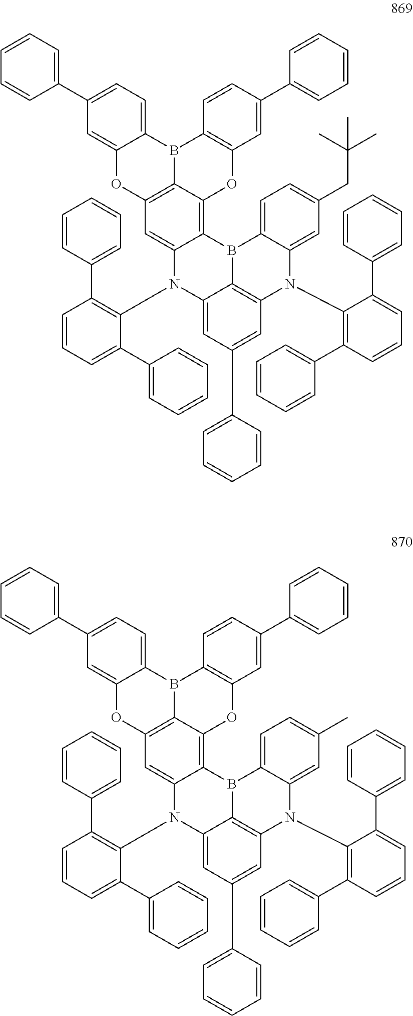 [SMILES: CC(C)(C)Cc1ccc2c(c1)N(c1c(-c3ccccc3)cccc1-c1ccccc1)c1cc(-c3ccccc3)cc3c1B2c1c(cc2c4c1Oc1cc(-c5ccccc5)ccc1B4c1ccc(-c4ccccc4)cc1O2)N3c1c(-c2ccccc2)cccc1-c1ccccc1 ; Cc1ccc2c(c1)N(c1c(-c3ccccc3)cccc1-c1ccccc1)c1cc(-c3ccccc3)cc3c1B2c1c(cc2c4c1Oc1cc(-c5ccccc5)ccc1B4c1ccc(-c4ccccc4)cc1O2)N3c1c(-c2ccccc2)cccc1-c1ccccc1]

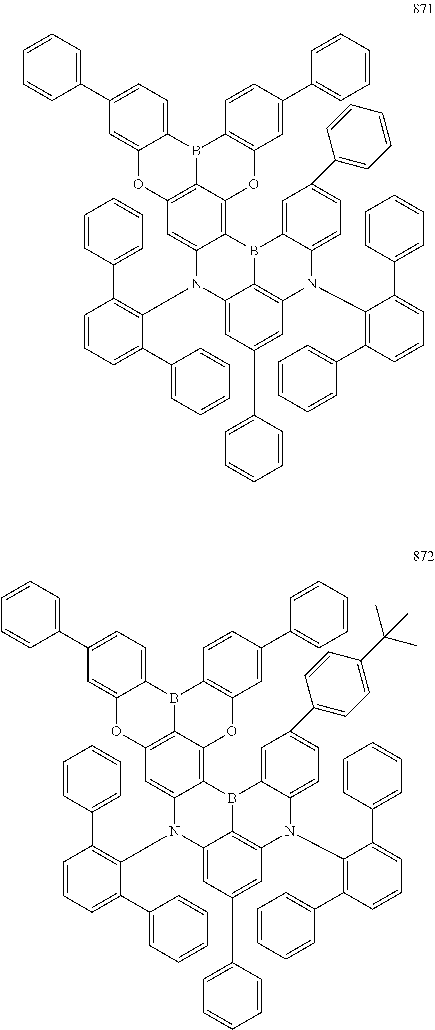 [SMILES: c1ccc(-c2ccc3c(c2)Oc2cc4c(c5c2B3c2ccc(-c3ccccc3)cc2O5)B2c3cc(-c5ccccc5)ccc3N(c3c(-c5ccccc5)cccc3-c3ccccc3)c3cc(-c5ccccc5)cc(c32)N4c2c(-c3ccccc3)cccc2-c2ccccc2)cc1 ; CC(C)(C)c1ccc(-c2ccc3c(c2)B2c4c(cc(-c5ccccc5)cc4N(c4c(-c5ccccc5)cccc4-c4ccccc4)c4cc5c6c(c42)Oc2cc(-c4ccccc4)ccc2B6c2ccc(-c4ccccc4)cc2O5)N3c2c(-c3ccccc3)cccc2-c2ccccc2)cc1]

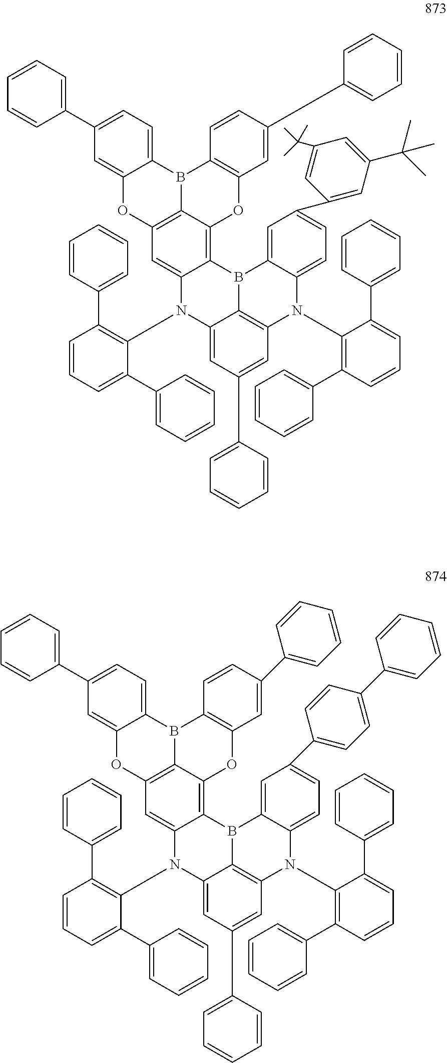 [SMILES: CC(C)(C)c1cc(-c2ccc3c(c2)B2c4c(cc(-c5ccccc5)cc4N(c4c(-c5ccccc5)cccc4-c4ccccc4)c4cc5c6c(c42)Oc2cc(-c4ccccc4)ccc2B6c2ccc(-c4ccccc4)cc2O5)N3c2c(-c3ccccc3)cccc2-c2ccccc2)cc(C(C)(C)C)c1 ; c1ccc(-c2ccc(-c3ccc4c(c3)B3c5c(cc(-c6ccccc6)cc5N(c5c(-c6ccccc6)cccc5-c5ccccc5)c5cc6c7c(c53)Oc3cc(-c5ccccc5)ccc3B7c3ccc(-c5ccccc5)cc3O6)N4c3c(-c4ccccc4)cccc3-c3ccccc3)cc2)cc1]

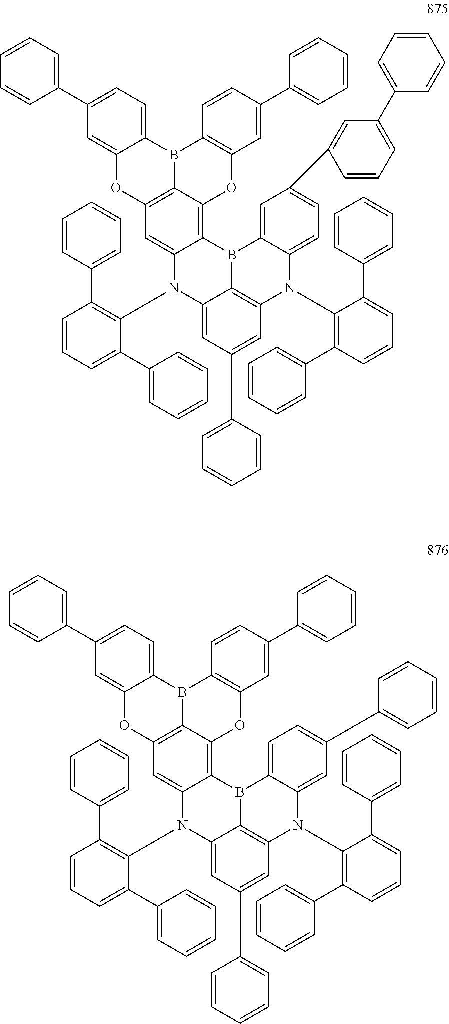 [SMILES: c1ccc(-c2cccc(-c3ccc4c(c3)B3c5c(cc(-c6ccccc6)cc5N(c5c(-c6ccccc6)cccc5-c5ccccc5)c5cc6c7c(c53)Oc3cc(-c5ccccc5)ccc3B7c3ccc(-c5ccccc5)cc3O6)N4c3c(-c4ccccc4)cccc3-c3ccccc3)c2)cc1 ; c1ccc(-c2ccc3c(c2)Oc2cc4c(c5c2B3c2ccc(-c3ccccc3)cc2O5)B2c3ccc(-c5ccccc5)cc3N(c3c(-c5ccccc5)cccc3-c3ccccc3)c3cc(-c5ccccc5)cc(c32)N4c2c(-c3ccccc3)cccc2-c2ccccc2)cc1]

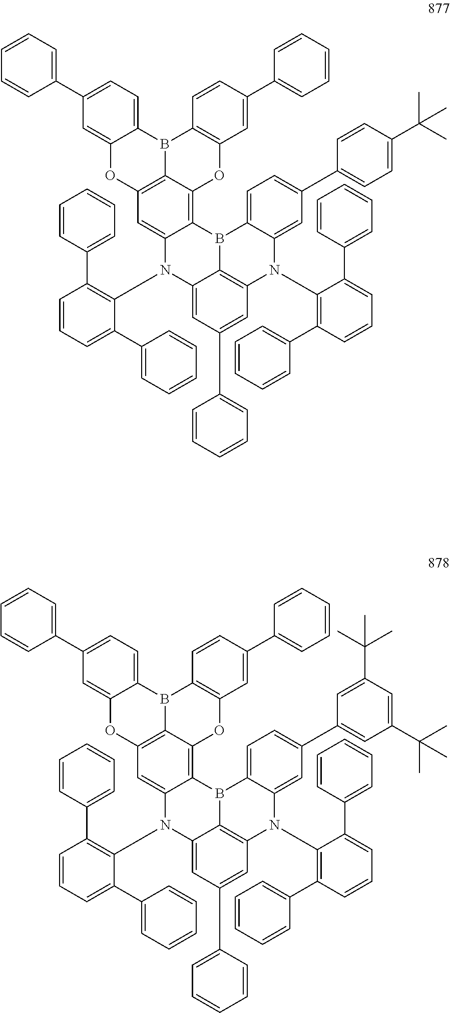 [SMILES: CC(C)(C)c1ccc(-c2ccc3c(c2)N(c2c(-c4ccccc4)cccc2-c2ccccc2)c2cc(-c4ccccc4)cc4c2B3c2c(cc3c5c2Oc2cc(-c6ccccc6)ccc2B5c2ccc(-c5ccccc5)cc2O3)N4c2c(-c3ccccc3)cccc2-c2ccccc2)cc1 ; CC(C)(C)c1cc(-c2ccc3c(c2)N(c2c(-c4ccccc4)cccc2-c2ccccc2)c2cc(-c4ccccc4)cc4c2B3c2c(cc3c5c2Oc2cc(-c6ccccc6)ccc2B5c2ccc(-c5ccccc5)cc2O3)N4c2c(-c3ccccc3)cccc2-c2ccccc2)cc(C(C)(C)C)c1]

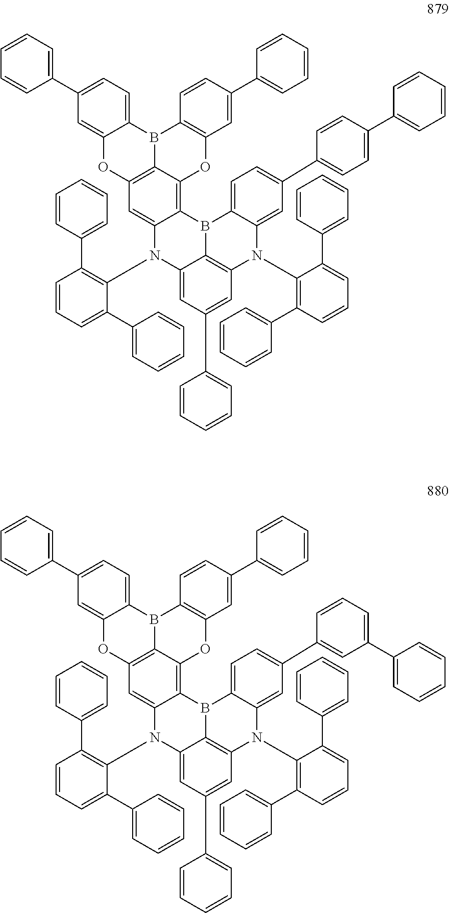 [SMILES: c1ccc(-c2ccc(-c3ccc4c(c3)N(c3c(-c5ccccc5)cccc3-c3ccccc3)c3cc(-c5ccccc5)cc5c3B4c3c(cc4c6c3Oc3cc(-c7ccccc7)ccc3B6c3ccc(-c6ccccc6)cc3O4)N5c3c(-c4ccccc4)cccc3-c3ccccc3)cc2)cc1 ; c1ccc(-c2cccc(-c3ccc4c(c3)N(c3c(-c5ccccc5)cccc3-c3ccccc3)c3cc(-c5ccccc5)cc5c3B4c3c(cc4c6c3Oc3cc(-c7ccccc7)ccc3B6c3ccc(-c6ccccc6)cc3O4)N5c3c(-c4ccccc4)cccc3-c3ccccc3)c2)cc1]

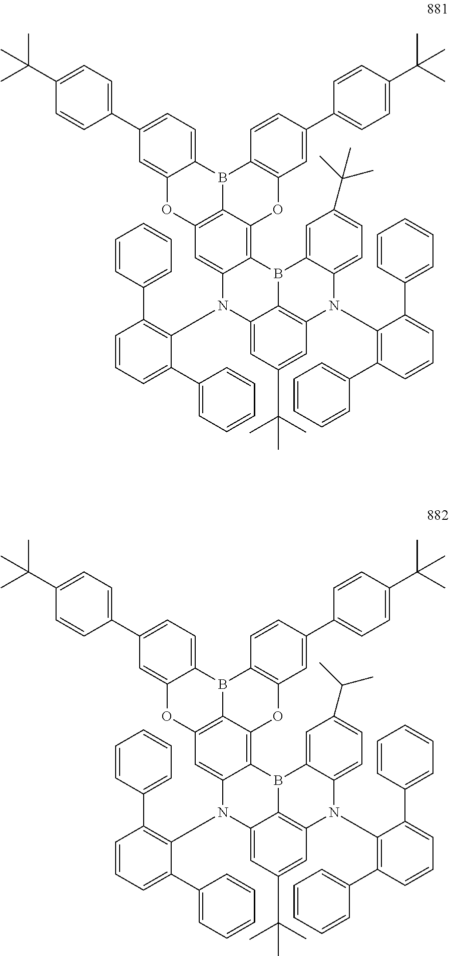

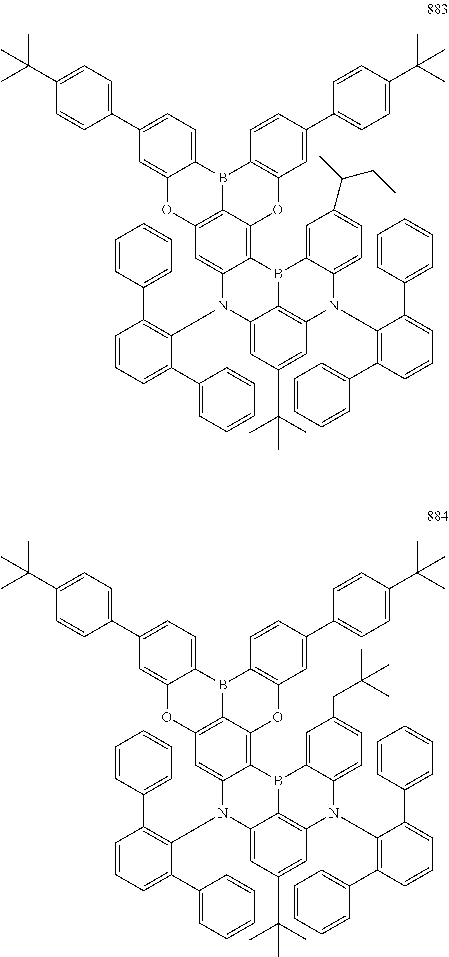

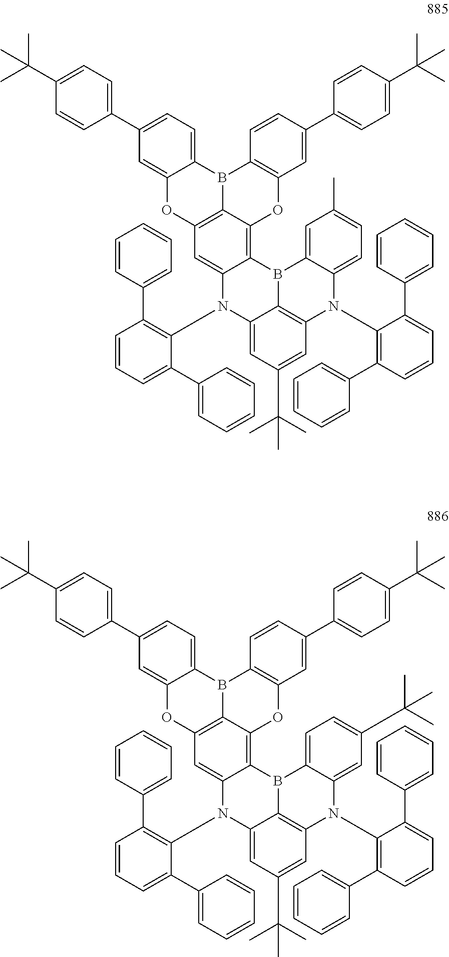

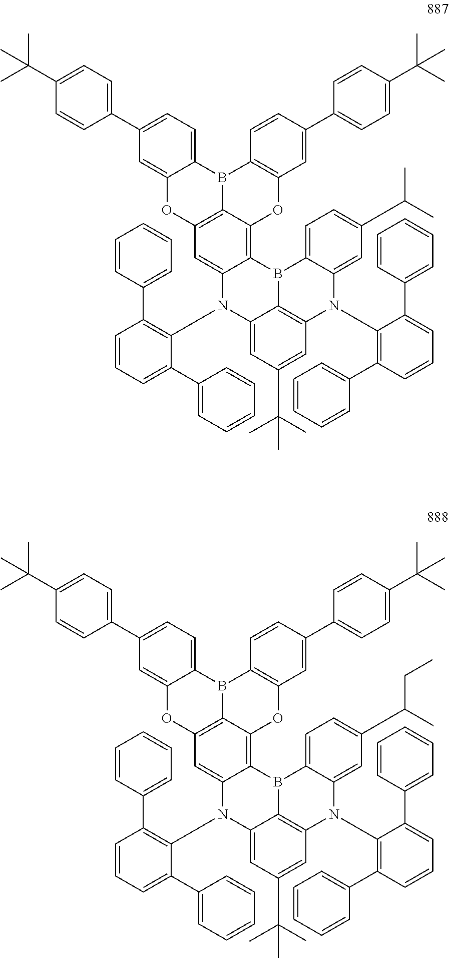

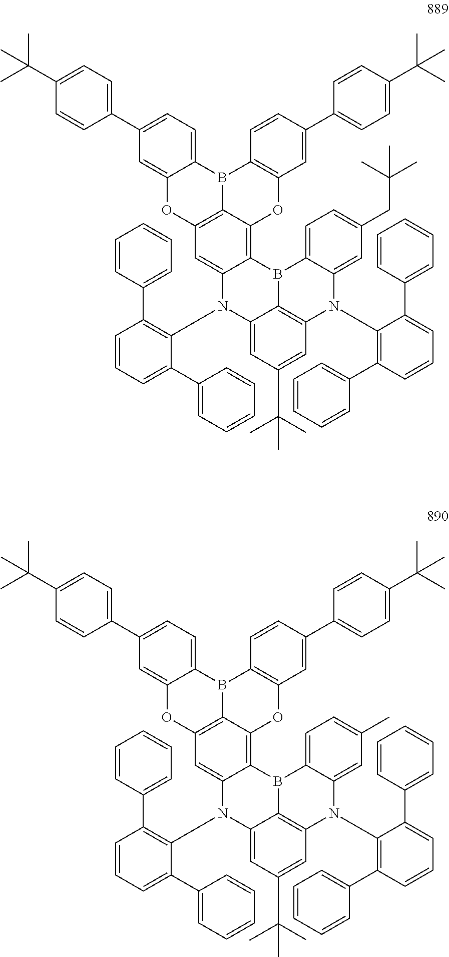

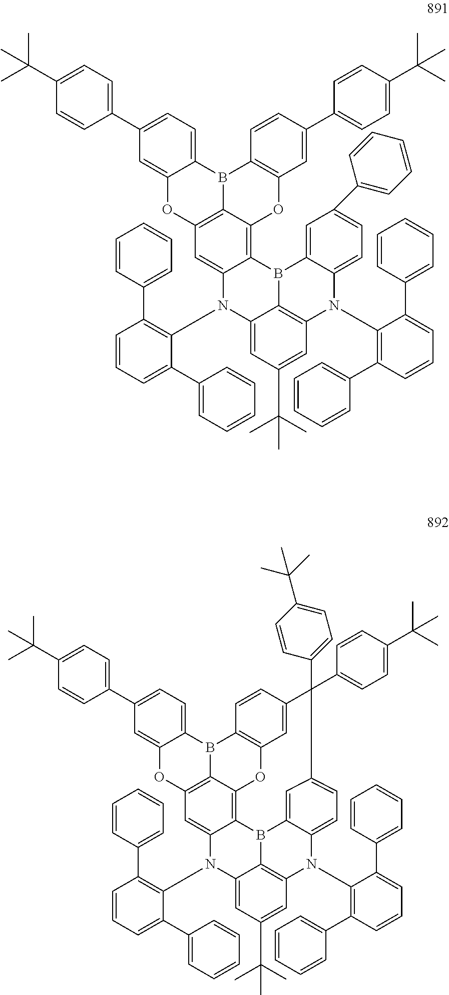

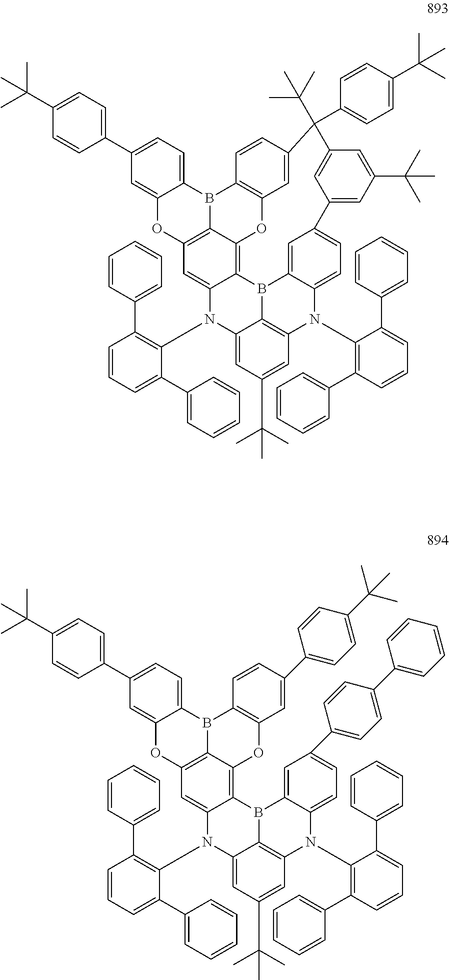

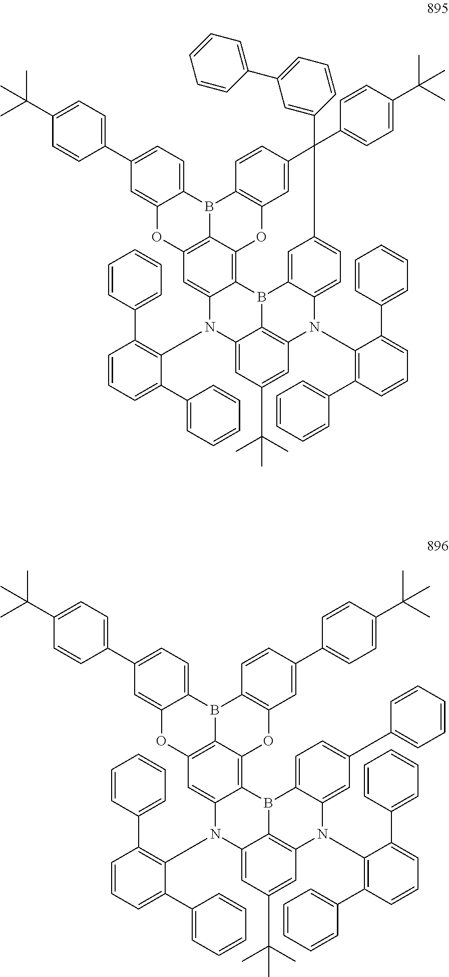

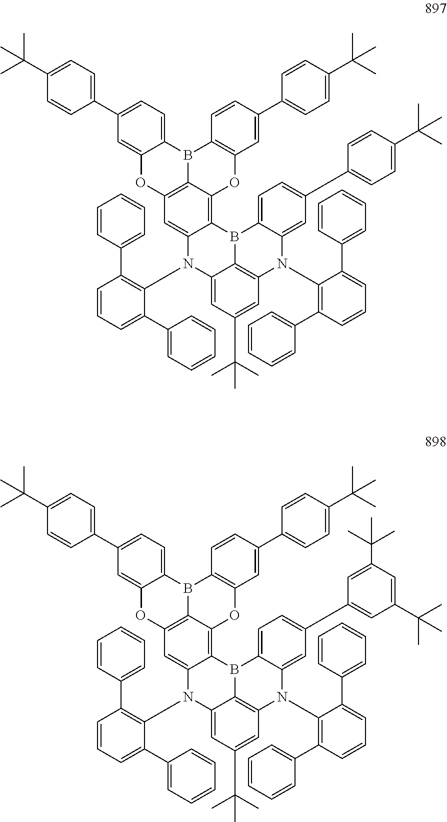

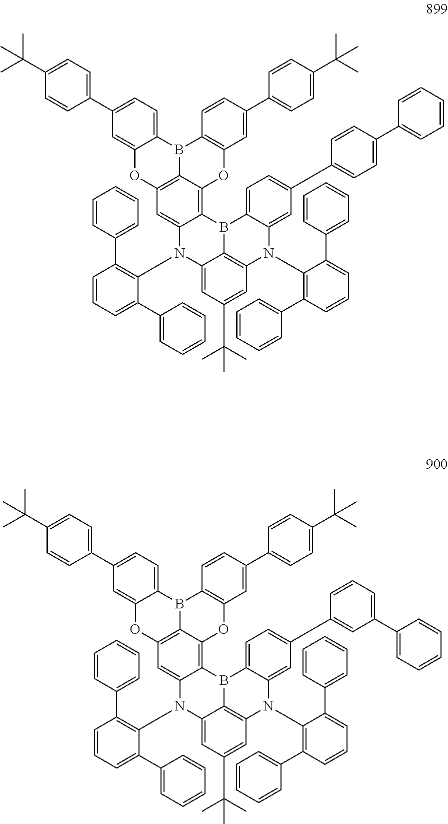 [SMILES: CC(C)(C)c1ccc(-c2ccc3c(c2)Oc2cc4c(c5c2B3c2ccc(-c3ccc(C(C)(C)C)cc3)cc2O5)B2c3ccc(-c5ccc(-c6ccccc6)cc5)cc3N(c3c(-c5ccccc5)cccc3-c3ccccc3)c3cc(C(C)(C)C)cc(c32)N4c2c(-c3ccccc3)cccc2-c2ccccc2)cc1 ; CC(C)(C)c1ccc(-c2ccc3c(c2)Oc2cc4c(c5c2B3c2ccc(-c3ccc(C(C)(C)C)cc3)cc2O5)B2c3ccc(-c5cccc(-c6ccccc6)c5)cc3N(c3c(-c5ccccc5)cccc3-c3ccccc3)c3cc(C(C)(C)C)cc(c32)N4c2c(-c3ccccc3)cccc2-c2ccccc2)cc1]

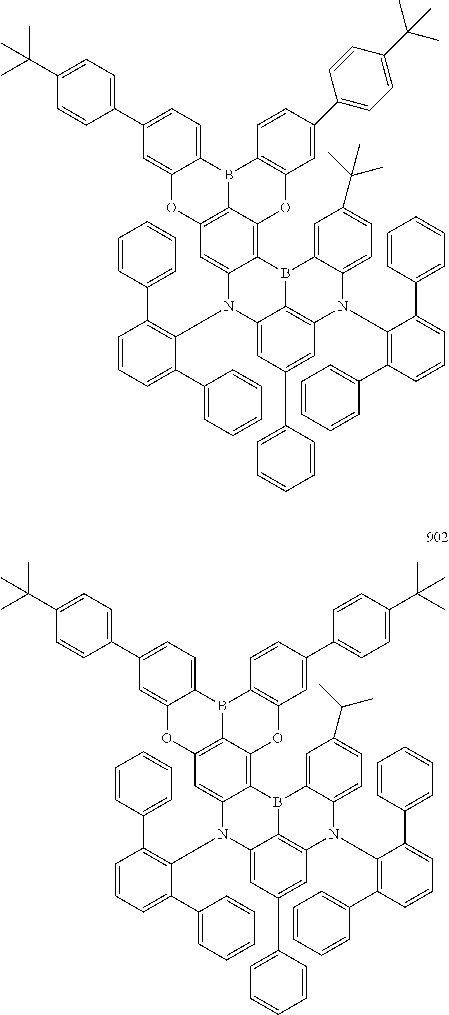 [SMILES: CC(C)(C)c1ccc(-c2ccc3c(c2)Oc2cc4c(c5c2B3c2ccc(-c3ccc(C(C)(C)C)cc3)cc2O5)B2c3cc(C(C)(C)C)ccc3N(c3c(-c5ccccc5)cccc3-c3ccccc3)c3cc(-c5ccccc5)cc(c32)N4c2c(-c3ccccc3)cccc2-c2ccccc2)cc1 ; CC(C)c1ccc2c(c1)B1c3c(cc(-c4ccccc4)cc3N(c3c(-c4ccccc4)cccc3-c3ccccc3)c3cc4c5c(c31)Oc1cc(-c3ccc(C(C)(C)C)cc3)ccc1B5c1ccc(-c3ccc(C(C)(C)C)cc3)cc1O4)N2c1c(-c2ccccc2)cccc1-c1ccccc1]

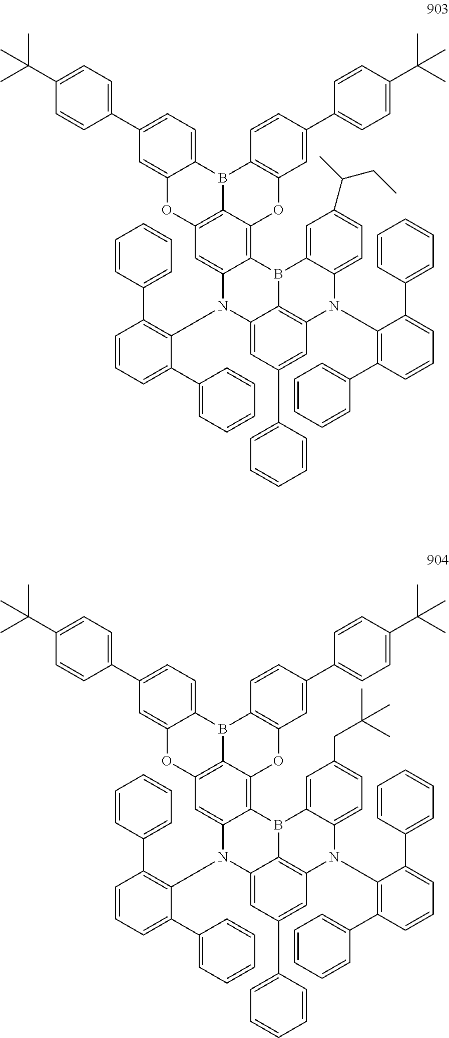

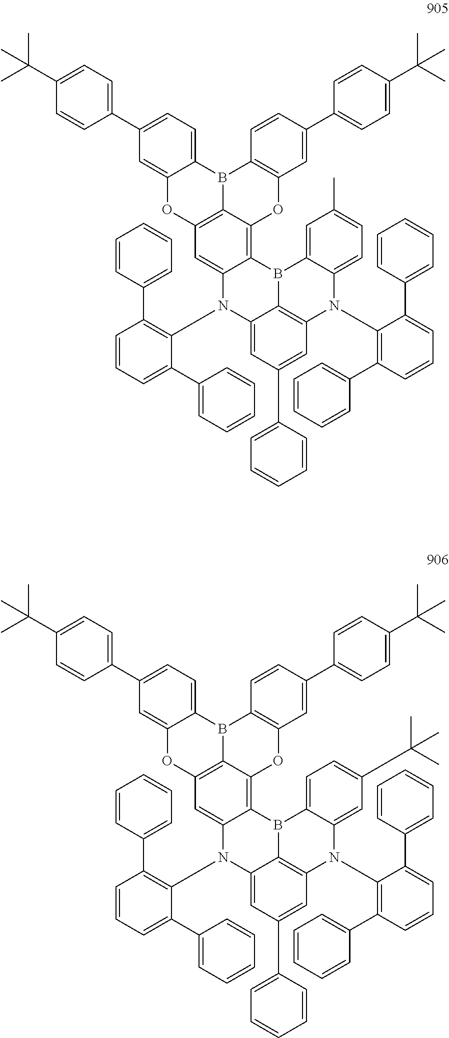

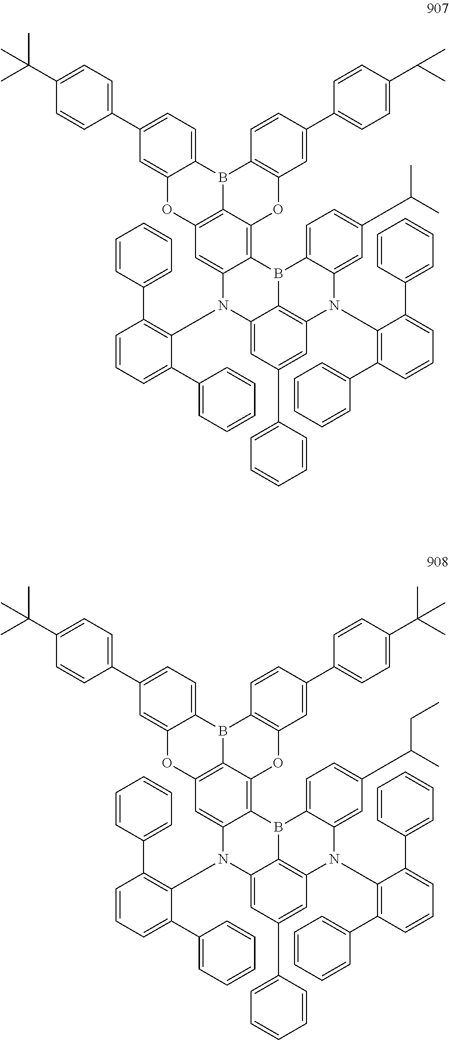

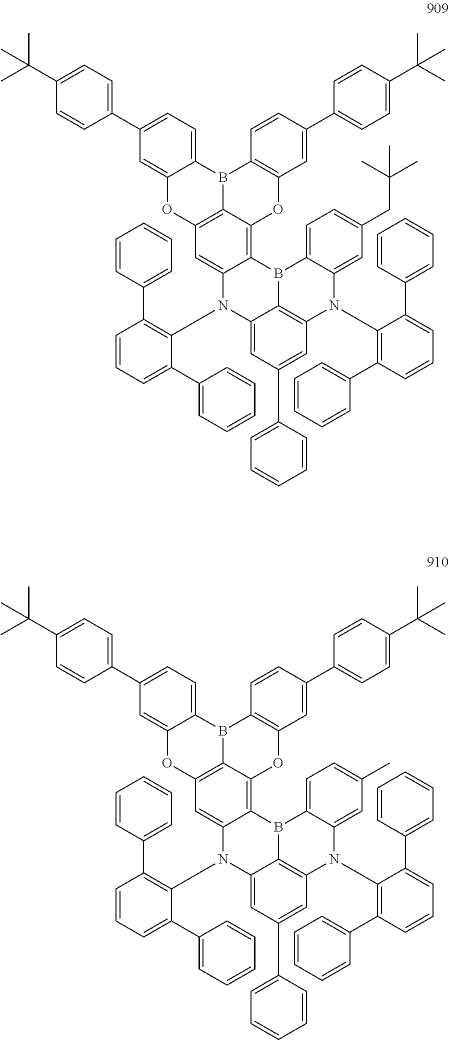

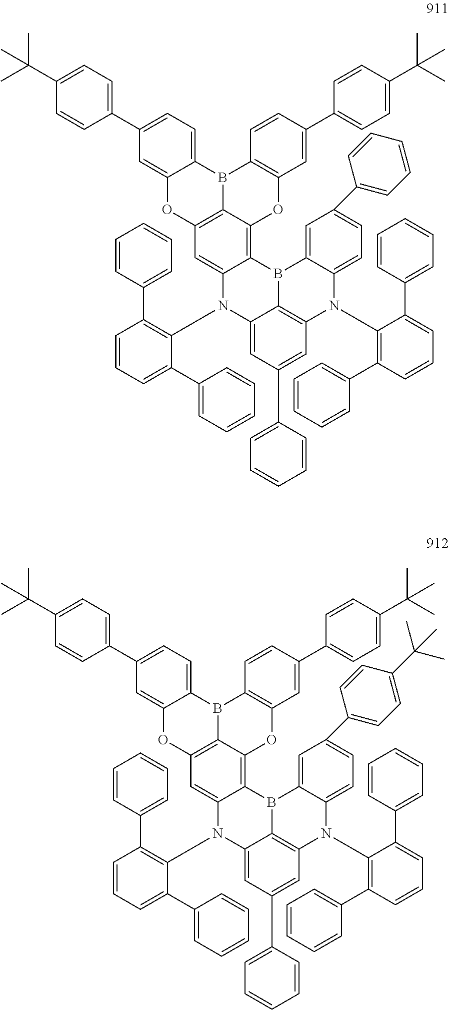

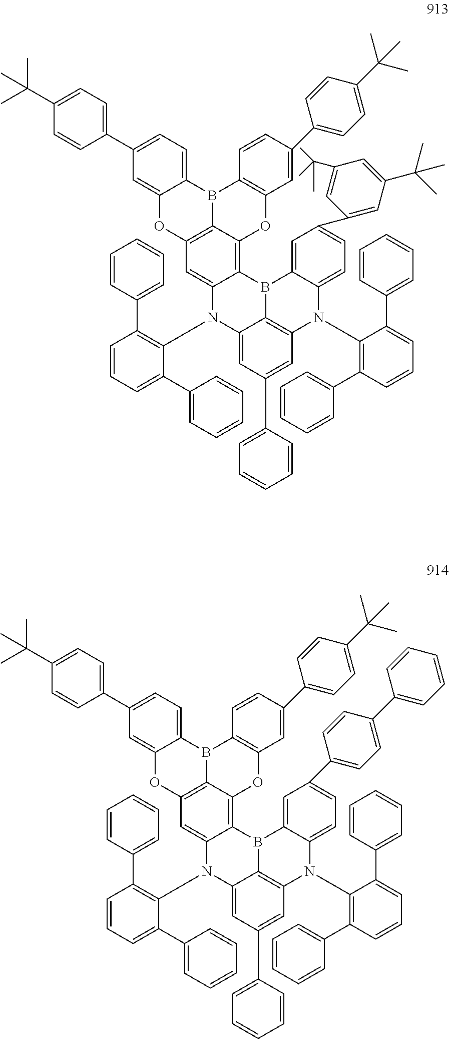

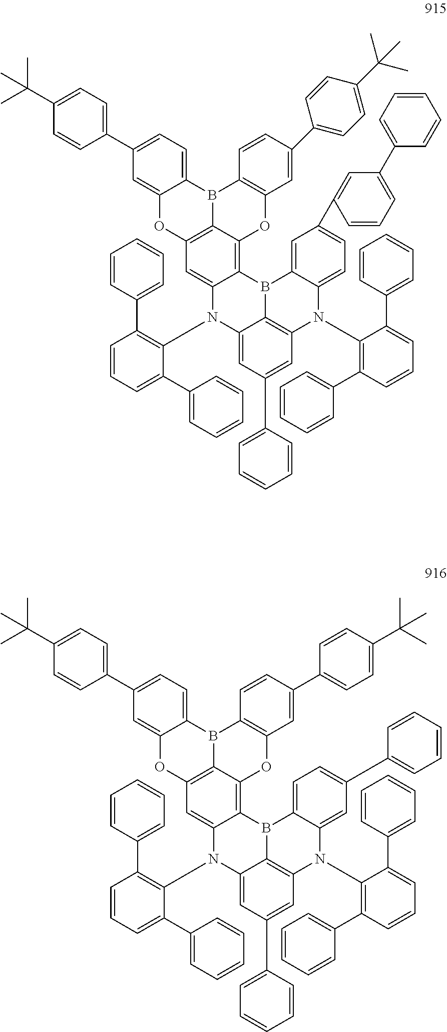 [SMILES: CC(C)(C)c1ccc(-c2ccc3c(c2)Oc2cc4c(c5c2B3c2ccc(-c3ccc(C(C)(C)C)cc3)cc2O5)B2c3cc(-c5cccc(-c6ccccc6)c5)ccc3N(c3c(-c5ccccc5)cccc3-c3ccccc3)c3cc(-c5ccccc5)cc(c32)N4c2c(-c3ccccc3)cccc2-c2ccccc2)cc1 ; CC(C)(C)c1ccc(-c2ccc3c(c2)Oc2cc4c(c5c2B3c2ccc(-c3ccc(C(C)(C)C)cc3)cc2O5)B2c3ccc(-c5ccccc5)cc3N(c3c(-c5ccccc5)cccc3-c3ccccc3)c3cc(-c5ccccc5)cc(c32)N4c2c(-c3ccccc3)cccc2-c2ccccc2)cc1]

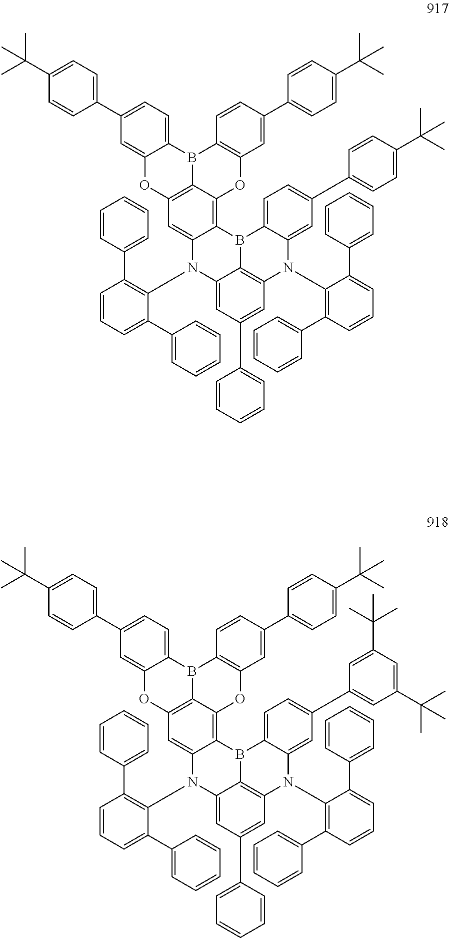

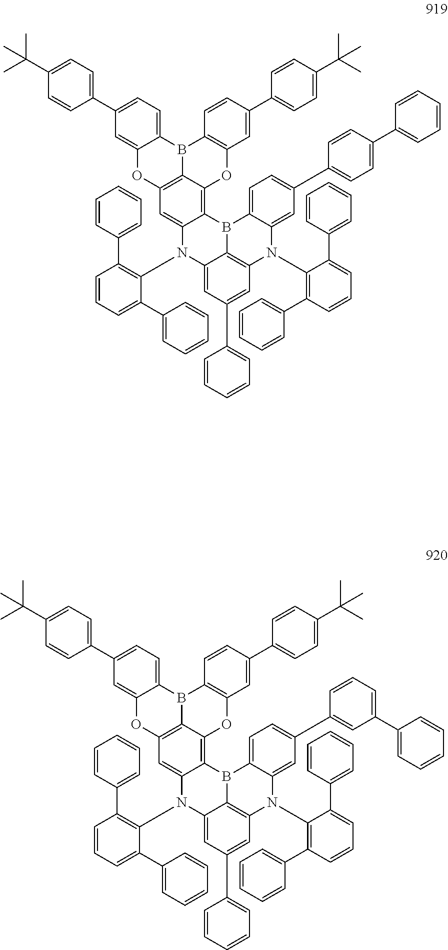 [SMILES: CC(C)(C)c1ccc(-c2ccc3c(c2)Oc2cc4c(c5c2B3c2ccc(-c3ccc(C(C)(C)C)cc3)cc2O5)B2c3ccc(-c5ccc(-c6ccccc6)cc5)cc3N(c3c(-c5ccccc5)cccc3-c3ccccc3)c3cc(-c5ccccc5)cc(c32)N4c2c(-c3ccccc3)cccc2-c2ccccc2)cc1 ; CC(C)(C)c1ccc(-c2ccc3c(c2)Oc2cc4c(c5c2B3c2ccc(-c3ccc(C(C)(C)C)cc3)cc2O5)B2c3ccc(-c5cccc(-c6ccccc6)c5)cc3N(c3c(-c5ccccc5)cccc3-c3ccccc3)c3cc(-c5ccccc5)cc(c32)N4c2c(-c3ccccc3)cccc2-c2ccccc2)cc1]

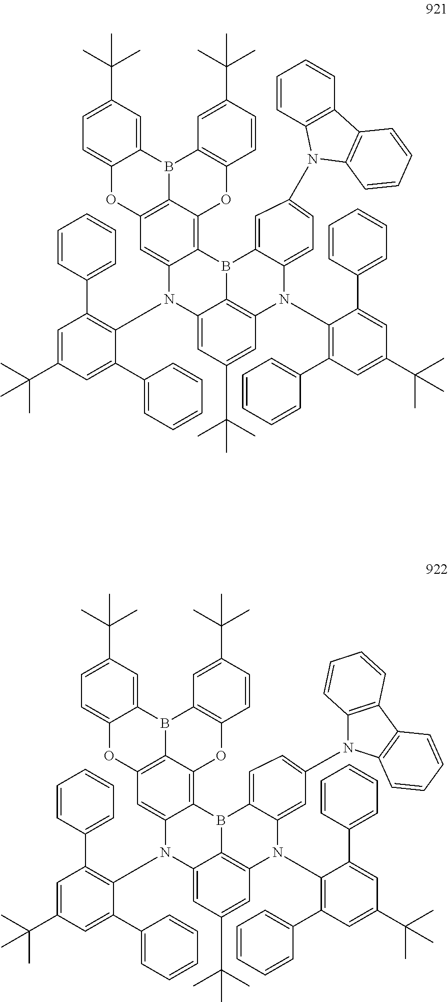

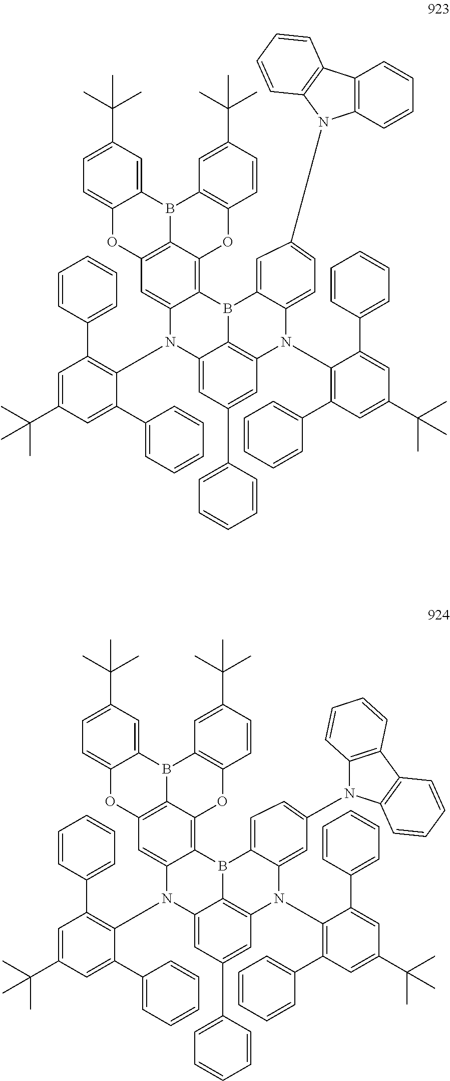

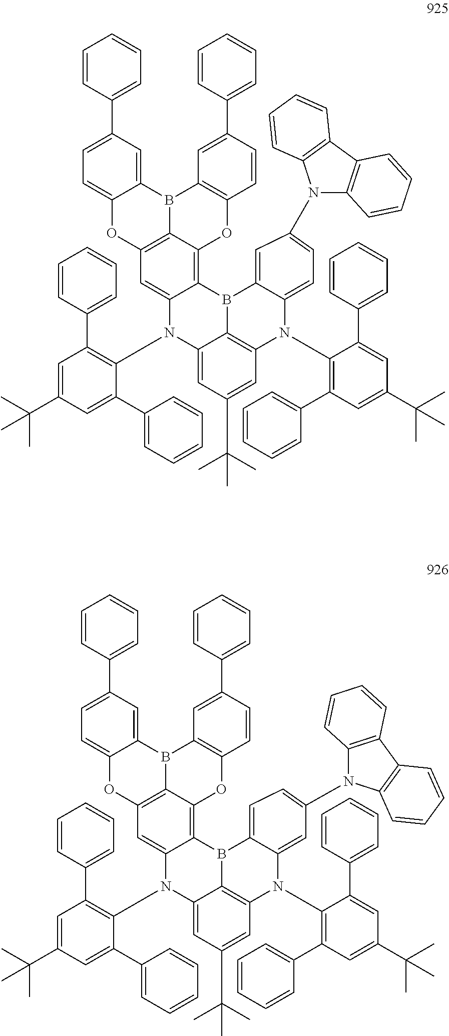

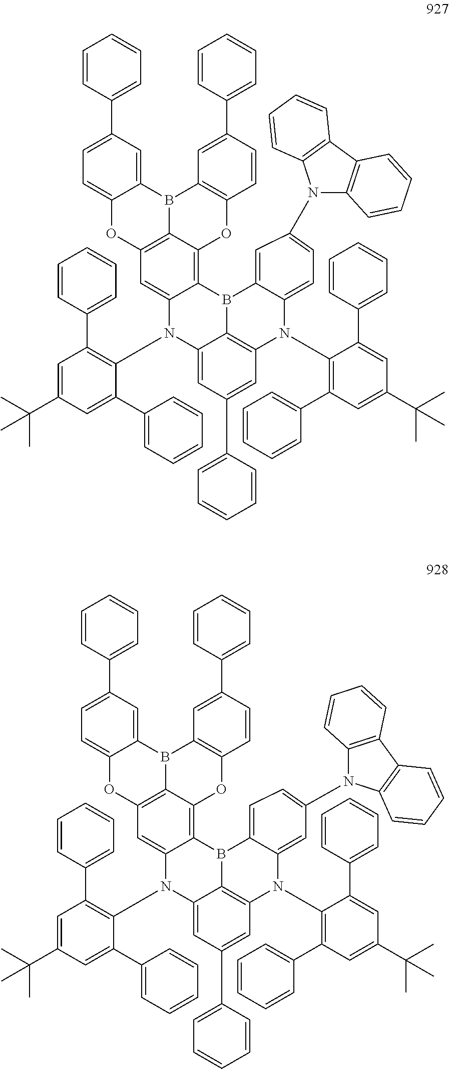

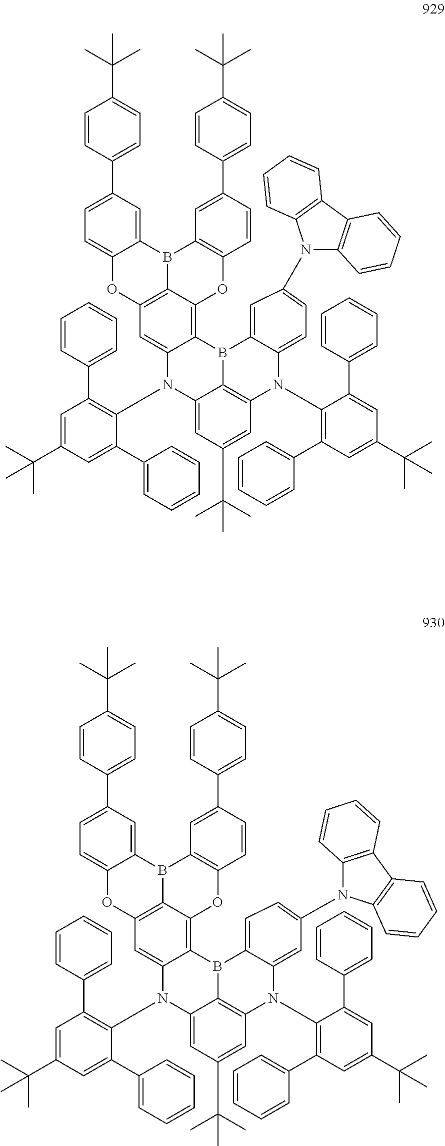

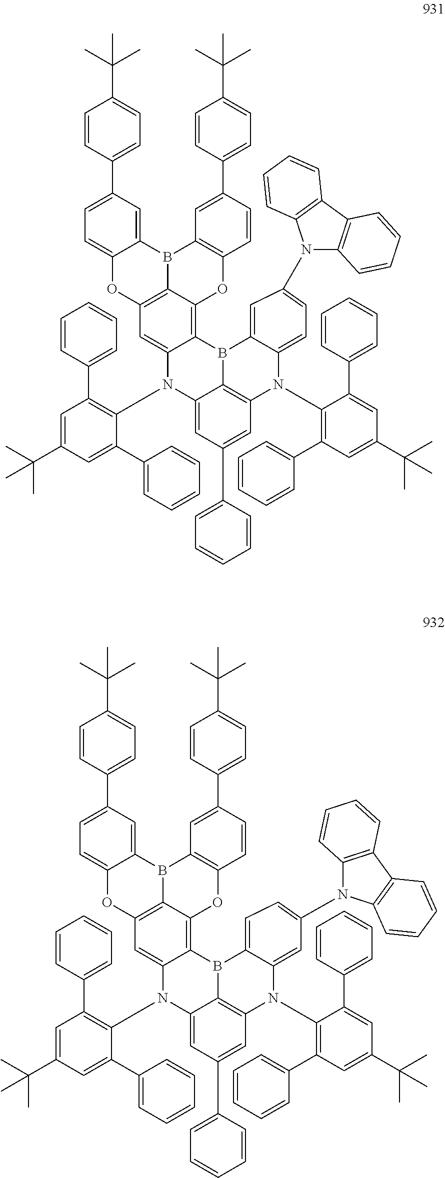

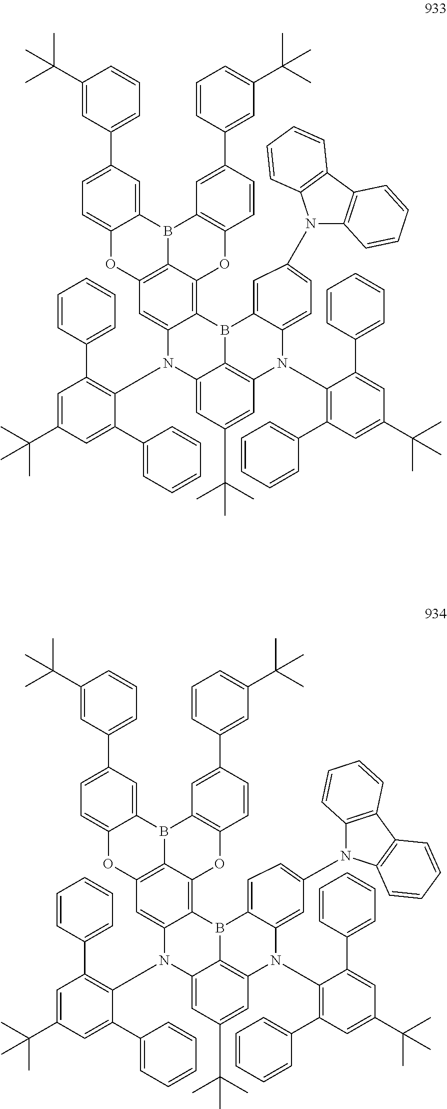

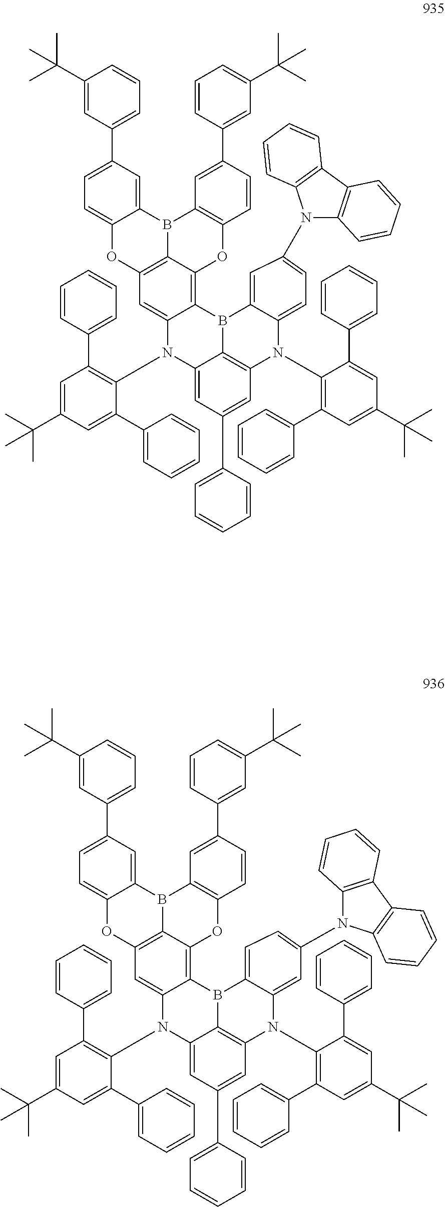

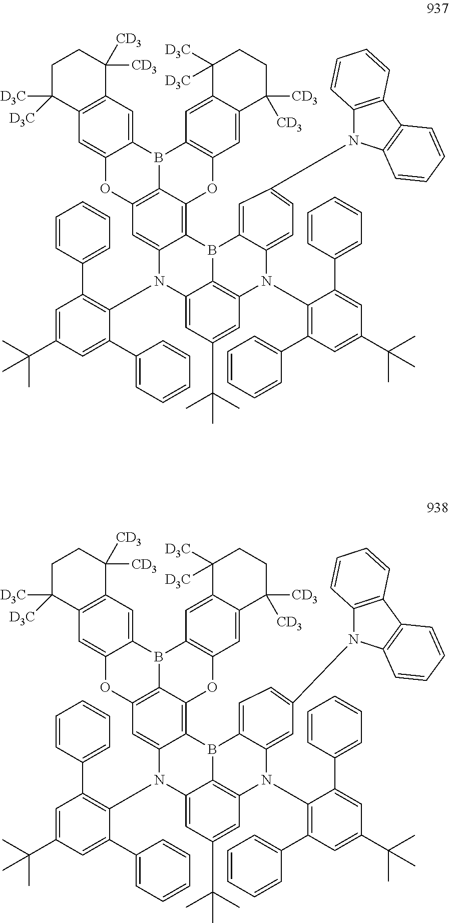

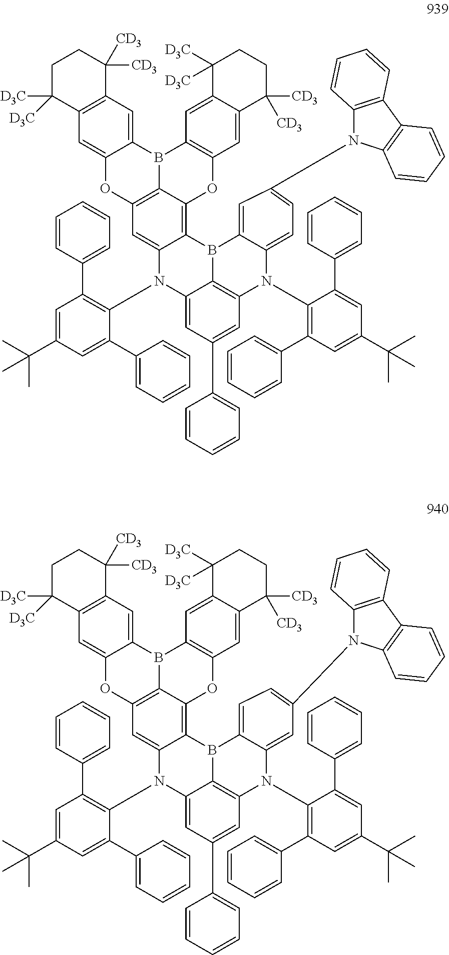

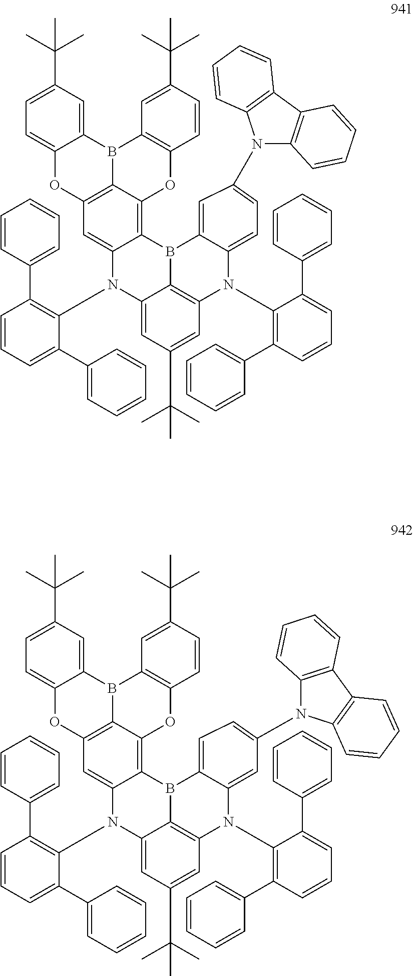 [SMILES: CC(C)(C)c1ccc2c(c1)B1c3cc(C(C)(C)C)ccc3Oc3c1c(cc1c3B3c4cc(-n5c6ccccc6c6ccccc65)ccc4N(c4c(-c5ccccc5)cccc4-c4ccccc4)c4cc(C(C)(C)C)cc(c43)N1c1c(-c3ccccc3)cccc1-c1ccccc1)O2 ; CC(C)(C)c1ccc2c(c1)B1c3cc(C(C)(C)C)ccc3Oc3c1c(cc1c3B3c4ccc(-n5c6ccccc6c6ccccc65)cc4N(c4c(-c5ccccc5)cccc4-c4ccccc4)c4cc(C(C)(C)C)cc(c43)N1c1c(-c3ccccc3)cccc1-c1ccccc1)O2]

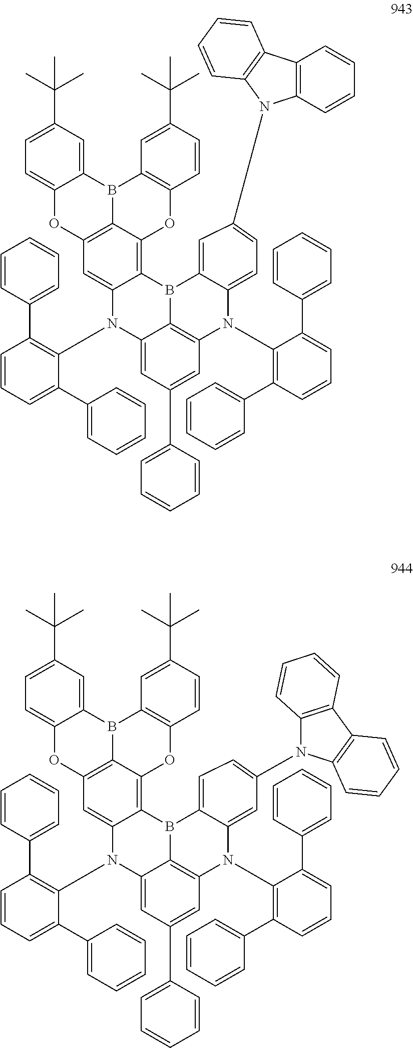 [SMILES: CC(C)(C)c1ccc2c(c1)B1c3cc(C(C)(C)C)ccc3Oc3c1c(cc1c3B3c4cc(-n5c6ccccc6c6ccccc65)ccc4N(c4c(-c5ccccc5)cccc4-c4ccccc4)c4cc(-c5ccccc5)cc(c43)N1c1c(-c3ccccc3)cccc1-c1ccccc1)O2 ; CC(C)(C)c1ccc2c(c1)B1c3cc(C(C)(C)C)ccc3Oc3c1c(cc1c3B3c4ccc(-n5c6ccccc6c6ccccc65)cc4N(c4c(-c5ccccc5)cccc4-c4ccccc4)c4cc(-c5ccccc5)cc(c43)N1c1c(-c3ccccc3)cccc1-c1ccccc1)O2]

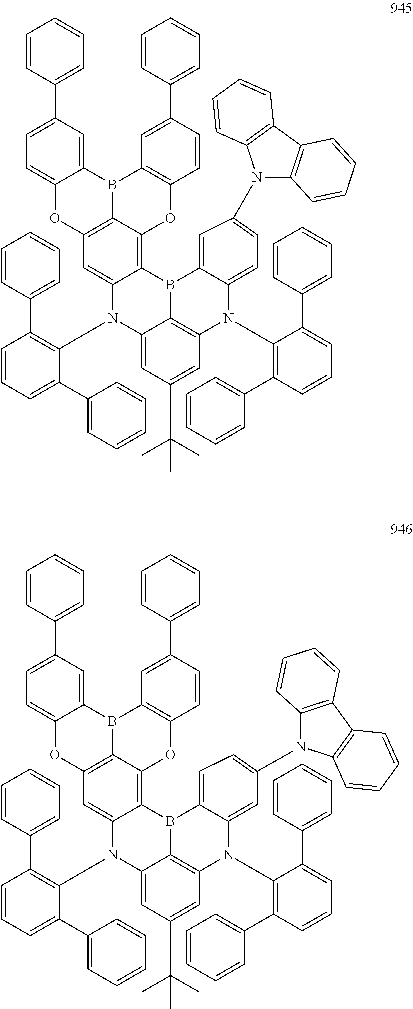 [SMILES: CC(C)(C)c1cc2c3c(c1)N(c1c(-c4ccccc4)cccc1-c1ccccc1)c1cc4c5c(c1B3c1cc(-n3c6ccccc6c6ccccc63)ccc1N2c1c(-c2ccccc2)cccc1-c1ccccc1)Oc1ccc(-c2ccccc2)cc1B5c1cc(-c2ccccc2)ccc1O4 ; CC(C)(C)c1cc2c3c(c1)N(c1c(-c4ccccc4)cccc1-c1ccccc1)c1cc4c5c(c1B3c1ccc(-n3c6ccccc6c6ccccc63)cc1N2c1c(-c2ccccc2)cccc1-c1ccccc1)Oc1ccc(-c2ccccc2)cc1B5c1cc(-c2ccccc2)ccc1O4]

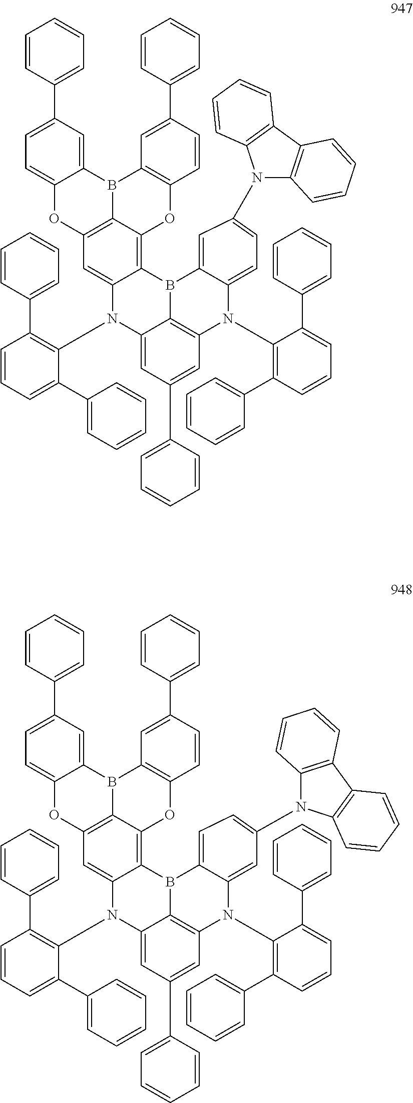 [SMILES: c1ccc(-c2ccc3c(c2)B2c4cc(-c5ccccc5)ccc4Oc4c2c(cc2c4B4c5cc(-n6c7ccccc7c7ccccc76)ccc5N(c5c(-c6ccccc6)cccc5-c5ccccc5)c5cc(-c6ccccc6)cc(c54)N2c2c(-c4ccccc4)cccc2-c2ccccc2)O3)cc1 ; c1ccc(-c2ccc3c(c2)B2c4cc(-c5ccccc5)ccc4Oc4c2c(cc2c4B4c5ccc(-n6c7ccccc7c7ccccc76)cc5N(c5c(-c6ccccc6)cccc5-c5ccccc5)c5cc(-c6ccccc6)cc(c54)N2c2c(-c4ccccc4)cccc2-c2ccccc2)O3)cc1]

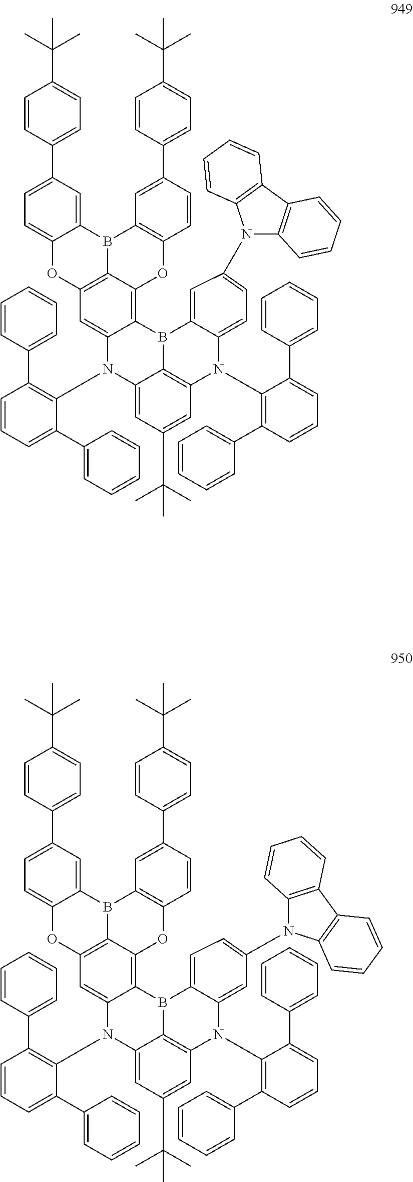 [SMILES: CC(C)(C)c1ccc(-c2ccc3c(c2)B2c4cc(-c5ccc(C(C)(C)C)cc5)ccc4Oc4c2c(cc2c4B4c5cc(-n6c7ccccc7c7ccccc76)ccc5N(c5c(-c6ccccc6)cccc5-c5ccccc5)c5cc(C(C)(C)C)cc(c54)N2c2c(-c4ccccc4)cccc2-c2ccccc2)O3)cc1 ; CC(C)(C)c1ccc(-c2ccc3c(c2)B2c4cc(-c5ccc(C(C)(C)C)cc5)ccc4Oc4c2c(cc2c4B4c5ccc(-n6c7ccccc7c7ccccc76)cc5N(c5c(-c6ccccc6)cccc5-c5ccccc5)c5cc(C(C)(C)C)cc(c54)N2c2c(-c4ccccc4)cccc2-c2ccccc2)O3)cc1]

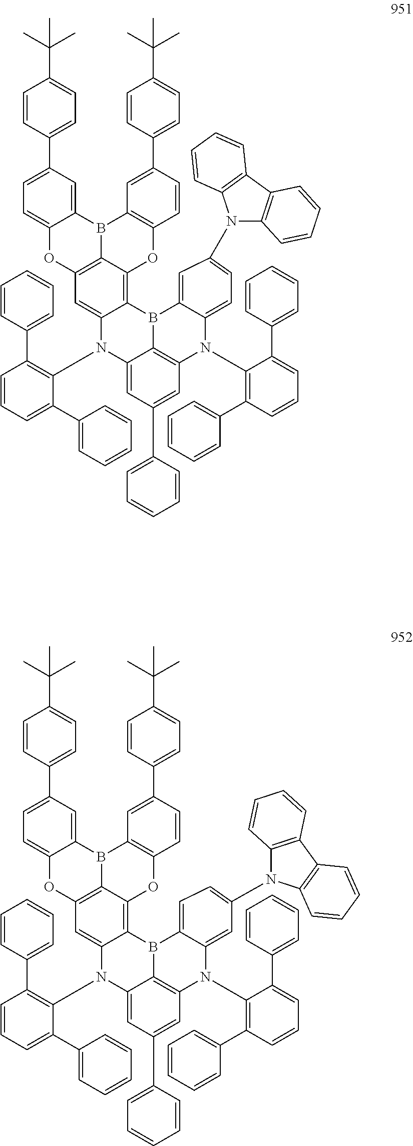 [SMILES: CC(C)(C)c1ccc(-c2ccc3c(c2)B2c4cc(-c5ccc(C(C)(C)C)cc5)ccc4Oc4c2c(cc2c4B4c5cc(-n6c7ccccc7c7ccccc76)ccc5N(c5c(-c6ccccc6)cccc5-c5ccccc5)c5cc(-c6ccccc6)cc(c54)N2c2c(-c4ccccc4)cccc2-c2ccccc2)O3)cc1 ; CC(C)(C)c1ccc(-c2ccc3c(c2)B2c4cc(-c5ccc(C(C)(C)C)cc5)ccc4Oc4c2c(cc2c4B4c5ccc(-n6c7ccccc7c7ccccc76)cc5N(c5c(-c6ccccc6)cccc5-c5ccccc5)c5cc(-c6ccccc6)cc(c54)N2c2c(-c4ccccc4)cccc2-c2ccccc2)O3)cc1]

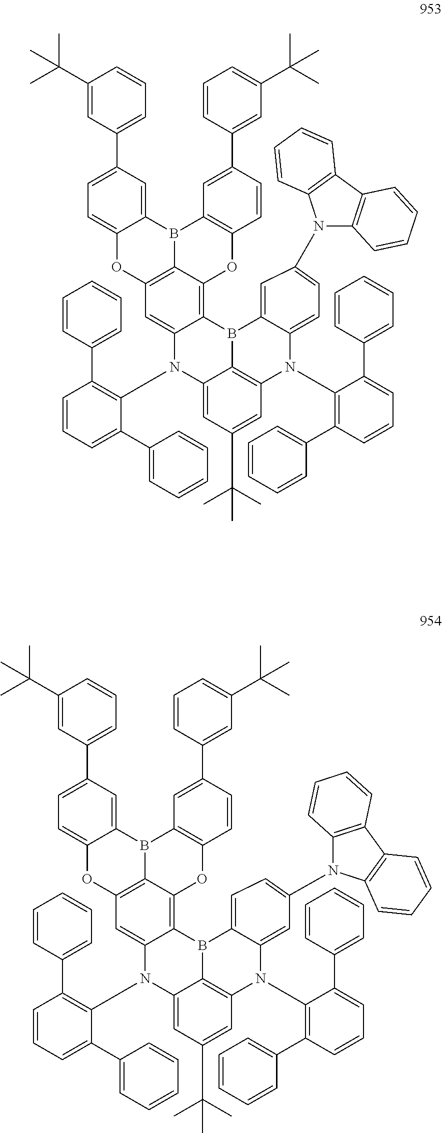 [SMILES: CC(C)(C)c1cccc(-c2ccc3c(c2)B2c4cc(-c5cccc(C(C)(C)C)c5)ccc4Oc4c2c(cc2c4B4c5cc(-n6c7ccccc7c7ccccc76)ccc5N(c5c(-c6ccccc6)cccc5-c5ccccc5)c5cc(C(C)(C)C)cc(c54)N2c2c(-c4ccccc4)cccc2-c2ccccc2)O3)c1 ; CC(C)(C)c1cccc(-c2ccc3c(c2)B2c4cc(-c5cccc(C(C)(C)C)c5)ccc4Oc4c2c(cc2c4B4c5ccc(-n6c7ccccc7c7ccccc76)cc5N(c5c(-c6ccccc6)cccc5-c5ccccc5)c5cc(C(C)(C)C)cc(c54)N2c2c(-c4ccccc4)cccc2-c2ccccc2)O3)c1]

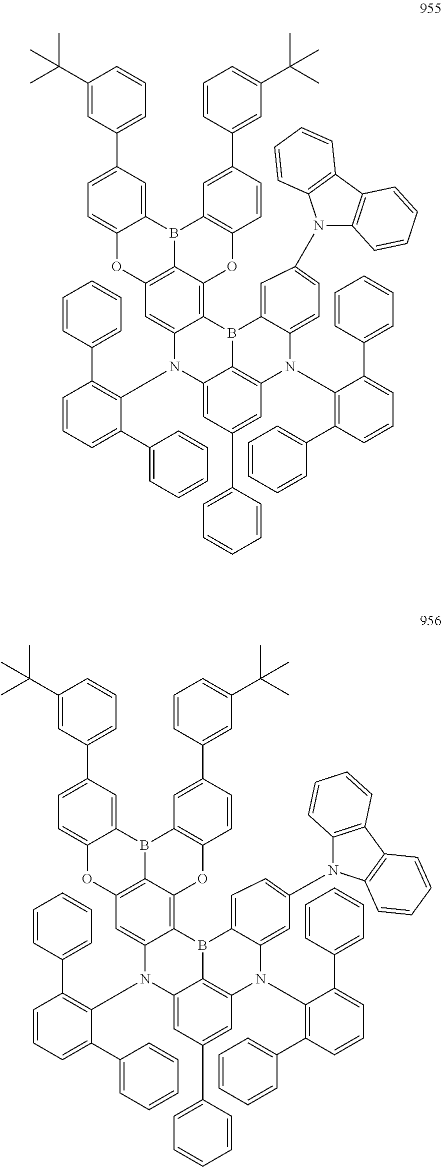 [SMILES: CC(C)(C)c1cccc(-c2ccc3c(c2)B2c4cc(-c5cccc(C(C)(C)C)c5)ccc4Oc4c2c(cc2c4B4c5cc(-n6c7ccccc7c7ccccc76)ccc5N(c5c(-c6ccccc6)cccc5-c5ccccc5)c5cc(-c6ccccc6)cc(c54)N2c2c(-c4ccccc4)cccc2-c2ccccc2)O3)c1 ; CC(C)(C)c1cccc(-c2ccc3c(c2)B2c4cc(-c5cccc(C(C)(C)C)c5)ccc4Oc4c2c(cc2c4B4c5ccc(-n6c7ccccc7c7ccccc76)cc5N(c5c(-c6ccccc6)cccc5-c5ccccc5)c5cc(-c6ccccc6)cc(c54)N2c2c(-c4ccccc4)cccc2-c2ccccc2)O3)c1]

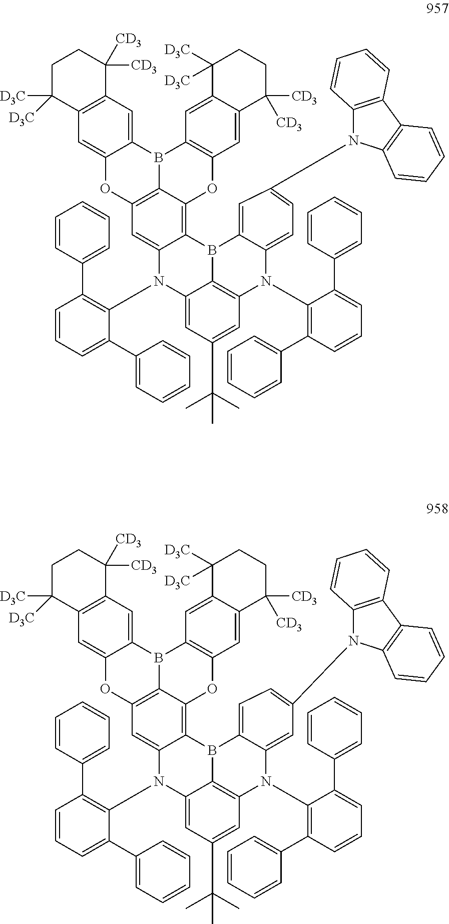

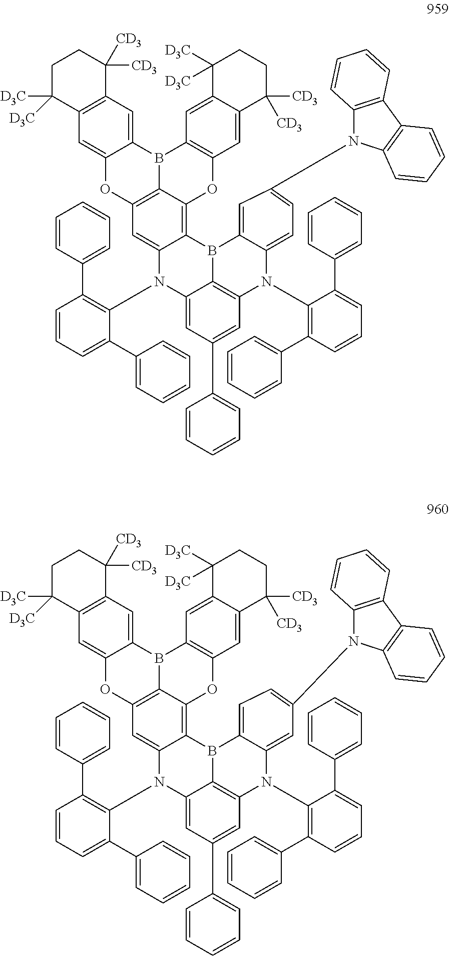

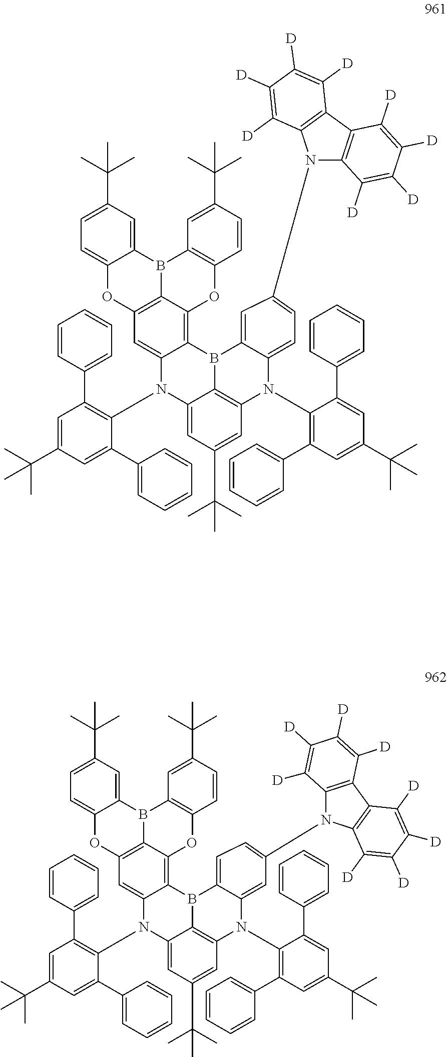 [SMILES: [2H]c1c([2H])c([2H])c2c(c1[2H])c1c([2H])c([2H])c([2H])c([2H])c1n2-c1ccc2c(c1)B1c3c(cc(C(C)(C)C)cc3N(c3c(-c4ccccc4)cc(C(C)(C)C)cc3-c3ccccc3)c3cc4c5c(c31)Oc1ccc(C(C)(C)C)cc1B5c1cc(C(C)(C)C)ccc1O4)N2c1c(-c2ccccc2)cc(C(C)(C)C)cc1-c1ccccc1 ; [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(C(C)(C)C)cc3c1B2c1c(cc2c4c1Oc1ccc(C(C)(C)C)cc1B4c1cc(C(C)(C)C)ccc1O2)N3c1c(-c2ccccc2)cc(C(C)(C)C)cc1-c1ccccc1]

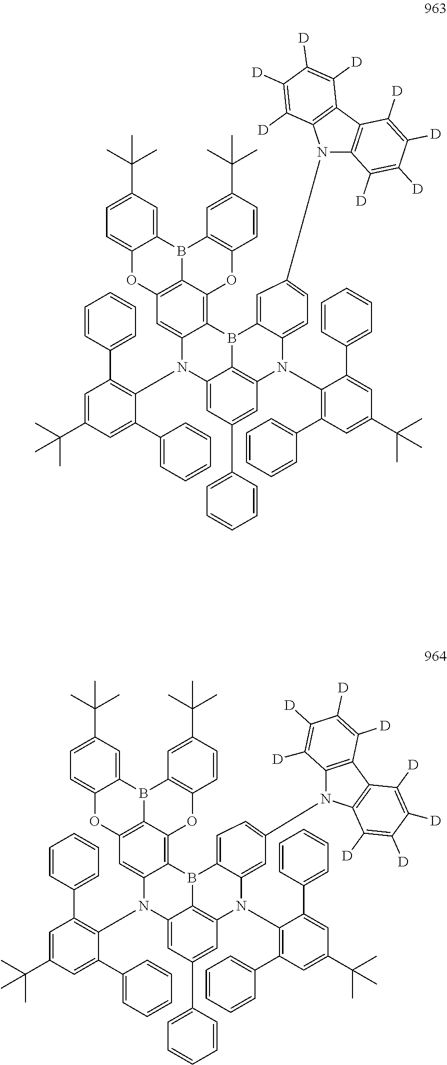 [SMILES: [2H]c1c([2H])c([2H])c2c(c1[2H])c1c([2H])c([2H])c([2H])c([2H])c1n2-c1ccc2c(c1)B1c3c(cc(-c4ccccc4)cc3N(c3c(-c4ccccc4)cc(C(C)(C)C)cc3-c3ccccc3)c3cc4c5c(c31)Oc1ccc(C(C)(C)C)cc1B5c1cc(C(C)(C)C)ccc1O4)N2c1c(-c2ccccc2)cc(C(C)(C)C)cc1-c1ccccc1 ; [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(-c3ccccc3)cc3c1B2c1c(cc2c4c1Oc1ccc(C(C)(C)C)cc1B4c1cc(C(C)(C)C)ccc1O2)N3c1c(-c2ccccc2)cc(C(C)(C)C)cc1-c1ccccc1]

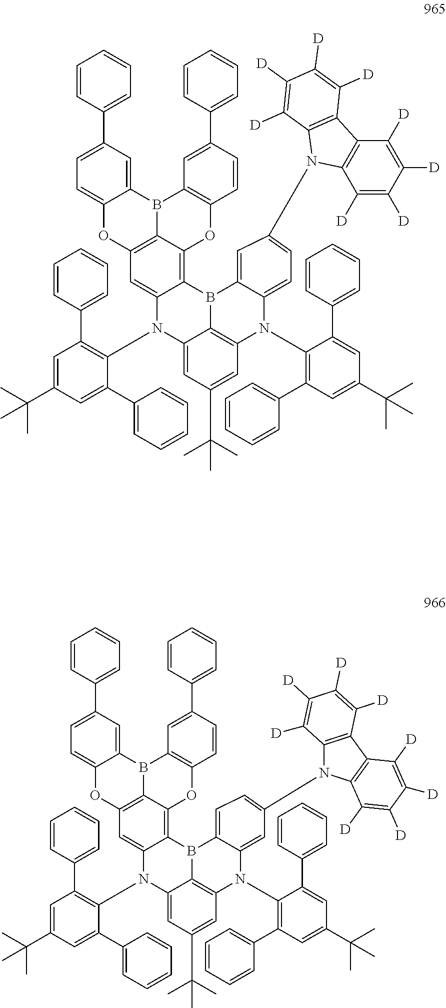 [SMILES: [2H]c1c([2H])c([2H])c2c(c1[2H])c1c([2H])c([2H])c([2H])c([2H])c1n2-c1ccc2c(c1)B1c3c(cc(C(C)(C)C)cc3N(c3c(-c4ccccc4)cc(C(C)(C)C)cc3-c3ccccc3)c3cc4c5c(c31)Oc1ccc(-c3ccccc3)cc1B5c1cc(-c3ccccc3)ccc1O4)N2c1c(-c2ccccc2)cc(C(C)(C)C)cc1-c1ccccc1 ; [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(C(C)(C)C)cc3c1B2c1c(cc2c4c1Oc1ccc(-c5ccccc5)cc1B4c1cc(-c4ccccc4)ccc1O2)N3c1c(-c2ccccc2)cc(C(C)(C)C)cc1-c1ccccc1]

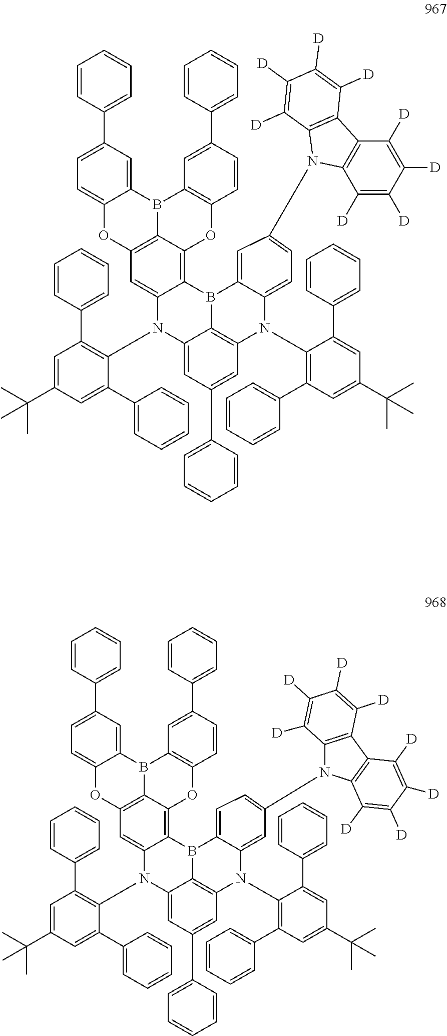 [SMILES: [2H]c1c([2H])c([2H])c2c(c1[2H])c1c([2H])c([2H])c([2H])c([2H])c1n2-c1ccc2c(c1)B1c3c(cc(-c4ccccc4)cc3N(c3c(-c4ccccc4)cc(C(C)(C)C)cc3-c3ccccc3)c3cc4c5c(c31)Oc1ccc(-c3ccccc3)cc1B5c1cc(-c3ccccc3)ccc1O4)N2c1c(-c2ccccc2)cc(C(C)(C)C)cc1-c1ccccc1 ; [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(-c3ccccc3)cc3c1B2c1c(cc2c4c1Oc1ccc(-c5ccccc5)cc1B4c1cc(-c4ccccc4)ccc1O2)N3c1c(-c2ccccc2)cc(C(C)(C)C)cc1-c1ccccc1]

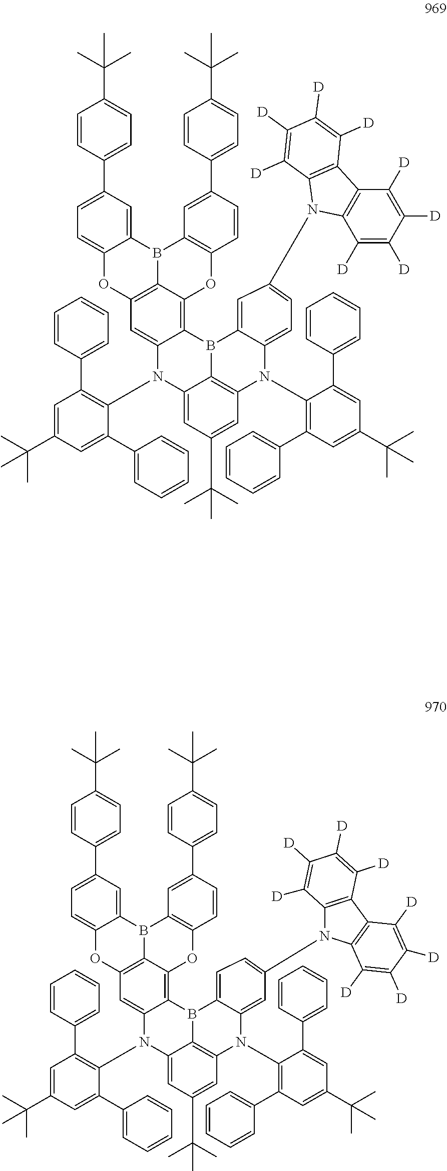

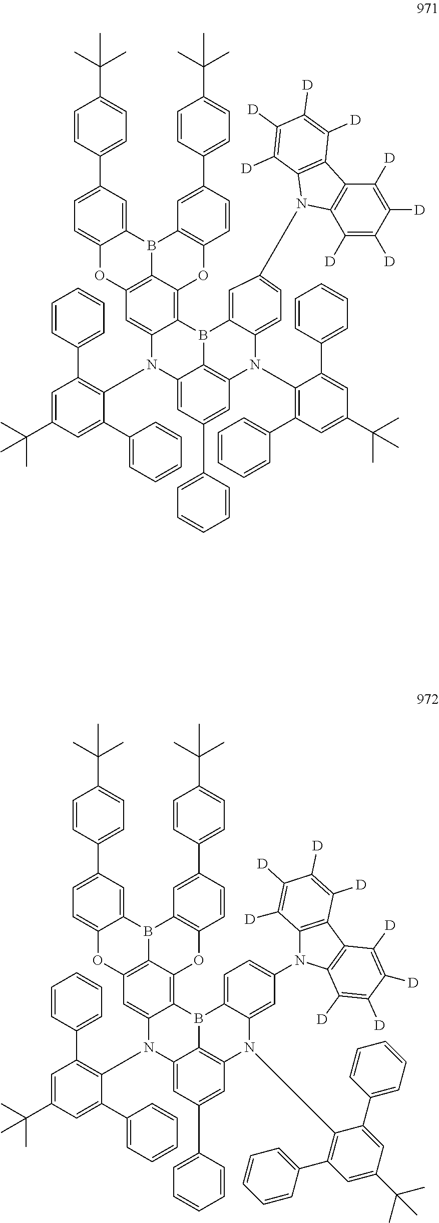

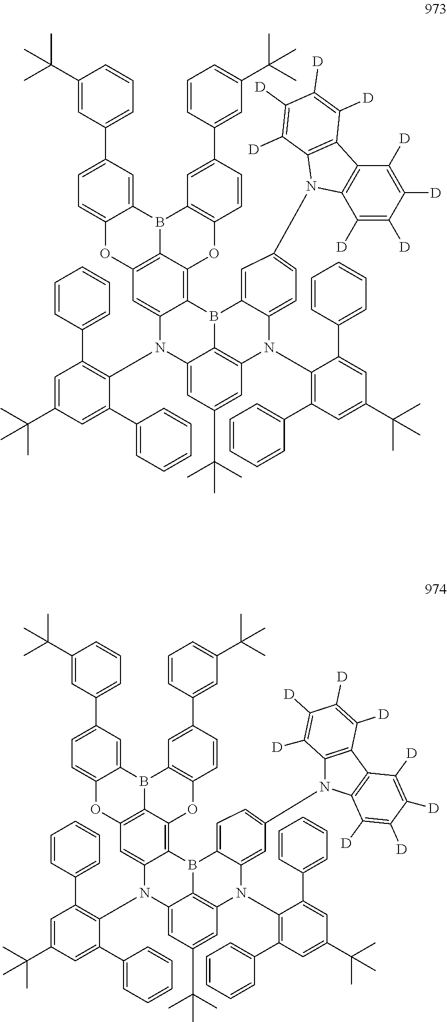

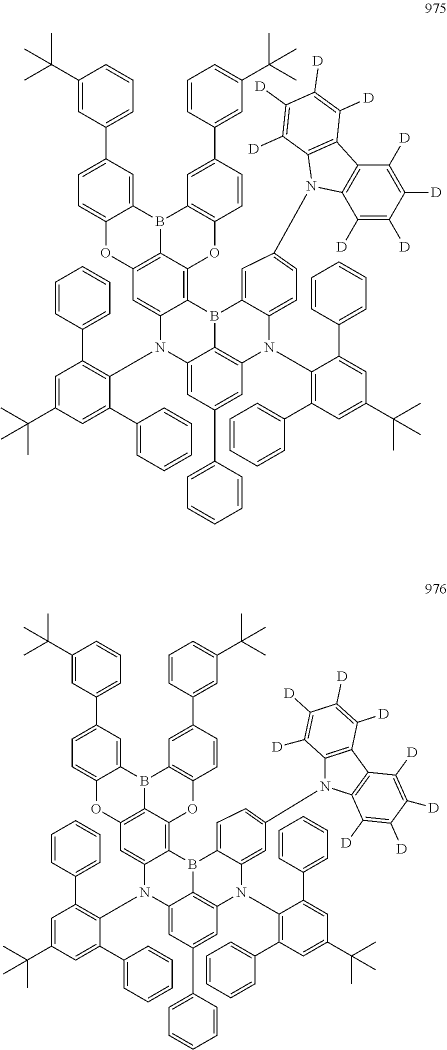

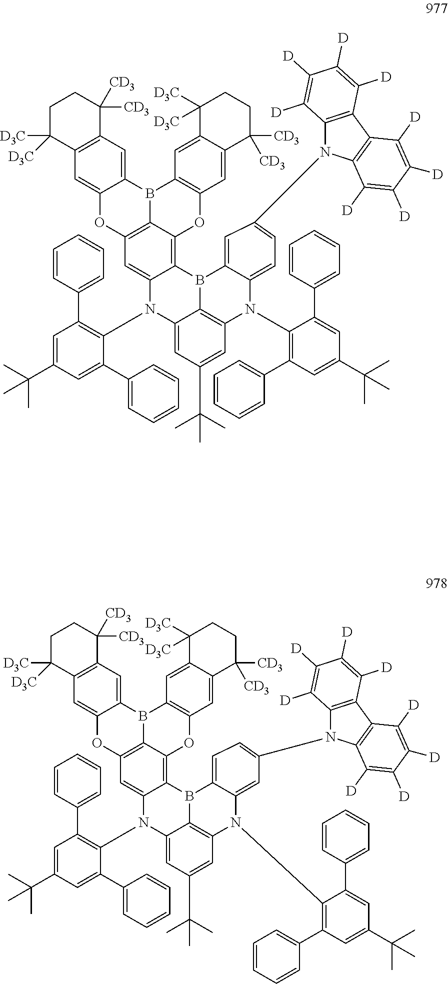

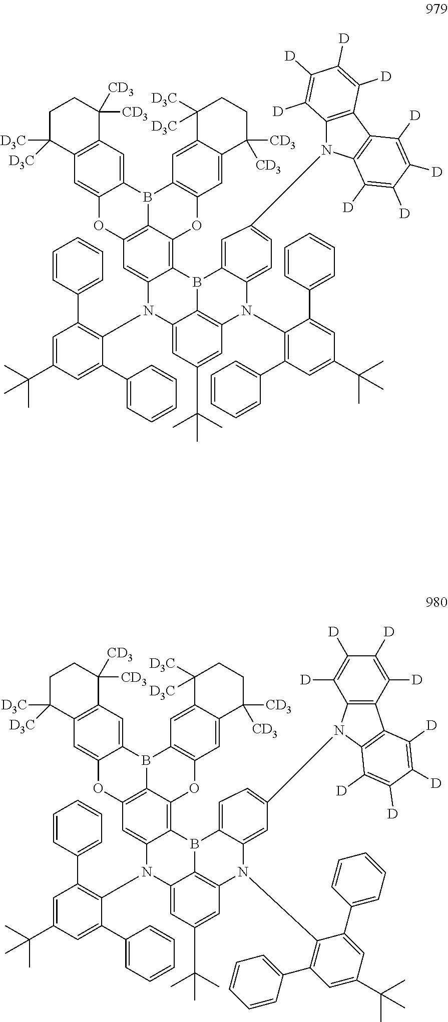

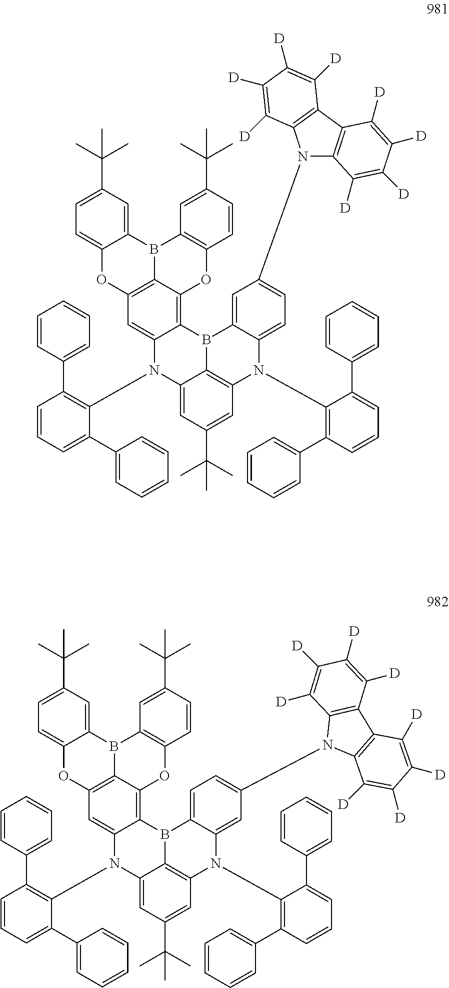 [SMILES: [2H]c1c([2H])c([2H])c2c(c1[2H])c1c([2H])c([2H])c([2H])c([2H])c1n2-c1ccc2c(c1)B1c3c(cc(C(C)(C)C)cc3N(c3c(-c4ccccc4)cccc3-c3ccccc3)c3cc4c5c(c31)Oc1ccc(C(C)(C)C)cc1B5c1cc(C(C)(C)C)ccc1O4)N2c1c(-c2ccccc2)cccc1-c1ccccc1 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(C(C)(C)C)cc3c1B2c1c(cc2c4c1Oc1ccc(C(C)(C)C)cc1B4c1cc(C(C)(C)C)ccc1O2)N3c1c(-c2ccccc2)cccc1-c1ccccc1]

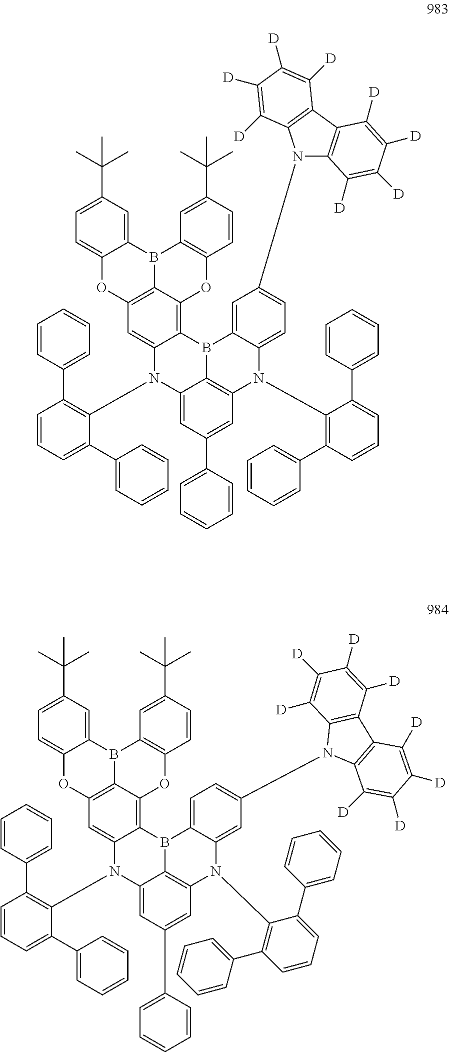 [SMILES: [2H]c1c([2H])c([2H])c2c(c1[2H])c1c([2H])c([2H])c([2H])c([2H])c1n2-c1ccc2c(c1)B1c3c(cc(-c4ccccc4)cc3N(c3c(-c4ccccc4)cccc3-c3ccccc3)c3cc4c5c(c31)Oc1ccc(C(C)(C)C)cc1B5c1cc(C(C)(C)C)ccc1O4)N2c1c(-c2ccccc2)cccc1-c1ccccc1 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3ccccc3)cc3c1B2c1c(cc2c4c1Oc1ccc(C(C)(C)C)cc1B4c1cc(C(C)(C)C)ccc1O2)N3c1c(-c2ccccc2)cccc1-c1ccccc1]

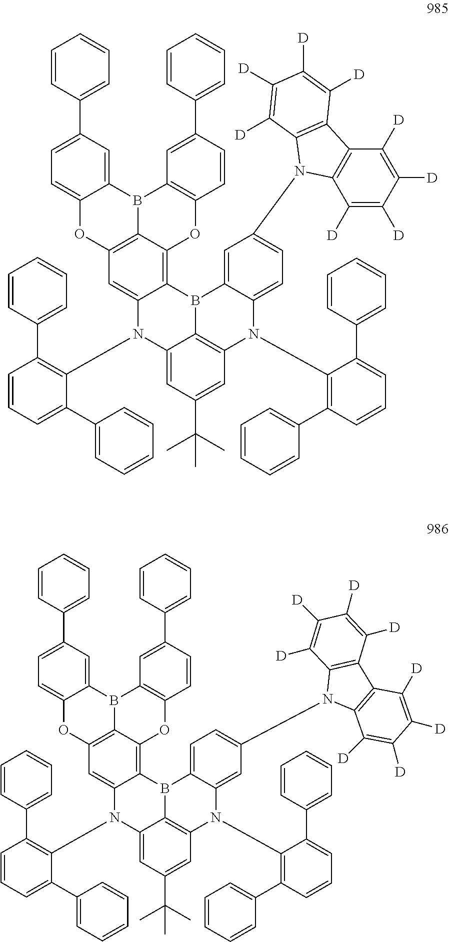 [SMILES: [2H]c1c([2H])c([2H])c2c(c1[2H])c1c([2H])c([2H])c([2H])c([2H])c1n2-c1ccc2c(c1)B1c3c(cc(C(C)(C)C)cc3N(c3c(-c4ccccc4)cccc3-c3ccccc3)c3cc4c5c(c31)Oc1ccc(-c3ccccc3)cc1B5c1cc(-c3ccccc3)ccc1O4)N2c1c(-c2ccccc2)cccc1-c1ccccc1 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(C(C)(C)C)cc3c1B2c1c(cc2c4c1Oc1ccc(-c5ccccc5)cc1B4c1cc(-c4ccccc4)ccc1O2)N3c1c(-c2ccccc2)cccc1-c1ccccc1]

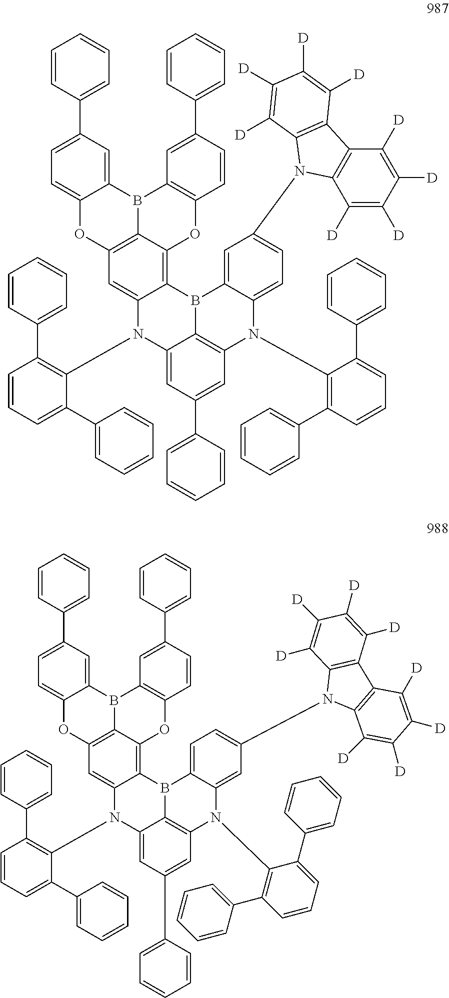 [SMILES: [2H]c1c([2H])c([2H])c2c(c1[2H])c1c([2H])c([2H])c([2H])c([2H])c1n2-c1ccc2c(c1)B1c3c(cc(-c4ccccc4)cc3N(c3c(-c4ccccc4)cccc3-c3ccccc3)c3cc4c5c(c31)Oc1ccc(-c3ccccc3)cc1B5c1cc(-c3ccccc3)ccc1O4)N2c1c(-c2ccccc2)cccc1-c1ccccc1 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3ccccc3)cc3c1B2c1c(cc2c4c1Oc1ccc(-c5ccccc5)cc1B4c1cc(-c4ccccc4)ccc1O2)N3c1c(-c2ccccc2)cccc1-c1ccccc1]

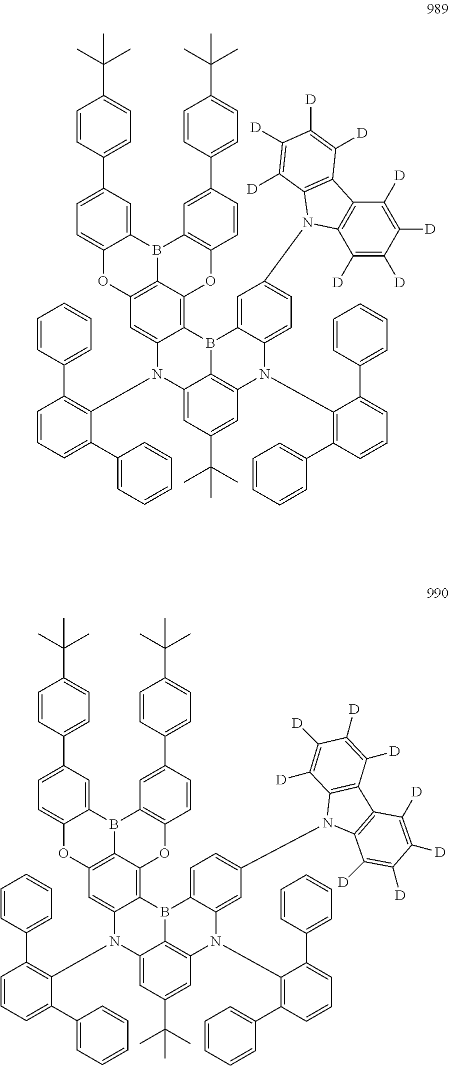 [SMILES: [2H]c1c([2H])c([2H])c2c(c1[2H])c1c([2H])c([2H])c([2H])c([2H])c1n2-c1ccc2c(c1)B1c3c(cc(C(C)(C)C)cc3N(c3c(-c4ccccc4)cccc3-c3ccccc3)c3cc4c5c(c31)Oc1ccc(-c3ccc(C(C)(C)C)cc3)cc1B5c1cc(-c3ccc(C(C)(C)C)cc3)ccc1O4)N2c1c(-c2ccccc2)cccc1-c1ccccc1 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(C(C)(C)C)cc3c1B2c1c(cc2c4c1Oc1ccc(-c5ccc(C(C)(C)C)cc5)cc1B4c1cc(-c4ccc(C(C)(C)C)cc4)ccc1O2)N3c1c(-c2ccccc2)cccc1-c1ccccc1]

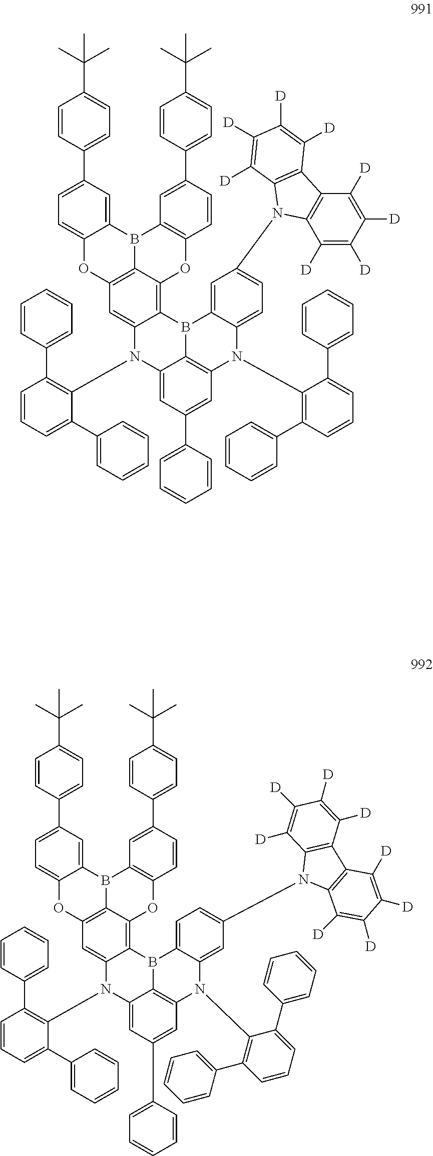 [SMILES: [2H]c1c([2H])c([2H])c2c(c1[2H])c1c([2H])c([2H])c([2H])c([2H])c1n2-c1ccc2c(c1)B1c3c(cc(-c4ccccc4)cc3N(c3c(-c4ccccc4)cccc3-c3ccccc3)c3cc4c5c(c31)Oc1ccc(-c3ccc(C(C)(C)C)cc3)cc1B5c1cc(-c3ccc(C(C)(C)C)cc3)ccc1O4)N2c1c(-c2ccccc2)cccc1-c1ccccc1 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3ccccc3)cc3c1B2c1c(cc2c4c1Oc1ccc(-c5ccc(C(C)(C)C)cc5)cc1B4c1cc(-c4ccc(C(C)(C)C)cc4)ccc1O2)N3c1c(-c2ccccc2)cccc1-c1ccccc1]

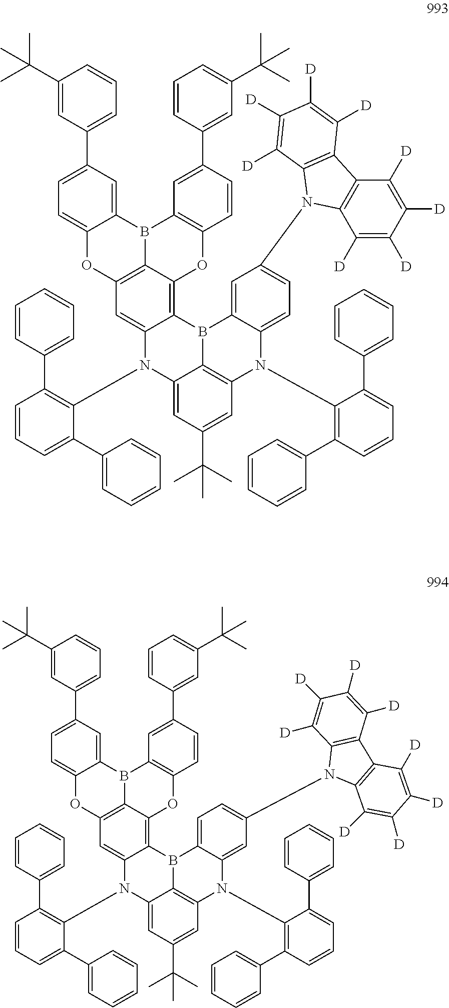 [SMILES: [2H]c1c([2H])c([2H])c2c(c1[2H])c1c([2H])c([2H])c([2H])c([2H])c1n2-c1ccc2c(c1)B1c3c(cc(C(C)(C)C)cc3N(c3c(-c4ccccc4)cccc3-c3ccccc3)c3cc4c5c(c31)Oc1ccc(-c3cccc(C(C)(C)C)c3)cc1B5c1cc(-c3cccc(C(C)(C)C)c3)ccc1O4)N2c1c(-c2ccccc2)cccc1-c1ccccc1 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(C(C)(C)C)cc3c1B2c1c(cc2c4c1Oc1ccc(-c5cccc(C(C)(C)C)c5)cc1B4c1cc(-c4cccc(C(C)(C)C)c4)ccc1O2)N3c1c(-c2ccccc2)cccc1-c1ccccc1]

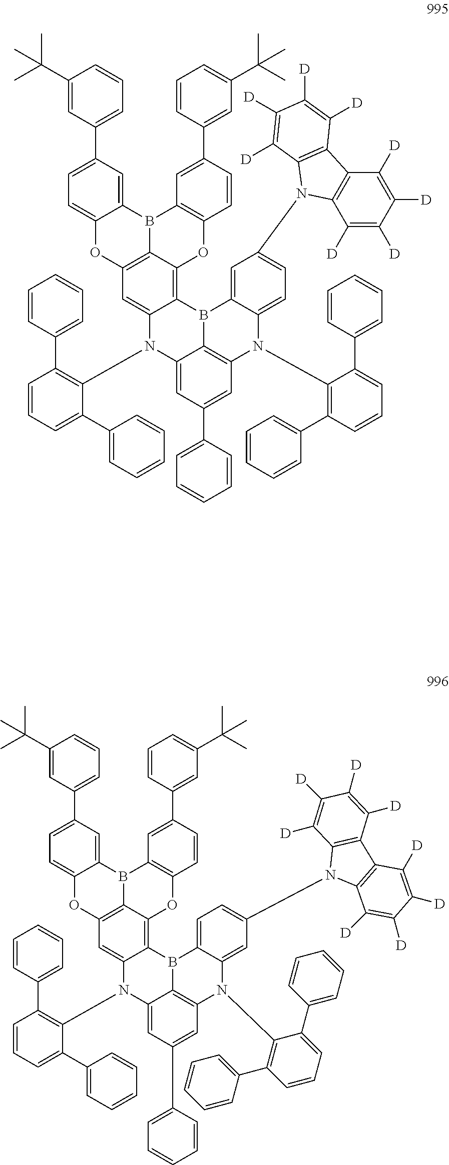 [SMILES: [2H]c1c([2H])c([2H])c2c(c1[2H])c1c([2H])c([2H])c([2H])c([2H])c1n2-c1ccc2c(c1)B1c3c(cc(-c4ccccc4)cc3N(c3c(-c4ccccc4)cccc3-c3ccccc3)c3cc4c5c(c31)Oc1ccc(-c3cccc(C(C)(C)C)c3)cc1B5c1cc(-c3cccc(C(C)(C)C)c3)ccc1O4)N2c1c(-c2ccccc2)cccc1-c1ccccc1 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3ccccc3)cc3c1B2c1c(cc2c4c1Oc1ccc(-c5cccc(C(C)(C)C)c5)cc1B4c1cc(-c4cccc(C(C)(C)C)c4)ccc1O2)N3c1c(-c2ccccc2)cccc1-c1ccccc1]

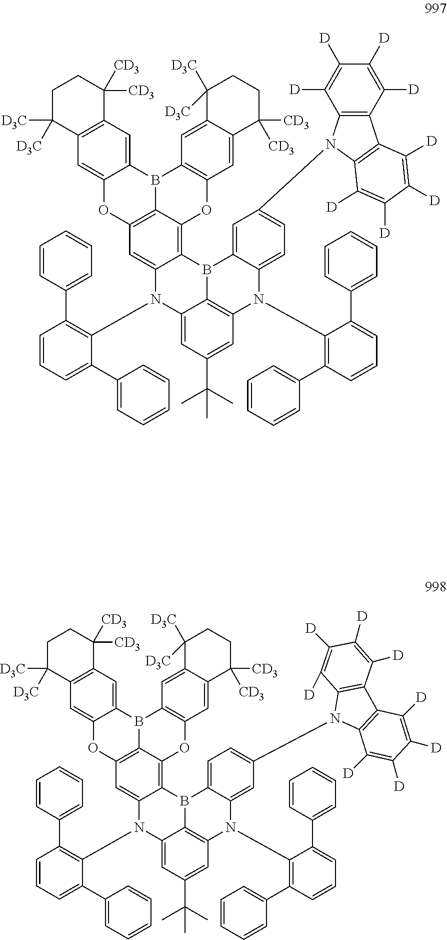

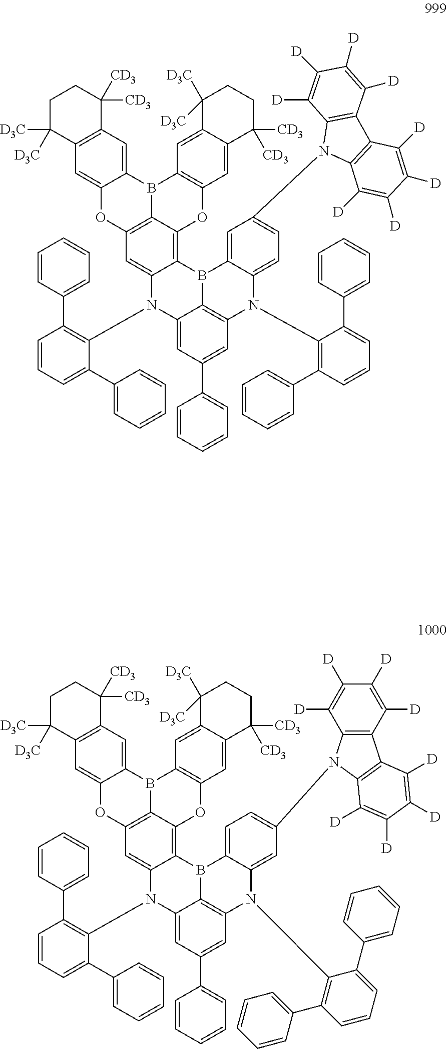

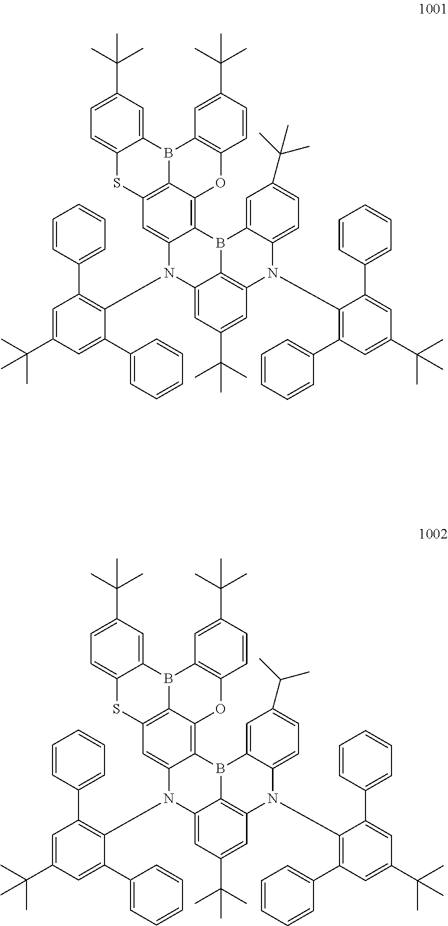

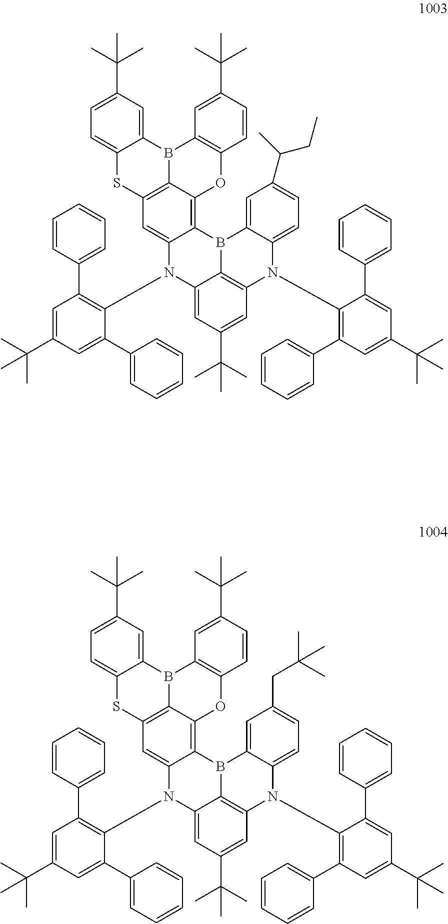

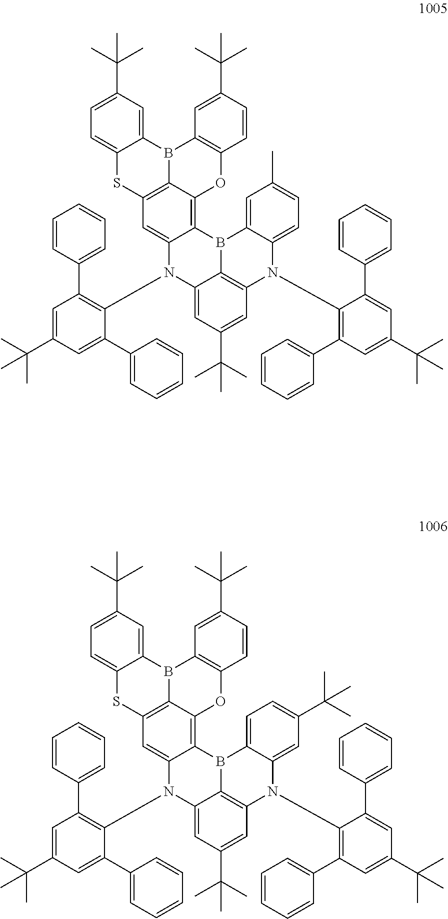

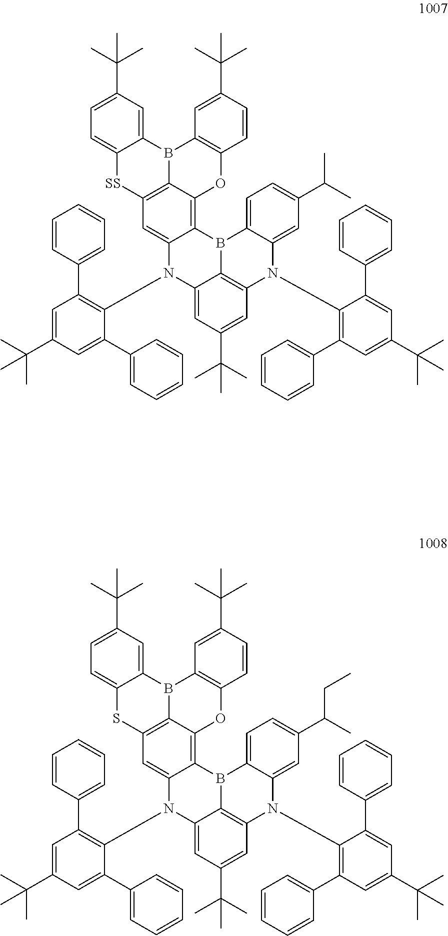

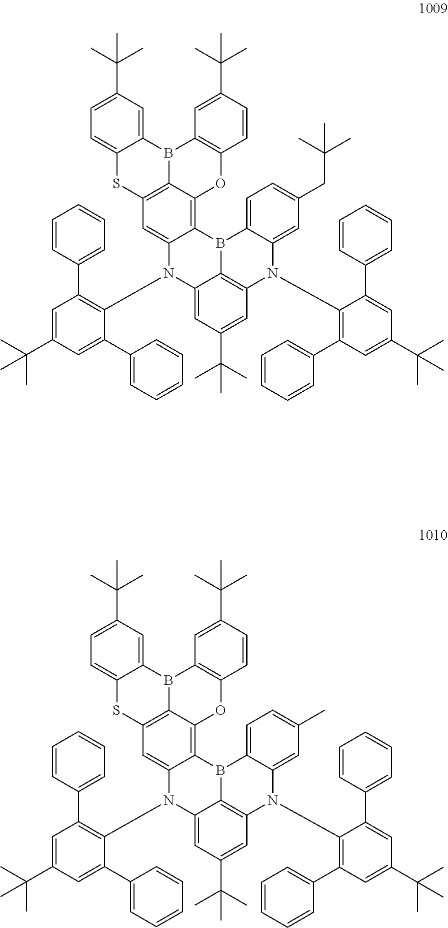

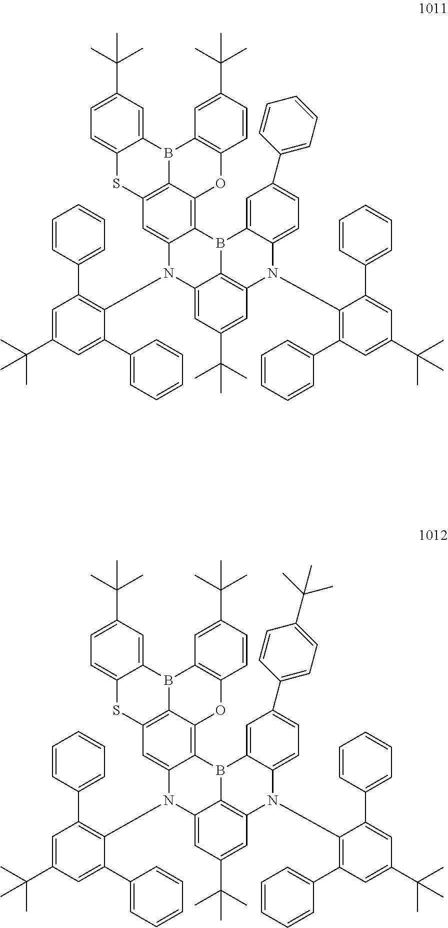

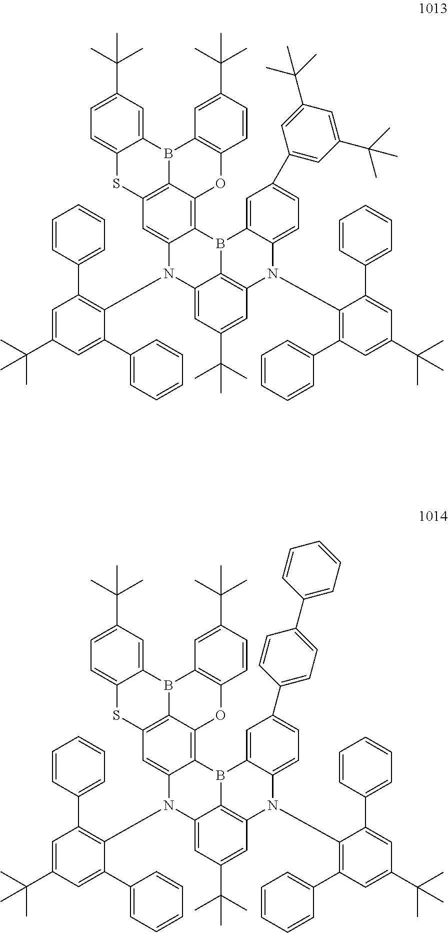

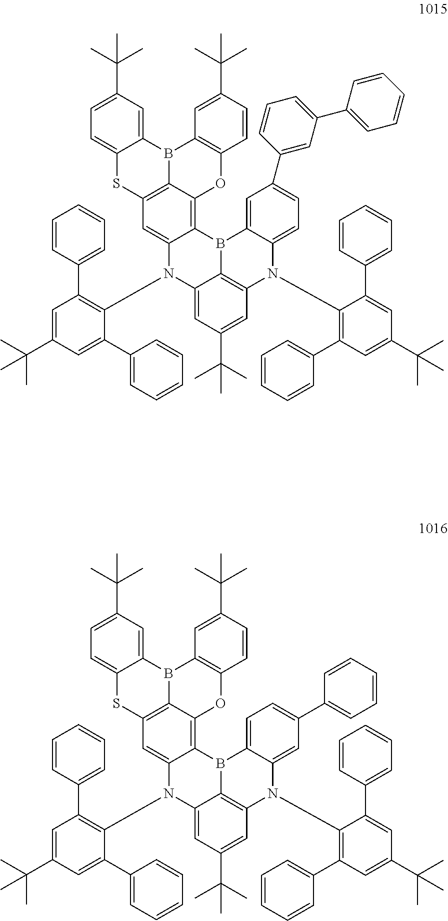

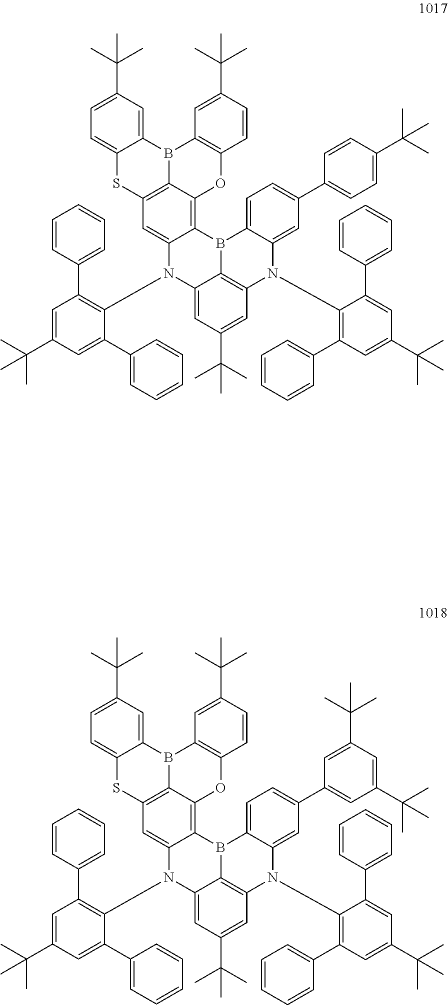

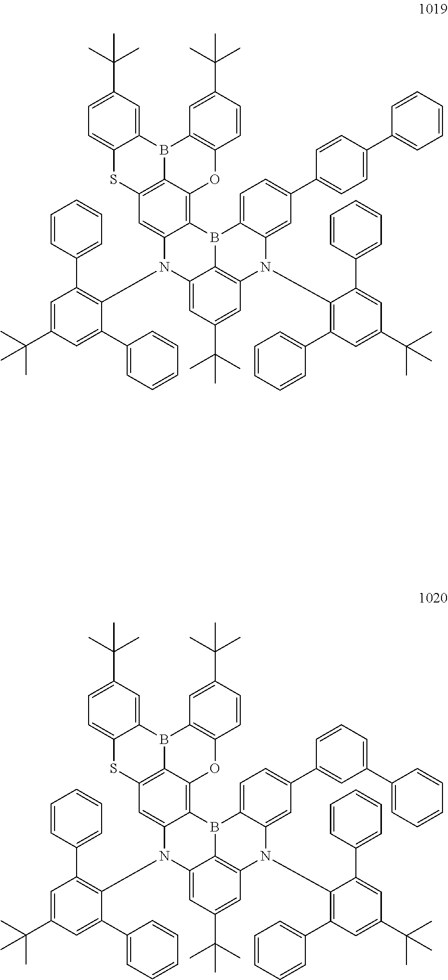 [SMILES: CC(C)(C)c1ccc2c(c1)B1c3cc(C(C)(C)C)ccc3Sc3cc4c(c(c31)O2)B1c2ccc(-c3ccc(-c5ccccc5)cc3)cc2N(c2c(-c3ccccc3)cc(C(C)(C)C)cc2-c2ccccc2)c2cc(C(C)(C)C)cc(c21)N4c1c(-c2ccccc2)cc(C(C)(C)C)cc1-c1ccccc1 ; CC(C)(C)c1ccc2c(c1)B1c3cc(C(C)(C)C)ccc3Sc3cc4c(c(c31)O2)B1c2ccc(-c3cccc(-c5ccccc5)c3)cc2N(c2c(-c3ccccc3)cc(C(C)(C)C)cc2-c2ccccc2)c2cc(C(C)(C)C)cc(c21)N4c1c(-c2ccccc2)cc(C(C)(C)C)cc1-c1ccccc1]

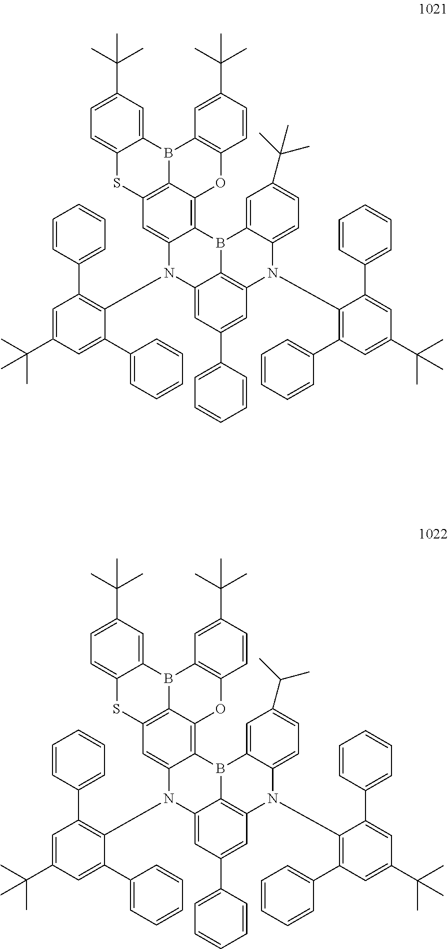

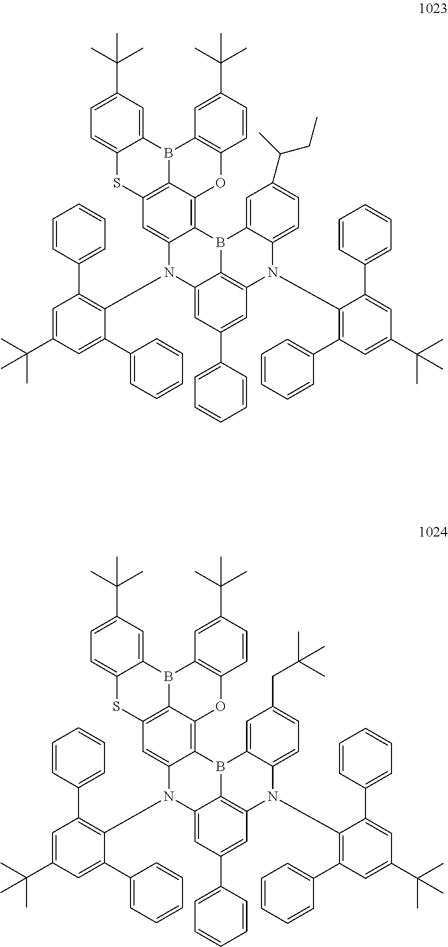

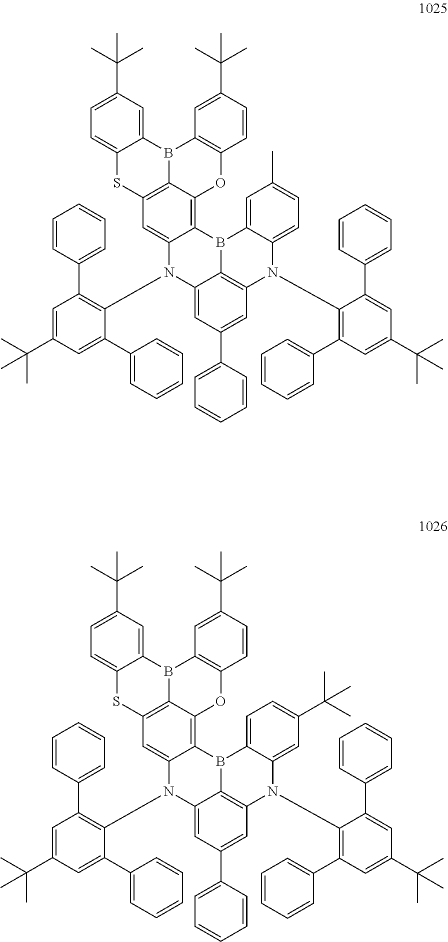

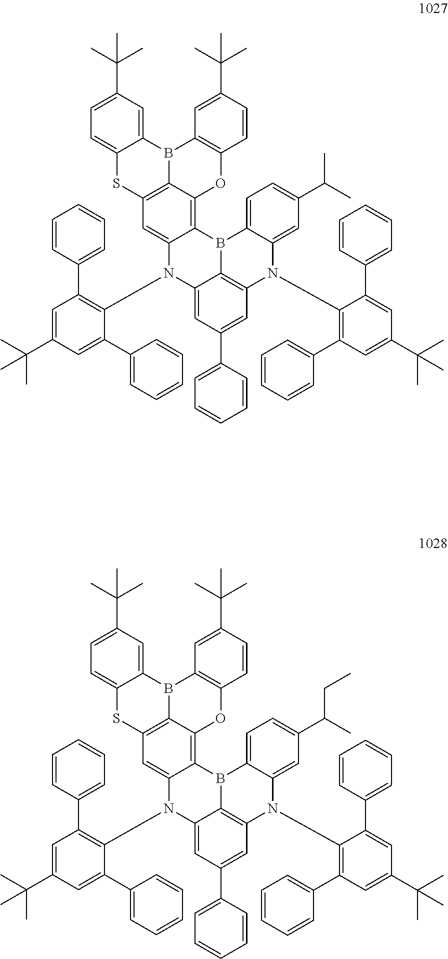

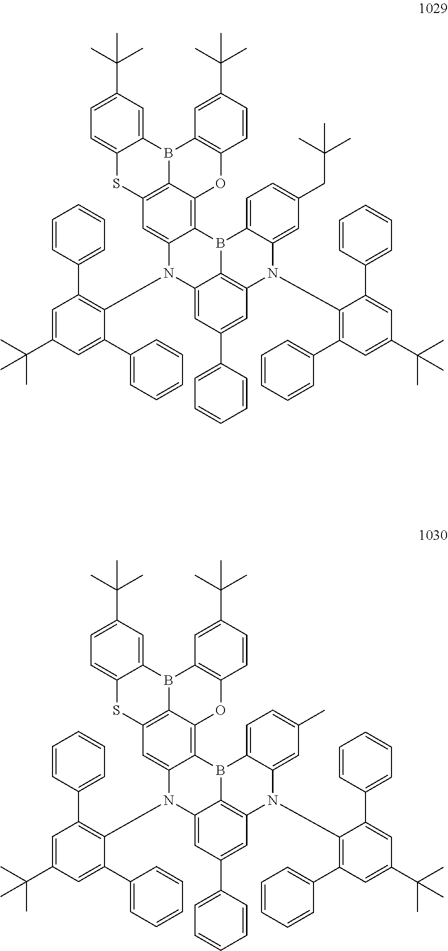

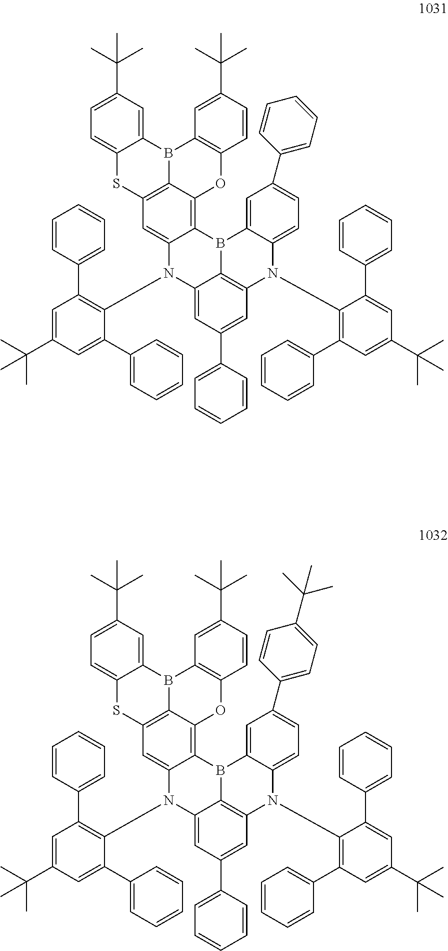

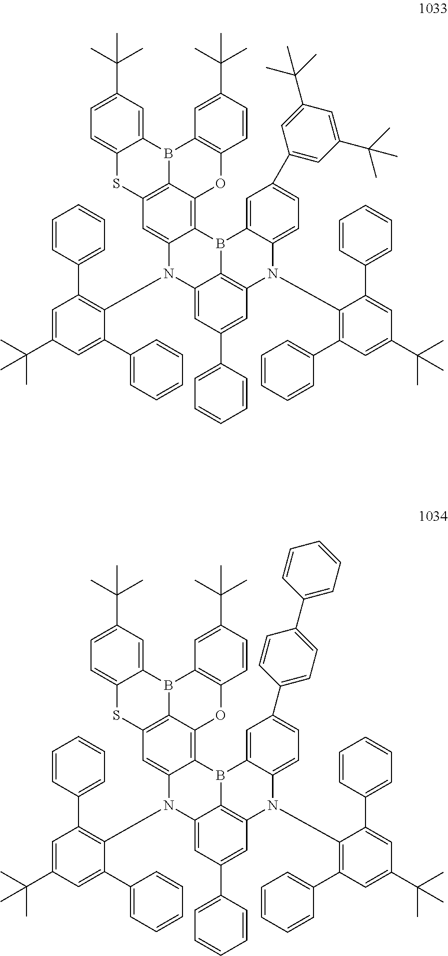

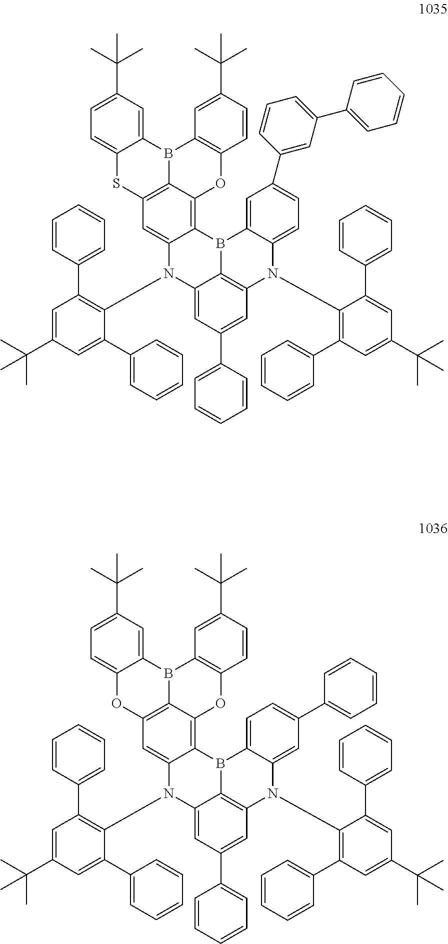

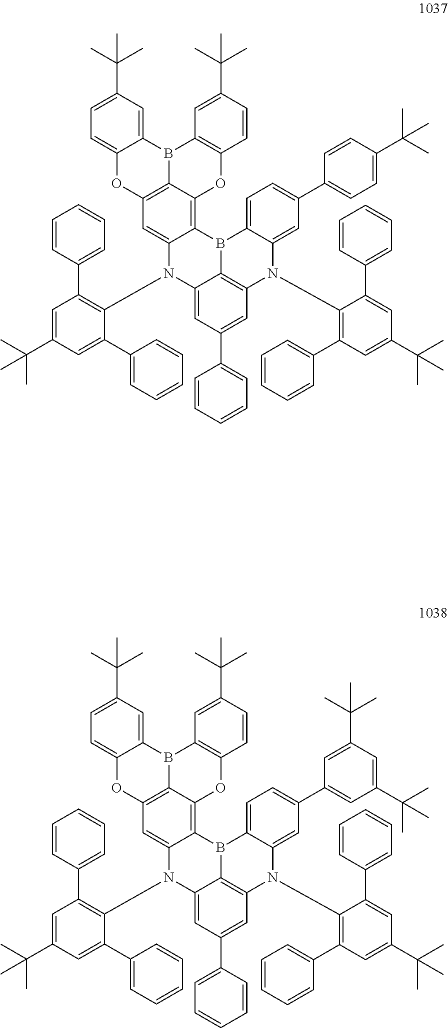

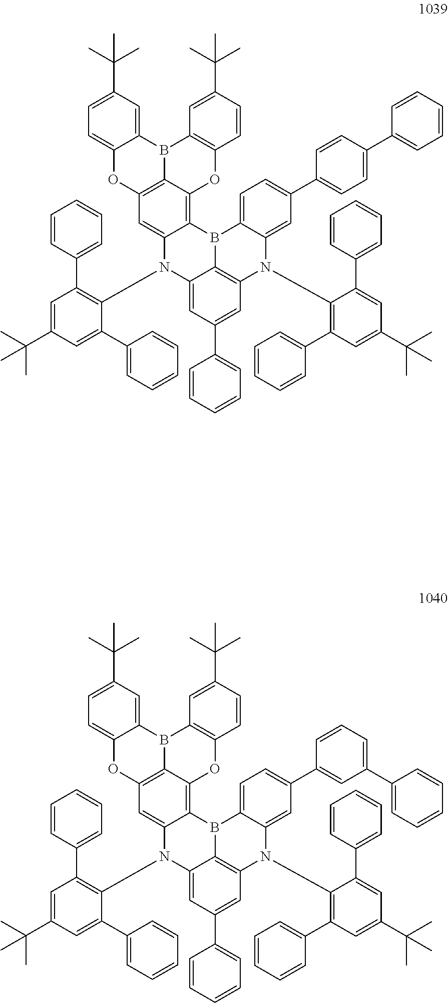 [SMILES: CC(C)(C)c1ccc2c(c1)B1c3cc(C(C)(C)C)ccc3Oc3c1c(cc1c3B3c4ccc(-c5ccc(-c6ccccc6)cc5)cc4N(c4c(-c5ccccc5)cc(C(C)(C)C)cc4-c4ccccc4)c4cc(-c5ccccc5)cc(c43)N1c1c(-c3ccccc3)cc(C(C)(C)C)cc1-c1ccccc1)O2 ; CC(C)(C)c1ccc2c(c1)B1c3cc(C(C)(C)C)ccc3Oc3c1c(cc1c3B3c4ccc(-c5cccc(-c6ccccc6)c5)cc4N(c4c(-c5ccccc5)cc(C(C)(C)C)cc4-c4ccccc4)c4cc(-c5ccccc5)cc(c43)N1c1c(-c3ccccc3)cc(C(C)(C)C)cc1-c1ccccc1)O2]

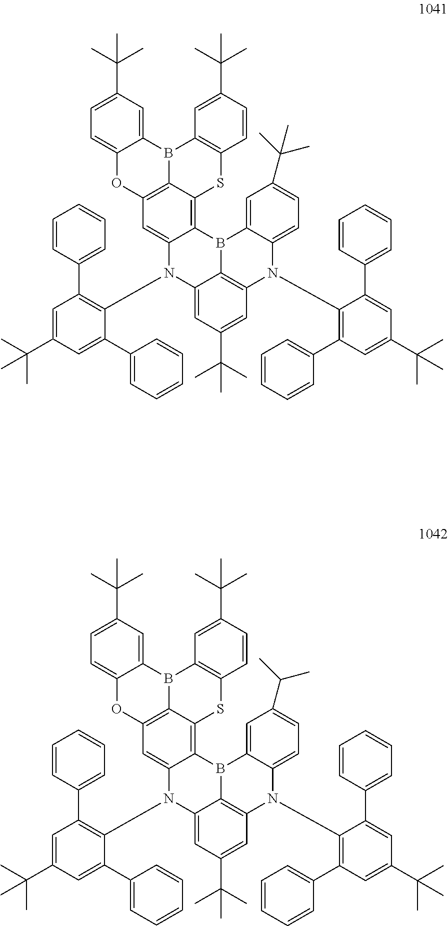

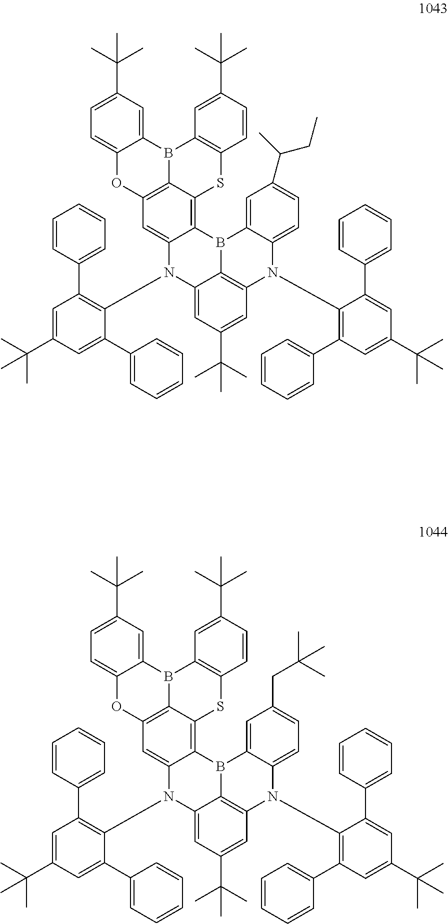

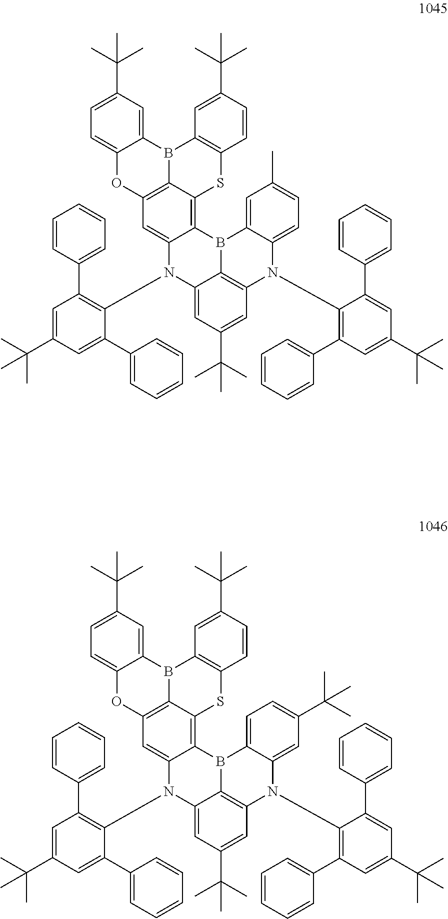

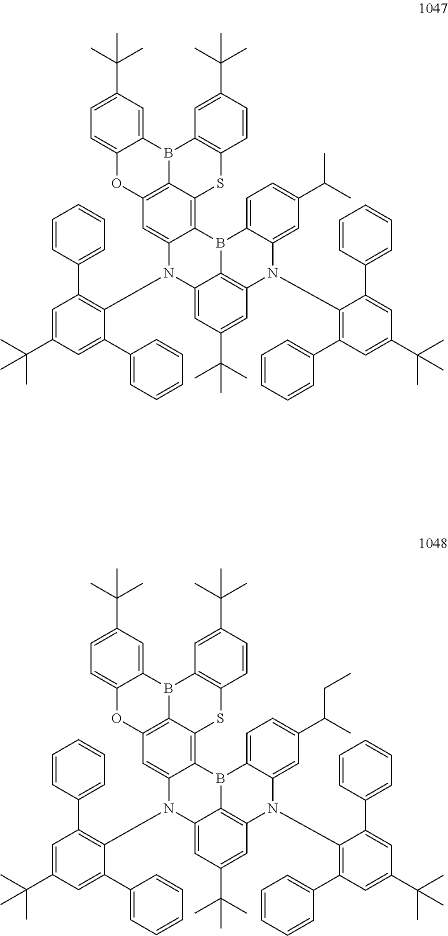

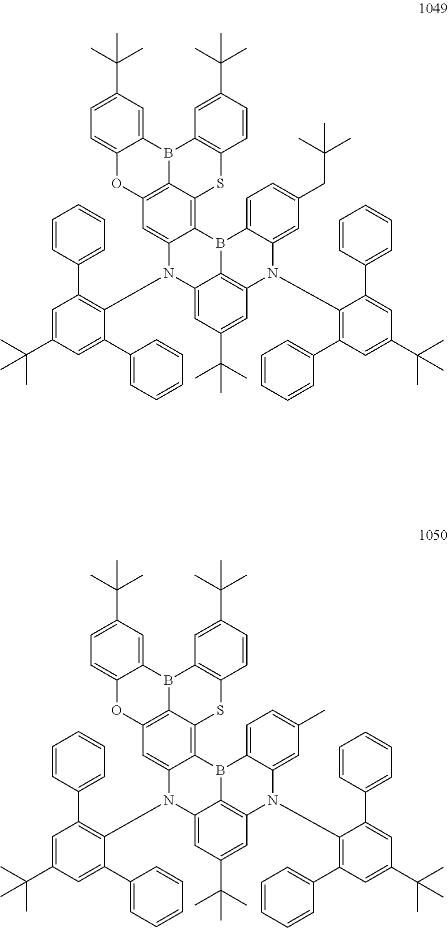

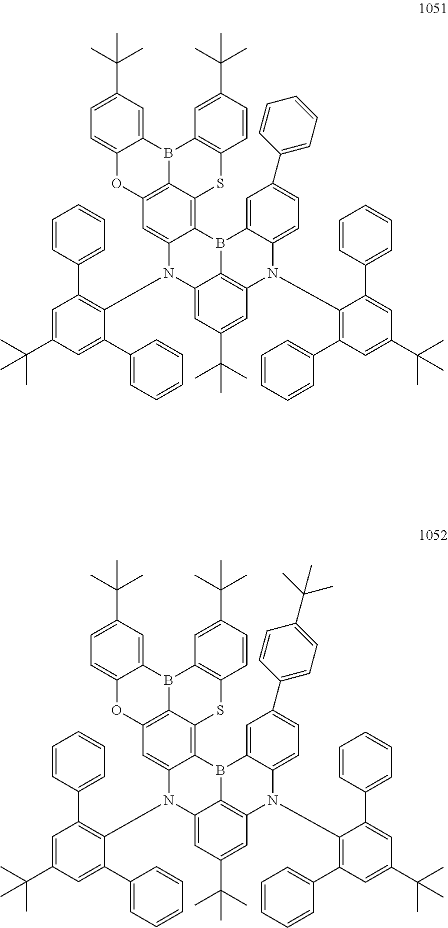

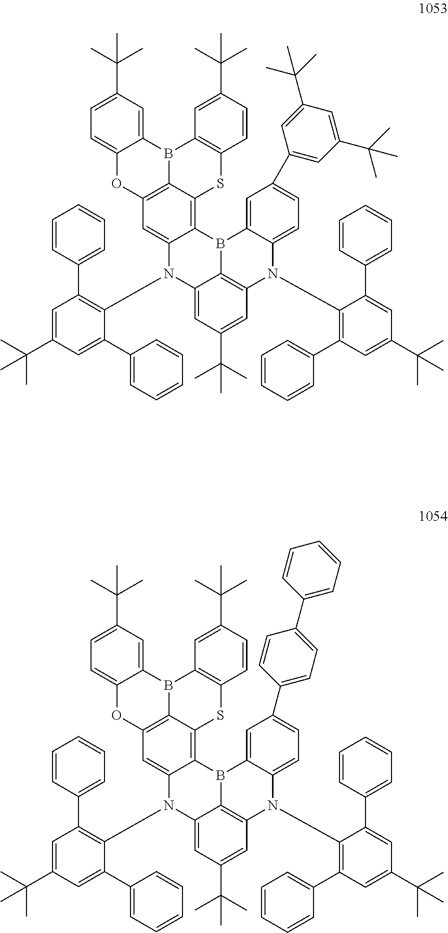

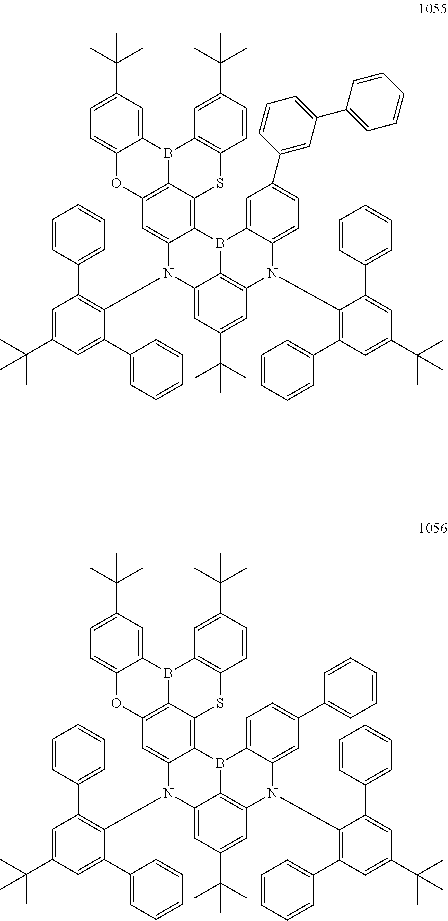

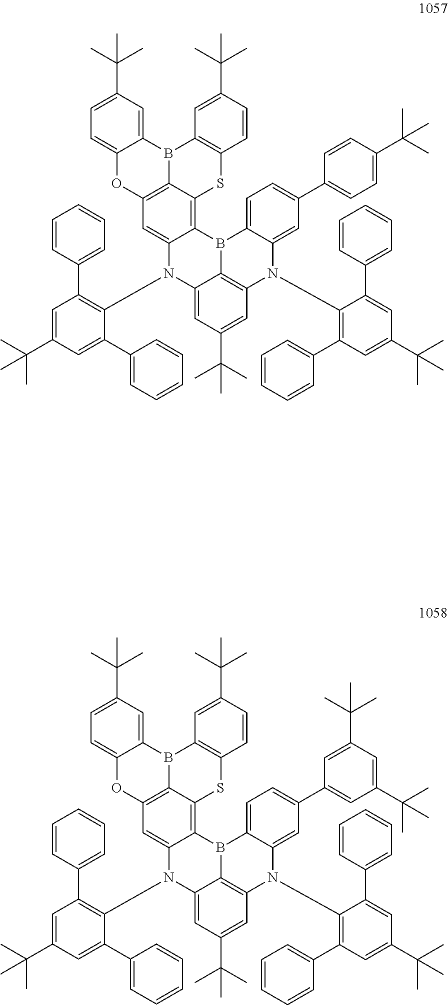

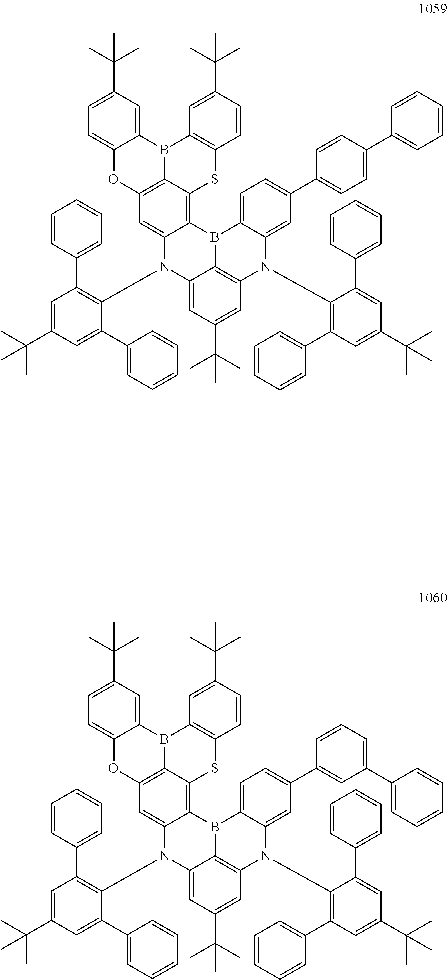 [SMILES: CC(C)(C)c1ccc2c(c1)B1c3cc(C(C)(C)C)ccc3Sc3c1c(cc1c3B3c4ccc(-c5ccc(-c6ccccc6)cc5)cc4N(c4c(-c5ccccc5)cc(C(C)(C)C)cc4-c4ccccc4)c4cc(C(C)(C)C)cc(c43)N1c1c(-c3ccccc3)cc(C(C)(C)C)cc1-c1ccccc1)O2 ; CC(C)(C)c1ccc2c(c1)B1c3cc(C(C)(C)C)ccc3Sc3c1c(cc1c3B3c4ccc(-c5cccc(-c6ccccc6)c5)cc4N(c4c(-c5ccccc5)cc(C(C)(C)C)cc4-c4ccccc4)c4cc(C(C)(C)C)cc(c43)N1c1c(-c3ccccc3)cc(C(C)(C)C)cc1-c1ccccc1)O2]

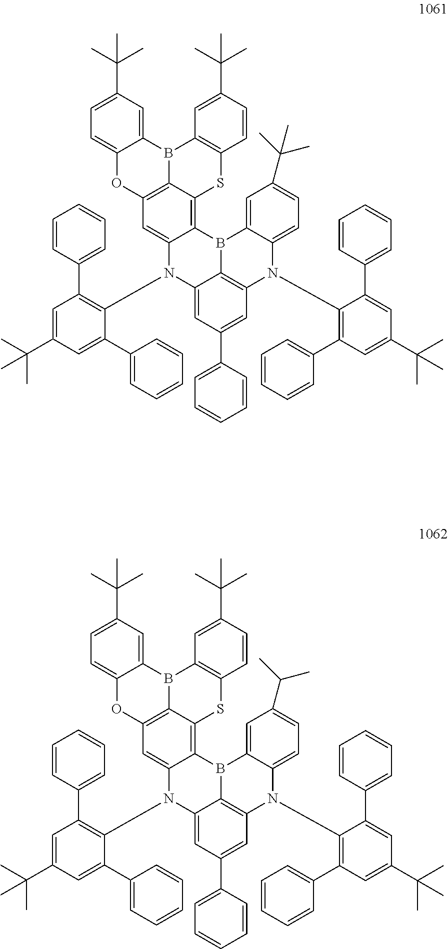

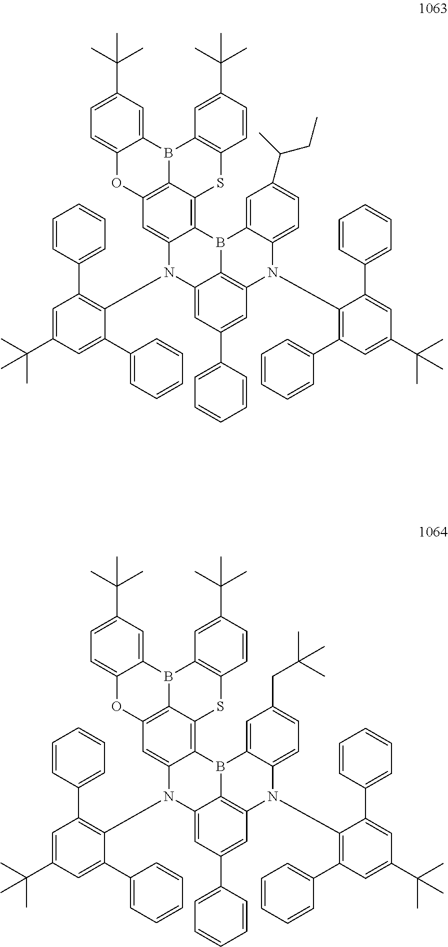

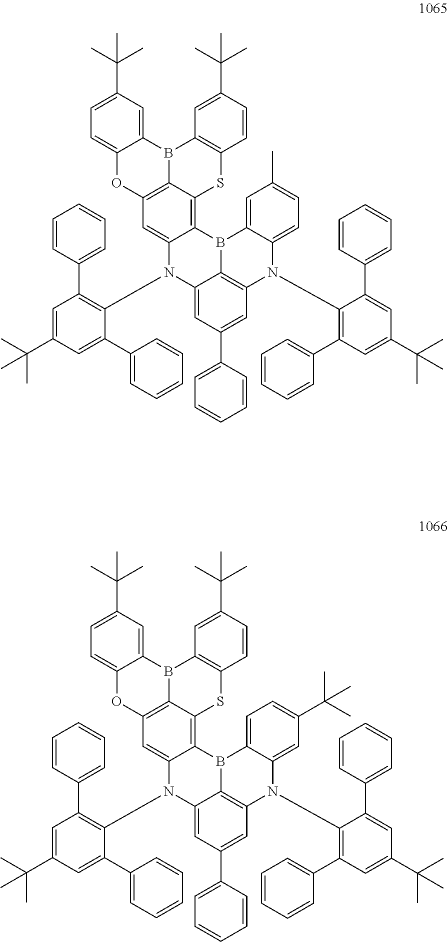

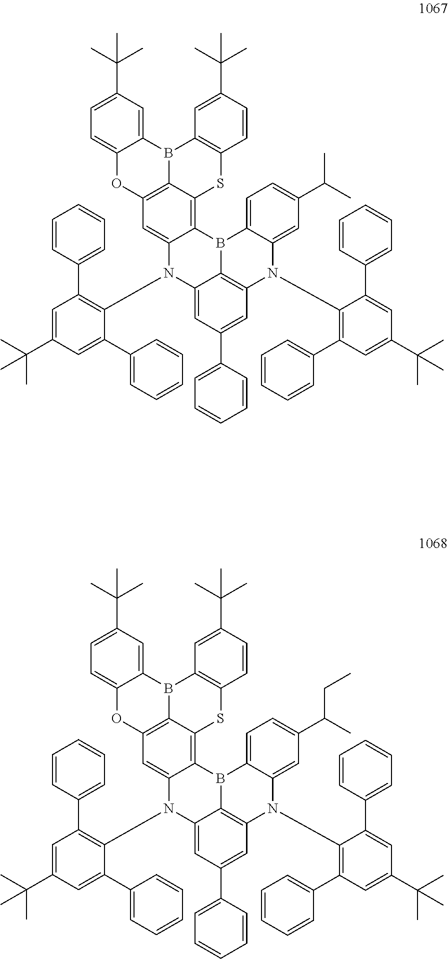

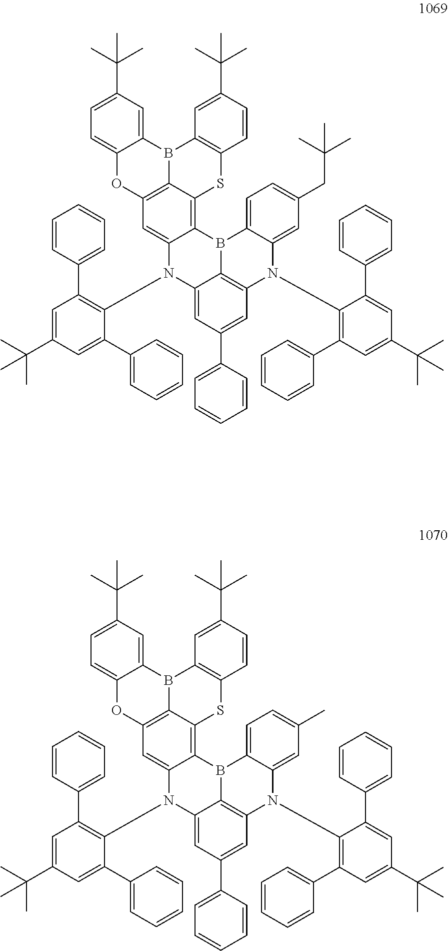

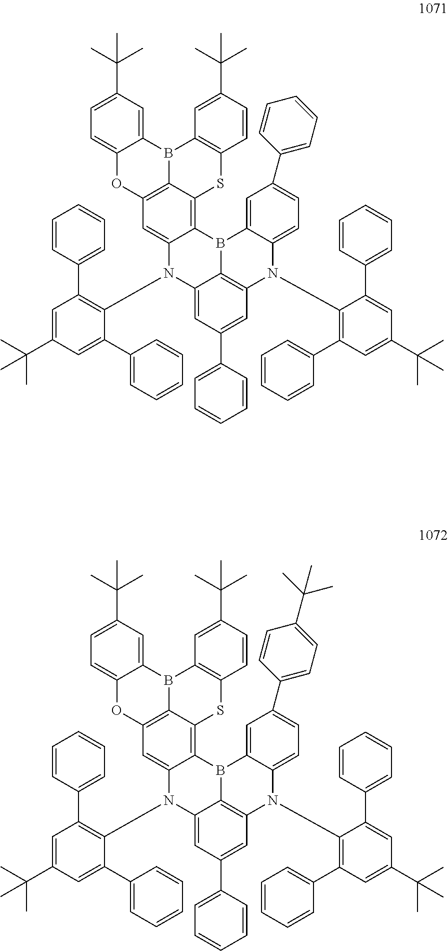

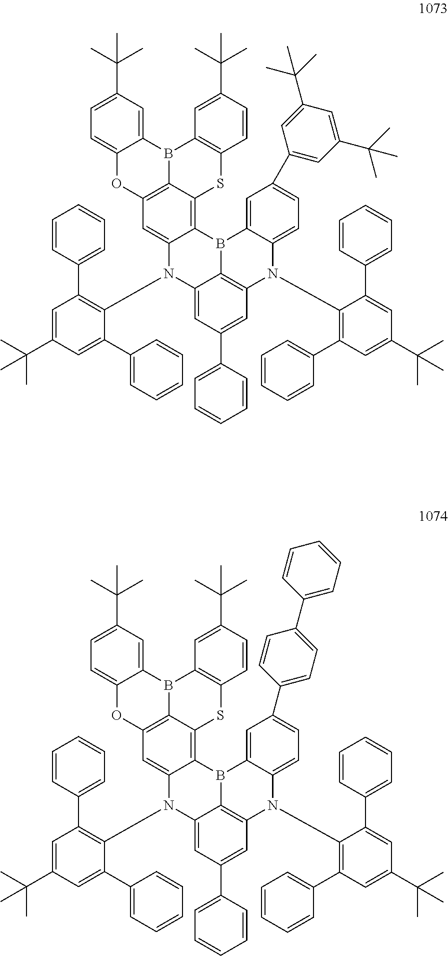

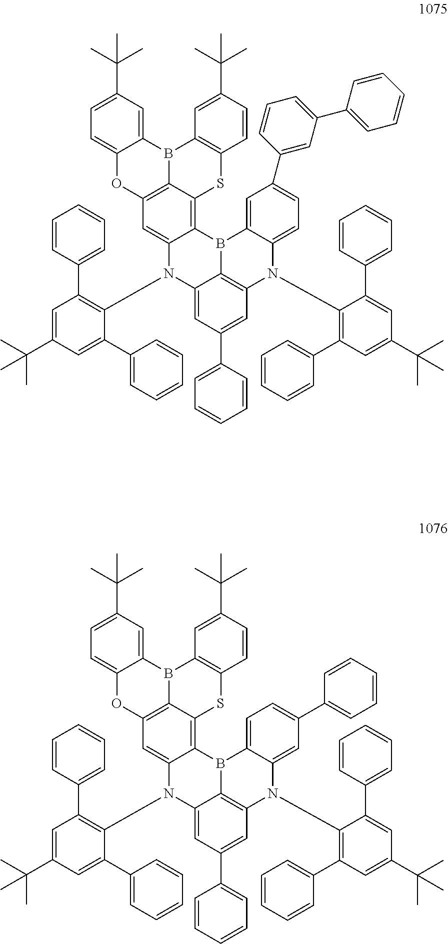

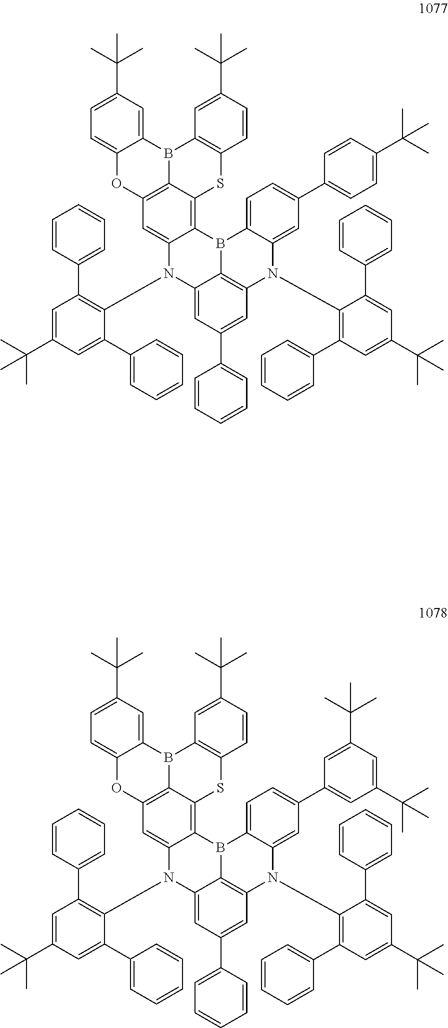

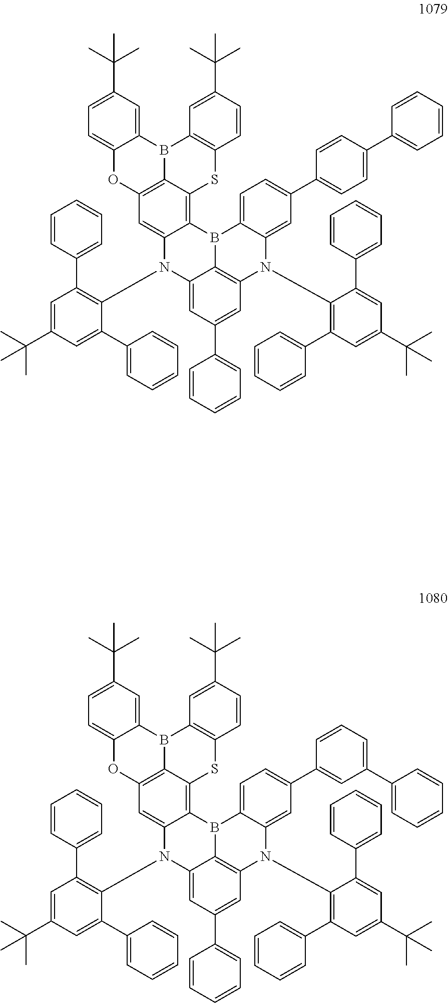 [SMILES: CC(C)(C)c1ccc2c(c1)B1c3cc(C(C)(C)C)ccc3Sc3c1c(cc1c3B3c4ccc(-c5ccc(-c6ccccc6)cc5)cc4N(c4c(-c5ccccc5)cc(C(C)(C)C)cc4-c4ccccc4)c4cc(-c5ccccc5)cc(c43)N1c1c(-c3ccccc3)cc(C(C)(C)C)cc1-c1ccccc1)O2 ; CC(C)(C)c1ccc2c(c1)B1c3cc(C(C)(C)C)ccc3Sc3c1c(cc1c3B3c4ccc(-c5cccc(-c6ccccc6)c5)cc4N(c4c(-c5ccccc5)cc(C(C)(C)C)cc4-c4ccccc4)c4cc(-c5ccccc5)cc(c43)N1c1c(-c3ccccc3)cc(C(C)(C)C)cc1-c1ccccc1)O2]

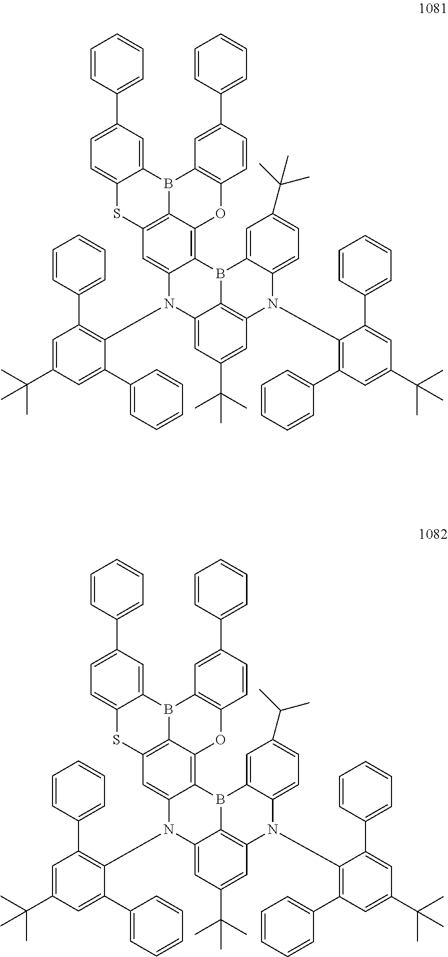

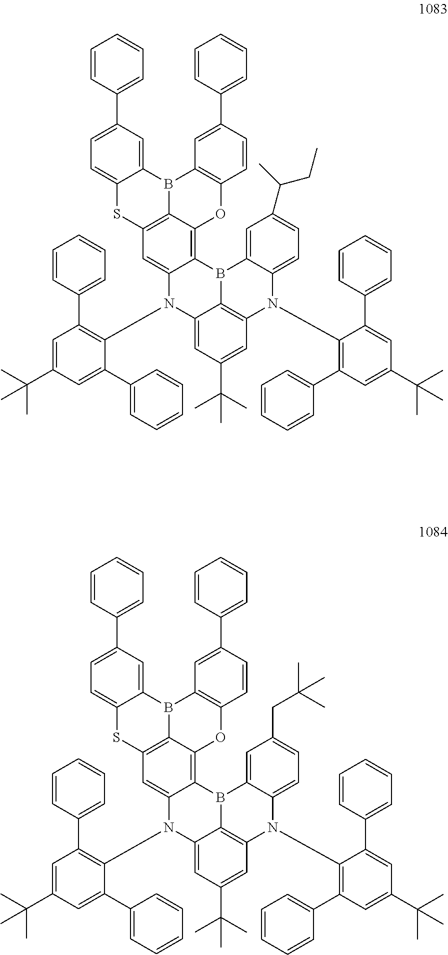

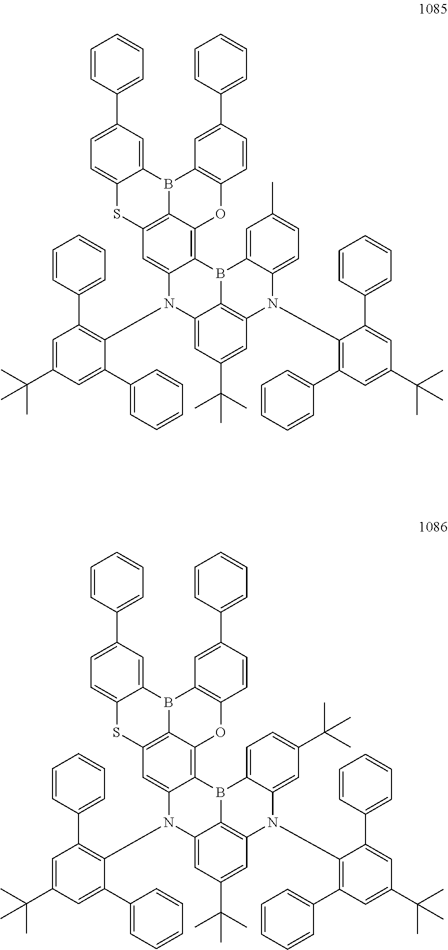

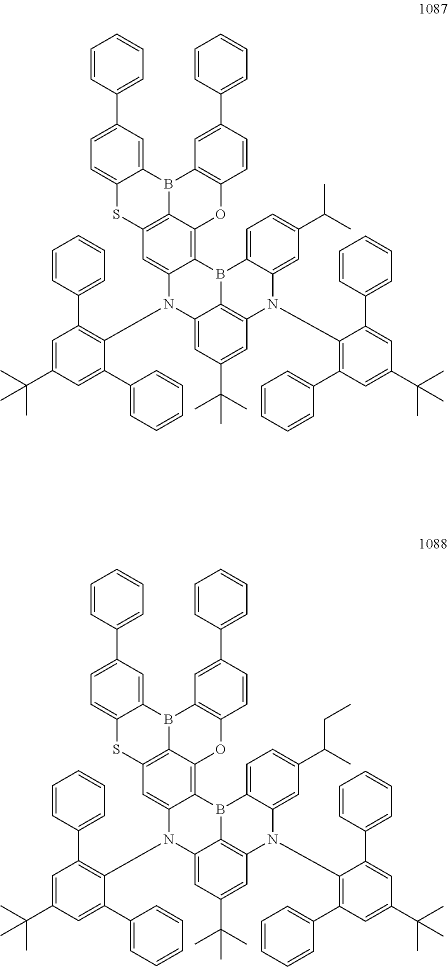

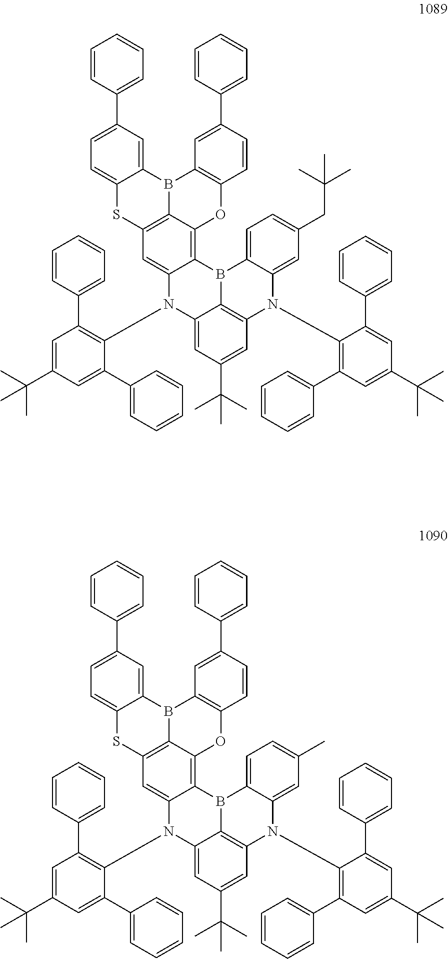

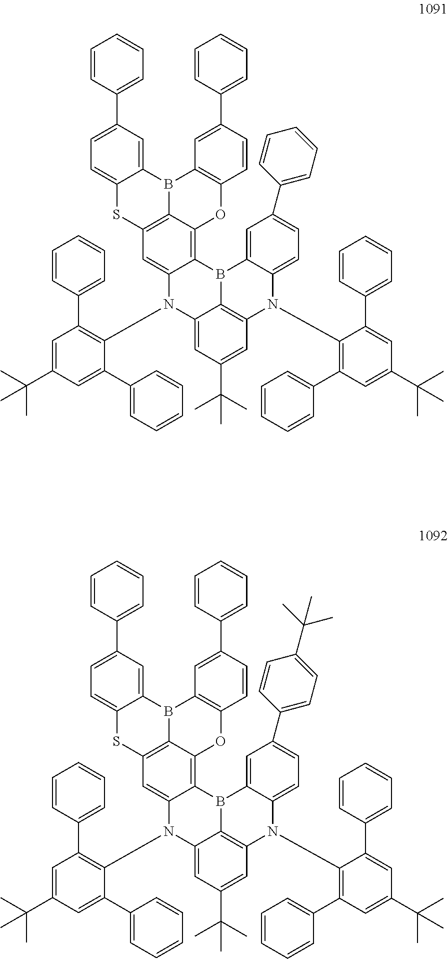

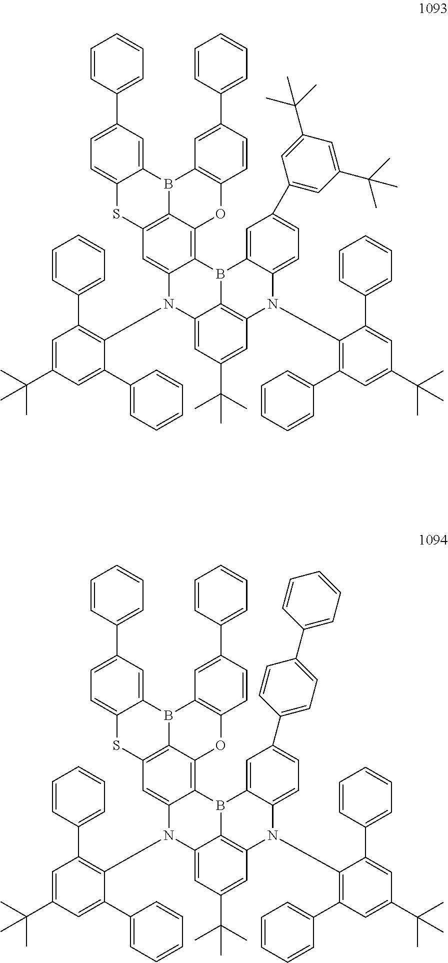

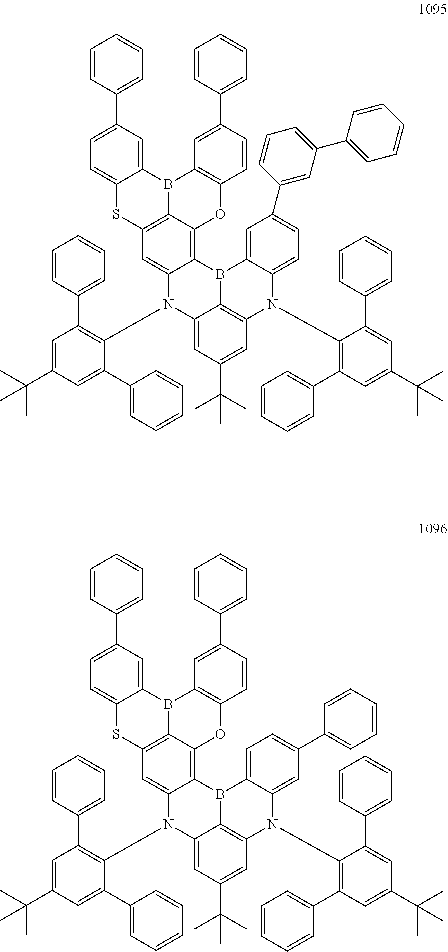

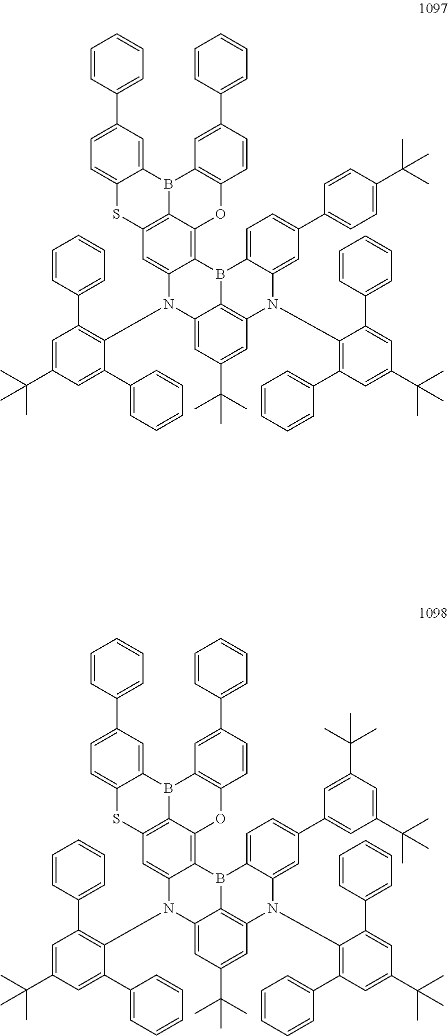

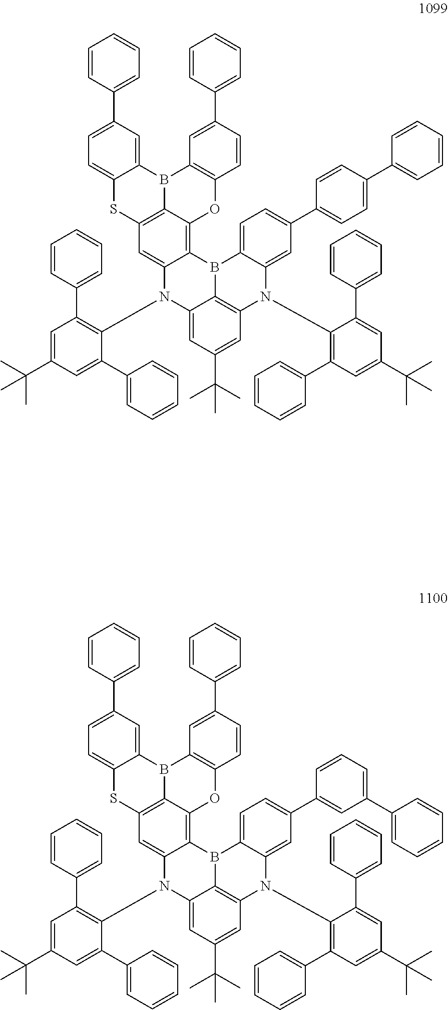 [SMILES: CC(C)(C)c1cc(-c2ccccc2)c(N2c3cc(-c4ccc(-c5ccccc5)cc4)ccc3B3c4c2cc(C(C)(C)C)cc4N(c2c(-c4ccccc4)cc(C(C)(C)C)cc2-c2ccccc2)c2cc4c5c(c23)Oc2ccc(-c3ccccc3)cc2B5c2cc(-c3ccccc3)ccc2S4)c(-c2ccccc2)c1 ; CC(C)(C)c1cc(-c2ccccc2)c(N2c3cc(-c4cccc(-c5ccccc5)c4)ccc3B3c4c2cc(C(C)(C)C)cc4N(c2c(-c4ccccc4)cc(C(C)(C)C)cc2-c2ccccc2)c2cc4c5c(c23)Oc2ccc(-c3ccccc3)cc2B5c2cc(-c3ccccc3)ccc2S4)c(-c2ccccc2)c1]

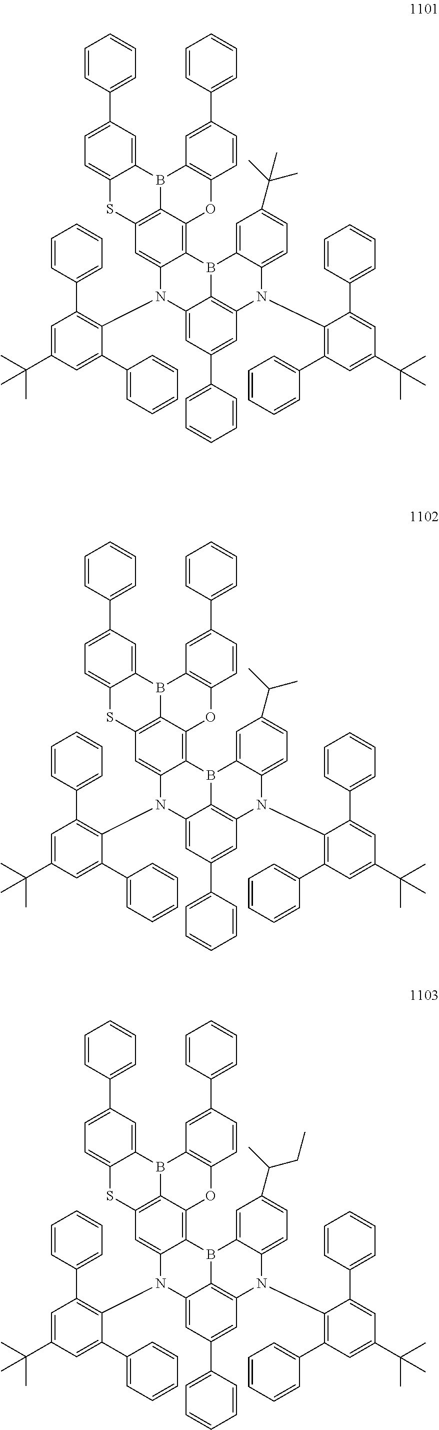

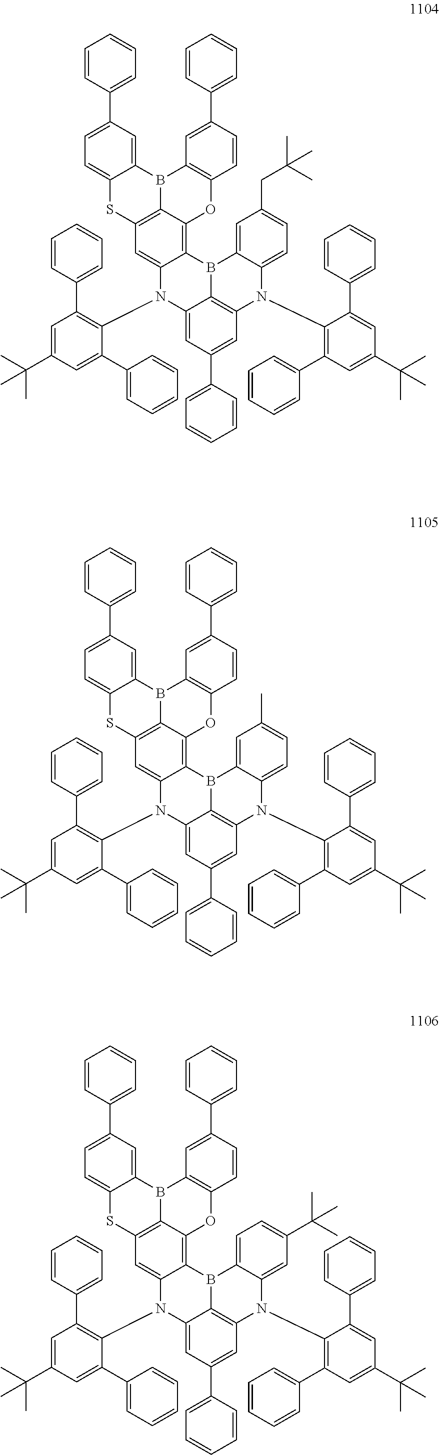

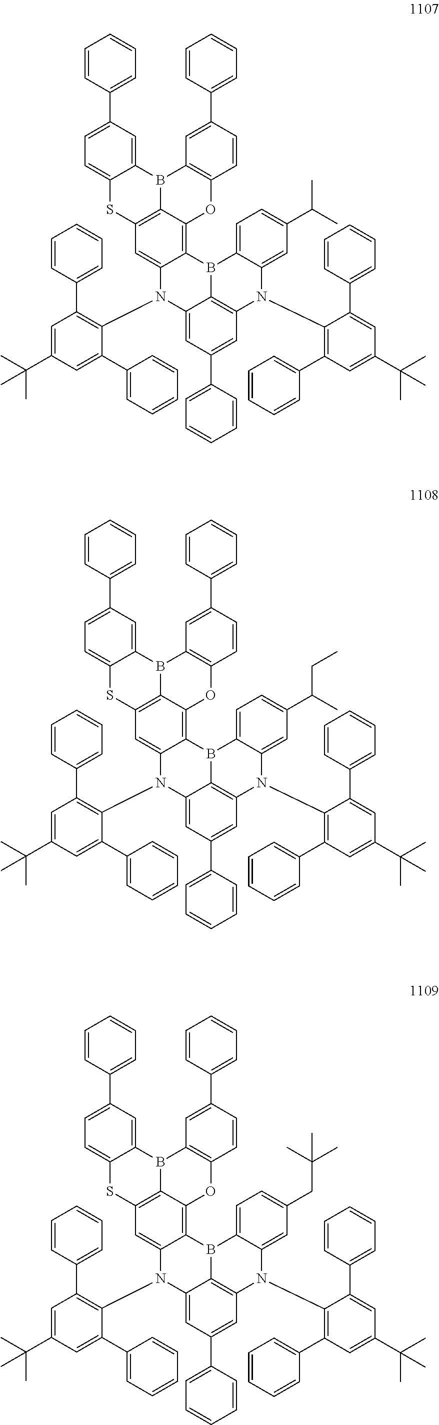

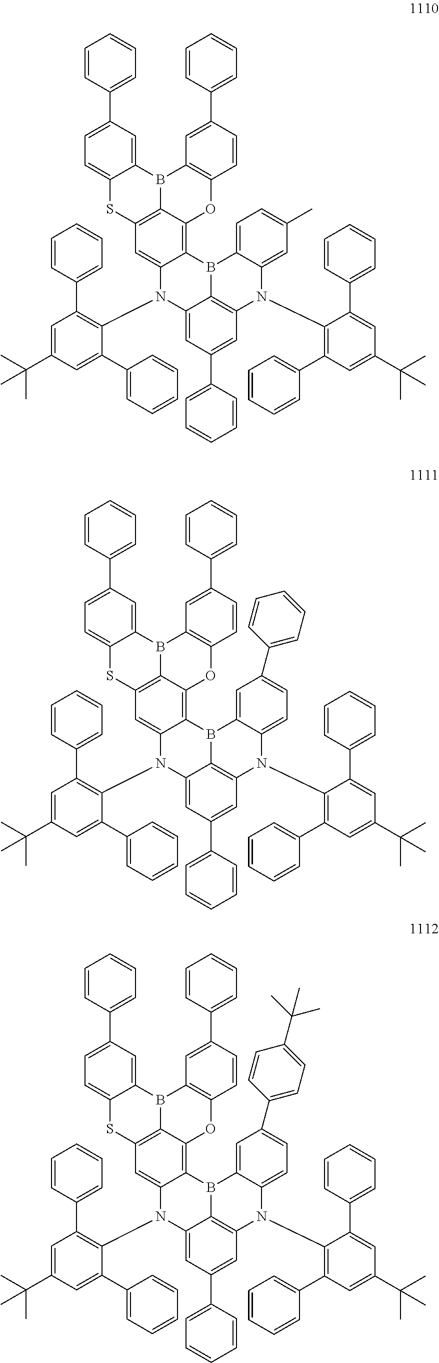

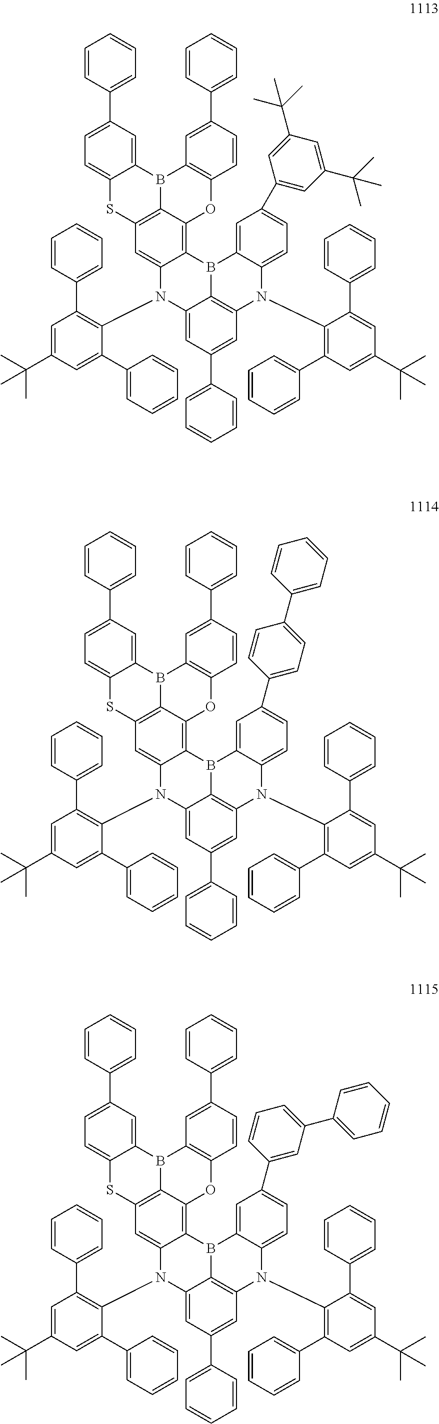

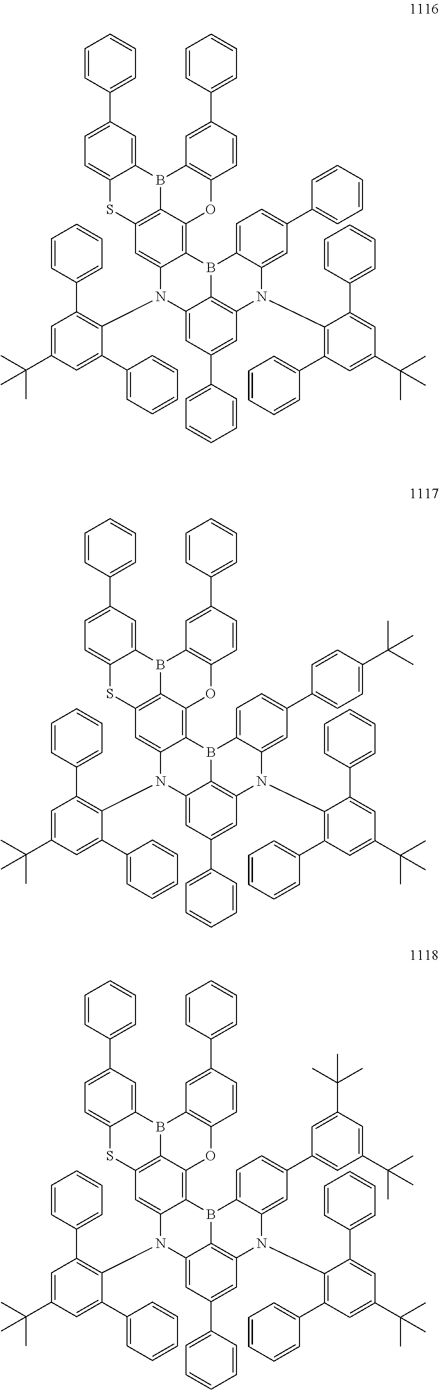

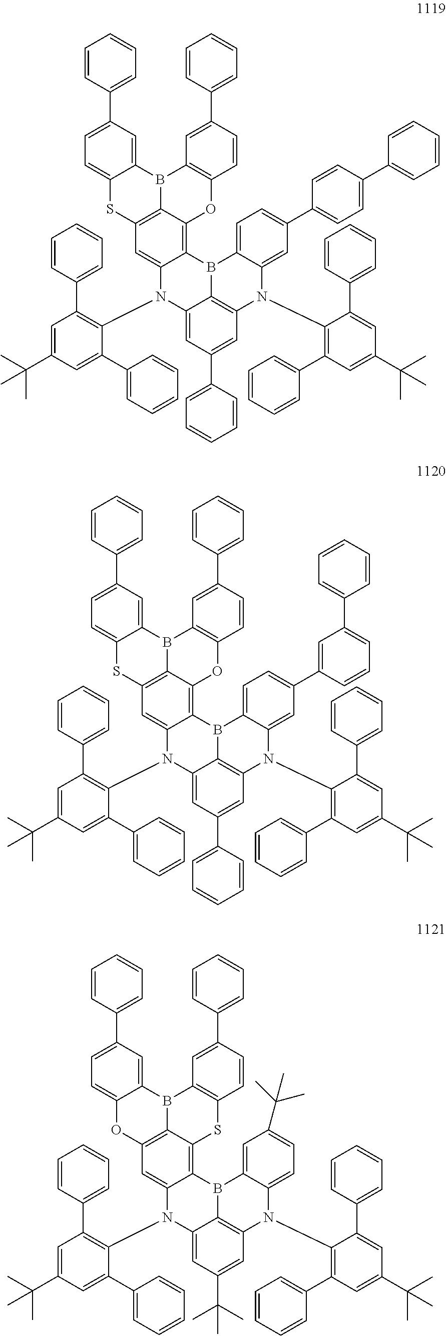

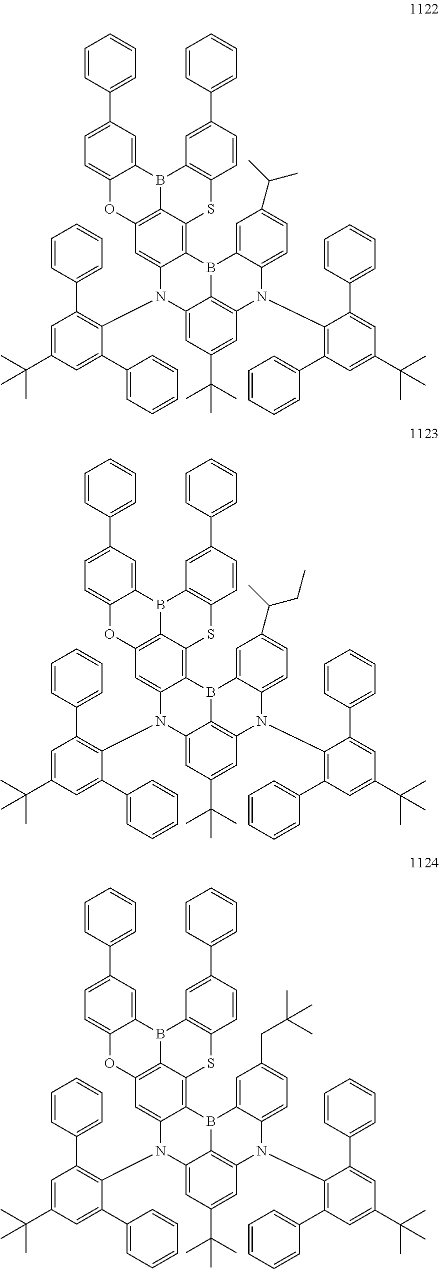

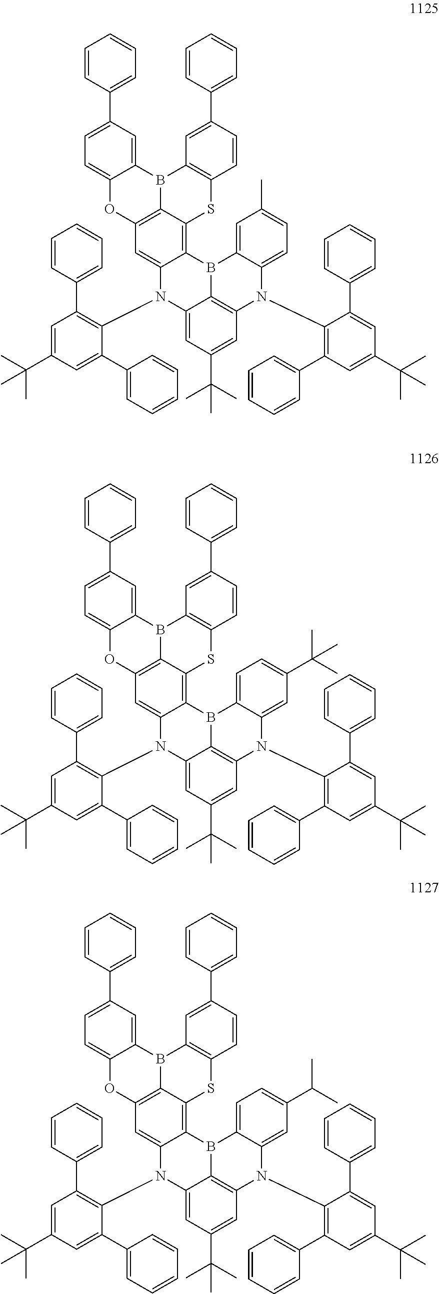

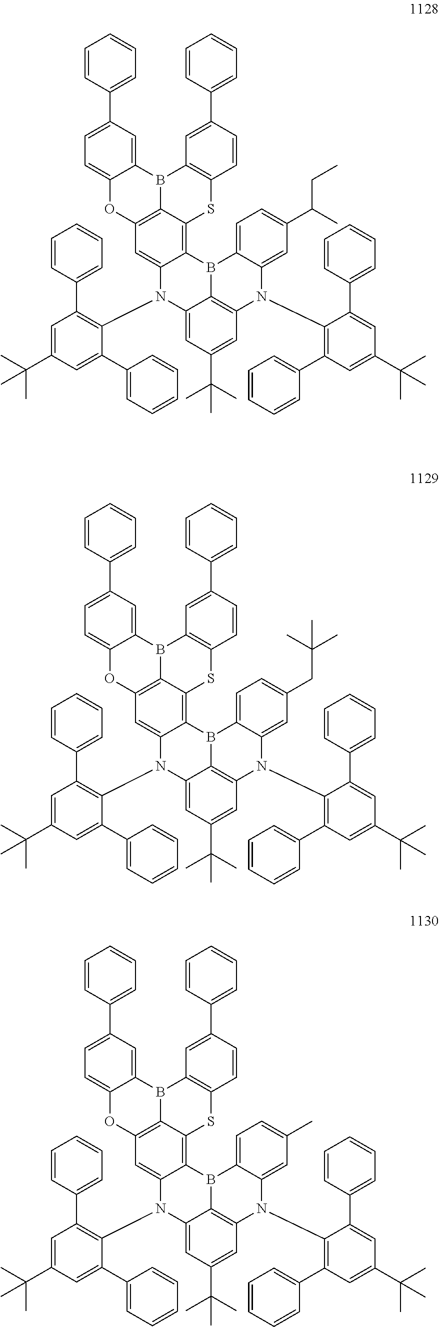

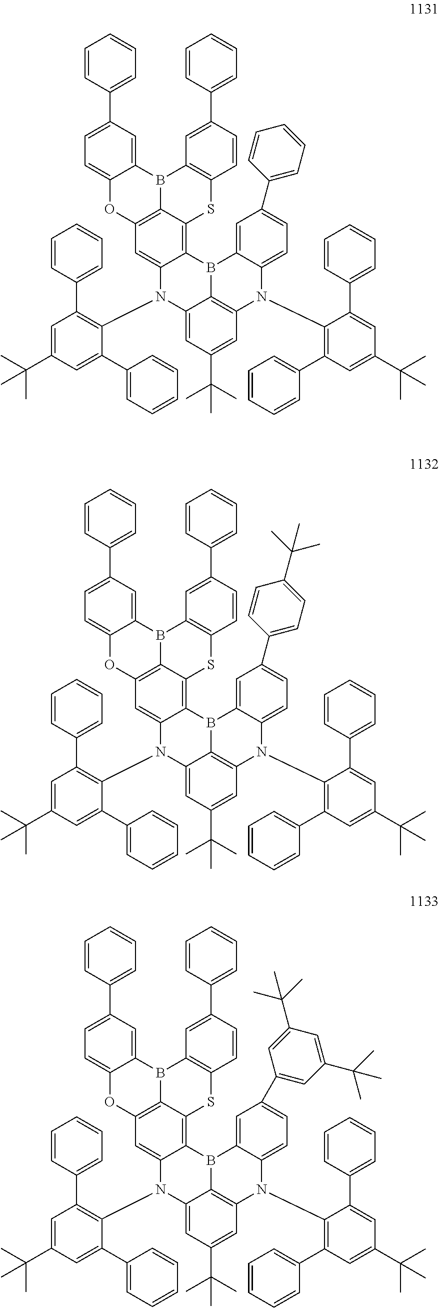

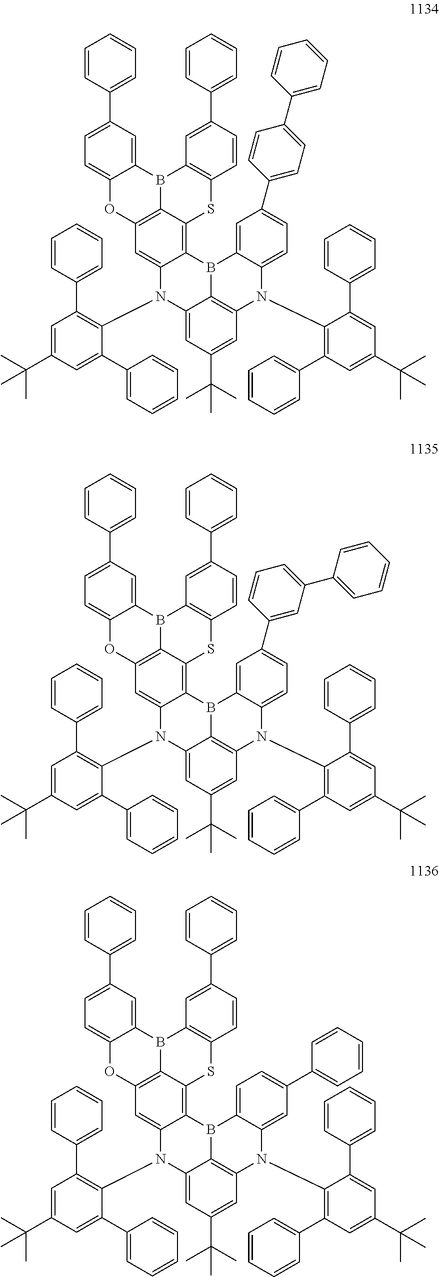

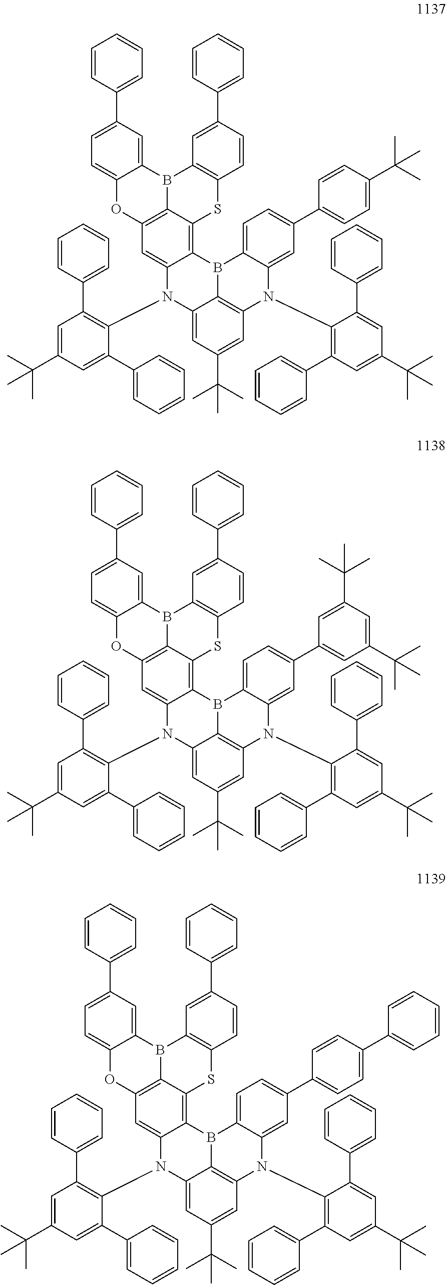

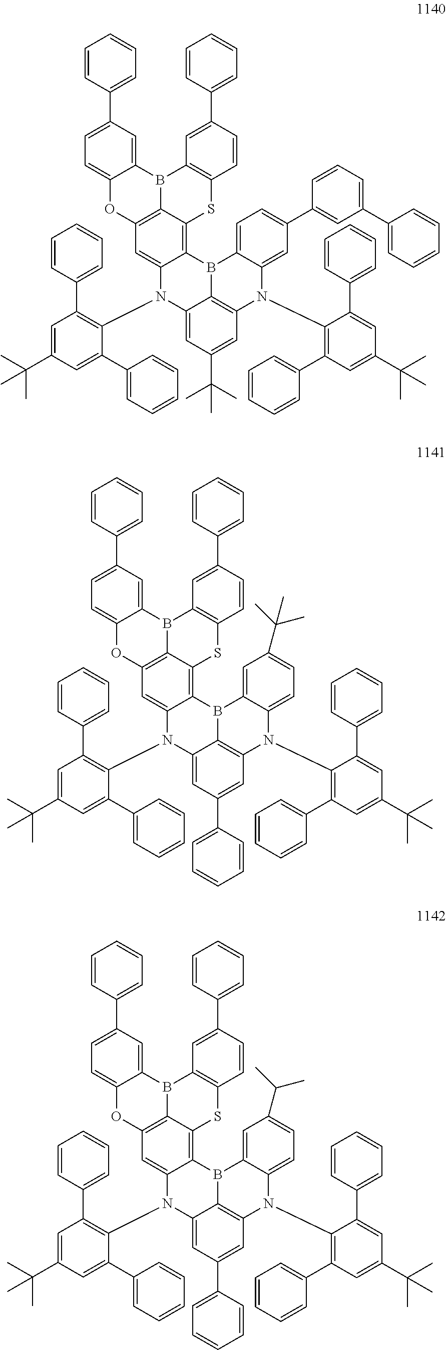

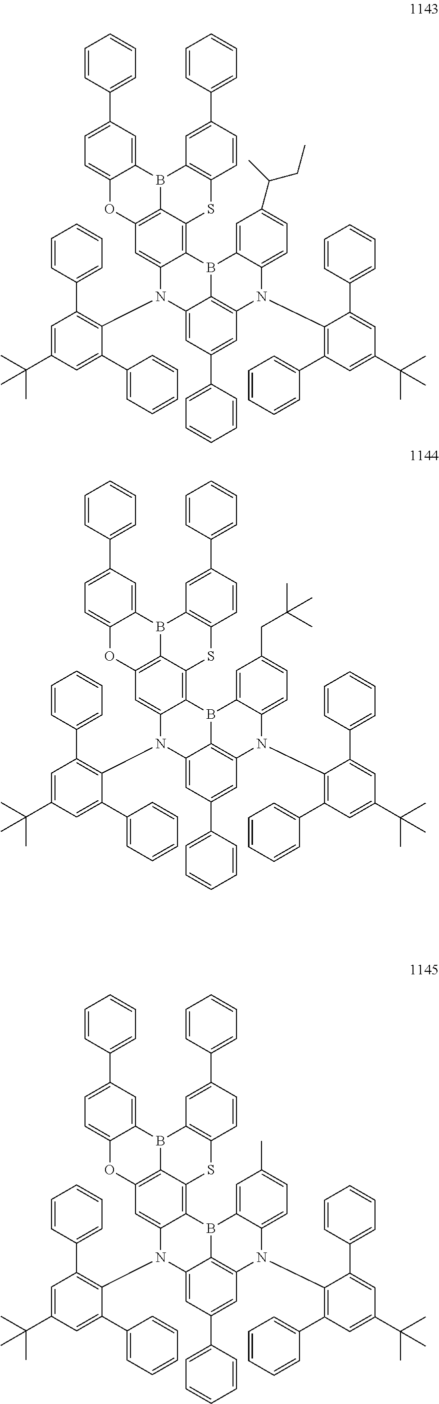

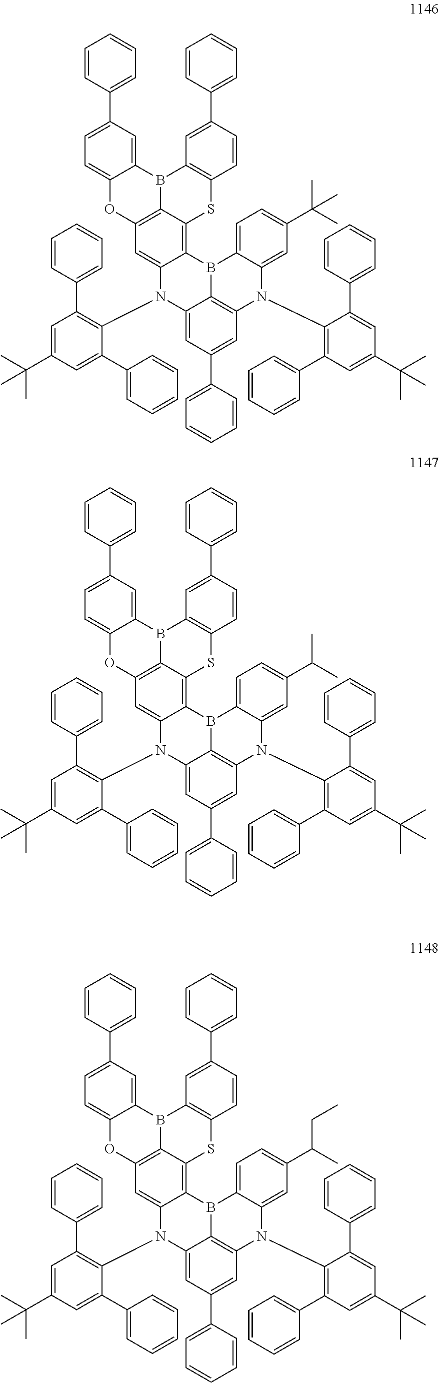

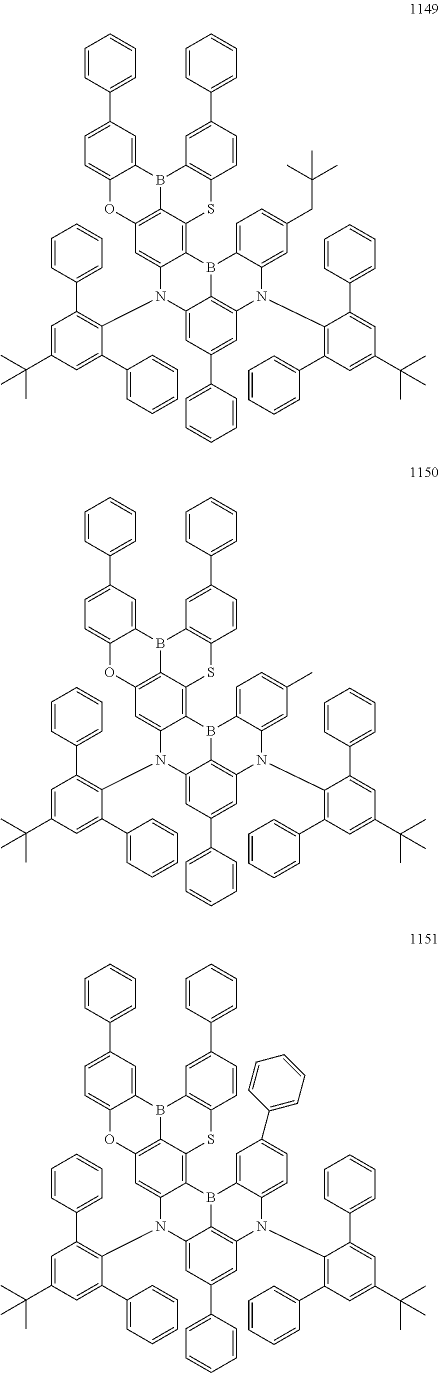

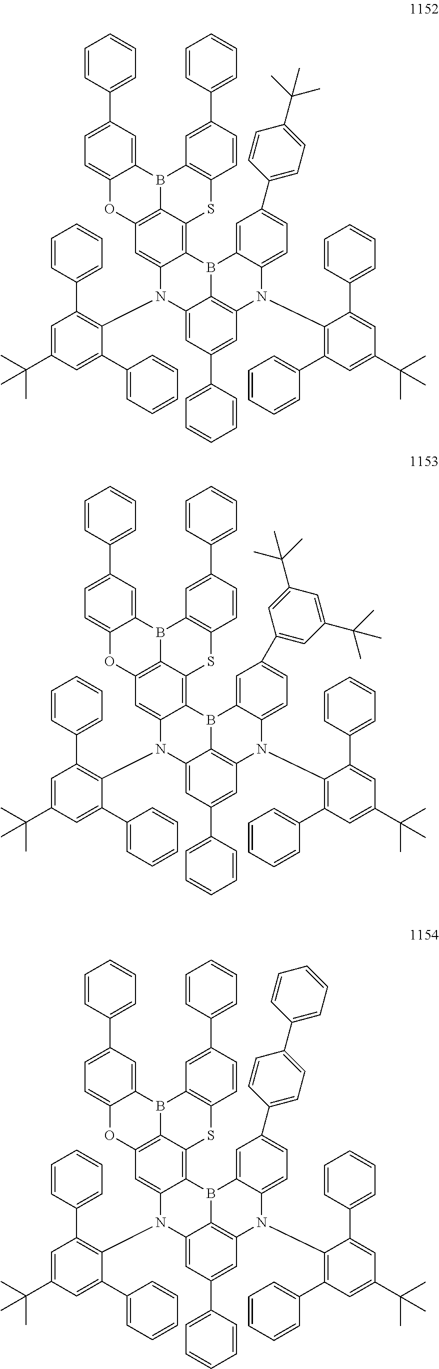

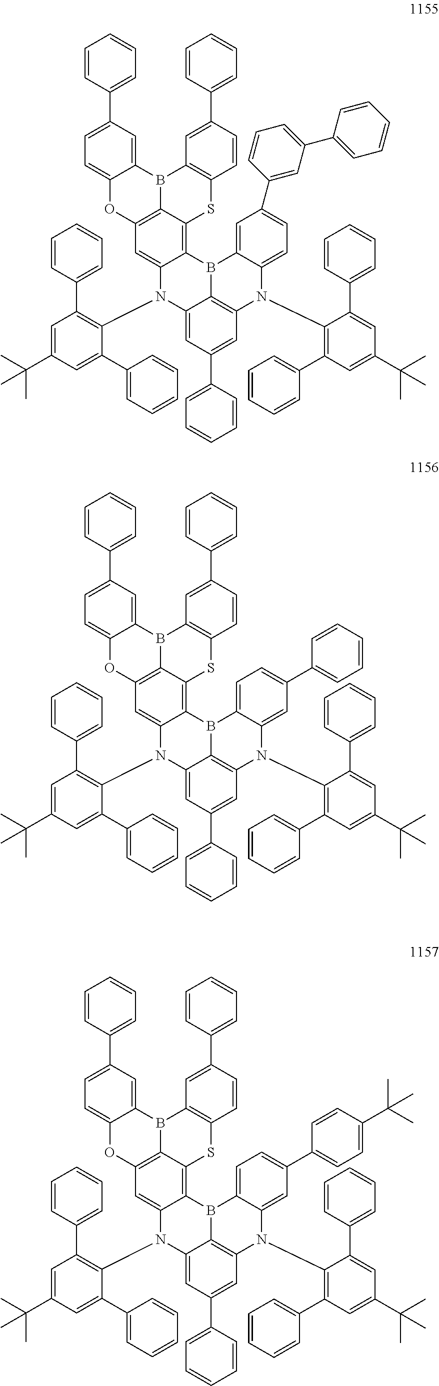

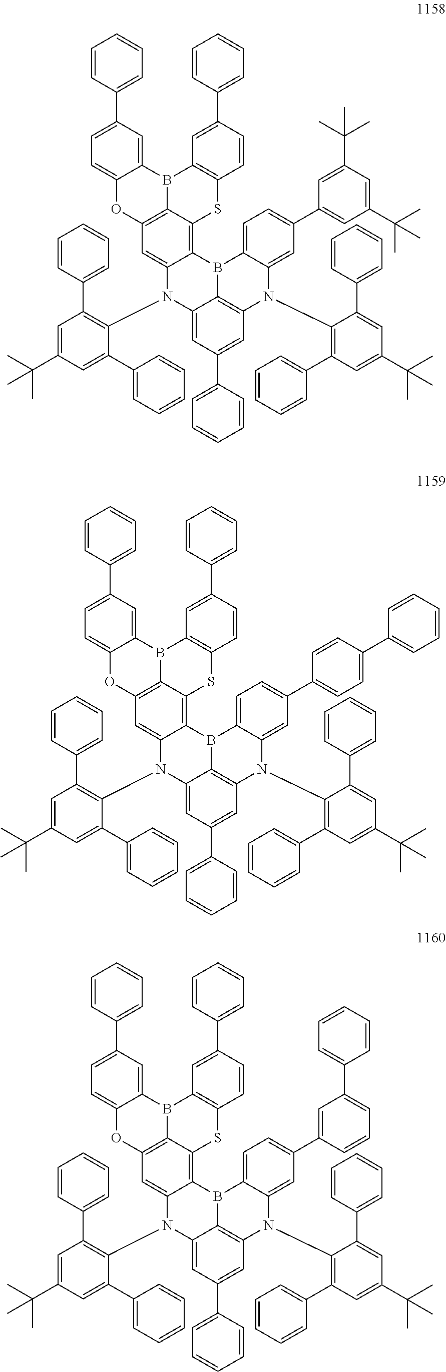

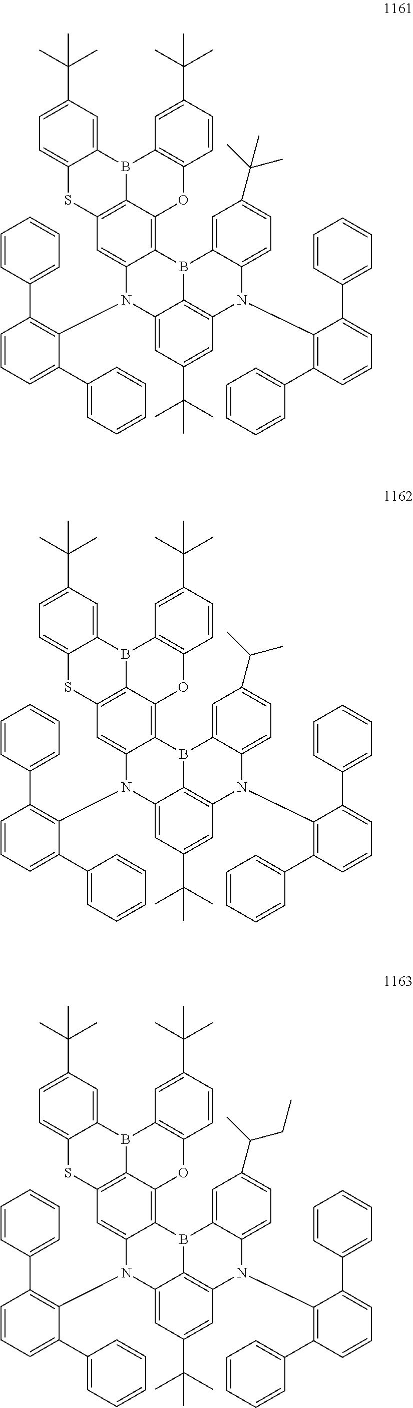 [SMILES: CC(C)(C)c1ccc2c(c1)B1c3cc(C(C)(C)C)ccc3Sc3cc4c(c(c31)O2)B1c2cc(C(C)(C)C)ccc2N(c2c(-c3ccccc3)cccc2-c2ccccc2)c2cc(C(C)(C)C)cc(c21)N4c1c(-c2ccccc2)cccc1-c1ccccc1 ; CC(C)c1ccc2c(c1)B1c3c(cc(C(C)(C)C)cc3N(c3c(-c4ccccc4)cccc3-c3ccccc3)c3cc4c5c(c31)Oc1ccc(C(C)(C)C)cc1B5c1cc(C(C)(C)C)ccc1S4)N2c1c(-c2ccccc2)cccc1-c1ccccc1 ; CCC(C)c1ccc2c(c1)B1c3c(cc(C(C)(C)C)cc3N(c3c(-c4ccccc4)cccc3-c3ccccc3)c3cc4c5c(c31)Oc1ccc(C(C)(C)C)cc1B5c1cc(C(C)(C)C)ccc1S4)N2c1c(-c2ccccc2)cccc1-c1ccccc1]

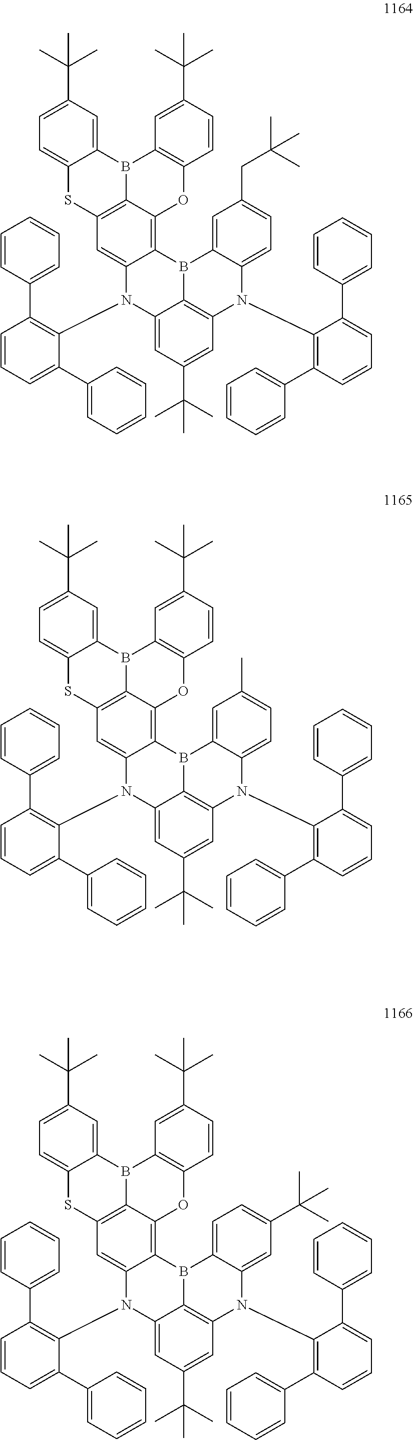 [SMILES: CC(C)(C)Cc1ccc2c(c1)B1c3c(cc(C(C)(C)C)cc3N(c3c(-c4ccccc4)cccc3-c3ccccc3)c3cc4c5c(c31)Oc1ccc(C(C)(C)C)cc1B5c1cc(C(C)(C)C)ccc1S4)N2c1c(-c2ccccc2)cccc1-c1ccccc1 ; Cc1ccc2c(c1)B1c3c(cc(C(C)(C)C)cc3N(c3c(-c4ccccc4)cccc3-c3ccccc3)c3cc4c5c(c31)Oc1ccc(C(C)(C)C)cc1B5c1cc(C(C)(C)C)ccc1S4)N2c1c(-c2ccccc2)cccc1-c1ccccc1 ; CC(C)(C)c1ccc2c(c1)B1c3cc(C(C)(C)C)ccc3Sc3cc4c(c(c31)O2)B1c2ccc(C(C)(C)C)cc2N(c2c(-c3ccccc3)cccc2-c2ccccc2)c2cc(C(C)(C)C)cc(c21)N4c1c(-c2ccccc2)cccc1-c1ccccc1]

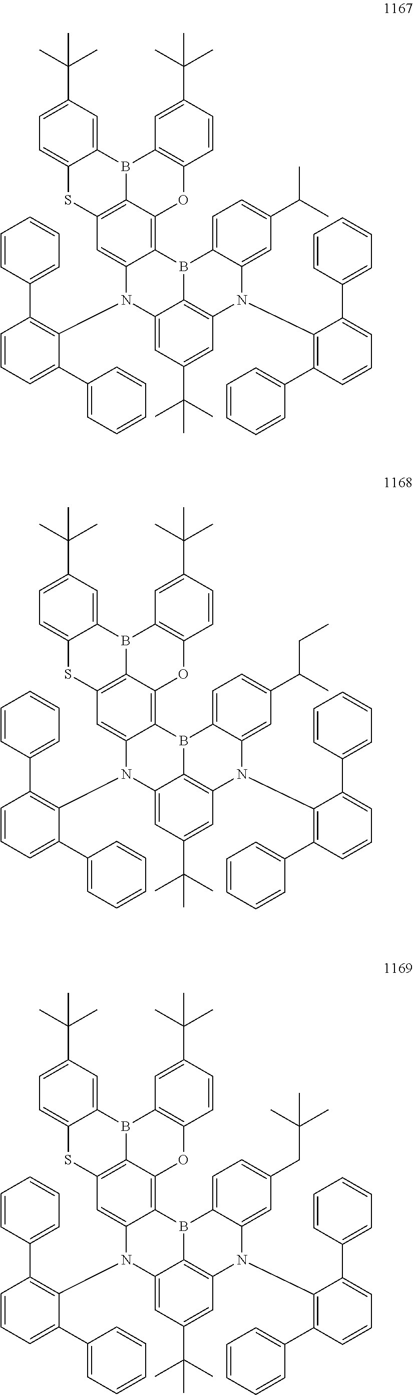 [SMILES: CC(C)c1ccc2c(c1)N(c1c(-c3ccccc3)cccc1-c1ccccc1)c1cc(C(C)(C)C)cc3c1B2c1c(cc2c4c1Oc1ccc(C(C)(C)C)cc1B4c1cc(C(C)(C)C)ccc1S2)N3c1c(-c2ccccc2)cccc1-c1ccccc1 ; CCC(C)c1ccc2c(c1)N(c1c(-c3ccccc3)cccc1-c1ccccc1)c1cc(C(C)(C)C)cc3c1B2c1c(cc2c4c1Oc1ccc(C(C)(C)C)cc1B4c1cc(C(C)(C)C)ccc1S2)N3c1c(-c2ccccc2)cccc1-c1ccccc1 ; CC(C)(C)Cc1ccc2c(c1)N(c1c(-c3ccccc3)cccc1-c1ccccc1)c1cc(C(C)(C)C)cc3c1B2c1c(cc2c4c1Oc1ccc(C(C)(C)C)cc1B4c1cc(C(C)(C)C)ccc1S2)N3c1c(-c2ccccc2)cccc1-c1ccccc1]

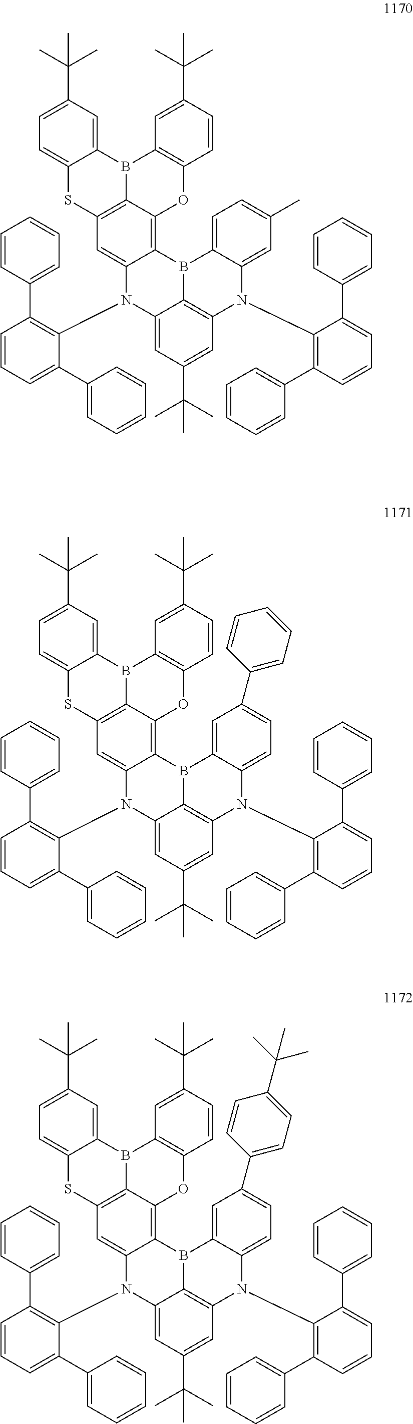 [SMILES: Cc1ccc2c(c1)N(c1c(-c3ccccc3)cccc1-c1ccccc1)c1cc(C(C)(C)C)cc3c1B2c1c(cc2c4c1Oc1ccc(C(C)(C)C)cc1B4c1cc(C(C)(C)C)ccc1S2)N3c1c(-c2ccccc2)cccc1-c1ccccc1 ; CC(C)(C)c1ccc2c(c1)B1c3cc(C(C)(C)C)ccc3Sc3cc4c(c(c31)O2)B1c2cc(-c3ccccc3)ccc2N(c2c(-c3ccccc3)cccc2-c2ccccc2)c2cc(C(C)(C)C)cc(c21)N4c1c(-c2ccccc2)cccc1-c1ccccc1 ; CC(C)(C)c1ccc(-c2ccc3c(c2)B2c4c(cc(C(C)(C)C)cc4N(c4c(-c5ccccc5)cccc4-c4ccccc4)c4cc5c6c(c42)Oc2ccc(C(C)(C)C)cc2B6c2cc(C(C)(C)C)ccc2S5)N3c2c(-c3ccccc3)cccc2-c2ccccc2)cc1]

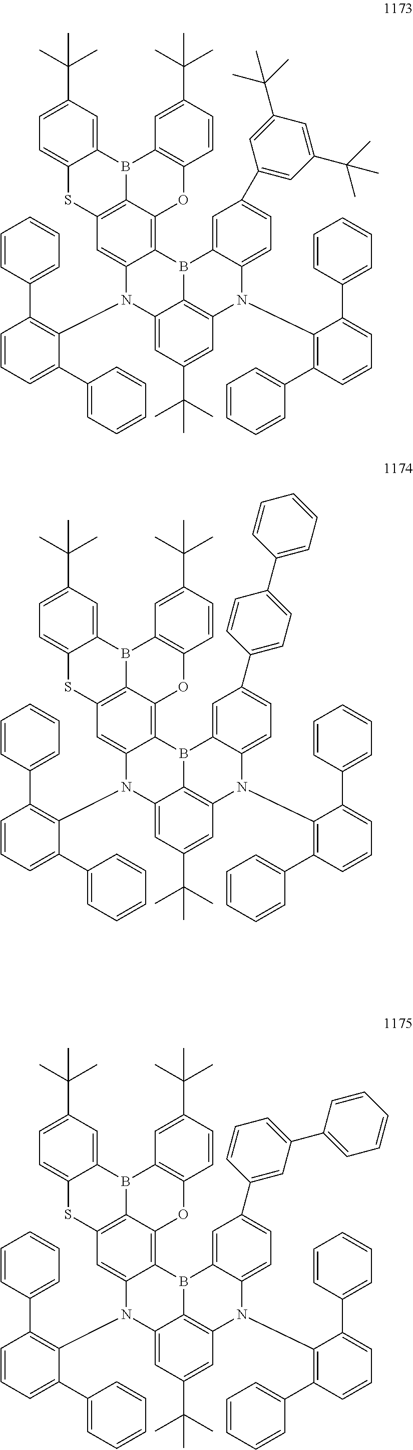

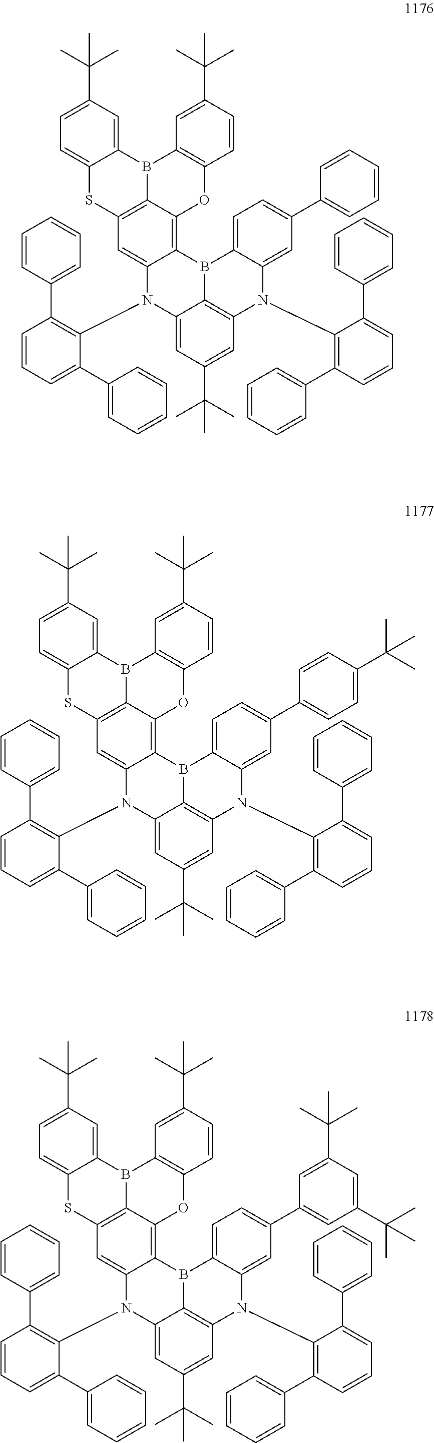

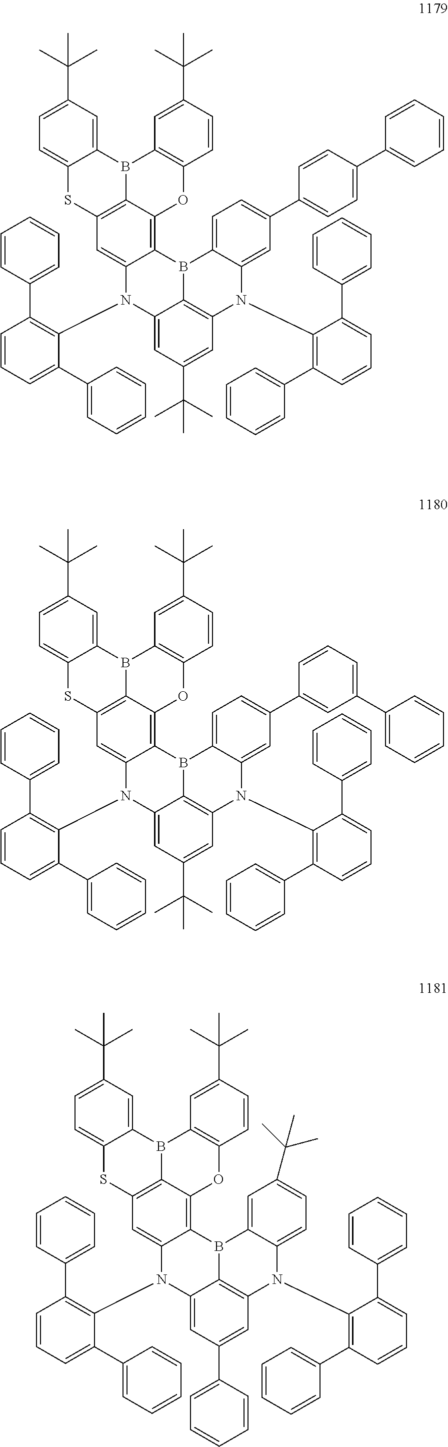

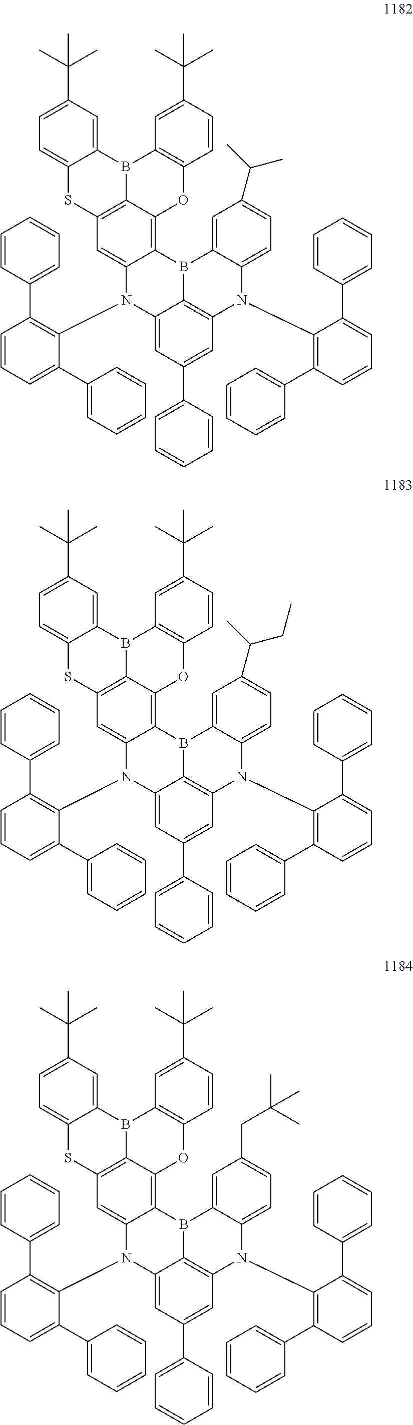

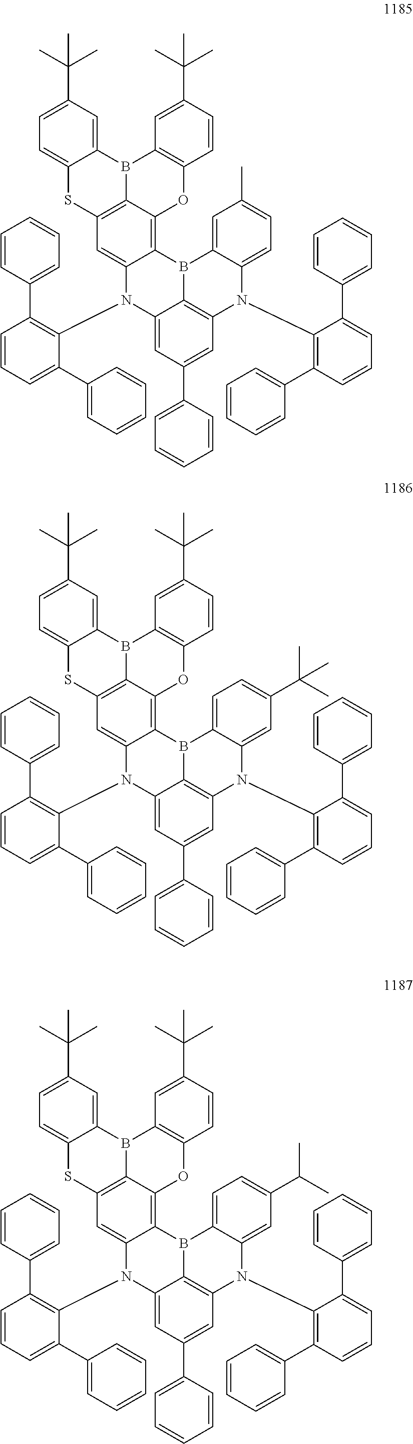

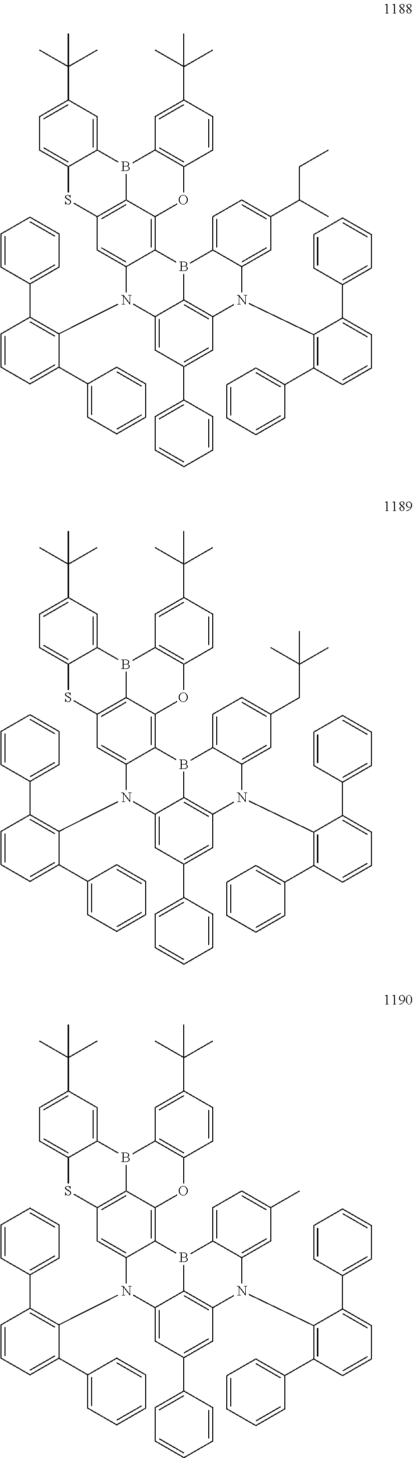 [SMILES: CCC(C)c1ccc2c(c1)N(c1c(-c3ccccc3)cccc1-c1ccccc1)c1cc(-c3ccccc3)cc3c1B2c1c(cc2c4c1Oc1ccc(C(C)(C)C)cc1B4c1cc(C(C)(C)C)ccc1S2)N3c1c(-c2ccccc2)cccc1-c1ccccc1 ; CC(C)(C)Cc1ccc2c(c1)N(c1c(-c3ccccc3)cccc1-c1ccccc1)c1cc(-c3ccccc3)cc3c1B2c1c(cc2c4c1Oc1ccc(C(C)(C)C)cc1B4c1cc(C(C)(C)C)ccc1S2)N3c1c(-c2ccccc2)cccc1-c1ccccc1 ; Cc1ccc2c(c1)N(c1c(-c3ccccc3)cccc1-c1ccccc1)c1cc(-c3ccccc3)cc3c1B2c1c(cc2c4c1Oc1ccc(C(C)(C)C)cc1B4c1cc(C(C)(C)C)ccc1S2)N3c1c(-c2ccccc2)cccc1-c1ccccc1]

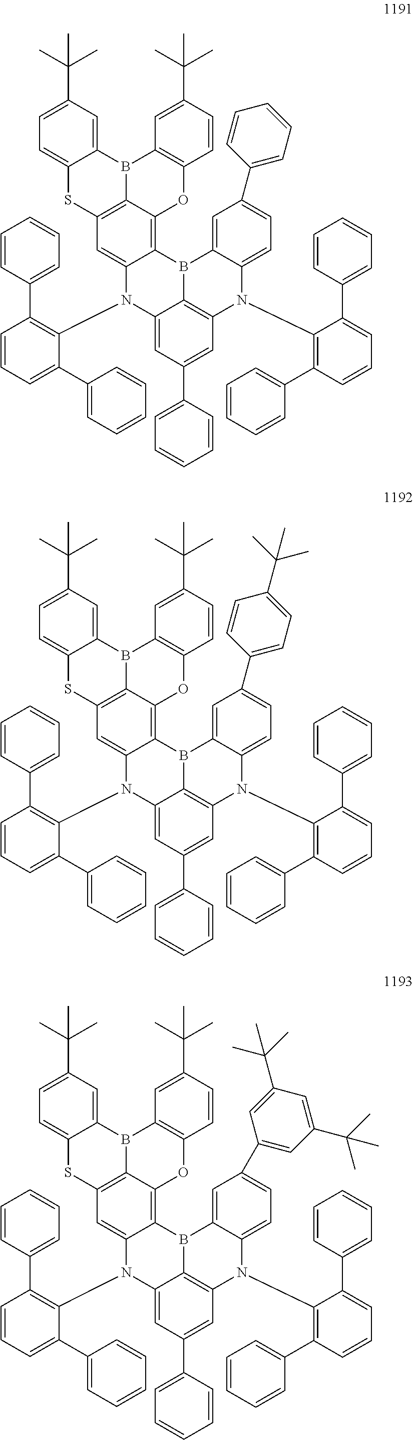

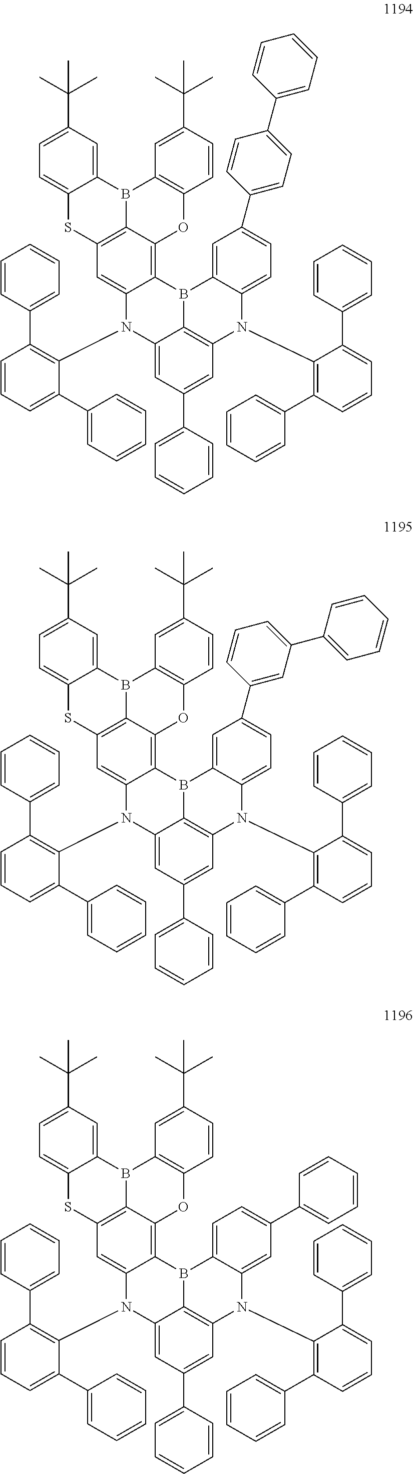

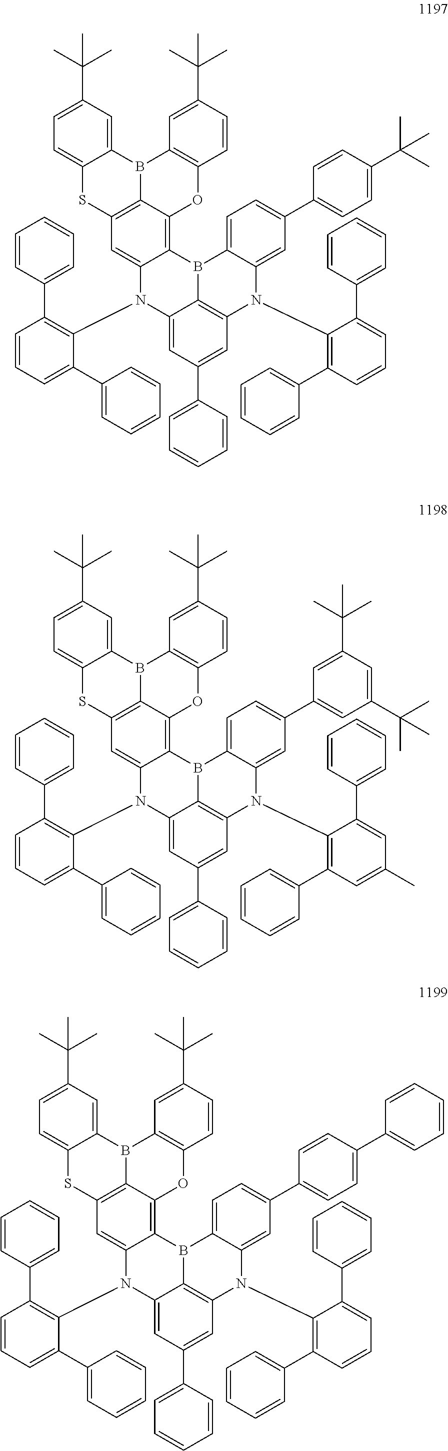

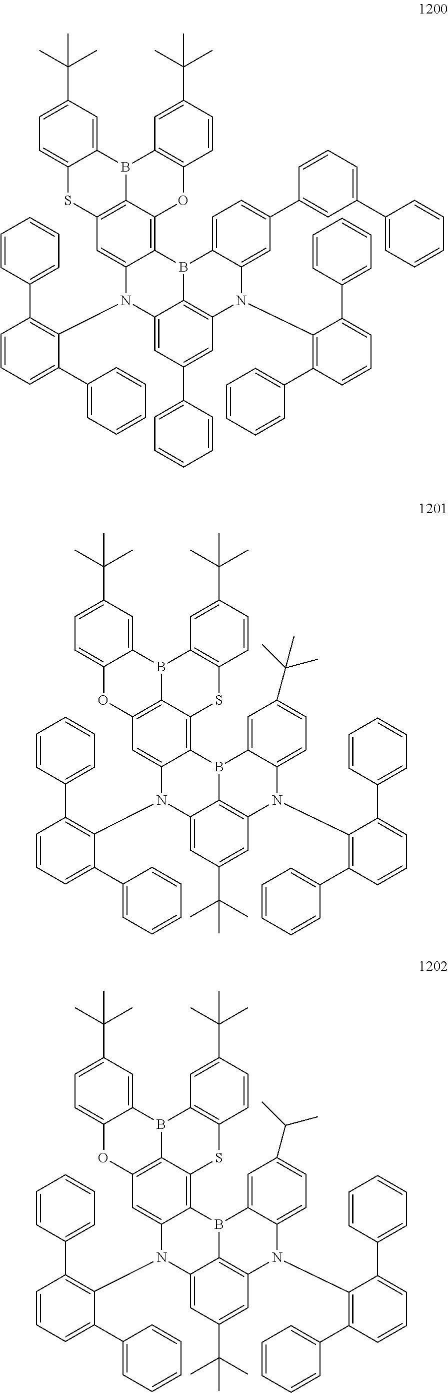 [SMILES: CC(C)(C)c1ccc2c(c1)B1c3cc(C(C)(C)C)ccc3Sc3cc4c(c(c31)O2)B1c2ccc(-c3cccc(-c5ccccc5)c3)cc2N(c2c(-c3ccccc3)cccc2-c2ccccc2)c2cc(-c3ccccc3)cc(c21)N4c1c(-c2ccccc2)cccc1-c1ccccc1 ; CC(C)(C)c1ccc2c(c1)B1c3cc(C(C)(C)C)ccc3Sc3c1c(cc1c3B3c4cc(C(C)(C)C)ccc4N(c4c(-c5ccccc5)cccc4-c4ccccc4)c4cc(C(C)(C)C)cc(c43)N1c1c(-c3ccccc3)cccc1-c1ccccc1)O2 ; CC(C)c1ccc2c(c1)B1c3c(cc(C(C)(C)C)cc3N(c3c(-c4ccccc4)cccc3-c3ccccc3)c3cc4c5c(c31)Sc1ccc(C(C)(C)C)cc1B5c1cc(C(C)(C)C)ccc1O4)N2c1c(-c2ccccc2)cccc1-c1ccccc1]

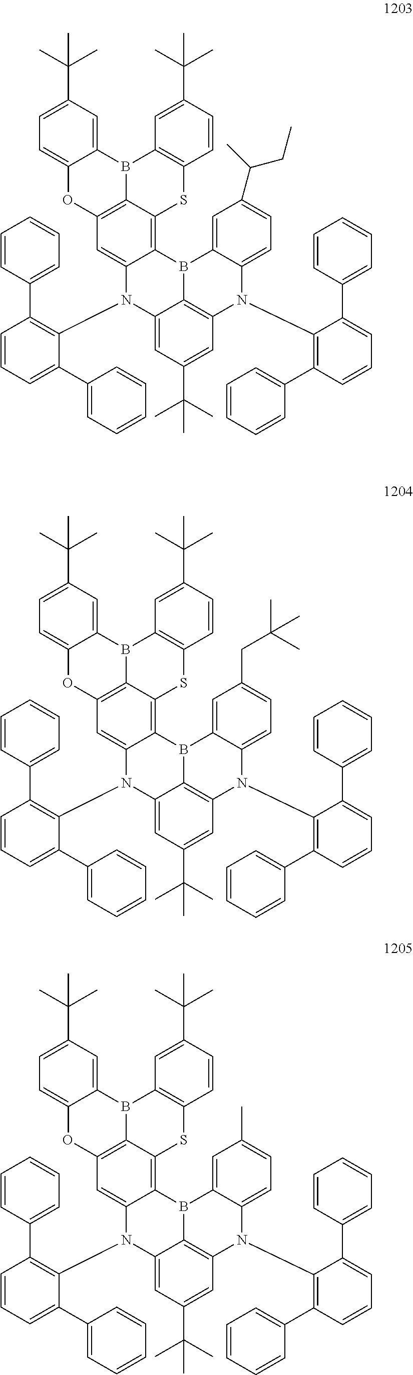 [SMILES: CCC(C)c1ccc2c(c1)B1c3c(cc(C(C)(C)C)cc3N(c3c(-c4ccccc4)cccc3-c3ccccc3)c3cc4c5c(c31)Sc1ccc(C(C)(C)C)cc1B5c1cc(C(C)(C)C)ccc1O4)N2c1c(-c2ccccc2)cccc1-c1ccccc1 ; CC(C)(C)Cc1ccc2c(c1)B1c3c(cc(C(C)(C)C)cc3N(c3c(-c4ccccc4)cccc3-c3ccccc3)c3cc4c5c(c31)Sc1ccc(C(C)(C)C)cc1B5c1cc(C(C)(C)C)ccc1O4)N2c1c(-c2ccccc2)cccc1-c1ccccc1 ; Cc1ccc2c(c1)B1c3c(cc(C(C)(C)C)cc3N(c3c(-c4ccccc4)cccc3-c3ccccc3)c3cc4c5c(c31)Sc1ccc(C(C)(C)C)cc1B5c1cc(C(C)(C)C)ccc1O4)N2c1c(-c2ccccc2)cccc1-c1ccccc1]

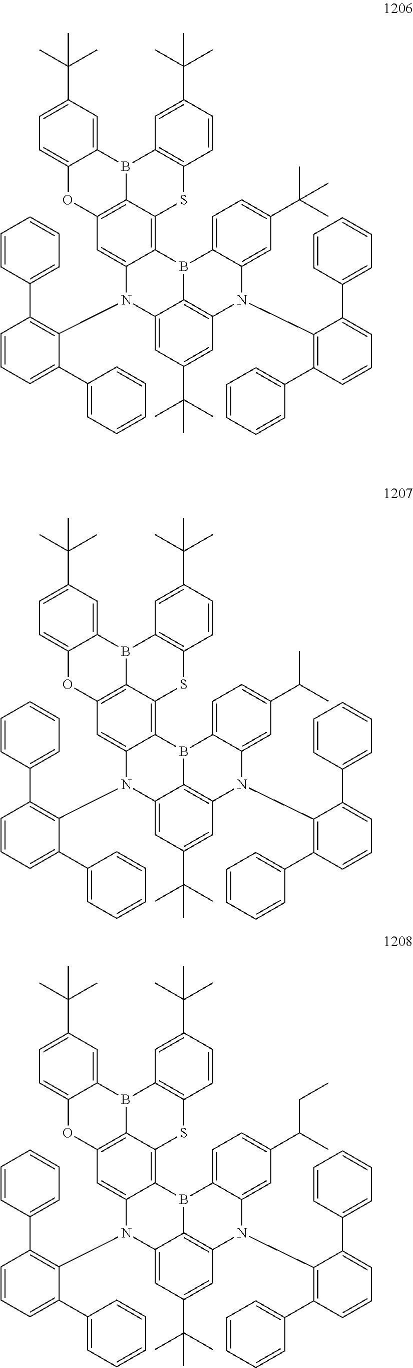 [SMILES: CC(C)(C)c1ccc2c(c1)B1c3cc(C(C)(C)C)ccc3Sc3c1c(cc1c3B3c4ccc(C(C)(C)C)cc4N(c4c(-c5ccccc5)cccc4-c4ccccc4)c4cc(C(C)(C)C)cc(c43)N1c1c(-c3ccccc3)cccc1-c1ccccc1)O2 ; CC(C)c1ccc2c(c1)N(c1c(-c3ccccc3)cccc1-c1ccccc1)c1cc(C(C)(C)C)cc3c1B2c1c(cc2c4c1Sc1ccc(C(C)(C)C)cc1B4c1cc(C(C)(C)C)ccc1O2)N3c1c(-c2ccccc2)cccc1-c1ccccc1 ; CCC(C)c1ccc2c(c1)N(c1c(-c3ccccc3)cccc1-c1ccccc1)c1cc(C(C)(C)C)cc3c1B2c1c(cc2c4c1Sc1ccc(C(C)(C)C)cc1B4c1cc(C(C)(C)C)ccc1O2)N3c1c(-c2ccccc2)cccc1-c1ccccc1]

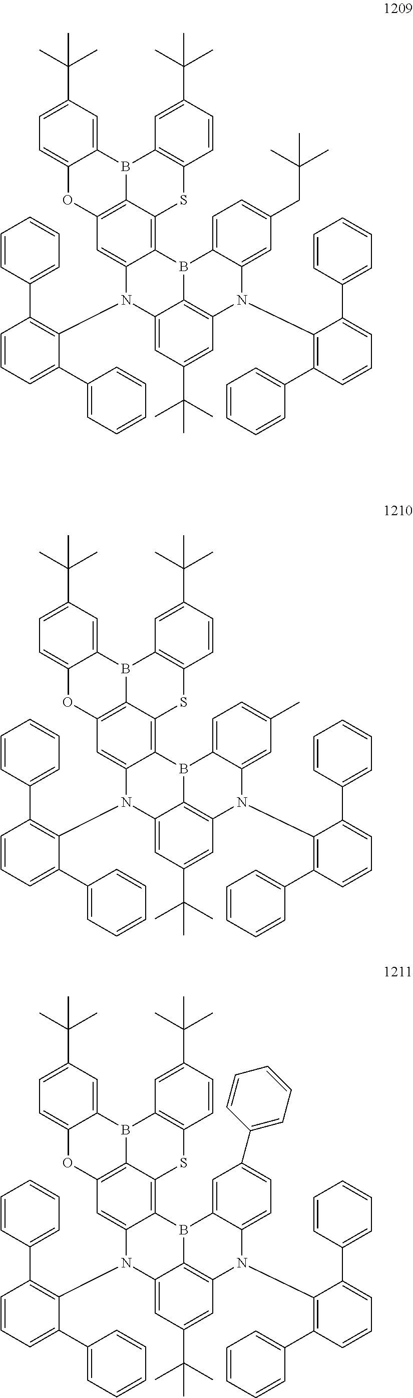 [SMILES: CC(C)(C)Cc1ccc2c(c1)N(c1c(-c3ccccc3)cccc1-c1ccccc1)c1cc(C(C)(C)C)cc3c1B2c1c(cc2c4c1Sc1ccc(C(C)(C)C)cc1B4c1cc(C(C)(C)C)ccc1O2)N3c1c(-c2ccccc2)cccc1-c1ccccc1 ; Cc1ccc2c(c1)N(c1c(-c3ccccc3)cccc1-c1ccccc1)c1cc(C(C)(C)C)cc3c1B2c1c(cc2c4c1Sc1ccc(C(C)(C)C)cc1B4c1cc(C(C)(C)C)ccc1O2)N3c1c(-c2ccccc2)cccc1-c1ccccc1 ; CC(C)(C)c1ccc2c(c1)B1c3cc(C(C)(C)C)ccc3Sc3c1c(cc1c3B3c4cc(-c5ccccc5)ccc4N(c4c(-c5ccccc5)cccc4-c4ccccc4)c4cc(C(C)(C)C)cc(c43)N1c1c(-c3ccccc3)cccc1-c1ccccc1)O2]

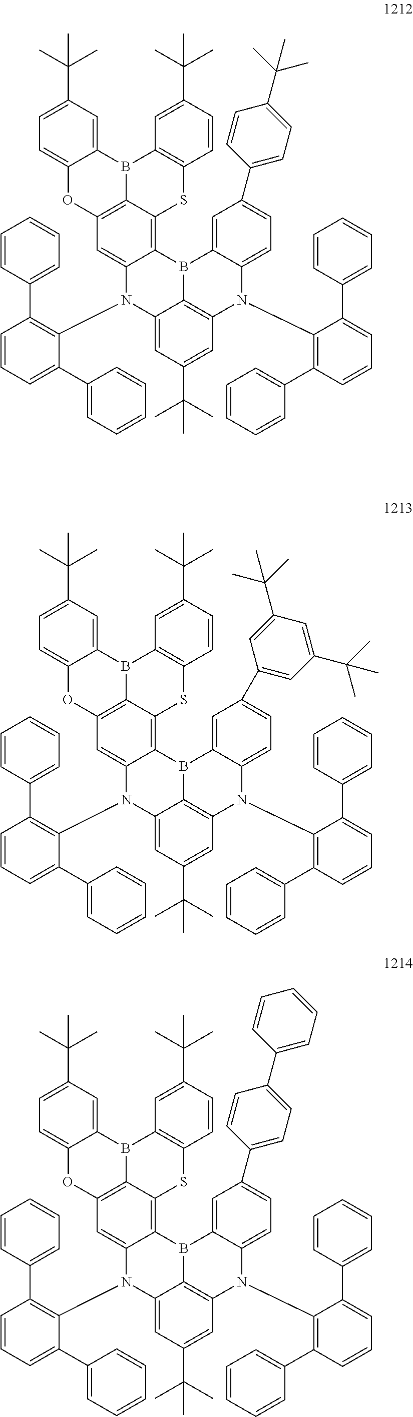

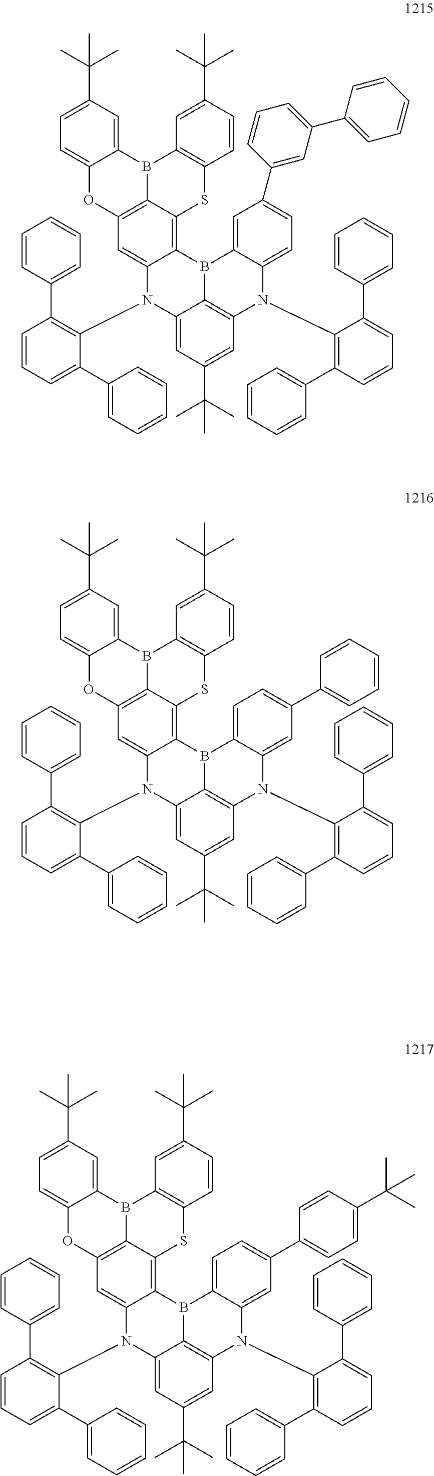 [SMILES: CC(C)(C)c1ccc2c(c1)B1c3cc(C(C)(C)C)ccc3Sc3c1c(cc1c3B3c4cc(-c5cccc(-c6ccccc6)c5)ccc4N(c4c(-c5ccccc5)cccc4-c4ccccc4)c4cc(C(C)(C)C)cc(c43)N1c1c(-c3ccccc3)cccc1-c1ccccc1)O2 ; CC(C)(C)c1ccc2c(c1)B1c3cc(C(C)(C)C)ccc3Sc3c1c(cc1c3B3c4ccc(-c5ccccc5)cc4N(c4c(-c5ccccc5)cccc4-c4ccccc4)c4cc(C(C)(C)C)cc(c43)N1c1c(-c3ccccc3)cccc1-c1ccccc1)O2 ; CC(C)(C)c1ccc(-c2ccc3c(c2)N(c2c(-c4ccccc4)cccc2-c2ccccc2)c2cc(C(C)(C)C)cc4c2B3c2c(cc3c5c2Sc2ccc(C(C)(C)C)cc2B5c2cc(C(C)(C)C)ccc2O3)N4c2c(-c3ccccc3)cccc2-c2ccccc2)cc1]

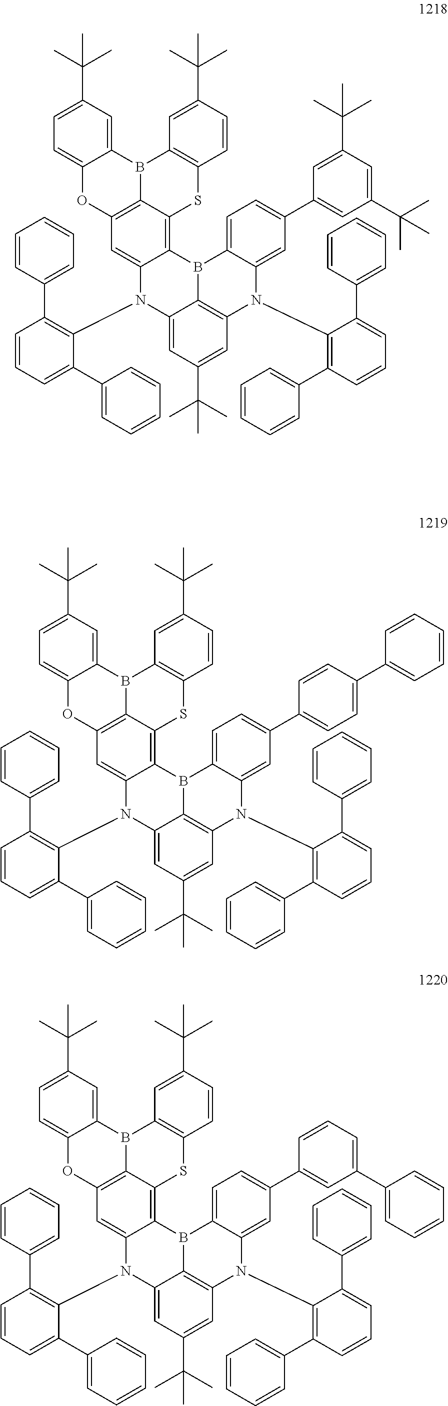

What is claimed is:

1. A heterocyclic compound represented by Formula 1: 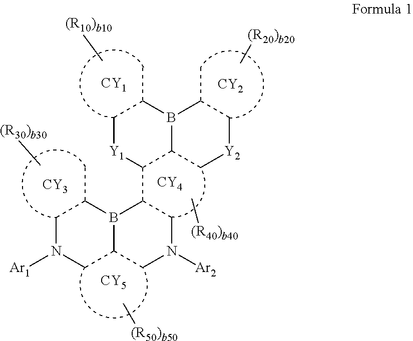
wherein, in Formula 1,
Y₁ is a single bond, O, S, Se, N(R₁), C(R₁)(R₂), Si(R₁)(R₂), Ge(R₁)(R₂), B(R₁), P(R₁), P(═O)(R₁), S(═O)₂, or C(═O),
Y₂ is a single bond, O, S, Se, N(R₃), C(R₃)(R₄), Si(R₃)(R₄), Ge(R₃)(R₄), B(R₃), P(R₃), P(═O)(R₃), S(═O)₂, or C(═O),
ring CY₁ to ring CY₅ are each independently a C₅-C₃₀ carbocyclic group or a C₁-C₃₀ heterocyclic group, and
Ar₁ and Ar₂ are each independently a group represented by Formula 2: 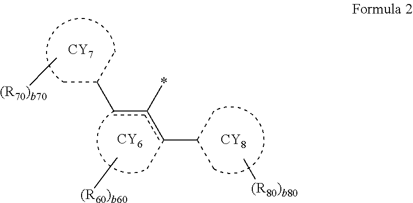
wherein, in Formula 2,
ring CY₆ to ring CY₈ are each independently a C₅-C₃₀ carbocyclic group or a C₁-C₃₀ heterocyclic group, [symbol] indicates a single bond or a double bond,
* indicates a binding site to a neighboring atom,
wherein, in Formulae 1 and 2,
R₁ to R₄, R₁₀, R₂₀, R₃₀, R₄₀, R₅₀, R₆₀, R₇₀, and R₈₀ are each independently hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, a substituted or unsubstituted monovalent non-aromatic condensed heteropolycyclic group, —N(Q₁)(Q₂), —Si(Q₁)(Q₂)(Q₃), —Ge(Q₁)(Q₂)(Q₃), —C(═O)(Q₁), —S(═O)(Q₁), —S(═O)₂(Q₁), —B(Q₁)(Q₂), —P(Q₁)(Q₂), —P(═O)(Q₁)(Q₂), or —P(═S)(Q₁)(Q₂),
b10, b20, b30, b40, b50, b60, b70, and b80 are each independently 1, 2, 3, 4, 5, 6, 7, 8, 9, 10, 11, 12, 13, or 14,
at least two of a plurality of R₁₀ are optionally bonded together to form a substituted or unsubstituted C₅-C₃₀ carbocyclic group or a substituted or unsubstituted C₁-C₃₀ heterocyclic group,
at least two of a plurality of R₂₀ are optionally bonded together to form a substituted or unsubstituted C₅-C₃₀ carbocyclic group or a substituted or unsubstituted C₁-C₃₀ heterocyclic group,
at least two of a plurality of R₃₀ are optionally bonded together to form a substituted or unsubstituted C₅-C₃₀ carbocyclic group or a substituted or unsubstituted C₁-C₃₀ heterocyclic group,
at least two of a plurality of R₄₀ are optionally bonded together to form a substituted or unsubstituted C₅-C₃₀ carbocyclic group or a substituted or unsubstituted C₁-C₃₀ heterocyclic group,
at least two of a plurality of R₅₀ are optionally bonded together to form a substituted or unsubstituted C₅-C₃₀ carbocyclic group or a substituted or unsubstituted C₁-C₃₀ heterocyclic group,
at least two of a plurality of R₆₀ are optionally bonded together to form a substituted or unsubstituted C₅-C₃₀ carbocyclic group or a substituted or unsubstituted C₁-C₃₀ heterocyclic group,
at least two of a plurality of R₇₀ are optionally bonded together to form a substituted or unsubstituted C₅-C₃₀ carbocyclic group or a substituted or unsubstituted C₁-C₃₀ heterocyclic group,
at least two of a plurality of R₈₀ are optionally be bonded together to form a substituted or unsubstituted C₅-C₃₀ carbocyclic group or a substituted or unsubstituted C₁-C₃₀ heterocyclic group,
two or more of adjacent R₁ to R₄, R₁₀, R₂₀, R₃₀, R₄₀, R₅₀, R₆₀, R₇₀, and Rao are optionally bonded together to form a substituted or unsubstituted C₅-C₃₀ carbocyclic group or a substituted or unsubstituted C₁-C₃₀ heterocyclic group,
at least one substituent of the substituted C₅-C₃₀ carbocyclic group, the substituted C₁-C₃₀ heterocyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₁-C₆₀ alkylthio group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₇-C₆₀ alkyl aryl group, the substituted C₇-C₆₀ aryl alkyl group, the substituted C₆-C₆₀ aryloxy group, the substituted C₆-C₆₀ arylthio group, the substituted C₁-C₆₀ heteroaryl group, the substituted C₂-C₆₀ alkyl heteroaryl group, the substituted C₂-C₆₀ heteroaryl alkyl group, the substituted C₁-C₆₀ heteroaryloxy group, the substituted C₁-C₆₀ heteroarylthio group, the substituted monovalent non-aromatic condensed polycyclic group, the substituted monovalent non-aromatic condensed heteropolycyclic group, the substituted C₃-C₁₀ cycloalkylene group, the substituted C₁-C₁₀ heterocycloalkylene group, the substituted C₃-C₁₀ cycloalkenylene group, the substituted C₁-C₁₀ heterocycloalkenylene group, the substituted C₆-C₆₀ arylene group, the substituted C₁-C₆₀ heteroarylene group, the substituted divalent non-aromatic condensed polycyclic group, and the substituted divalent non-aromatic condensed heteropolycyclic group is:
deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, or a C₁-C₆₀ alkylthio group;
a C₁-C₆₀ alkyl group, a C₂-C₆₀ alkenyl group, a C₂-C₆₀ alkynyl group, a C₁-C₆₀ alkoxy group, or a C₁-C₆₀ alkylthio group, each substituted with deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, a monovalent non-aromatic heterocondensed polycyclic group, —N(Q₁₁)(Q₁₂), —Si(Q₁₁)(Q₁₂)(Q₁₃), —Ge(Q₁₁)(Q₁₂)(Q₁₃), —C(═O)(Q₁₁), —S(═O)(Q₁₁), —S(═O)₂(Q₁₁), —B(Q₁₁)(Q₁₂), —P(Q₁₁)(Q₁₂), —P(═O)(Q₁₁)(Q₁₂), —P(═S)(Q₁₁)(Q₁₂), or a combination thereof,
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, or a monovalent non-aromatic condensed heteropolycyclic group, each unsubstituted or substituted with deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₇-C₆₀ aryl alkyl group, a C₆-C₆₀ aryloxy group, a C₆-C₆₀ arylthio group, a C₁-C₆₀ heteroaryl group, a C₂-C₆₀ alkyl heteroaryl group, a C₂-C₆₀ heteroaryl alkyl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₂₁)(Q₂₂), —Si(Q₂₁)(Q₂₂)(Q₂₃), —Ge(Q₂₁)(Q₂₂)(Q₂₃), —C(═O)(Q₂₁), —S(═O)(Q₂₁), —S(═O)₂(Q₂₁), —B(Q₂₁)(Q₂₂), —P(Q₂₁)(Q₂₂), —P(═O)(Q₂₁)(Q₂₂), —P(═S)(Q₂₁)(Q₂₂), or a combination thereof;
—N(Q₃₁)(Q₃₂), —Si(Q₃₁)(Q₃₂)(Q₃₃), —Ge(Q₃₁)(Q₃₂)(Q₃₃), —C(═O)(Q₃₁), —S(═O)(Q₃₁), —S(═O)₂(Q₃₁), —B(Q₃₁)(Q₃₂), —P(Q₃₁)(Q₃₂), —P(═O)(Q₃₁)(Q₃₂), or —P(═S)(Q₃₁)(Q₃₂), or
a combination thereof,
Q₁ to Q₃, Q₁₁ to Q₁₃, Q₂₁ to Q₂₃, and Q₃₁ to Q₃₃ are each independently hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, or a substituted or unsubstituted monovalent non-aromatic condensed heteropolycyclic group, and
* indicates a binding site to a neighboring atom.

2. The heterocyclic compound of claim 1, wherein
Y₁ is O, S, Se, or N(R₁), and
Y₂ is O, S, Se, or N(R₃).

3. The heterocyclic compound of claim 1, wherein
ring CY₁ to ring CY₅ are each independently a benzene group, a naphthalene group, a phenanthrene group, a fluorene group, a pyridine group, a pyrimidine group, a quinoline group, an isoquinoline group, a phthalazine group, a naphthyridine group, a quinoxaline group, a quinazoline group, a carbazole group, a dibenzofuran group, a dibenzothiophene group, a dibenzosilole group, a dibenzoborole group, a dibenzophosphole group, a dibenzoselenophene group, a dibenzogermole group, a dibenzothiophene 5-oxide group, a 9H-fluoren-9-one group, or a dibenzothiophene 5,5-dioxide group.

4. The heterocyclic compound of claim 1, wherein
ring CY₆ to ring CY₈ are each independently a benzene group, a naphthalene group, a phenanthrene group, a pyridine group, a pyrimidine group, a quinoline group, an isoquinoline group, a phthalazine group, a naphthyridine group, a quinoxaline group, or a quinazoline group.

5. The heterocyclic compound of claim 1, wherein
the group represented by Formula 2 is a group represented by Formula 2A: 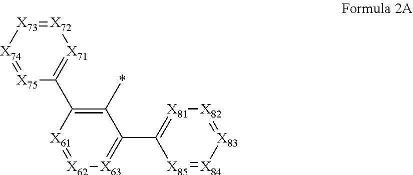
wherein, in Formula 2A,
X₆₁ is C(R₆₁) or N, X₆₂ is C(R₆₂) or N, X₆₃ is C(R₆₃) or N,
X₇₁ is C(R₇₁) or N, X₇₂ is C(R₇₂) or N, X₇₃ is C(R₇₃) or N, X₇₄ is C(R₇₄) or N, X₇₅ is C(R₇₅) or N,
X₈₁ is C(R₈₁) or N, X₈₂ is C(R₈₂) or N, X₈₃ is C(R₃₃) or N, X₈₄ is C(R₈₄) or N, X₈₅ is C(R₈₅) or N,
R₆₁ to R₆₃ are each independently as described in connection with R₆₀ in claim 1,
R₇₁ to R₇₅ are each independently as described in connection with R₇₀ in claim 1,
R₈₁ to R₈₅ are each independently as described in connection with R₈₀ in claim 1, and
* indicates a binding site to a neighboring atom.

6. The heterocyclic compound of claim 1, wherein
the group represented by Formula 2 is a group represented by Formula 2A-1: 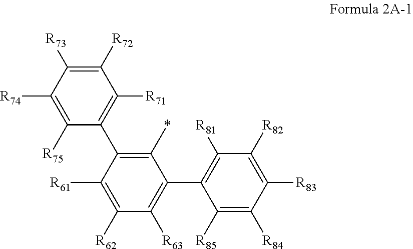
wherein, in Formula 2A-1,
R₆₁ to R₆₃ are each independently as described in connection with R₆₀ in claim 1,
R₇₁ to R₇₅ are each independently as described in connection with R₇₀ in claim 1,
R₈₁ to R₈₅ are each independently as described in connection with R₈₀ in claim 1, and
* indicates a binding site to a neighboring atom.

7. The heterocyclic compound of claim 1, wherein
R₁ to R₄, R₁₀, R₂₀, R₃₀, R₄₀, R₅₀, R₆₀, R₇₀, and R₈₀ are each independently:
hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, or a C₁-C₂₀ alkylthio group;
a C₁-C₂₀ alkyl group, a C₁-C₂₀ alkoxy group, or a C₁-C₂₀ alkylthio group, each substituted with deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a deuterium-containing C₁-C₂₀ alkyl group, a fluorine-containing C₁-C₂₀ alkyl group, a cyclopentyl group, a cyclohexyl group, a cycloheptyl group, a cyclooctyl group, an adamantanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group (norbornanyl group), a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.1]heptyl group, a (C₁-C₂₀ alkyl)bicyclo[2.2.2]octyl group, a silolanyl group, a phenyl group, a (C₁-C₂₀ alkyl)phenyl group, a biphenyl group, a terphenyl group, a naphthyl group, a 1,2,3,4-tetrahydronaphthyl group, a pyridinyl group, a pyrimidinyl group, or a combination thereof;
a cyclopentyl group, a cyclohexyl group, a cycloheptyl group, a cyclooctyl group, an adamantanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a silolanyl group, a phenyl group, a (C₁-C₂₀ alkyl)phenyl group, a biphenyl group, a terphenyl group, a naphthyl group, a 1,2,3,4-tetrahydronaphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, or an azadibenzothiophenyl group, each unsubstituted or substituted with deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a deuterium-containing C₁-C₂₀ alkyl group, a fluorine-containing C₁-C₂₀ alkyl group, a C₁-C₂₀ alkoxy group, a C₁-C₂₀ alkylthio group, a cyclopentyl group, a cyclohexyl group, a cycloheptyl group, a cyclooctyl group, an adamantanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.1]heptyl group, a (C₁-C₂₀ alkyl)bicyclo[2.2.2]octyl group, a silolanyl group, a phenyl group, a (C₁-C₂₀ alkyl)phenyl group, a biphenyl group, a terphenyl group, a naphthyl group, a 1,2,3,4-tetrahydronaphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, or a combination thereof; or
—N(Q₁)(Q₂), —Si(Q₁)(Q₂)(Q₃), —Ge(Q₁)(Q₂)(Q₃), —C(═O)(Q₁), —S(═O)(Q₁), —S(═O)₂(Q₁), —B(Q₁)(Q₂), —P(Q₁)(Q₂), —P(═O)(Q₁)(Q₂), or —P(═S)(Q₁)(Q₂)—N(Q₁₁)(Q₁₂), —Si(Q₁₁)(Q₁₂)(Q₁₃), —Ge(Q₁₁)(Q₁₂)(Q₁₃), —C(═O)(Q₁₁), —S(═O)(Q₁₁), —S(═O)₂(Q₁₁), —B(Q₁₁)(Q₁₂), —P(Q₁₁)(Q₁₂), —P(═O)(Q₁₁)(Q₁₂), or —P(═S)(Q₁₁)(Q₁₂).

8. The heterocyclic compound of claim 1, wherein
at least one of R₁ to R₄, R₁₀, R₂₀, R₃₀, R₄₀, R₅₀, R₆₀, R₇₀, or R₈₀ is deuterium, —F, —Cl, —Br, —I, —SF₅, a cyano group, a substituted or unsubstituted C₁-C₆₀ alkyl group, a substituted or unsubstituted C₃-C₁₀ cycloalkyl group, a substituted or unsubstituted C₆-C₆₀ aryl group, a substituted or unsubstituted C₁-C₆₀ heteroaryl group, a substituted or unsubstituted monovalent non-aromatic condensed polycyclic group, or a substituted or unsubstituted monovalent non-aromatic condensed heteropolycyclic group.

9. The heterocyclic compound of claim 1, wherein
the heterocyclic compound is represented by Formula 11: 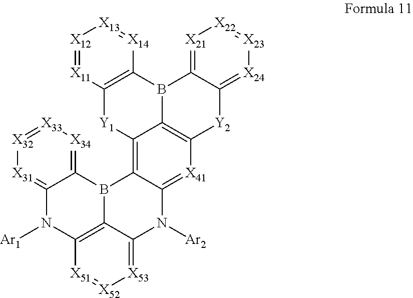
wherein, in Formula 11,
Y₁, Y₂, Ar₁, and Ar₂ are as described in claim 1,
X₁₁ is C(R₁₁) or N, X₁₂ is C(R₁₂) or N, X₁₃ is C(R₁₃) or N, and X₁₄ is C(R₁₄) or N,
X₂₁ is C(R₂₁) or N, X₂₂ is C(R₂₂) or N, X₂₃ is C(R₂₃) or N, and X₂₄ is C(R₂₄) or N,
X₃₁ is C(R₃₁) or N, X₃₂ is C(R₃₂) or N, X₃₃ is C(R₃₃) or N, and X₃₄ is C(R₃₄) or N,
X₄₁ is C(R₄₁) or N,
X₅₁ is C(R₅₁) or N, X₅₂ is C(R₅₂) or N, and X₅₃ is C(R₅₃) or N,
R₁₁ to R₁₄ are each independently as described in connection with R₁₀ in claim 1,
R₂₁ to R₂₄ are each independently as described in connection with R₂₀ in claim 1,
R₃₁ to R₃₄ are each independently as described in connection with R₃₀ in claim 1,
R₄₁ is as described in connection with R₄₀ in claim 1, and
R₅₁ to R₅₃ are each independently as described in connection with R₅₀ in claim 1.

10. The heterocyclic compound of claim 9, wherein
at least one of R₁₁ to R₁₄, R₂₁ to R₂₄, R₃₁ to R₃₄, R₄₁, or R₅₁ to R₅₃ is deuterium, —F, —Cl, —Br, —I, —SF₅, a cyano group, a substituted or unsubstituted C₁-C₆₀ alkyl group, a substituted or unsubstituted C₃-C₁₀ cycloalkyl group, a substituted or unsubstituted C₆-C₆₀ aryl group, a substituted or unsubstituted C₁-C₆₀ heteroaryl group, a substituted or unsubstituted monovalent non-aromatic condensed polycyclic group, or a substituted or unsubstituted monovalent non-aromatic condensed heteropolycyclic group.

11. The heterocyclic compound of claim 1, wherein
the heterocyclic compound is represented by Formula 21: 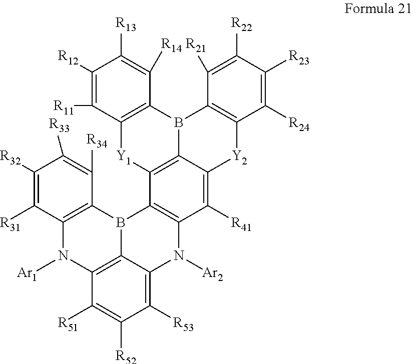
wherein, in Formula 21,
Y₁, Y₂, Ar₁, and Ar₂ are as described in claim 1,
R₁₁ to R₁₄ are each independently as described in connection with R₁₀ in claim 1,
R₂₁ to R₂₄ are each independently as described in connection with R₂₀ in claim 1,
R₃₁ to R₃₄ are each independently as described in connection with R₃₀ in claim 1,
R₄₁ is as described in connection with R₄₀ in claim 1, and
R₅₁ to R₅₃ are each independently as described in connection with R₅₀ in claim 1.

12. The heterocyclic compound of claim 1, wherein
the heterocyclic compound is represented by Formula 31: 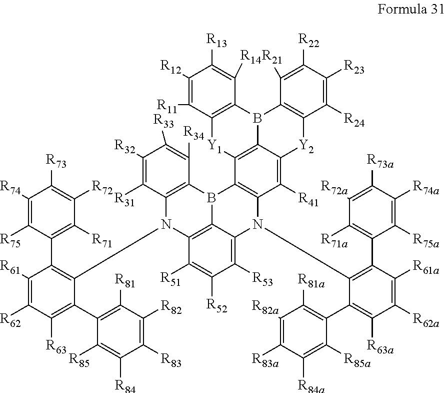
wherein, in Formula 31,
Y₁ and Y₂ are as described in claim 1,
R₁₁ to R₁₄ are each independently as described in connection with R₁₀ in claim 1,
R₂₁ to R₂₄ are each independently as described in connection with R₂₀ in claim 1,
R₃₁ to R₃₄ are each independently as described in connection with R₃₀ in claim 1,
R₄₁ is as described in connection with R₄₀ in claim 1, and
R₅₁ to R₅₃ are each independently as described in connection with R₅₀ in claim 1,
R₆₁ to R₆₃ and R₆₁ₐ to R₆₃ₐ are each independently as described in connection with R₆₀ in claim 1,
R₇₁ to R₇₅ and R₇₁ₐ to R₇₅ₐ are each independently as described in connection with R₇₀ in claim 1, and
R₈₁ to R₈₅ and R₈₁ₐ to R₈₅ₐ are each independently as described in connection with R₈₀ in claim 1.

13. An organic light-emitting device, comprising:
a first electrode;
a second electrode; and
an organic layer arranged between the first electrode and the second electrode,
wherein the organic layer comprises an emission layer, and
wherein the organic layer further comprises at least one heterocyclic compound of claim 1.

14. The organic light-emitting device of claim 13, wherein
the emission layer comprises the at least one heterocyclic compound.

15. The organic light-emitting device of claim 14, wherein
the emission layer comprises a host and an emitter, and
the emitter comprises the at least one heterocyclic compound.

16. The organic light-emitting device of claim 15, wherein
an amount of the host in the emission layer is greater than an amount of the heterocyclic compound in the emission layer, based on weight.

17. The organic light-emitting device of claim 15, wherein
the emission layer further comprises a sensitizer.

18. The organic light-emitting device of claim 17, wherein
the sensitizer comprises a phosphorescent dopant.

19. The organic light-emitting device of claim 14, wherein
the emission layer emits a blue light having a maximum emission wavelength of about 400 nanometers to about 490 nanometers.

20. An electronic apparatus, comprising the organic light-emitting device of claim 13.
